(19) United States
(12) Patent Application Publication
(10) Pub. No.: US 2024/0034746 A1
(43) Pub. Date: Feb. 1, 2024

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Han Zhang, Beijing (CN); Cuifang Zhang, Beijing (CN); Zhihong Dai, Beijing (CN); Qi Zhang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/216,309

(22) Filed: Jun. 29, 2023

(30) Foreign Application Priority Data
Jun. 30, 2022 (CN) 202210755444.0
Apr. 26, 2023 (CN) 202310464176.1

(51) Int. Cl. C07F 15/00; C07F 19/00; H10K 85/30; H10K 50/82; H10K 50/81; H10K 50/11; C09K 11/06

(52) U.S. Cl. CPC C07F 15/0033; C07F 19/00; H10K 85/342; H10K 50/82; H10K 50/81; H10K 50/11; C09K 11/06; C07B 2200/05; C09K 2211/1074

(57) ABSTRACT

Provided are an organic electroluminescent material and a device thereof. The organic electroluminescent material is a metal complex having a general formula of M(Lₐ)ₘ(L_{b})ₙ(L_{c})_{q}. The metal complex can meet luminescence requirements on different wavebands, unexpectedly have a greatly narrowed full width at half maximum, and can achieve high-saturation luminescence. Moreover, when used as a emissive material in an electroluminescent device, the metal complex can effectively control the luminescence wavelength of the device, can make the device have the advantages of a low voltage, high efficiency, and an ultra-long lifetime, and can provide better device performance. Further provided are an electroluminescent device and a compound composition.

### CROSS-REFERENCE TO RELATED APPLICATION(S)

This application claims priority to Chinese Patent Application No. 202210755444.0 filed on Jun. 30, 2022 and Chinese Patent Application No. 202310464176.1 filed on Apr. 26, 2023, the disclosure of which are incorporated herein by reference in their entireties.

### TECHNICAL FIELD

The present disclosure relates to compounds for organic electronic devices such as organic light-emitting devices. More particularly, the present disclosure relates to a metal complex having a general formula of M(Lₐ)ₘ(L_{b})ₙ(L_{c})_{q}, an organic electroluminescent device comprising the metal complex, and a compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Phosphorescent materials have been reported in the related art. However, further research and development is still required to meet the increasing requirements of the industry on device performance such as emitted colors of devices, luminescence saturation, voltage, device efficiency, and device lifetime.

### SUMMARY

The present disclosure aims to provide a series of metal complexes having a general formula of M(Lₐ)ₘ(L_{b})ₙ(L_{c})_{q} to solve at least part of the preceding problems. The metal complexes may be used as emissive materials in organic electroluminescent devices. The metal complexes can meet luminescence requirements on different wavebands, unexpectedly have a greatly narrowed full width at half maximum, and can achieve high-saturation luminescence. Moreover, when used as emissive materials in electroluminescent devices, the metal complexes of the present disclosure can effectively control the luminescence wavelength of the devices, can make the devices have the advantages of a low voltage, high efficiency, and an ultra-long lifetime, and can provide better device performance.

According to an embodiment of the present disclosure, disclosed is a metal complex having a general formula of M(Lₐ)ₘ(L_{b})ₙ(L_{c})_{q}, wherein the metal M is selected from a metal with a relative atomic mass greater than 40, and Lₐ, L_{b}, and L_{c} are a first ligand, a second ligand, and a third ligand coordinated to the metal M, respectively;
Lₐ, L_{b}, and L_{c} can be optionally joined to form a multidentate ligand;
m is selected from 1 or 2, n is selected from 1 or 2, q is selected from 0 or 1, and m+n+q equals the oxidation state of the metal M; when m is equal to 2, two Lₐ are the same or different; when n is equal to 2, two L_{b} are the same or different;
the first ligand Lₐ has a structure represented by Formula 1:

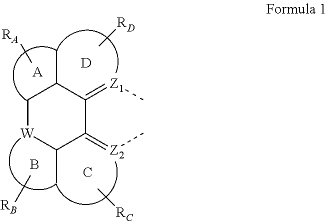

wherein Z₁ and Z₂ are each independently selected from C or N, and Z₁ is different from Z₂;
W is, at each occurrence identically or differently, selected from B, N, or P;
the ring A, the ring C, and the ring D are, at each occurrence identically or differently, selected from a five-membered unsaturated carbocyclic ring, an aromatic ring having 6 to 30 carbon atoms, or a heteroaromatic ring having 3 to 30 carbon atoms;
the ring B is selected from a heterocyclic ring having 2 to 30 carbon atoms or a heteroaromatic ring having 2 to 30 carbon atoms;
R_{A}, R_{B}, R_{C}, and R_{D} represent, at each occurrence identically or differently, mono-substitution, multiple substitutions, or non-substitution;
R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, and R_{D} can be optionally joined to form a ring;
the second ligand L_{b} has a structure represented by Formula 2:

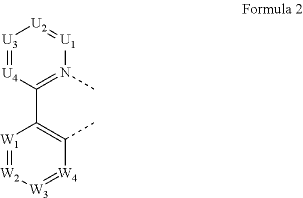

wherein U₁ to U₄ are, at each occurrence identically or differently, selected from N or CR_{U};
W₁ to W₄ are, at each occurrence identically or differently, selected from N or CR_{W};
R_{U} and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{U}, R_{W} can be optionally joined to form a ring; and
L_{c} is selected from a monoanionic bidentate ligand.

According to another embodiment of the present disclosure, further disclosed is an electroluminescent device comprising an anode, a cathode, and an organic layer disposed between the anode and the cathode, wherein the organic layer comprises the metal complex in the preceding embodiment.

According to another embodiment of the present disclosure, further disclosed is a compound composition comprising the metal complex in the preceding embodiment.

The novel metal complexes disclosed in the present disclosure may be used as emissive materials in electroluminescent devices. These novel metal complexes can unexpectedly narrow a light emitting spectrum greatly, greatly improve the luminescence saturation of the devices, make the devices have a low voltage, high efficiency, and an ultra-long lifetime, effectively adjust the luminescence wavelength of the devices, and provide good device performance.

### BRIEF DESCRIPTION OF DRAWINGS

FIG. 1 is a schematic diagram of an organic light-emitting device that may contain a metal complex and a compound composition disclosed herein.

FIG. 2 is a schematic diagram of another organic light-emitting device that may contain a metal complex and a compound composition disclosed herein.

### DETAILED DESCRIPTION

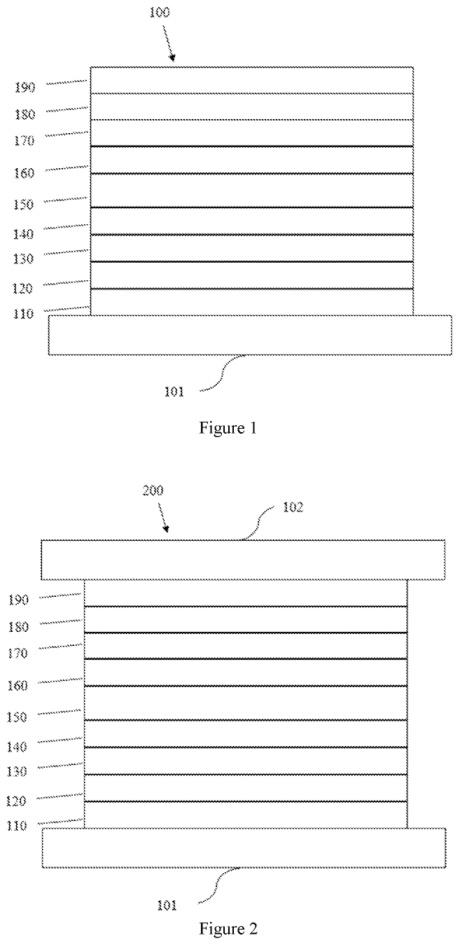

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

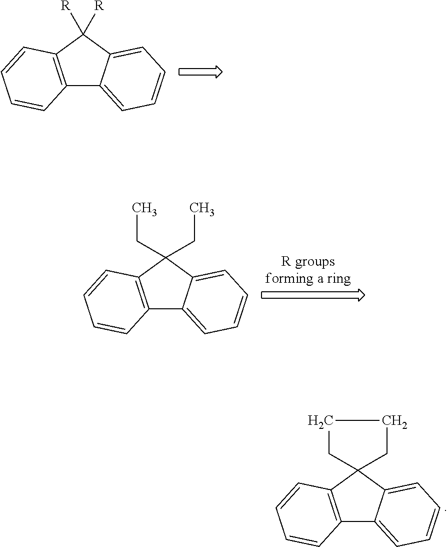

The expression that adjacent substituents can be optionally joined to form a ring is also intended to mean that two substituents bonded to carbon atoms which are directly bonded to each other are joined to each other via a chemical bond to form a ring, which can be exemplified by the following formula:

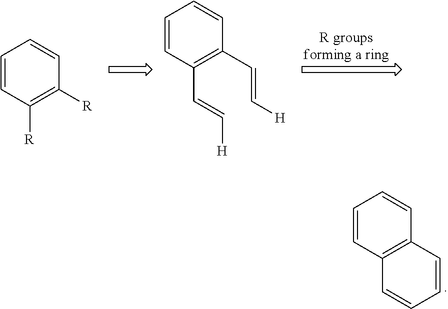

The expression that adjacent substituents can be optionally joined to form a ring is also intended to mean that two substituents bonded to further distant carbon atoms are joined to each other via a chemical bond to form a ring, which can be exemplified by the following formula:

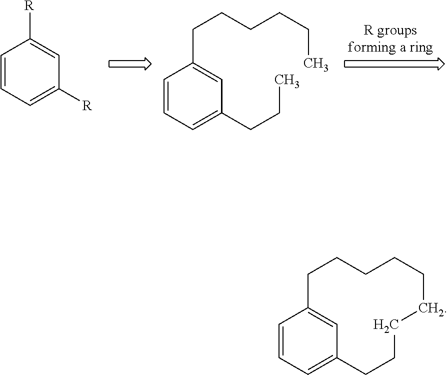

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

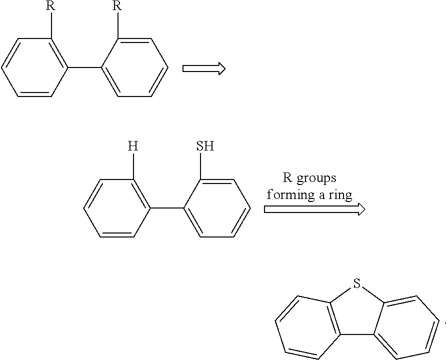

According to an embodiment of the present disclosure, disclosed is a metal complex having a general formula of M(Lₐ)ₘ(L_{b})ₙ(L_{c})_{q}, wherein the metal M is selected from a metal with a relative atomic mass greater than 40, and Lₐ, L_{b}, and L_{c} are a first ligand, a second ligand, and a third ligand coordinated to the metal M, respectively;
Lₐ, L_{b}, and L_{c} can be optionally joined to form a multidentate ligand;
m is selected from 1 or 2, n is selected from 1 or 2, q is selected from 0 or 1, and m+n+q equals the oxidation state of the metal M; when m is equal to 2, two Lₐ are the same or different; when n is equal to 2, two L_{b} are the same or different;
the first ligand Lₐ has a structure represented by Formula 1:

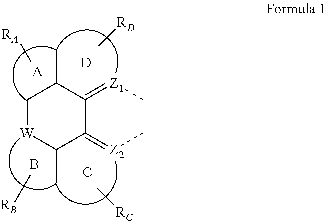

wherein Z₁ and Z₂ are each independently selected from C or N, and Z₁ is different from Z₂;
W is, at each occurrence identically or differently, selected from B, N, or P;
the ring A, the ring C, and the ring D are, at each occurrence identically or differently, selected from a five-membered unsaturated carbocyclic ring, an aromatic ring having 6 to 30 carbon atoms, or a heteroaromatic ring having 3 to 30 carbon atoms;
the ring B is selected from a heterocyclic ring having 2 to 30 carbon atoms or a heteroaromatic ring having 2 to 30 carbon atoms;
R_{A}, R_{B}, R_{C}, and R_{D} represent, at each occurrence identically or differently, mono-substitution, multiple substitutions, or non-substitution;
R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, and R_{D} can be optionally joined to form a ring;
the second ligand L_{b} has a structure represented by Formula 2:

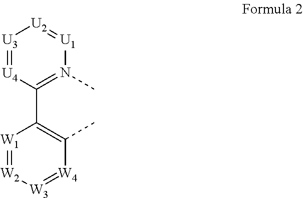

wherein U₁ to U₄ are, at each occurrence identically or differently, selected from N or CR_{U};
W₁ to W₄ are, at each occurrence identically or differently, selected from N or CR_{W};
R_{U} and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{U}, R_{W} can be optionally joined to form a ring; and
L_{c} is selected from a monoanionic bidentate ligand.

In the present disclosure, the expression that adjacent substituents R_{A}, R_{B}, R_{C}, and R_{D} can be optionally joined to form a ring is intended to mean that any one or more of groups of adjacent substituents, such as adjacent substituents R_{A}, adjacent substituents R_{B}, adjacent substituents R_{C}, adjacent substituents R_{D}, adjacent substituents R_{A} and R_{B}, adjacent substituents R_{A} and R_{D}, and adjacent substituents R_{B} and R_{C}, can be joined to form a ring. Obviously, it is also possible that none of these groups of adjacent substituents are joined to form a ring.

In the present disclosure, the expression that adjacent substituents R_{U}, R_{W} can be optionally joined to form a ring is intended to mean that in Formula 2, any one or more of groups of adjacent substituents, such as adjacent substituents R_{U}, adjacent substituents R_{W}, and adjacent substituents R_{U} and R_{W}, can be joined to form a ring. Obviously, it is also possible that none of these groups of adjacent substituents are joined to form a ring.

In this embodiment, Lₐ, L_{b}, and L_{c} can be optionally joined to form a multidentate ligand, for example, any two or three of Lₐ, L_{b}, and L_{c} can be joined to form a tetradentate ligand or a hexadentate ligand. Obviously, it is also possible that none of Lₐ, L_{b}, and L_{c} are joined to form a multidentate ligand.

According to an embodiment of the present disclosure, in Lₐ, the ring A, the ring C, and the ring D are, at each occurrence identically or differently, selected from an aromatic ring having 6 to 18 carbon atoms or a heteroaromatic ring having 3 to 18 carbon atoms; and the ring B is selected from a heteroaromatic ring having 2 to 18 carbon atoms.

According to an embodiment of the present disclosure, in Lₐ, the ring A, the ring C, and the ring D are, at each occurrence identically or differently, selected from a benzene ring, a naphthalene ring, a pyridine ring, a pyrimidine ring, a pyrazine ring, an azanaphthalene ring, a furan ring, a thiophene ring, an isoxazole ring, an isothiazole ring, a pyrrole ring, a pyrazole ring, a benzofuran ring, a benzothiophene ring, an azabenzofuran ring, or an azabenzothiophene ring; and the ring B is selected from a pyrrole ring, an indole ring, an imidazole ring, a pyrazole ring, a triazole ring, or an azaindole ring.

According to an embodiment of the present disclosure, in Lₐ, the ring A, the ring C, and the ring D are, at each occurrence identically or differently, selected from a benzene ring, a naphthalene ring, a pyridine ring, or a pyrimidine ring; and the ring B is selected from a pyrrole ring, an indole ring, or an azaindole ring.

According to an embodiment of the present disclosure, Lₐ is selected from a structure represented by any one of Formula 3 to Formula 20:

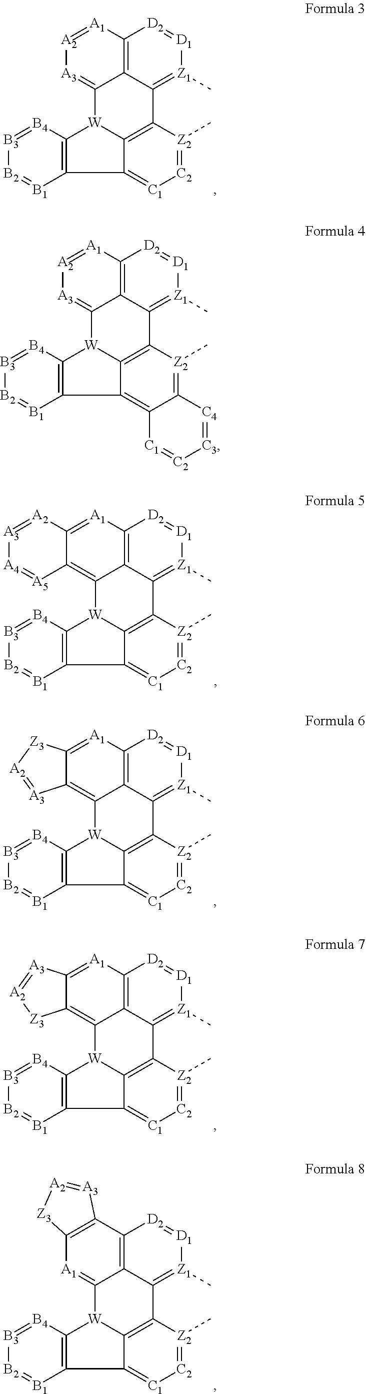

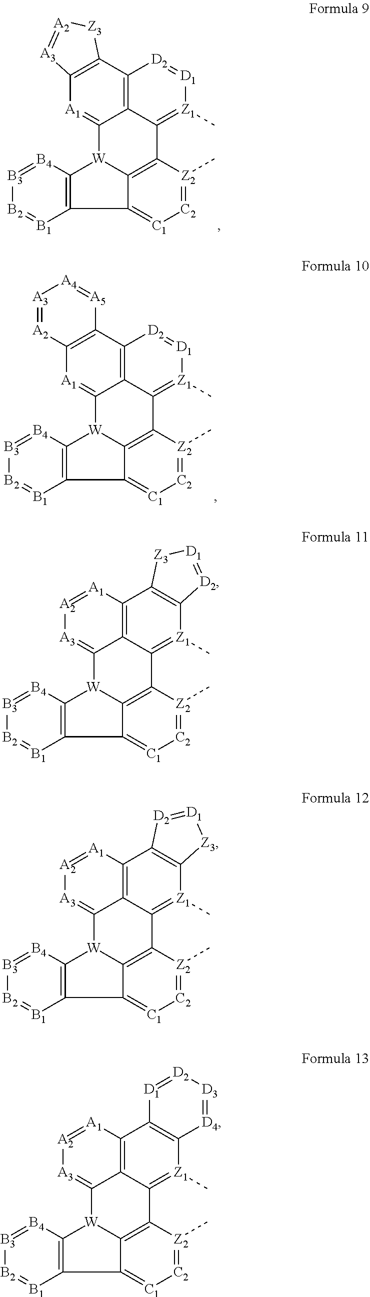

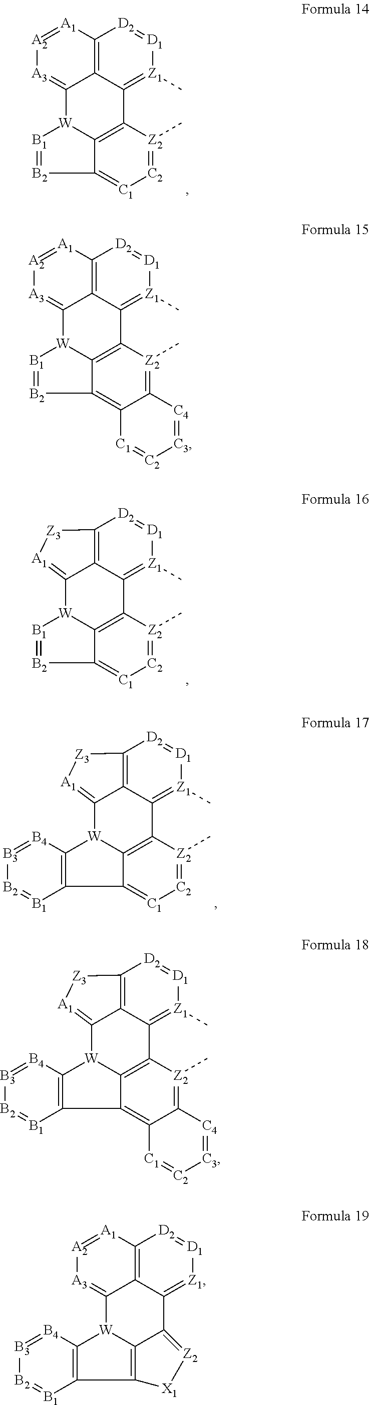

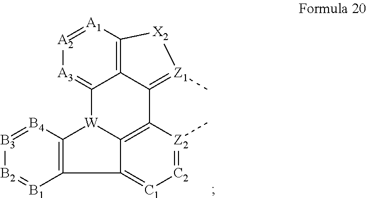

wherein
Z₁ and Z₂ are each independently selected from C or N, and Z₁ is different from Z₂; W is, at each occurrence identically or differently, selected from B, N, or P;
A₁ to A₅ are, at each occurrence identically or differently, selected from N or CR_{A};
B₁ to B₄ are, at each occurrence identically or differently, selected from N or CR_{B};
C₁ to C₄ are, at each occurrence identically or differently, selected from N or CR_{C};
D₁ to D₄ are, at each occurrence identically or differently, selected from N or CR_{D};
X₁ is, at each occurrence identically or differently, selected from O, S, Se, NR_{C}, CR_{C}R_{C}, SiR_{C}R_{C}, or PR_{C};
X₂ is, at each occurrence identically or differently, selected from O, S, Se, NR_{D}, CR_{D}R_{D}, SiR_{D}R_{D}, or PR_{D};
Z₃ is, at each occurrence identically or differently, selected from O, S, Se, NR_{Z}, CR_{Z}R_{Z}, SiR_{Z}R_{Z}, or PR_{Z};
R_{A}, R_{B}, R_{C}, R_{D}, and R_{Z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, R_{D}, and R_{Z} can be optionally joined to form a ring.

In this embodiment, the expression that adjacent substituents R_{A}, R_{B}, R_{C}, R_{D}, and R_{Z} can be optionally joined to form a ring is intended to mean that any one or more of groups of adjacent substituents, such as adjacent substituents R_{A}, adjacent substituents R_{B}, adjacent substituents R_{C}, adjacent substituents R_{D}, adjacent substituents R_{A} and R_{B}, adjacent substituents R_{A} and R_{D}, adjacent substituents R_{B} and R_{C}, adjacent substituents R_{A} and R_{Z}, adjacent substituents R_{D} and R_{Z}, and adjacent substituents R_{Z}, can be joined to form a ring. Obviously, it is also possible that none of these groups of adjacent substituents are joined to form a ring.

According to an embodiment of the present disclosure, Lₐ is selected from a structure represented by Formula 3, Formula 4, Formula 8, Formula 9, Formula 10, or Formula 13.

According to an embodiment of the present disclosure, Lₐ is selected from a structure represented by Formula 3, Formula 4, or Formula 13.

According to an embodiment of the present disclosure, in Formula 1 and Formula 3 to Formula 20, W is B or N.

According to an embodiment of the present disclosure, in Formula 1 and Formula 3 to Formula 20, W is N.

According to an embodiment of the present disclosure, in Formula 3 to Formula 19, Z₁ is N, and at least one of D₁ and D₂ is N; or in Formula 3 to Formula 18 and Formula 20, Z₂ is N, and at least one of C₁ and C₂ is N.

According to an embodiment of the present disclosure, in Formula 3 to Formula 19, Z₁ is N, and one of D₁ and D₂ is N; or in Formula 3 to Formula 18, and Formula 20, Z₂ is N, and one of C₁ and C₂ is N.

According to an embodiment of the present disclosure, in Formula 3 to Formula 19, Z₁ is N, and D₂ is N; or in Formula 3 to Formula 18 and Formula 20, Z₂ is N, and C₁ is N.

According to an embodiment of the present disclosure, in Formula 3 to Formula 20, A₁ to A₅ are each independently selected from CR_{A}, and B₁ to B₄ are each independently selected from CR_{B}; in Formula 3 to Formula 18 and Formula 20, C₁ to C₄ are each independently selected from CR_{C}; in Formula 3 to Formula 19, D₁ to D₄ are each independently selected from CR_{D}; and the R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, and R_{D} can be optionally joined to form a ring.

In the present disclosure, the expression that adjacent substituents R_{A}, R_{B}, R_{C}, and R_{D} can be optionally joined to form a ring is intended to mean that any one or more of groups of adjacent substituents, such as adjacent substituents R_{A}, adjacent substituents R_{B}, adjacent substituents R_{C}, adjacent substituents R_{D}, adjacent substituents R_{A} and R_{B}, adjacent substituents R_{A} and R_{D}, and adjacent substituents R_{B} and R_{C}, can be joined to form a ring. Obviously, it is also possible that none of these groups of adjacent substituents are joined to form a ring.

According to an embodiment of the present disclosure, in Formula 3 to Formula 20, A₁ to A₅ are each independently selected from CR_{A}, and B₁ to B₄ are each independently selected from CR_{B}; in Formula 3 to Formula 18 and Formula 20, C₁ to C₄ are each independently selected from CR_{C}; in Formula 3 to Formula 19, D₁ to D₄ are each independently selected from CR_{D}; and the R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkoxy having 1 to 20 carbon atoms, substituted or unsubstituted aryloxy having 6 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, and combinations thereof, and adjacent substituents R_{A}, R_{B}, R_{C}, and R_{D} can be optionally joined to form a ring.

According to an embodiment of the present disclosure, in Formula 3 to Formula 20, A₁ to A₅ are each independently selected from CR_{A}, and B₁ to B₄ are each independently selected from CR_{B}; in Formula 3 to Formula 18 and Formula 20, C₁ to C₄ are each independently selected from CR_{C}; in Formula 3 to Formula 19, D₁ to D₄ are each independently selected from CR_{D}; and the R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, cyano, and combinations thereof, and adjacent substituents R_{A}, R_{B}, R_{C}, and R_{D} can be optionally joined to form a ring.

According to an embodiment of the present disclosure, in Formula 3 to Formula 20, at least one of A₁ to Aₙ is, at each occurrence identically or differently, selected from CR_{A}, wherein the Aₙ corresponds to the one with the largest serial number among A₁ to A₅ in any one of Formula 3 to Formula 20; and the R_{A} is, at each occurrence identically or differently, selected from the group consisting of: deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof, and
adjacent substituents R_{A} can be optionally joined to form a ring.

In the present disclosure, the expression that adjacent substituents R_{A} can be optionally joined to form a ring is intended to mean that any adjacent substituents R_{A} can be joined to form a ring. Obviously, it is also possible that any adjacent substituents R_{A} are not joined to form a ring.

In this embodiment, in Formula 3 to Formula 20, at least one of A₁ to Aₙ is, at each occurrence identically or differently, selected from CR_{A}, wherein the Aₙ corresponds to the one with the largest serial number among A₁ to A₅ in any one of Formula 3 to Formula 20, for example, in Formula 3, the Aₙ corresponds to A₃ whose serial number is the largest among A₁ to A₅ in Formula 3, that is, in Formula 3, at least one of A₁ to A₃ is, at each occurrence identically or differently, selected from CR_{A}; in another example, in Formula 5, the Aₙ corresponds to A₅ whose serial number is the largest among A₁ to A₅ in Formula 5, that is, in Formula 5, at least one of A₁ to A₅ is, at each occurrence identically or differently, selected from CR_{A}; in another example, in Formula 16, the Aₙ corresponds to A₁ whose serial number is the largest among A₁ to A₅ in Formula 16, that is, in Formula 16, A₁ is, at each occurrence identically or differently, selected from CR_{A}.

According to an embodiment of the present disclosure, in Formula 3 to Formula 15, Formula 19, and Formula 20, at least one of A₁ to A₃ is, at each occurrence identically or differently, selected from CR_{A}; in Formula 16 to Formula 18, A₁ is selected from CR_{A}; and the R_{A} is, at each occurrence identically or differently, selected from the group consisting of: deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof, and adjacent substituents R_{A} can be optionally joined to form a ring.

According to an embodiment of the present disclosure, in Formula 3, Formula 4, Formula 6 to Formula 9, Formula 11 to Formula 15, Formula 19, and Formula 20, A₂ is selected from CR_{A}; and in Formula 5, Formula 10, and Formula 16 to Formula 18, A₁ is selected from CR_{A}.

According to an embodiment of the present disclosure, in Formula 3, Formula 4, Formula 6 to Formula 9, Formula 11 to Formula 15, Formula 19, and Formula 20, A₂ is selected from CR_{A}; in Formula 5, Formula 10, and Formula 16 to Formula 18, A₁ is selected from CR_{A}; and the R_{A} is, at each occurrence identically or differently, selected from the group consisting of: deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, sec-butyl, t-butyl, neopentyl, cyclopentyl, cyclopentylmethyl, cyclohexyl, norbornyl, adamantyl, trimethylsilyl, triethylsilyl, phenyldimethylsilyl, trimethylgermanyl, triethylgermanyl, phenyl, 2,6-dimethylphenyl, 2,6-diisopropylphenyl, pyridyl, pyrimidinyl, triazinyl, and combinations thereof.

According to an embodiment of the present disclosure, in Formula 3 to Formula 18 and Formula 20, at least one of C₁ and C₂ is, at each occurrence identically or differently, selected from CR_{C}, and the R_{C} is, at each occurrence identically or differently, selected from the group consisting of: deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, and combinations thereof.

According to an embodiment of the present disclosure, in Formula 3 to Formula 18 and Formula 20, C₂ is selected from CR_{C}, and the R_{C} is selected from the group consisting of: deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, and combinations thereof.

According to an embodiment of the present disclosure, in Formula 3 to Formula 18 and Formula 20, at least one of C₁ and C₂ is, at each occurrence identically or differently, selected from CR_{C}, and the R_{C} is, at each occurrence identically or differently, selected from the group consisting of: deuterium, cyano, fluorine, methyl, ethyl, isopropyl, isobutyl, t-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, and combinations thereof.

According to an embodiment of the present disclosure, in Formula 3 to Formula 18 and Formula 20, C₂ is selected from CR_{C}; and the R_{C} is selected from the group consisting of: deuterium, cyano, fluorine, methyl, ethyl, isopropyl, isobutyl, t-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, and combinations thereof.

According to an embodiment of the present disclosure, in Formula 3 to Formula 20, at least one of B₁ to Bₙ is selected from CR_{B}, wherein the Bₙ corresponds to the one with the largest serial number among B₁ to B₄ in any one of Formula 3 to Formula 20; and/or in Formula 3 to Formula 19, at least one of D₁ to Dₙ is selected from CR_{D}, wherein the Dₙ corresponds to the one with the largest serial number among D₁ to D₄ in any one of Formula 3 to Formula 19; wherein the R_{B} and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, hydroxyl, sulfanyl, and combinations thereof.

In this embodiment, in Formula 3 to Formula 20, at least one of B₁ to Bₙ is, at each occurrence identically or differently, selected from selected from CR_{B}, wherein the Bₙ corresponds to the one with the largest serial number among B₁ to B₄ in any one of Formula 3 to Formula 20, for example, in Formula 3, the Bₙ corresponds to B₄ whose serial number is the largest among B₁ to B₄ in Formula 3, that is, in Formula 3, at least one of B₁ to B₄ is, at each occurrence identically or differently, selected from CR_{B}; in another example, in Formula 14, the Bₙ corresponds to B₂ whose serial number is the largest among B₁ to B₄ in Formula 14, that is, in Formula 14, at least one of B₁ and B₂ is, at each occurrence identically or differently, selected from CR_{B}.

In this embodiment, in Formula 3 to Formula 19, at least one of D₁ to Dₙ is, at each occurrence identically or differently, selected from selected from CR_{D}, wherein the Dₙ corresponds to the one with the largest serial number among D₁ to D₄ in any one of Formula 3 to Formula 19, for example, in Formula 3, the Dₙ corresponds to D₂ whose serial number is the largest among D₁ to D₄ in Formula 3, that is, in Formula 3, at least one of D₁ and D₂ is, at each occurrence identically or differently, selected from CR_{D}; in another example, in Formula 13, the Dₙ corresponds to D₄ whose serial number is the largest among D₁ to D₄ in Formula 13, that is, in Formula 13, at least one of D₁ to D₄ is, at each occurrence identically or differently, selected from CR_{D}.

According to an embodiment of the present disclosure, in Formula 3 to Formula 20, at least one of B₁ to Bₙ is selected from CR_{B}, wherein the Bₙ corresponds to the one with the largest serial number among B₁ to B₄ in any one of Formula 3 to Formula 20; and/or in Formula 3 to Formula 19, at least one of D₁ to Dₙ is selected from CR_{D}, wherein the Dₙ corresponds to the one with the largest serial number among D₁ to D₄ in any one of Formula 3 to Formula 19; wherein the R_{B} and R_{D} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, hydroxyl, sulfanyl, and combinations thereof.

According to an embodiment of the present disclosure, in Formula 3 to Formula 13, Formula 17, Formula 19, and Formula 20, B₂ and/or B₃ are selected from CR_{B}; in Formula 14 to Formula 16 and Formula 18, B₁ and/or B₂ are selected from CR_{B}; and in Formula 3 to Formula 19, D₁ and/or D₂ are selected from CR_{D}.

According to an embodiment of the present disclosure, in Formula 3 to Formula 13, Formula 17, Formula 19, and Formula 20, B₂ and/or B₃ are selected from CR_{B}; in Formula 14 to Formula 16 and Formula 18, B₁ and/or B₂ are selected from CR_{B}; in Formula 3 to Formula 19, D₁ and/or D₂ are selected from CR_{D}; and the R_{B} and R_{D} are, at each occurrence identically or differently, selected from the group consisting of: hydrogen, deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, t-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, and combinations thereof.

According to an embodiment of the present disclosure, Lₐ is, at each occurrence identically or differently, selected from the group consisting of Lₐ₁ to Lₐ₁₈₂₀. For the specific structures of Lₐ₁ to Lₐ₁₈₂₀, see claim 10.

According to an embodiment of the present disclosure, Lₐ is, at each occurrence identically or differently, selected from the group consisting of Lₐ₁ to Lₐ₁₈₅₆. For the specific structures of Lₐ₁ to Lₐ₁₈₂₀, see claim 10, and the specific structures of Lₐ₁₈₂₁ to Lₐ₁₈₅₆ are as follows:

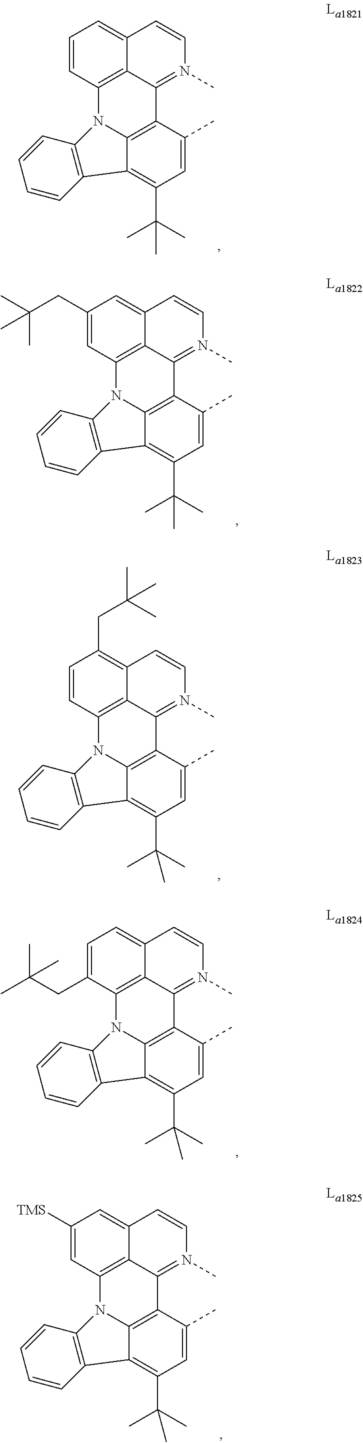

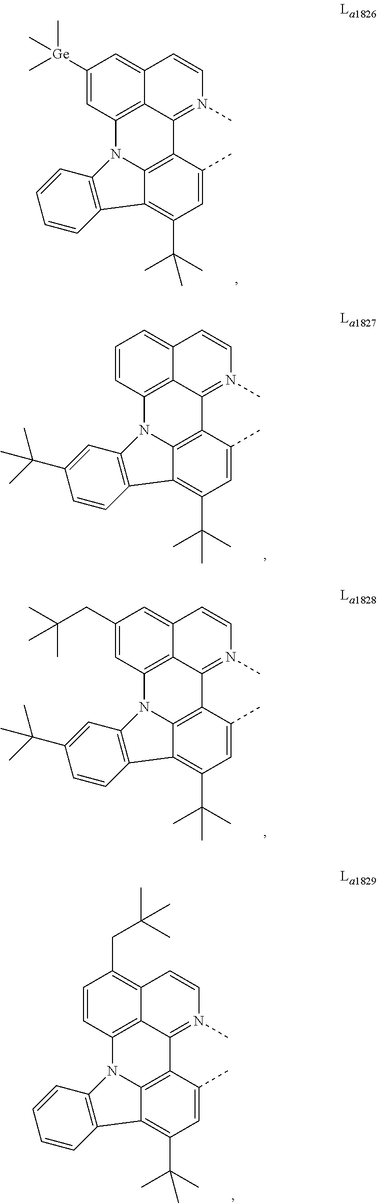

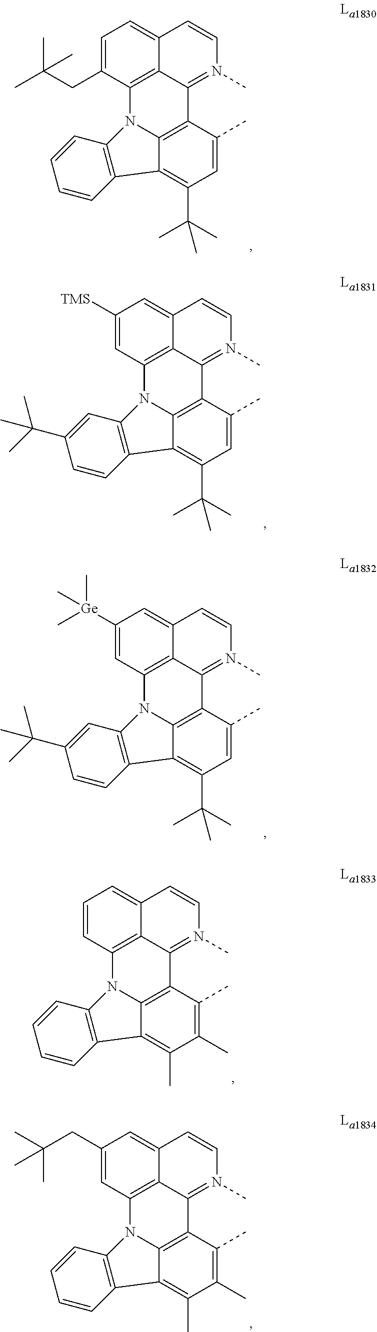

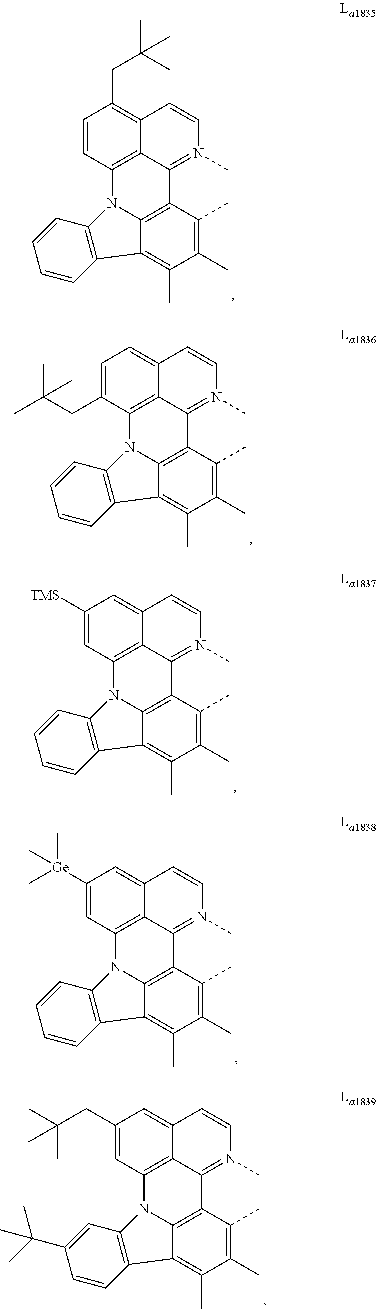

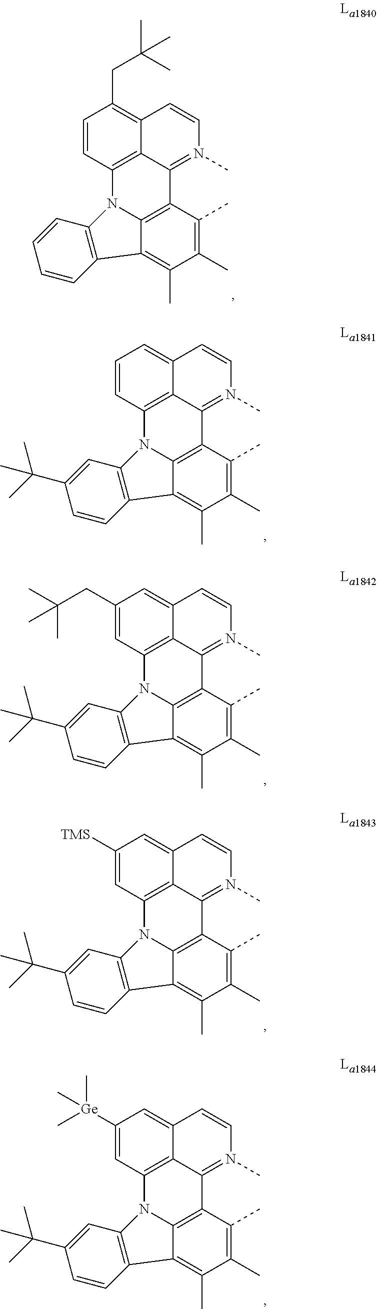

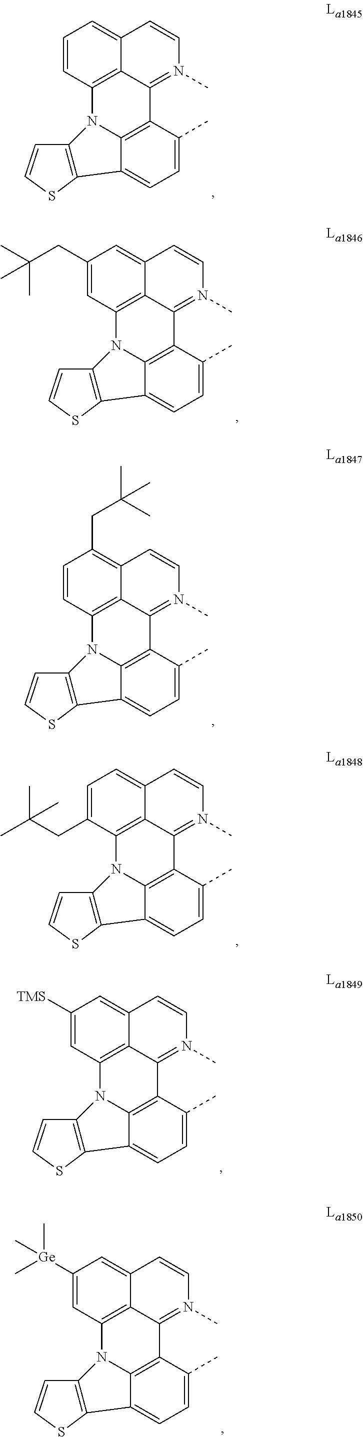

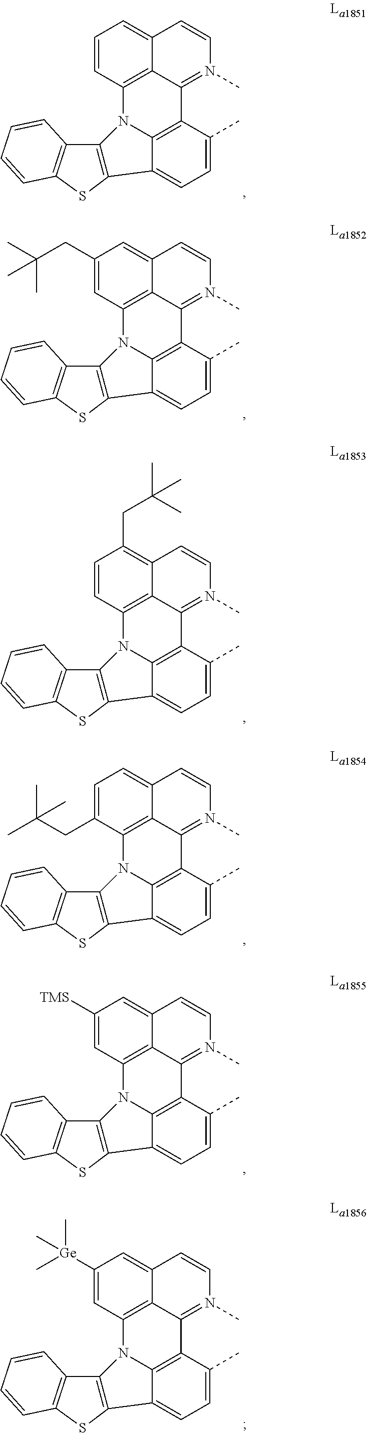

wherein in the above structures, TMS represents trimethylsilyl.

According to an embodiment of the present disclosure, hydrogen atoms in Lₐ₁ to Lₐ₁₈₂₀ can be partially or fully substituted with deuterium.

According to an embodiment of the present disclosure, hydrogen atoms in Lₐ₁ to Lₐ₁₈₅₆ can be partially or fully substituted with deuterium.

According to an embodiment of the present disclosure, the second ligand L_{b} is represented by Formula 21:

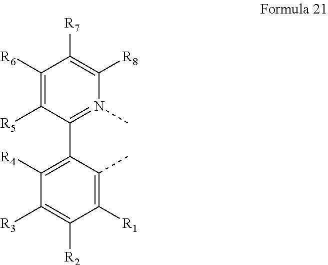

wherein R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R₁ to R₈ can be optionally joined to form a ring.

In the present disclosure, the expression that adjacent substituents R₁ to R₅ can be optionally joined to form a ring is intended to mean that any one or more of groups of adjacent substituents, such as adjacent substituents R₁ and R₂, adjacent substituents R₂ and R₃, adjacent substituents R₃ and R₄, adjacent substituents R₄ and R₅, adjacent substituents R₅ and R₆, adjacent substituents R₆ and R₇, and adjacent substituents R₇ and R₈, can be joined to form a ring. Obviously, it is also possible that none of these groups of adjacent substituents are joined to form a ring.

According to an embodiment of the present disclosure, in Formula 21, R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof, and
adjacent substituents R₁ to R₈ can be optionally joined to form a ring.

According to an embodiment of the present disclosure, in Formula 21, at least one or two of R₁ to R₈ are, at each occurrence identically or differently, selected from deuterium, substituted or unsubstituted alkyl having 1 to 20 carbon atoms, substituted or unsubstituted cycloalkyl having 3 to 20 ring carbon atoms, or a combination thereof, and
adjacent substituents R₁ to R₈ can be optionally joined to form a ring.

According to an embodiment of the present disclosure, in Formula 21, at least one, at least two, at least three, or all of R₂, R₃, R₆, and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, in Formula 21, at least one, at least two, at least three, or all of R₂, R₃, R₆, and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, in Formula 21, at least one, at least two, at least three, or all of R₂, R₃, R₆, and R₇ are, at each occurrence identically or differently, selected from the group consisting of: deuterium, methyl, ethyl, propyl, isopropyl, n-butyl, isobutyl, t-butyl, cyclopentyl, cyclohexyl, neopentyl, t-pentyl, and any preceding group that is partially or fully substituted with deuterium.

According to an embodiment of the present disclosure, L_{b} is, at each occurrence identically or differently, selected from the group consisting of L_{b1} to L_{b379}. For the specific structures of L_{b1} to L_{b379}, see claim 13.

According to an embodiment of the present disclosure, hydrogen atoms in L_{b1} to L_{b379} can be partially or fully substituted with deuterium.

According to an embodiment of the present disclosure, L_{c} is, at each occurrence identically or differently, selected from the group consisting of the following structures:

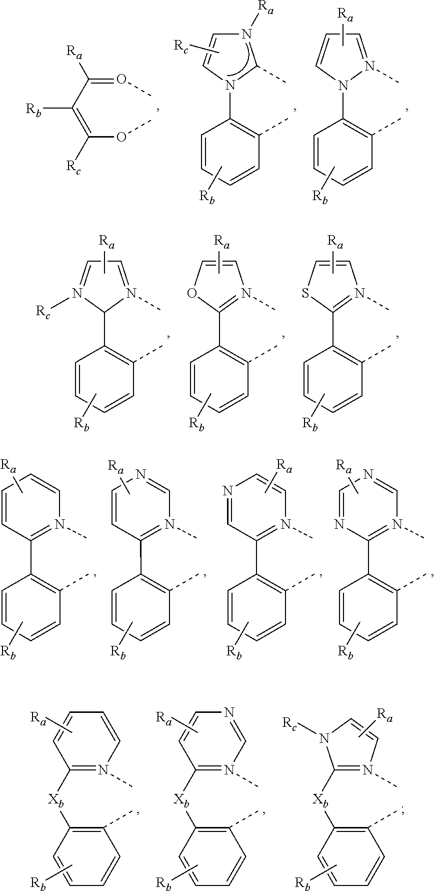

wherein Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ, R_{b}, R_{c}, R_{N1}, R_{C1}, and R_{C2} can be optionally joined to form a ring.

In this embodiment, the expression that adjacent substituents Rₐ, R_{b}, R_{C}, R_{N1}, R_{C1}, and R_{C2} can be optionally joined to form a ring is intended to mean that any one or more of groups of adjacent substituents in the structure of L_{c}, such as adjacent substituents Rₐ, adjacent substituents R_{b}, adjacent substituents R_{c}, adjacent substituents Rₐ and R_{b}, adjacent substituents R_{b} and R_{c}, adjacent substituents Rₐ and R_{c}, adjacent substituents Rₐ and R_{N1}, adjacent substituents Rₐ and R_{C1}, adjacent substituents Rₐ and R_{C2}, adjacent substituents R_{b} and R_{N1}, adjacent substituents R_{c} and R_{N1}, adjacent substituents R_{b} and R_{C1}, adjacent substituents R_{b} and R_{C2}, adjacent substituents R_{C} and R_{C1}, adjacent substituents R_{C} and R_{C2}, and adjacent substituents R_{C1} and R_{C2}, can be joined to form a ring. Obviously, it is also possible that none of these substituents are joined to form a ring.

According to an embodiment of the present disclosure, L_{c} is, at each occurrence identically or differently, selected from the group consisting of L_{c1} to L_{c329}. For the specific structures of L_{c1} to L_{c329}, see claim 14.

According to an embodiment of the present disclosure, hydrogen atoms in L_{c1} to L_{c329} can be partially or fully substituted with deuterium.

According to an embodiment of the present disclosure, the metal M is selected from Ir, Rh, Re, Os, Pt, Au, or Cu.

According to an embodiment of the present disclosure, the metal M is selected from Ir, Pt, or Os.

According to an embodiment of the present disclosure, the metal M is Ir.

According to an embodiment of the present disclosure, the metal complex has a general formula of Ir(Lₐ)ₘ(L_{b})₃₋ₘ and has a structure represented by Formula 22:

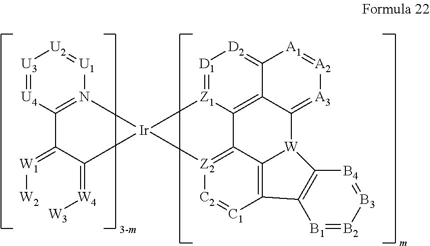

wherein m is 1 or 2;
Z₁ and Z₂ are each independently selected from C or N, and Z₁ is different from Z₂;
W is, at each occurrence identically or differently, selected from B, N, or P;
A₁ to A₃ are, at each occurrence identically or differently, selected from N or CR_{A};
B₁ to B₄ are, at each occurrence identically or differently, selected from N or CR_{B};
C₁ and C₂ are, at each occurrence identically or differently, selected from N or CR_{C};
D₁ and D₂ are, at each occurrence identically or differently, selected from N or CR_{D};
U₁ to U₄ are, at each occurrence identically or differently, selected from N or CR_{U};
W₁ to W₄ are, at each occurrence identically or differently, selected from N or CR_{W};
R_{A}, R_{B}, R_{C}, R_{D}, R_{U}, and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{A}, R_{B}, R_{C}, R_{D} can be optionally joined to form a ring; and
adjacent substituents R_{U}, R_{W} can be optionally joined to form a ring.

According to an embodiment of the present disclosure, in Formula 22, at least one of A₁ to A₃ is selected from CR_{A} and/or at least one of B₁ to B₄ is selected from CR_{B}, and the R_{A} and R_{B} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, hydroxyl, sulfanyl, and combinations thereof.

According to an embodiment of the present disclosure, in Formula 22, at least one of A₁ to A₃ is selected from CR_{A} and/or at least one of B₁ to B₄ is selected from CR_{B}, and the R_{A} and R_{B} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, and combinations thereof.

According to an embodiment of the present disclosure, A₂ is selected from CR_{A} and/or one of B₂ and B₃ is selected from CR_{B}, and the R_{A} and R_{B} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof.

According to an embodiment of the present disclosure, A₂ is selected from CR_{A} and/or one of B₂ and B₃ is selected from CR_{B}; and the R_{A} and R_{B} are, at each occurrence identically or differently, selected from the group consisting of: deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, sec-butyl, t-butyl, neopentyl, cyclopentyl, cyclopentylmethyl, cyclohexyl, norbornyl, adamantyl, trimethylsilyl, triethylsilyl, phenyldimethylsilyl, trimethylgermanyl, triethylgermanyl, phenyl, 2,6-dimethylphenyl, 2,6-diisopropylphenyl, pyridyl, pyrimidinyl, triazinyl, and combinations thereof.

According to an embodiment of the present disclosure, the metal complex has a structure of Ir(Lₐ)(L_{b})₂ or Ir(Lₐ)₂(L_{b}) or Ir(Lₐ)(L_{b})(L_{c});
wherein when the metal complex has a structure of Ir(Lₐ)(L_{b})₂, Lₐ is selected from any one of the group consisting of Lₐ₁ to Lₐ₁₈₂₀ and L_{b} is, at each occurrence identically or differently, selected from any one or two of the group consisting of L_{b1} to L_{b379}; when the metal complex has a structure of Ir(Lₐ)₂(L_{b}), Lₐ is, at each occurrence identically or differently, selected from any one or two of the group consisting of Lₐ₁ to Lₐ₁₈₂₀ and L_{b} is selected from any one of the group consisting of L_{b1} to L_{b379}; when the metal complex has a structure of Ir(Lₐ)(L_{b})(L_{c}), Lₐ is selected from any one of the group consisting of Lₐ₁ to Lₐ₁₈₂₀, L_{b} is selected from any one of the group consisting of L_{b1} to L_{b379}, and L_{c} is selected from any one of the group consisting of L_{c1} to L_{c329}; optionally, hydrogen atoms in the structure of the metal complex can be partially or fully substituted with deuterium.

According to an embodiment of the present disclosure, the metal complex has a structure of Ir(Lₐ)(L_{b})₂ or Ir(Lₐ)₂(L_{b}) or Ir(Lₐ)(L_{b})(L_{c});
wherein when the metal complex has a structure of Ir(Lₐ)(L_{b})₂, Lₐ is selected from any one of the group consisting of Lₐ₁ to Lₐ₁₈₅₆ and L_{b} is, at each occurrence identically or differently, selected from any one or two of the group consisting of L_{b1} to L_{b379}; when the metal complex has a structure of Ir(Lₐ)₂(L_{b}), Lₐ is, at each occurrence identically or differently, selected from any one or two of the group consisting of Lₐ₁ to Lₐ₁₈₅₆ and L_{b} is selected from any one of the group consisting of L_{b1} to L_{b379}; when the metal complex has a structure of Ir(Lₐ)(L_{b})(L_{c}), Lₐ is selected from any one of the group consisting of Lₐ₁ to Lₐ₁₈₅₆, L_{b} is selected from any one of the group consisting of L_{b1} to L_{b379}, and L_{c} is selected from any one of the group consisting of L_{c1} to L_{c329}; optionally, hydrogen atoms in the structure of the metal complex can be partially or fully substituted with deuterium.

According to an embodiment of the present disclosure, the metal complex is selected from the group consisting of Compound 1 to Compound 1826. For the specific structures of Compound 1 to Compound 1826, see claim 17.

According to an embodiment of the present disclosure, the metal complex is selected from the group consisting of Compound 1 to Compound 1856. For the specific structures of Compound 1 to Compound 1826, see claim 17. Compound 1827 to Compound 1856 each have a structure of Ir(Lₐ)(L_{b})₂, wherein the two L_{b} are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 1827 | Lₐ₅₁₄ | L_{b2} | 1828 | Lₐ₅₁₄ | L_{b4} |
| 1829 | Lₐ₅₁₄ | L_{b81} | 1830 | Lₐ₅₁₄ | L_{b329} |
| 1831 | Lₐ₅₁₄ | L_{b330} | 1832 | Lₐ₅₁₄ | L_{b333} |
| 1833 | Lₐ₁₇₉₆ | L_{b2} | 1834 | Lₐ₁₇₉₆ | L_{b4} |
| 1835 | Lₐ₁₇₉₆ | L_{b81} | 1836 | Lₐ₁₇₉₆ | L_{b329} |
| 1837 | Lₐ₁₇₉₆ | L_{b330} | 1838 | Lₐ₁₇₉₆ | L_{b333} |
| 1839 | Lₐ₁₈₄₂ | L_{b2} | 1840 | Lₐ₁₈₄₂ | L_{b4} |
| 1841 | Lₐ₁₈₄₂ | L_{b81} | 1842 | Lₐ₁₈₄₂ | L_{b329} |
| 1843 | Lₐ₁₈₄₂ | L_{b330} | 1844 | Lₐ₁₈₄₂ | L_{b333} |
| 1845 | Lₐ₁₈₄₆ | L_{b2} | 1846 | Lₐ₁₈₄₆ | L_{b4} |
| 1847 | Lₐ₁₈₄₆ | L_{b81} | 1848 | Lₐ₁₈₄₆ | L_{b329} |
| 1849 | Lₐ₁₈₄₆ | L_{b330} | 1850 | Lₐ₁₈₄₆ | L_{b333} |
| 1851 | Lₐ₁₈₅₂ | L_{b2} | 1852 | Lₐ₁₈₅₂ | L_{b4} |
| 1853 | Lₐ₁₈₅₂ | L_{b81} | 1854 | Lₐ₁₈₅₂ | L_{b329} |
| 1855 | Lₐ₁₈₅₂ | L_{b330} | 1856 | Lₐ₁₈₅₂ | L_{b333}. |

According to an embodiment of the present disclosure, hydrogen atoms in the structures of Compound 1 to Compound 1826 can be partially or fully substituted with deuterium.

According to an embodiment of the present disclosure, hydrogen atoms in the structures of Compound 1 to Compound 1856 can be partially or fully substituted with deuterium.

According to an embodiment of the present disclosure, further disclosed is an electroluminescent device comprising:
an anode,
a cathode, and
an organic layer disposed between the anode and the cathode, wherein the organic layer comprises a metal complex whose specific structure is shown in any one of the preceding embodiments.

According to an embodiment of the present disclosure, in the device, the organic layer is an emissive layer, and the compound is an emissive material.

According to an embodiment of the present disclosure, the electroluminescent device emits red light.

According to an embodiment of the present disclosure, the electroluminescent device emits white light.

According to an embodiment of the present disclosure, in the device, the emissive layer further comprises at least one host material.

According to an embodiment of the present disclosure, in the device, the at least one host material comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, in the device, the at least one host material may be a conventional host material in the related art. For example, the host material may typically include the following host materials without limitation:

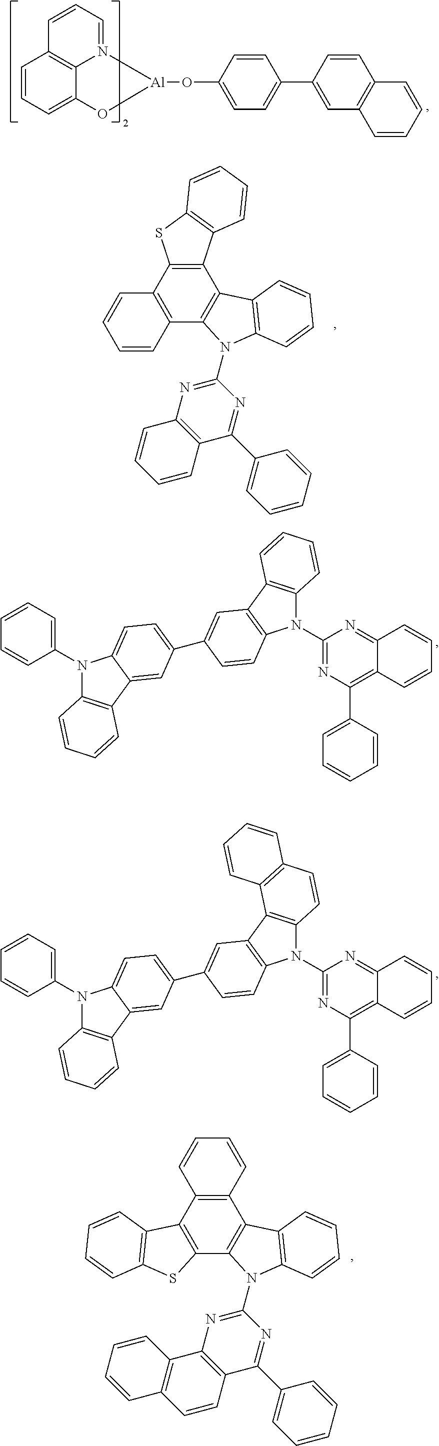

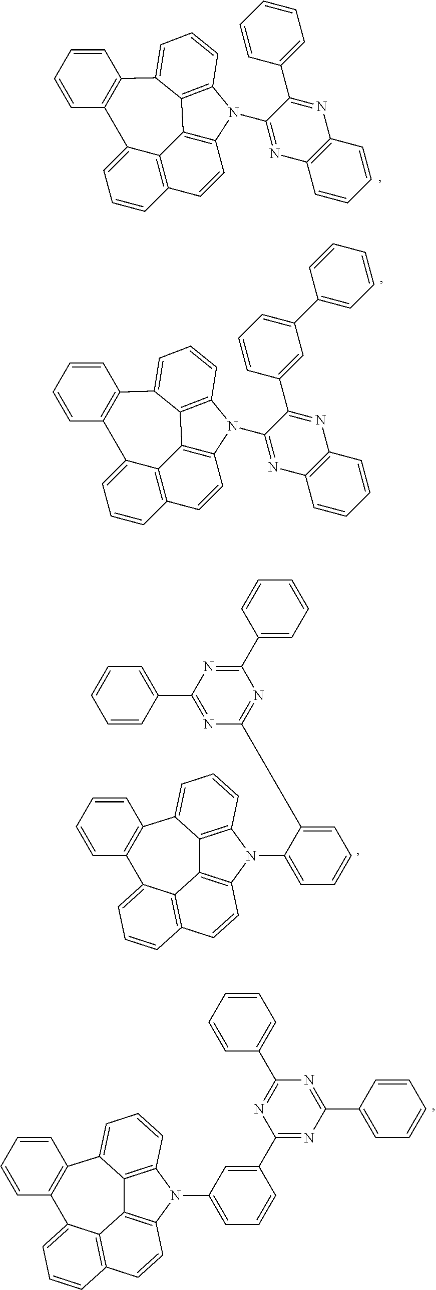

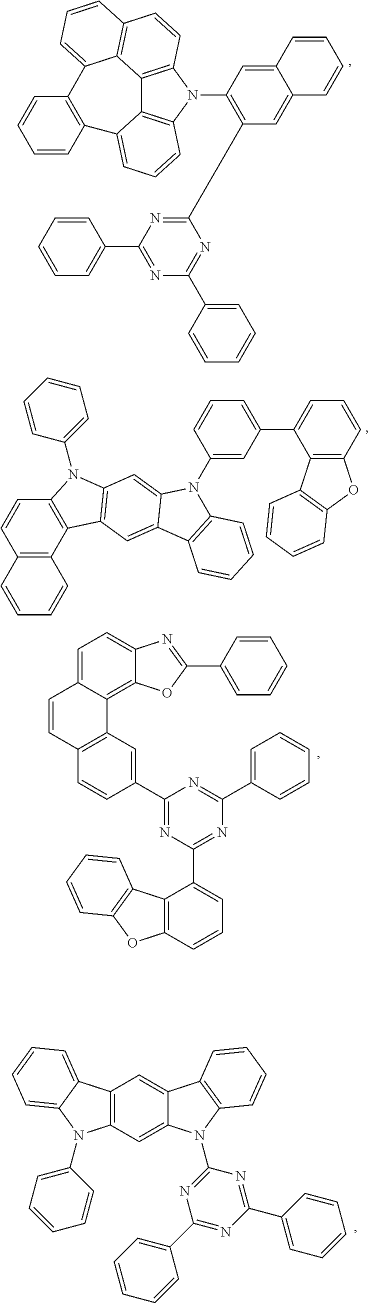

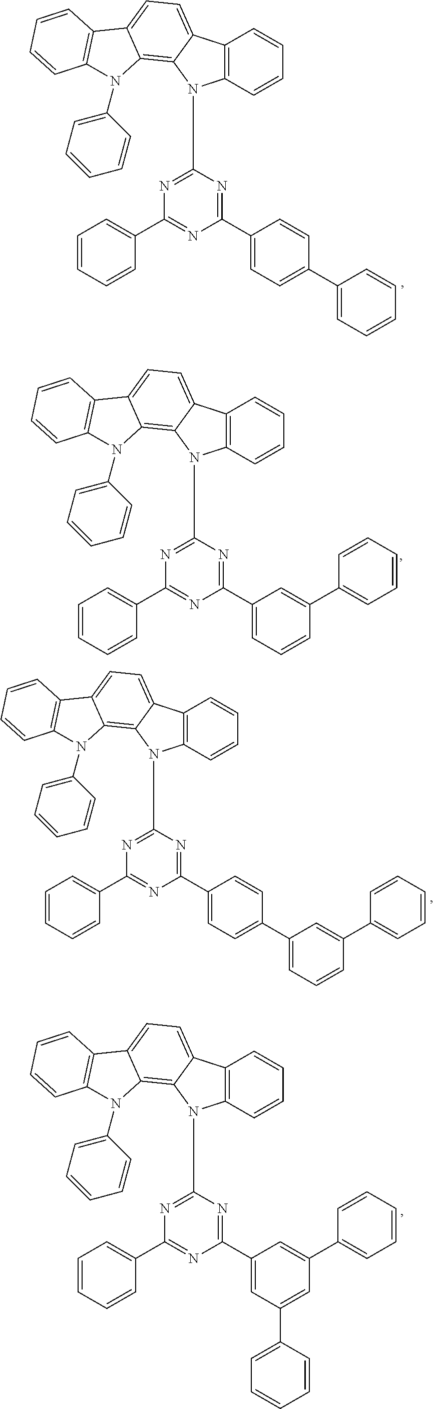

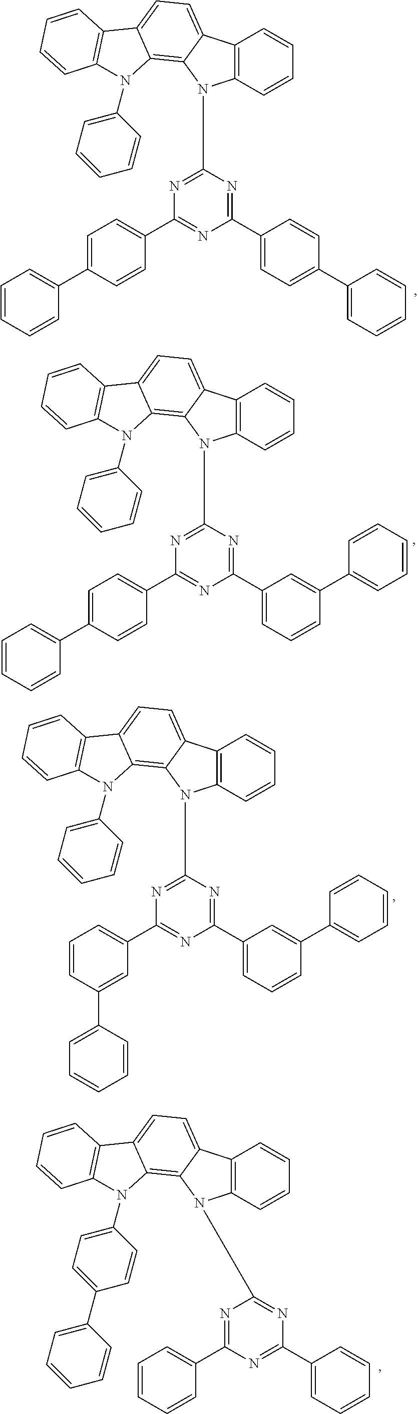

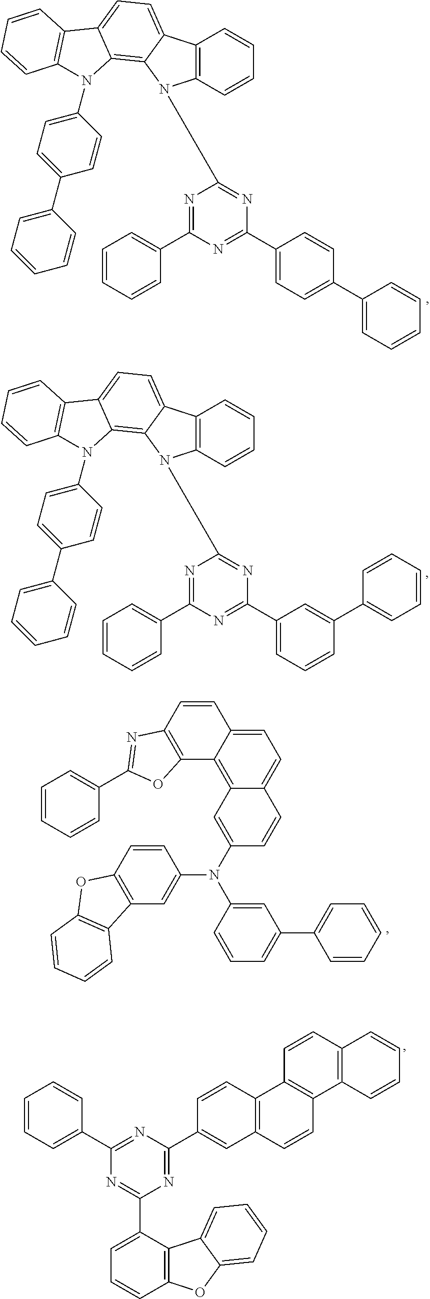 [SMILES: c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2ccc(-n3c4ccccc4c4ccc5c6ccccc6n(-c6nc(-c7ccccc7)nc(-c7cccc(-c8ccccc8)c7)n6)c5c43)cc2)cc1 ; c1ccc(-c2cccc(N(c3ccc4oc5ccccc5c4c3)c3ccc4ccc5ccc6nc(-c7ccccc7)oc6c5c4c3)c2)cc1 ; c1ccc(-c2nc(-c3ccc4c(ccc5c6ccccc6ccc45)c3)nc(-c3cccc4oc5ccccc5c34)n2)cc1]

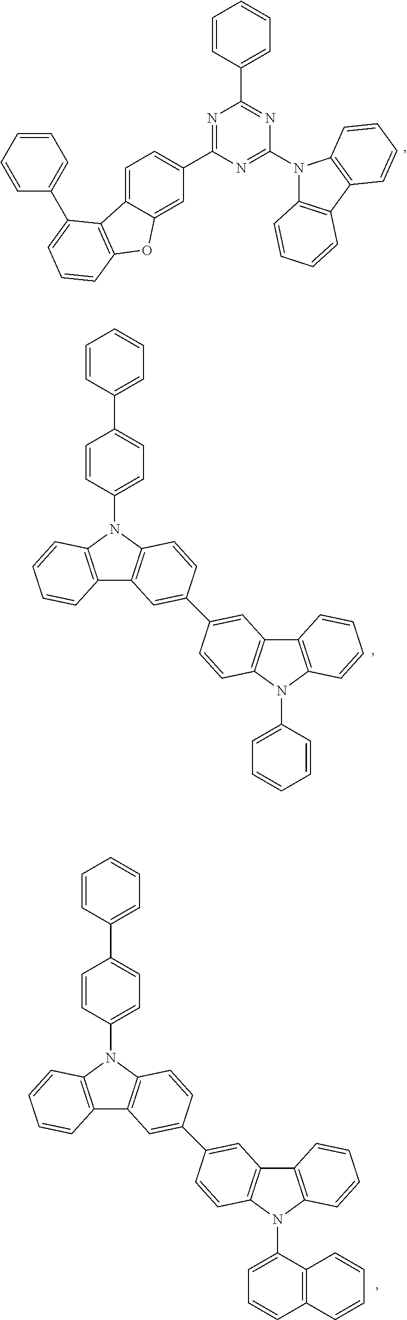 [SMILES: c1ccc(-c2nc(-c3ccc4c(c3)oc3cccc(-c5ccccc5)c34)nc(-n3c4ccccc4c4ccccc43)n2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc6ccccc56)ccc43)cc2)cc1]

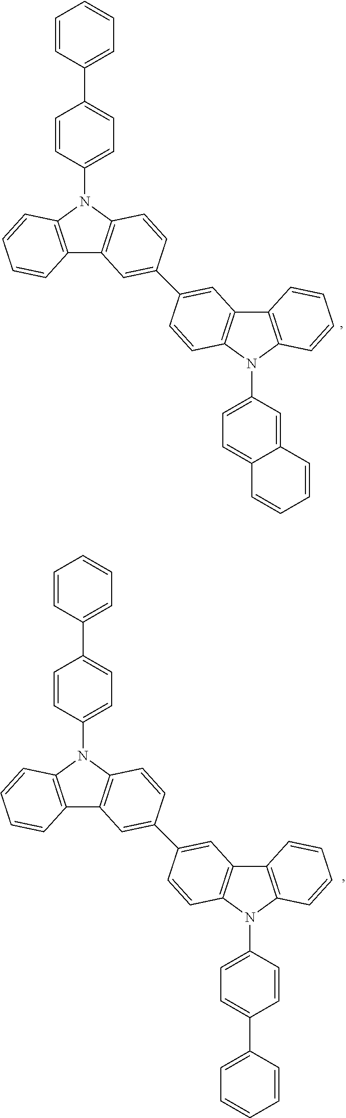 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

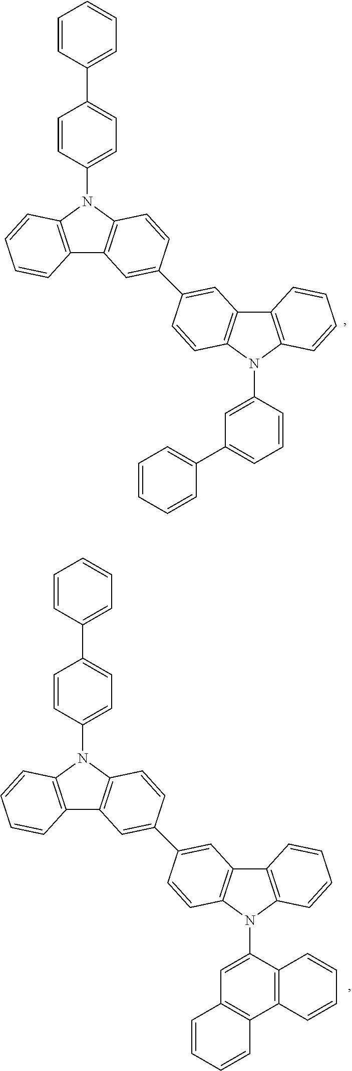 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5cc6ccccc6c6ccccc56)ccc43)cc2)cc1]

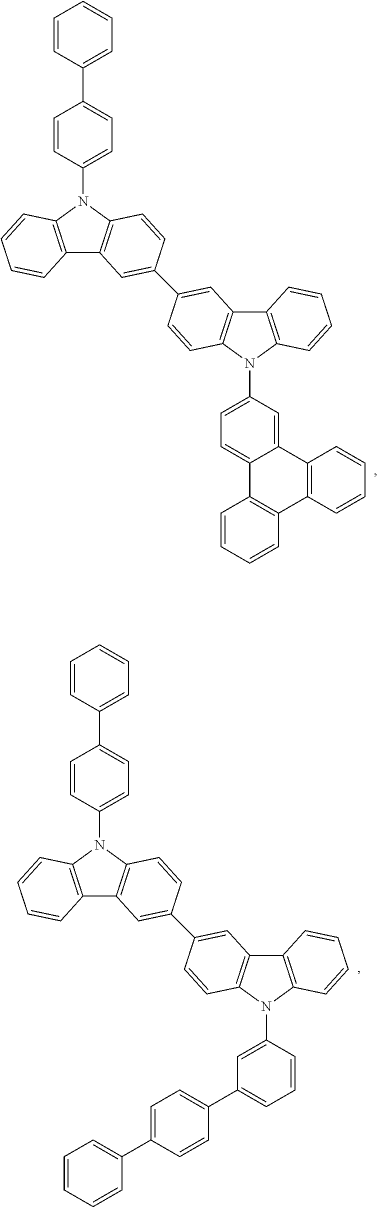 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1 ; c1ccc(-c2ccc(-c3cccc(-n4c5ccccc5c5cc(-c6ccc7c(c6)c6ccccc6n7-c6ccc(-c7ccccc7)cc6)ccc54)c3)cc2)cc1]

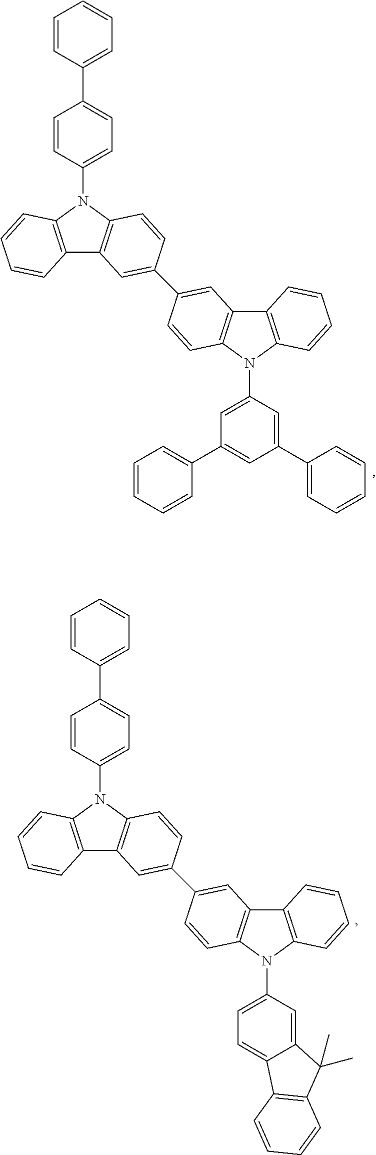 [SMILES: c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1 ; CC1(C)c2ccccc2-c2ccc(-n3c4ccccc4c4cc(-c5ccc6c(c5)c5ccccc5n6-c5ccc(-c6ccccc6)cc5)ccc43)cc21]

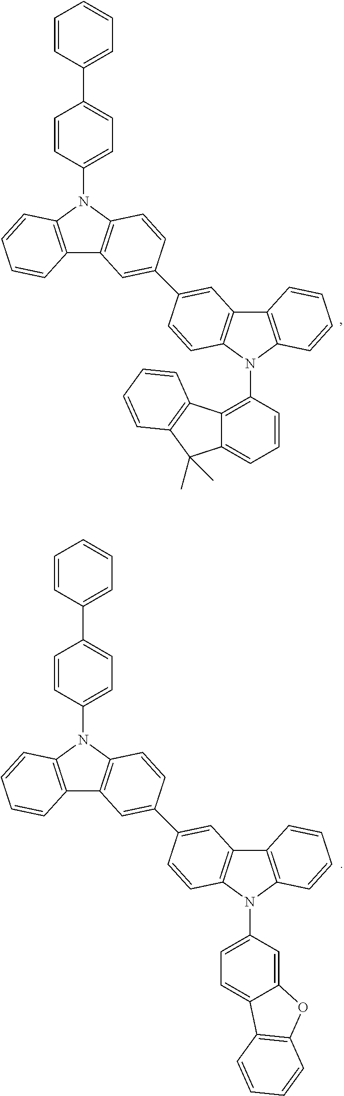 [SMILES: CC1(C)c2ccccc2-c2c(-n3c4ccccc4c4cc(-c5ccc6c(c5)c5ccccc5n6-c5ccc(-c6ccccc6)cc5)ccc43)cccc21 ; c1ccc(-c2ccc(-n3c4ccccc4c4cc(-c5ccc6c(c5)c5ccccc5n6-c5ccc6c(c5)oc5ccccc56)ccc43)cc2)cc1]

According to another embodiment of the present disclosure, further disclosed is a compound composition comprising a metal complex whose specific structure is shown in any one of the preceding embodiments.

Combination with Other Materials

The materials described in the present disclosure for a particular layer in an organic light emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, materials disclosed herein may be used in combination with a wide variety of dopants, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### Material Synthesis Example

The method for preparing a compound of the present disclosure is not limited herein. Typically, the following compounds are used as examples without limitation, and synthesis routes and preparation methods thereof are described below.

### Synthesis Example 1: Synthesis of Compound 263

Step 1: Synthesis of Intermediate 3

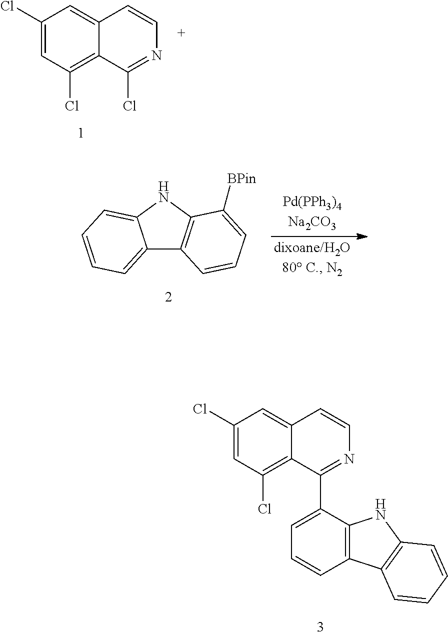

Intermediate 1 (4.3 g, 14.2 mmol), Intermediate 2 (3.3 g, 14.2 mmol), Pd(PPh₃)₄ (809 mg, 0.7 mmol), and Na₂CO₃ (2.3 g, 21.3 mmol) were mixed in 1,4-dioxane/H₂O (56 mL/14 mL), purged with nitrogen, and reacted overnight at 80° C. After the reaction was completed as detected through TLC, the reaction system was cooled to room temperature, diluted with ethyl acetate, and extracted. The organic phases were concentrated and purified through column chromatography to obtain Intermediate 3 (3.4 g).

Step 2: Synthesis of Intermediate 4

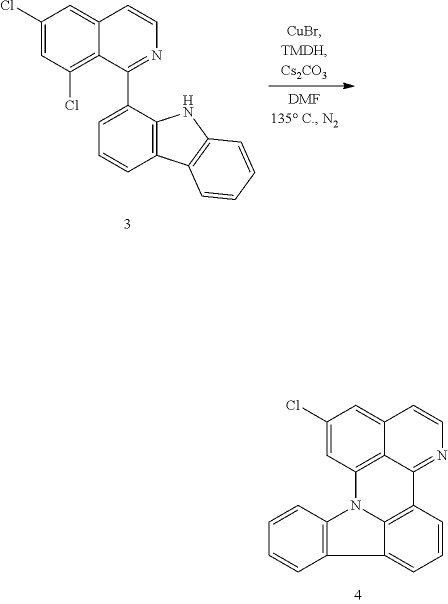 [SMILES: Clc1cc(Cl)c2c(-c3cccc4c3[nH]c3ccccc34)nccc2c1 ; Clc1cc2ccnc3c4cccc5c6ccccc6n(c(c1)c23)c54]

Intermediate 3 (3.4 g, 9 mmol), CuBr (129 mg, 0.9 mmol), 2,2,6,6-tetramethyl-3,5-heptanedione (TMDH) (1.33 g, 7.2 mmol), and Cs₂CO₃ (7.33 g, 22.5 mmol) were mixed in DMF (90 mL), purged with nitrogen, reacted at 135° C. for 5 h, cooled to room temperature, and added with water to precipitate the product. The product was filtered, and the filter cake was washed with an appropriate amount of water and PE, dried, refluxed in EtOH for 3 h, and filtered to obtain Intermediate 4 (2.6 g).

Step 3: Synthesis of Intermediate A

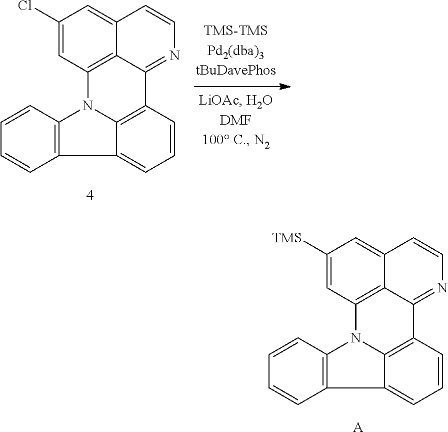

Intermediate 4 (2.6 g, 7.63 mmol), Pd₂(dba)₃ (137.4 mg, 0.15 mmol), tBuDavePhos (307.3 mg, 0.9 mmol, 6 mol %), and LiOAc (2.52 g, 38.2 mmol) were mixed in DMF (24 mL), purged with nitrogen, added with TMS-TMS (2.22 g, 15.2 mmol) and H₂O (275 mg, 15.3 mmol), and reacted overnight at 100° C. The reaction solution was cooled, added with water, and extracted with EA. The organic phases were collected and concentrated, and the residue was purified through column chromatography to obtain Intermediate A (2.4 g).

Step 4: Synthesis of Compound 263

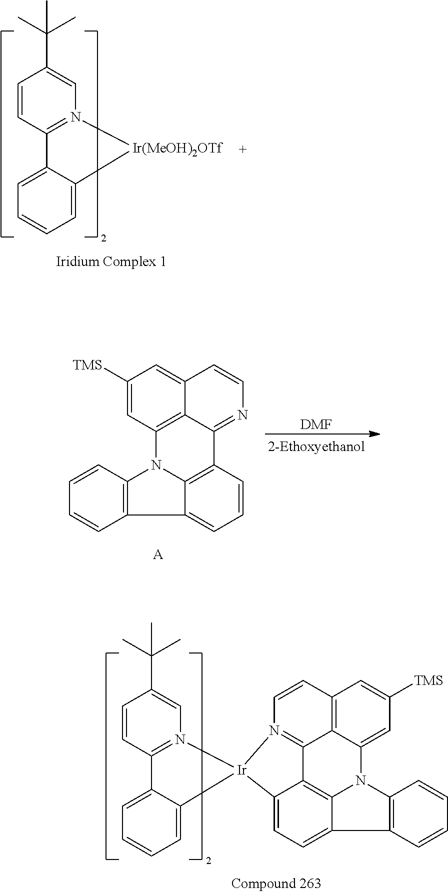

Iridium Complex 1 (3.0 g, 3.7 mmol) and Intermediate A (900 mg, 2.5 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 1 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 263 (300 mg with a yield of 12.3%). The product was confirmed as the target product with a molecular weight of 976.4.

### Synthesis Example 2: Synthesis of Compound 1524

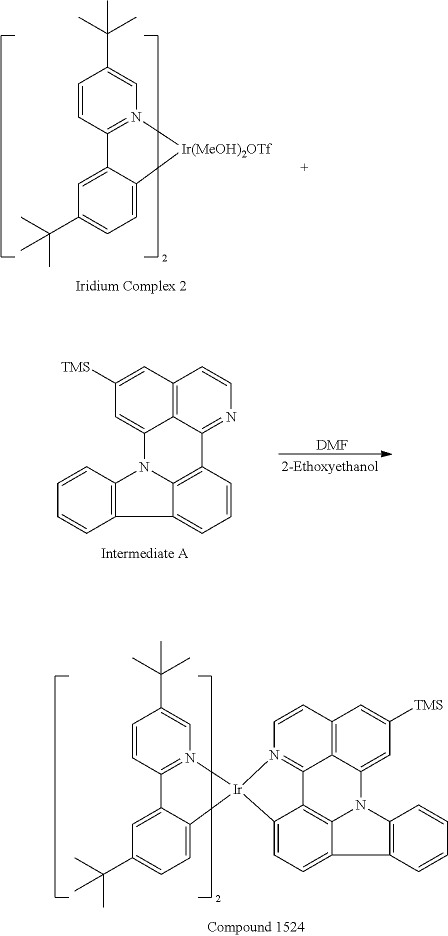

Iridium Complex 2 (3.5 g, 3.7 mmol) and Intermediate A (900 mg, 2.5 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 2 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 1524 (200 mg with a yield of 7.3%). The product was confirmed as the target product with a molecular weight of 1088.5.

### Synthesis Example 3: Synthesis of Compound 1272

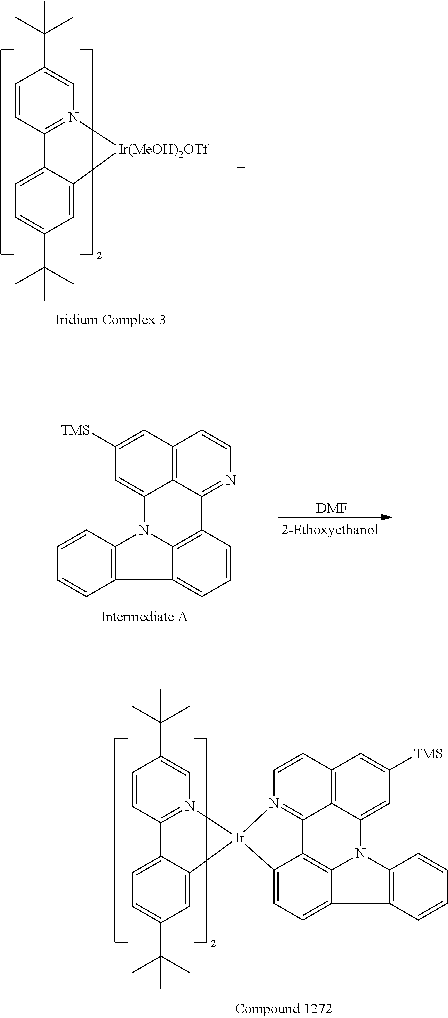

Iridium Complex 3 (3.5 g, 3.7 mmol) and Intermediate A (900 mg, 2.5 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 3 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 1272 (250 mg with a yield of 9.2%). The product was confirmed as the target product with a molecular weight of 1088.5.

### Synthesis Example 4: Synthesis of Compound 257

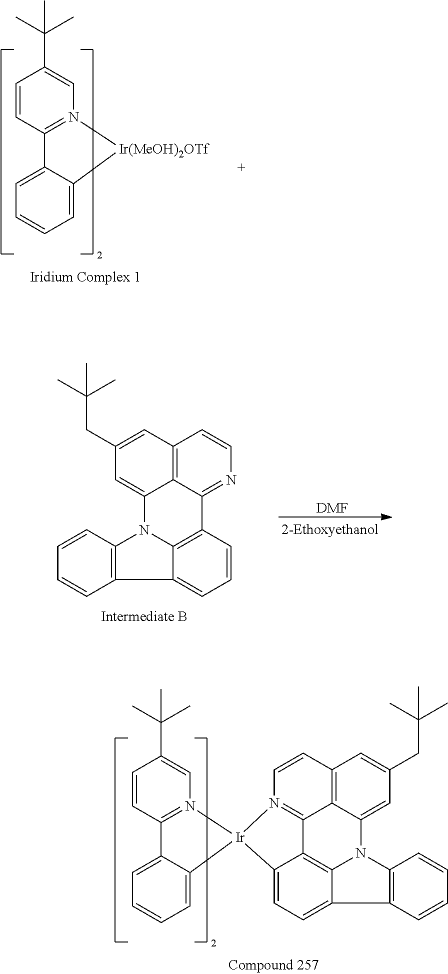

Iridium Complex 1 (2.3 g, 2.8 mmol) and Intermediate B (700 mg, 1.9 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 1 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 257 (200 mg with a yield of 10.8%). The product was confirmed as the target product with a molecular weight of 974.4.

### Synthesis Example 5: Synthesis of Compound 5

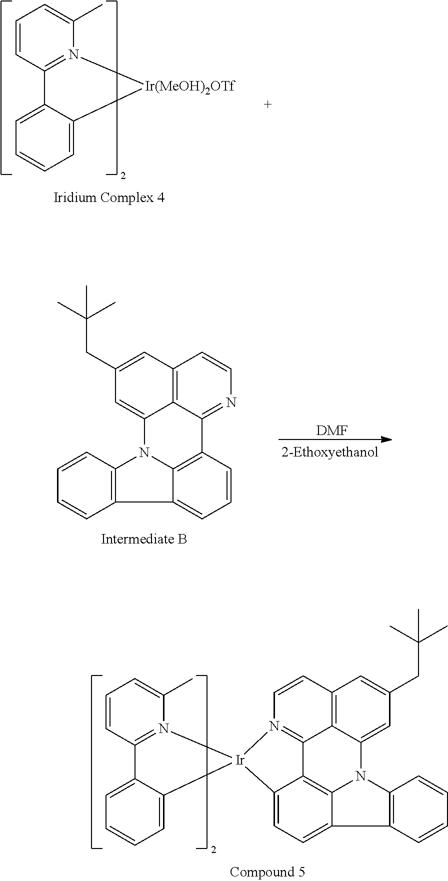

Iridium Complex 4 (2.0 g, 2.8 mmol) and Intermediate B (700 mg, 1.9 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 4 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 5 (300 mg with a yield of 17.7%). The product was confirmed as the target product with a molecular weight of 890.3.

### Synthesis Example 6: Synthesis of Compound 367

Step 1: Synthesis of Intermediate 7

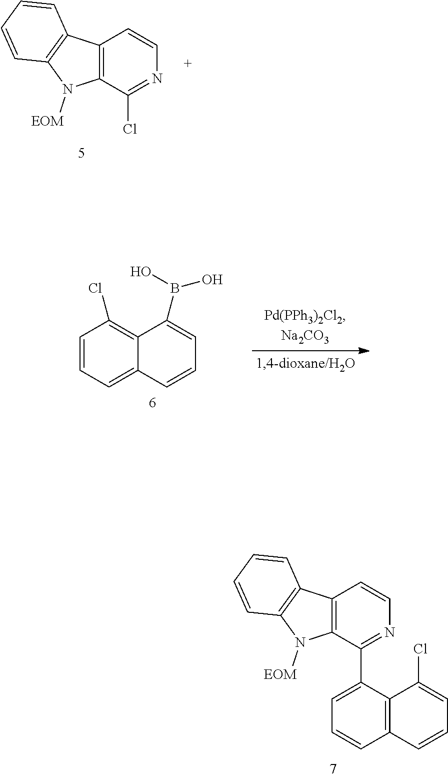

Intermediate 5 (1-chloro-9-(ethoxymethoxy)-9H-pyrido[3,4-b]indole, 2.19 g, 8.4 mmol), Intermediate 6 (1.9 g, 9.2 mmol), Pd(PPh₃)₂Cl₂ (295 mg, 0.42 mmol), and sodium carbonate (1.34 g, 12.6 mmol) were mixed in 1,4-dioxane/water (32 mL/8 mL) and reacted overnight at 85° C. under nitrogen protection. After the reaction was completed as detected through TLC, the reaction system was cooled to room temperature, diluted with ethyl acetate, and extracted with water. The organic phases were collected, concentrated, purified through column chromatography, and eluted with petroleum ether:ethyl acetate (4:1, v/v) to obtain Intermediate 7 (1.55 g with a yield of 56.4%).

Step 2: Synthesis of Intermediate 8

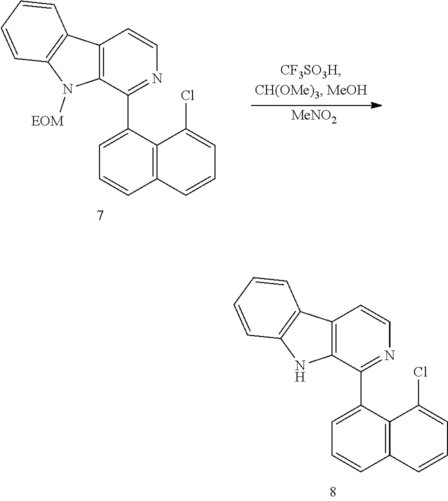

Intermediate 7 (1.55 g, 4 mmol), trimethyl orthoformate (4.25 g, 40 mmol), and methanol (1.28 g, 40 mmol) were mixed in nitromethane (20 mL) and cooled at 0° C. Trifluoromethanesulfonic acid (1.8 g, 12 mmol) was added dropwise and reacted at 100° C. After the reaction was completed as detected through TLC, the reaction system was cooled to room temperature, diluted with ethyl acetate, extracted, washed with saturated brine, and dried over anhydrous sodium sulfate to obtain Intermediate 8, which was directly used in the next step without further purification.

Step 3: Synthesis of Intermediate C

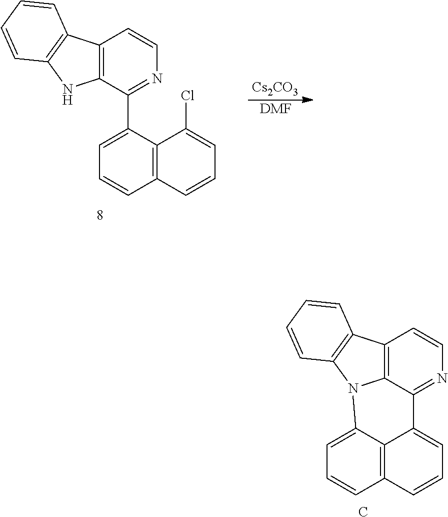

Intermediate 8 and cesium carbonate (2.44 g, 7.5 mmol) were mixed in DMF (30 mL), purged with nitrogen, and reacted at 135° C. for 1 h. After the reaction was completed as detected through TLC, the reaction system was cooled to room temperature, added with water to precipitate the product, filtered, and dried. The crude product was refluxed in petroleum ether (20 mL) for 1 h and filtered to obtain Intermediate C (530 mg with a yield of 45.4%).

Step 4: Synthesis of Compound 367

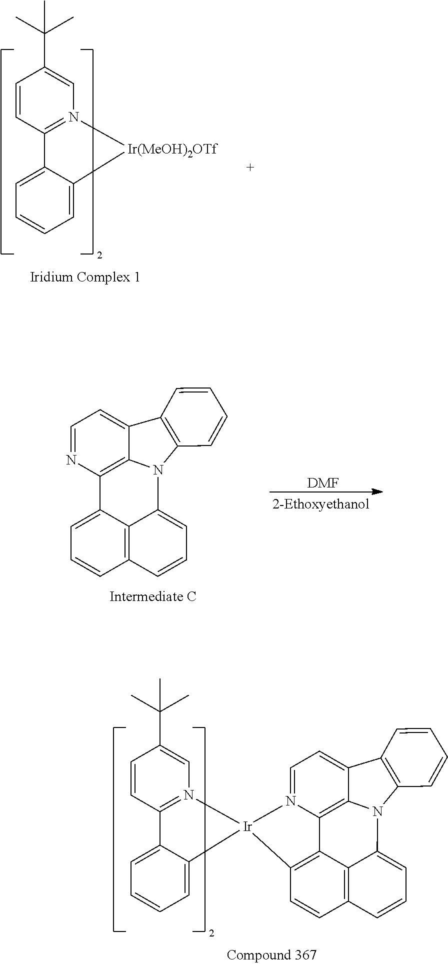

Iridium Complex 1 (250 mg, 0.4 mmol) and Intermediate C (100 mg, 0.3 mmol) were added to a 100 mL three-necked flask and added with a mixed solvent of ethoxyethanol (10 mL) and N,N-dimethylformamide (10 mL). Under nitrogen protection, the reaction system was heated to 100° C. and reacted for 120 h. After Iridium Complex 1 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 367 (25 mg with a yield of 9%). The product was confirmed as the target product with a molecular weight of 904.3.

### Synthesis Example 7: Synthesis of Compound 375

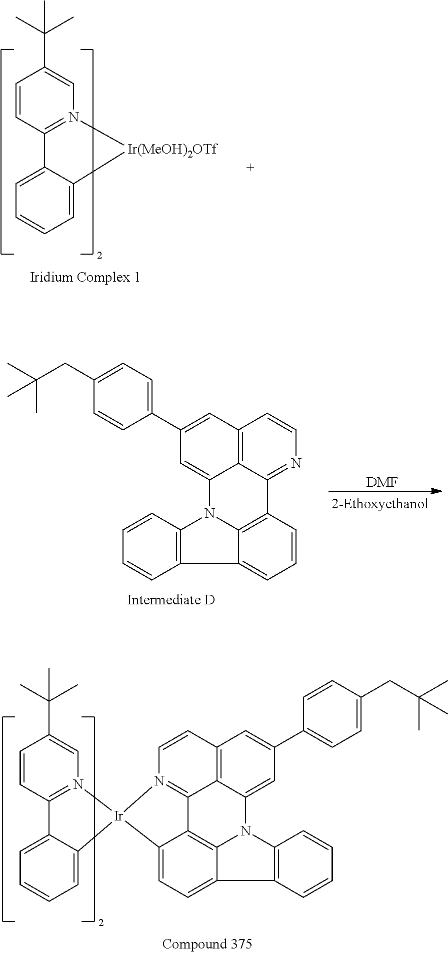

Iridium Complex 1 (2.3 g, 2.8 mmol) and Intermediate D (850 mg, 1.9 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 1 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 375 (300 mg with a yield of 15.0%). The product was confirmed as the target product with a molecular weight of 1050.4.

### Synthesis Example 8: Synthesis of Compound 1636

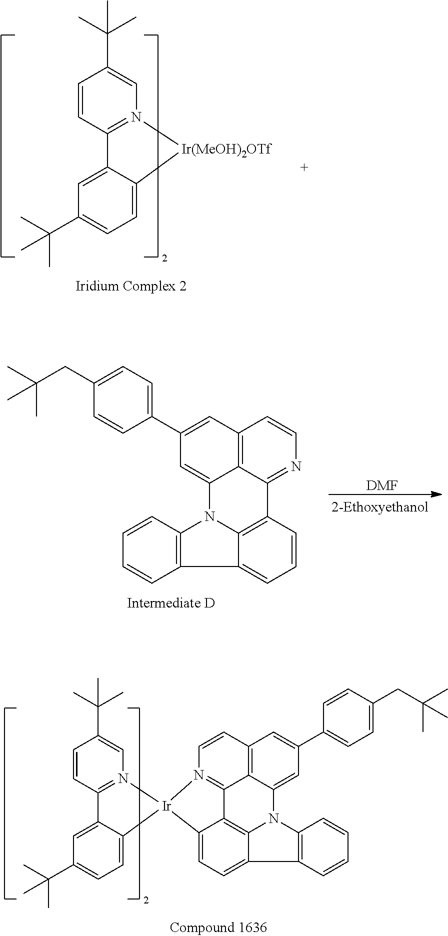

Iridium Complex 2 (3.5 g, 3.7 mmol) and Intermediate D (1100 mg, 2.5 mmol) were added to a 100 mL three-necked flask and added with a mixed solvent of ethoxyethanol (25 mL) and N,N-dimethylformamide (25 mL). Under nitrogen protection, the reaction system was heated to 100° C. and reacted for 120 h. After Iridium Complex 2 disappeared as displayed through TLC, the reaction system was cooled to room temperature. The solvent was removed through rotary evaporation, and the residue was purified through column chromatography and eluted with petroleum ether:dichloromethane (2:1, v/v) to obtain Compound 1636 (300 mg with a yield of 10.3%). The product was confirmed as the target product with a molecular weight of 1162.5.

### Synthesis Example 9: Synthesis of Compound 1829

Step 1: Synthesis of Intermediate 10

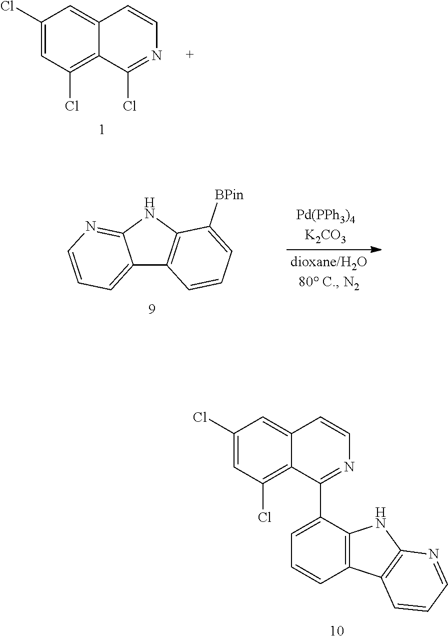

Intermediate 1 (1.6 g, 6.8 mmol), Intermediate 9 (2.0 g, 6.8 mmol), Pd(PPh₃)₄ (690 mg, 0.6 mmol), and K₂CO₃ (1.9 g, 13.8 mmol) were mixed in 1,4-dioxane/H₂O (56 mL/14 mL), purged with nitrogen, and reacted overnight at 80° C. After the reaction was completed as detected through TLC, the reaction system was cooled to room temperature, diluted with ethyl acetate, and extracted. The organic phases were concentrated and purified through column chromatography to obtain Intermediate 10 (1.5 g with a yield of 60.8%).

Step 2: Synthesis of Intermediate 11

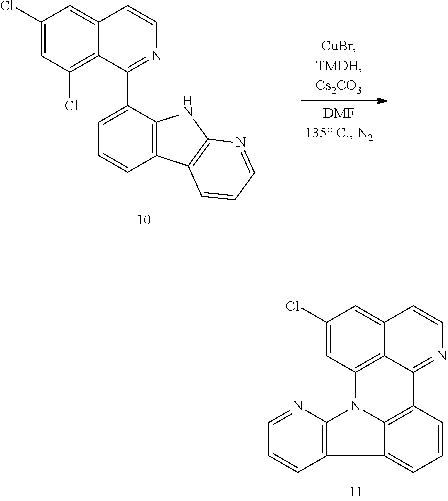 [SMILES: Clc1cc(Cl)c2c(-c3cccc4c3[nH]c3ncccc34)nccc2c1 ; Clc1cc2ccnc3c4cccc5c6cccnc6n(c(c1)c23)c54]

Intermediate 10 (1.5 g, 4.0 mmol), CuBr (57 mg, 0.4 mmol), 2,2,6,6-tetramethyl-3,5-heptanedione (TMDH) (0.59 g, 3.2 mmol), and Cs₂CO₃ (3.25 g, 10.0 mmol) were mixed in DMF (90 mL), purged with nitrogen, reacted at 135° C. for 5 h, cooled to room temperature, and added with water to precipitate the product. The product was filtered, and the filter cake was washed with an appropriate amount of water and PE, dried, refluxed in EtOH for 3 h, and filtered to obtain Intermediate 11 (1.0 g with a yield of 76.4%).

Step 3: Synthesis of Intermediate E

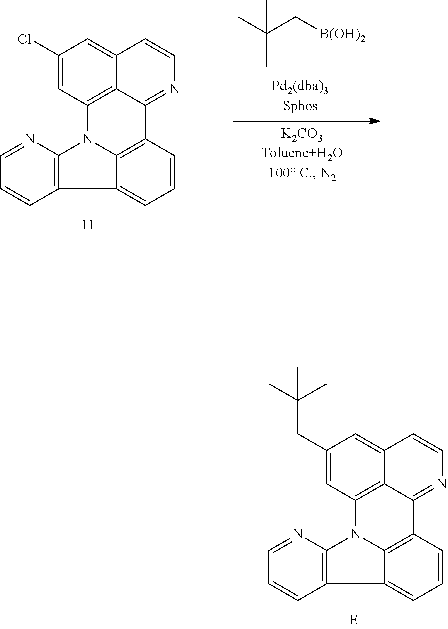

Intermediate 11 (1.0 g, 3.1 mmol), Pd₂(dba)₃ (142 mg, 0.16 mmol), Sphos (123 mg, 0.3 mmol), and potassium carbonate (855 mg, 6.2 mmol) were mixed in a mixed solution of toluene and water (10 mL+2 mL), purged with nitrogen, added with neopentylboronic acid (720 mg, 6.2 mmol), and reacted overnight at 100° C. The reaction solution was cooled, added with water, and extracted with EA. The organic phases were collected and concentrated, and the residue was purified through column chromatography to obtain Intermediate E (0.9 g with a yield of 79%).

Step 4: Synthesis of Compound 1829

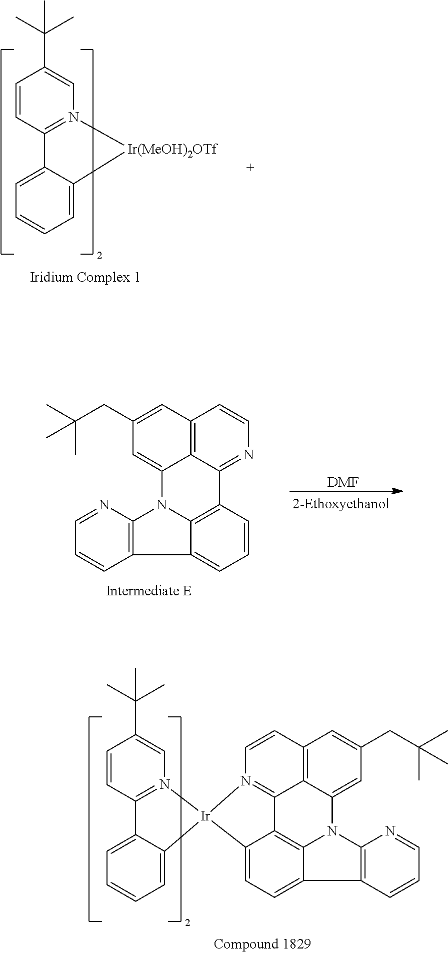

Iridium Complex 1 (660 mg, 0.8 mmol) and Intermediate E (360 mg, 1.0 mmol) were added to a 100 mL three-necked flask and added with a mixed solvent of ethoxyethanol (5 mL) and N,N-dimethylformamide (5 mL). Under nitrogen protection, the reaction system was heated to 100° C., reacted for 120 h, and cooled to room temperature. The solvent was removed through rotary evaporation, and the residue was purified through column chromatography and eluted with petroleum ether:dichloromethane (2:1, v/v) to obtain Compound 1829 (100 mg with a yield of 12.8%). The product was confirmed as the target product with a molecular weight of 975.4.

### Synthesis Example 10: Synthesis of Compound 1847

Step 1: Synthesis of Intermediate 12

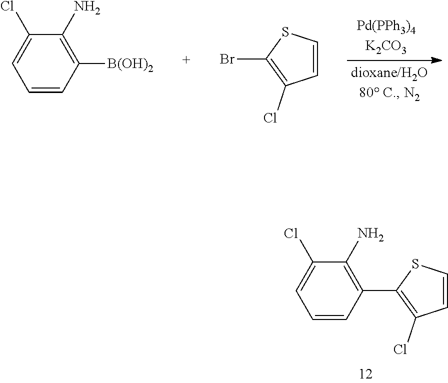 [SMILES: Nc1c(Cl)cccc1B(O)O ; Clc1ccsc1Br ; Nc1c(Cl)cccc1-c1sccc1Cl]

2-Amino-3-chlorophenylboronic acid (12.4 g, 50.8 mmol), 2-bromo-3-chlorothiophene (10 g, 50.8 mmol), Pd(PPh₃)₄ (1.2 g, 1.0 mmol), and K₂CO₃ (14.0 g, 101.5 mmol) were mixed in 1,4-dioxane/H₂O (560 mL/140 mL), purged with nitrogen, and reacted overnight at 80° C. After the reaction was completed as detected through TLC, the reaction system was cooled to room temperature, diluted with ethyl acetate, and extracted. The organic phases were concentrated and purified through column chromatography to obtain Intermediate 12 (9.3 g with a yield of 75.3%).

Step 2: Synthesis of Intermediate 13

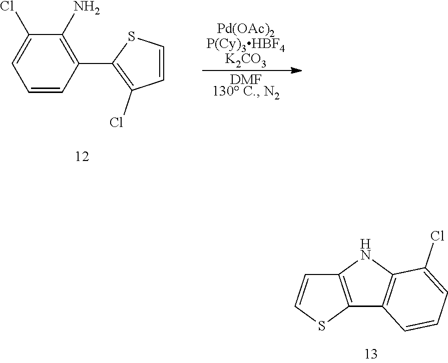 [SMILES: Nc1c(Cl)cccc1-c1sccc1Cl ; "DMF130° C., N2" ; "Pd(OAc)2P(Cy)3·HBF4K2CO3" ; Clc1cccc2c1[nH]c1ccsc12]

Intermediate 12 (9.3 g, 38.3 mmol), Pd(OAc)₂ (342 mg, 1.52 mmol), tricyclohexylphosphine tetrafluoroborate (1.1 g, 3.04 mmol), and K₂CO₃ (10.5 g, 76 mmol) were mixed in DMF (70 mL), purged with nitrogen, and reacted overnight at 130° C. After the reaction was completed as detected through TLC, the reaction system was cooled to room temperature, diluted with ethyl acetate, and extracted. The organic phases were concentrated and purified through column chromatography to obtain Intermediate 13 (3.2 g with a yield of 34.5%).

Step 3: Synthesis of Intermediate 14

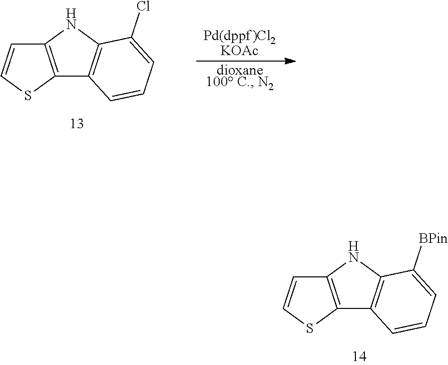

Intermediate 13 (3.2 g, 13.2 mmol), B₂Pin₂ (5.0 g, 19.7 mmol), Pd(dppf)Cl₂ (942 mg, 1.3 mmol), and KOAc (2.5 g, 26 mmol) were mixed in 1,4-dioxane (90 mL), purged with nitrogen, and reacted overnight at 100° C. After the reaction was completed as detected through TLC, the reaction system was cooled to room temperature, diluted with ethyl acetate, and extracted. The organic phases were concentrated and purified through column chromatography to obtain Intermediate 14 (2.0 g with a yield of 51.5%).

Step 4: Synthesis of Intermediate 15

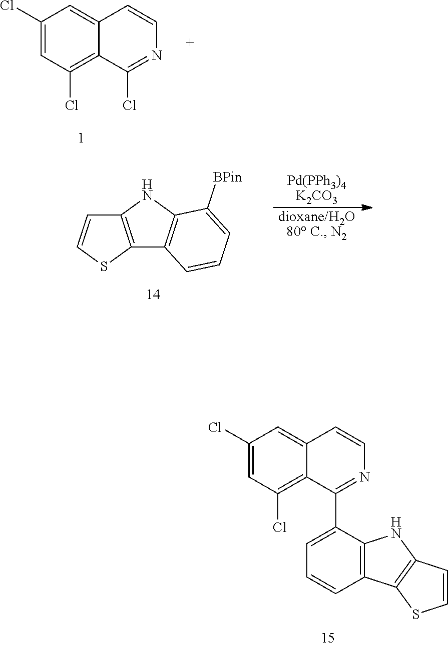

Intermediate 1 (1.6 g, 6.8 mmol), Intermediate 14 (2.0 g, 6.8 mmol), Pd(PPh₃)₄ (690 mg, 0.6 mmol), and K₂CO₃ (1.9 g, 13.8 mmol) were mixed in 1,4-dioxane/H₂O (56 mL/14 mL), purged with nitrogen, and reacted overnight at 80° C. After the reaction was completed as detected through TLC, the reaction system was cooled to room temperature, diluted with ethyl acetate, and extracted. The organic phases were concentrated and purified through column chromatography to obtain Intermediate 15 (1.2 g with a yield of 47.8%).

Step 5: Synthesis of Intermediate 16

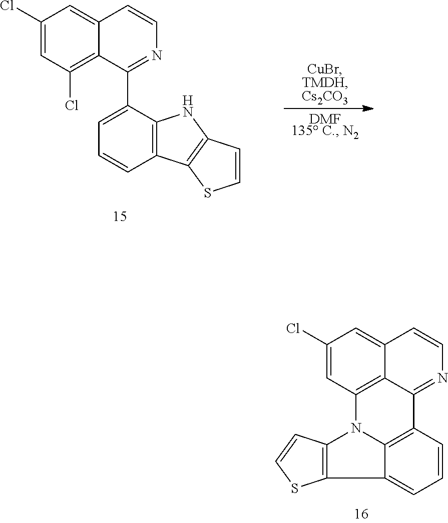

Intermediate 15 (1.0 g, 2.7 mmol), CuBr (43 mg, 0.3 mmol), 2,2,6,6-tetramethyl-3,5-heptanedione (TMDH) (0.55 g, 3.0 mmol), and Cs₂CO₃ (2.0 g, 6.0 mmol) were mixed in DMF (20 mL), purged with nitrogen, reacted at 135° C. for 5 h, cooled to room temperature, and added with water to precipitate the product. The product was filtered, and the filter cake was washed with an appropriate amount of water and PE, dried, refluxed in EtOH for 3 h, and filtered to obtain Intermediate 16 (780 mg with a yield of 87%).

Step 6: Synthesis of Intermediate F

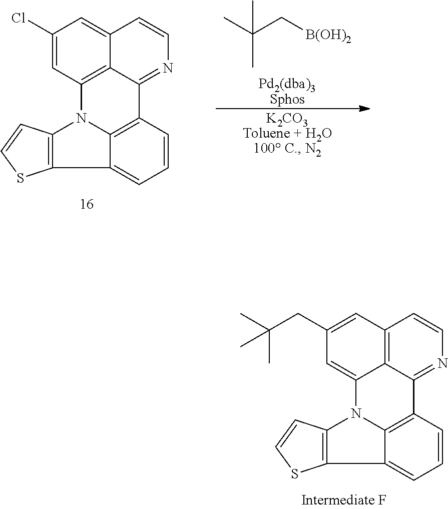

Intermediate 16 (780 mg, 2.3 mmol), Pd₂(dba)₃ (110 mg, 0.12 mmol), Sphos (98 mg, 0.24 mmol), and potassium carbonate (640 mg, 4.6 mmol) were mixed in a mixed solution of toluene and water (10 mL+2 mL), purged with nitrogen, added with neopentylboronic acid (540 mg, 4.6 mmol), and reacted overnight at 100° C. The reaction solution was cooled, added with water, and extracted with EA. The organic phases were collected and concentrated, and the residue was purified through column chromatography to obtain Intermediate F (600 mg with a yield of 70%).

Step 7: Synthesis of Compound 1847

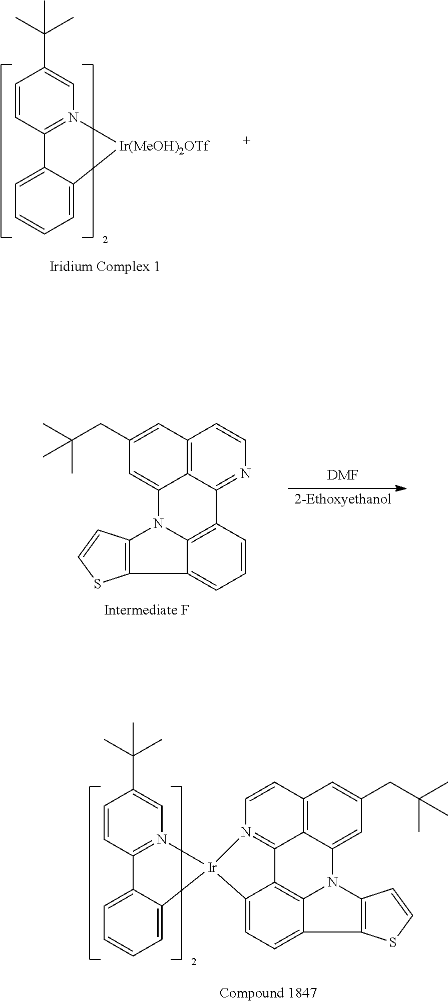

Iridium Complex 1 (1.0 g, 1.2 mmol) and Intermediate F (600 mg, 1.6 mmol) were added to a 100 mL three-necked flask and added with a mixed solvent of ethoxyethanol (15 mL) and N,N-dimethylformamide (15 mL). Under nitrogen protection, the reaction system was heated to 100° C., reacted for 120 h, and cooled to room temperature. The solvent was removed through rotary evaporation, and the residue was purified through column chromatography and eluted with petroleum ether:dichloromethane (2:1, v/v) to obtain Compound 1847 (200 mg with a yield of 17.0%). The product was confirmed as the target product with a molecular weight of 980.3.

### Synthesis Example 11: Synthesis of Compound 1853

Step 1: Synthesis of Intermediate 18

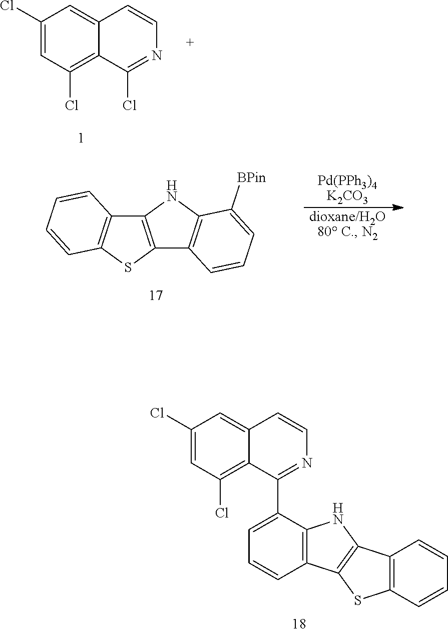

Intermediate 1 (1.7 g, 7.2 mmol), Intermediate 17 (2.5 g, 7.22 mmol), Pd(PPh₃)₄ (920 mg, 0.8 mmol), and K₂CO₃ (1.9 g, 13.8 mmol) were mixed in 1,4-dioxane/H₂O (56 mL/14 mL), purged with nitrogen, and reacted overnight at 80° C. After the reaction was completed as detected through TLC, the reaction system was cooled to room temperature, diluted with ethyl acetate, and extracted. The organic phases were concentrated and purified through column chromatography to obtain Intermediate 18 (1.8 g with a yield of 59.5%).

Step 2: Synthesis of Intermediate 19

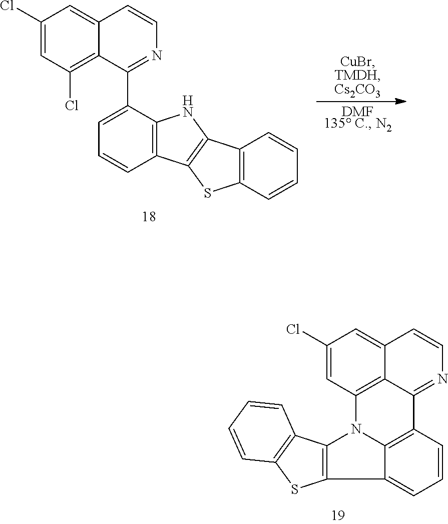

Intermediate 18 (1.8 g, 4.3 mmol), CuBr (70 mg, 0.5 mmol), 2,2,6,6-tetramethyl-3,5-heptanedione (TMDH) (0.9 g, 5.0 mmol), and Cs₂CO₃ (2.6 g, 8.0 mmol) were mixed in DMF (20 mL), purged with nitrogen, reacted at 135° C. for 5 h, cooled to room temperature, and added with water to precipitate the product. The product was filtered, and the filter cake was washed with an appropriate amount of water and PE, dried, refluxed in EtOH for 3 h, and filtered to obtain Intermediate 19 (900 mg with a yield of 54%).

Step 3: Synthesis of Intermediate G

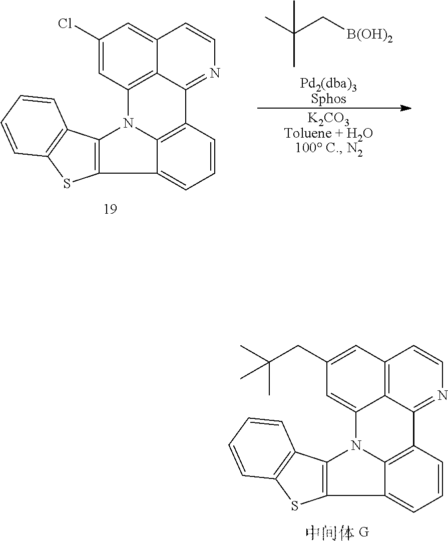

Intermediate 19 (900 mg, 2.3 mmol), Pd₂(dba)₃ (110 mg, 0.12 mmol), Sphos (98 mg, 0.24 mmol), and potassium carbonate (640 mg, 4.6 mmol) were mixed in a mixed solution of toluene and water (10 mL+2 mL), purged with nitrogen, added with neopentylboronic acid (540 mg, 4.6 mmol), and reacted overnight at 100° C. The reaction solution was cooled, added with water, and extracted with EA. The organic phases were collected and concentrated, and the residue was purified through column chromatography to obtain Intermediate G (820 mg with a yield of 85.3%).

Step 4: Synthesis of Compound 1853

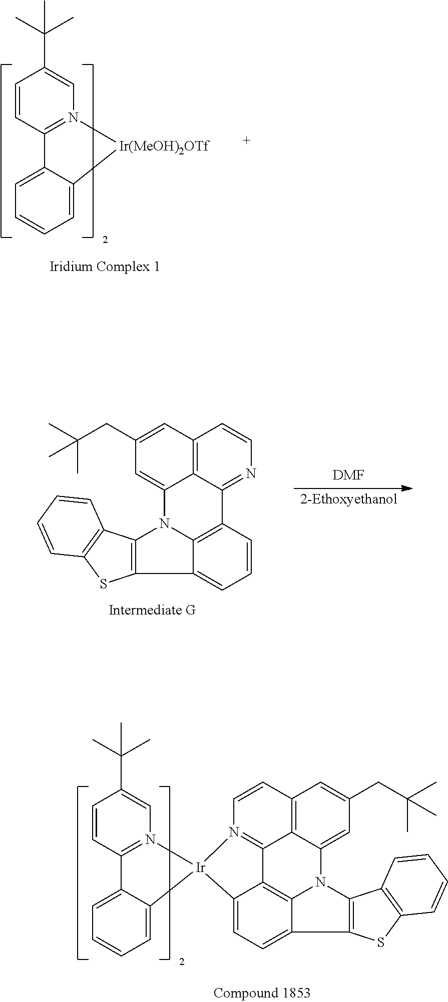

Iridium Complex 1 (1.3 g, 1.6 mmol) and Intermediate G (820 mg, 2.0 mmol) were added to a 100 mL three-necked flask and added with a mixed solvent of ethoxyethanol (15 mL) and N,N-dimethylformamide (15 mL). Under nitrogen protection, the reaction system was heated to 100° C., reacted for 120 h, and cooled to room temperature. The solvent was removed through rotary evaporation, and the residue was purified through column chromatography and eluted with petroleum ether:dichloromethane (2:1, v/v) to obtain Compound 1853 (220 mg with a yield of 13.4%). The product was confirmed as the target product with a molecular weight of 1030.4.

### Synthesis Example 12: Synthesis of Compound 1835

Step 1: Synthesis of Intermediate 21

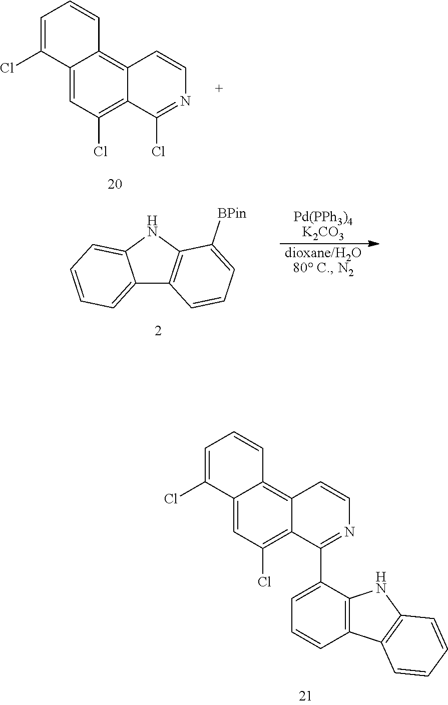

Intermediate 20 (2.8 g, 10.0 mmol), Intermediate 2 (2.9 g, 10.0 mmol), Pd(PPh₃)₄ (580 mg, 0.5 mmol), and K₂CO₃ (2.7 g, 20 mmol) were mixed in 1,4-dioxane/H₂O (56 mL/14 mL), purged with nitrogen, and reacted overnight at 80° C. After the reaction was completed as detected through TLC, the reaction system was cooled to room temperature, diluted with ethyl acetate, and extracted. The organic phases were concentrated and purified through column chromatography to obtain Intermediate 21 (2.9 g with a yield of 70%).

Step 2: Synthesis of Intermediate 22

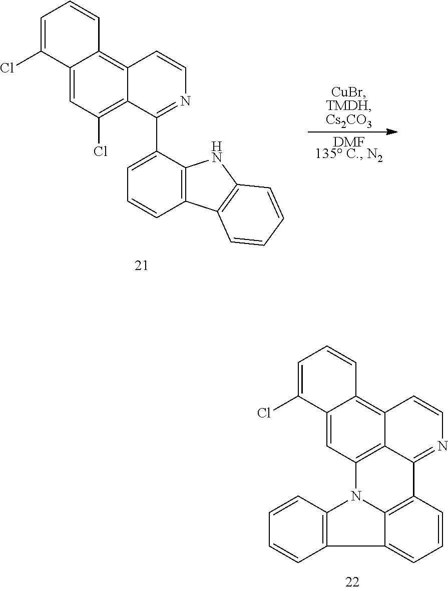

Intermediate 21 (2.3 g, 5.6 mmol), CuBr (86 mg, 0.6 mmol), 2,2,6,6-tetramethyl-3,5-heptanedione (TMDH) (1.1 g, 6.0 mmol), and Cs₂CO₃ (4.2 g, 12.2 mmol) were mixed in DMF (30 mL), purged with nitrogen, reacted at 135° C. for 5 h, cooled to room temperature, and added with water to precipitate the product. The product was filtered, and the filter cake was washed with an appropriate amount of water and PE, dried, refluxed in EtOH for 3 h, and filtered to obtain Intermediate 22 (2.0 g with a yield of 95%).

Step 3: Synthesis of Intermediate H

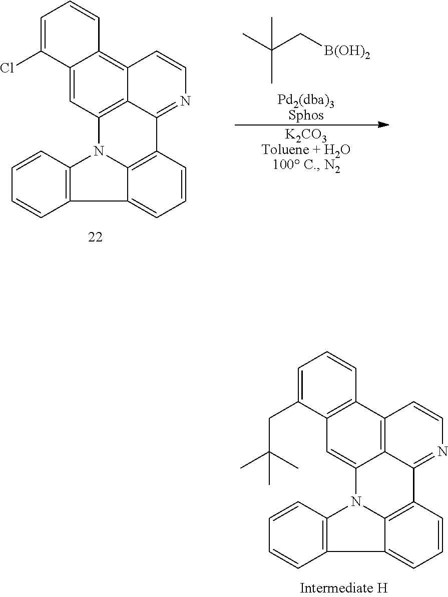

Intermediate 22 (2.0 g, 5.3 mmol), Pd₂(dba)₃ (242 mg, 0.26 mmol), Sphos (213 mg, 0.52 mmol), and potassium carbonate (1.5 g, 10.6 mmol) were mixed in a mixed solution of toluene and water (20 mL+4 mL), purged with nitrogen, added with neopentylboronic acid (1.3 g, 10.6 mmol), and reacted overnight at 100° C. The reaction solution was cooled, added with water, and extracted with EA. The organic phases were collected and concentrated, and the residue was purified through column chromatography to obtain Intermediate H (1.1 g with a yield of 50%).

Step 4: Synthesis of Compound 1835

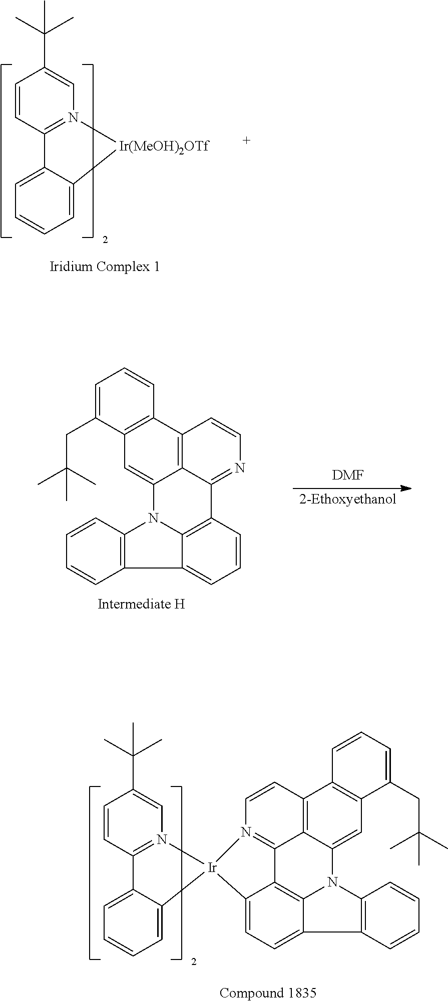

Iridium Complex 1 (1.6 g, 2.0 mmol) and Intermediate H (1.1 g, 2.5 mmol) were added to a 100 mL three-necked flask and added with a mixed solvent of ethoxyethanol (25 mL) and N,N-dimethylformamide (25 mL). Under nitrogen protection, the reaction system was heated to 100° C., reacted for 120 h, and cooled to room temperature. The solvent was removed through rotary evaporation, and the residue was purified through column chromatography and eluted with petroleum ether:dichloromethane (2:1, v/v) to obtain Compound 1835 (100 mg with a yield of 4.8%). The product was confirmed as the target product with a molecular weight of 1024.4.

Those skilled in the art will appreciate that the above preparation methods are merely exemplary. Those skilled in the art can obtain other compound structures of the present disclosure through the modifications of the preparation methods.

Spectral Data

The photoluminescence (PL) spectroscopy data of the compounds of the present disclosure and a comparative compound were measured using a fluorescence spectrophotometer F98 produced by SHANGHAI LENGGUANG TECHNOLOGY CO., LTD. Samples of the compounds in the examples and the comparative compound were each prepared into a solution with a concentration of 3×10⁻⁵ mol/L by using HPLC-grade dichloromethane and then excited at room temperature (298 K) by using light with a wavelength of 500 nm, and their emission spectrums were measured. Measurement results are shown in Table 1.

TABLE 1
PL data

| Compound No. | λₘₐₓ (nm) | FWHM (nm) |
|---|---|---|
| Compound 263 | 613 | 26.1 |
| Compound 1524 | 616 | 29.3 |
| Compound 1272 | 615 | 28.3 |
| Compound 257 | 600 | 27.1 |
| Compound 5 | 604 | 26.8 |
| Compound 367 | 698 | 24.6 |
| Compound 375 | 610 | 30.2 |
| Compound 1636 | 614 | 33.1 |
| Compound 1829 | 599 | 27.4 |
| Compound 1847 | 574 | 33.2 |
| Compound 1853 | 591 | 32.2 |
| Compound 1835 | 591 | 22.2 |
| Compound RD-A | 655 | 61.1 |

The related compounds in Table 1 have the following structures:

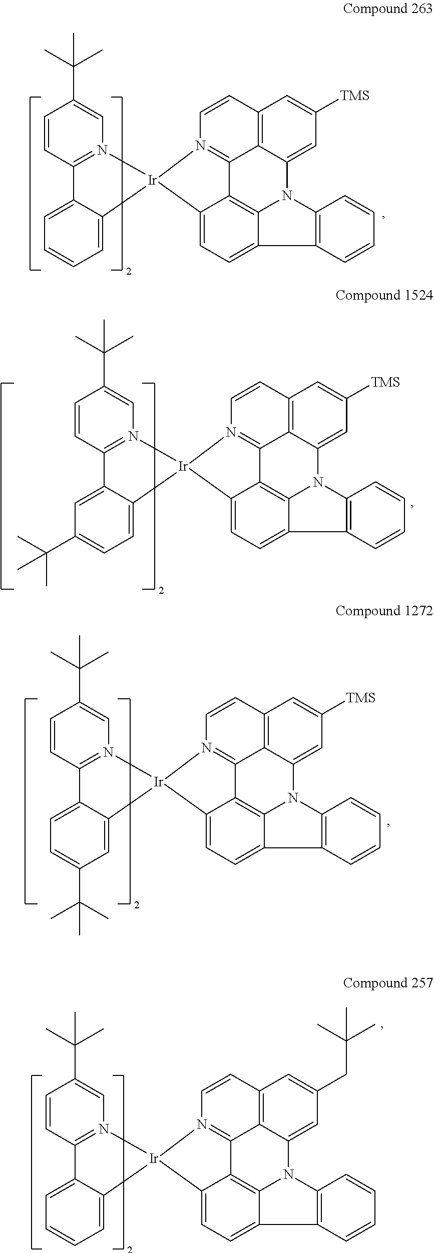

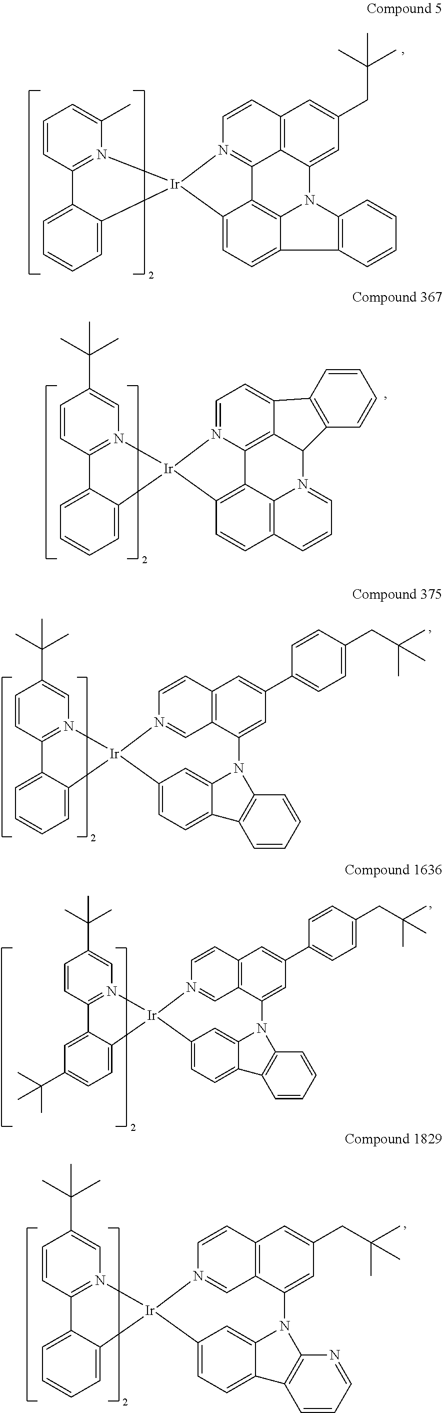

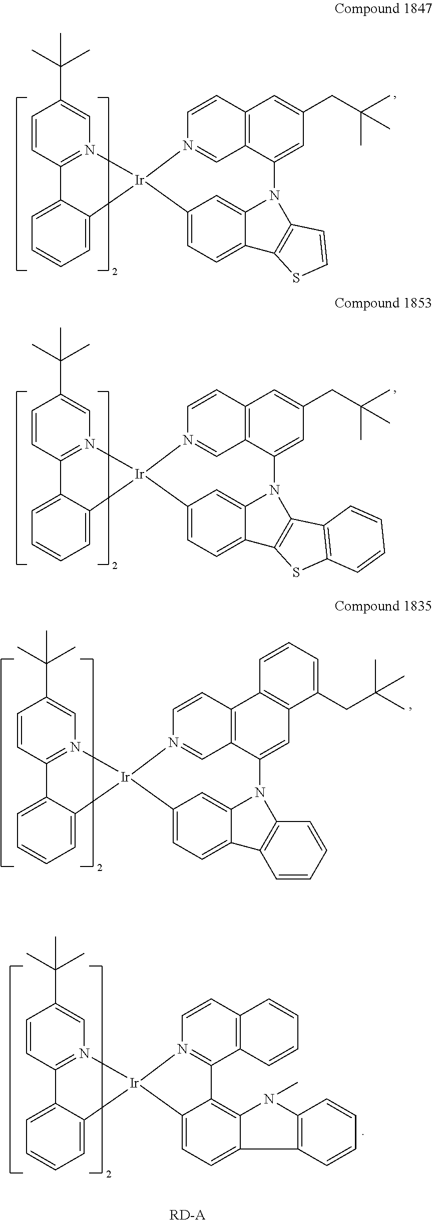

As can be seen from the data in Table 1, the metal complexes of the present disclosure can achieve luminescence in different wavebands from orange to deep red, indicating that the compounds of the present disclosure can effectively adjust a luminescence wavelength and meet luminescence requirements on different wavebands and all have very narrow FWHMs: the FWHMs of the these compounds are all smaller than 34 nm, and most examples even reach an extremely narrow FWHM of smaller than 30 nm; in particular, Compound 1835 has an extremely narrow FWHM of 22.2 nm. In previous reports, the introduction of phenylpyridine ligands often causes the peak width of the emission spectrum of a metal complex to become wider. However, the metal complexes of the present disclosure show unexpectedly narrow peak widths, which are greatly narrowed by more than 50% compared with that of the comparative compound RD-A. This indicates that the metal complex of the present disclosure has good luminescence performance and enables the device to achieve very saturated red light emission. To further verify the performance of the metal complex of the present disclosure in the device, device examples in which the metal complexes of the present disclosure are used as emissive materials are provided.

The method for preparing an electroluminescent device is not limited. The preparation methods in the following examples are merely examples and are not to be construed as limitations. Those skilled in the art can make reasonable improvements on the preparation methods in the following examples based on the related art. For example, the proportions of various materials in an emissive layer are not particularly limited. Those skilled in the art can reasonably select the proportions within a certain range based on the related art. For example, taking the total weight of the materials in the emissive layer for reference, a host material may account for 80% to 99% and an emissive material may account for 1% to 20%; or the host material may account for 90% to 99% and the emissive material may account for 1% to 10%; or the host material may account for 95% to 99% and the emissive material may account for 1% to 5%. Further, the host material may include one material or two materials, where the ratio of two host materials may be 100:0 to 1:99; or the ratio may be 80:20 to 20:80; or the ratio may be 60:40 to 40:60.

### Device Example

### Device Example 1

Firstly, a glass substrate having an indium tin oxide (ITO) anode with a thickness of 120 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 109⁻⁸ Torr. Compound HT and HI as a dopant were co-deposited at a weight ratio of 97:3 for use as a hole injection layer (HIL) with a thickness of 100 Å. Compound HT was used as a hole transporting layer (HTL) with a thickness of 400 Å. Compound EB was used as an electron blocking layer (EBL) with a thickness of 50 Å. Compound 263 of the present disclosure was doped with Compound RH-A as a first host and Compound RH-B as a second host, and they were co-deposited at a weight ratio of 2:49:49 for use as an emissive layer (EML) with a thickness of 400 Å. Compound HB was used as a hole blocking layer (HBL) with a thickness of 50 Å. On the HBL, Compound ET and 8-hydroxyquinolinolato-lithium (Liq) were co-deposited at a weight ratio of 40:60 for use as an electron transporting layer (ETL) with a thickness of 350 Å. Finally, Liq was deposited for use as an electron injection layer with a thickness of 1 nm, and Al was deposited for use as a cathode with a thickness of 120 nm. The device was transferred back to the glovebox and encapsulated with a glass lid and a moisture getter to complete the device.

### Device Example 2

Device Example 2 was prepared by the same method as Device Example 1 except that in the EML, Compound 263 of the present disclosure was replaced with Compound 1524 of the present disclosure.

### Device Example 3

Device Example 3 was prepared by the same method as Device Example 1 except that in the EML, Compound 263 of the present disclosure was replaced with Compound 257 of the present disclosure.

### Device Example 4

Device Example 4 was prepared by the same method as Device Example 1 except that in the EML, Compound 263 of the present disclosure was replaced with Compound 5 of the present disclosure.

### Device Example 5

Device Example 5 was prepared by the same method as Device Example 1 except that in the EML, Compound 263 of the present disclosure was replaced with Compound 375 of the present disclosure.

### Device Example 6

Device Example 6 was prepared by the same method as Device Example 1 except that in the EML, Compound 263 of the present disclosure was replaced with Compound 1636 of the present disclosure.

The structures and thicknesses of some layers of the devices are shown in the following table. A layer using more than one material is obtained by doping different compounds at their weight ratio as recorded.

TABLE 2
Part of device structures in the device examples

| Device | | | | | | |
|---|---|---|---|---|---|---|
| No. | HIL | HTL | EBL | EML | HBL | ETL |
| Example | Compound | Compound | Compound | Compound | Compound | Compound |
| 1 | HT:Compound | HT (400 | EB (50 Å) | RH-A:Compound | HB (50 Å) | ET:Liq |
| | HI (97:3) (100 | Å) | | RH-B:Compound | | (40:60) (350 |
| | Å) | | | 263 (49:49:2) | | Å) |
| | | | | (400 Å) | | |
| Example | Compound | Compound | Compound | Compound | Compound | Compound |
| 2 | HT:Compound | HT (400 | EB (50 Å) | RH-A:Compound | HB (50 Å) | ET:Liq |
| | HI (97:3) (100 | Å) | | RH-B:Compound | | (40:60) (350 |
| | Å) | | | 1524 (49:49:2) | | Å) |
| | | | | (400 Å) | | |
| Example | Compound | Compound | Compound | Compound | Compound | Compound |
| 3 | HT:Compound | HT (400 | EB (50 Å) | RH-A:Compound | HB (50 Å) | ET:Liq |
| | HI (97:3) (100 | Å) | | RH-B:Compound | | (40:60) (350 |
| | Å) | | | 257 (49:49:2) | | Å) |
| | | | | (400 Å) | | |
| Example | Compound | Compound | Compound | Compound | Compound | Compound |
| 4 | HT:Compound | HT (400 | EB (50 Å) | RH-A:Compound | HB (50 Å) | ET:Liq |
| | HI (97:3) (100 | Å) | | RH-B:Compound | | (40:60) (350 |
| | Å) | | | 5 (49:49:2) (400 | | Å) |
| | | | | Å) | | |
| Example | Compound | Compound | Compound | Compound | Compound | Compound |
| 5 | HT:Compound | HT (400 | EB (50 Å) | RH-A:Compound | HB (50 Å) | ET:Liq |
| | HI (97:3) (100 | Å) | | RH-B:Compound | | (40:60) (350 |
| | Å) | | | 375 (49:49:2) | | Å) |
| | | | | (400 Å) | | |
| Example | Compound | Compound | Compound | Compound | Compound | Compound |
| 6 | HT:Compound | HT (400 | EB (50 Å) | RH-A:Compound | HB (50 Å) | ET:Liq |
| | HI (97:3) (100 | Å) | | RH-B:Compound | | (40:60) (350 |
| | Å) | | | 1636 (49:49:2) | | Å) |
| | | | | (400 Å) | | |

The structures of the materials used in the devices are shown as follows:

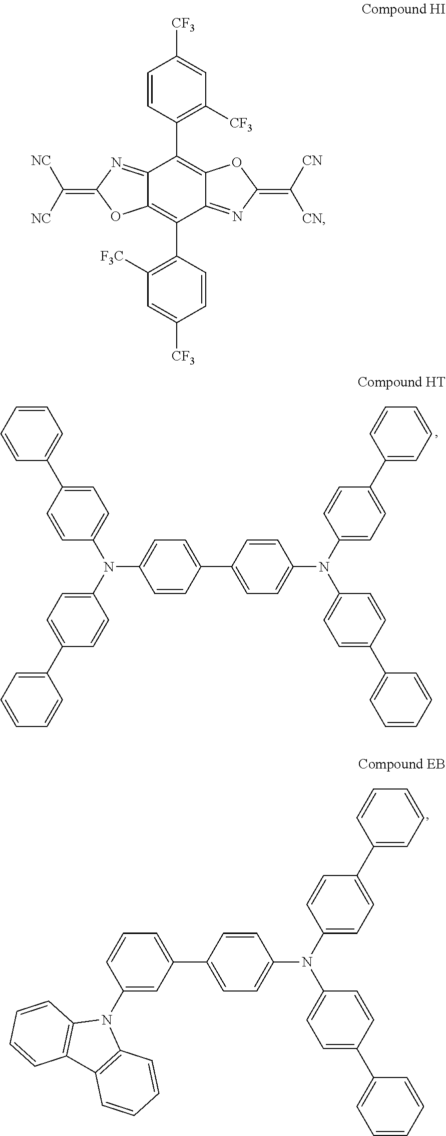 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

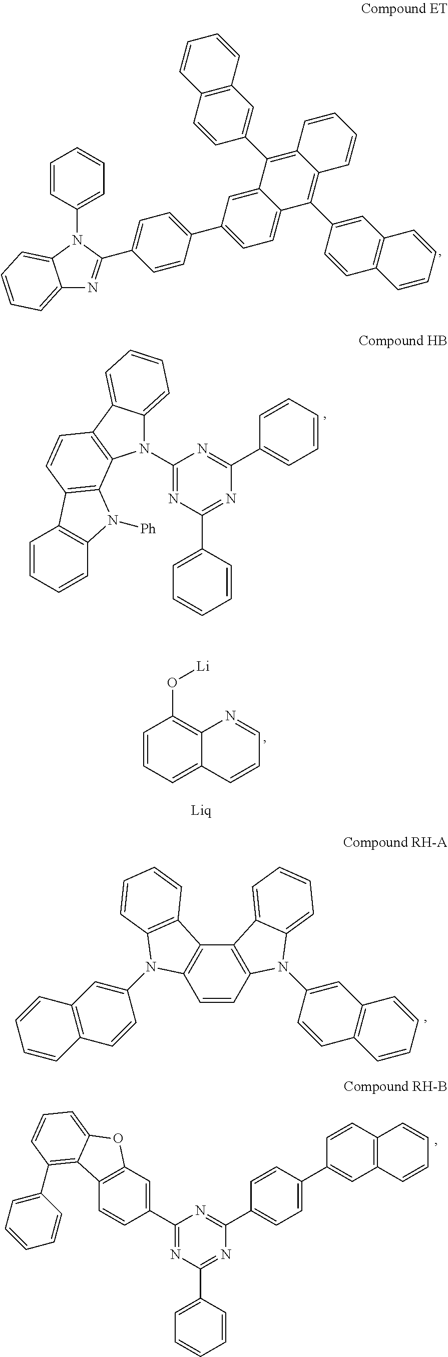

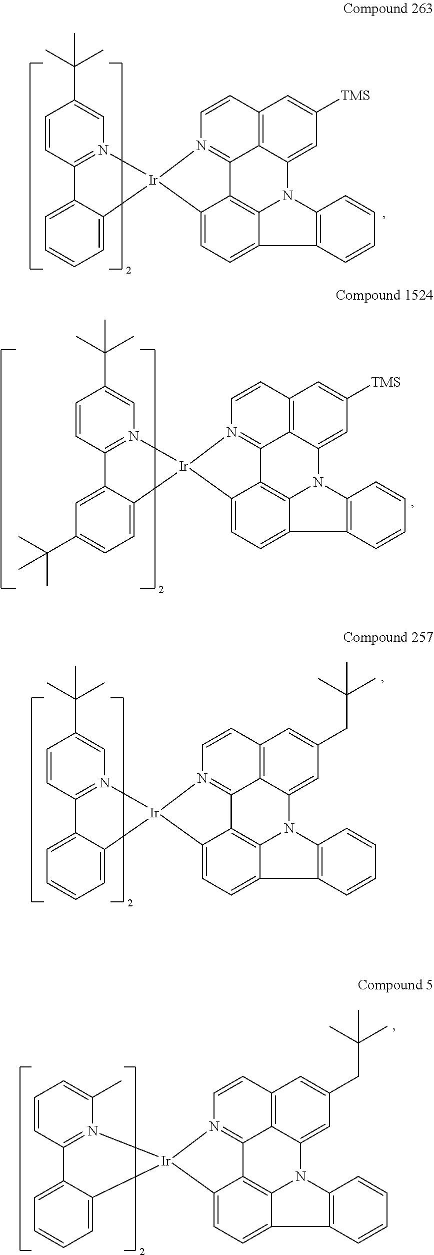

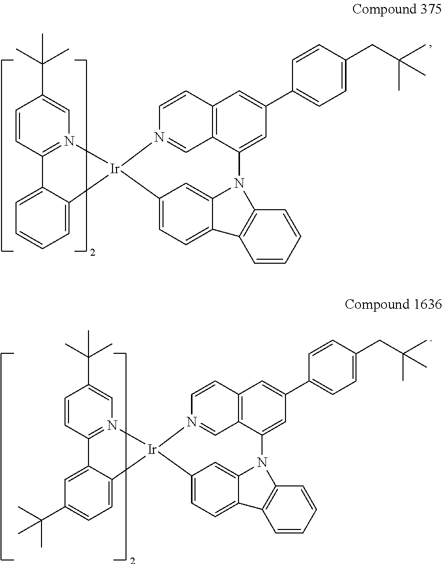

The current-voltage-luminance (IVL) and lifetime characteristics of the devices were measured. Table 3 shows data on the maximum emission wavelength (λₘₐₓ), full width at half maximum (FWHM), driving voltage (Voltage), and external quantum efficiency (EQE) measured at a current density of 15 mA/cm² and data on the device lifetime (LT99) measured at a current density of 80 mA/cm².

TABLE 3
Device data

| | λₘₐₓ | FWHM | Voltage | EQE | LT99 |
|---|---|---|---|---|---|
| Device No. | (nm) | (nm) | (V) | (%) | (h) |
| Example 1 | 614 | 26.7 | 3.52 | 19.5 | 96 |
| Example 2 | 616 | 30.2 | 3.71 | 20.7 | 81 |
| Example 3 | 602 | 28.4 | 3.74 | 19.9 | 60 |
| Example 4 | 605 | 27.3 | 3.82 | 17.9 | 150 |
| Example 5 | 614 | 32.6 | 3.47 | 21.7 | 90 |
| Example 6 | 616 | 34.8 | 3.62 | 21.3 | 60 |

### DISCUSSION

As can be seen from the data in Table 3, the metal complex of the present disclosure enabled the device to have very good performance. The FWHMs of Examples 1 to 6 were all very narrow, indicating that the metal complexes of the present disclosure enable the devices to achieve extremely high saturation luminescence. Additionally, Examples 1 to 6 also had the advantages of a low voltage and high efficiency. More importantly, as can be seen from the data in Table 3, the device lifetimes LT99 of Examples 1 to 6 at a high current density of 80 mA/cm² all reached more than 60 hours, and the device lifetime LT99 of Example 4 was even as high as 150 hours. These data indicates that the metal complexes of the present disclosure enable the devices to obtain an ultra-long lifetime far exceeding the common level of red phosphorescent materials; and, that the metal complexes of the present disclosure, when used as emissive materials, can effectively control the luminescence wavelength of the devices. All these data prove that the metal complexes disclosed in the present disclosure have good performance and a good application prospect.

To conclude, the metal complexes disclosed in the present disclosure can meet luminescence requirements on different wavebands, unexpectedly have a greatly narrowed full width at half maximum, and can achieve high-saturation luminescence. Moreover, when used as emissive materials in electroluminescent devices, the metal complexes of the present disclosure can effectively control the luminescence wavelength of the devices, can make the devices have the advantages of a low voltage, high efficiency, and an ultra-long lifetime, and can provide better device performance. This proves that the metal complexes disclosed in the present disclosure have good performance and a good application prospect.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A metal complex having a general formula of M(Lₐ)ₘ(L_{b})ₙ(L_{c})_{q}, wherein the metal M is selected from a metal with a relative atomic mass greater than 40, and Lₐ, L_{b}, and L_{c} are a first ligand, a second ligand, and a third ligand coordinated to the metal M, respectively;
Lₐ, L_{b}, and L_{c} can be optionally joined to form a multidentate ligand;
m is selected from 1 or 2, n is selected from 1 or 2, q is selected from 0 or 1, and m+n+q equals the oxidation state of the metal M; when m is equal to 2, two Lₐ are the same or different;
when n is equal to 2, two L_{b} are the same or different;
the first ligand Lₐ has a structure represented by Formula 1: 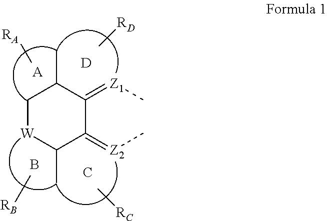
wherein Z₁ and Z₂ are each independently selected from C or N, and Z₁ is different from Z₂;
W is, at each occurrence identically or differently, selected from B, N, or P;
the ring A, the ring C, and the ring D are, at each occurrence identically or differently, selected from a five-membered unsaturated carbocyclic ring, an aromatic ring having 6 to 30 carbon atoms, or a heteroaromatic ring having 3 to 30 carbon atoms;
the ring B is selected from a heterocyclic ring having 2 to 30 carbon atoms or a heteroaromatic ring having 2 to 30 carbon atoms;
R_{A}, R_{B}, R_{C}, and R_{D} represent, at each occurrence identically or differently, mono-substitution, multiple substitutions, or non-substitution;
R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, and R_{D} can be optionally joined to form a ring;
the second ligand L_{b} has a structure represented by Formula 2: 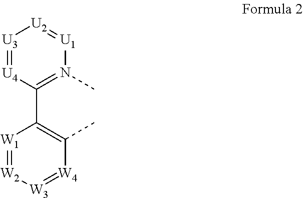
wherein U₁ to U₄ are, at each occurrence identically or differently, selected from N or CR_{U};
W₁ to W₄ are, at each occurrence identically or differently, selected from N or CR_{W};
R_{U} and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{U}, R_{W} can be optionally joined to form a ring; and
L_{c} is selected from a monoanionic bidentate ligand.

2. The metal complex according to claim 1, wherein in the Lₐ, the ring A, the ring C, and the ring D are, at each occurrence identically or differently, selected from an aromatic ring having 6 to 18 carbon atoms or a heteroaromatic ring having 3 to 18 carbon atoms; and the ring B is selected from a heteroaromatic ring having 2 to 18 carbon atoms;
preferably, the ring A, the ring C, and the ring D are, at each occurrence identically or differently, selected from a benzene ring, a naphthalene ring, a pyridine ring, a pyrimidine ring, a pyrazine ring, an azanaphthalene ring, a furan ring, a thiophene ring, an isoxazole ring, an isothiazole ring, a pyrrole ring, a pyrazole ring, a benzofuran ring, a benzothiophene ring, an azabenzofuran ring, or an azabenzothiophene ring; the ring B is selected from a pyrrole ring, an indole ring, an imidazole ring, a pyrazole ring, a triazole ring, or an azaindole ring;
more preferably, the ring A, the ring C, and the ring D are, at each occurrence identically or differently, selected from a benzene ring, a naphthalene ring, a pyridine ring, or a pyrimidine ring; the ring B is selected from a pyrrole ring, an indole ring, or an azaindole ring.

3. The metal complex according to claim 1, wherein the Lₐ is selected from a structure represented by any one of Formula 3 to Formula 20: 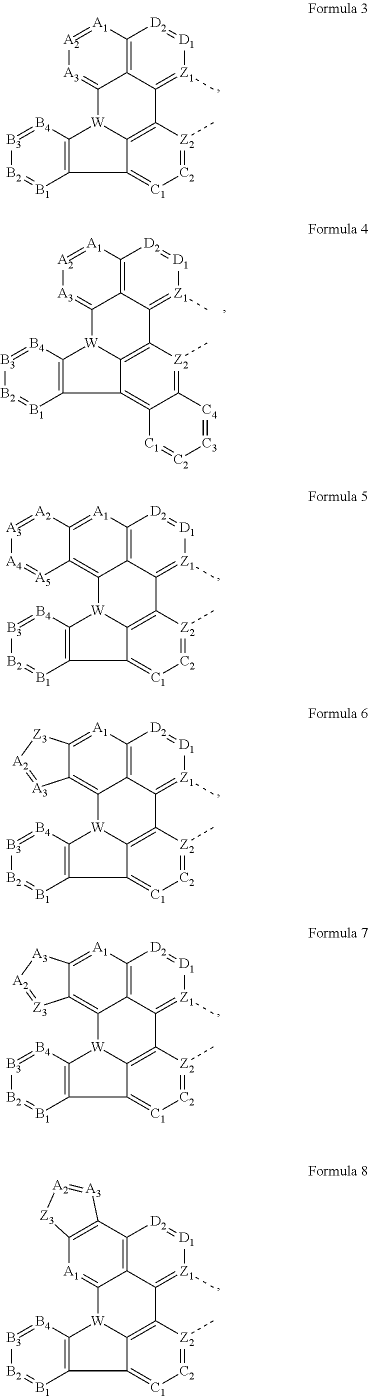 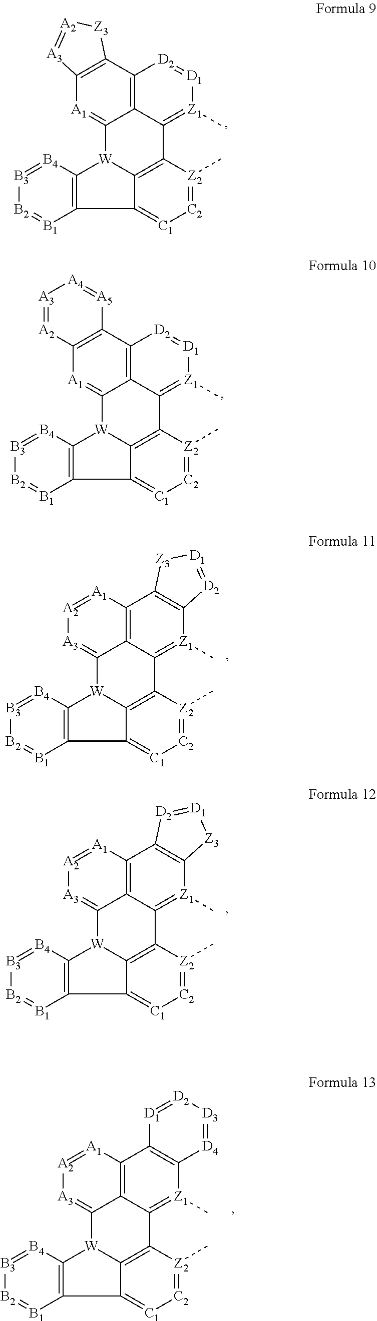 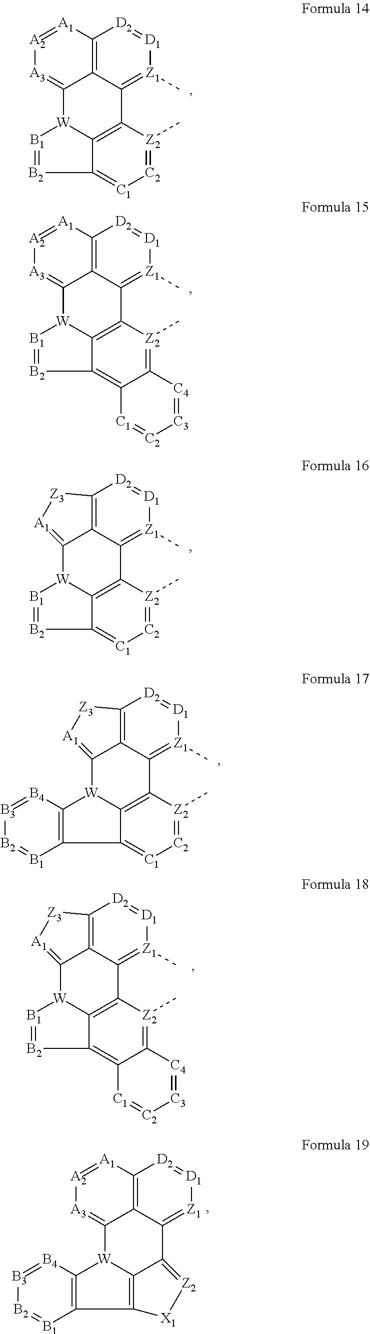 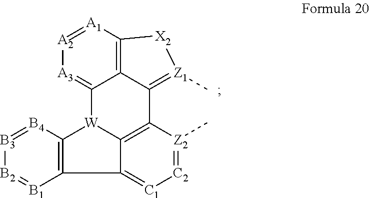
Wherein,
Z₁ and Z₂ are each independently selected from C or N, and Z₁ is different from Z₂;
W is, at each occurrence identically or differently, selected from B, N, or P;
A₁ to A₅ are, at each occurrence identically or differently, selected from N or CR_{A};
B₁ to B₄ are, at each occurrence identically or differently, selected from N or CR_{B};
C₁ to C₄ are, at each occurrence identically or differently, selected from N or CR_{C};
D₁ to D₄ are, at each occurrence identically or differently, selected from N or CR_{D};
X₁ is, at each occurrence identically or differently, selected from O, S, Se, NR_{C}, CR_{C}R_{C}, SiR_{C}R_{C}, or PR_{C};
X₂ is, at each occurrence identically or differently, selected from O, S, Se, NR_{D}, CR_{D}R_{D}, SiR_{D}R_{D}, or PR_{D};
Z₃ is, at each occurrence identically or differently, selected from O, S, Se, NR_{Z}, CR_{Z}R_{Z}, SiR_{Z}R_{Z}, or PR_{Z};
R_{A}, R_{B}, R_{C}, R_{D}, and R_{Z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, R_{D}, and R_{Z} can be optionally joined to form a ring;
preferably, Lₐ is selected from a structure represented by Formula 3, Formula 4, Formula 8, Formula 9, Formula 10, or Formula 13;
more preferably, Lₐ is selected from a structure represented by Formula 3, Formula 4, or Formula 13.

4. The metal complex according to claim 3, wherein in Formula 1 and Formula 3 to Formula 20, W is B or N; preferably, W is N.

5. The metal complex according to claim 3, wherein in Formula 3 to Formula 19, Z₁ is N, and at least one of D₁ and D₂ is N; or in Formula 3 to Formula 18 and Formula 20, Z₂ is N, and at least one of C₁ and C₂ is N;
preferably, in Formula 3 to Formula 19, Z₁ is N, and one of D₁ and D₂ is N; or in Formula 3, Formula 18, and Formula 20, Z₂ is N, and one of C₁ and C₂ is N;
more preferably, in Formula 3 to Formula 19, Z₁ is N, and D₂ is N; or in Formula 2 to Formula 18 and Formula 20, Z₂ is N, and C₁ is N.

6. The metal complex according to claim 3, wherein in Formula 3 to Formula 20, A₁ to A₅ are each independently selected from CR_{A}, and B₁ to B₄ are each independently selected from CR_{B}; in Formula 3 to Formula 18 and Formula 20, C₁ to C₄ are each independently selected from CR_{C}; in Formula 3 to Formula 19, D₁ to D₄ are each independently selected from CR_{D}; and the R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{A}, R_{B}, R_{C}, and R_{D} can be optionally joined to form a ring;
preferably, the R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkoxy having 1 to 20 carbon atoms, substituted or unsubstituted aryloxy having 6 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, and combinations thereof,
more preferably, the R_{A}, R_{B}, R_{C}, and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, cyano, and combinations thereof.

7. The metal complex according to claim 3, wherein in Formula 3 to Formula 20, at least one of A₁ to Aₙ is, at each occurrence identically or differently, selected from CR_{A}, wherein the Aₙ corresponds to the one with the largest serial number among A₁ to A₅ in any one of Formula 3 to Formula 20; and the R_{A} is, at each occurrence identically or differently, selected from the group consisting of: deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof, and
adjacent substituents R_{A} can be optionally joined to form a ring;
preferably, in Formula 3 to Formula 15, Formula 19, and Formula 20, at least one of A₁ to A₃ is, at each occurrence identically or differently, selected from CR_{A}; and in Formula 16 to Formula 18, A₁ is selected from CR_{A};
more preferably, in Formula 3, Formula 4, Formula 6 to Formula 9, Formula 11 to Formula 15, Formula 19, and Formula 20, A₂ is selected from CR_{A}; and in Formula 5, Formula 10, and Formula 16 to Formula 18, A₁ is selected from CR_{A};
most preferably, the R_{A} is, at each occurrence identically or differently, selected from the group consisting of: deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, sec-butyl, t-butyl, neopentyl, cyclopentyl, cyclopentylmethyl, cyclohexyl, norbornyl, adamantyl, trimethylsilyl, triethylsilyl, phenyldimethylsilyl, trimethylgermanyl, triethylgermanyl, phenyl, 2,6-dimethylphenyl, 2,6-diisopropylphenyl, pyridyl, pyrimidinyl, triazinyl, and combinations thereof.

8. The metal complex according to claim 3, wherein in Formula 3 to Formula 18 and Formula 20, at least one of C₁ and C₂ is, at each occurrence identically or differently, selected from CR_{C}, and the R_{C} is, at each occurrence identically or differently, selected from the group consisting of: deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, and combinations thereof,
preferably, in Formula 3 to Formula 18 and Formula 20, C₂ is selected from CR_{C}; more preferably, the R_{C} is, at each occurrence identically or differently, selected from the group consisting of: deuterium, cyano, fluorine, methyl, ethyl, isopropyl, isobutyl, t-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, and combinations thereof.

9. The metal complex according to claim 3, wherein in Formula 3 to Formula 20, at least one of B₁ to Bₙ is selected from CR_{B}, wherein the Bₙ corresponds to the one with the largest serial number among B₁ to B₄ in any one of Formula 3 to Formula 20; and/or in Formula 3 to Formula 19, at least one of D₁ to Dₙ is selected from CR_{D}, wherein the Dₙ corresponds to the one with the largest serial number among D₁ to D₄ in any one of Formula 3 to Formula 19; wherein the R_{B} and R_{D} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, hydroxyl, sulfanyl, and combinations thereof;
preferably, in Formula 3 to Formula 13, Formula 17, Formula 19, and Formula 20, B₂ and/or B₃ are selected from CR_{B}; in Formula 14 to Formula 16 and Formula 18, B₁ and/or B₂ are selected from CR_{B}; and in Formula 3 to Formula 19, D₁ and/or D₂ are selected from CR_{D};
more preferably, the R_{B} and R_{D} are, at each occurrence identically or differently, selected from the group consisting of: hydrogen, deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, t-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, and combinations thereof.

10. The metal complex according to claim 1, wherein Lₐ is, at each occurrence identically or differently, selected from the group consisting of the following structures: 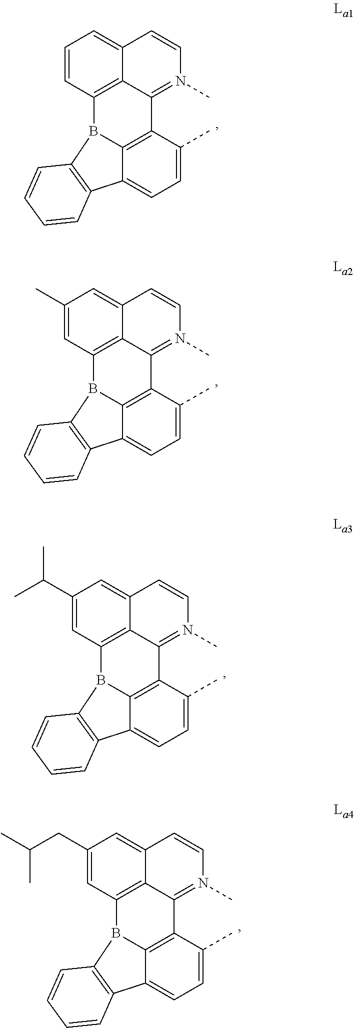 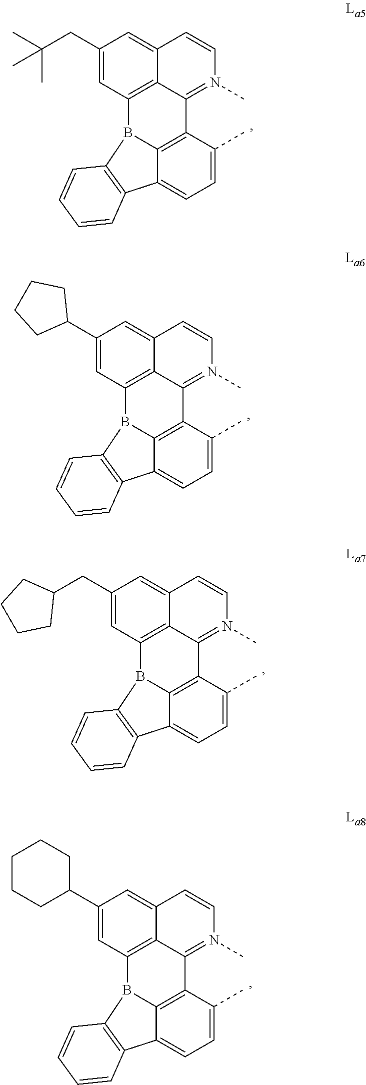 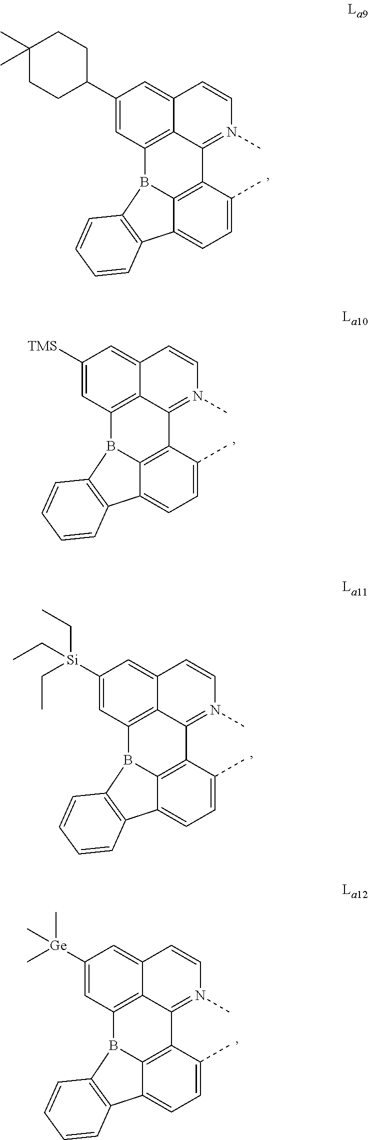 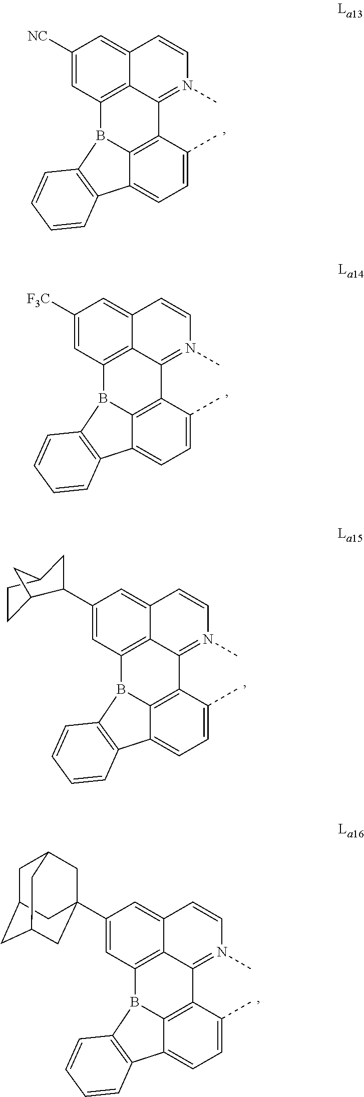 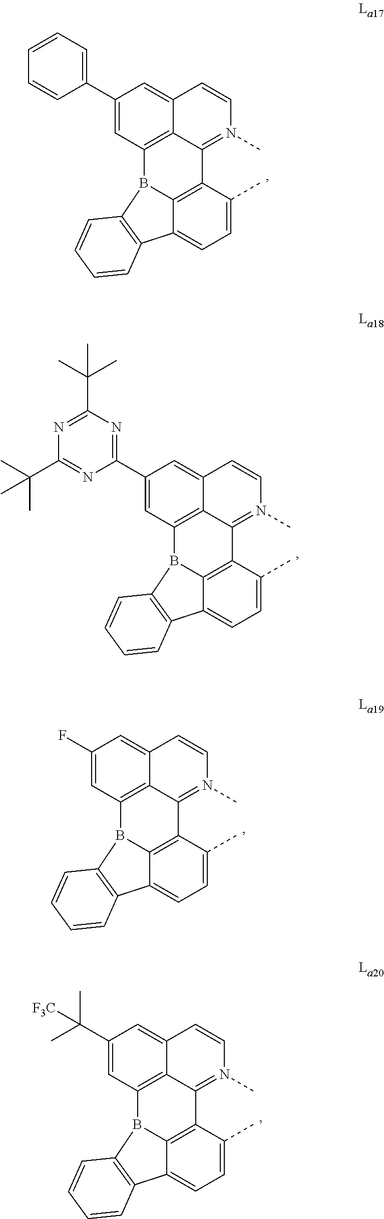 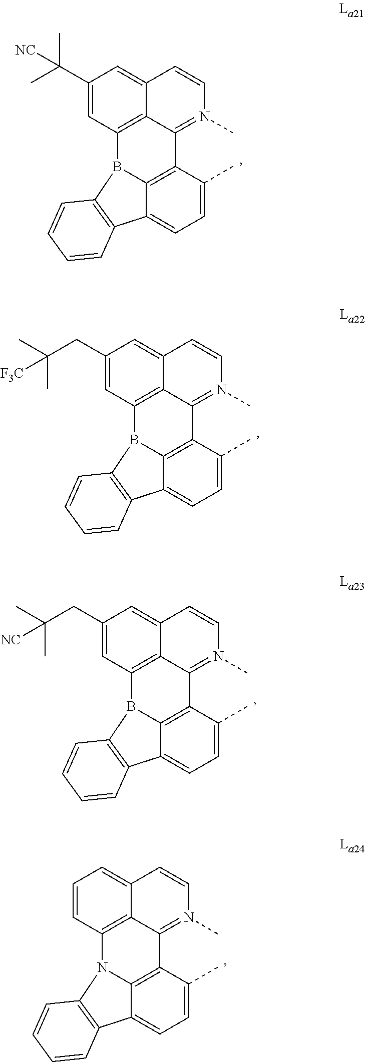 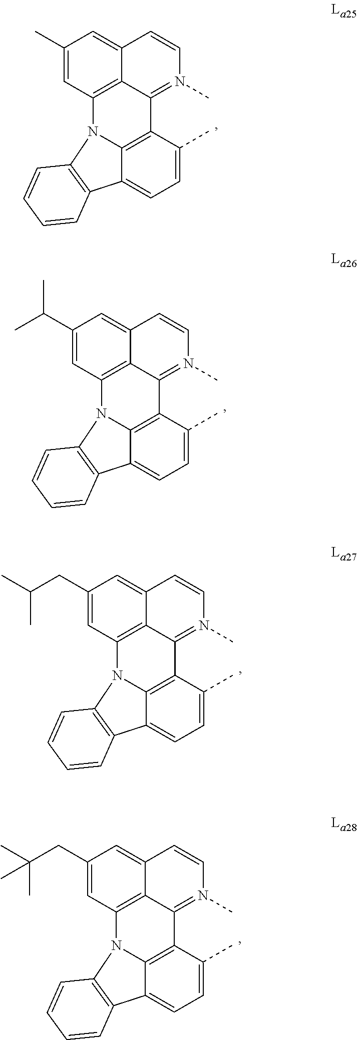 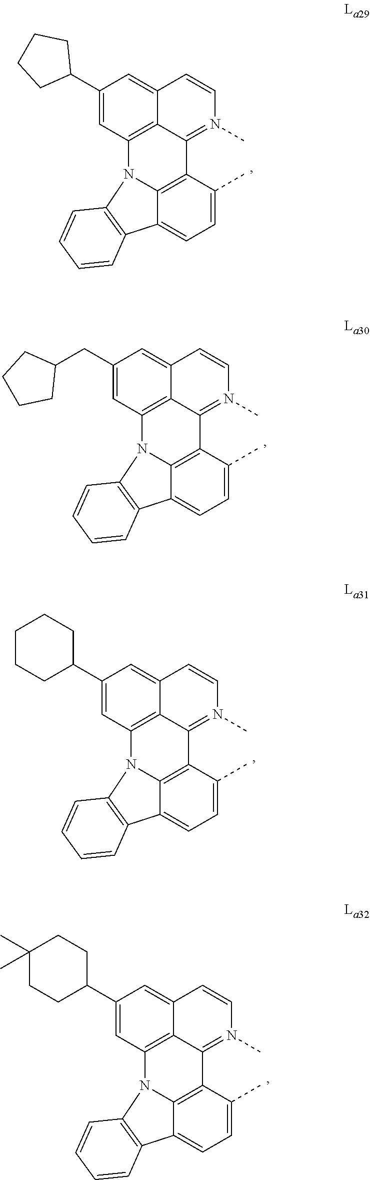 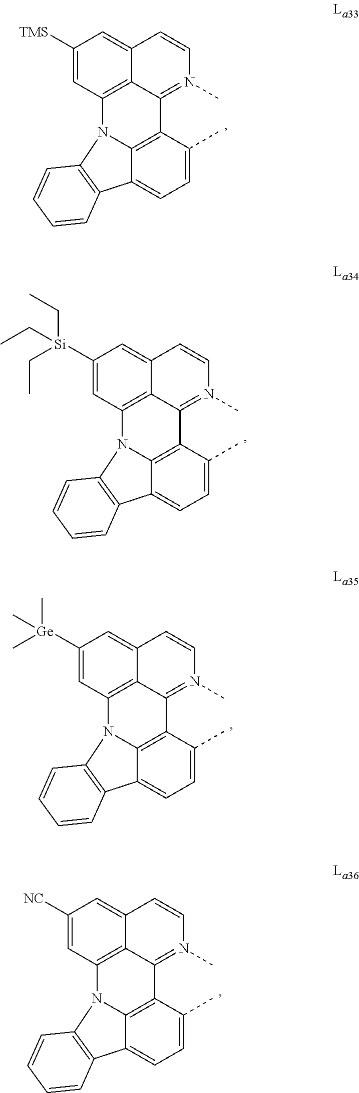 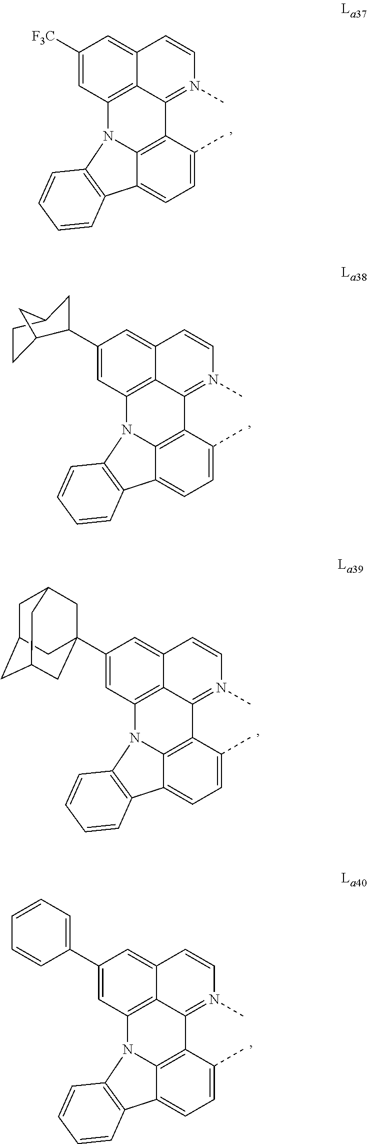 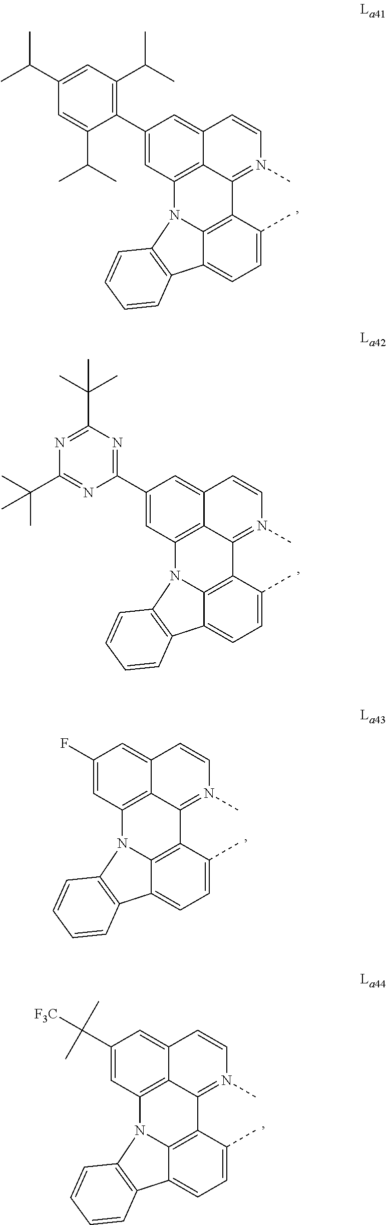 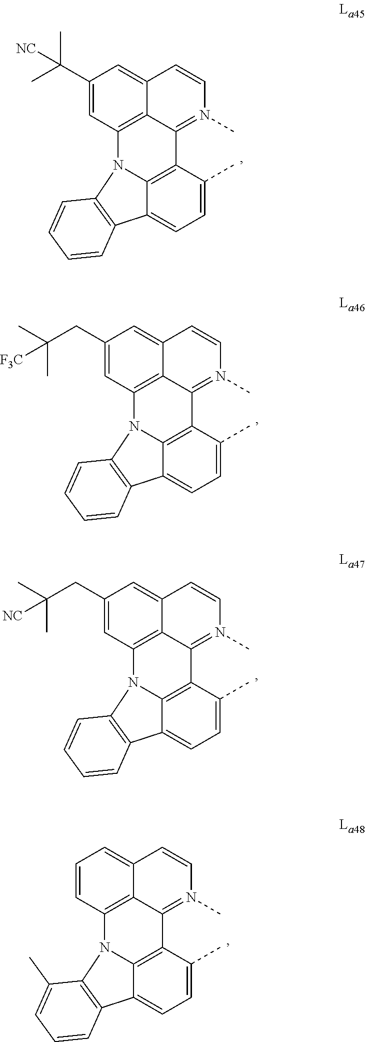 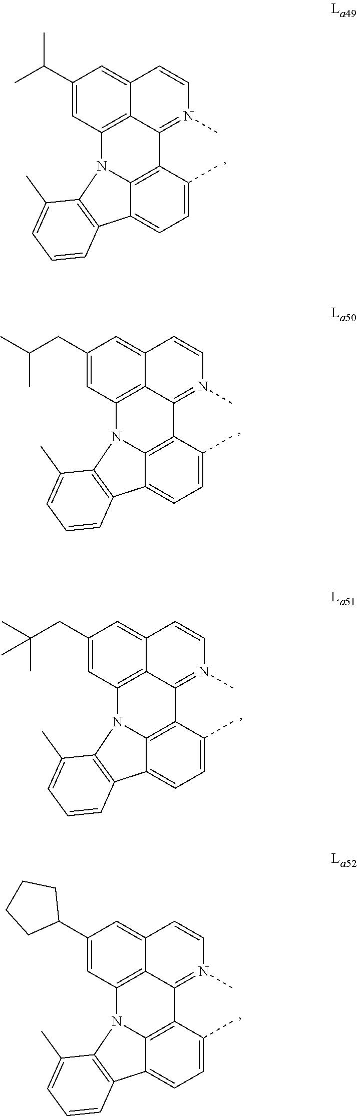 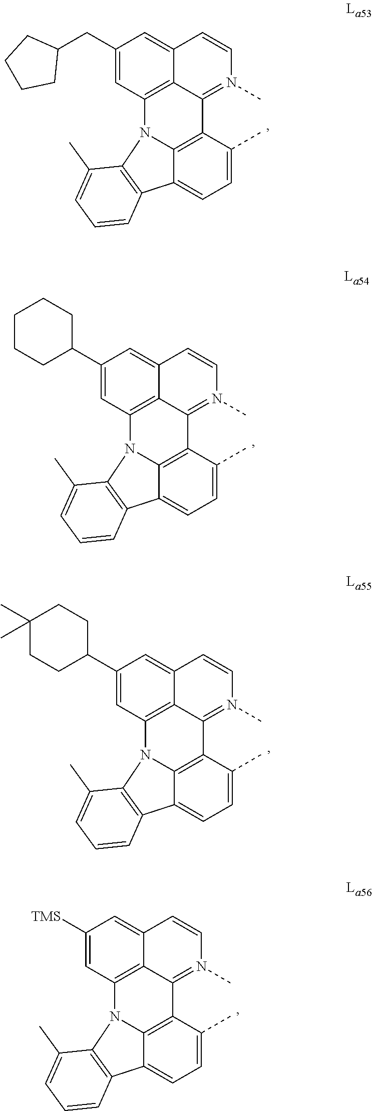 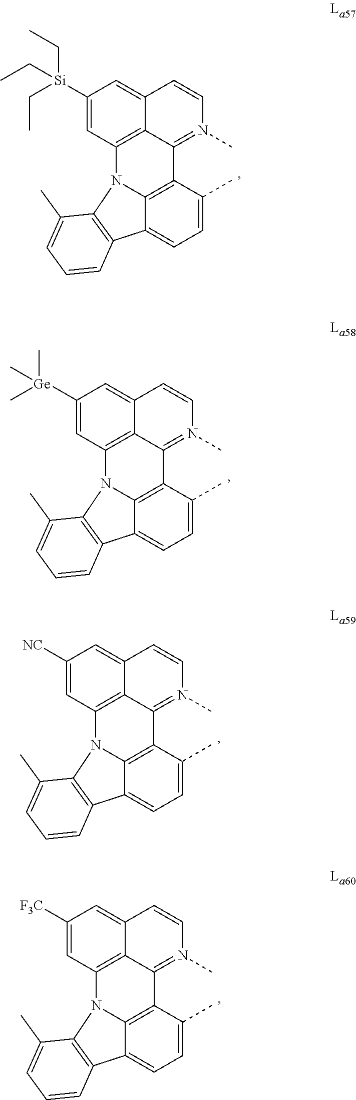 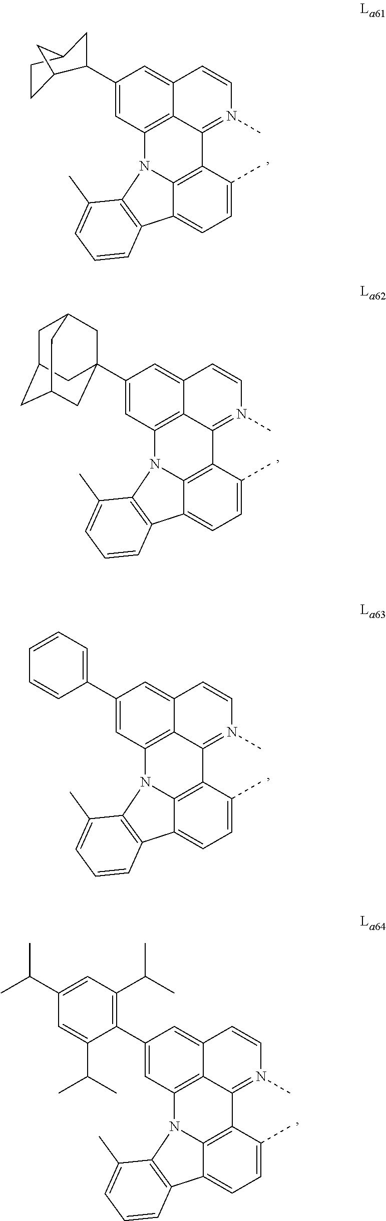 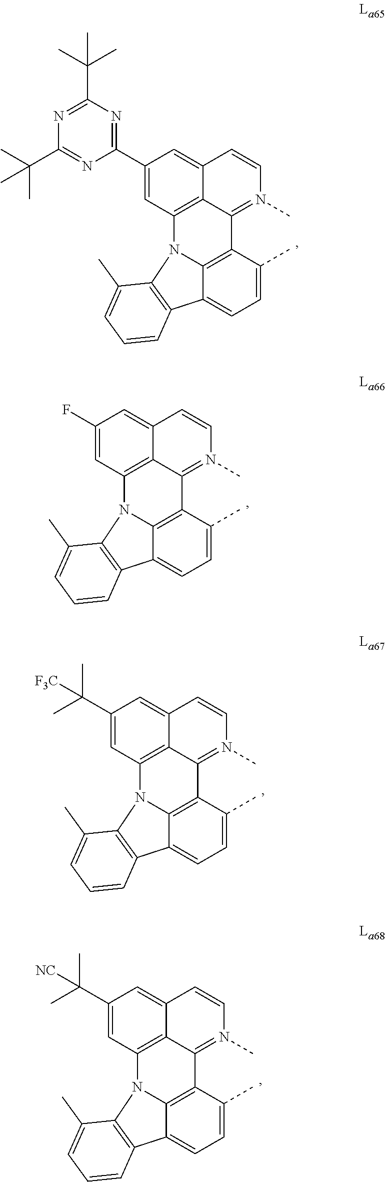 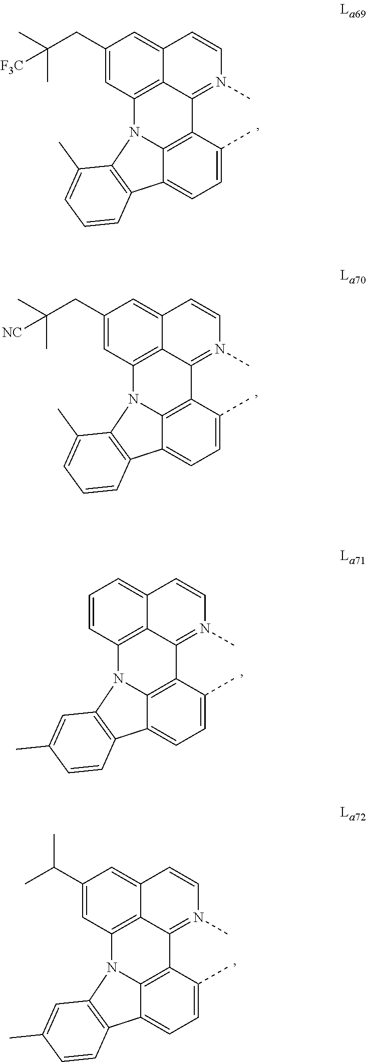 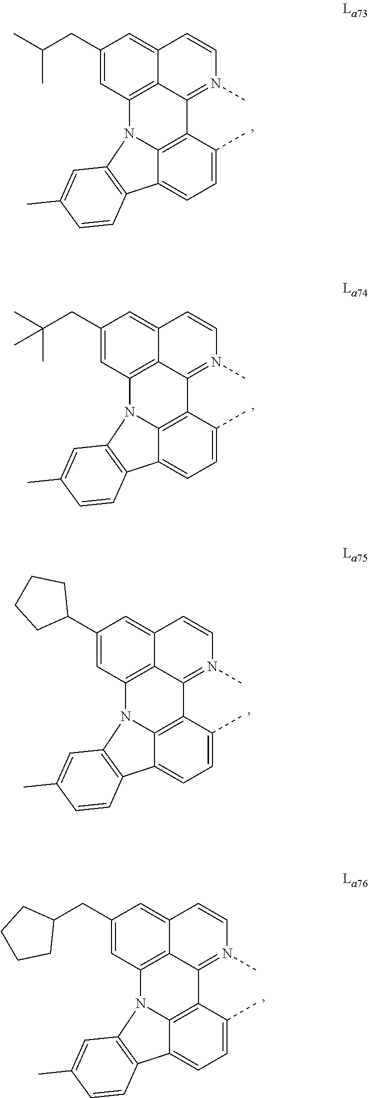 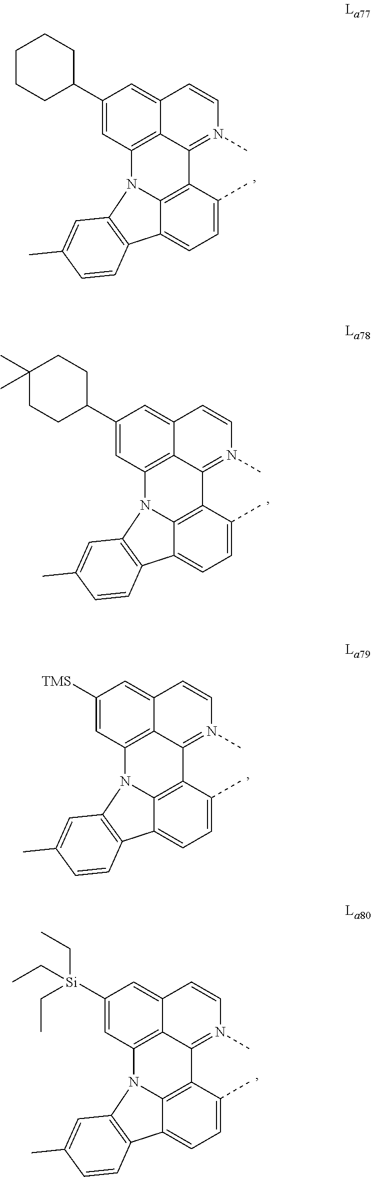 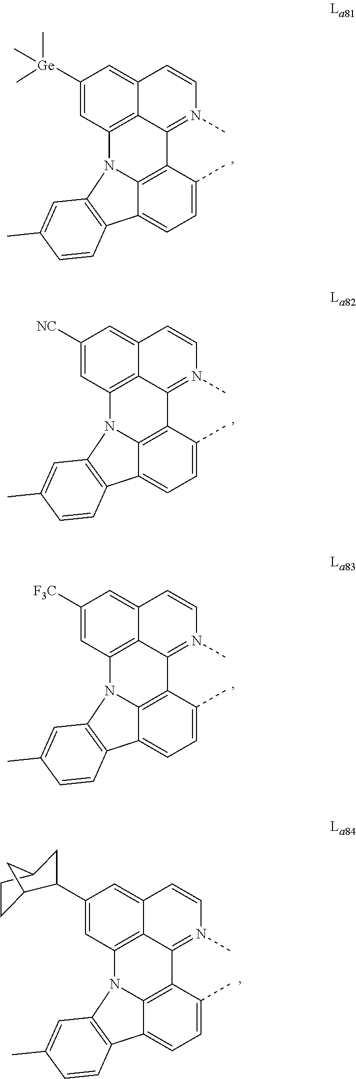 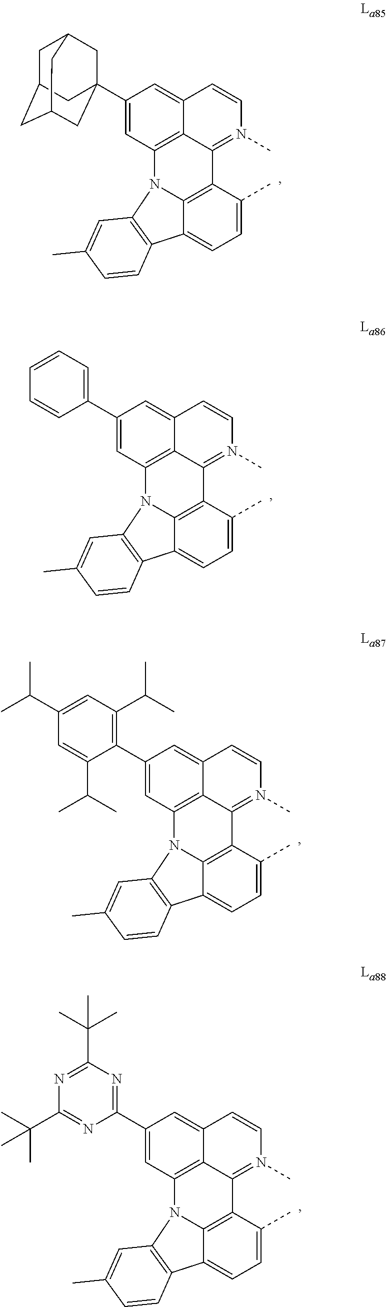 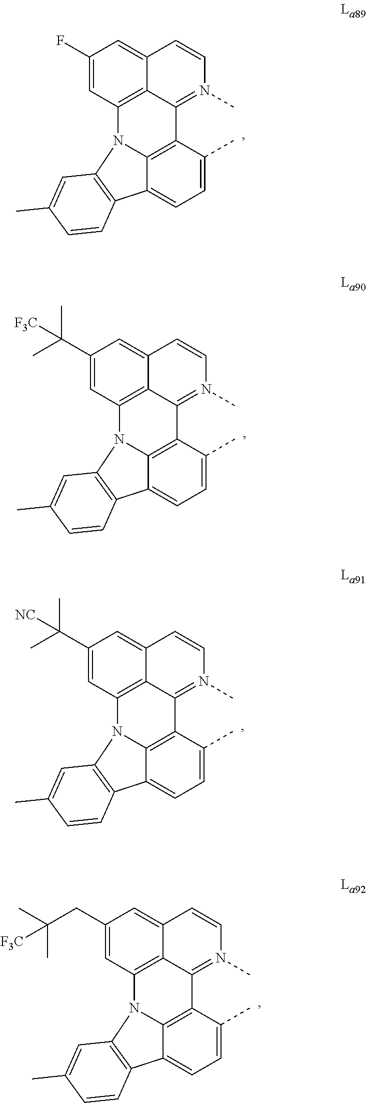 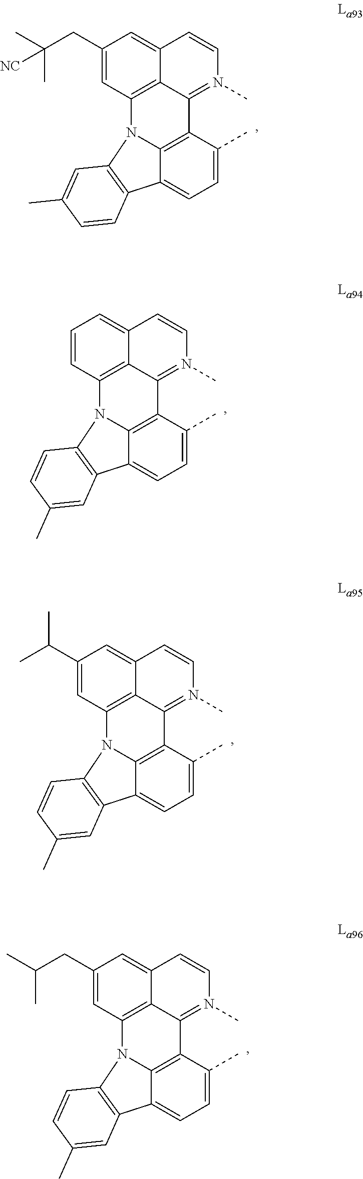 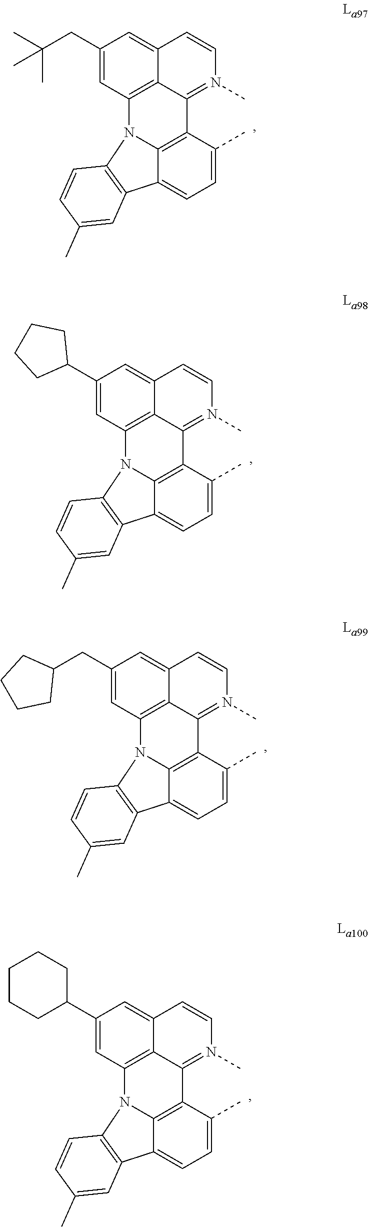 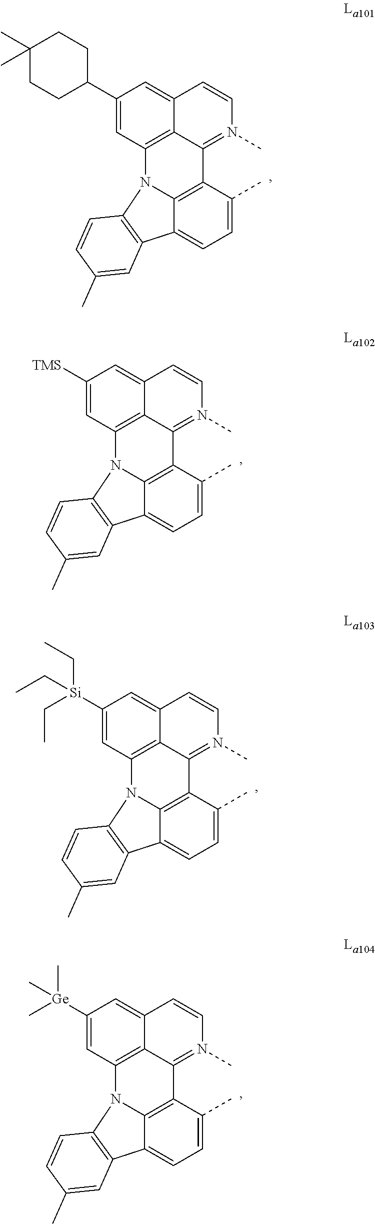 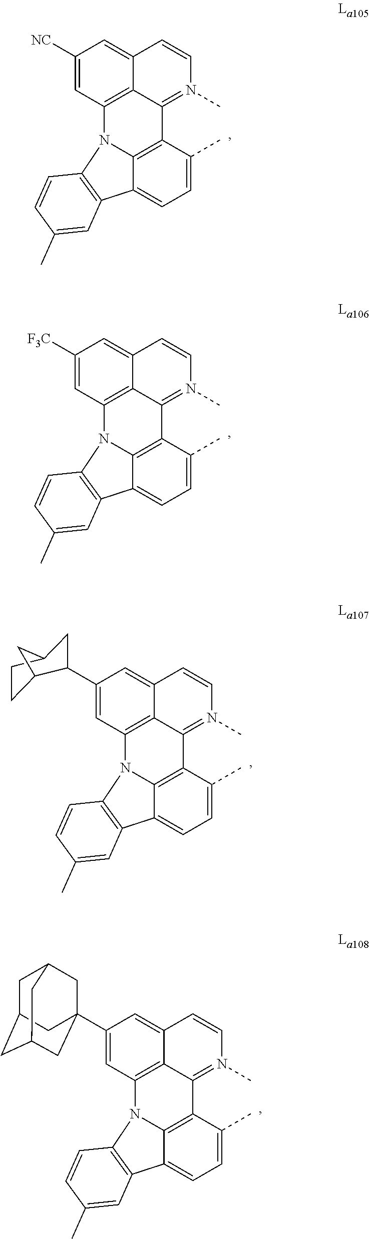 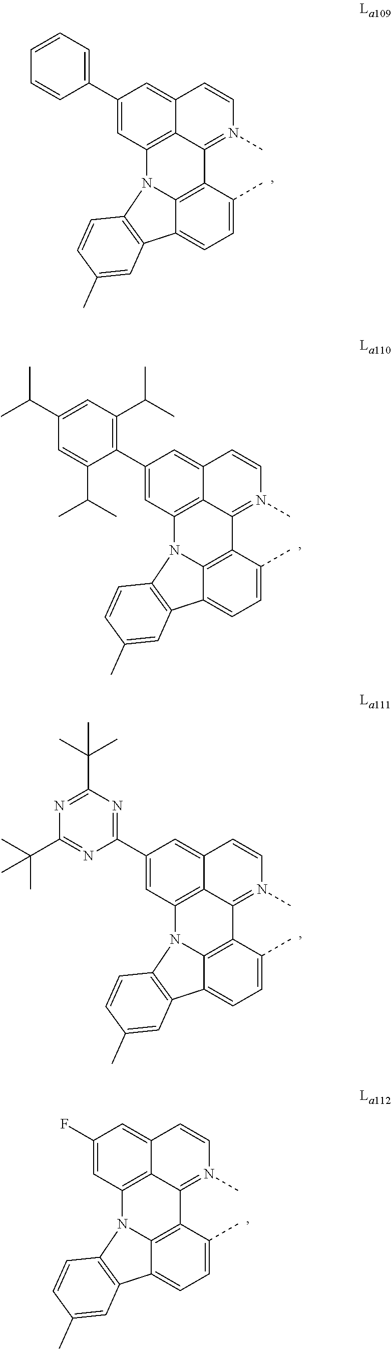 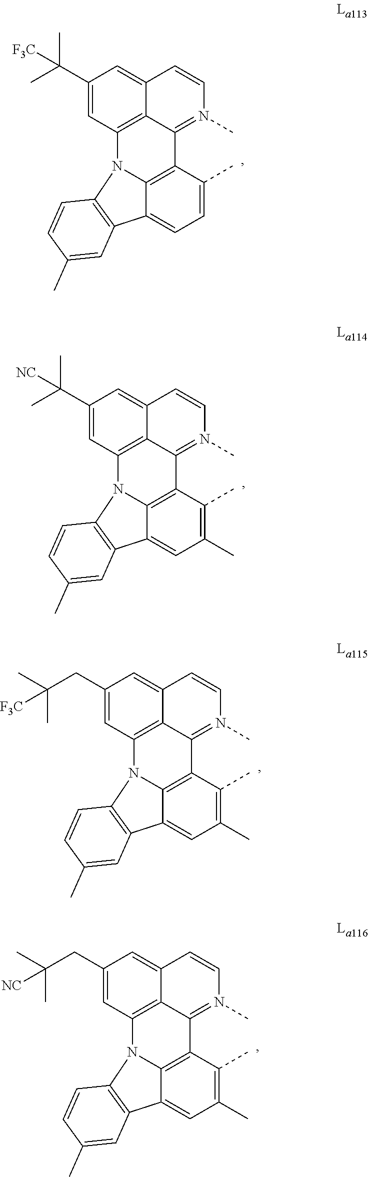 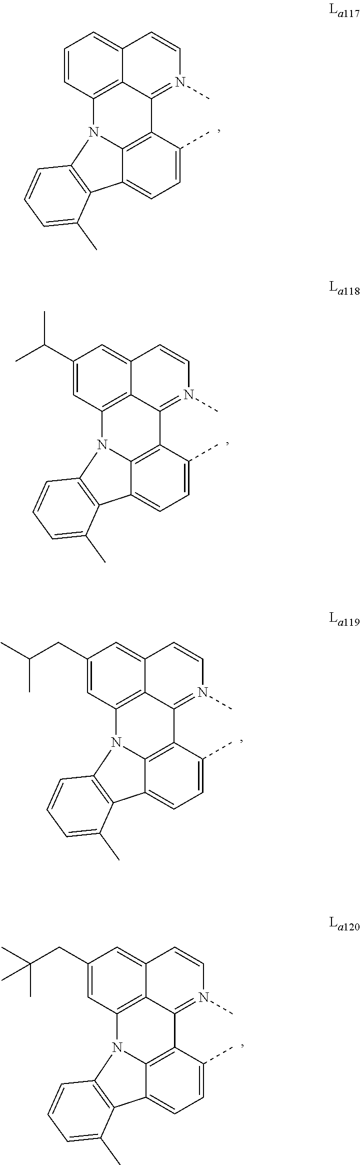 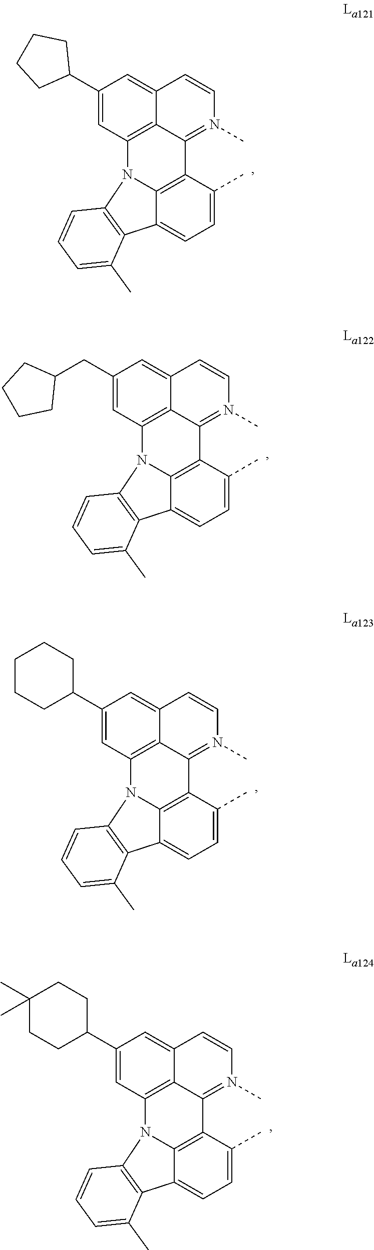 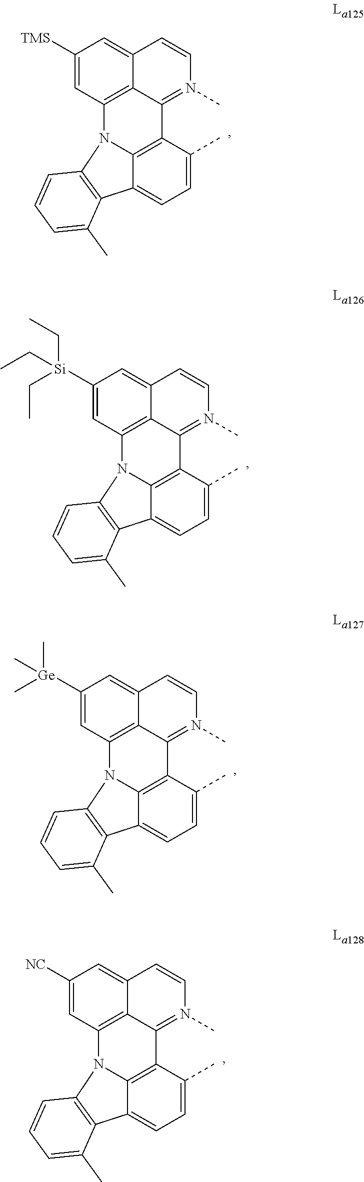 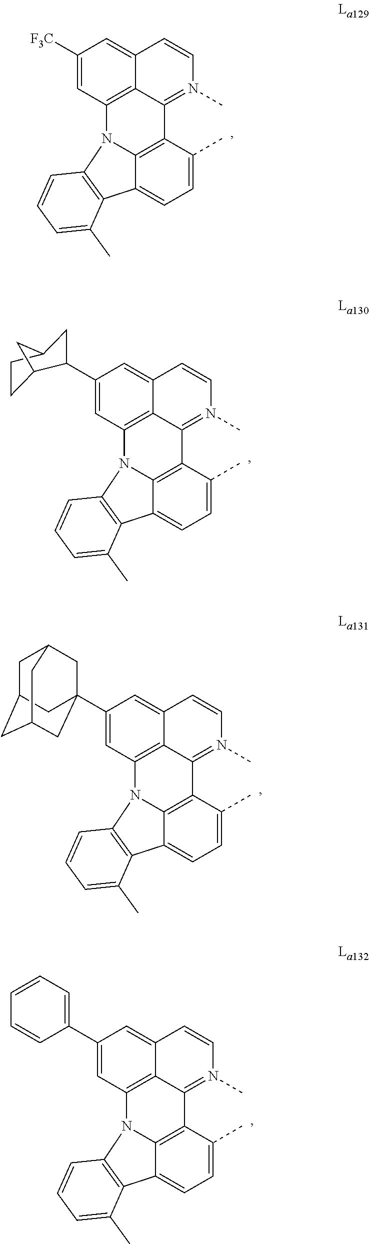 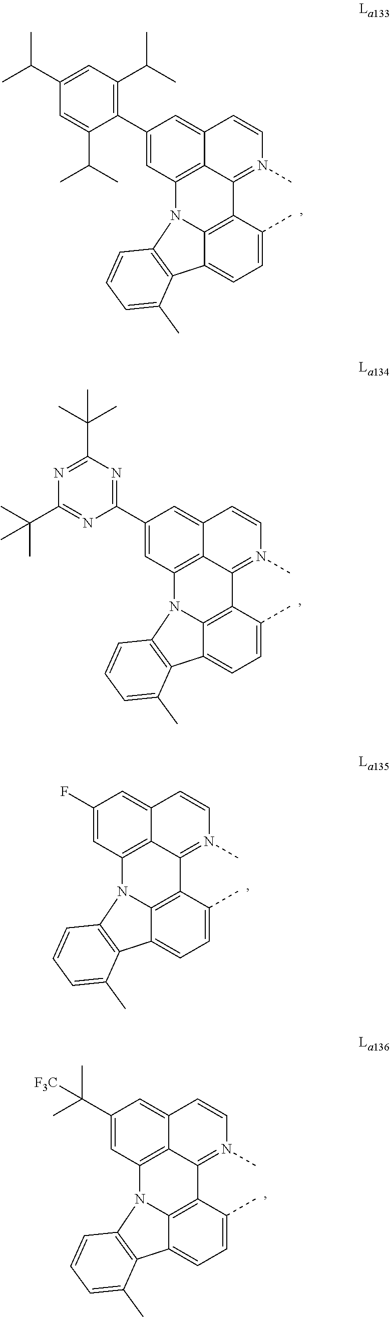 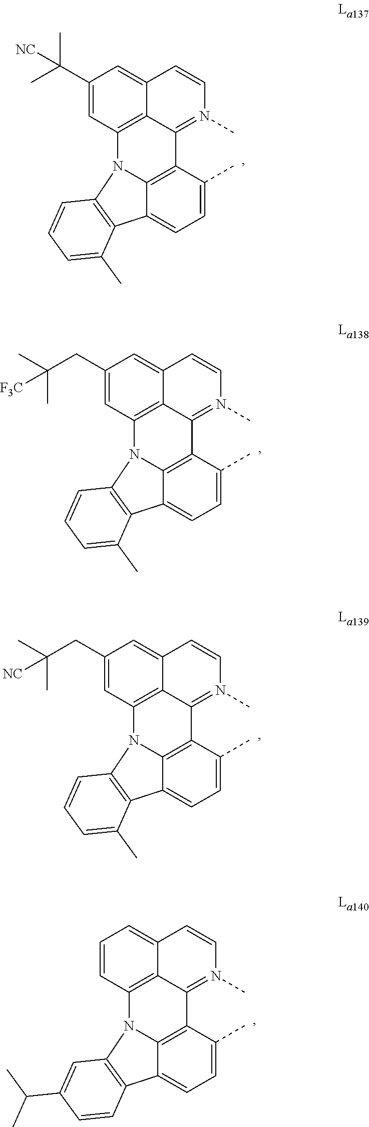 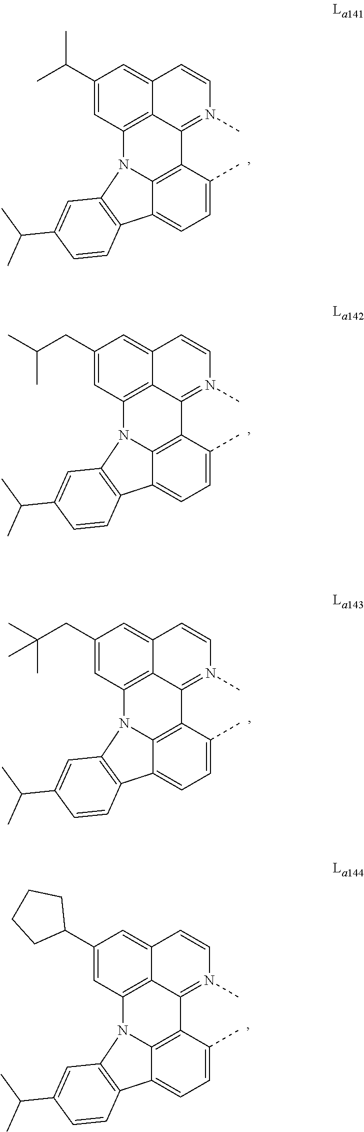 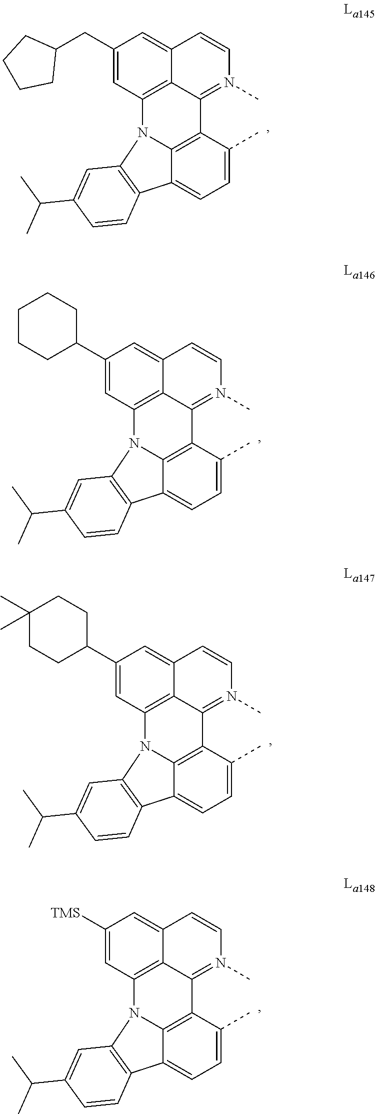 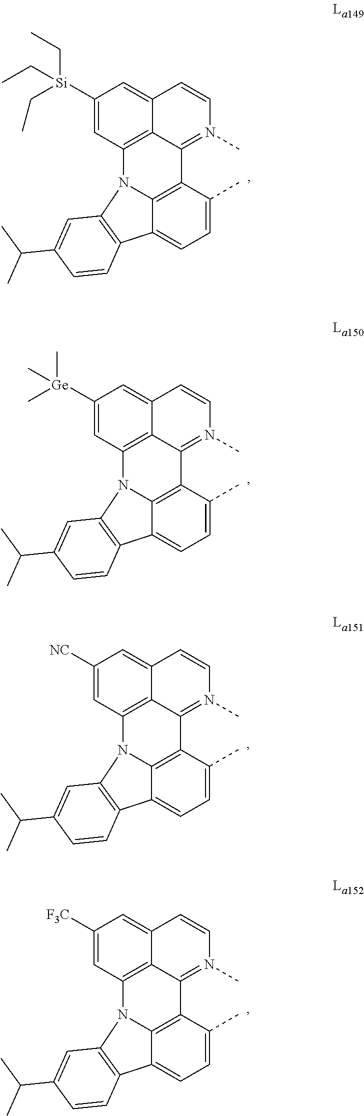 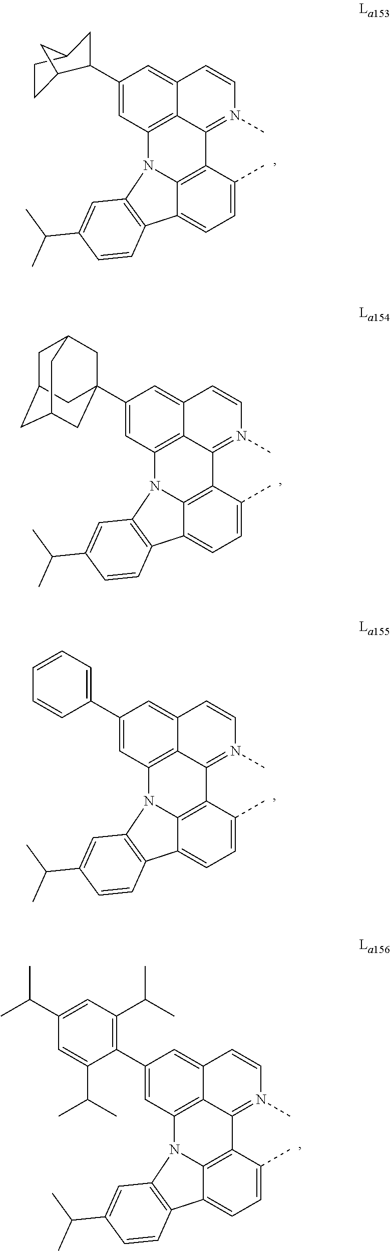 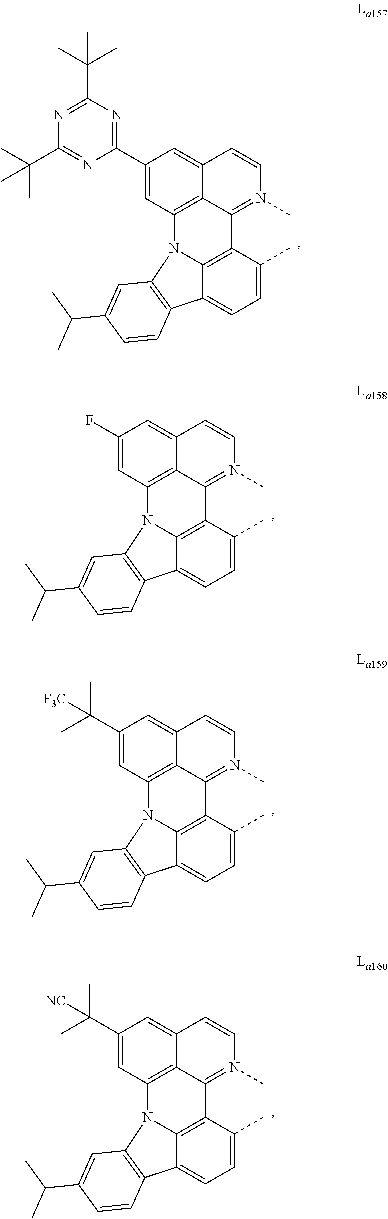 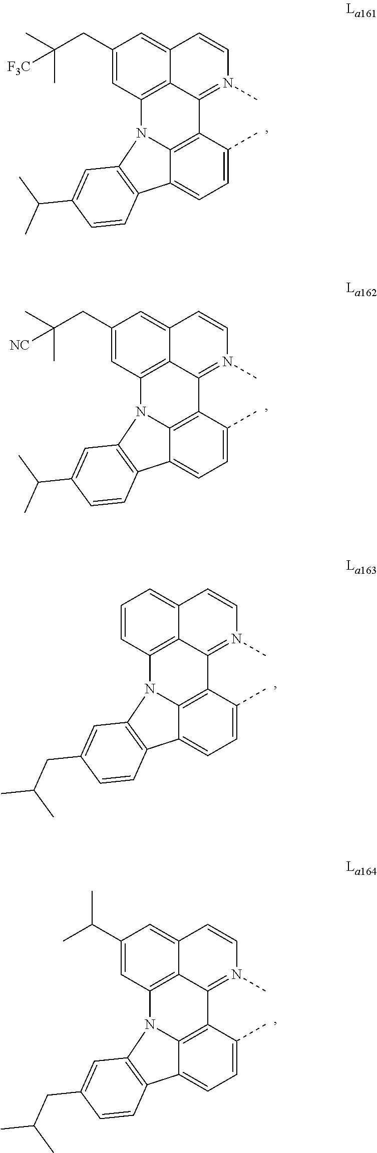 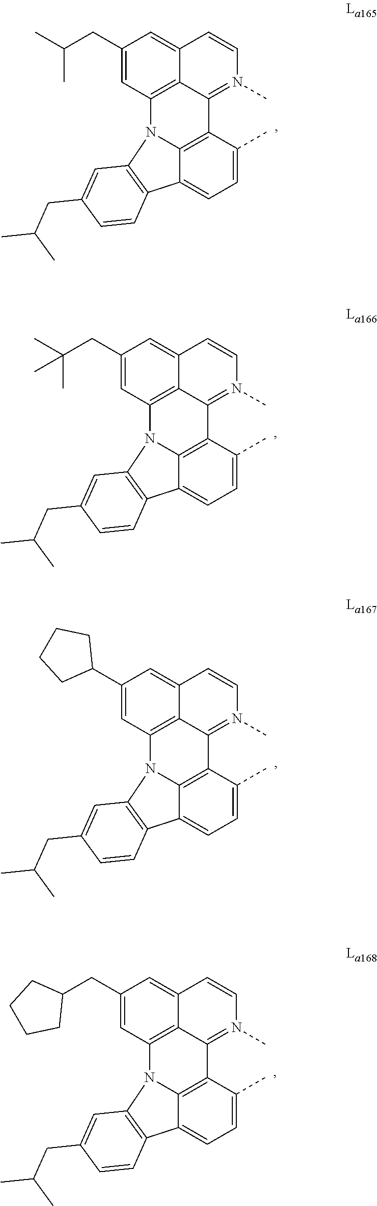 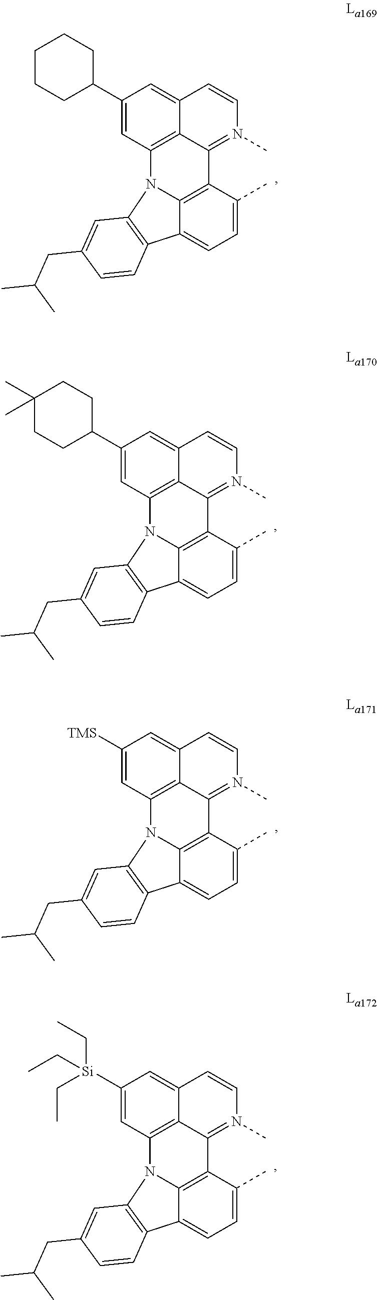 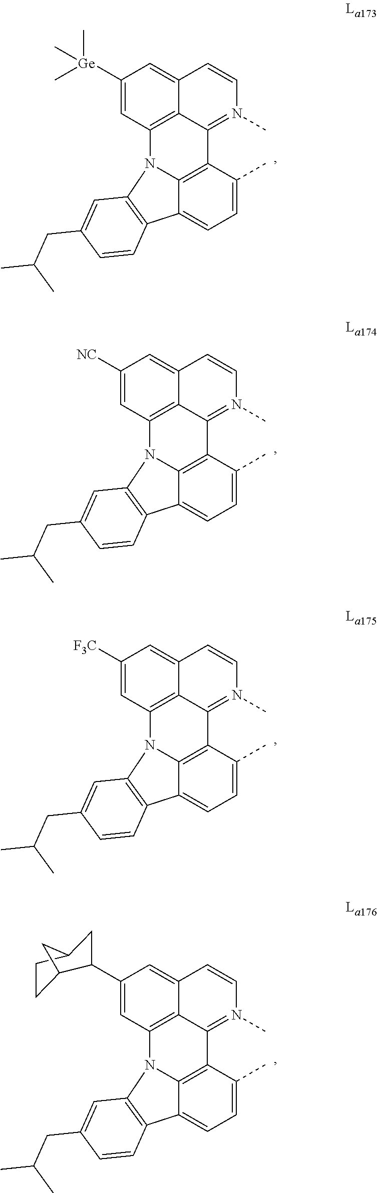 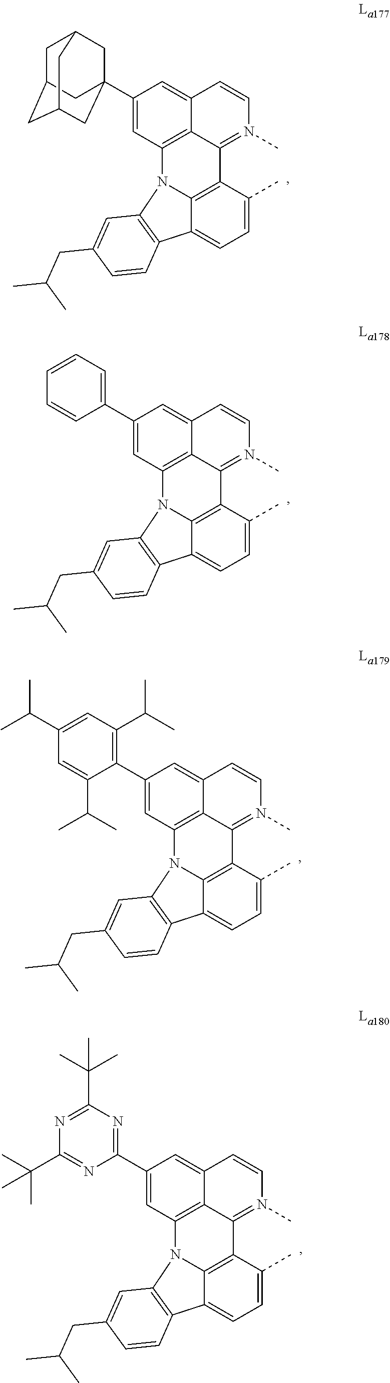 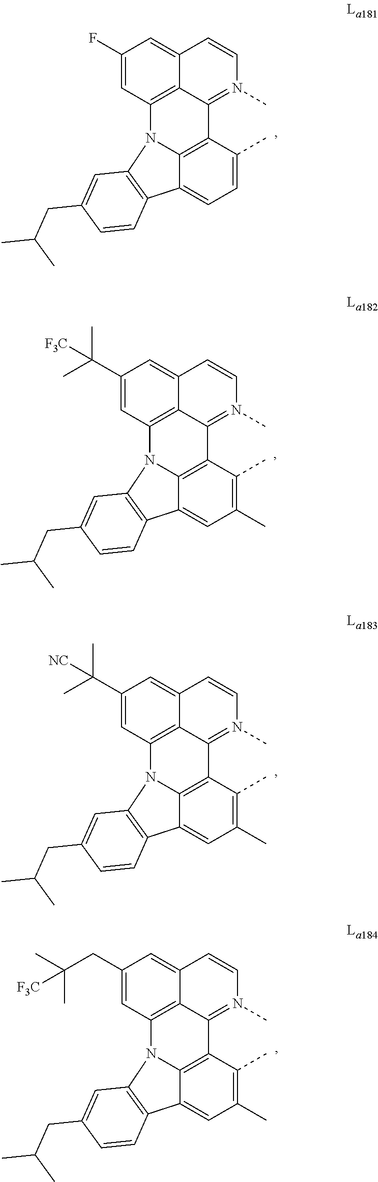 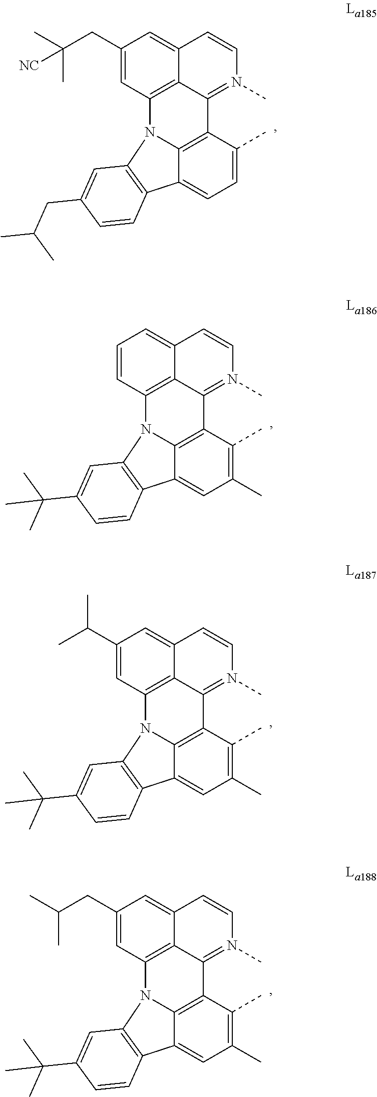 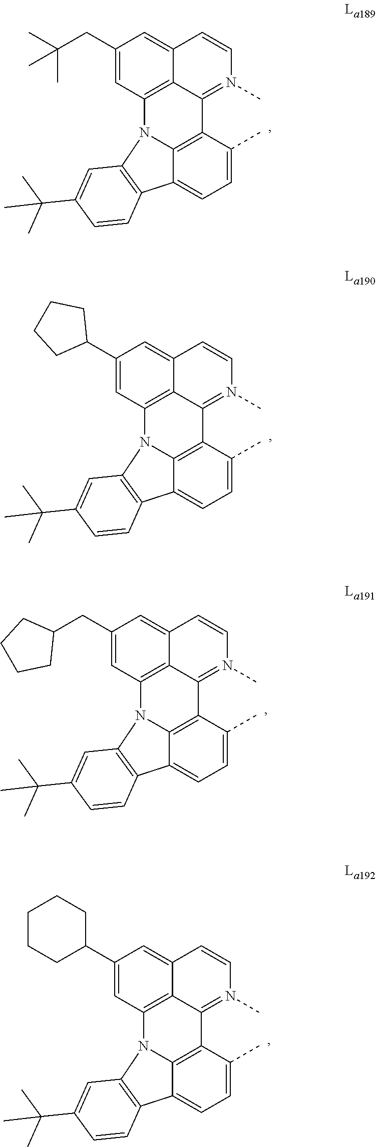 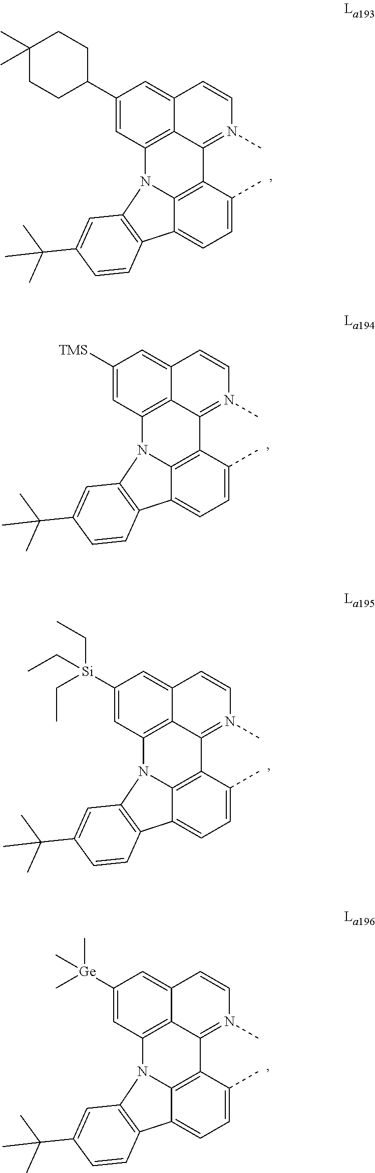 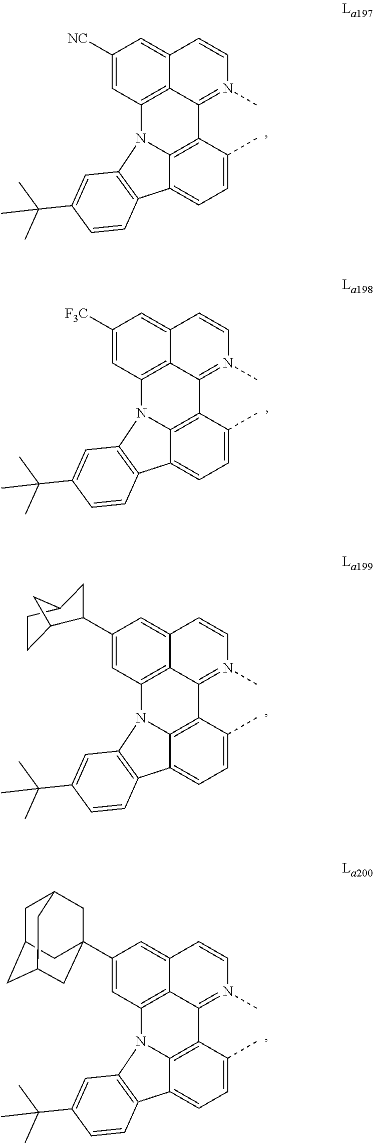 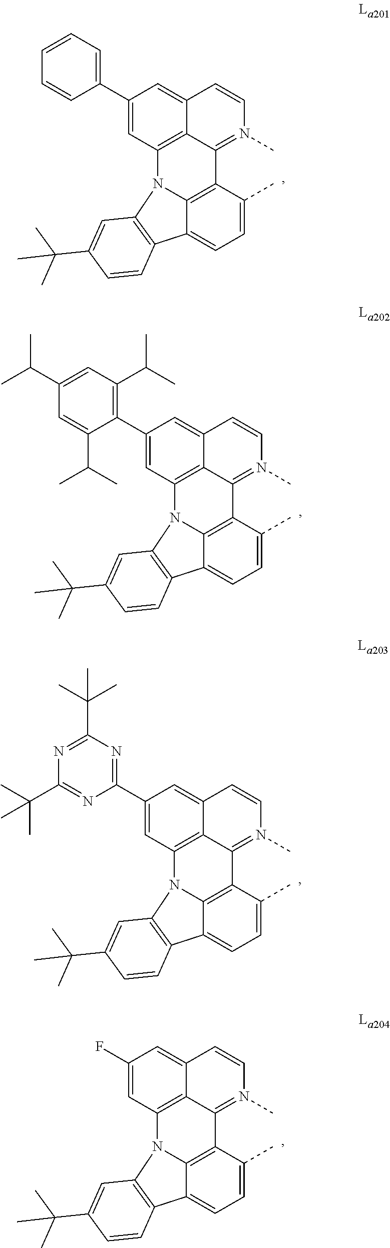 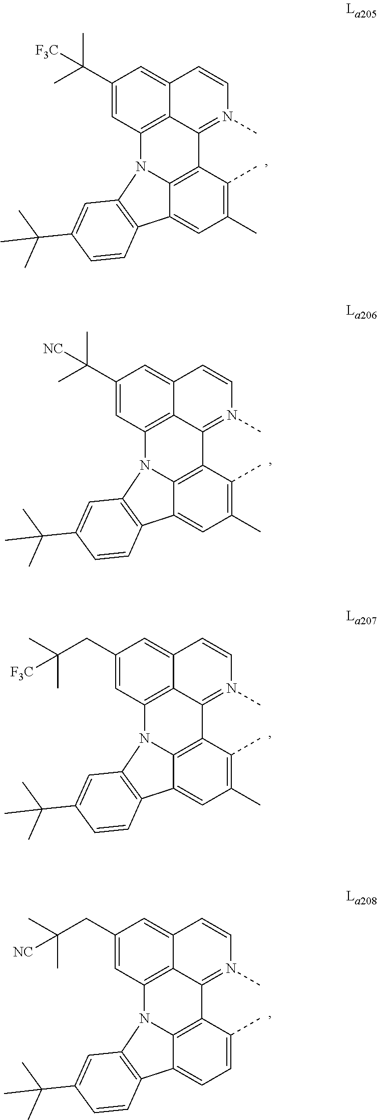 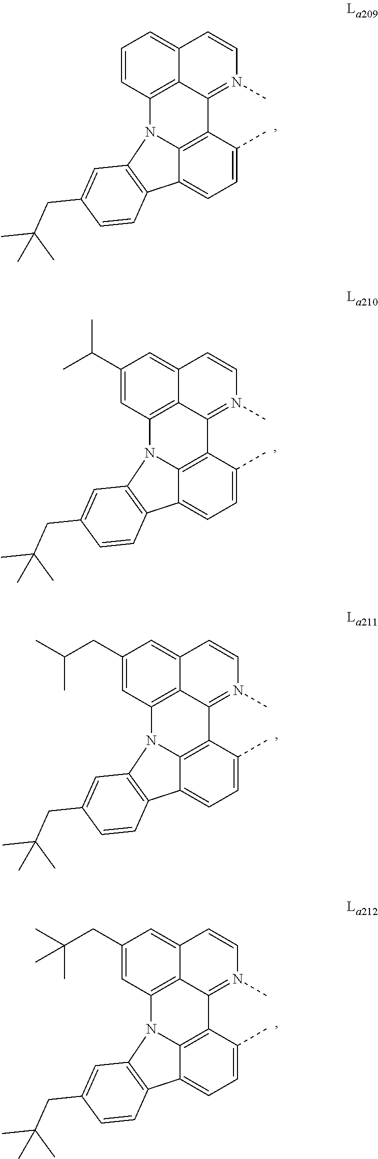 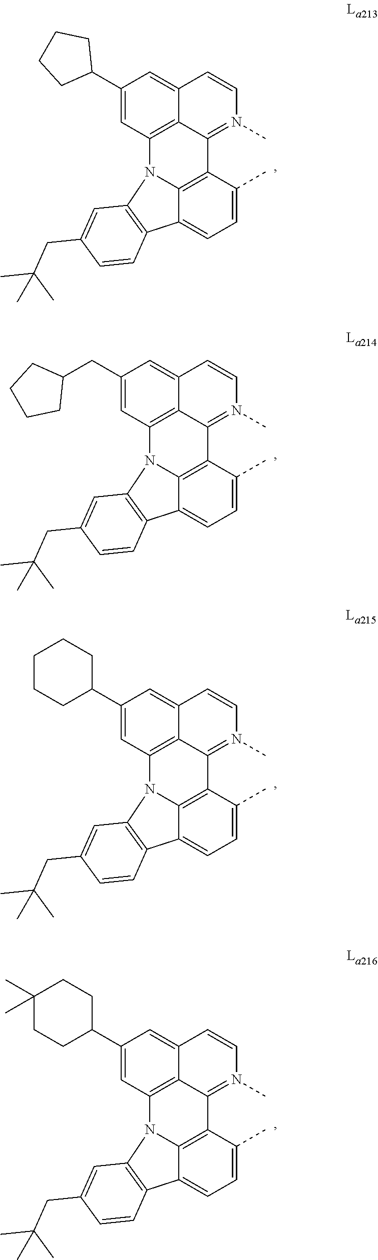 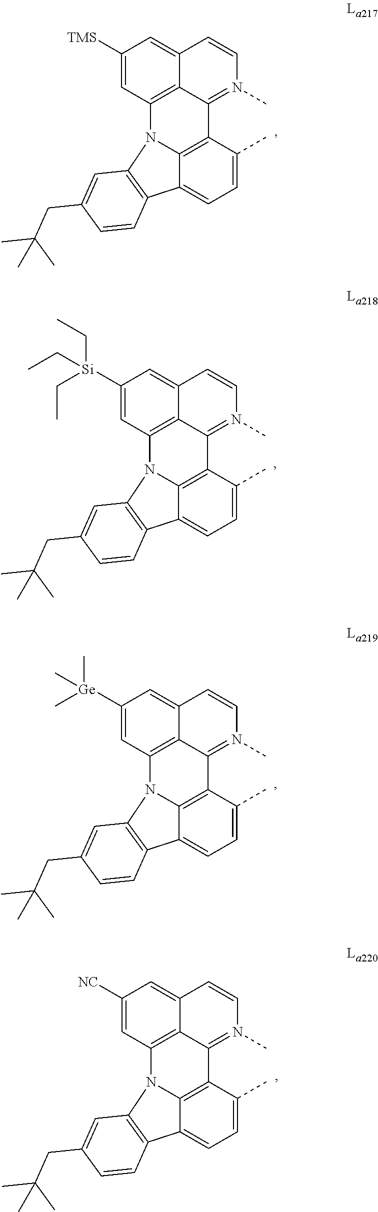 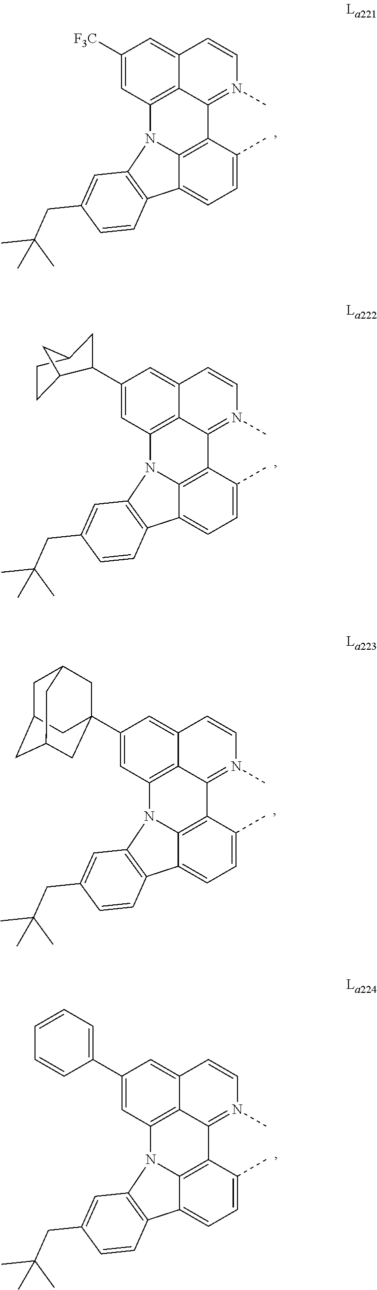 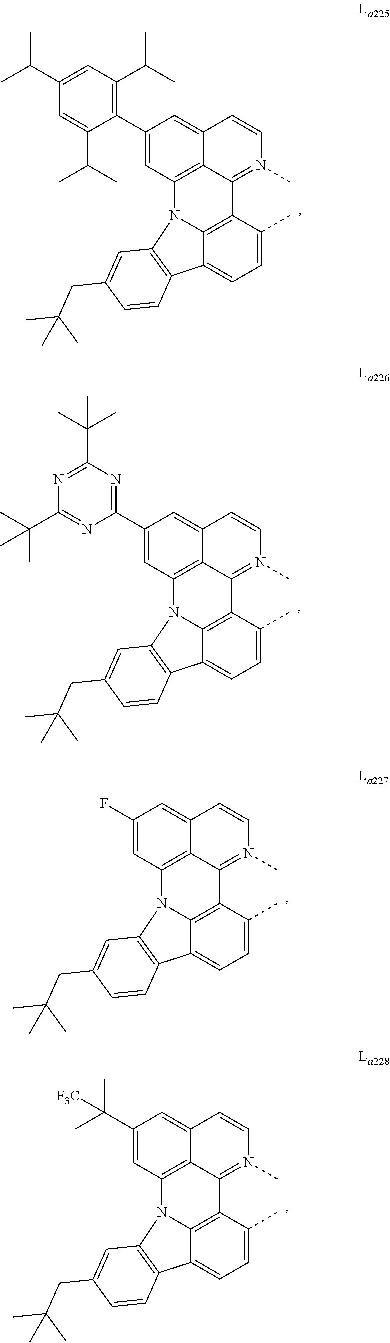 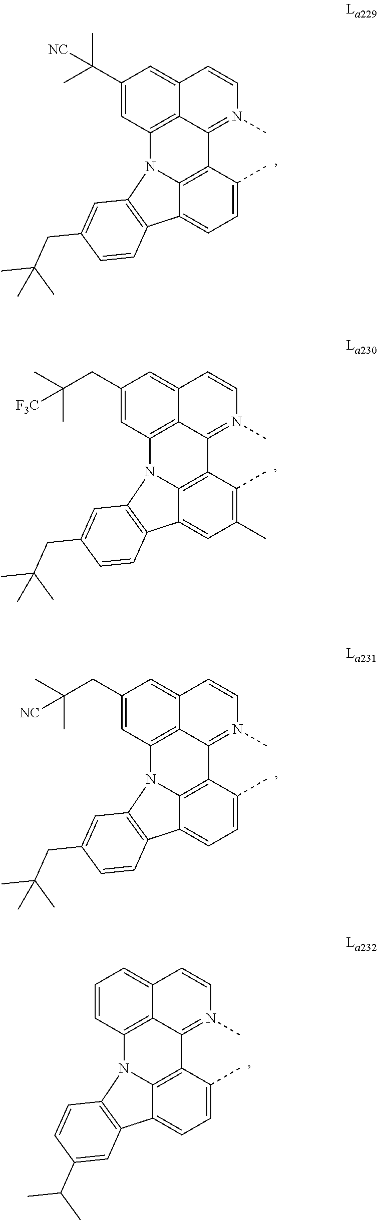 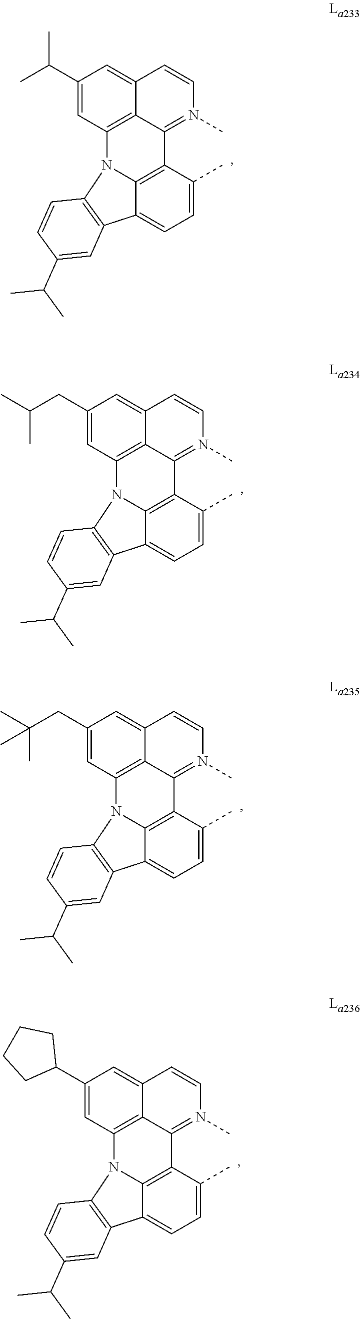 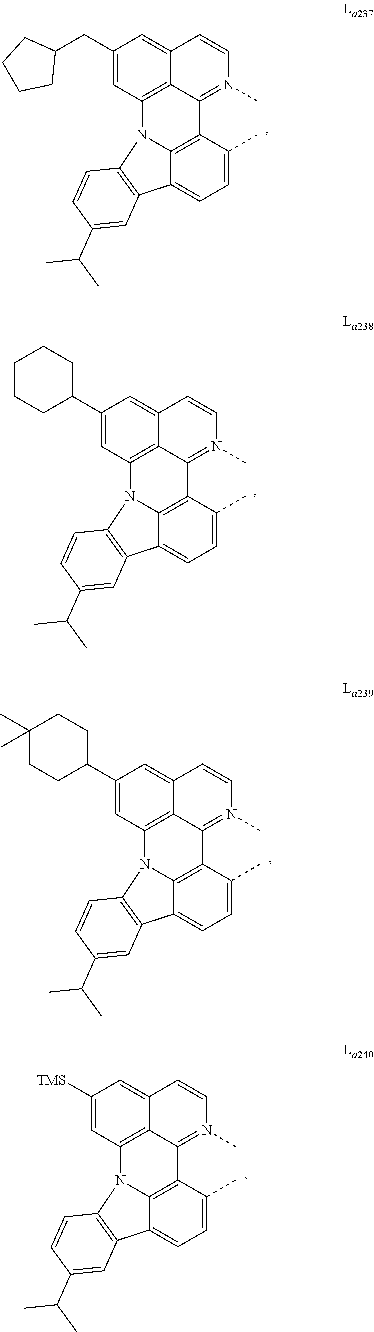 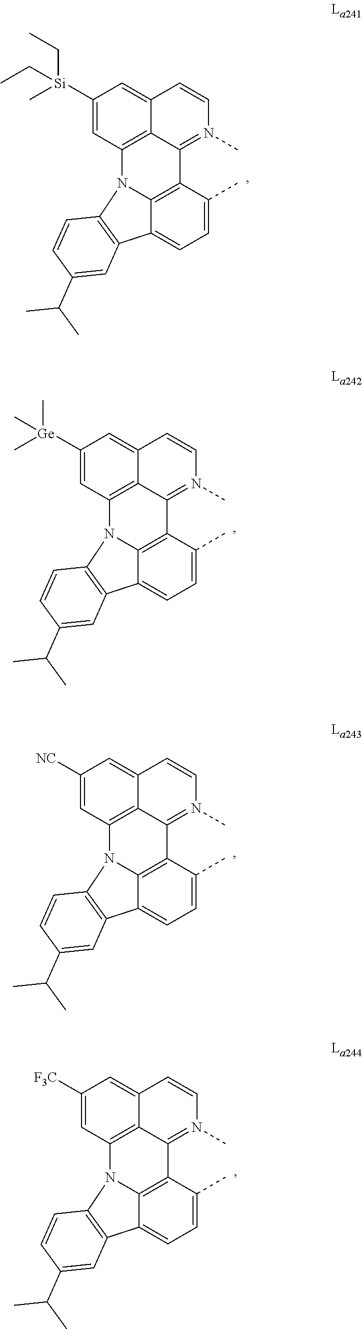 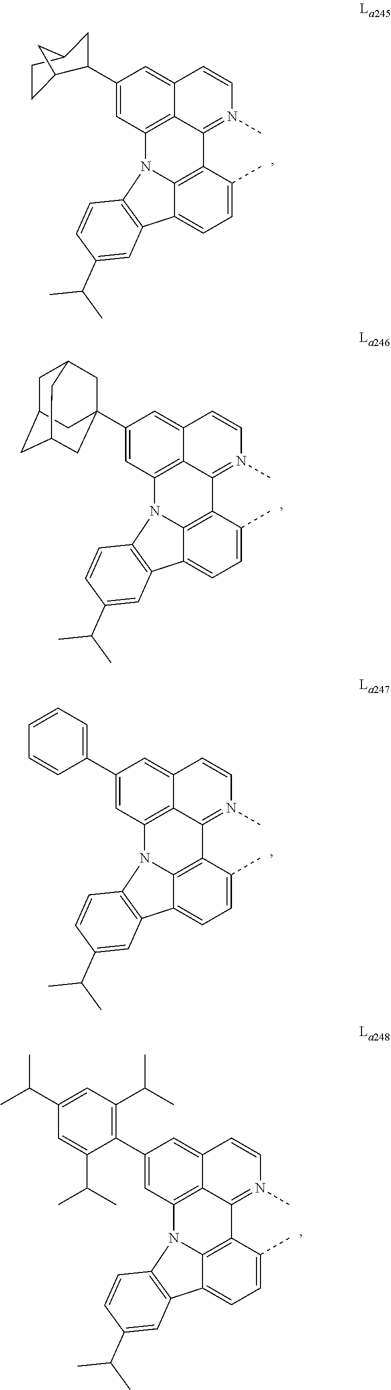 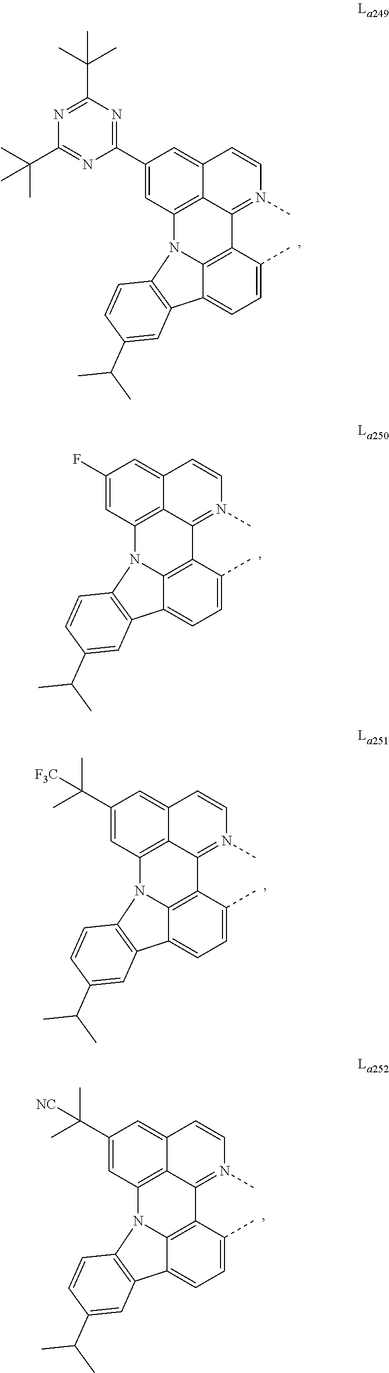 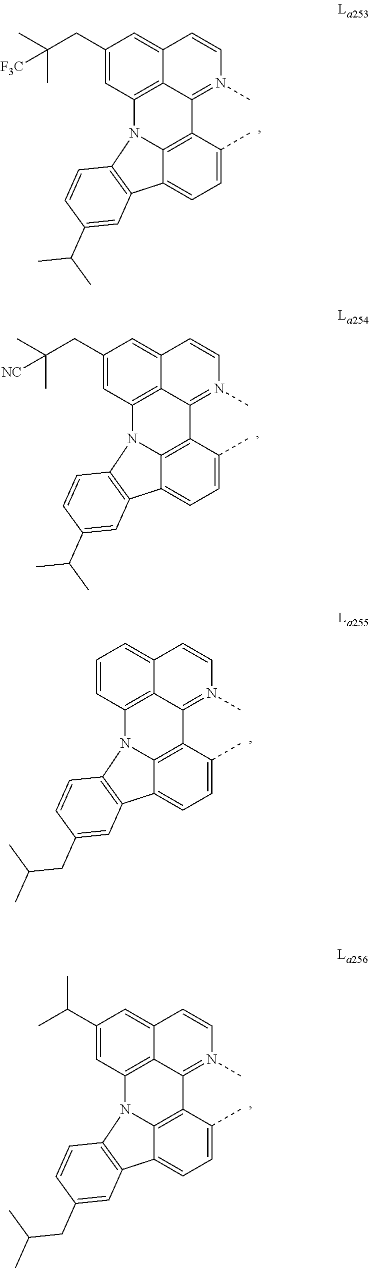 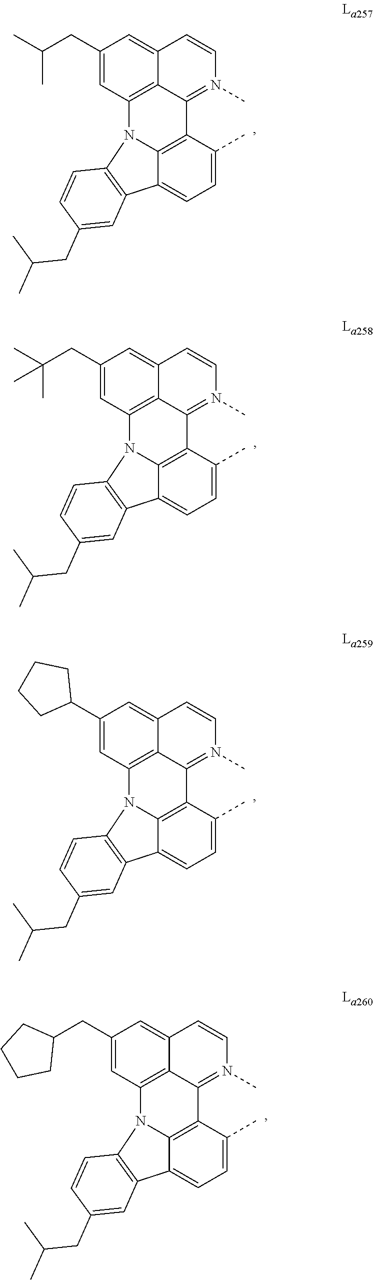 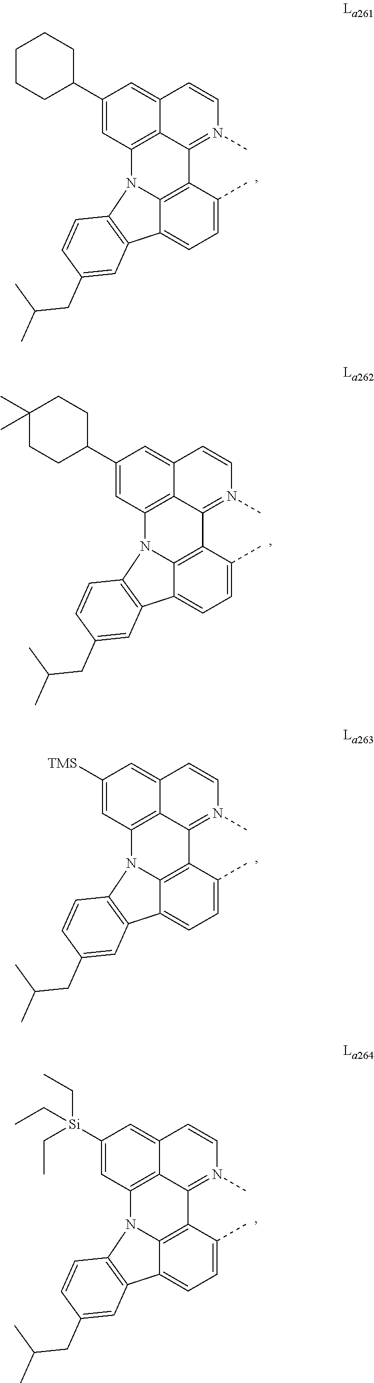 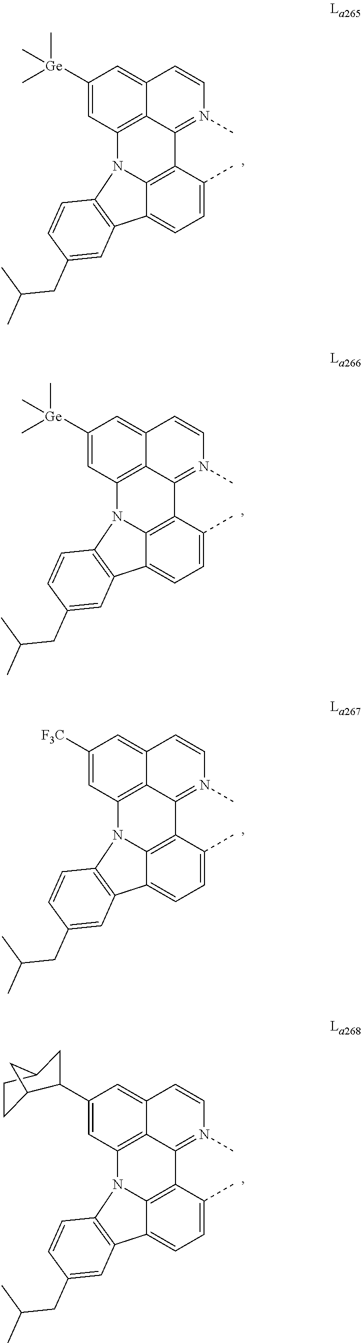 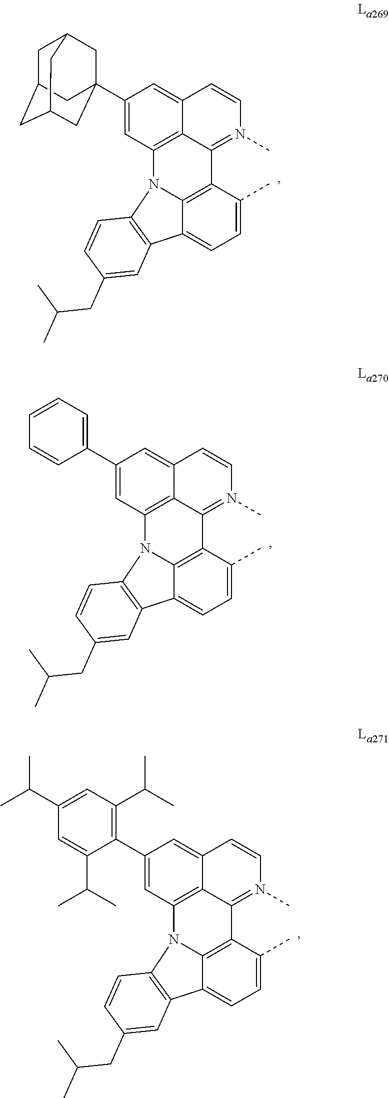 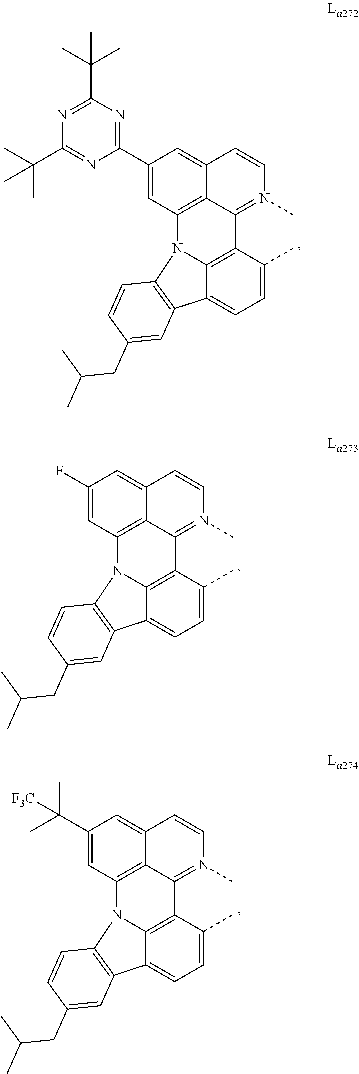 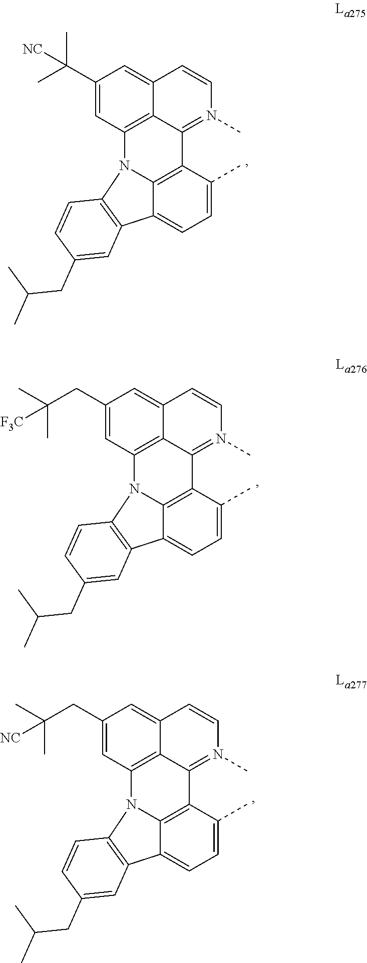 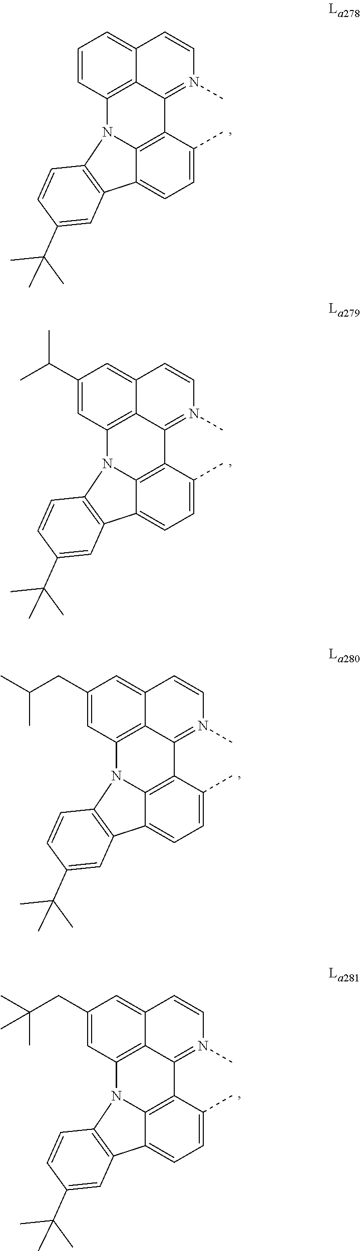 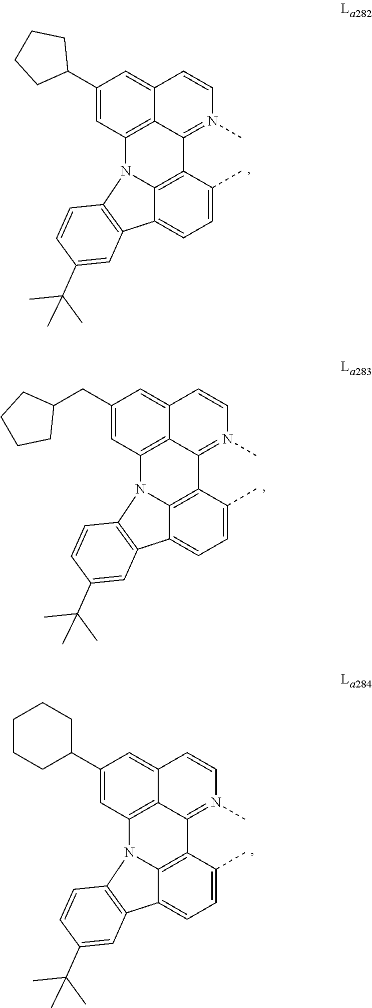 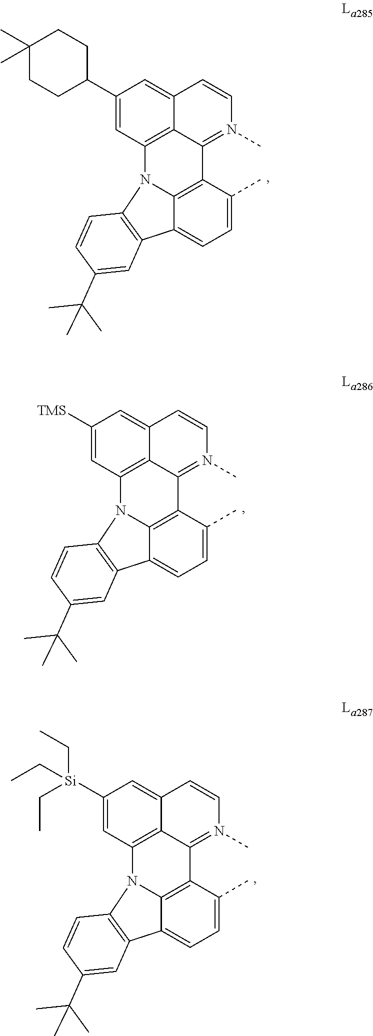 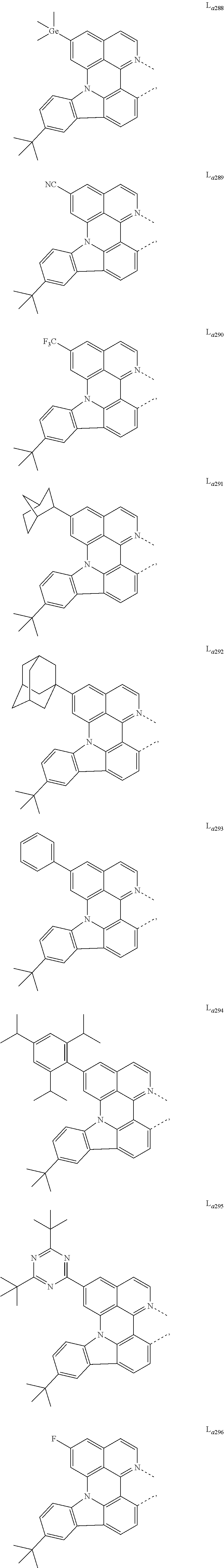 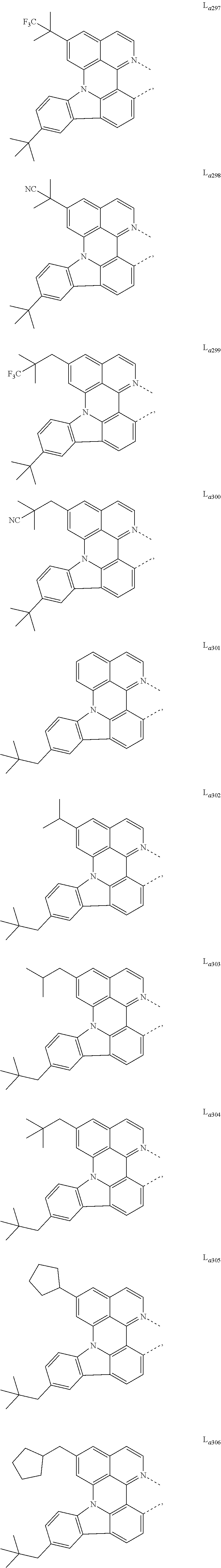 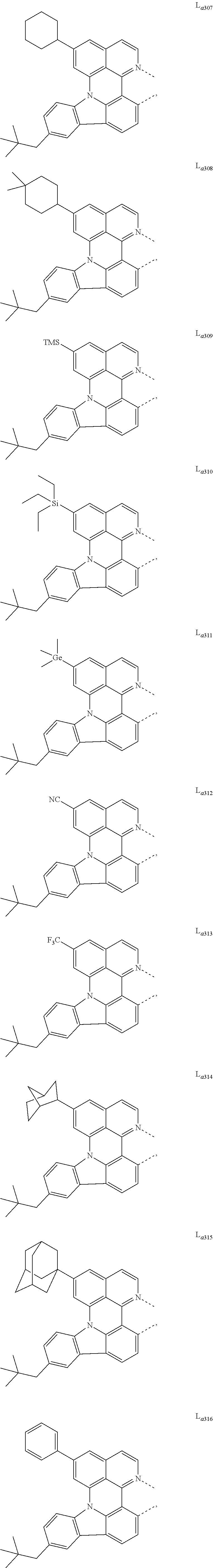 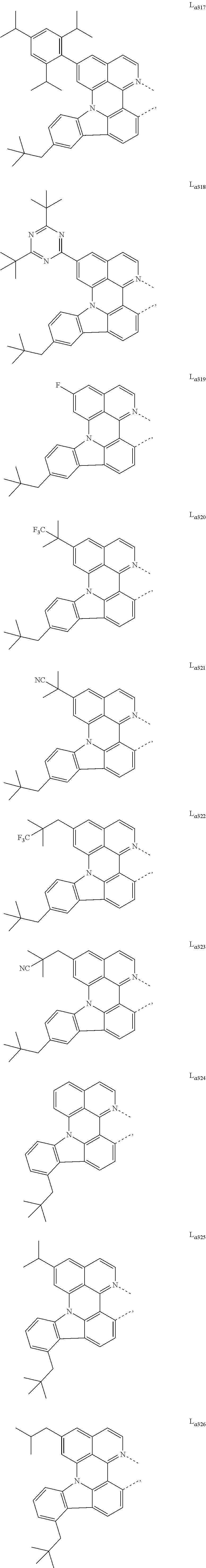 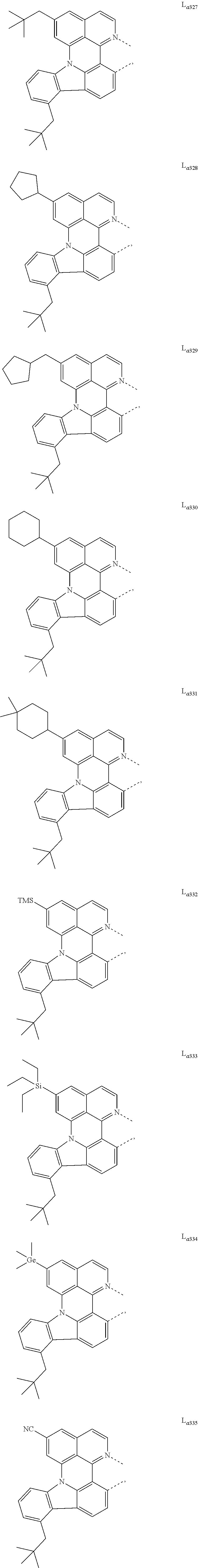 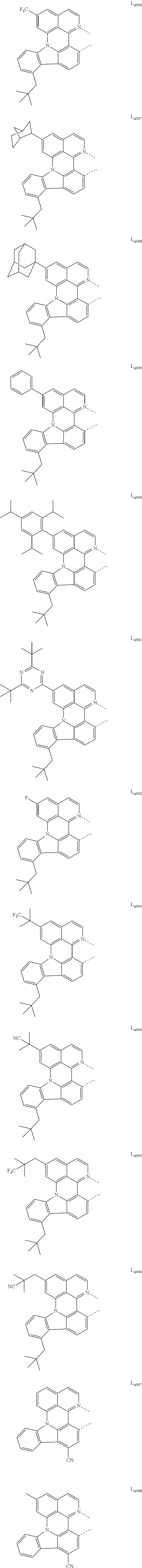 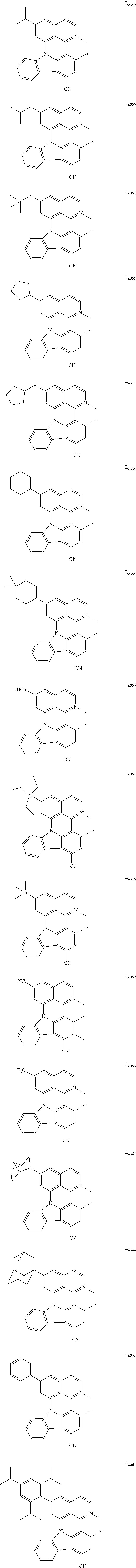 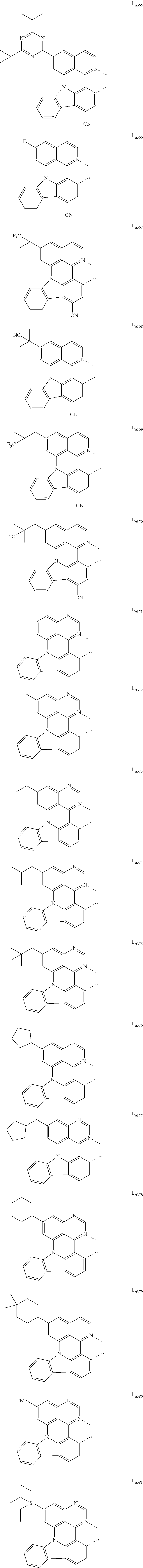 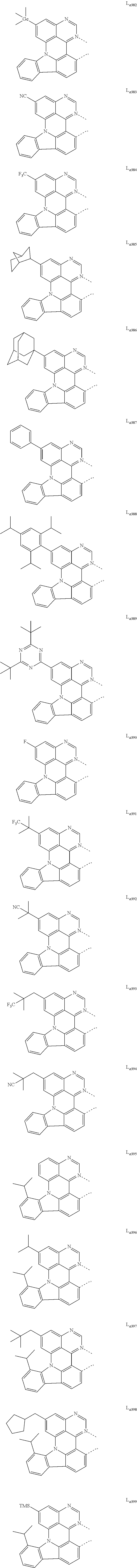 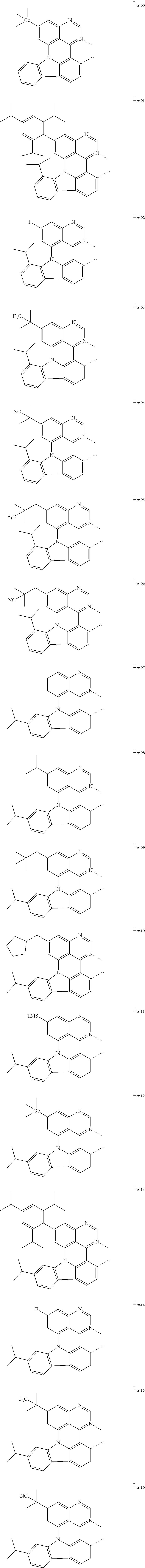 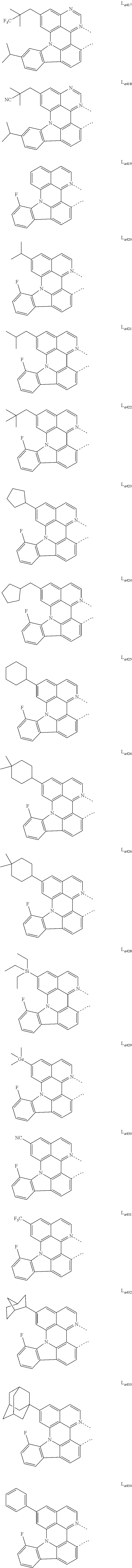 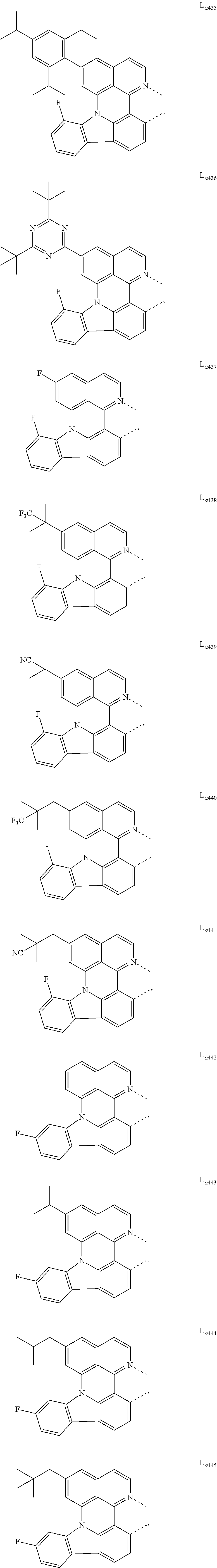 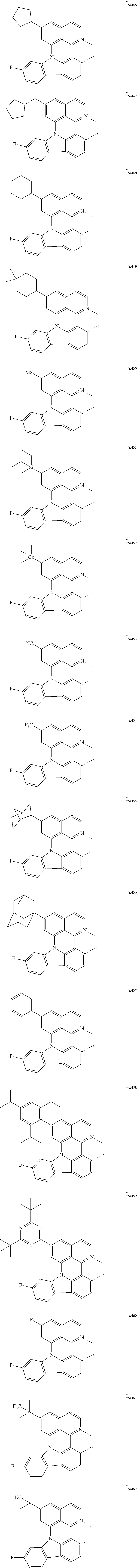 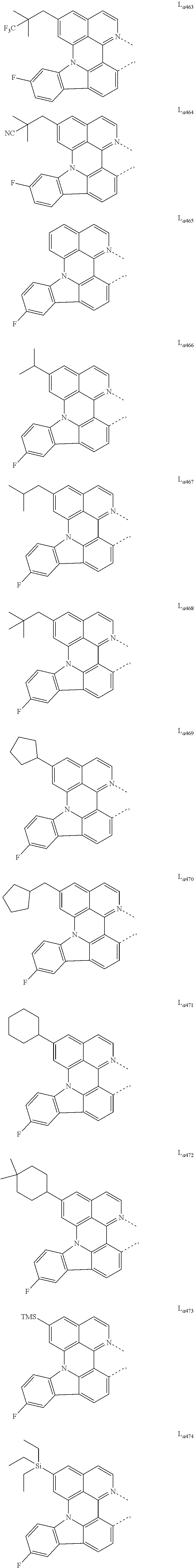 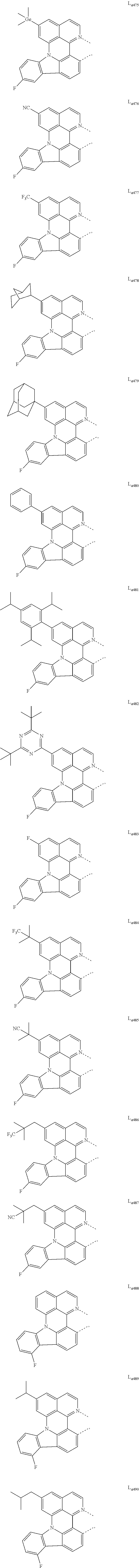 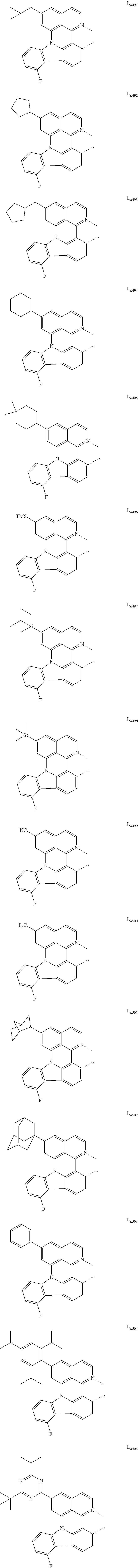 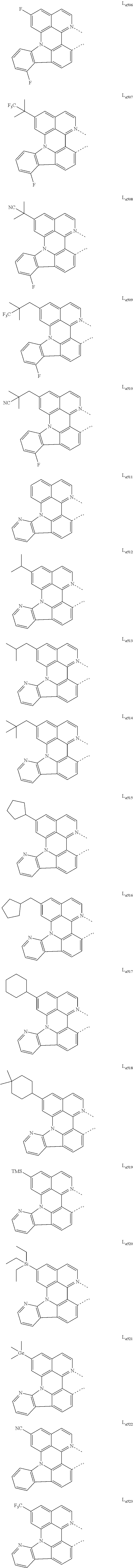 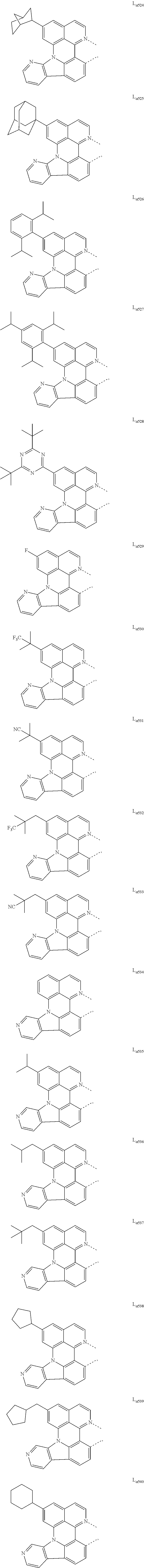 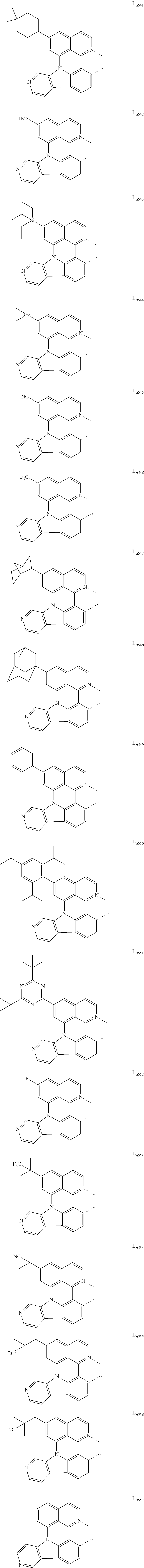 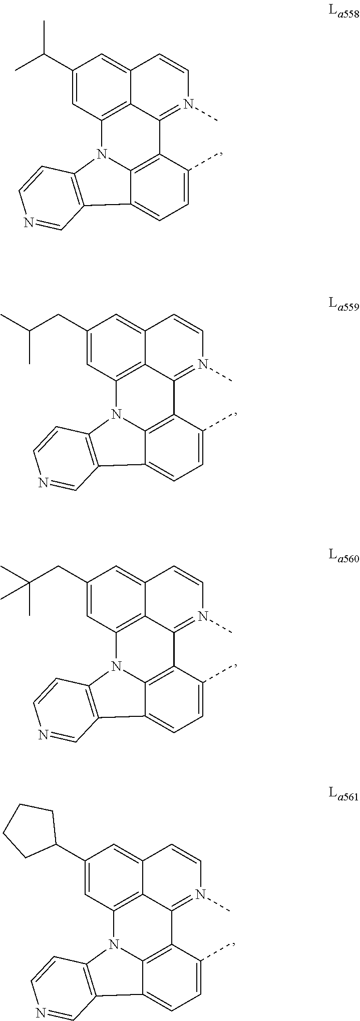 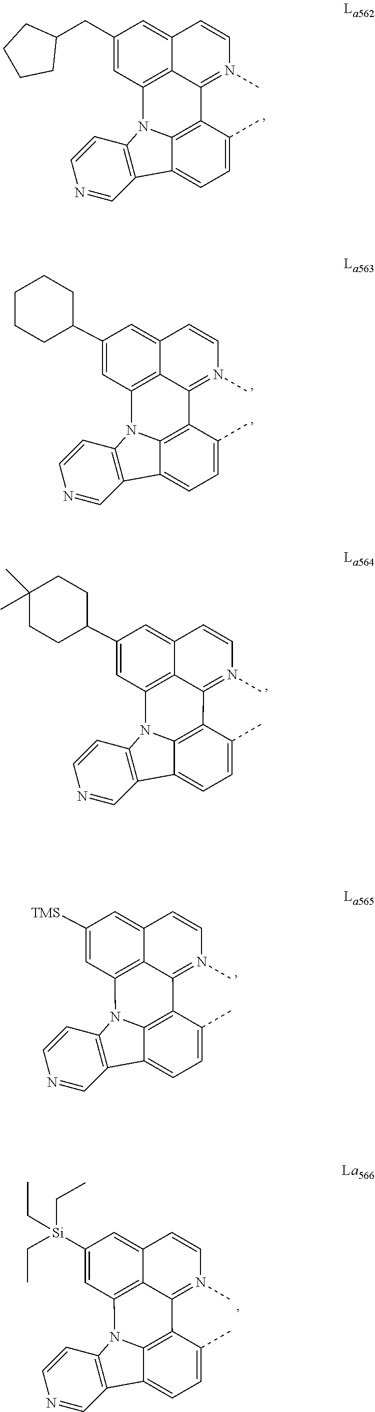 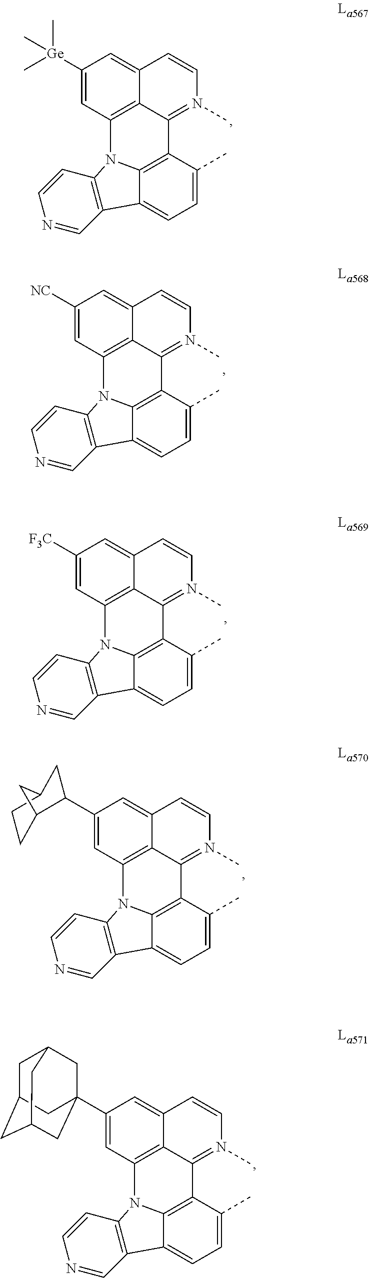 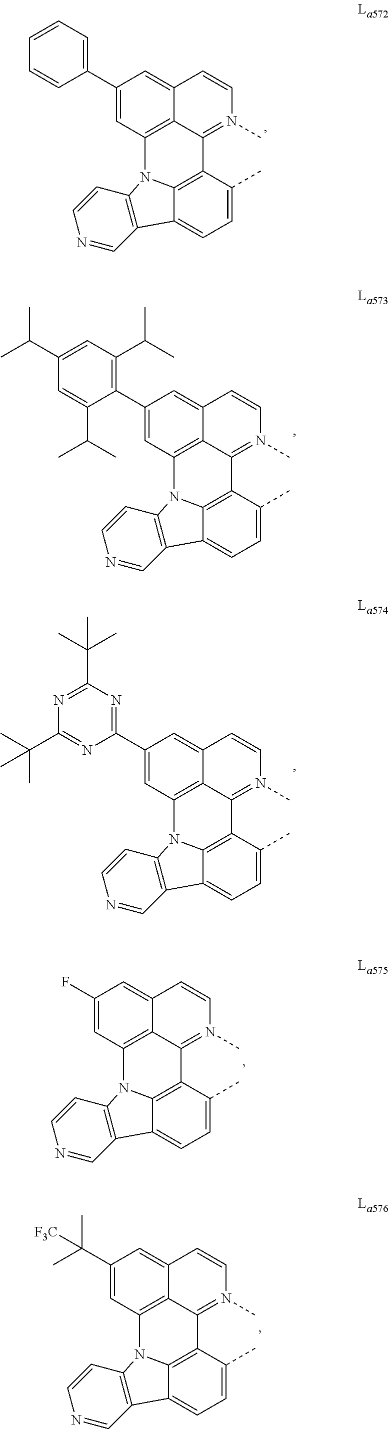 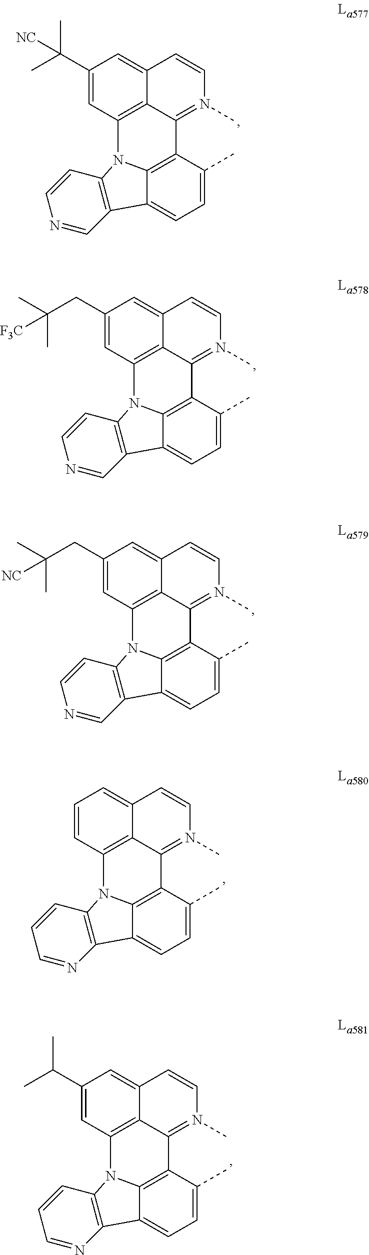 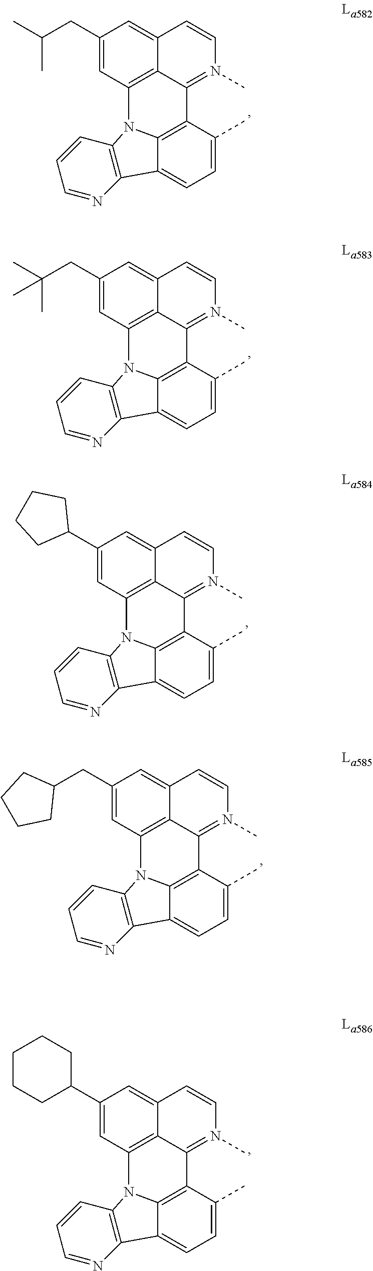 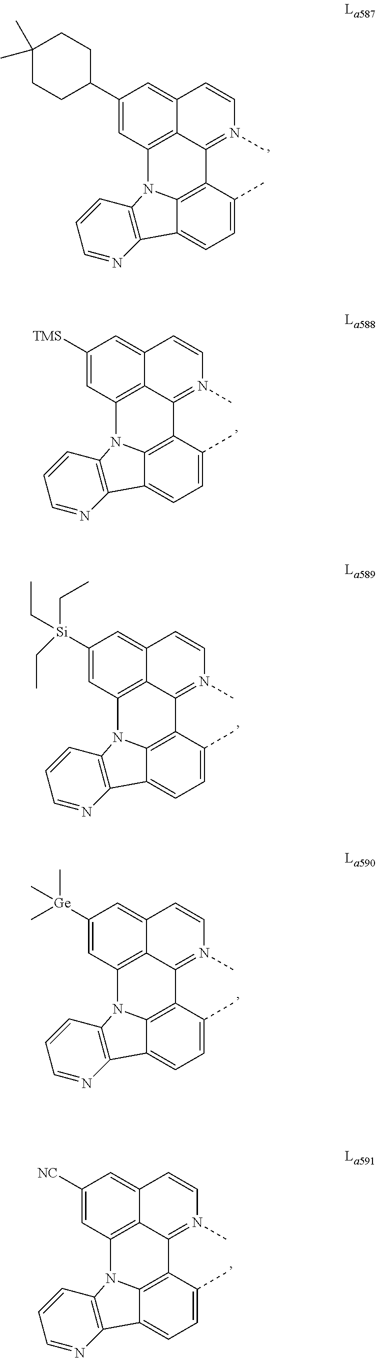 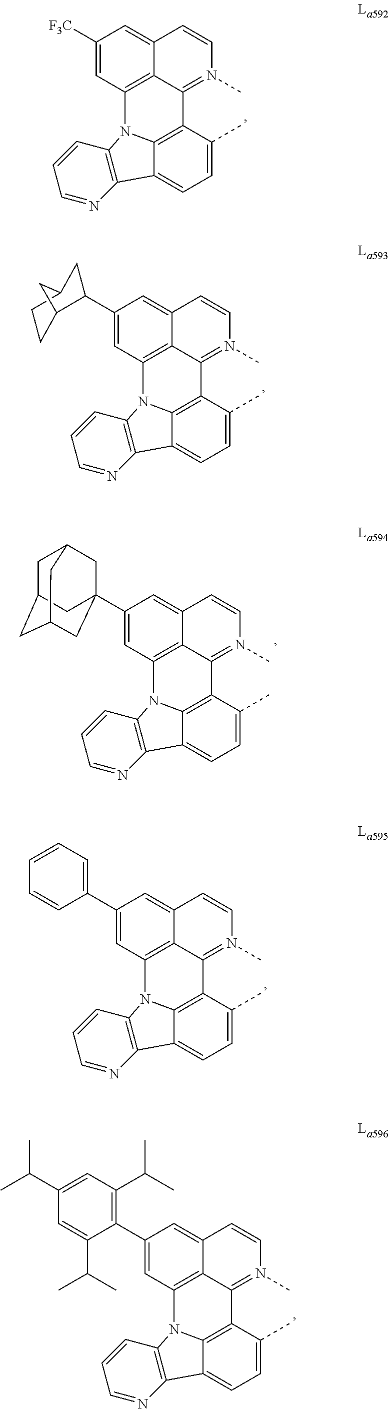 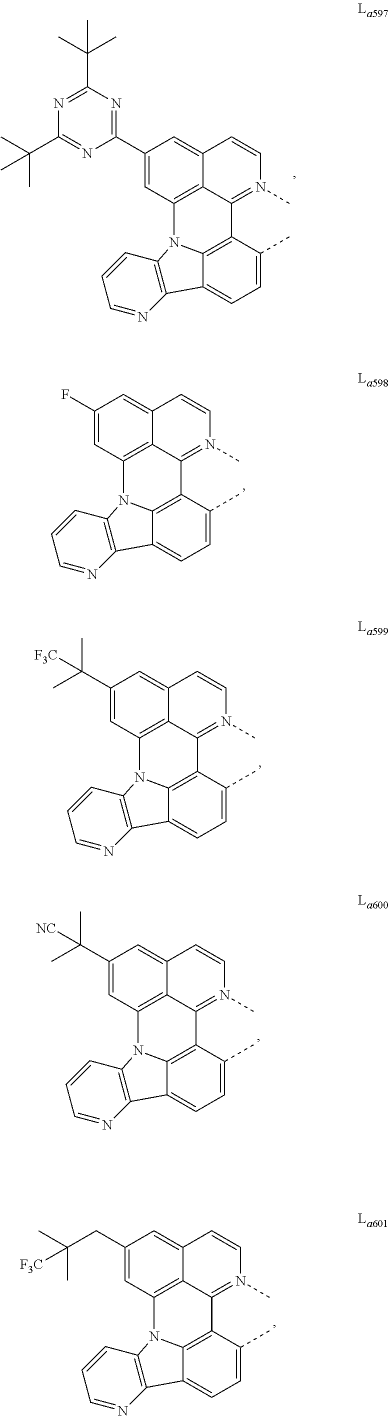 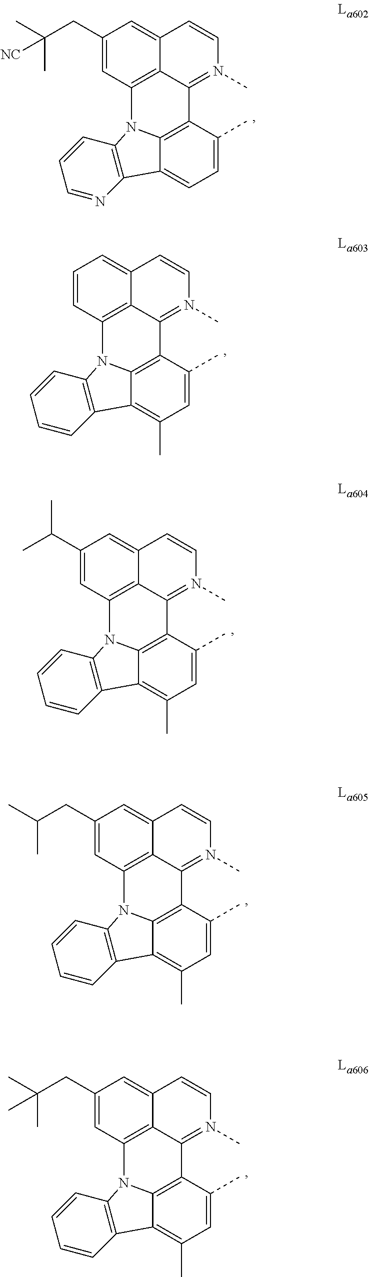 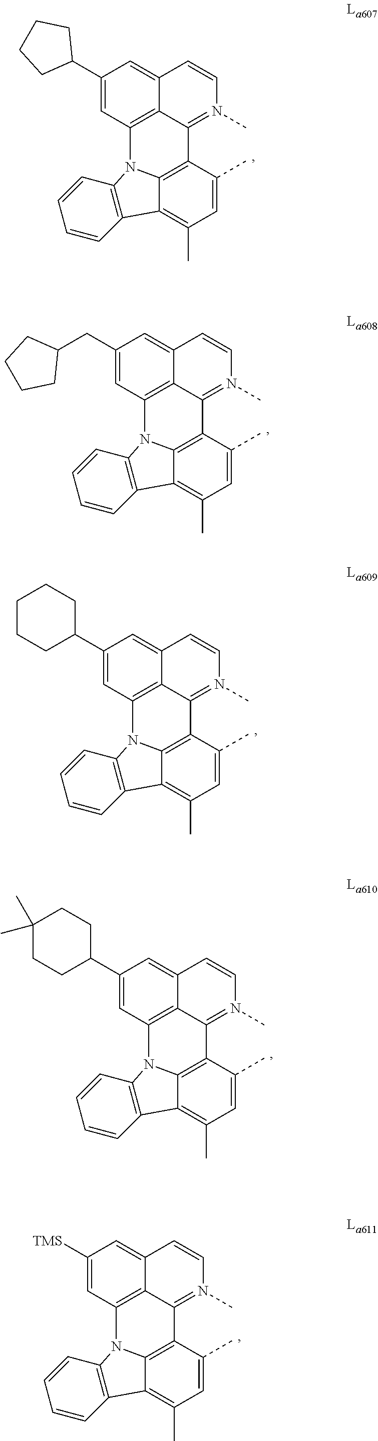 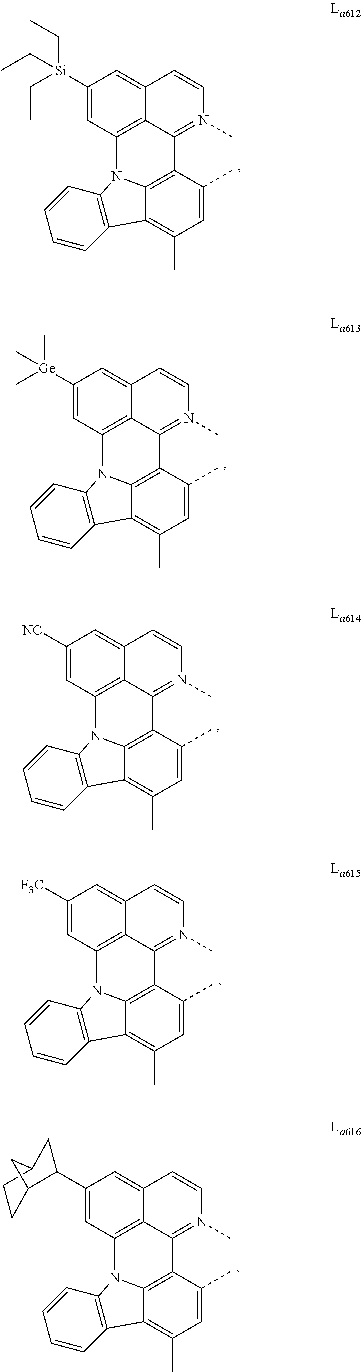 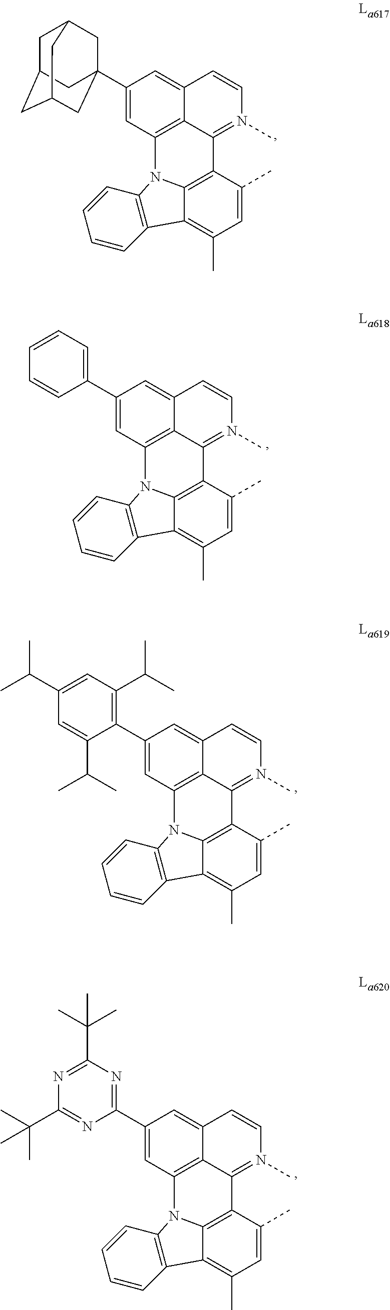 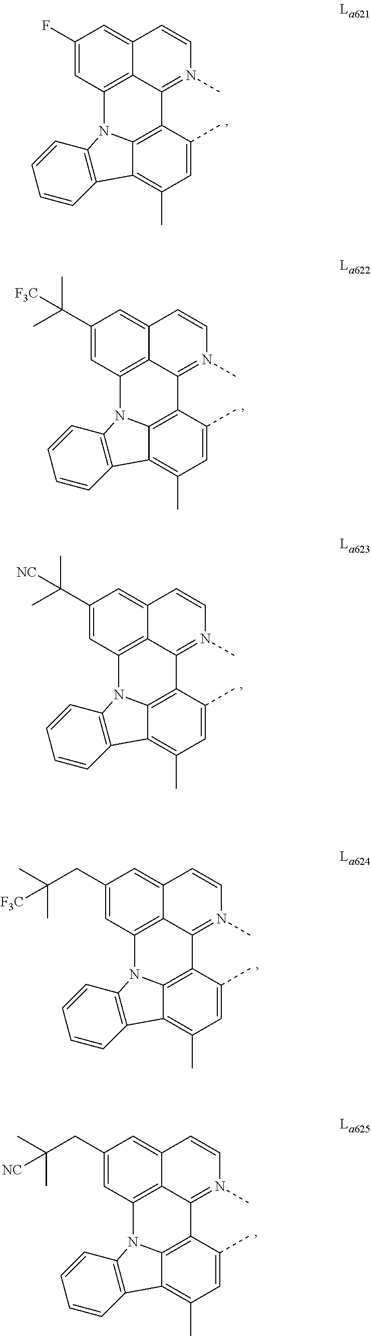 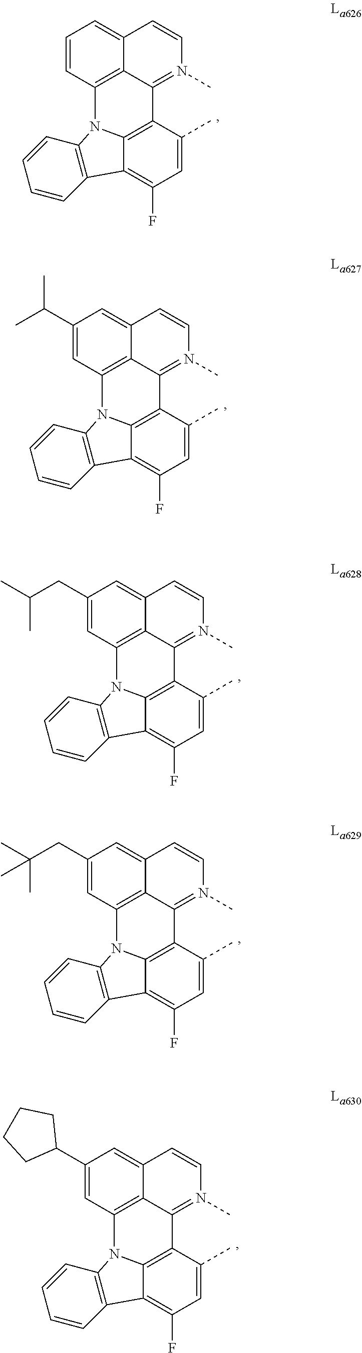 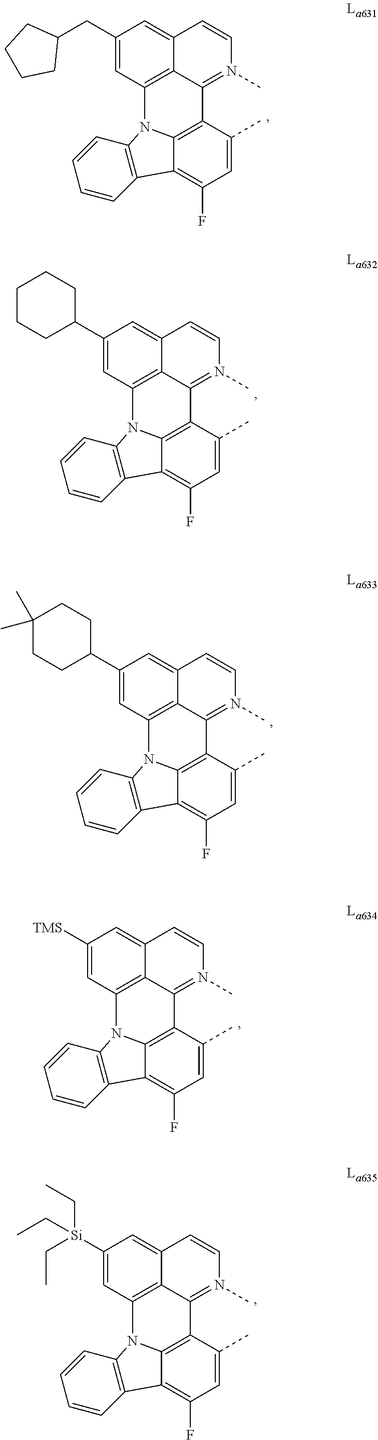 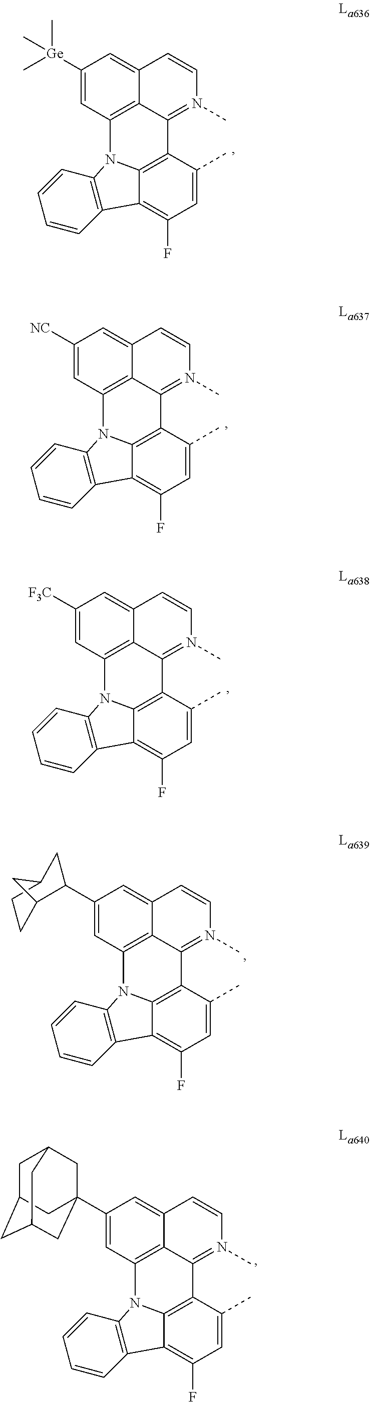 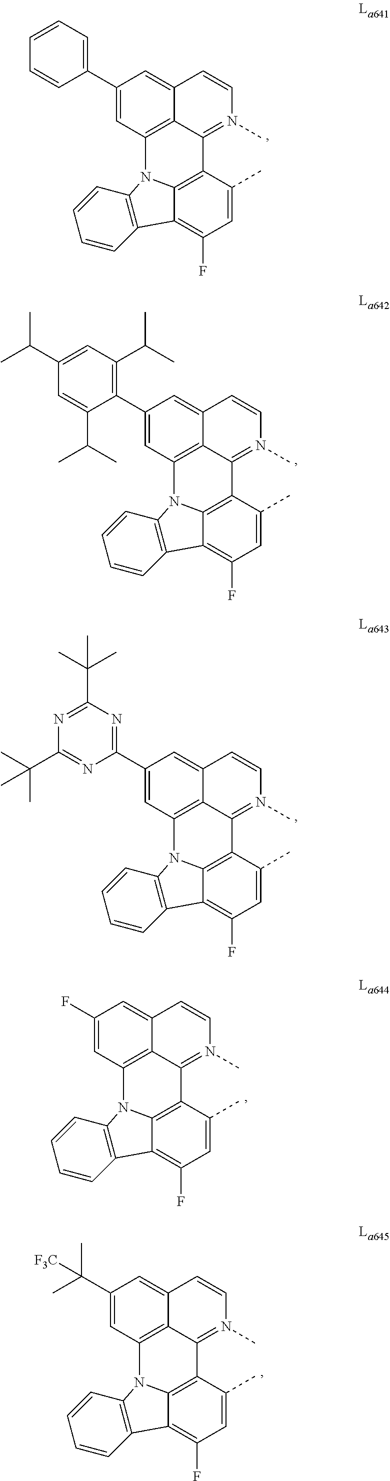 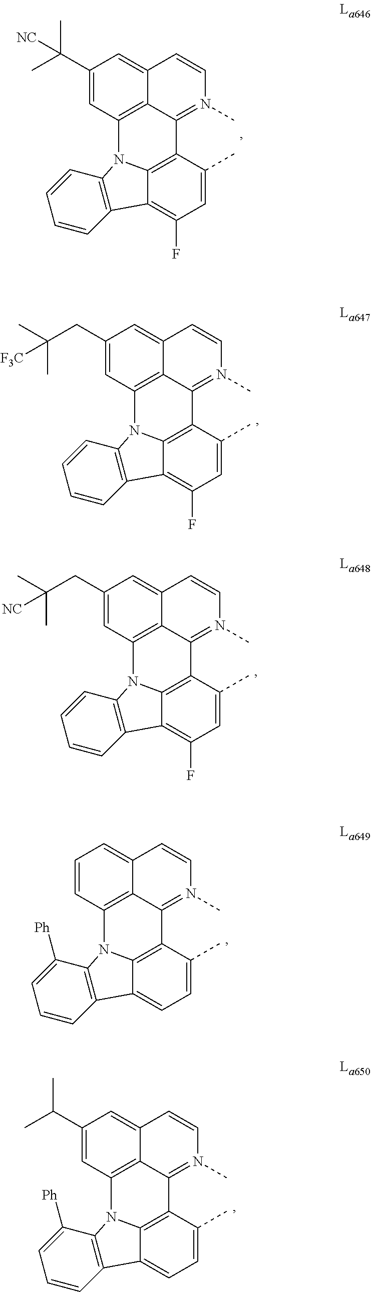 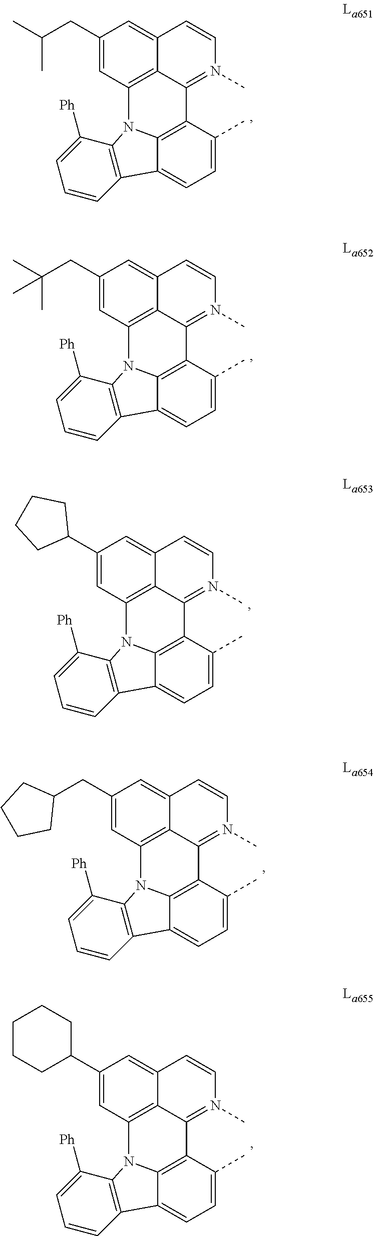 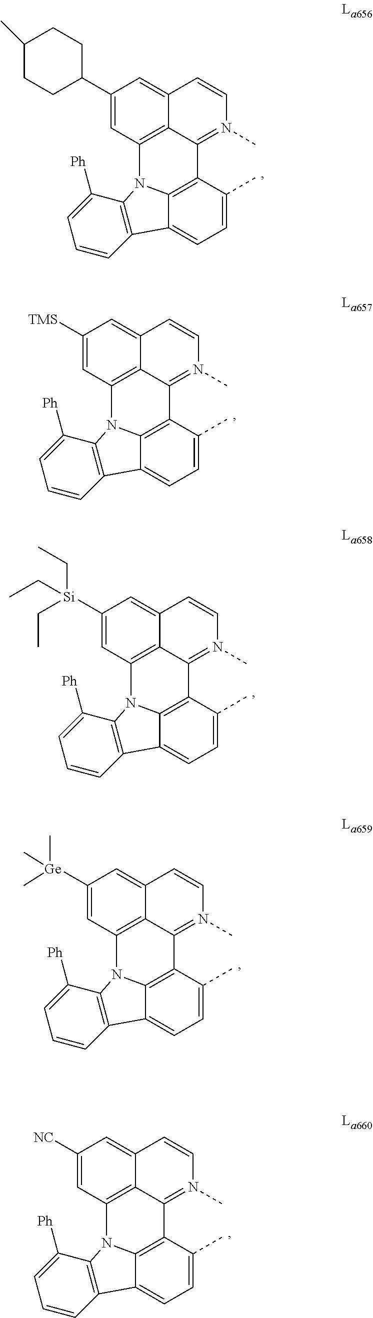 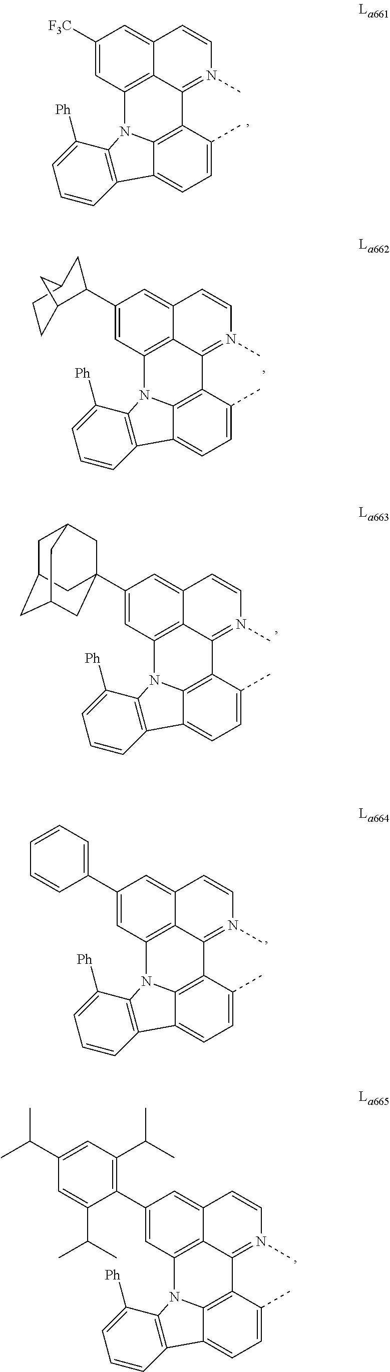 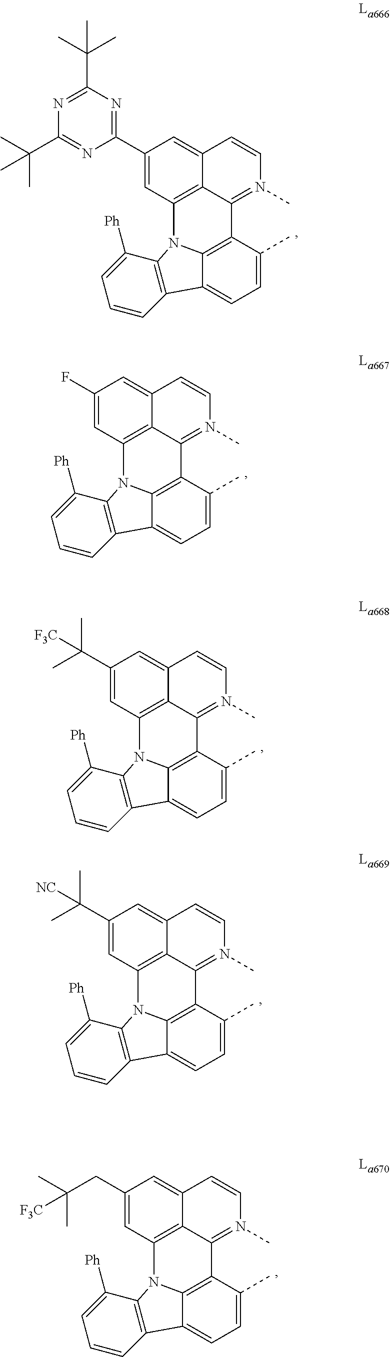 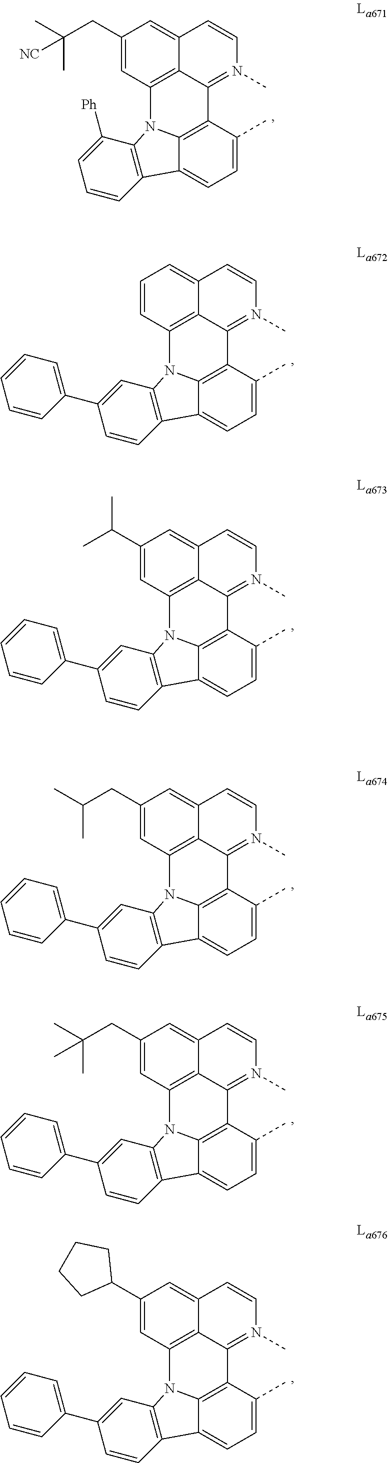 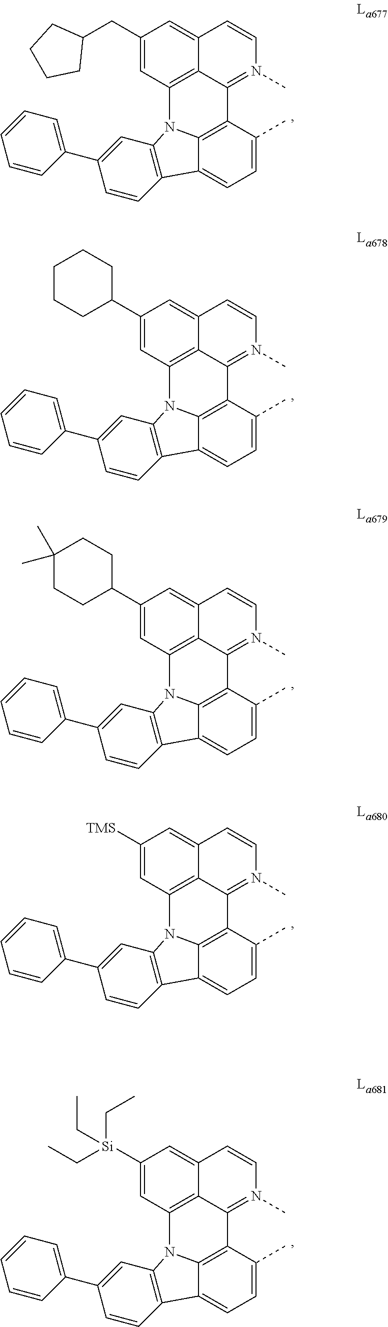 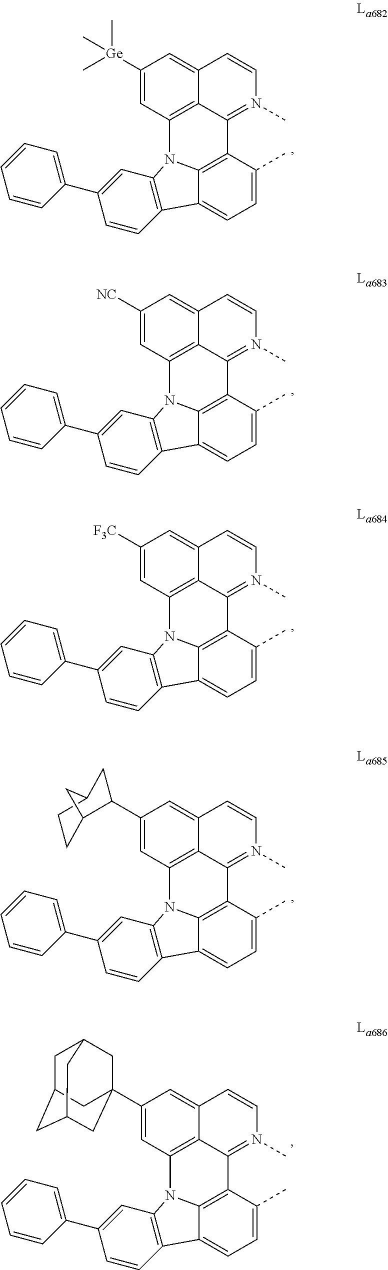 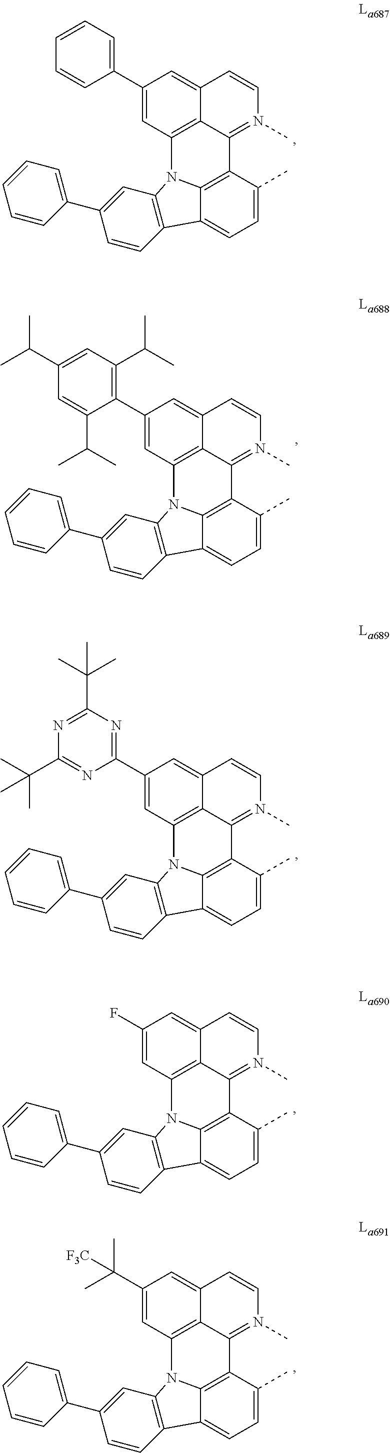 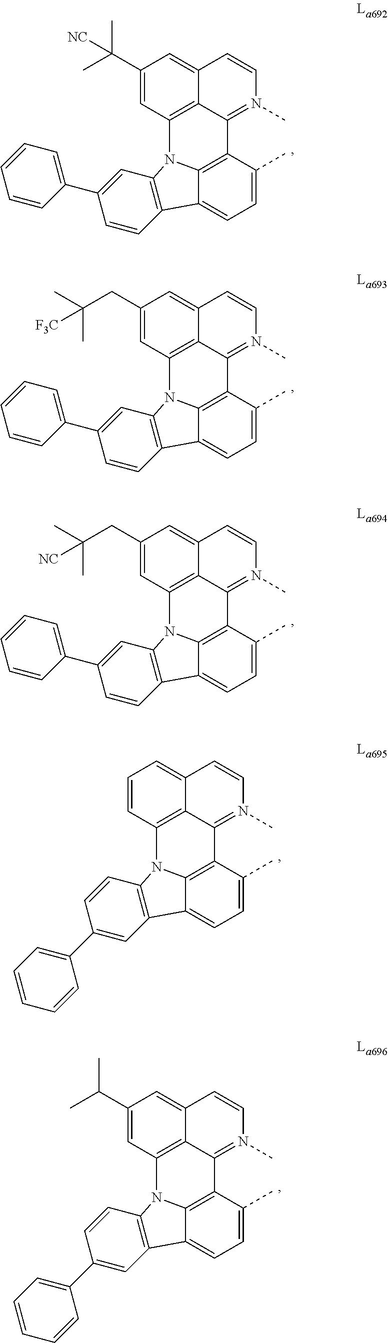 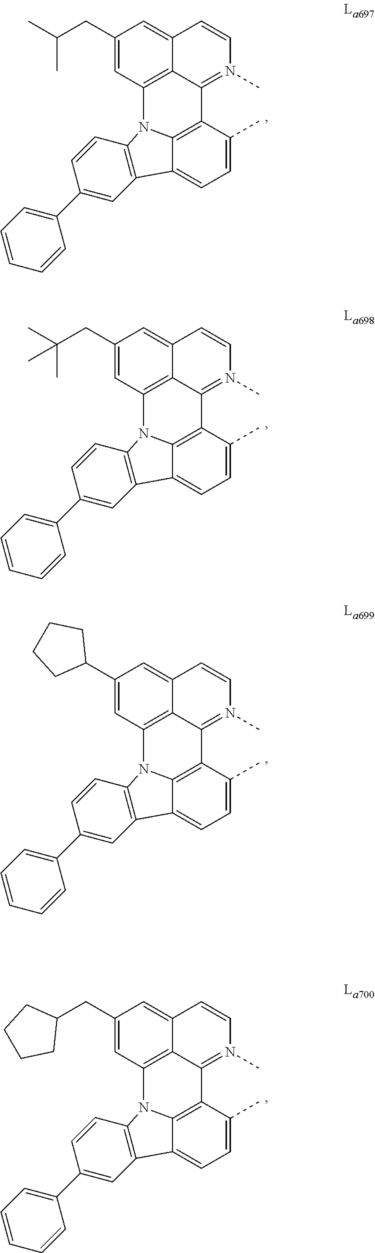 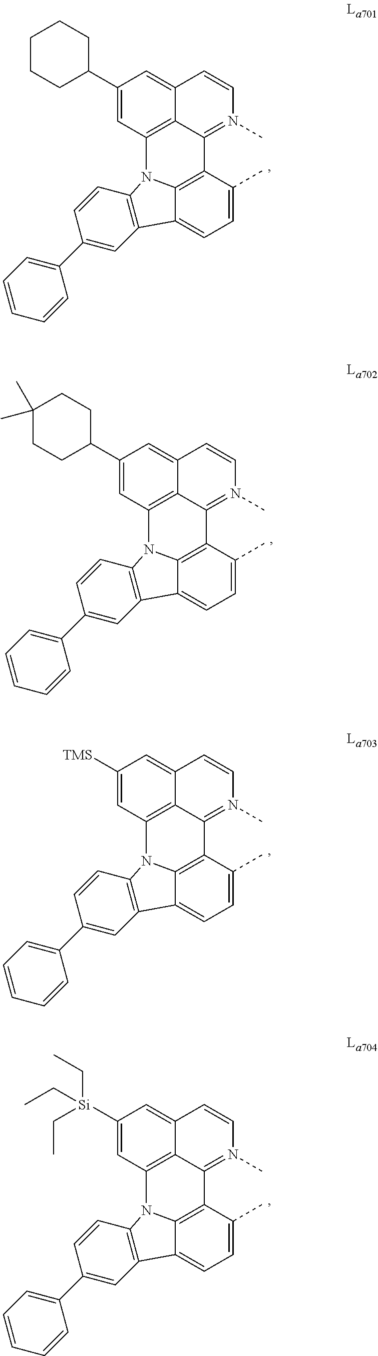 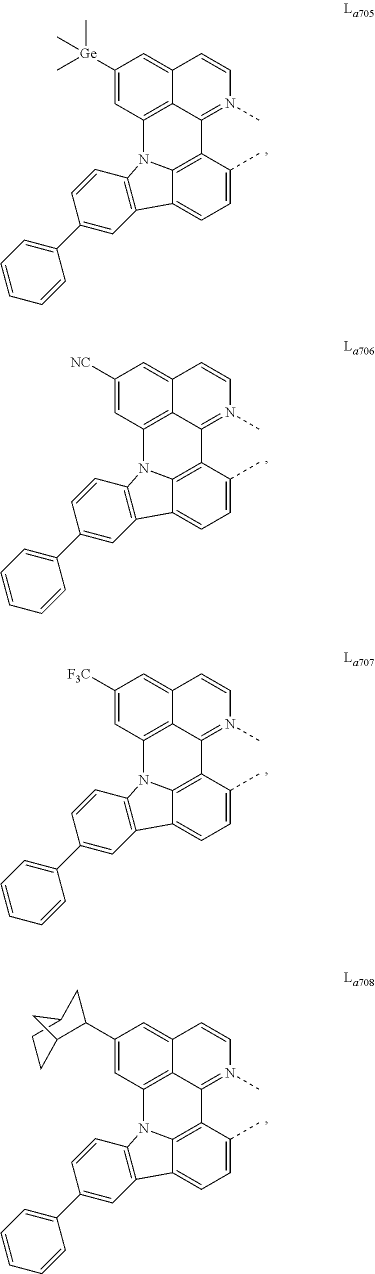 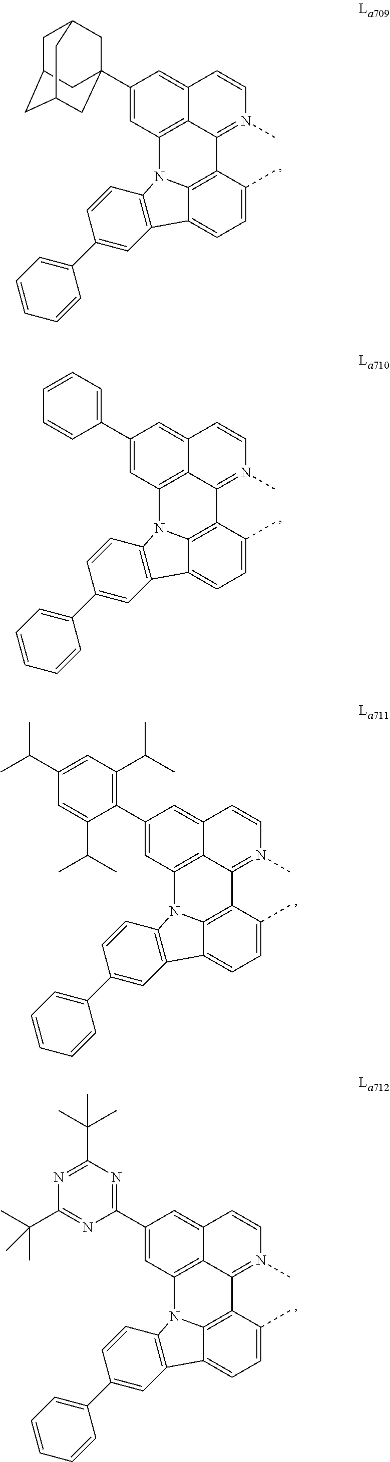 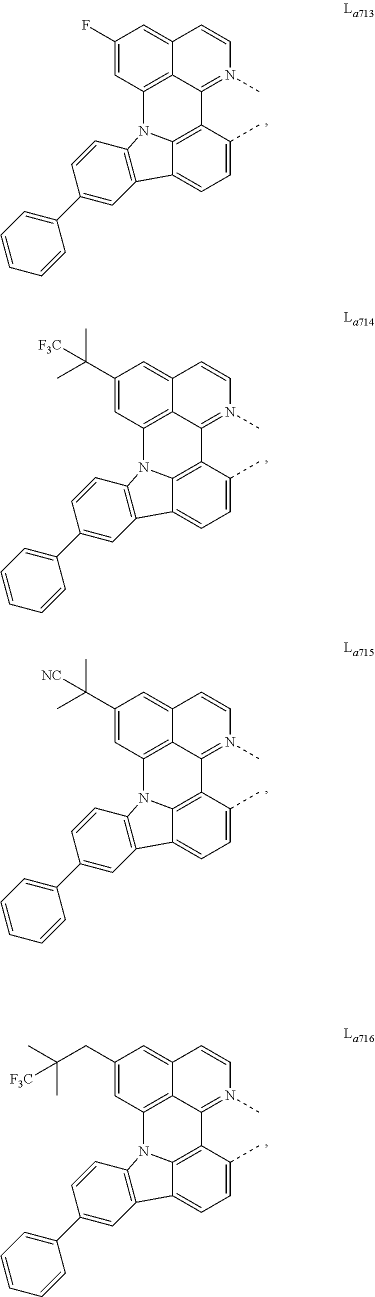 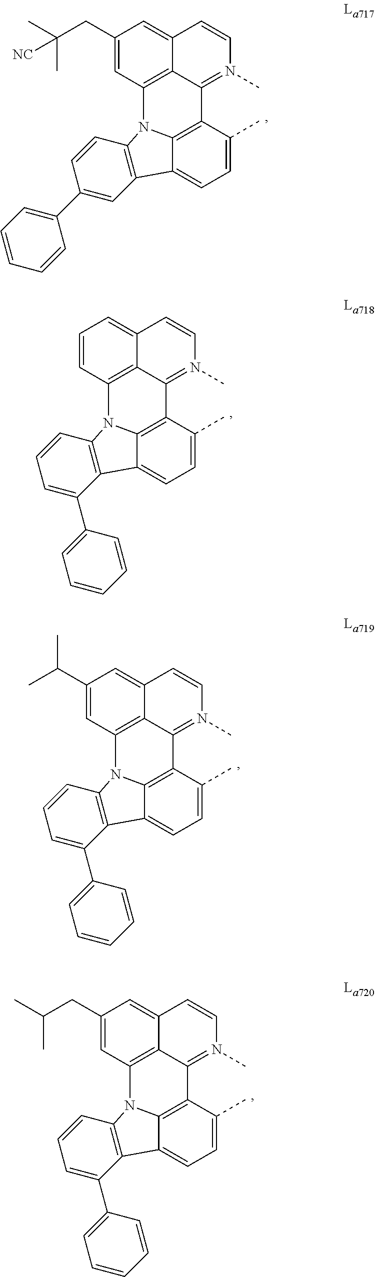 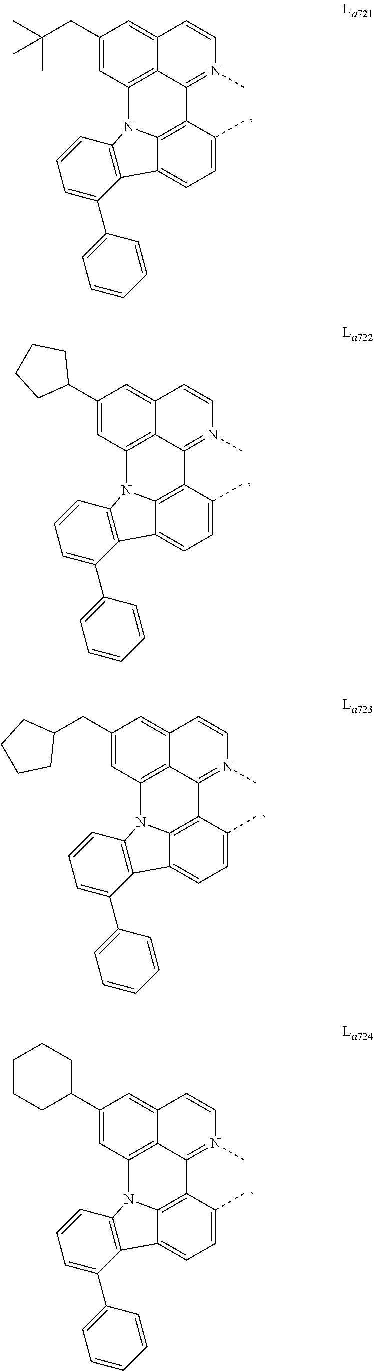 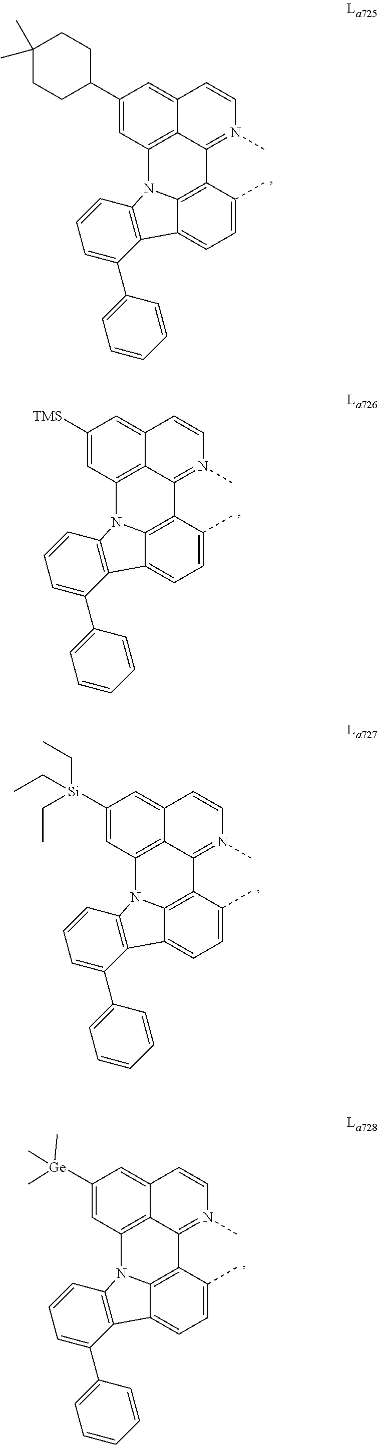 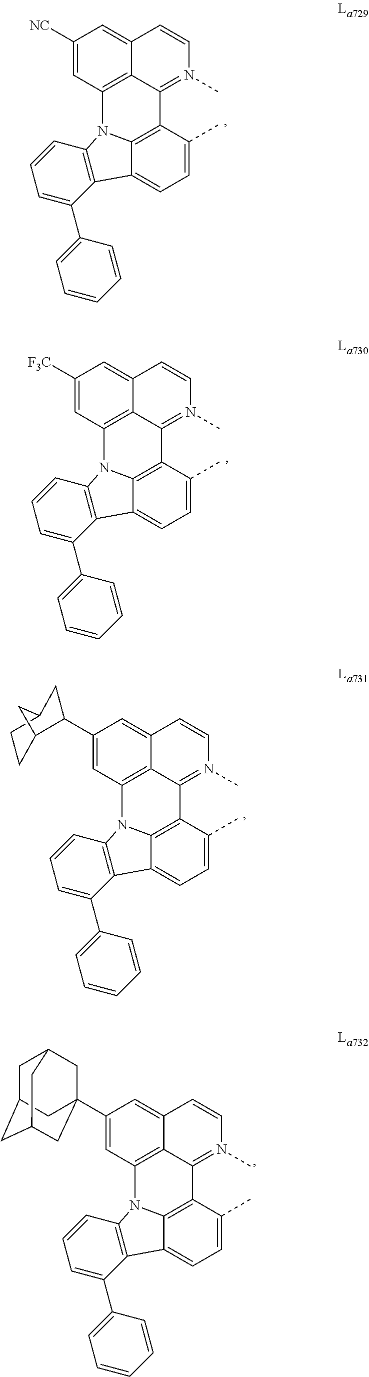 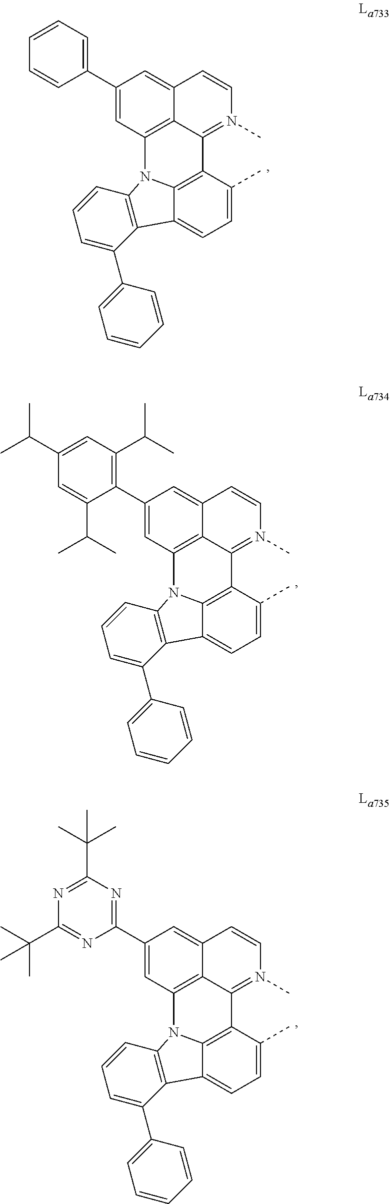 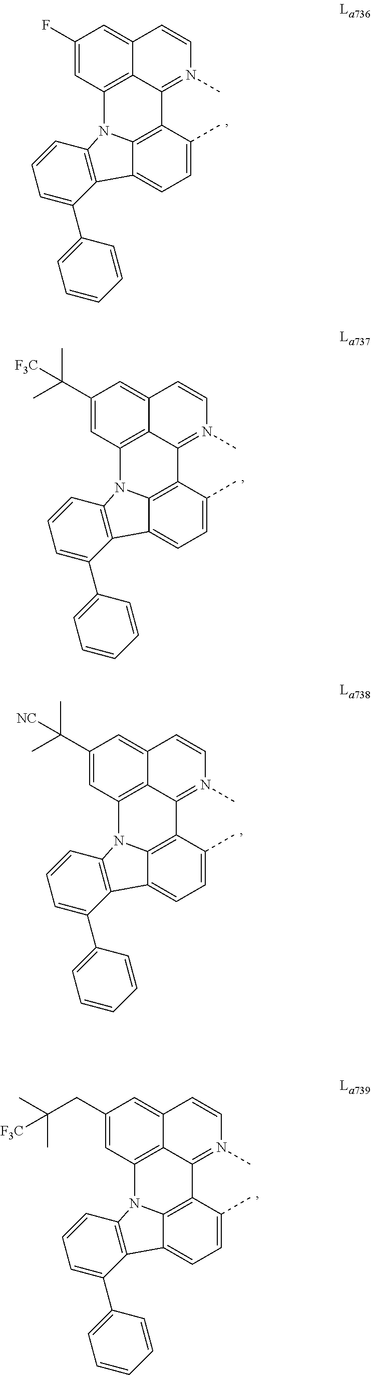 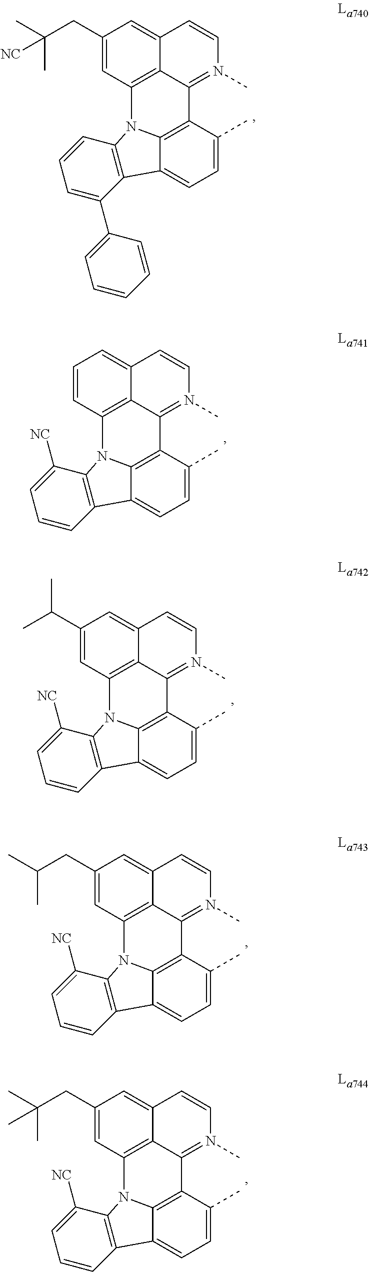 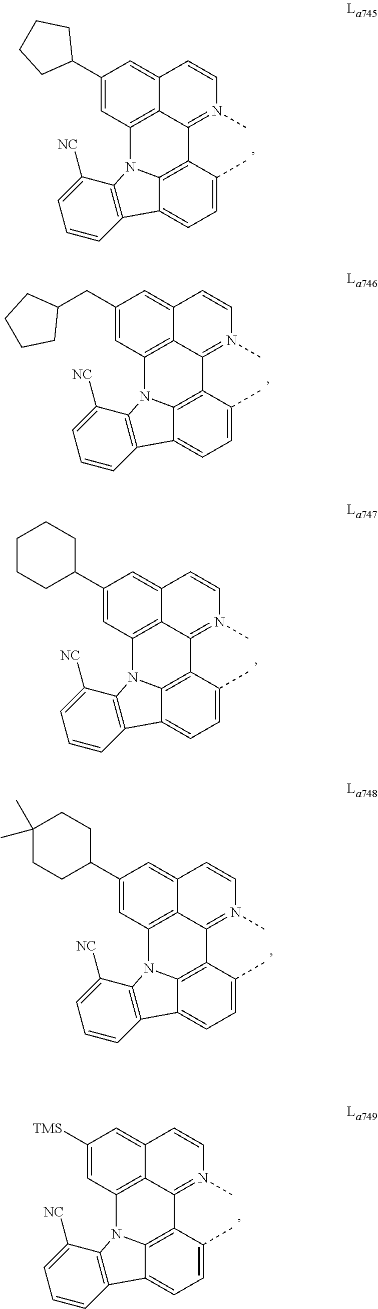 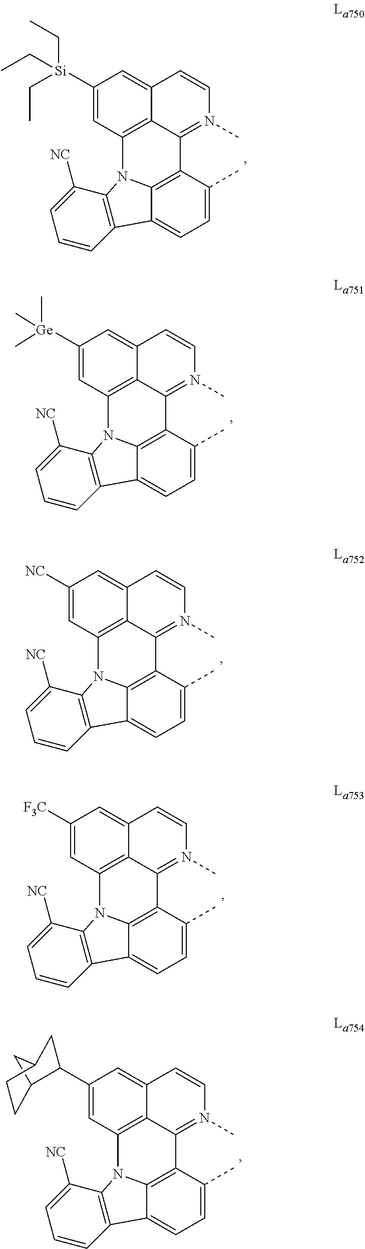 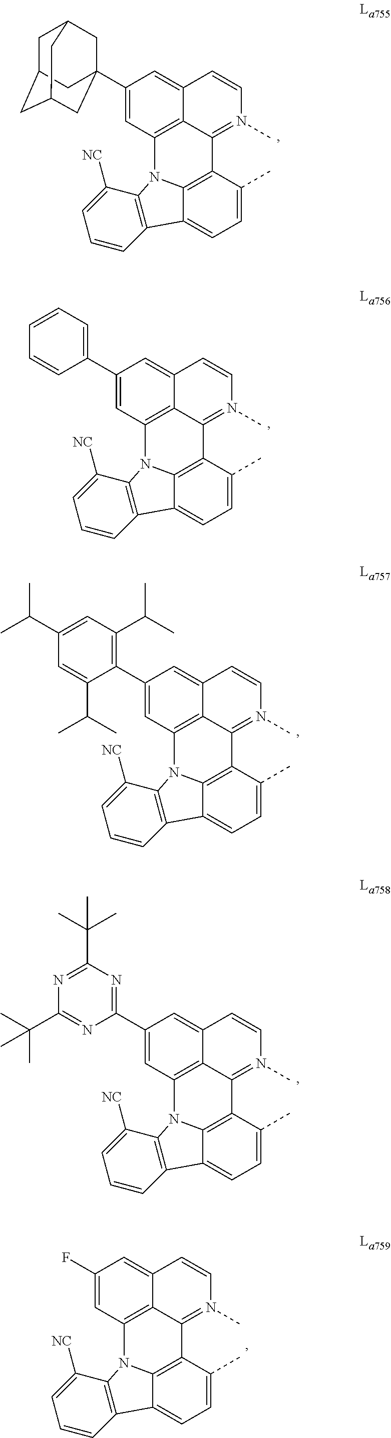 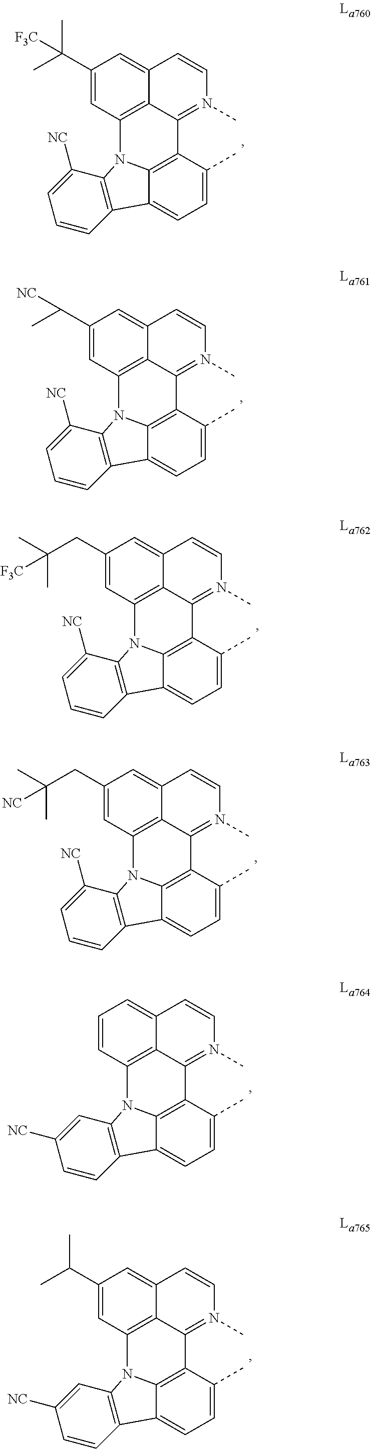 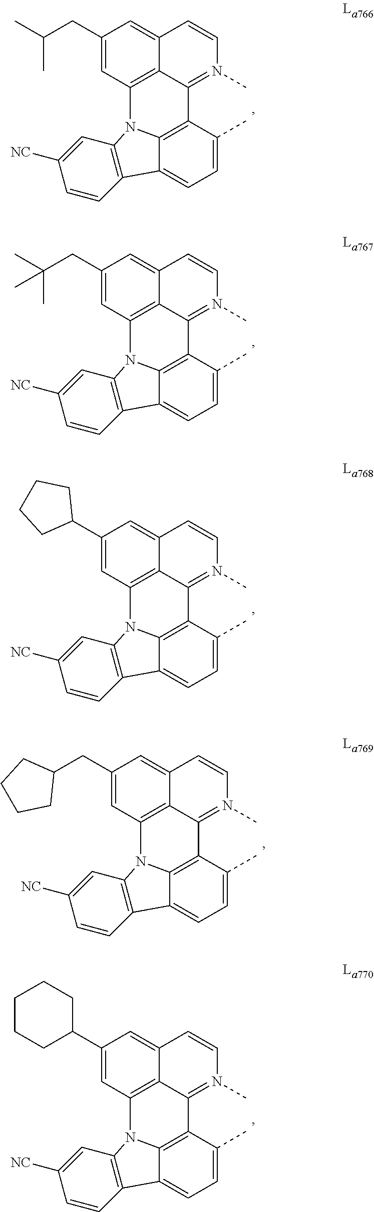 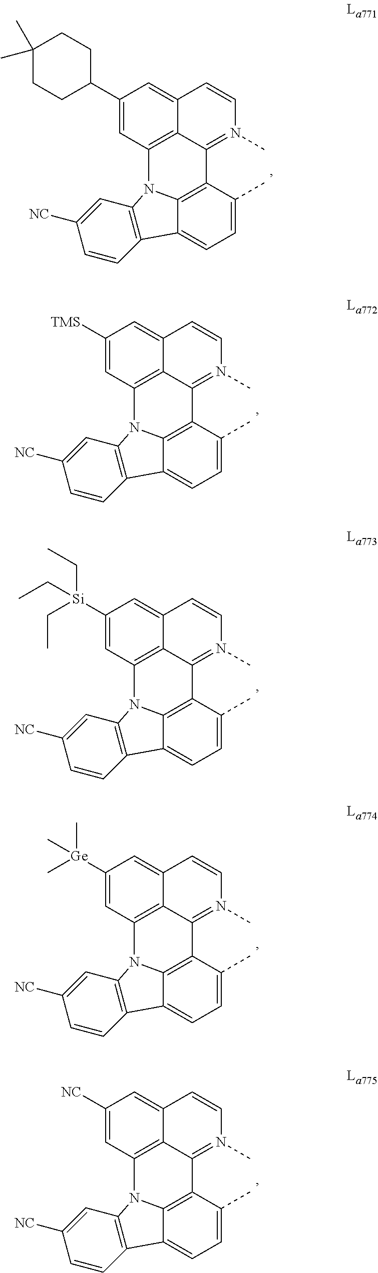 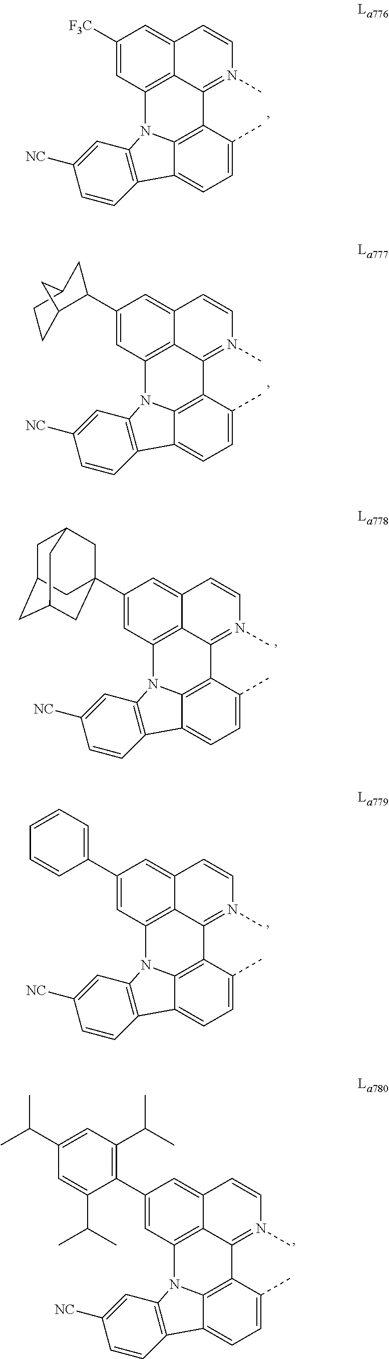 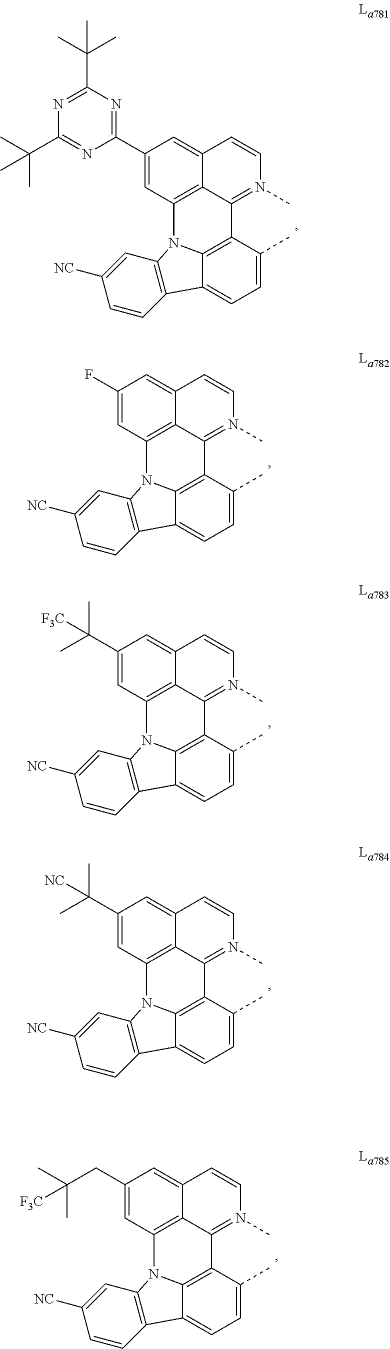 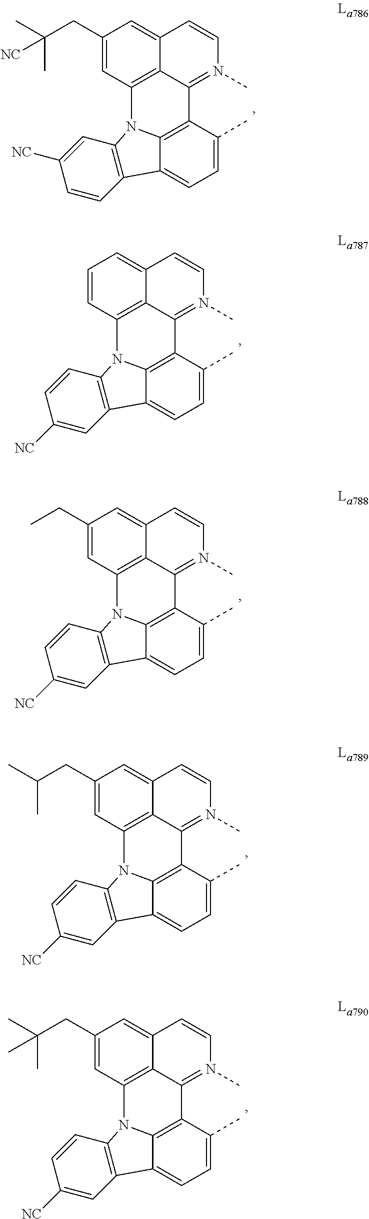 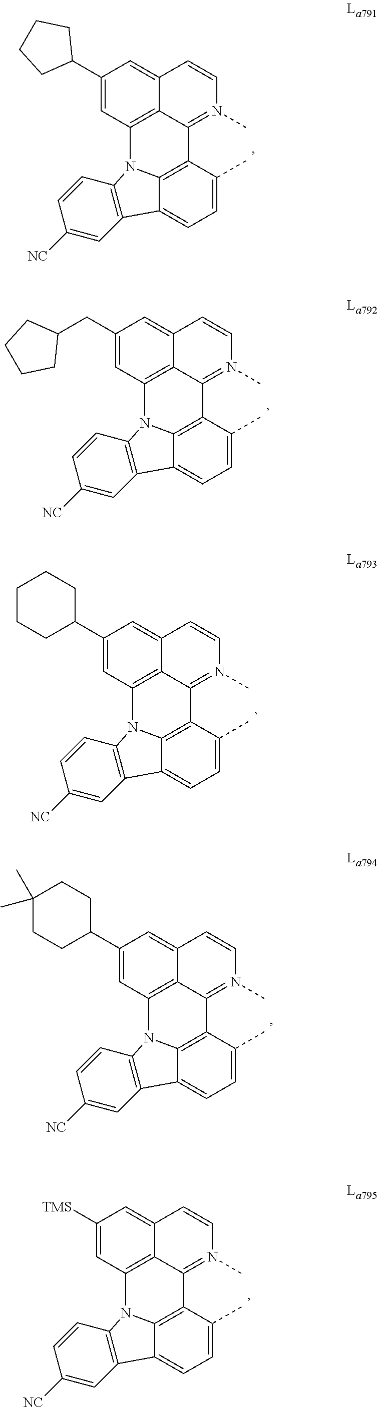 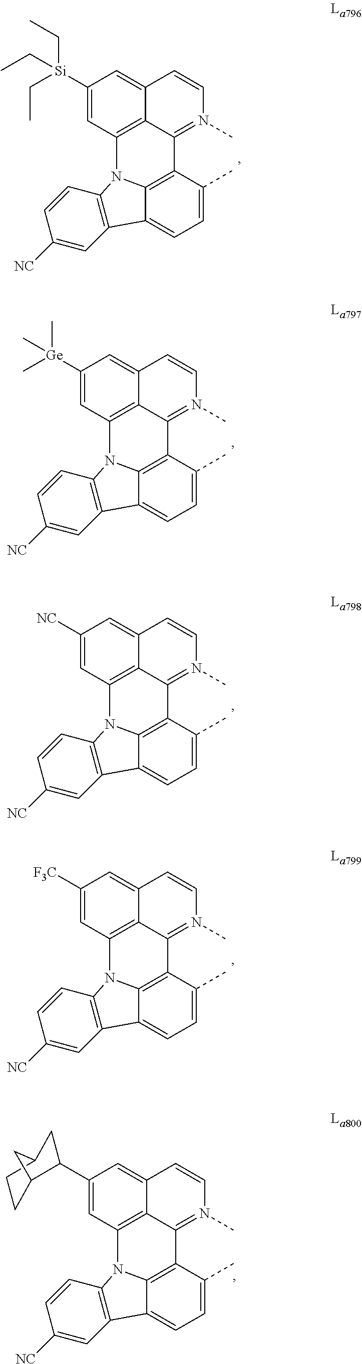 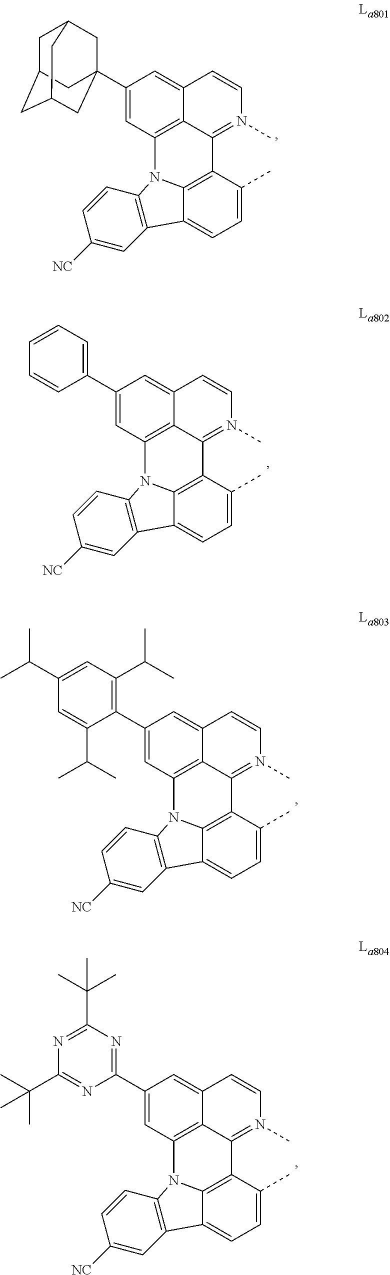 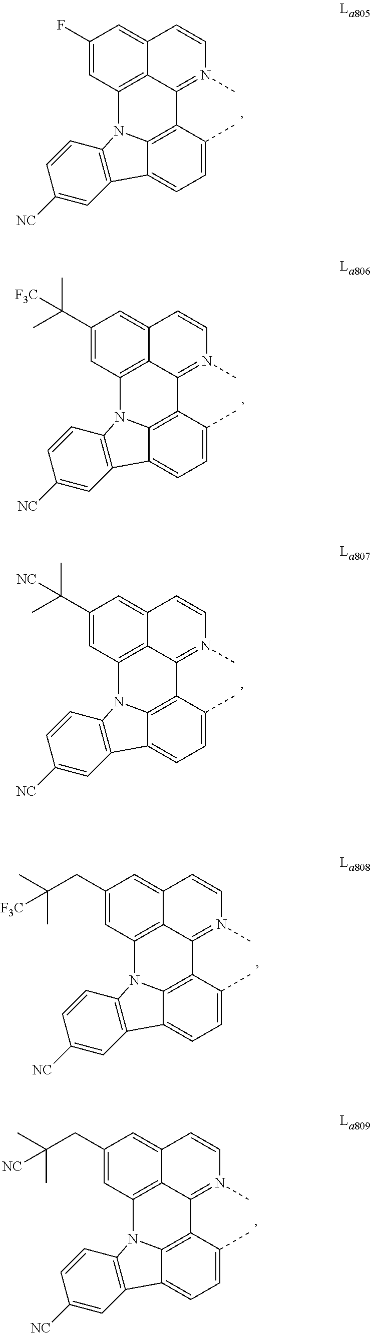 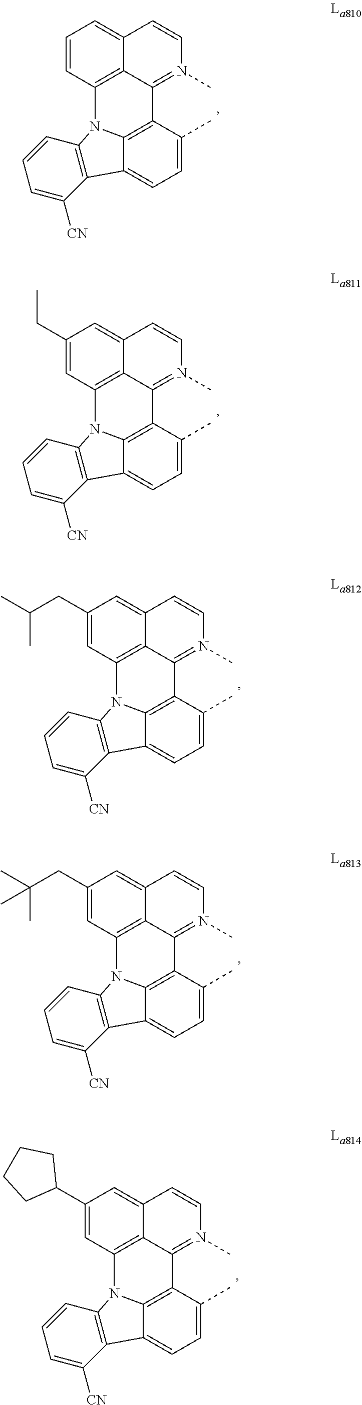 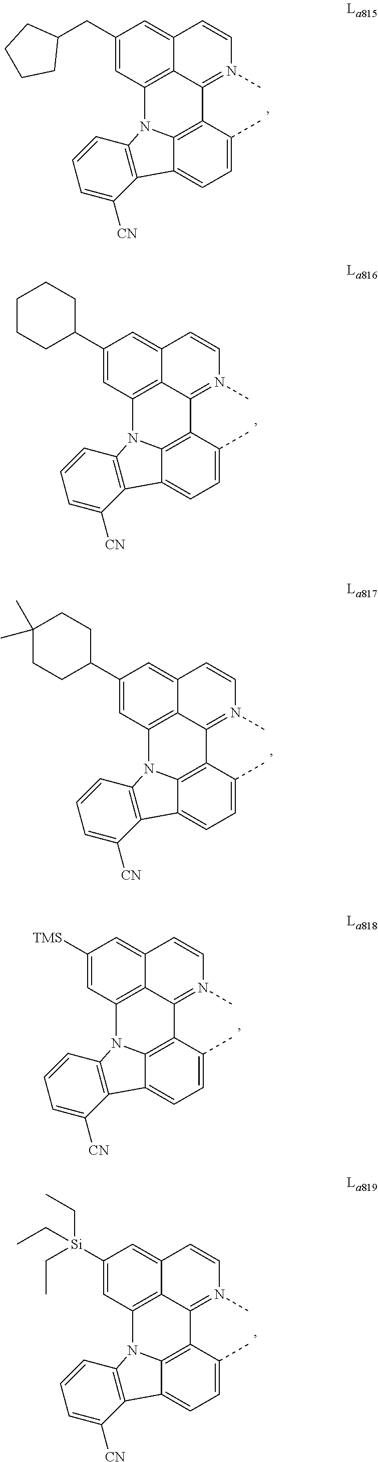 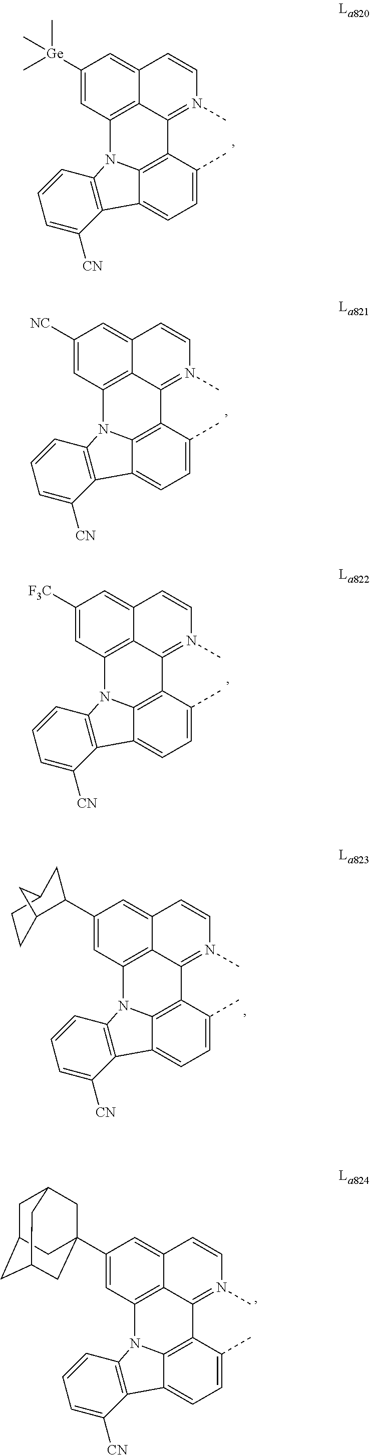 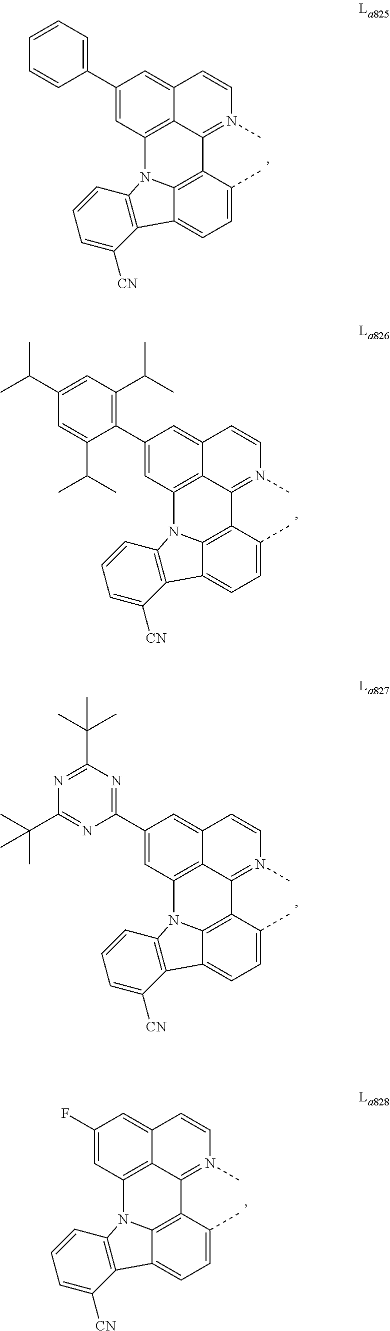 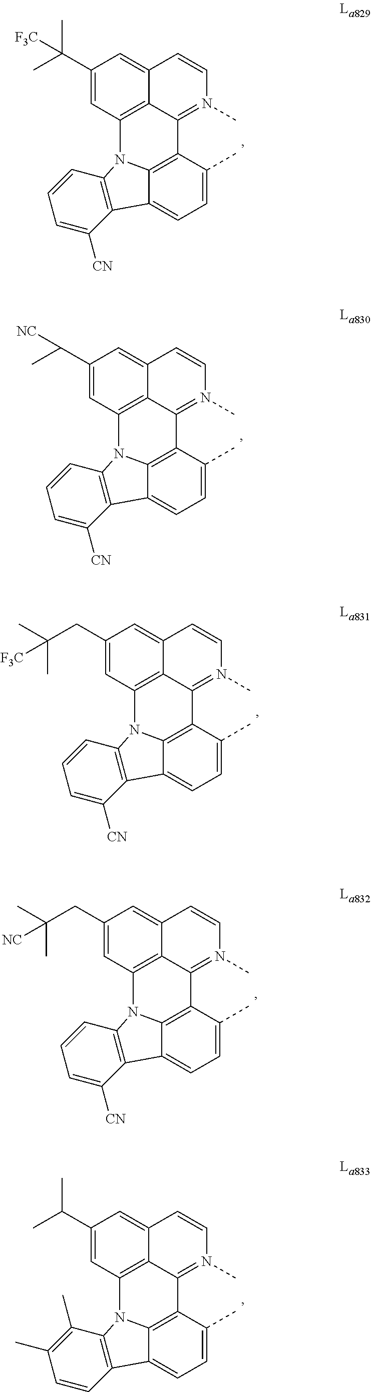 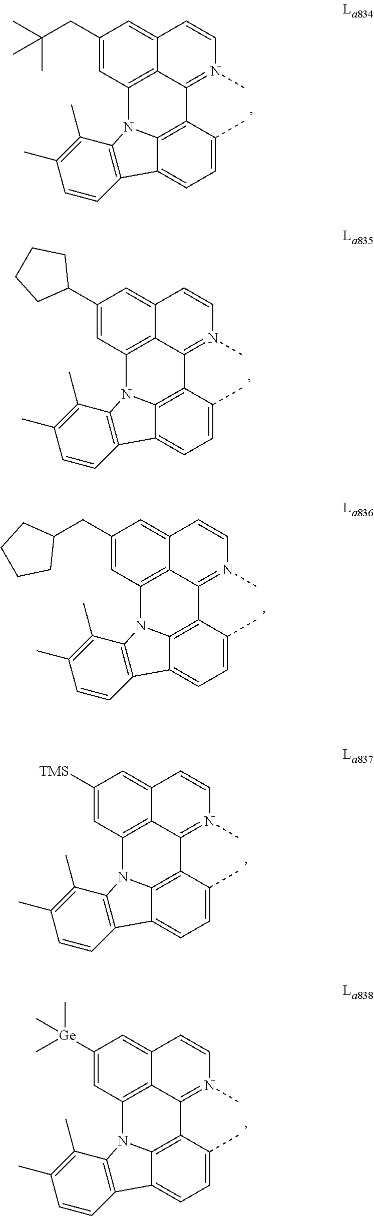 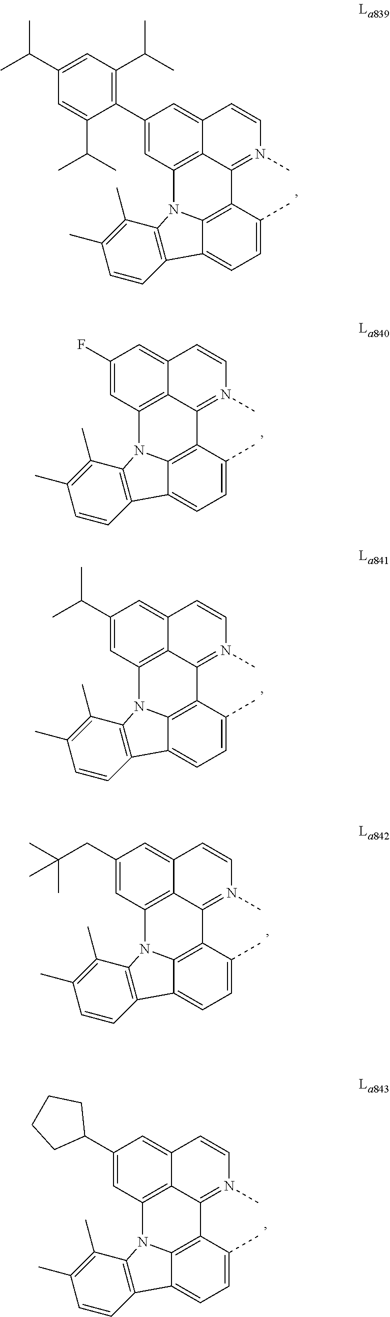 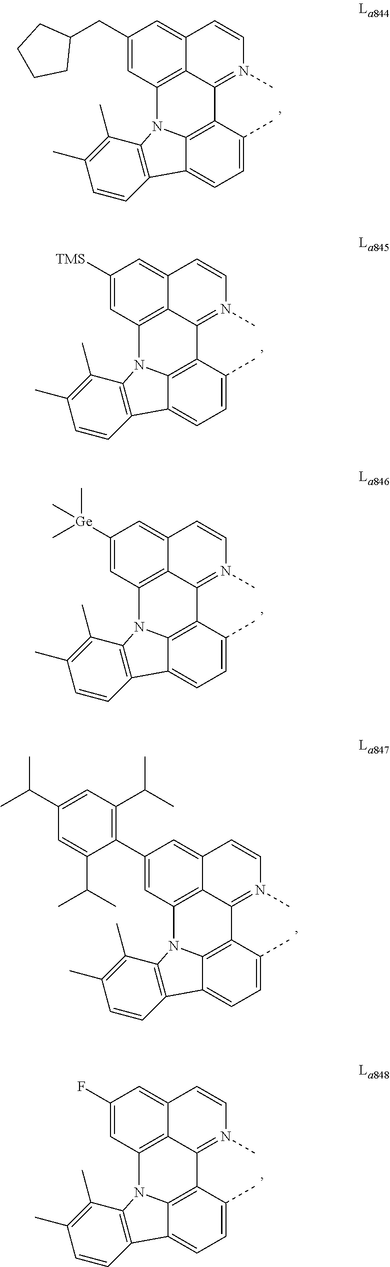 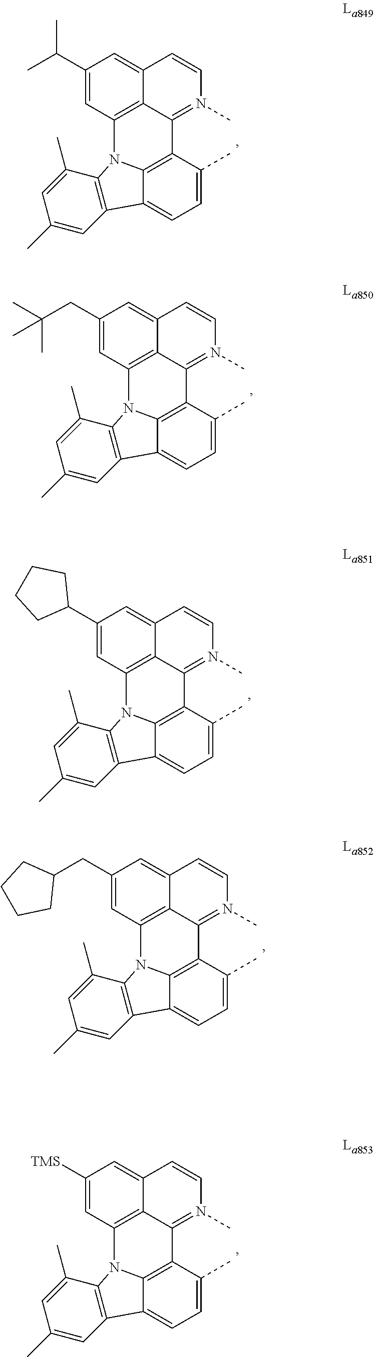 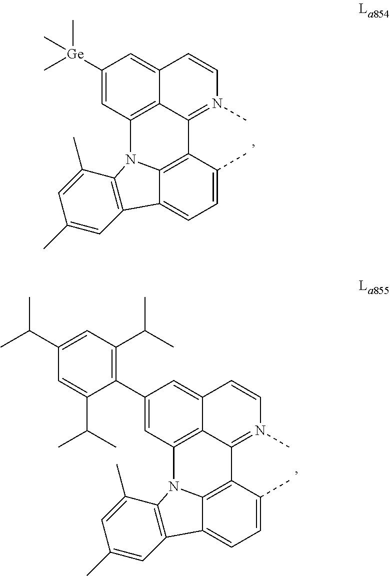 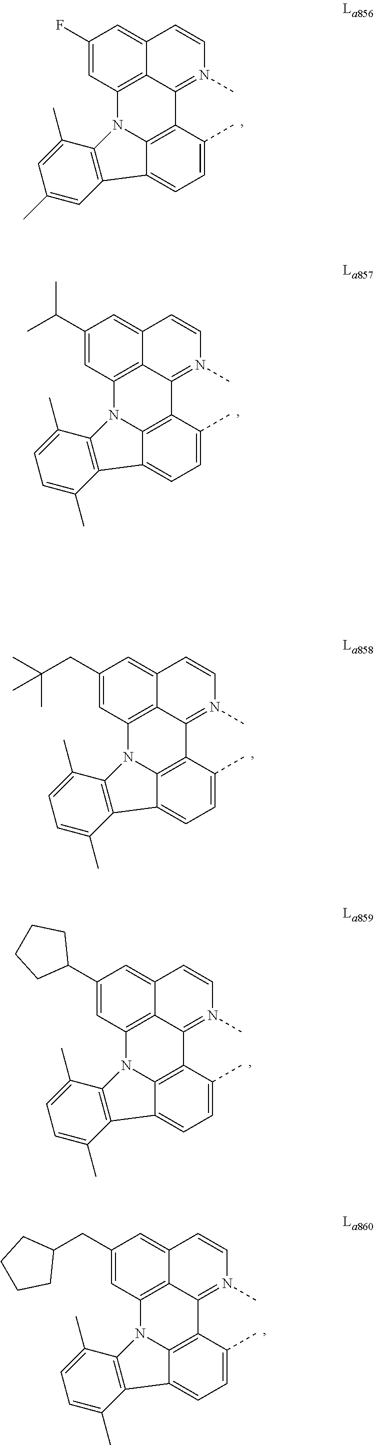 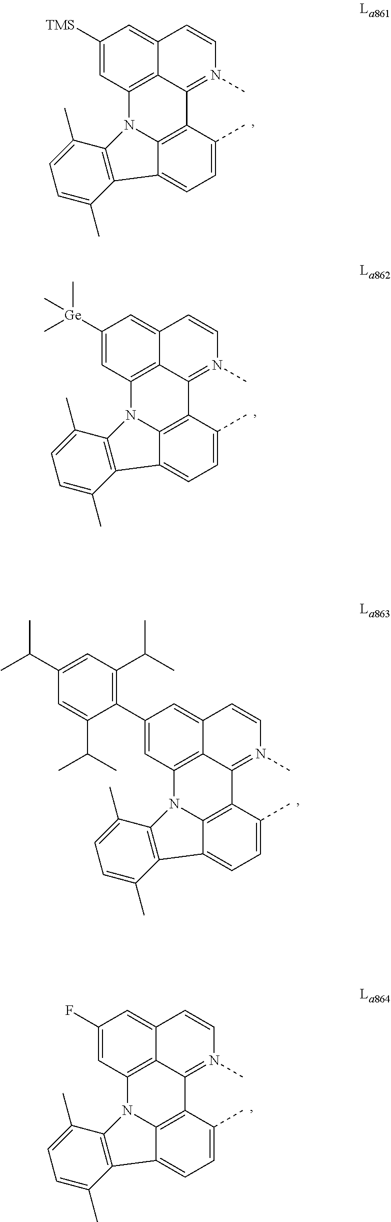 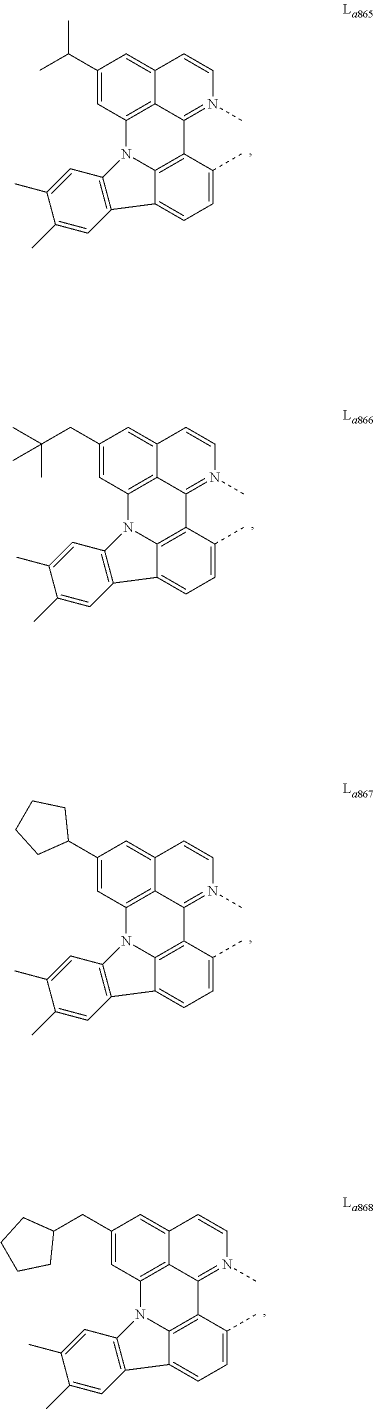 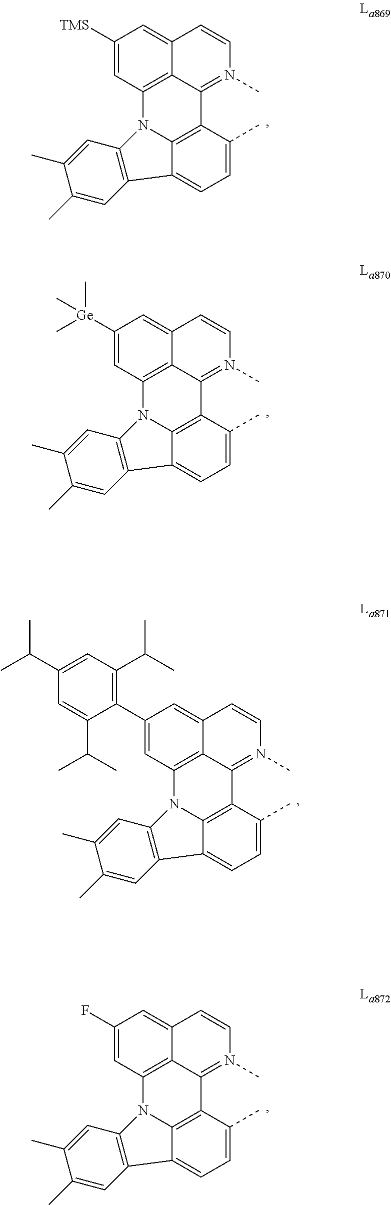 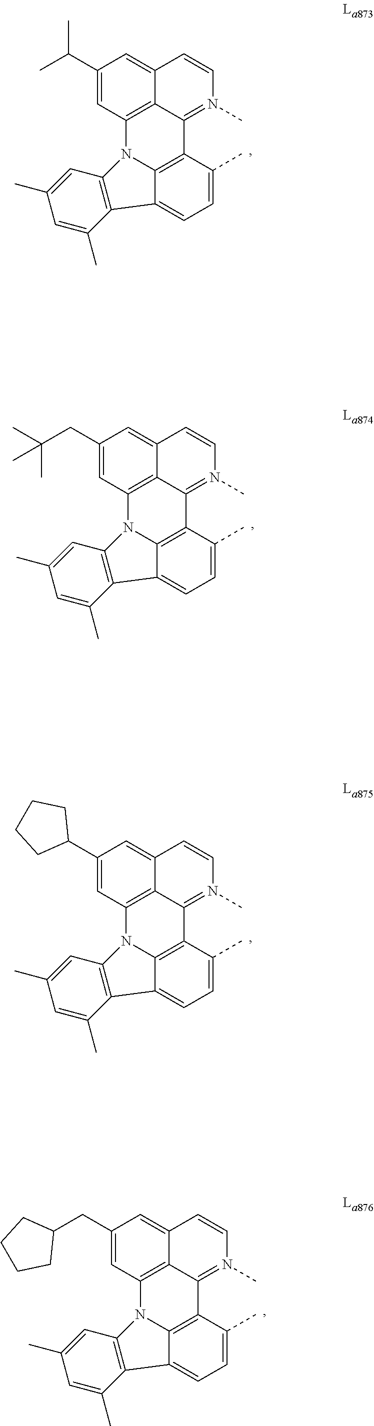 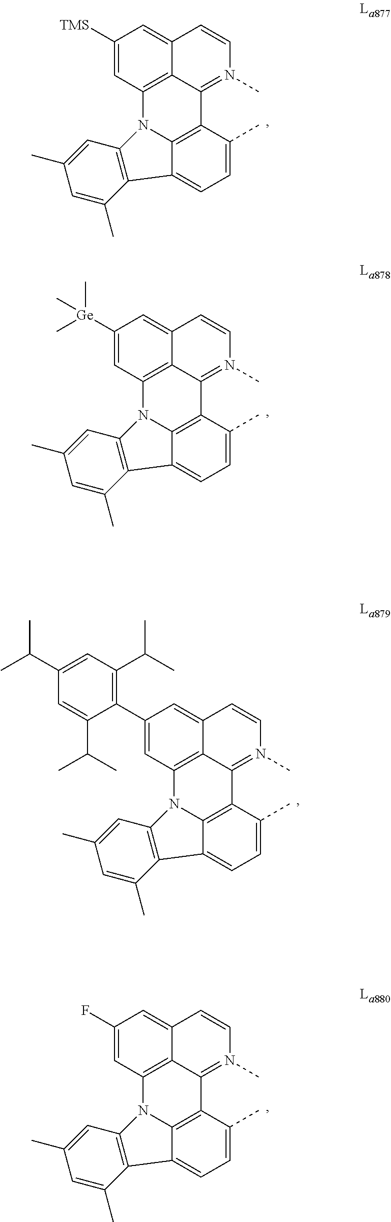 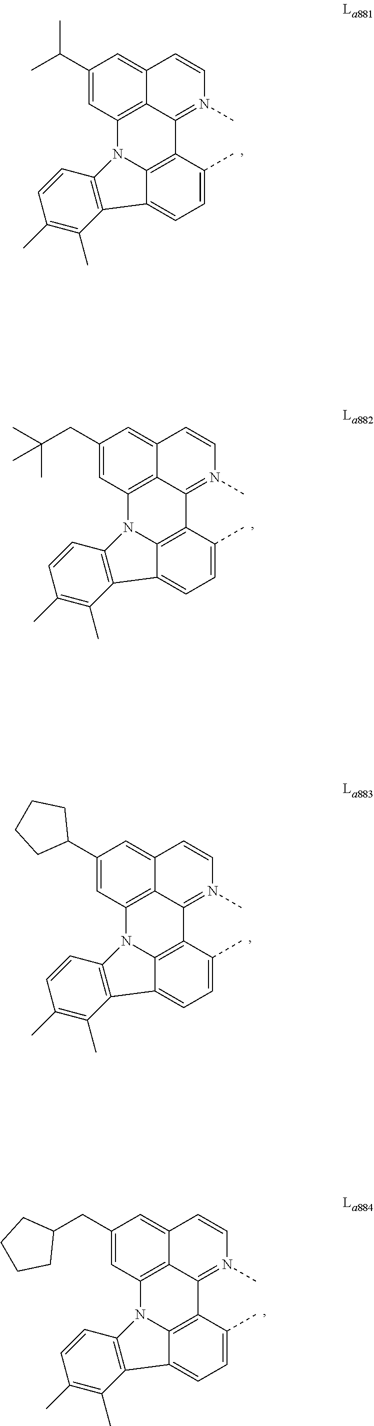 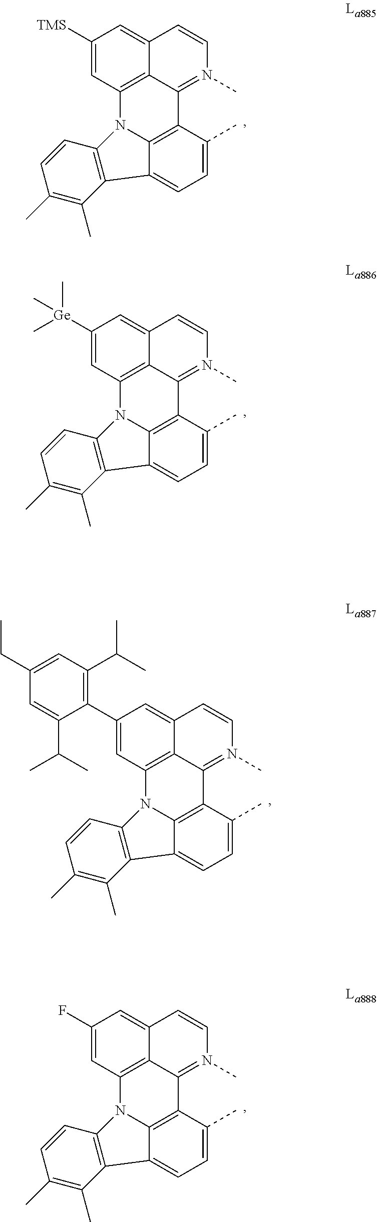 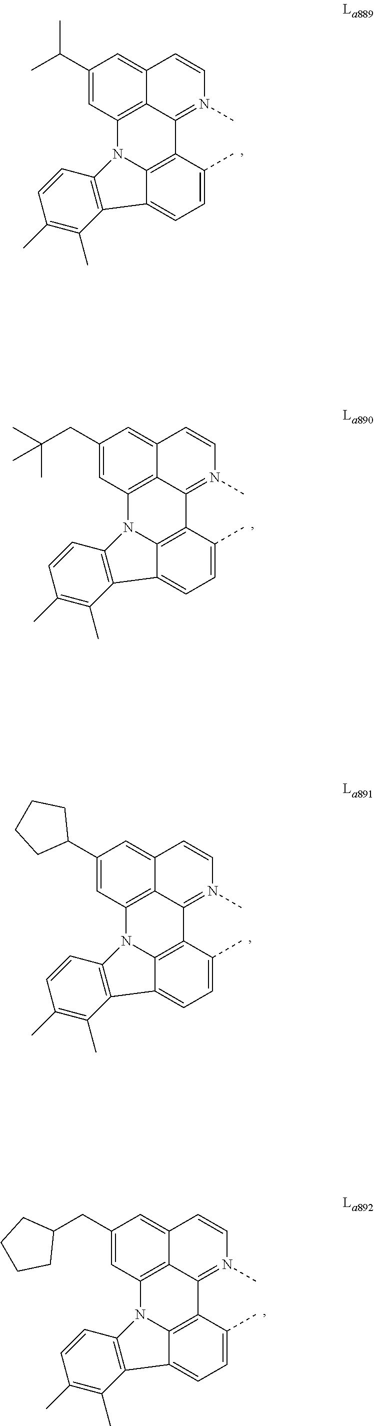 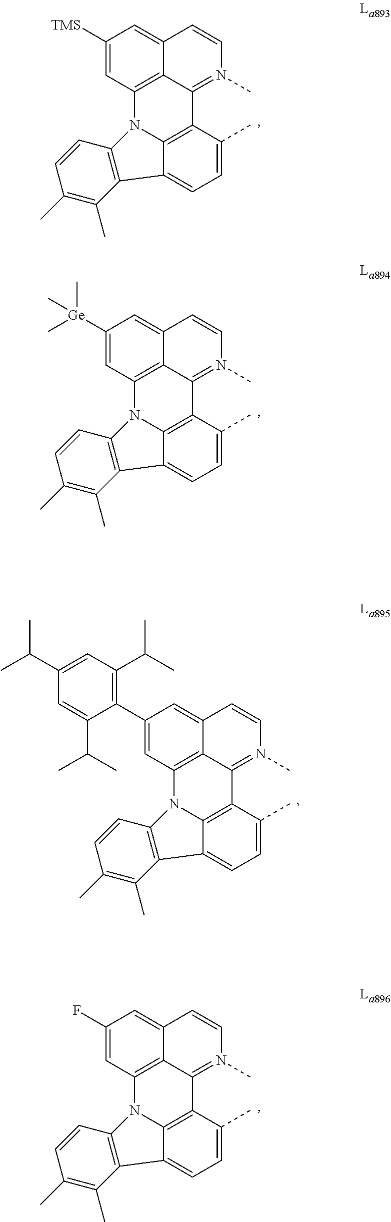 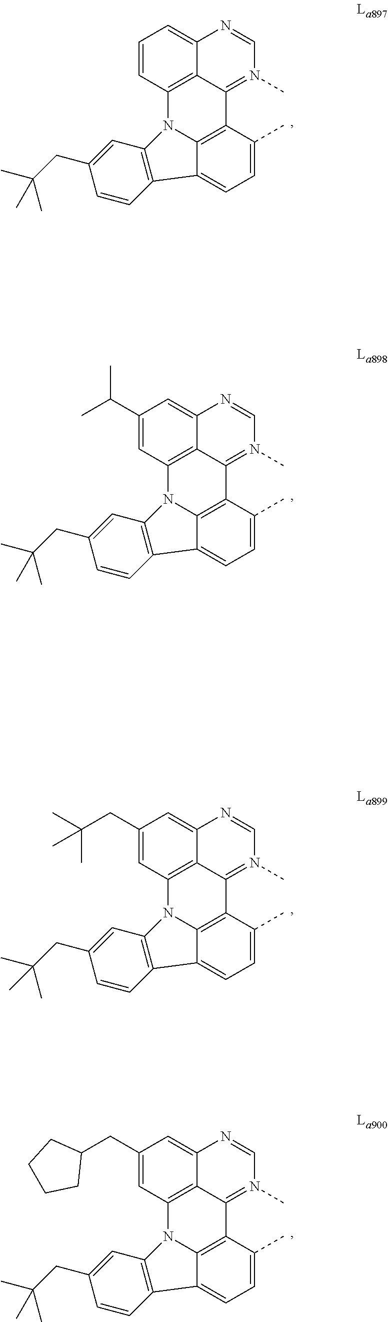 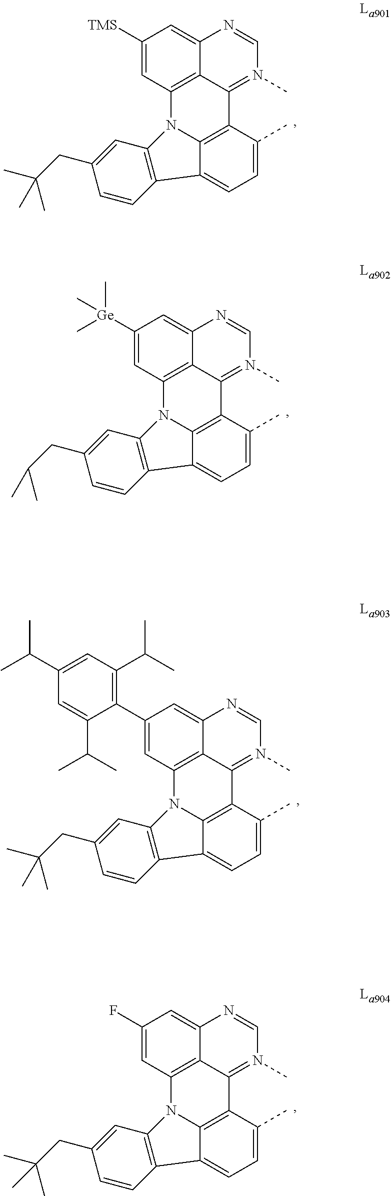 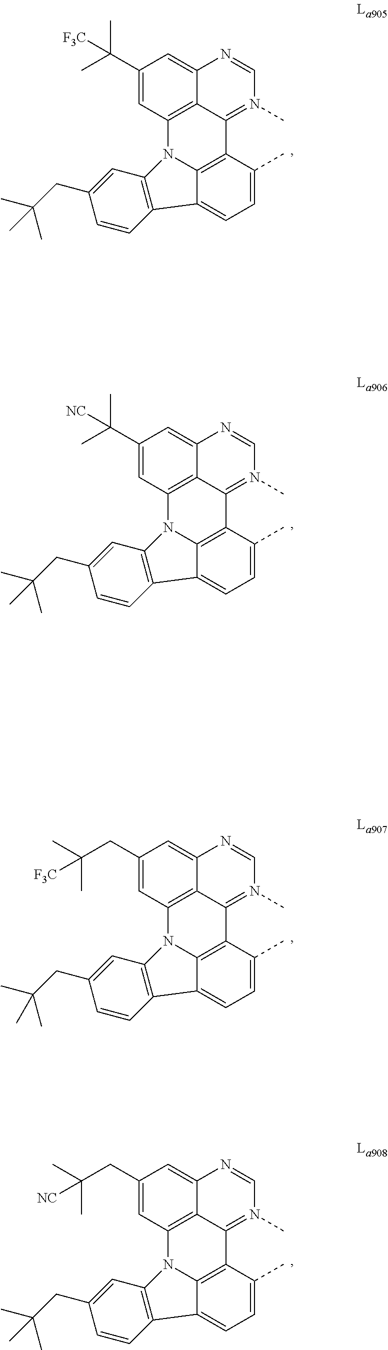 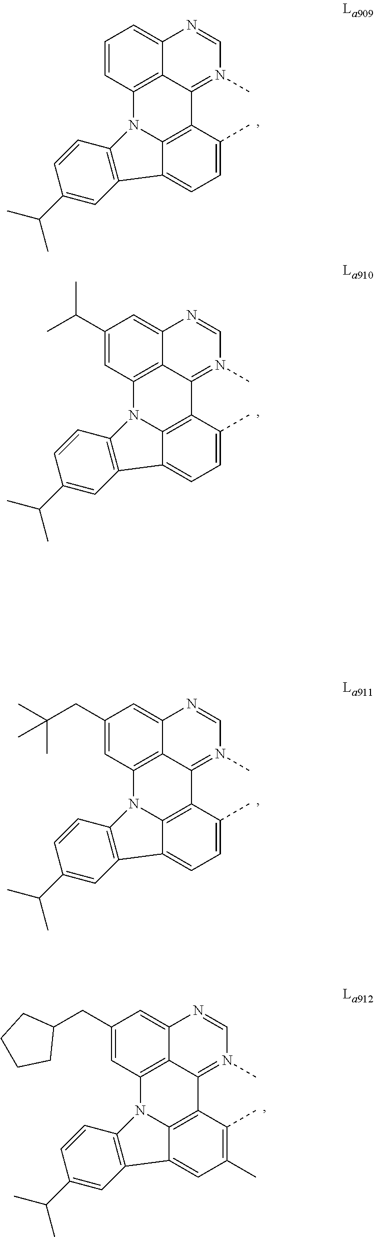 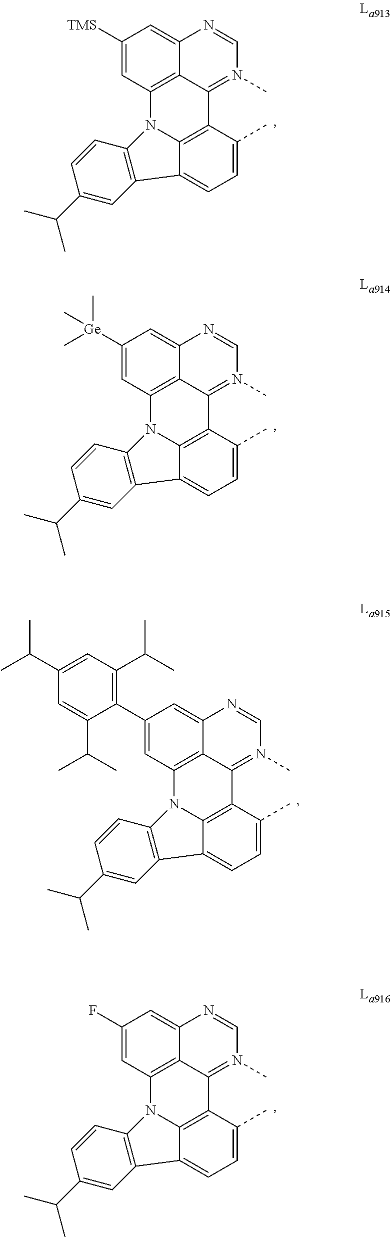 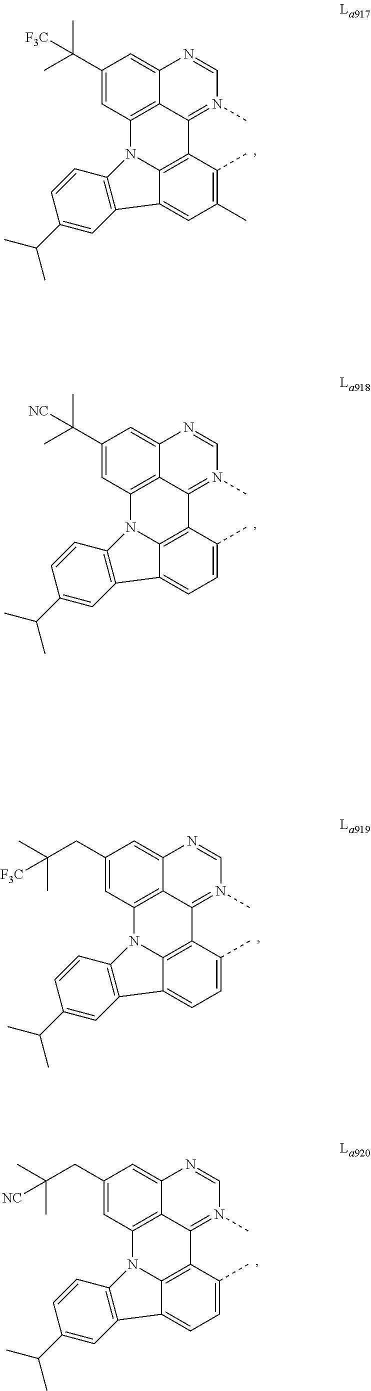 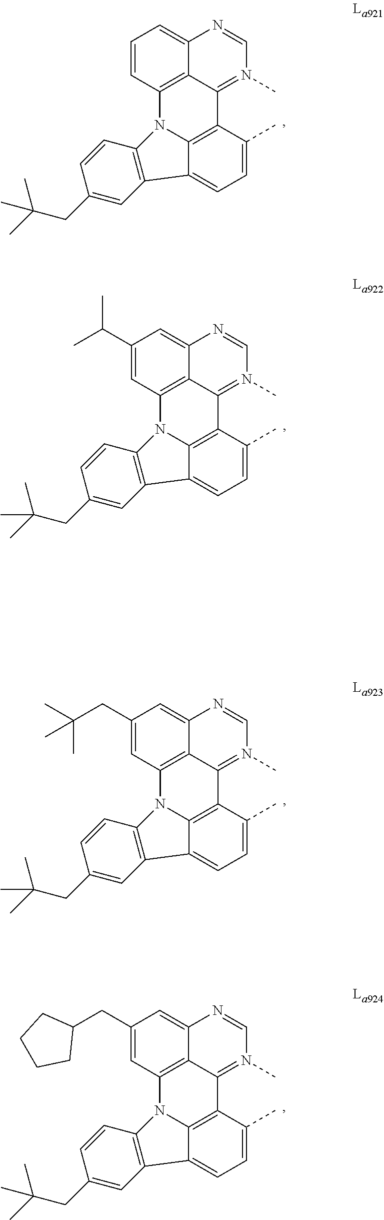 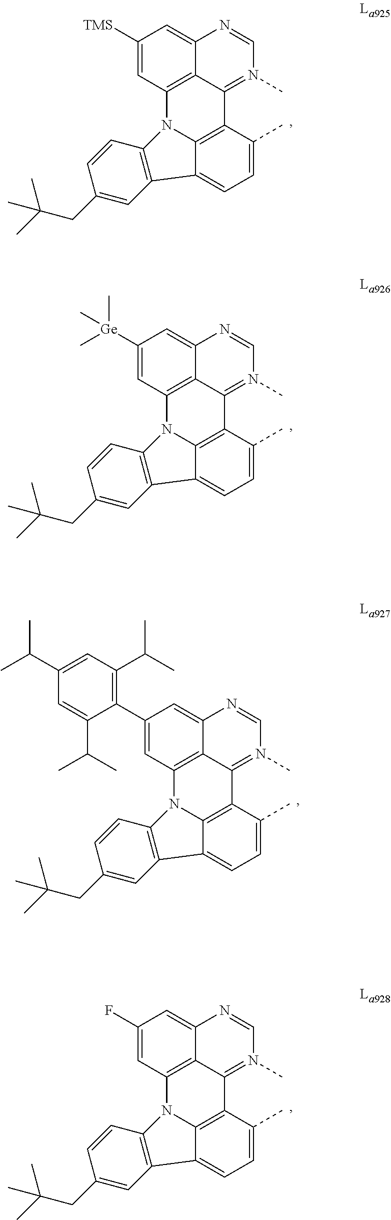 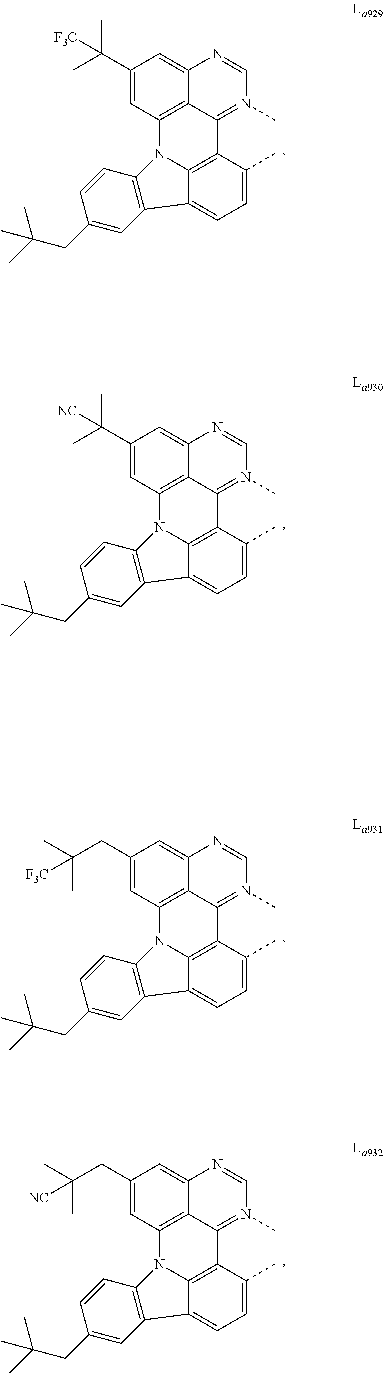 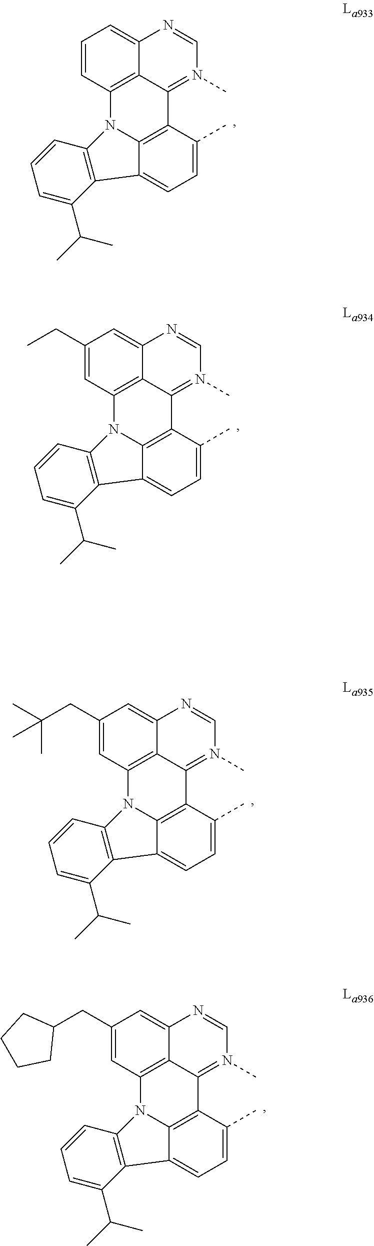 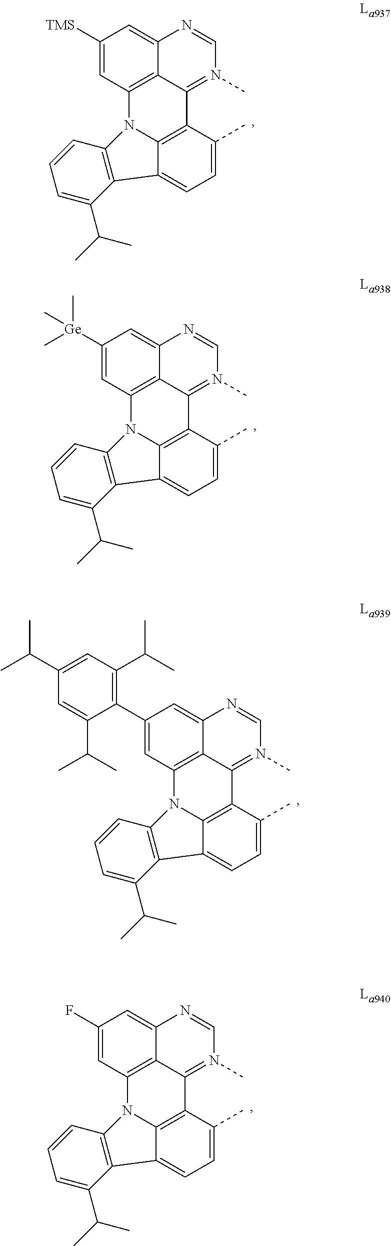 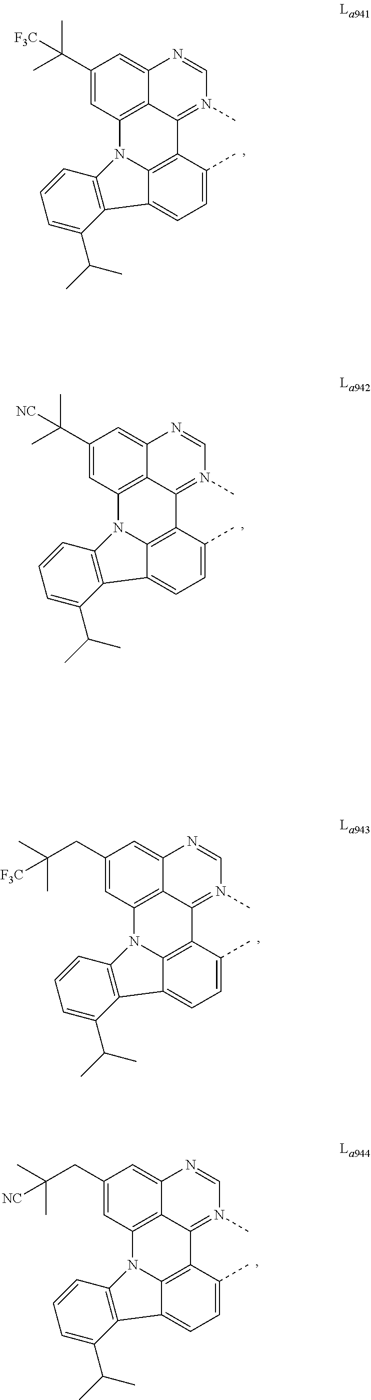 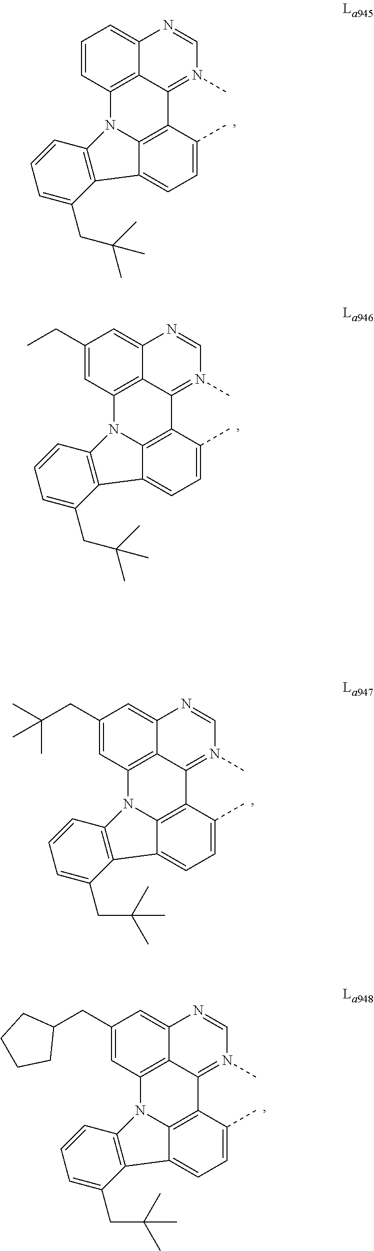 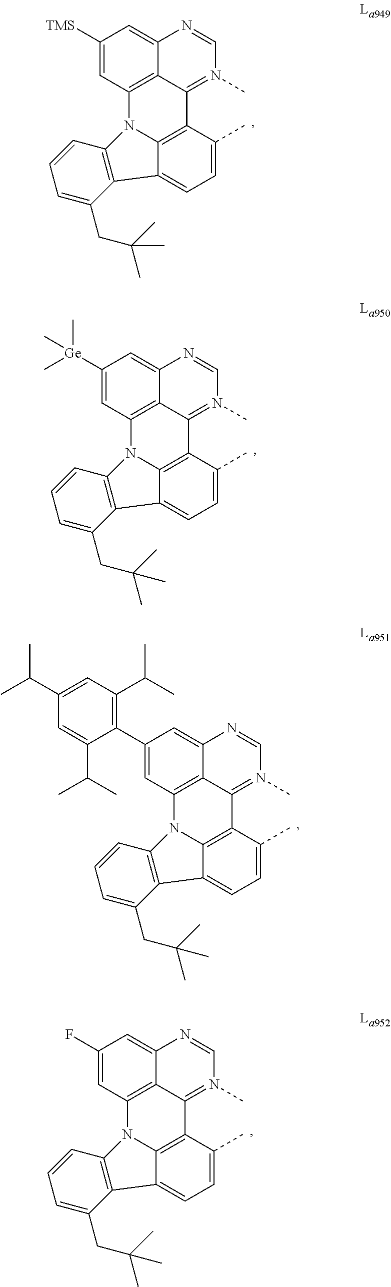 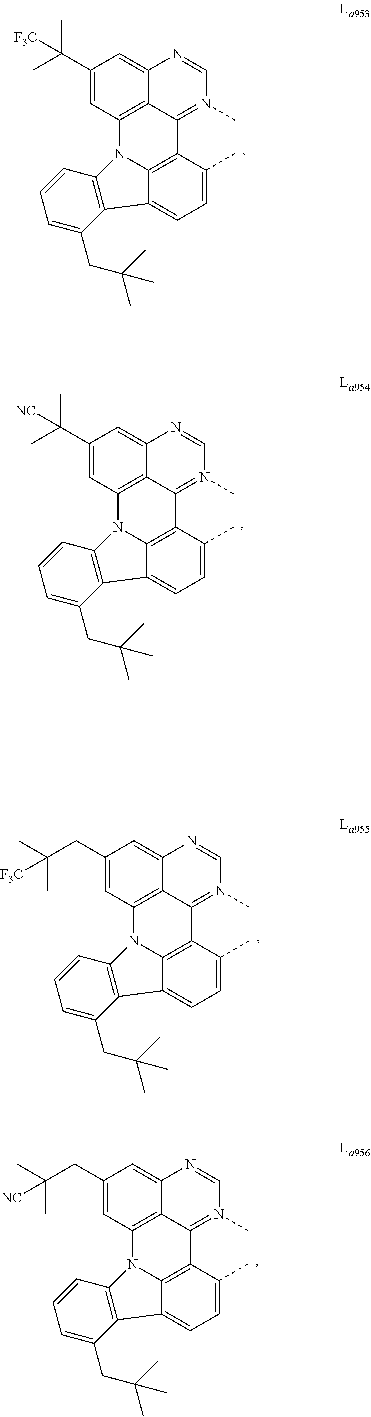 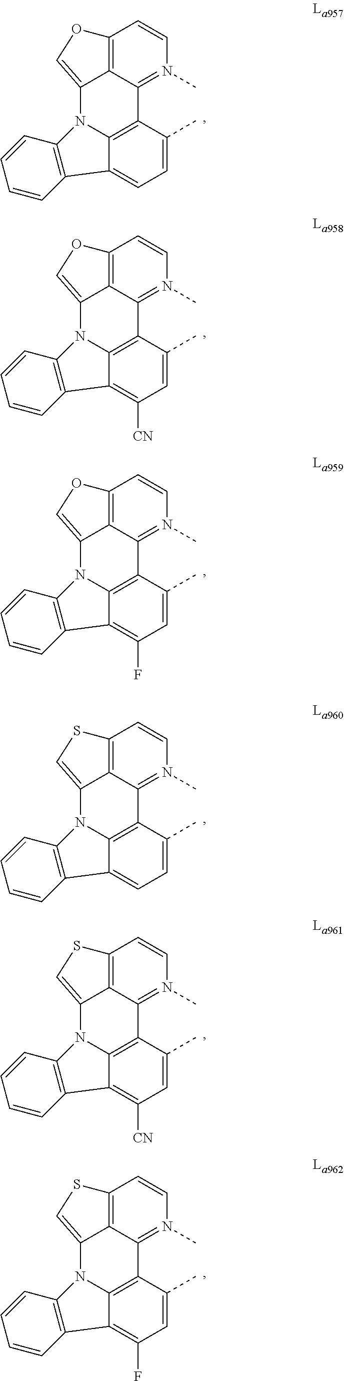 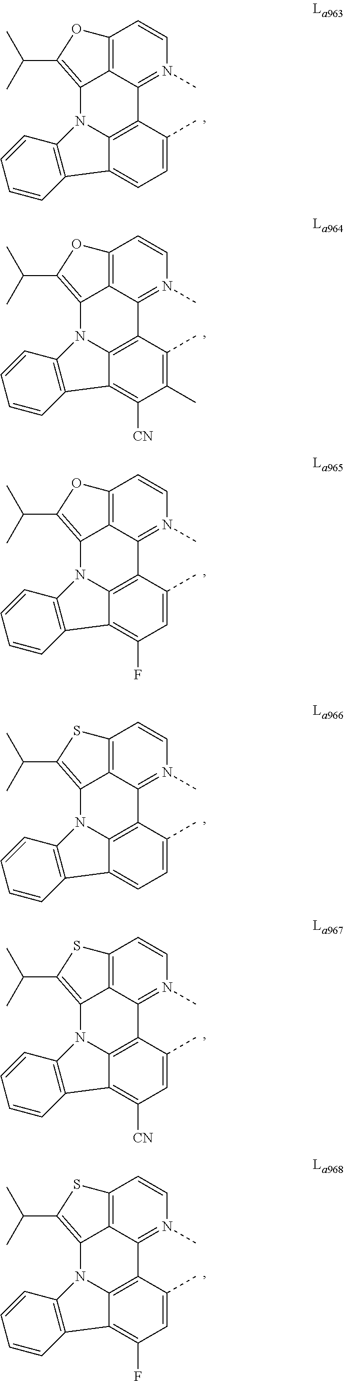 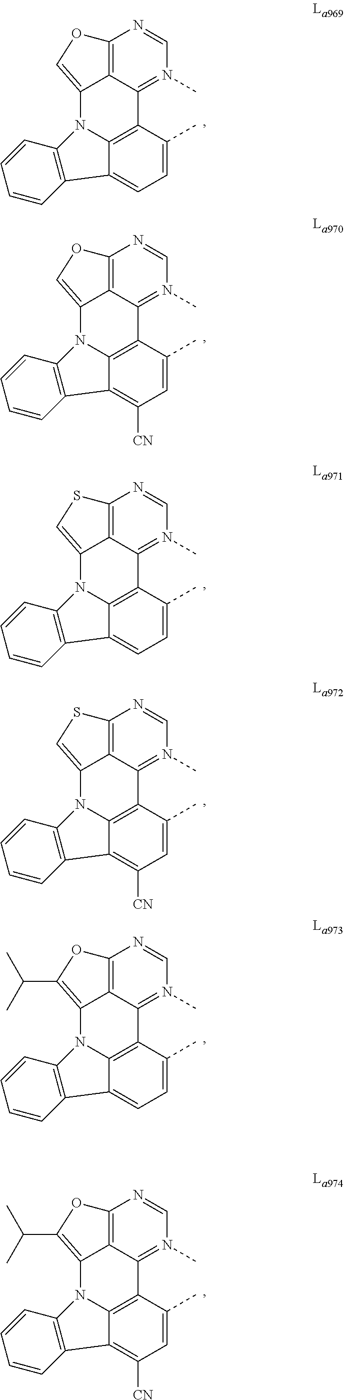 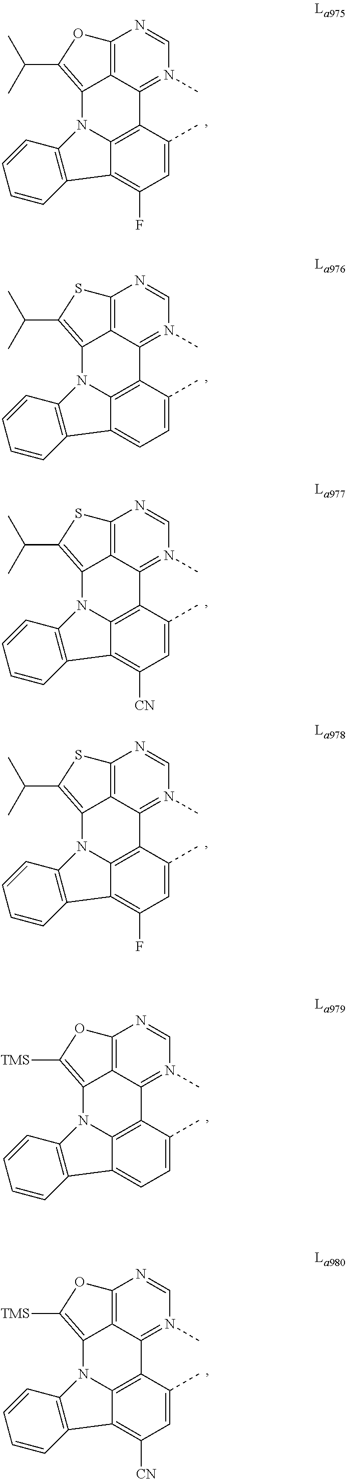 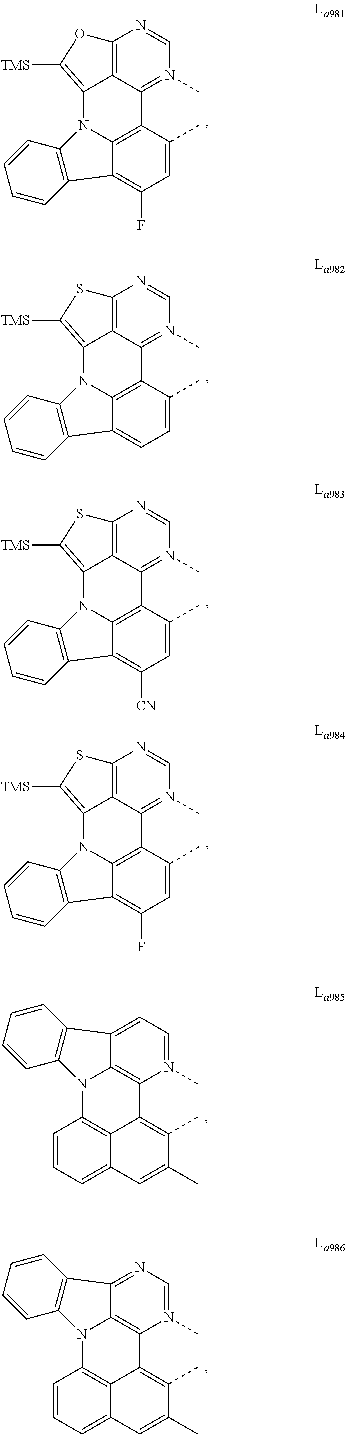 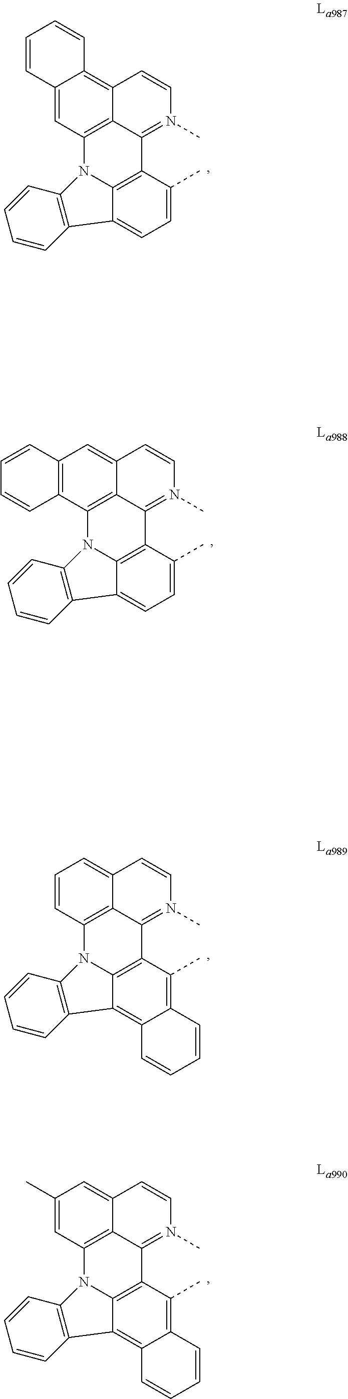 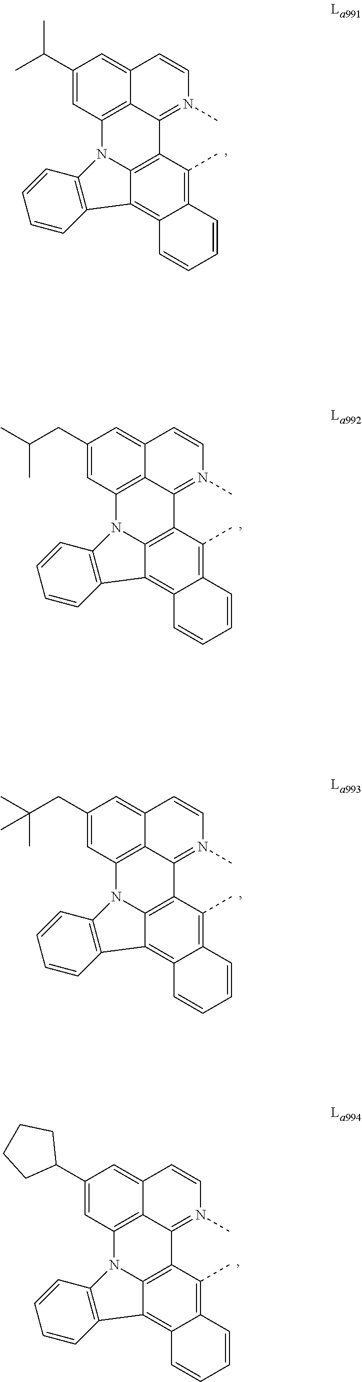 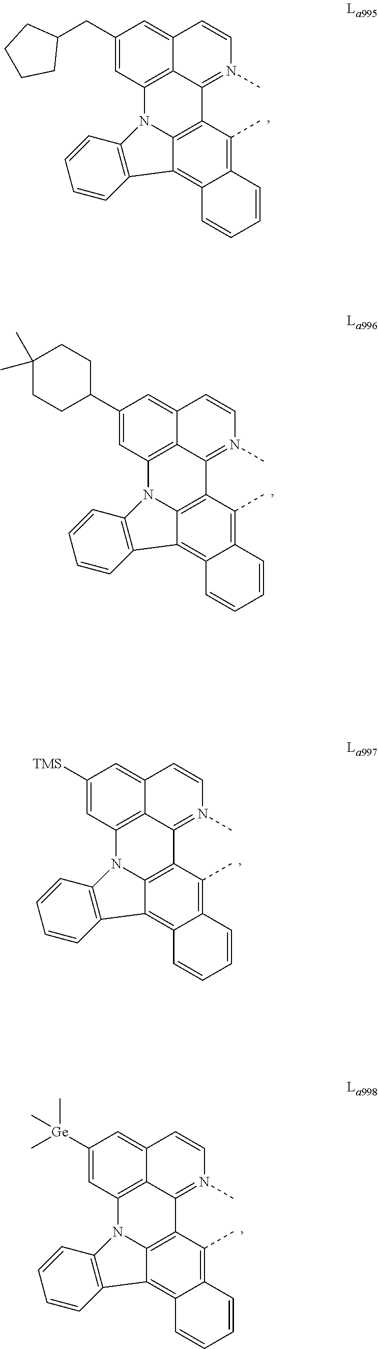 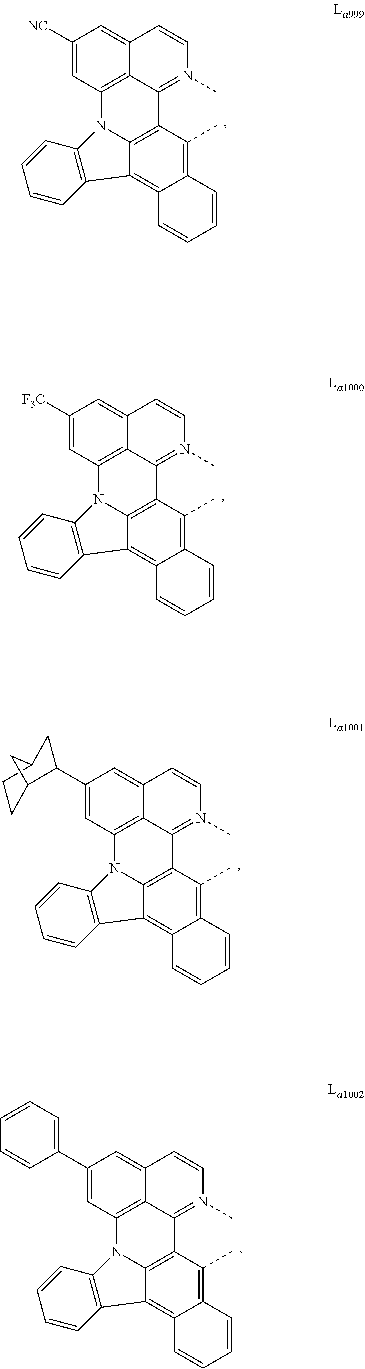 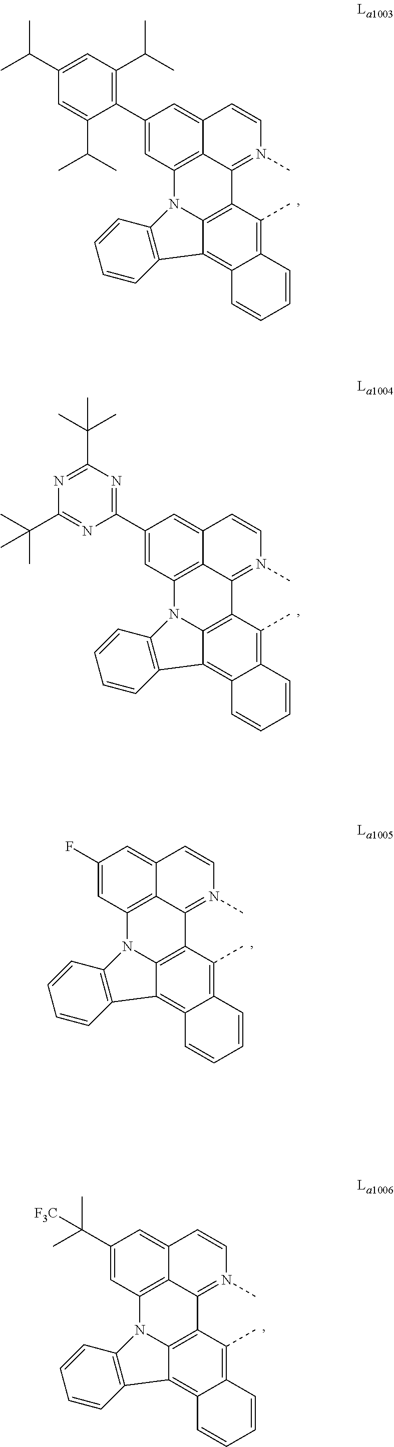 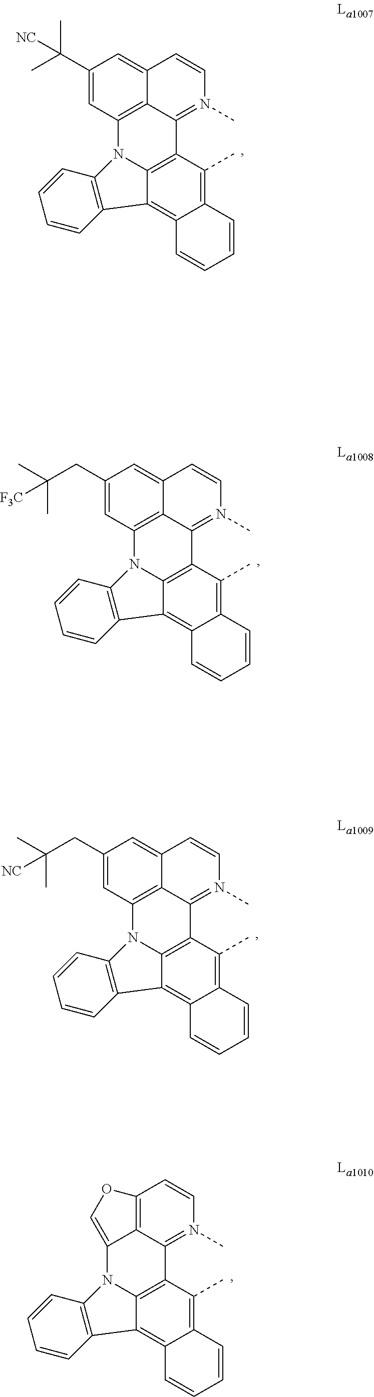 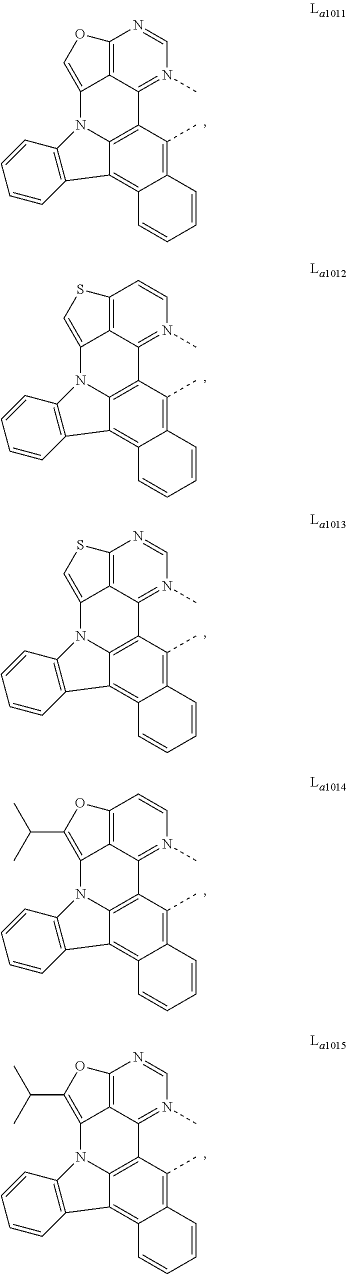 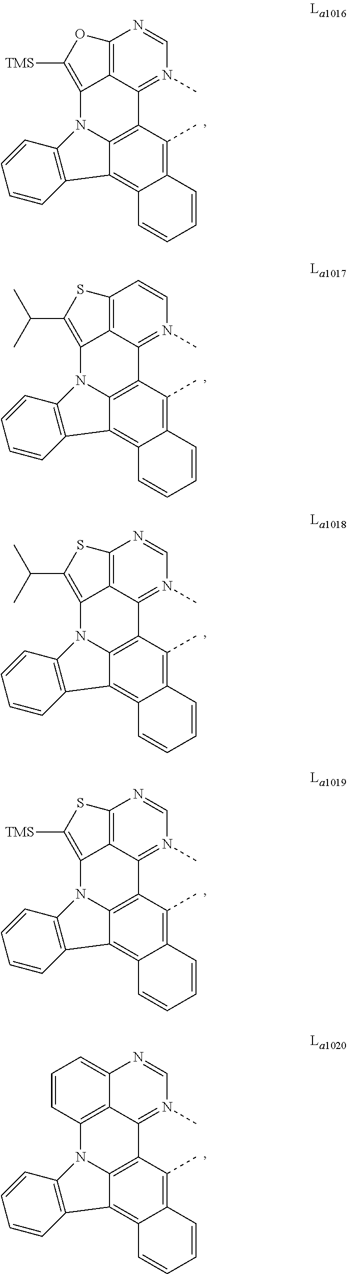 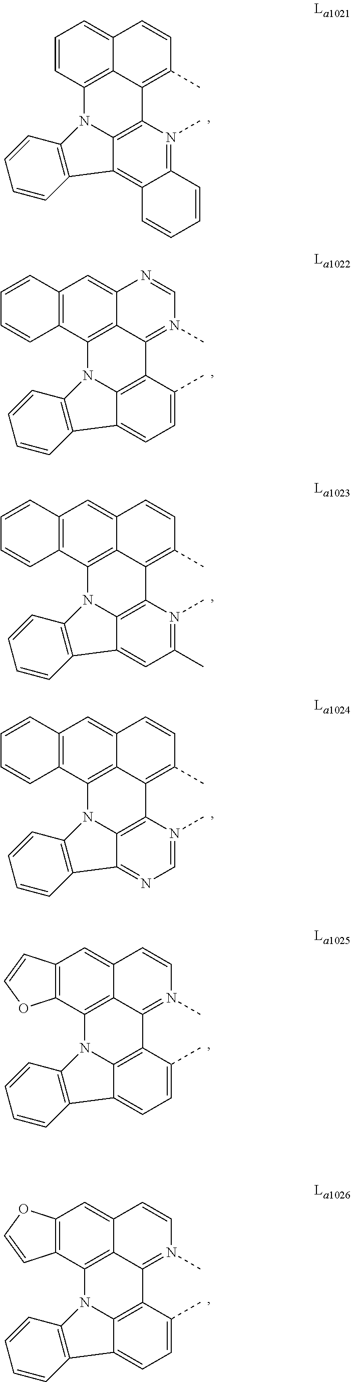 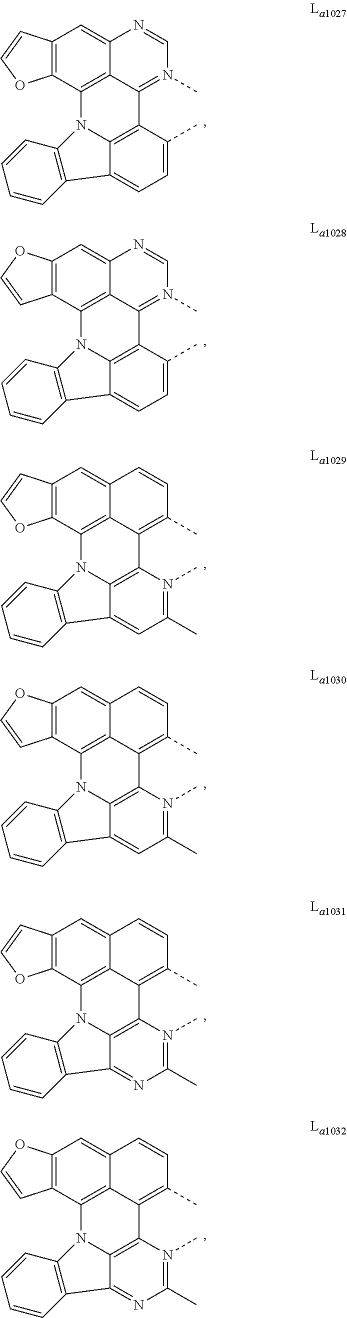 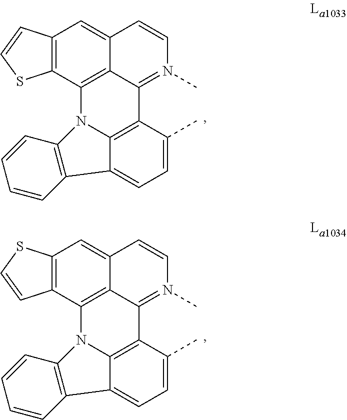 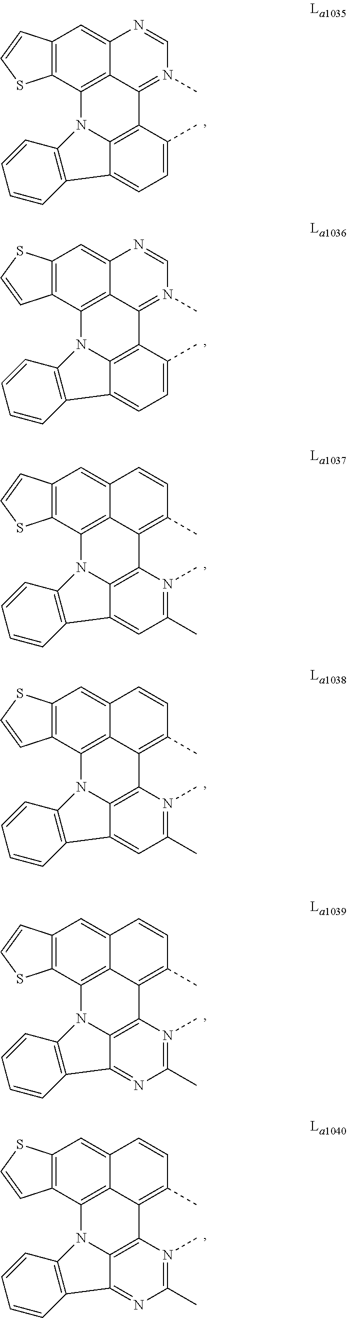 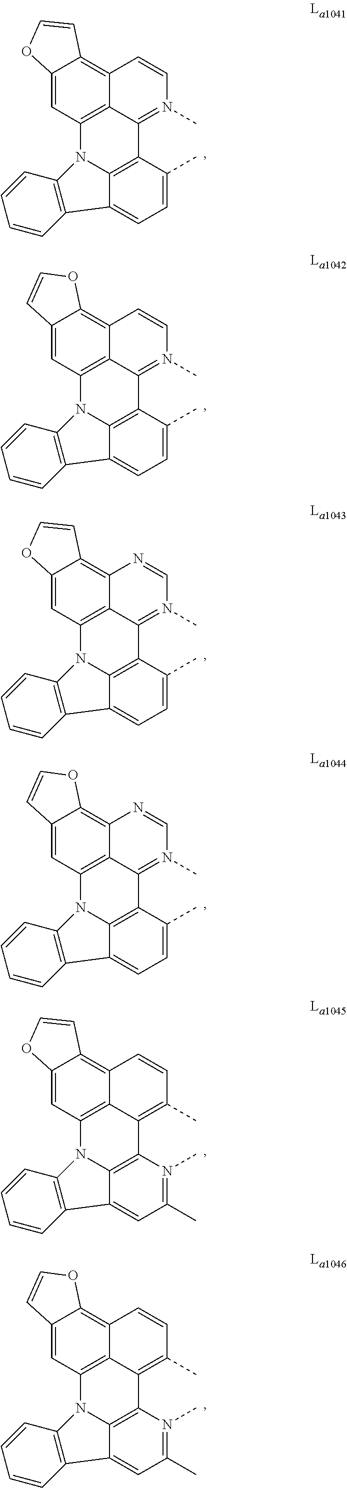 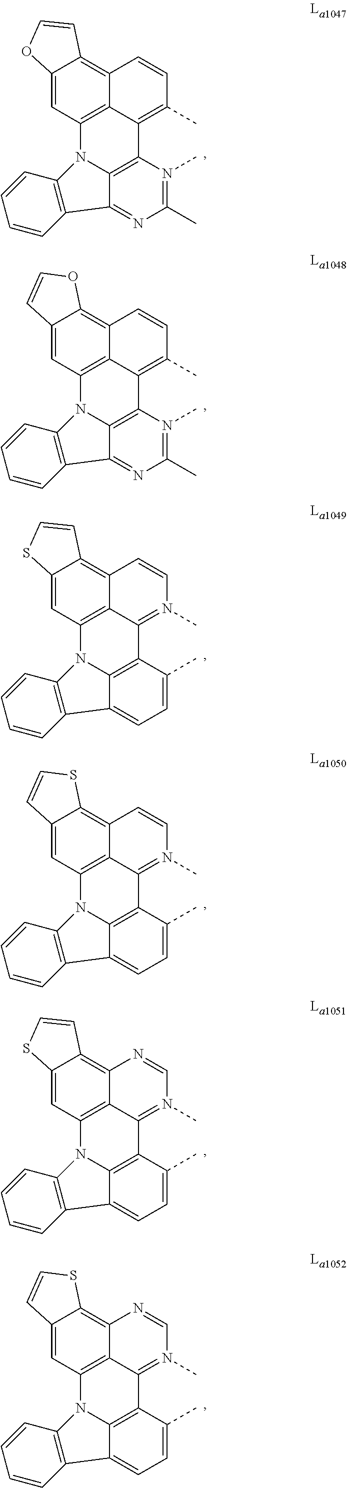 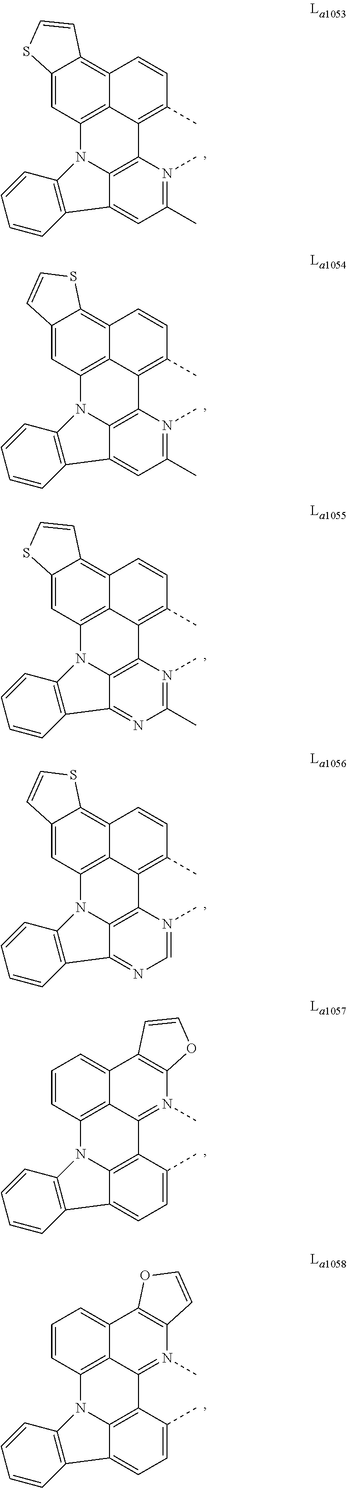 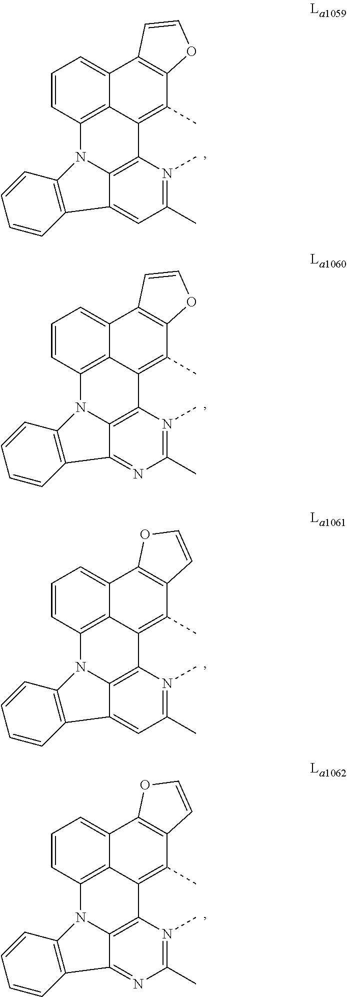 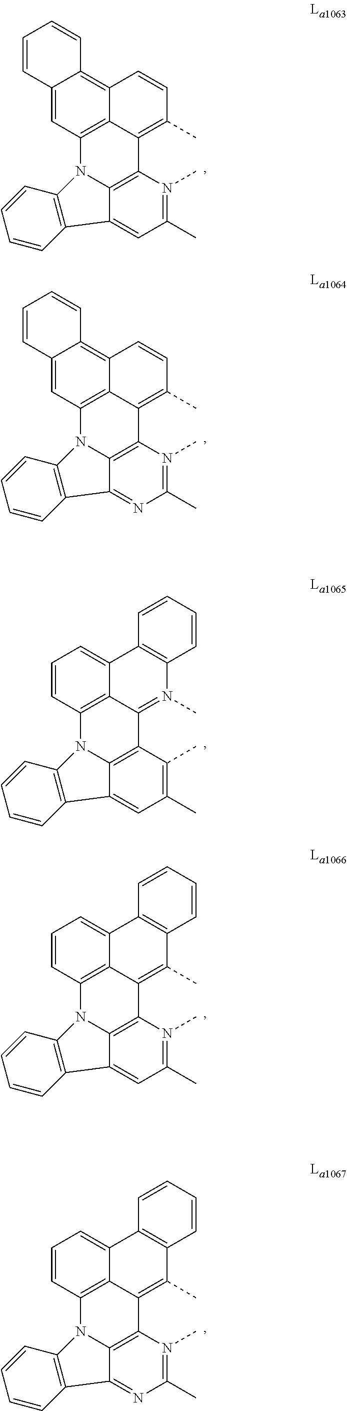 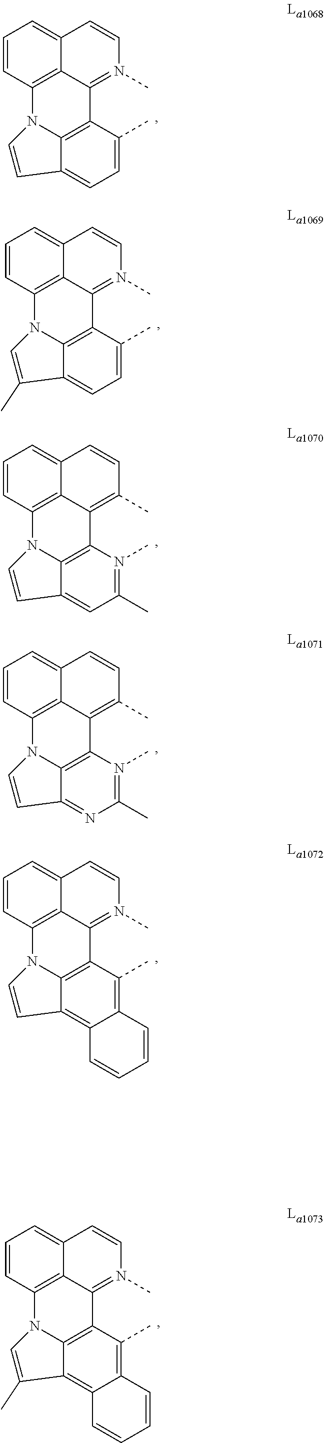 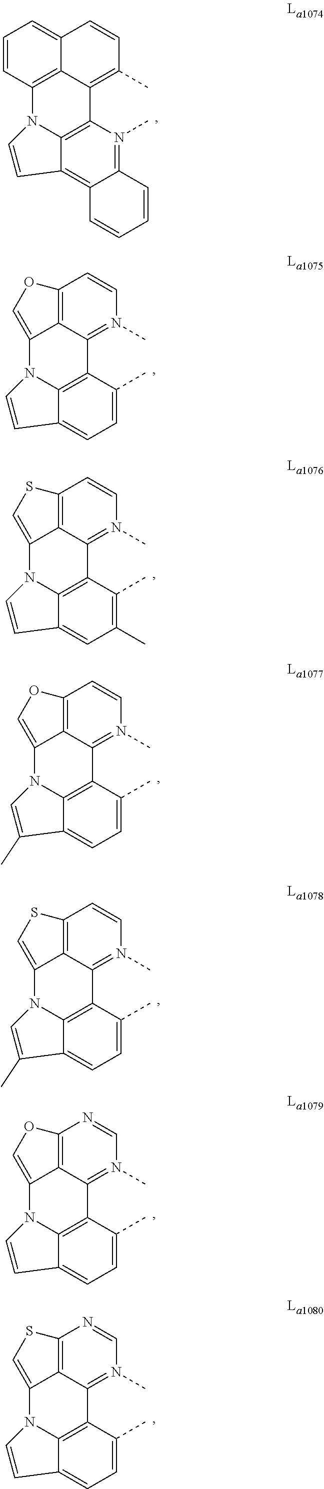 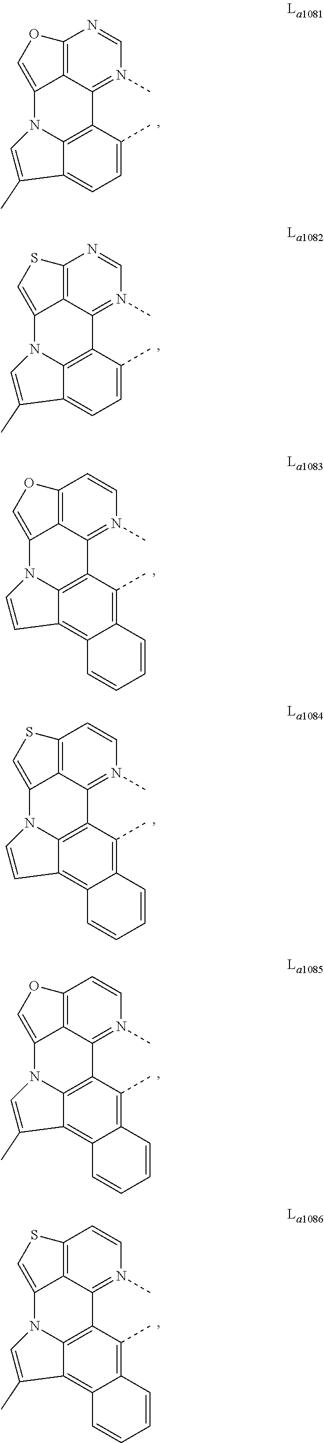 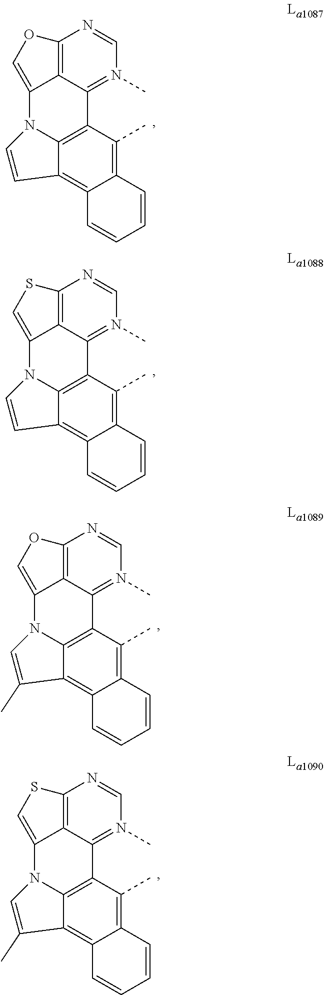 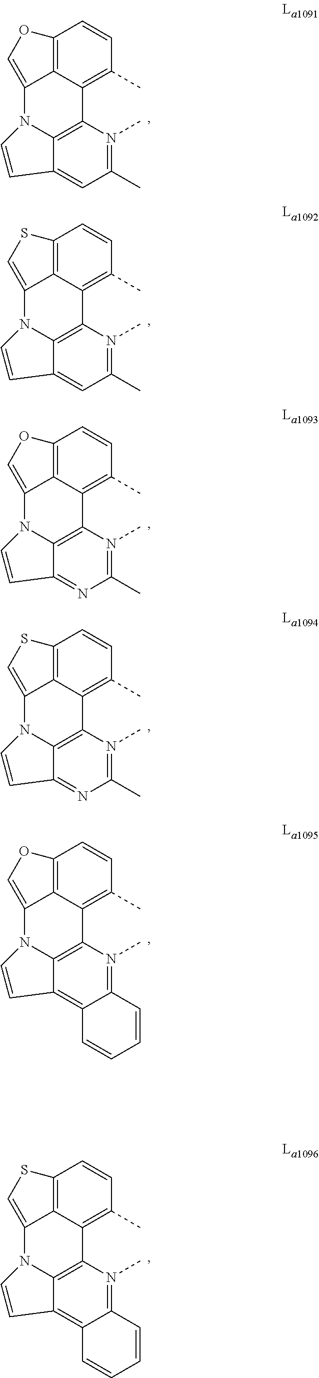 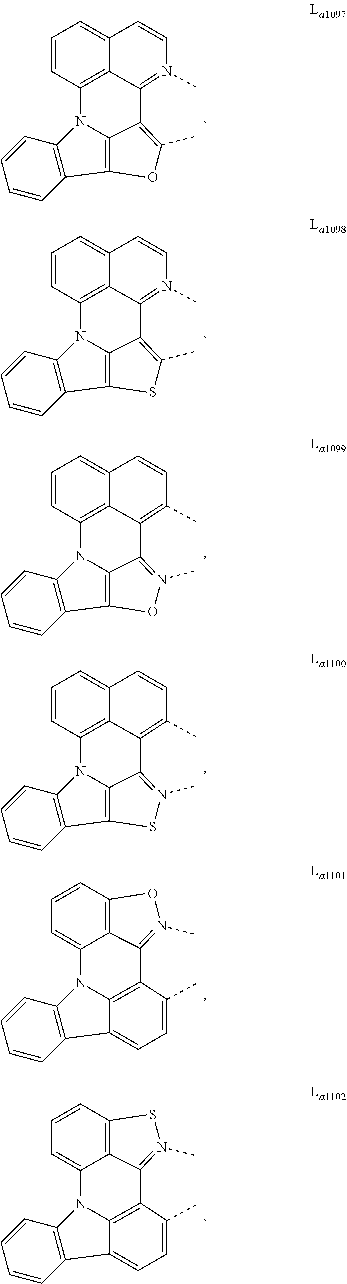 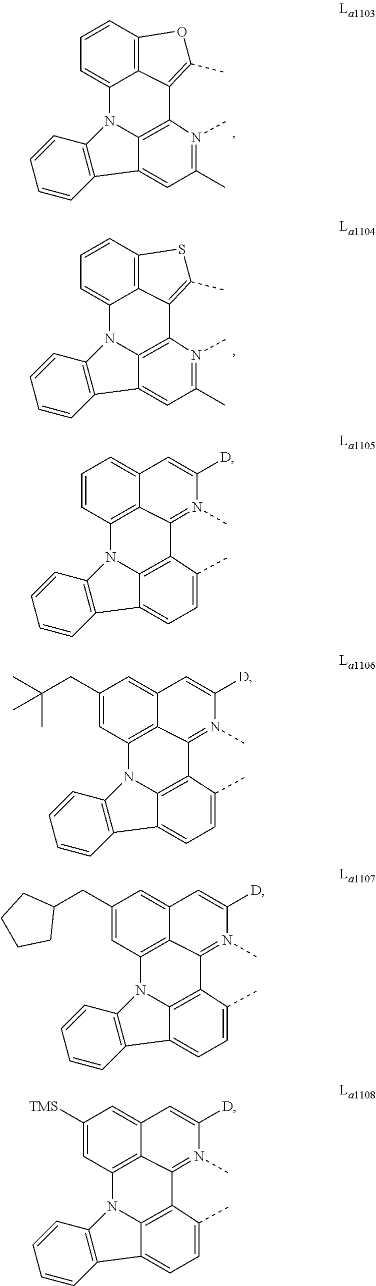 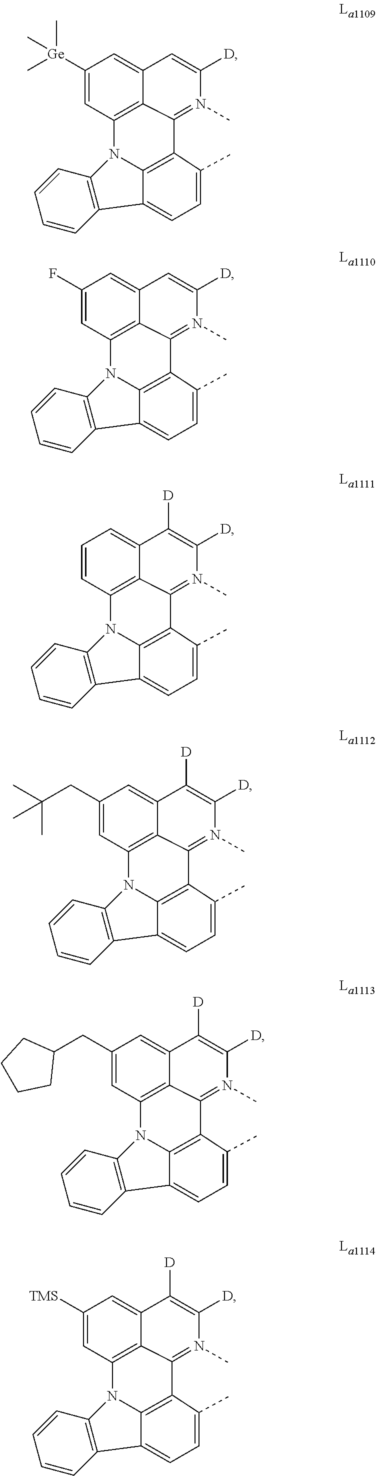 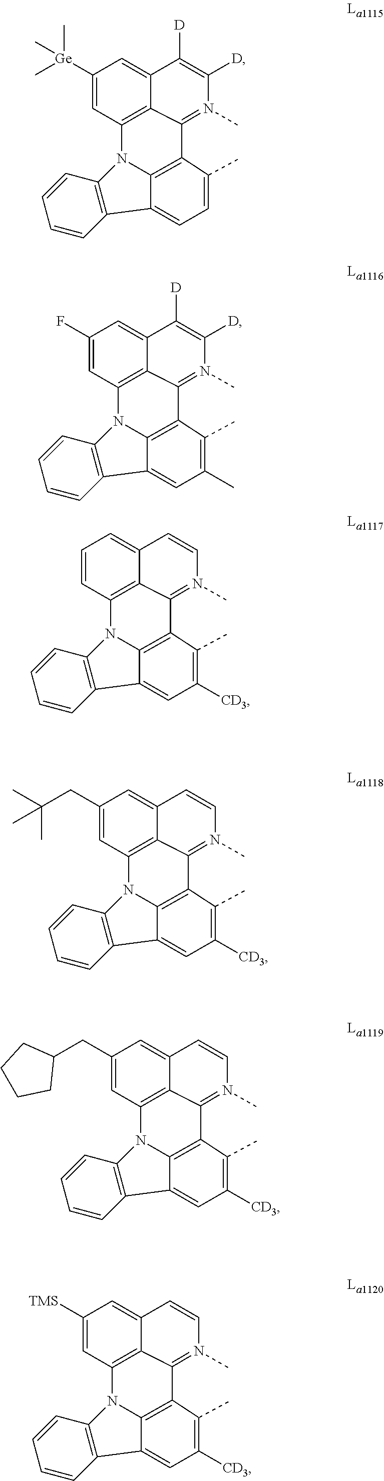 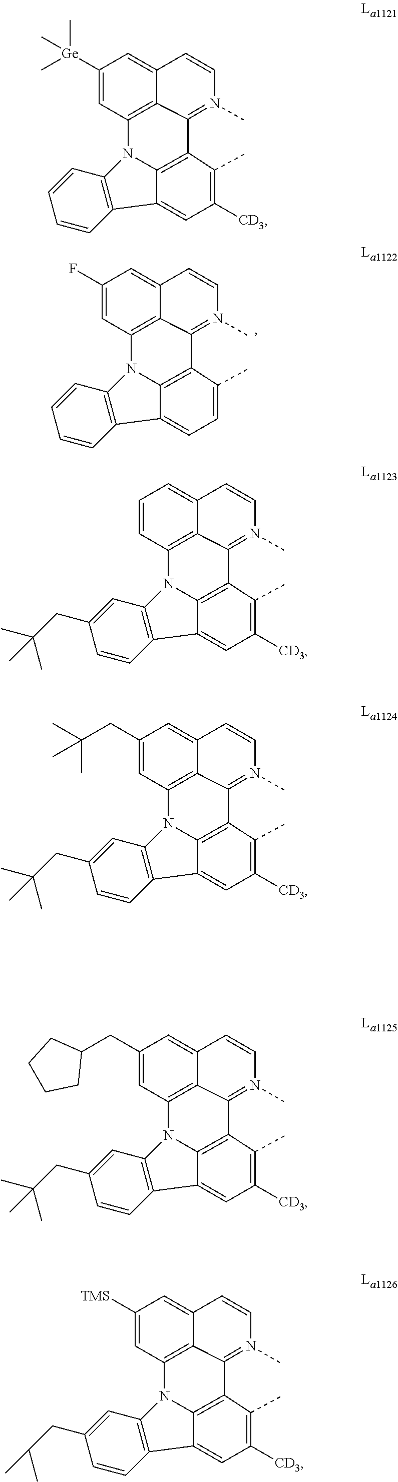 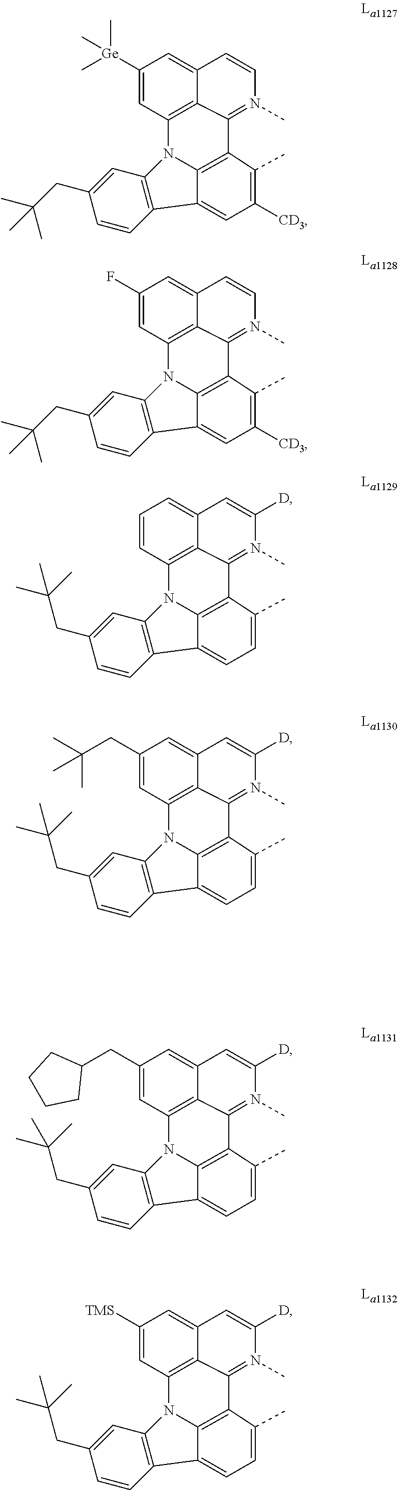 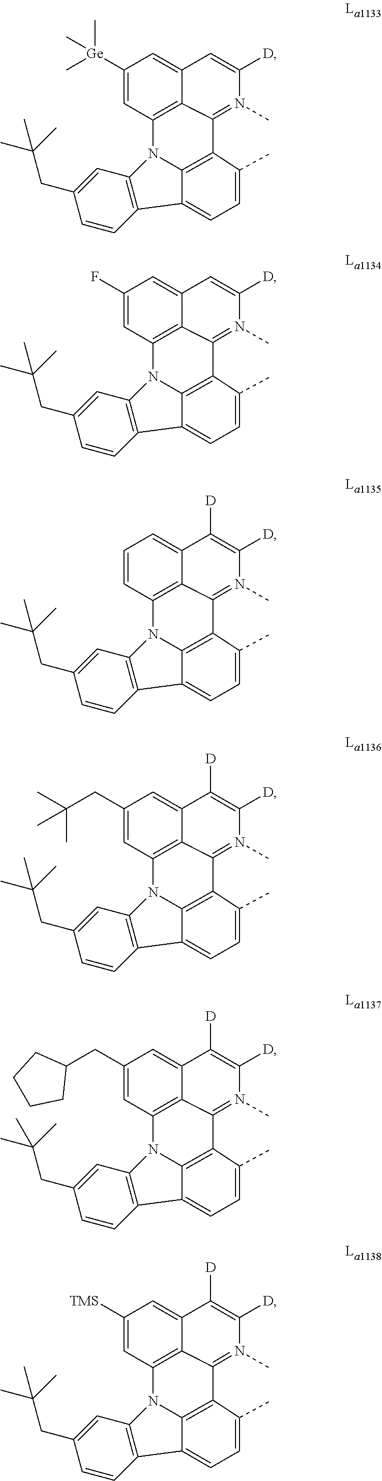 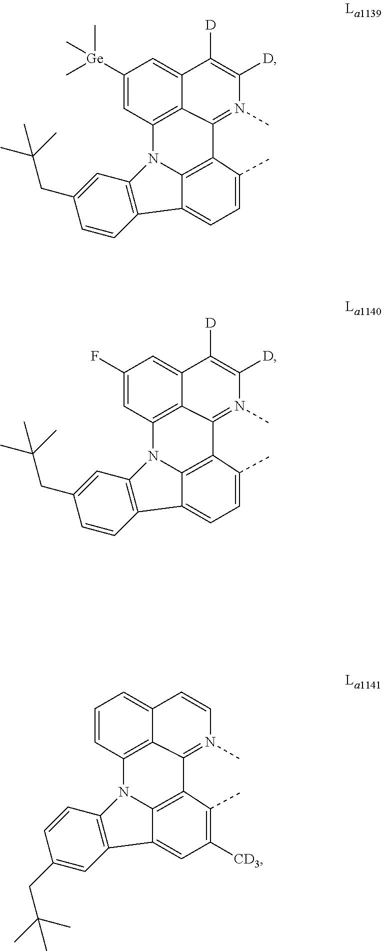 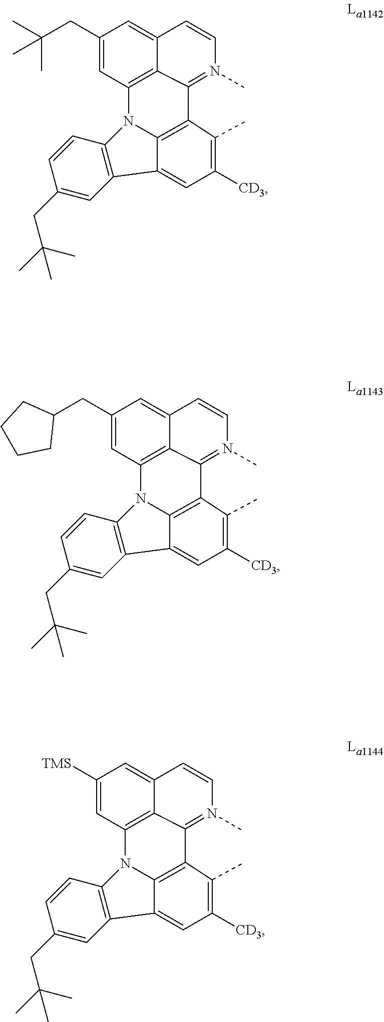 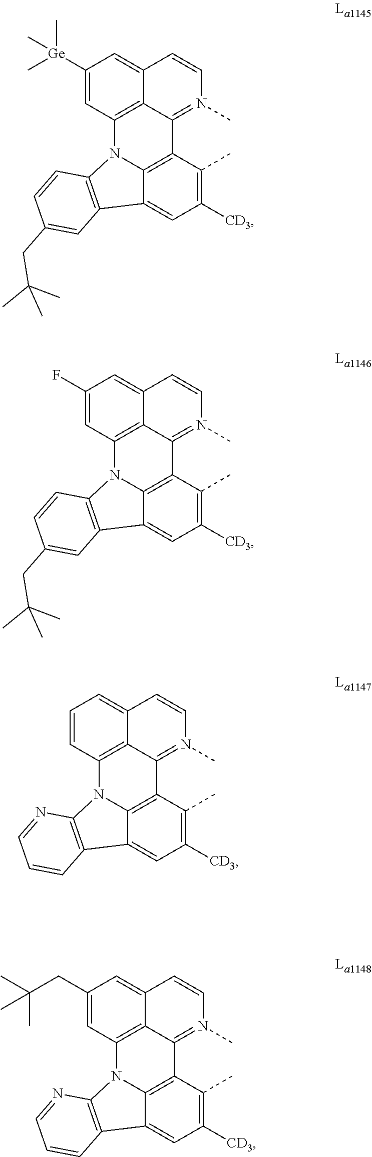 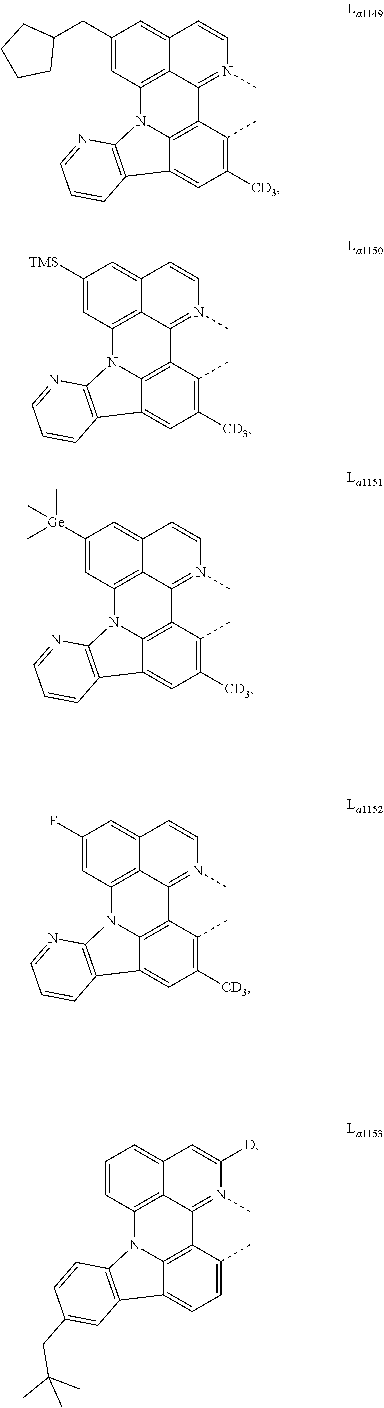 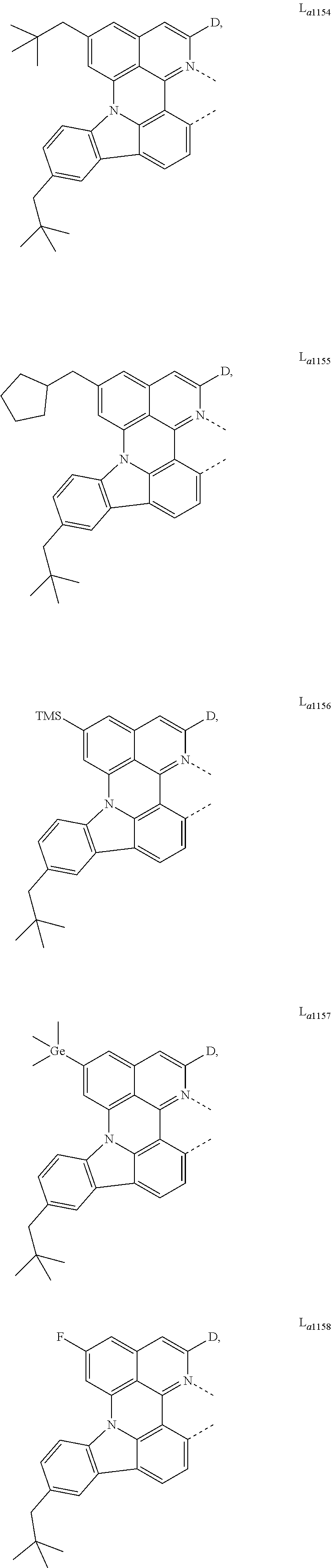 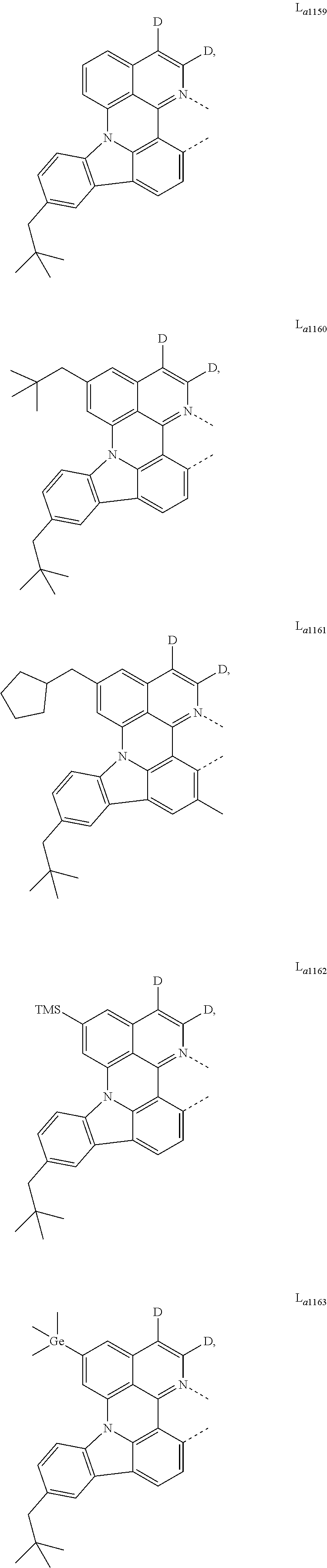 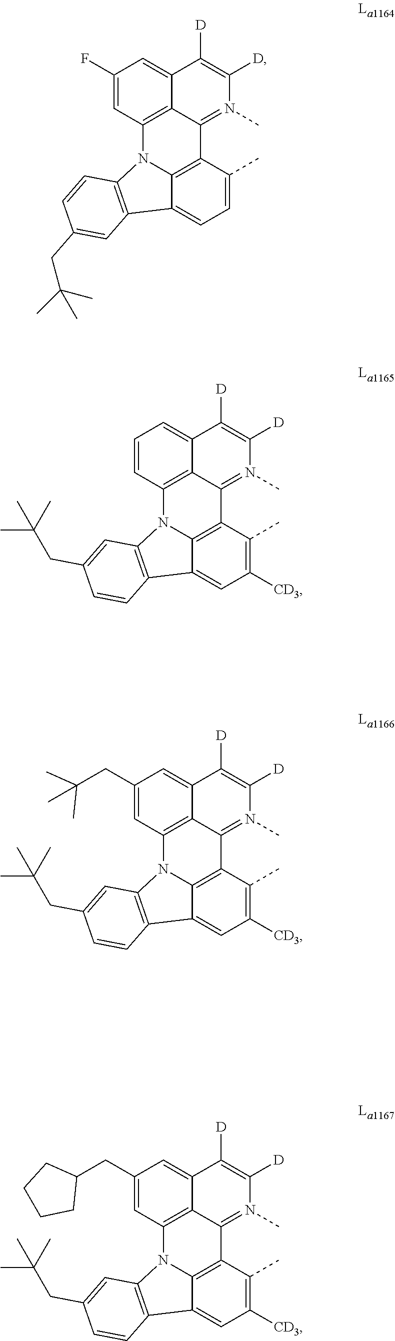 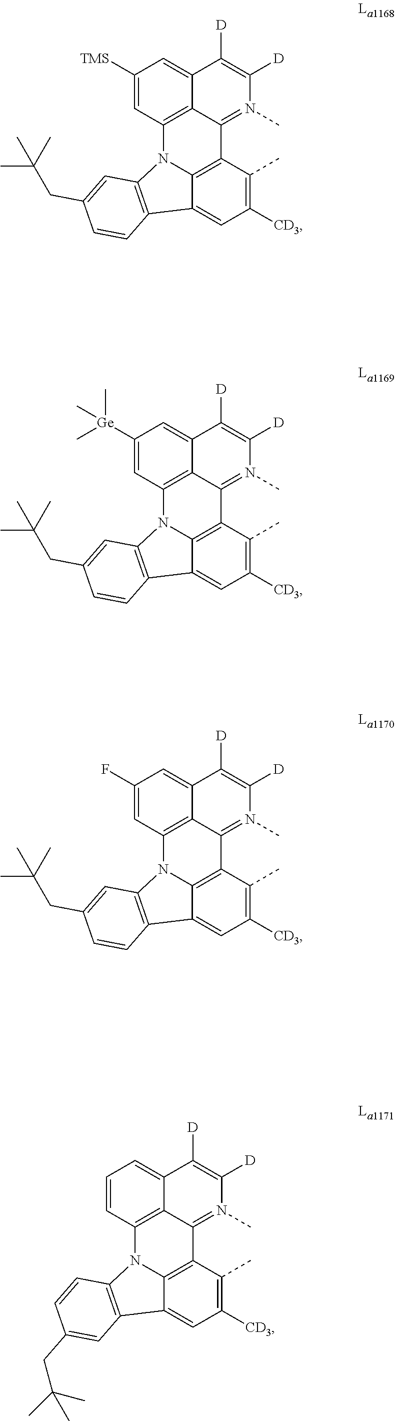 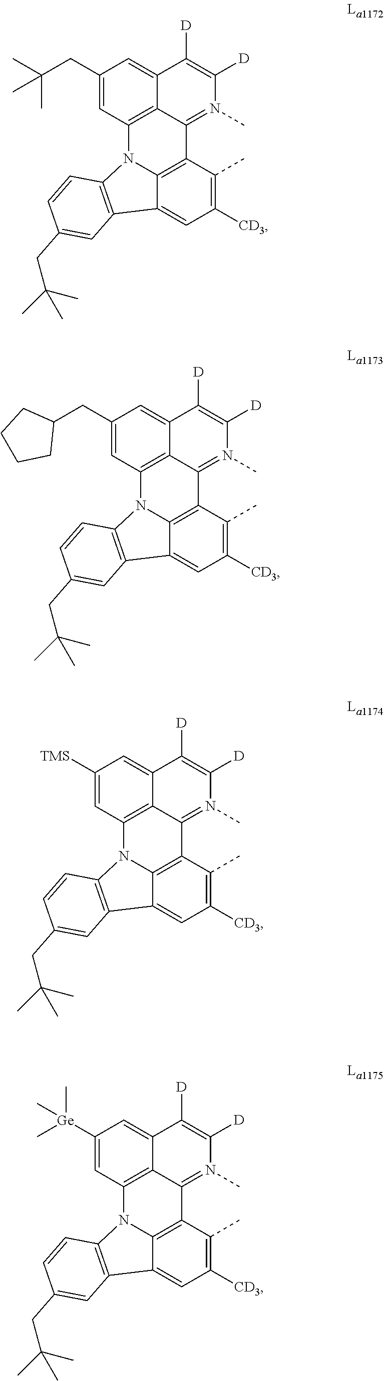 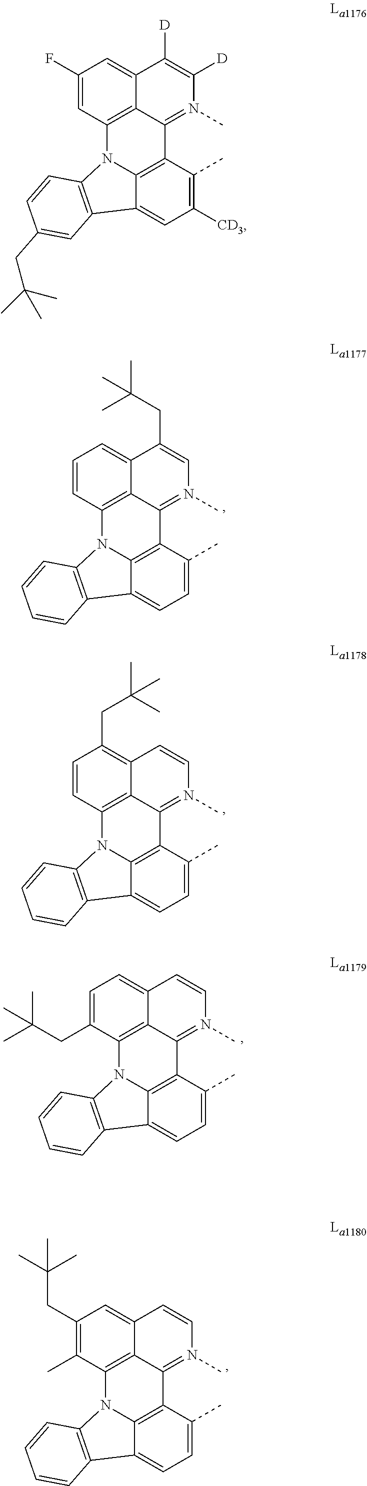 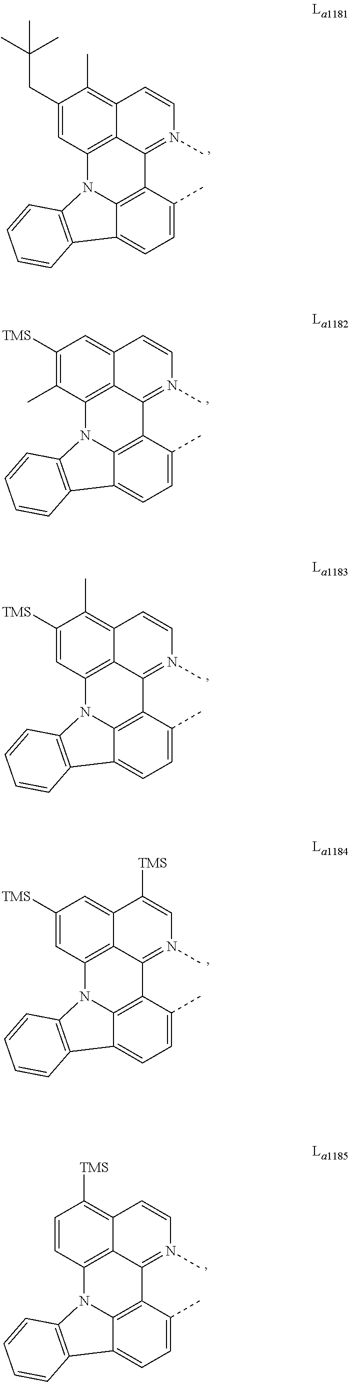 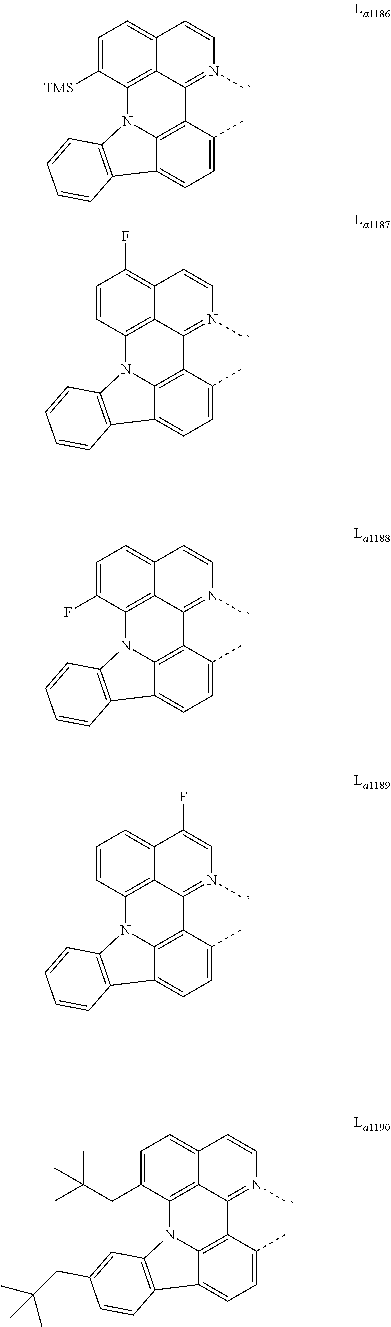 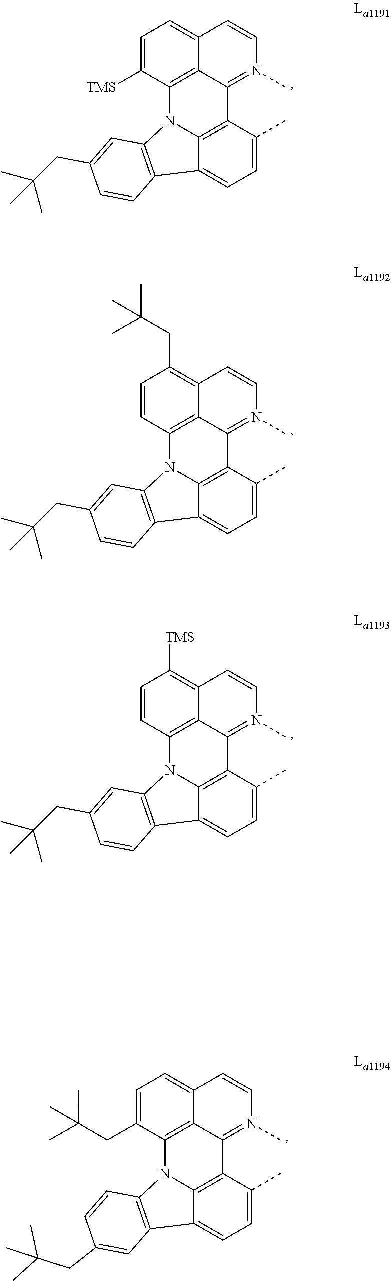 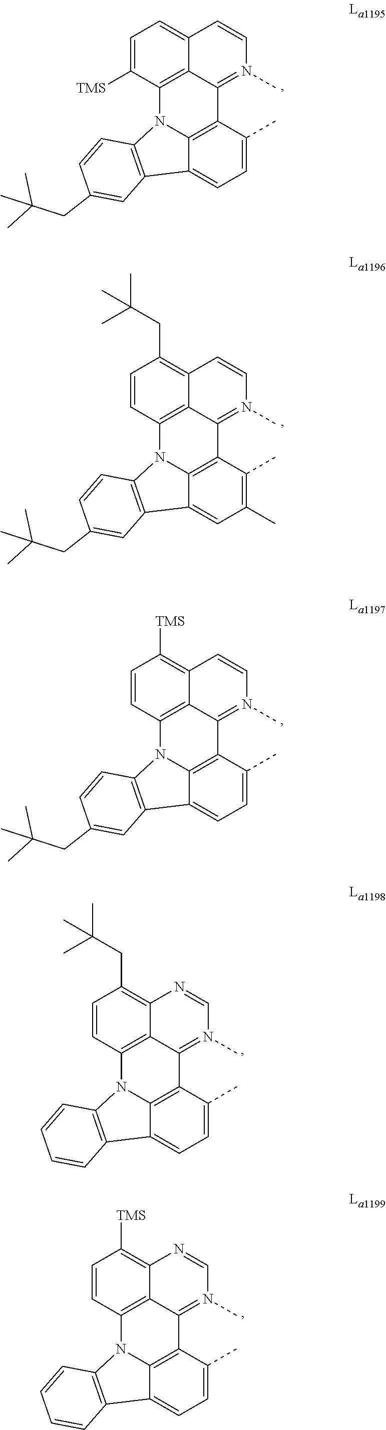 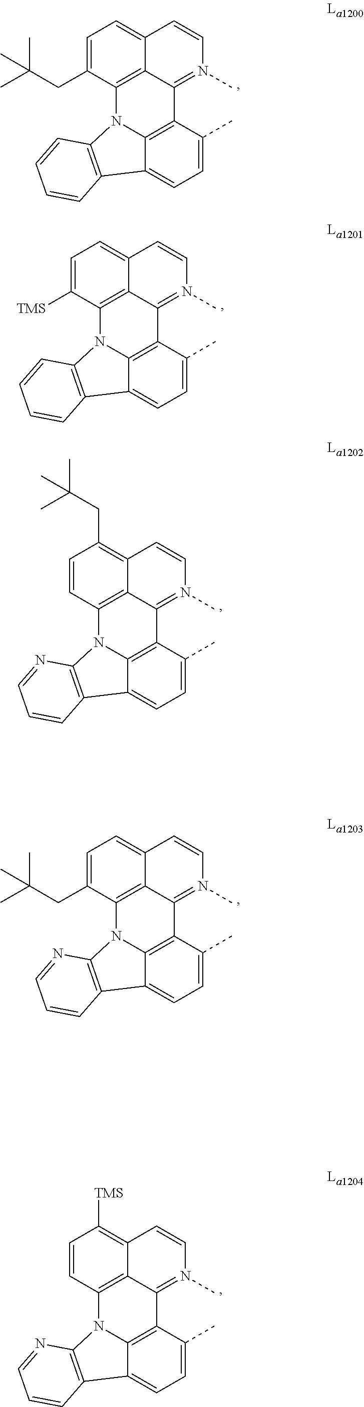 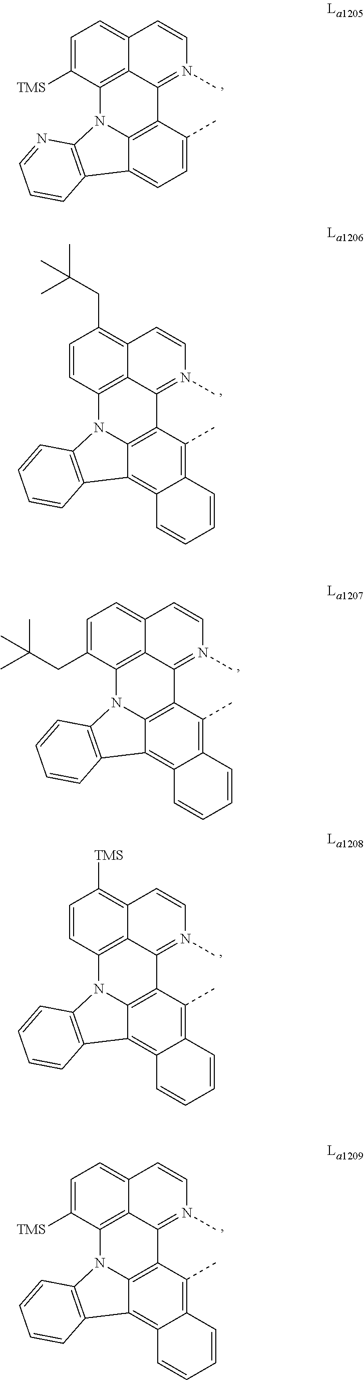 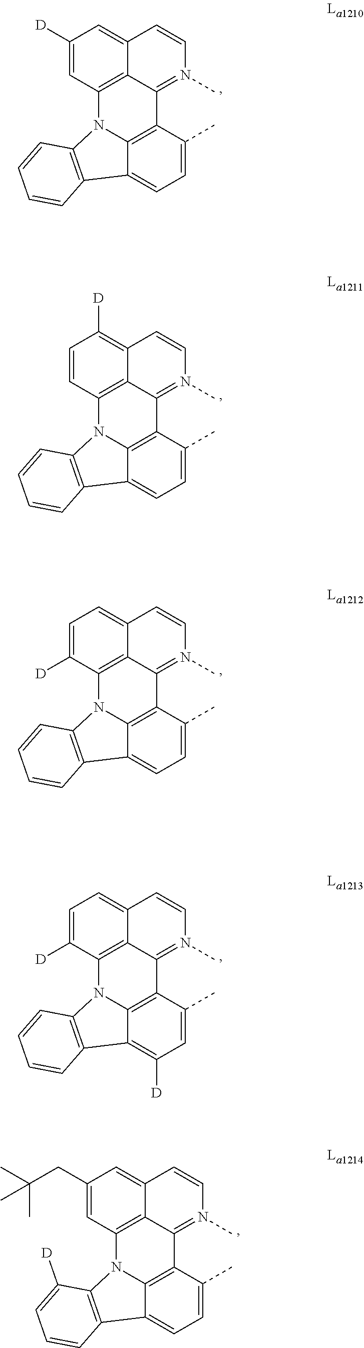 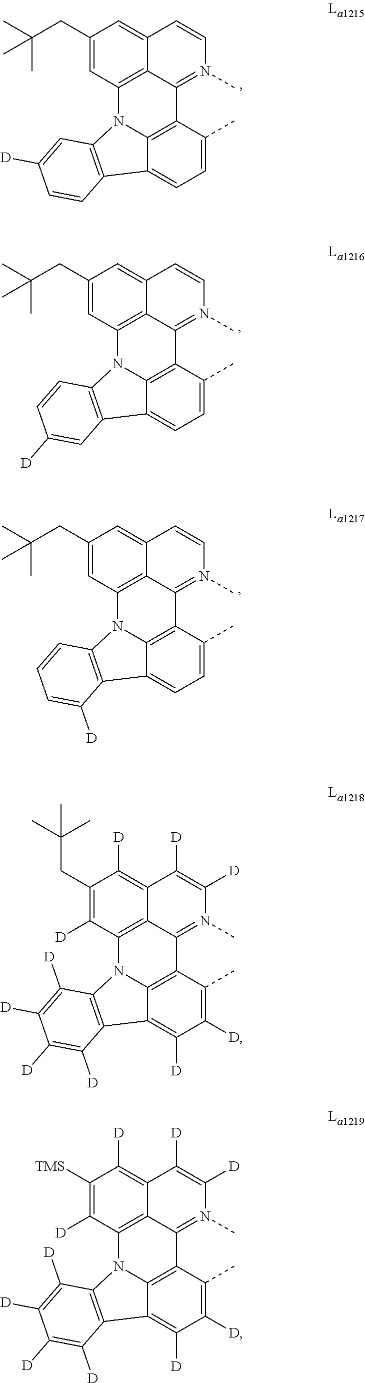 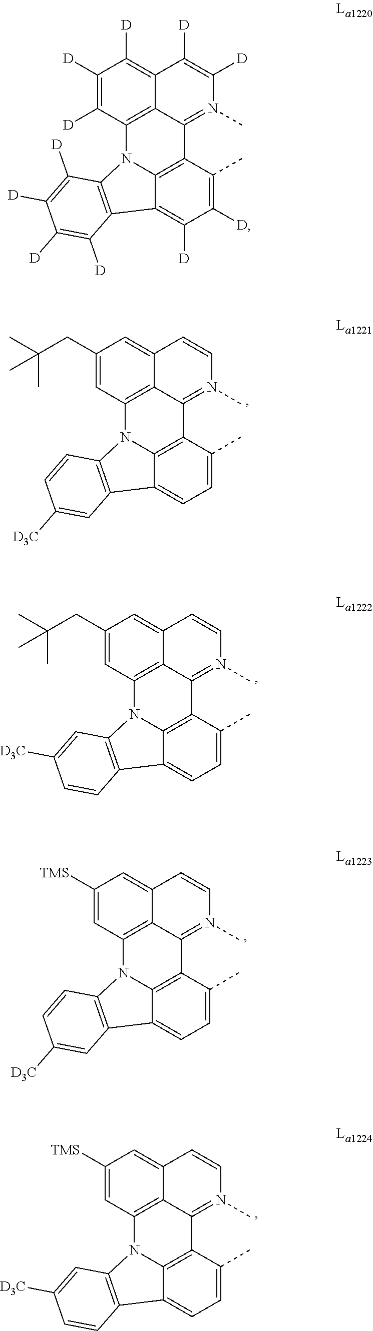 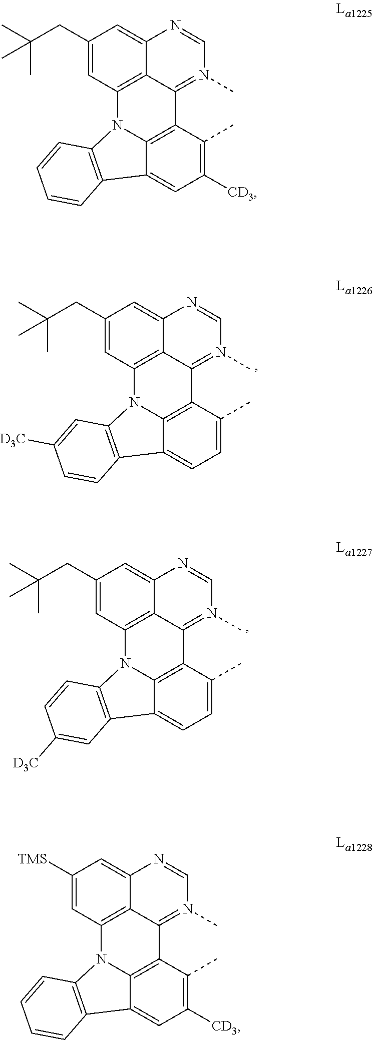 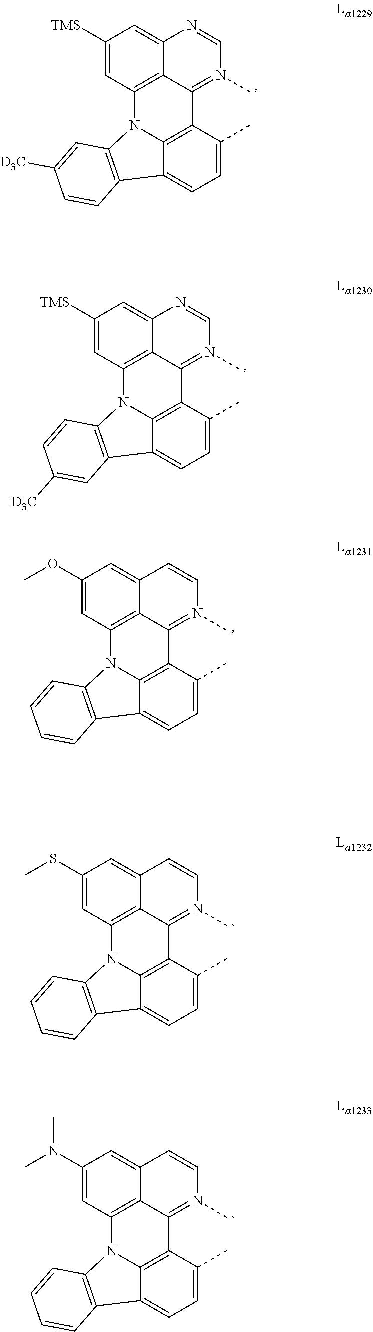 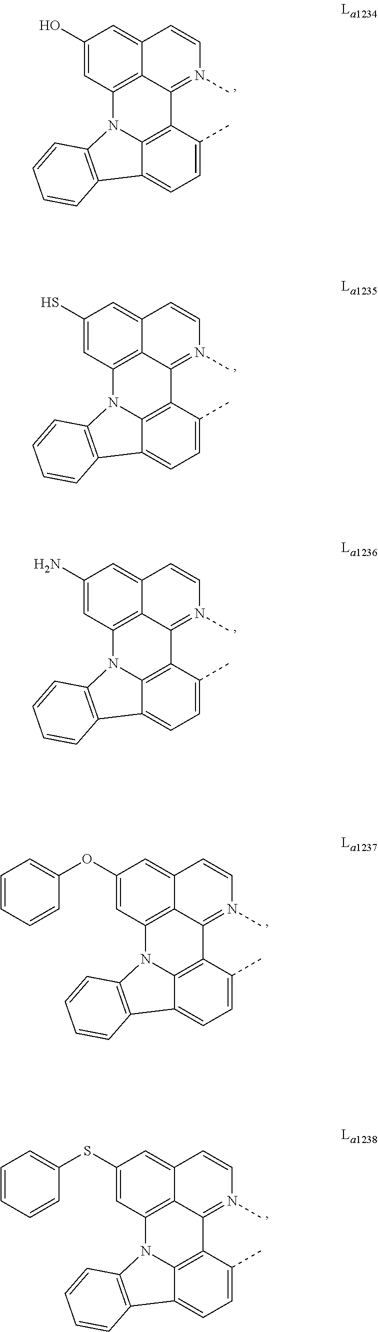 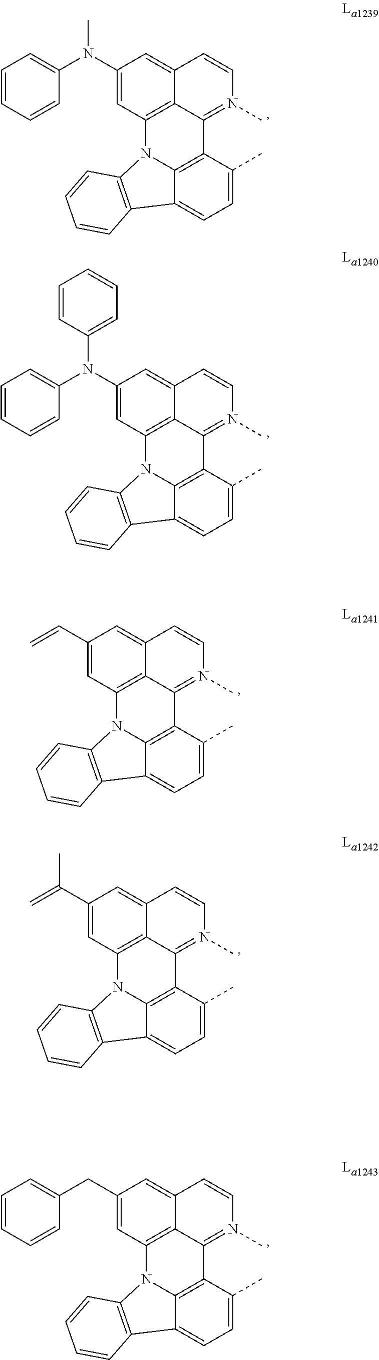 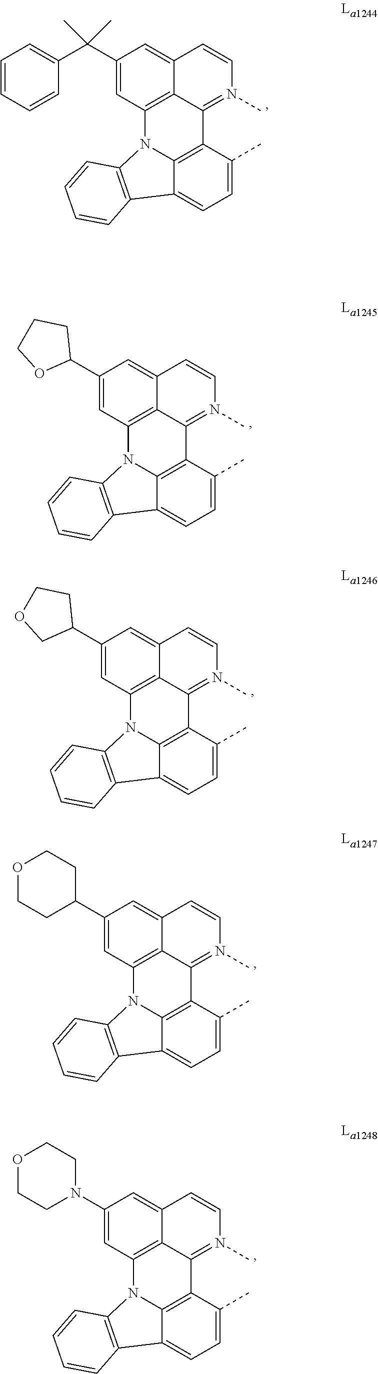 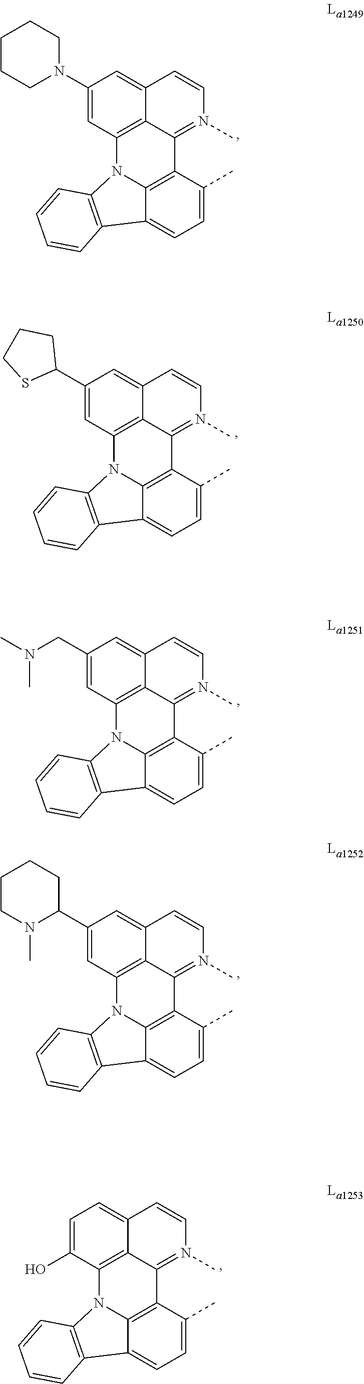 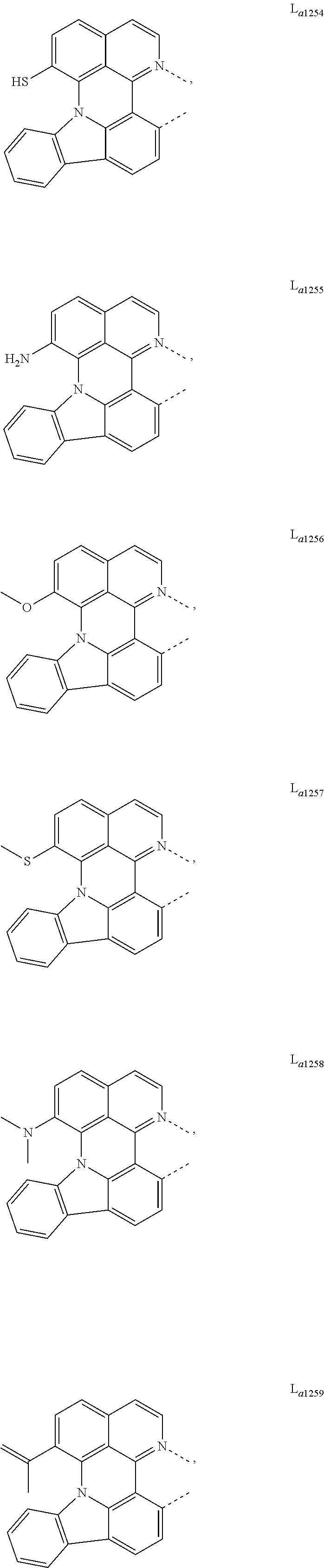 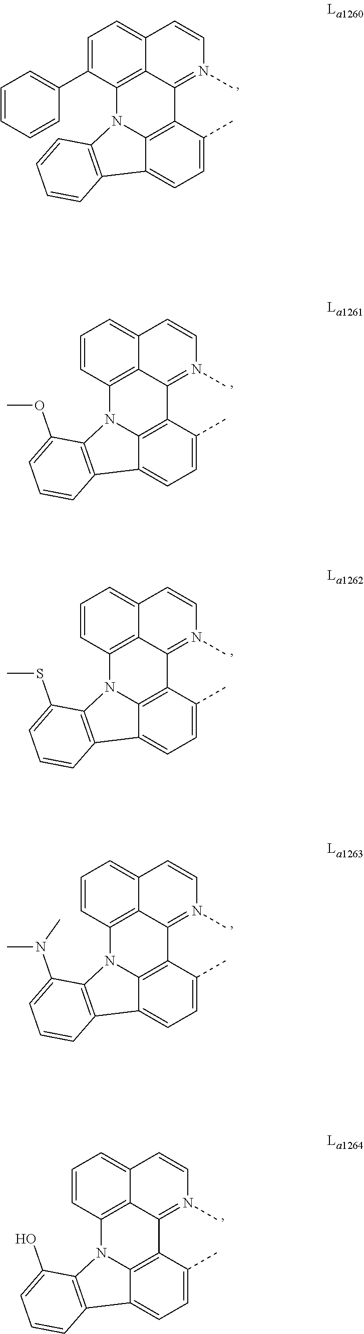 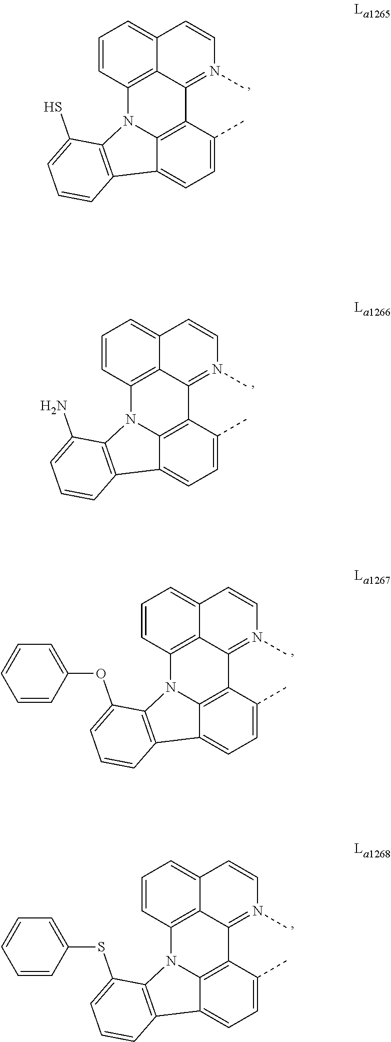 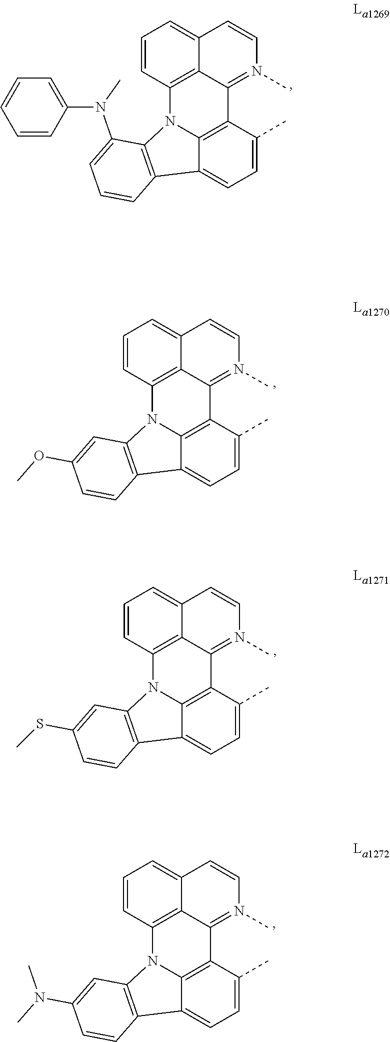 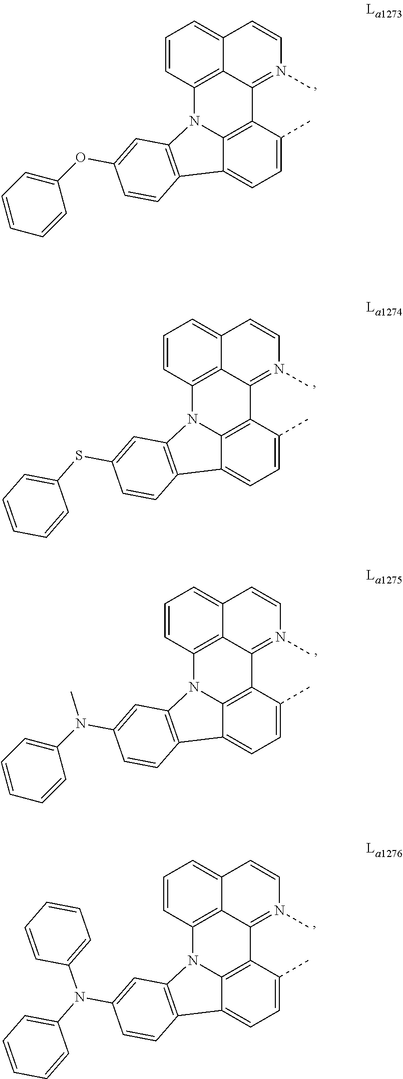 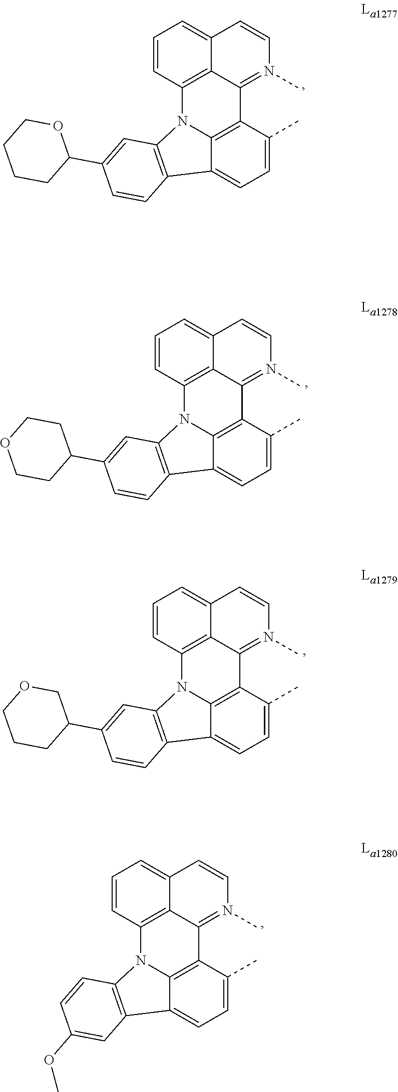 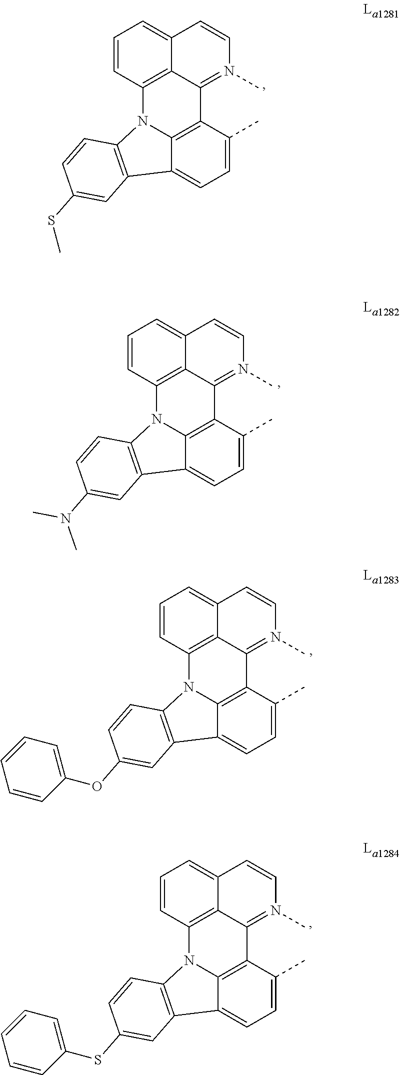 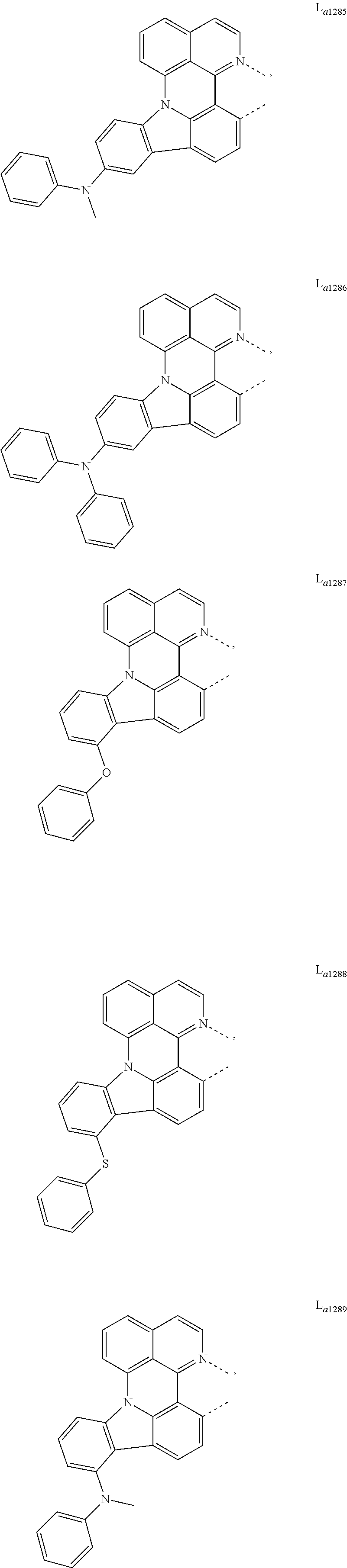 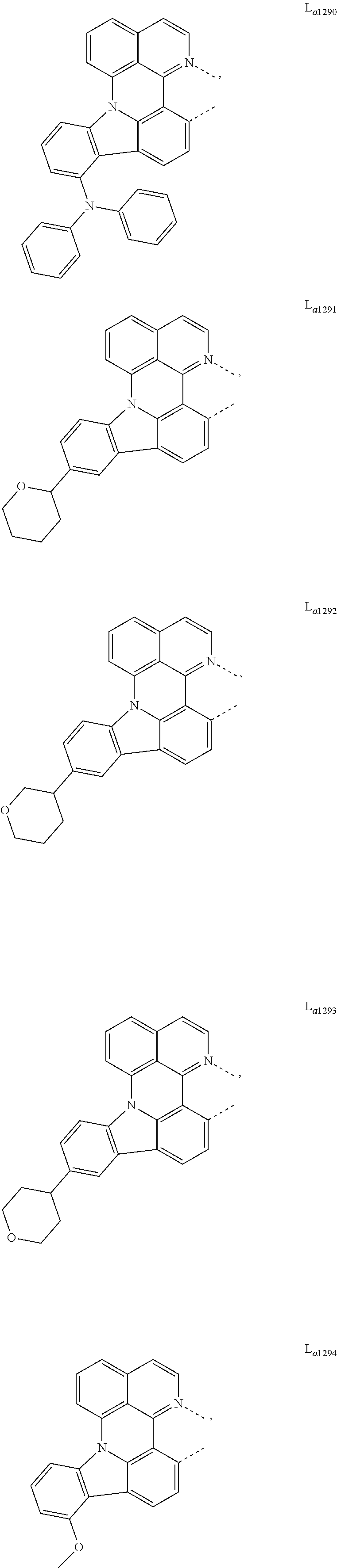 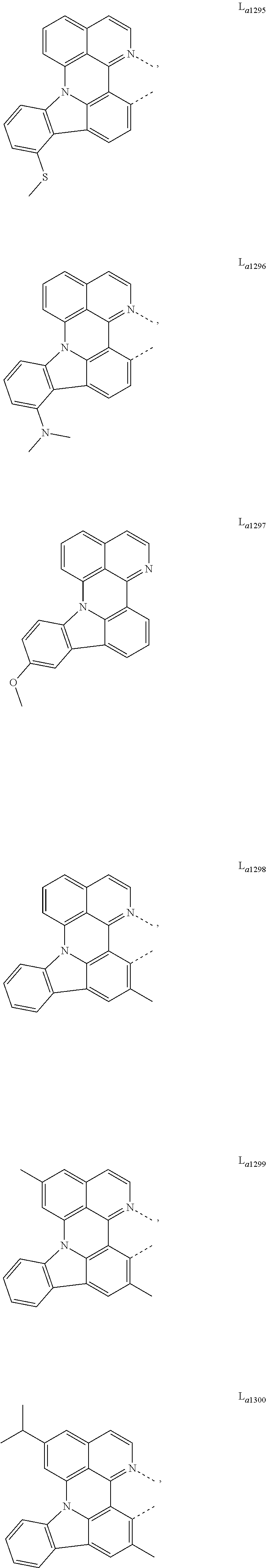 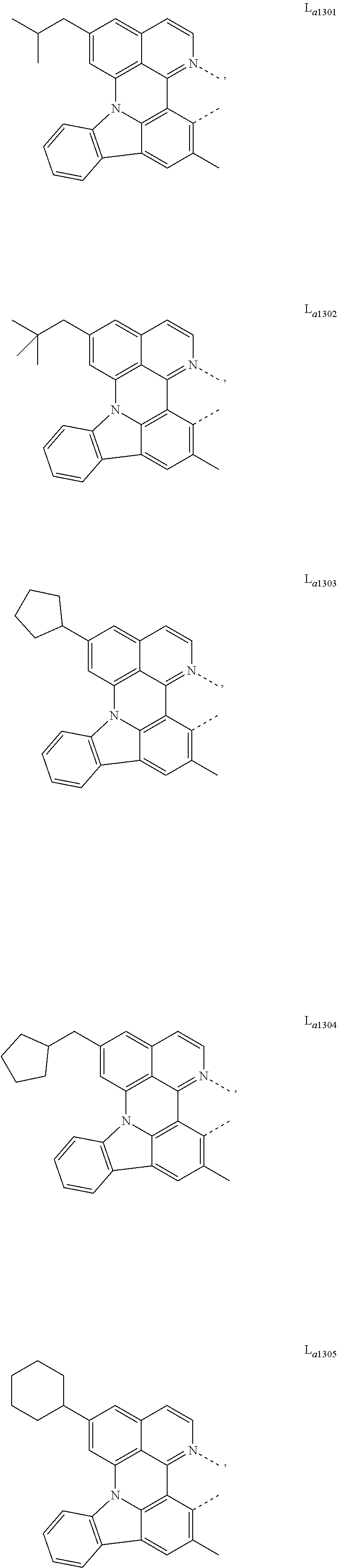 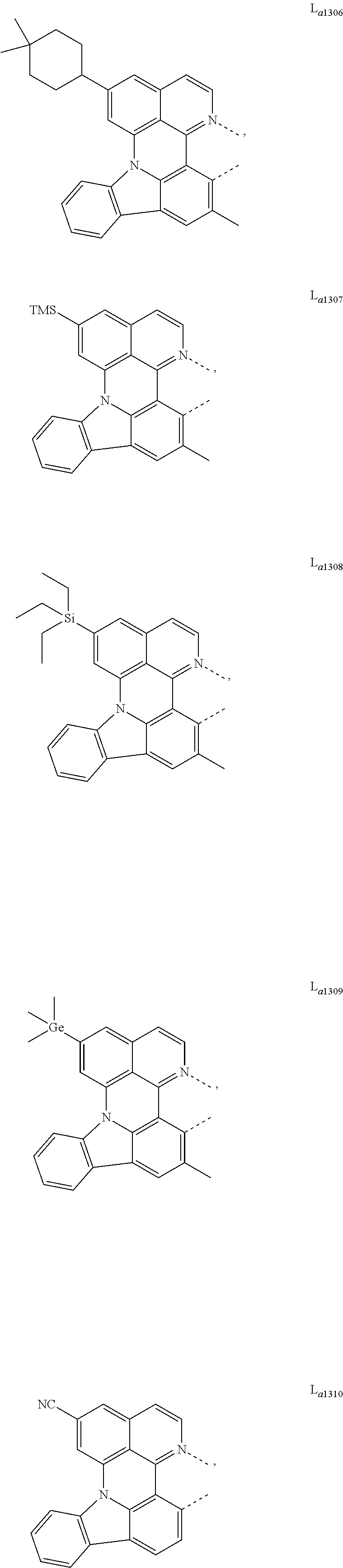 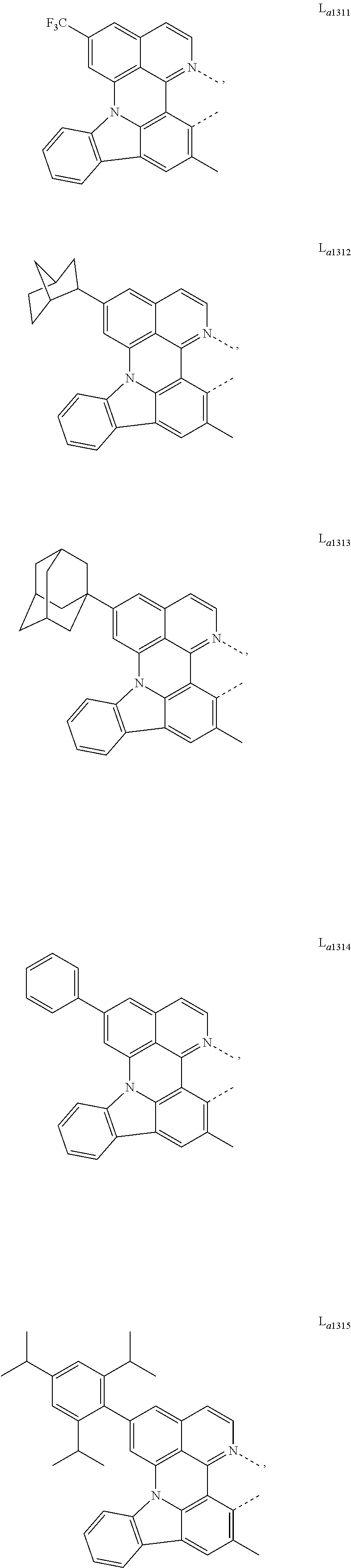 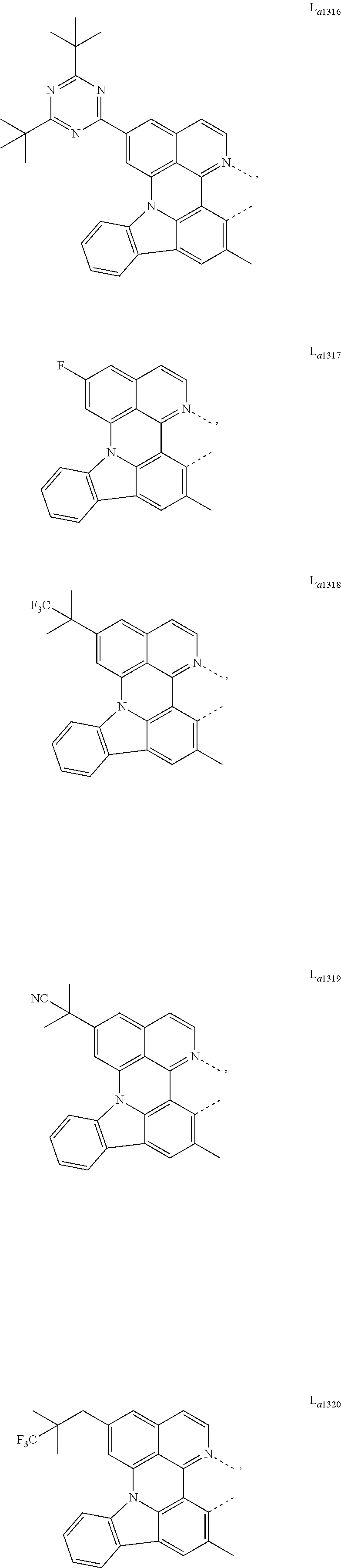 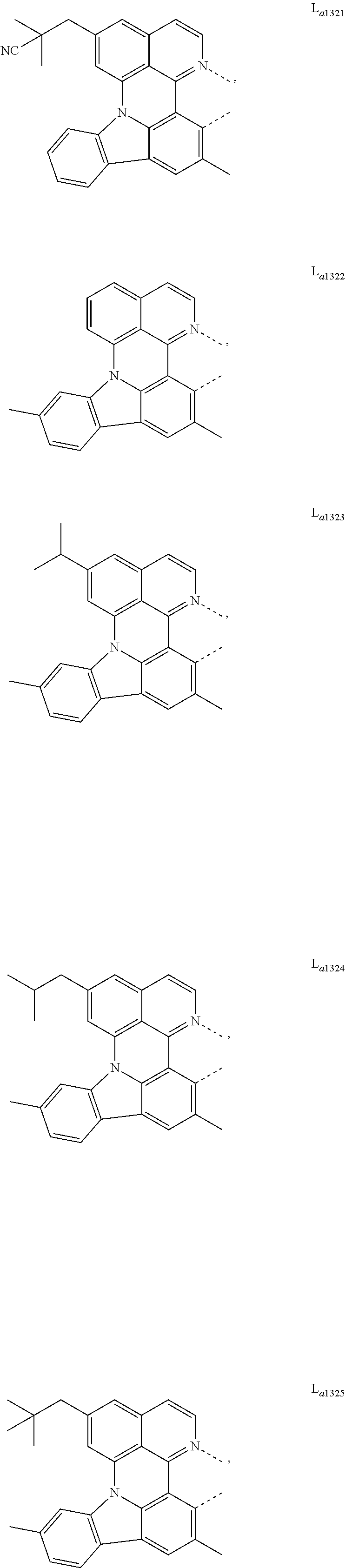 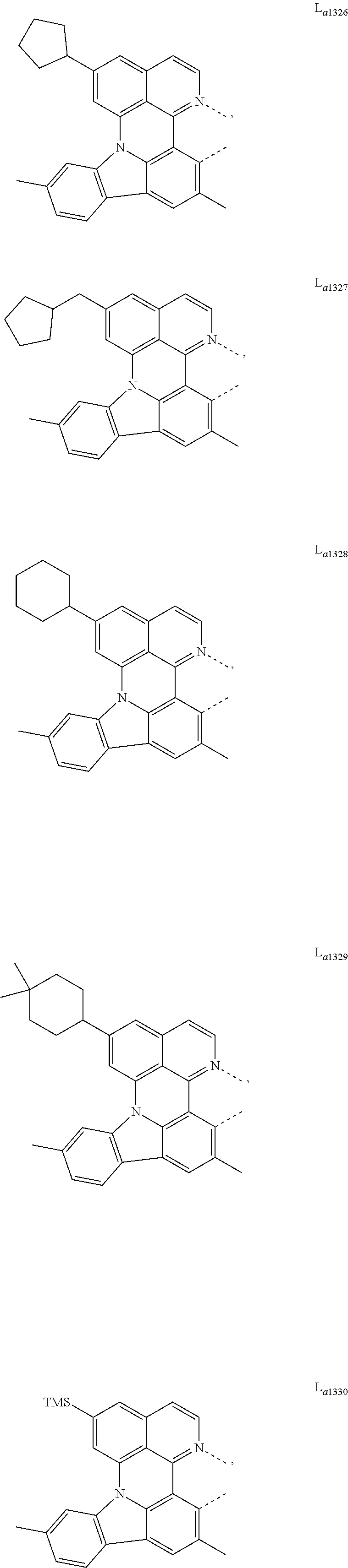 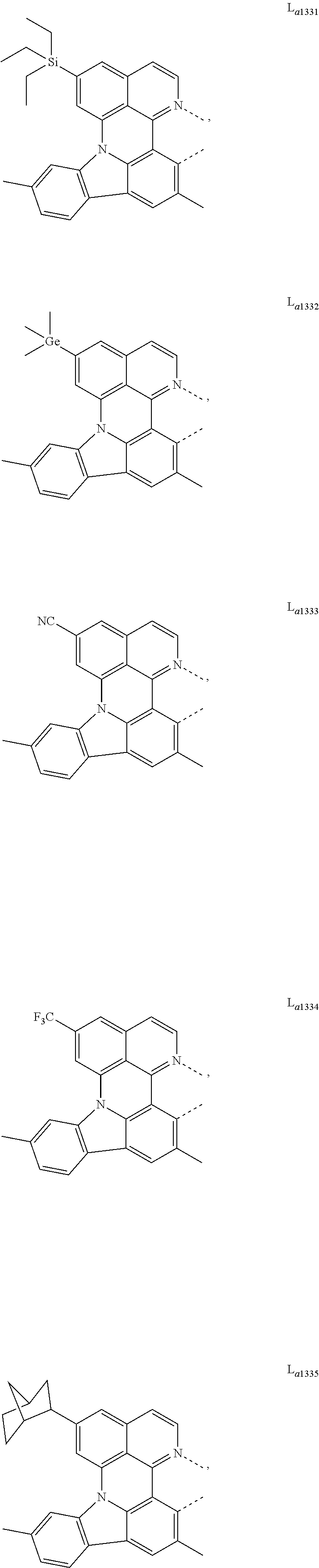 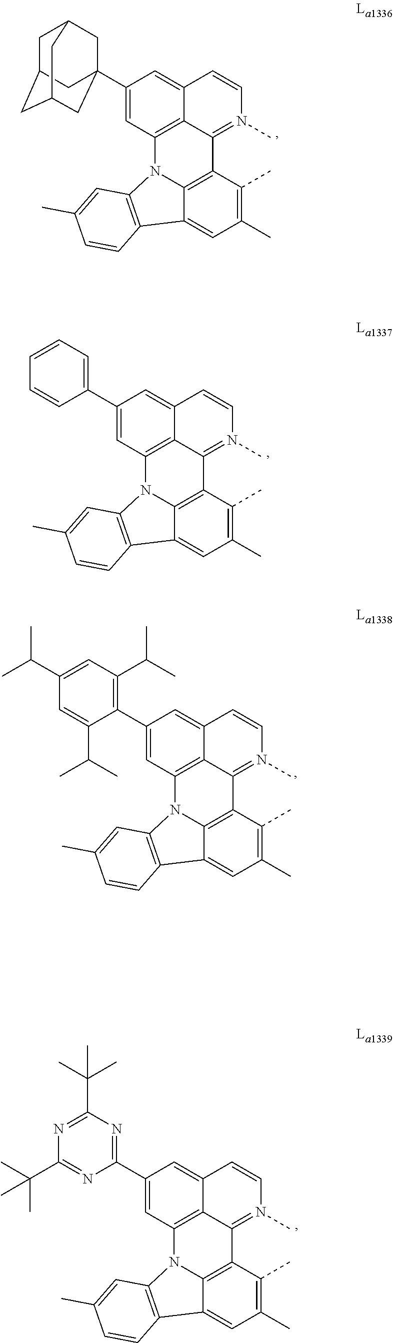 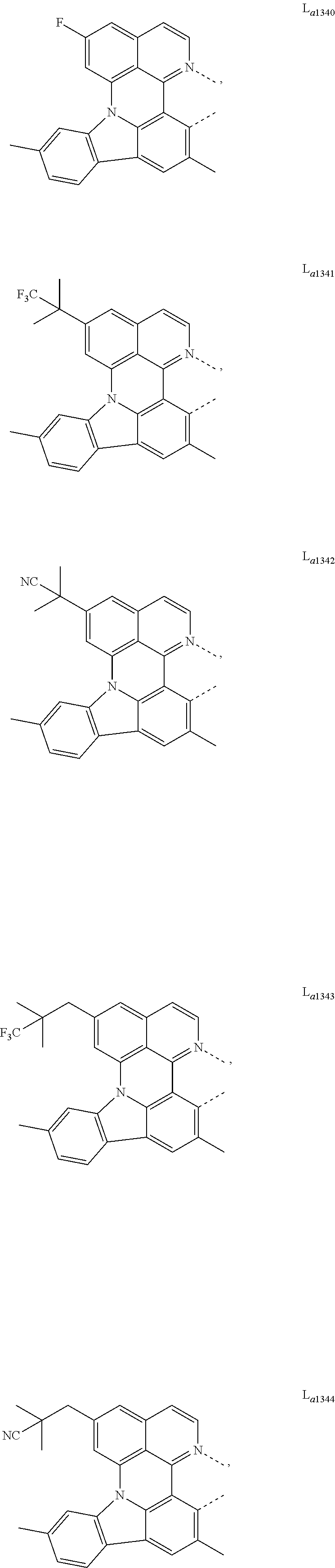 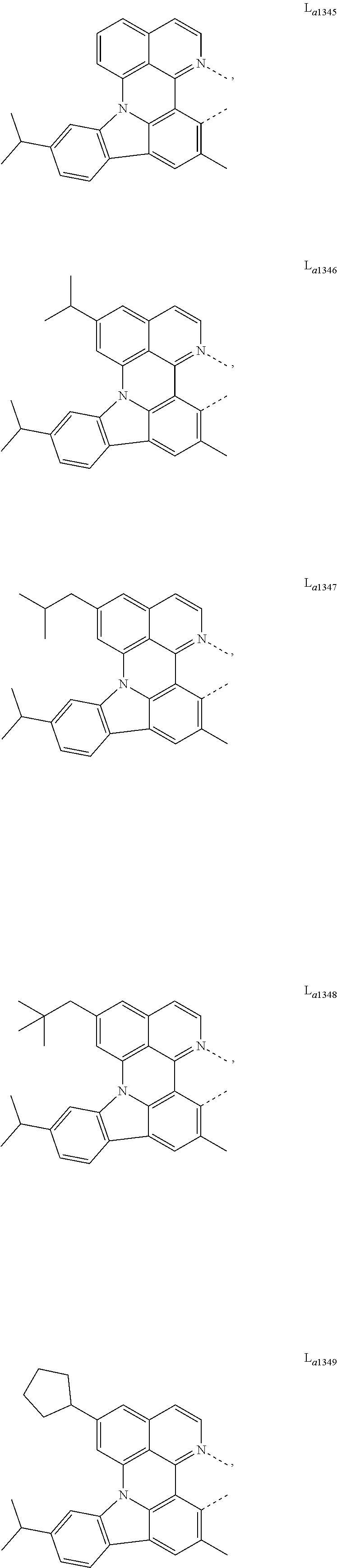 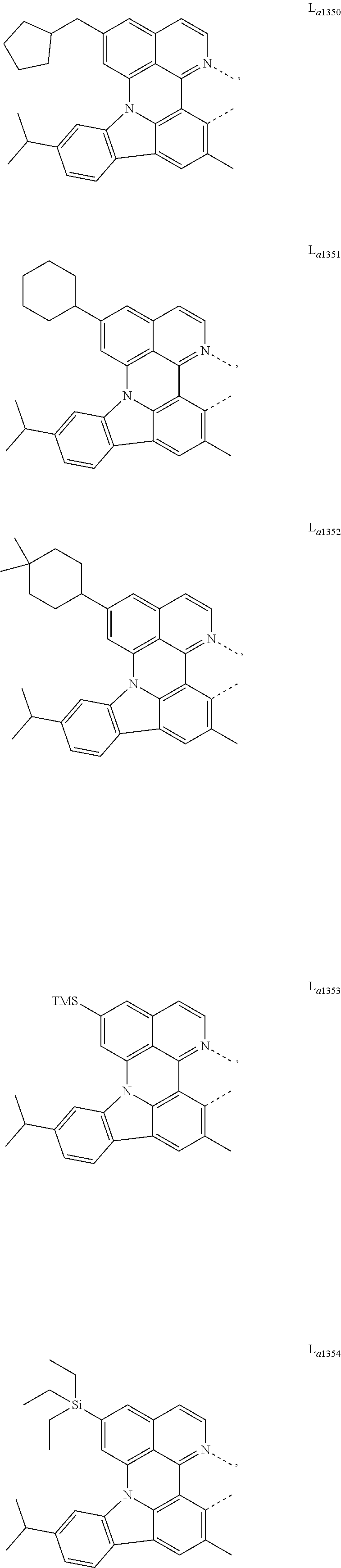 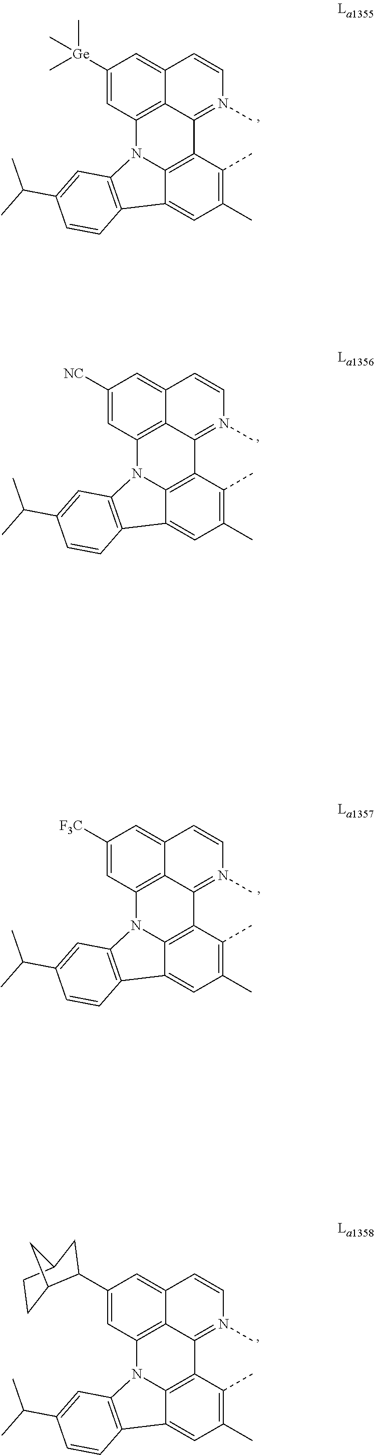 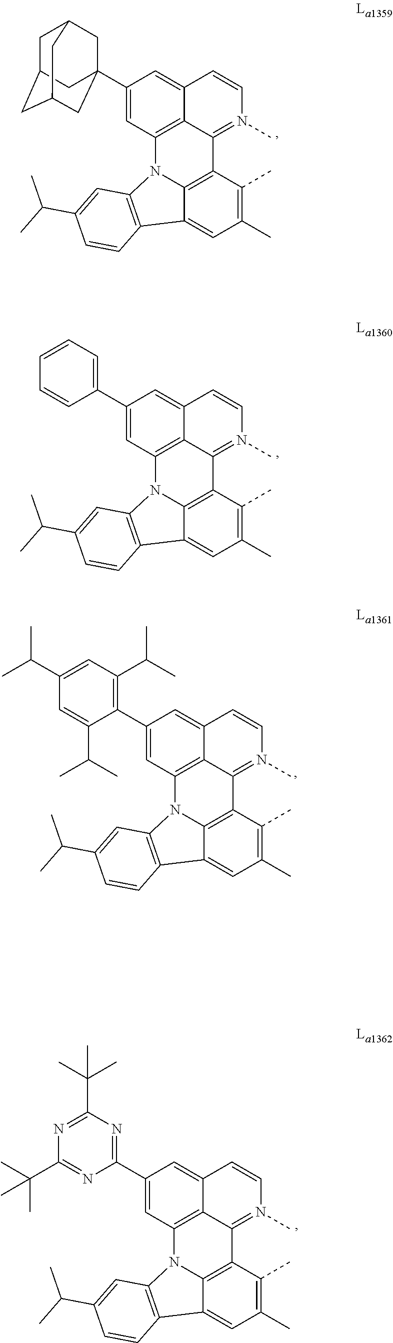 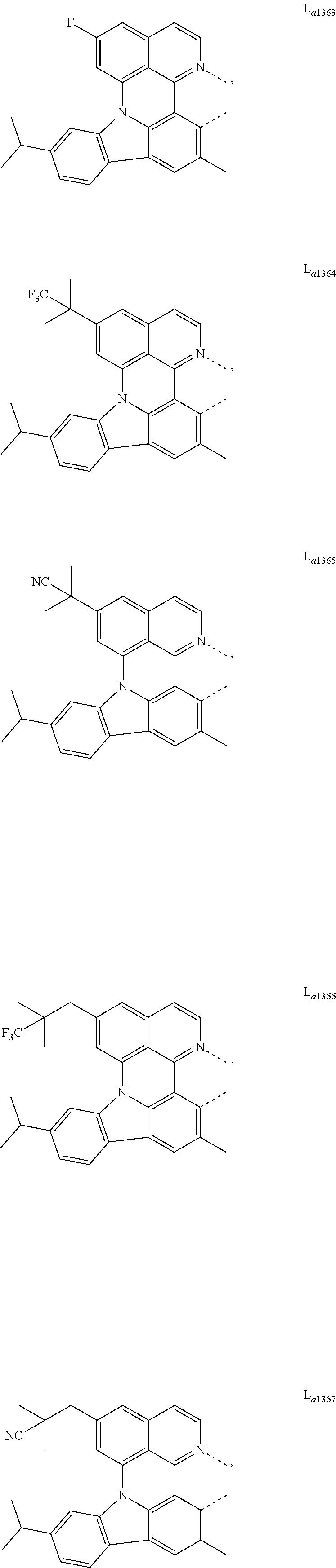 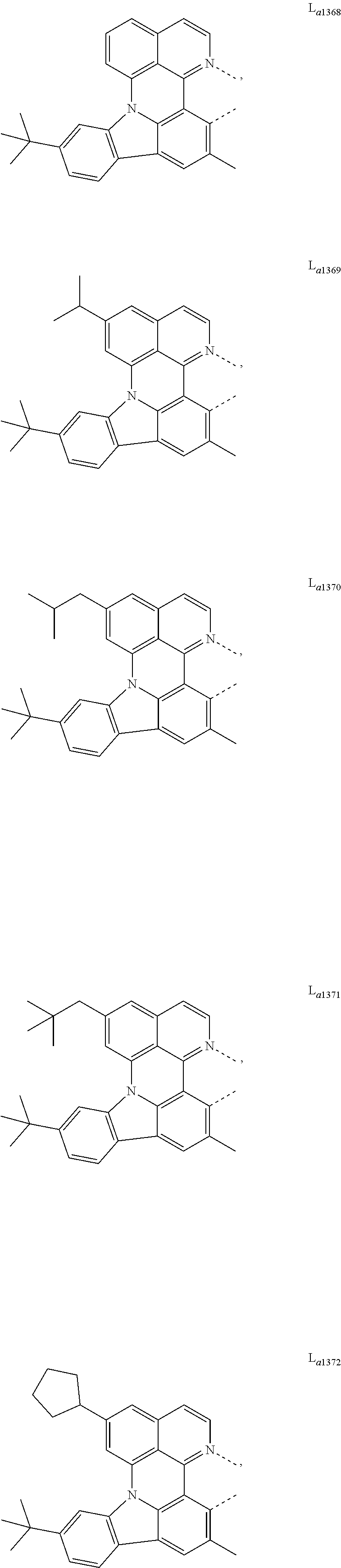 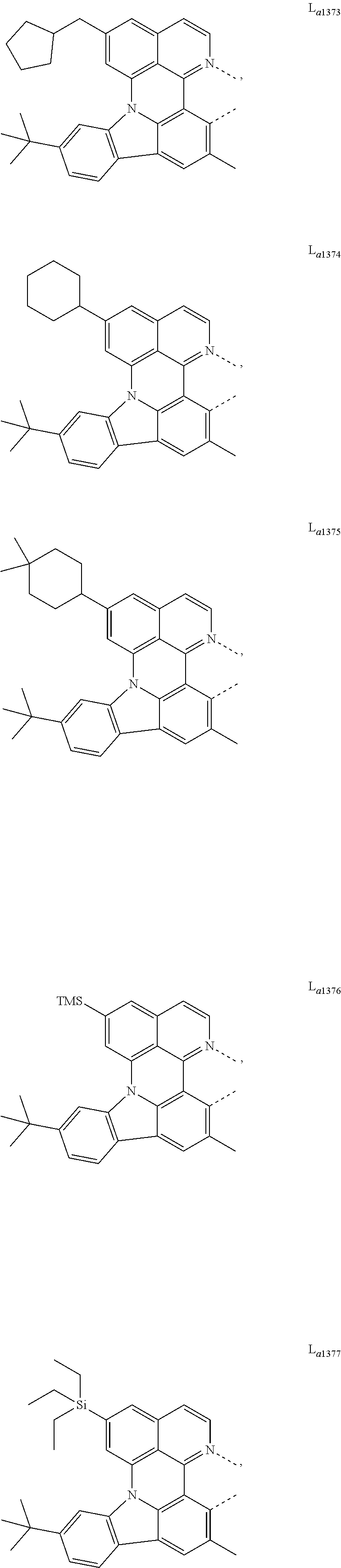 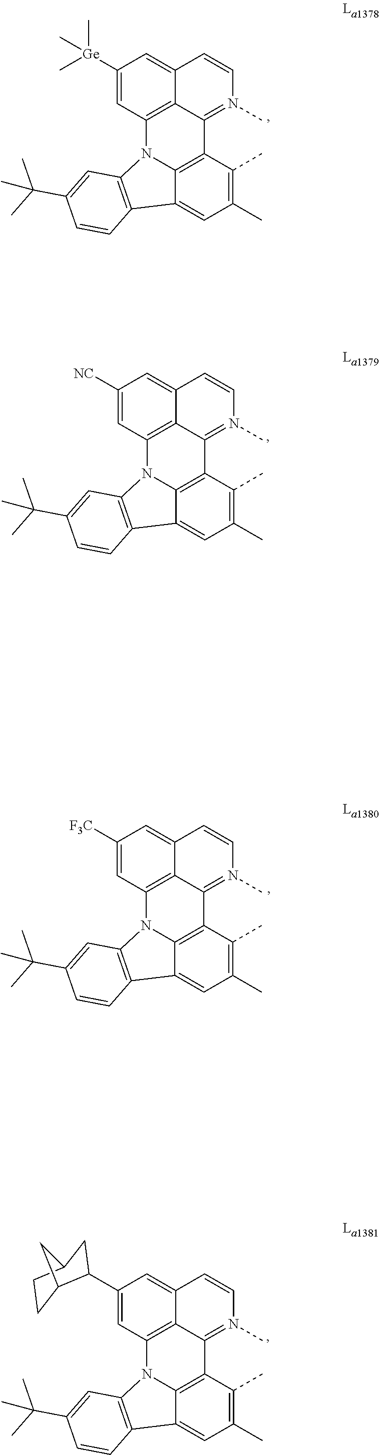 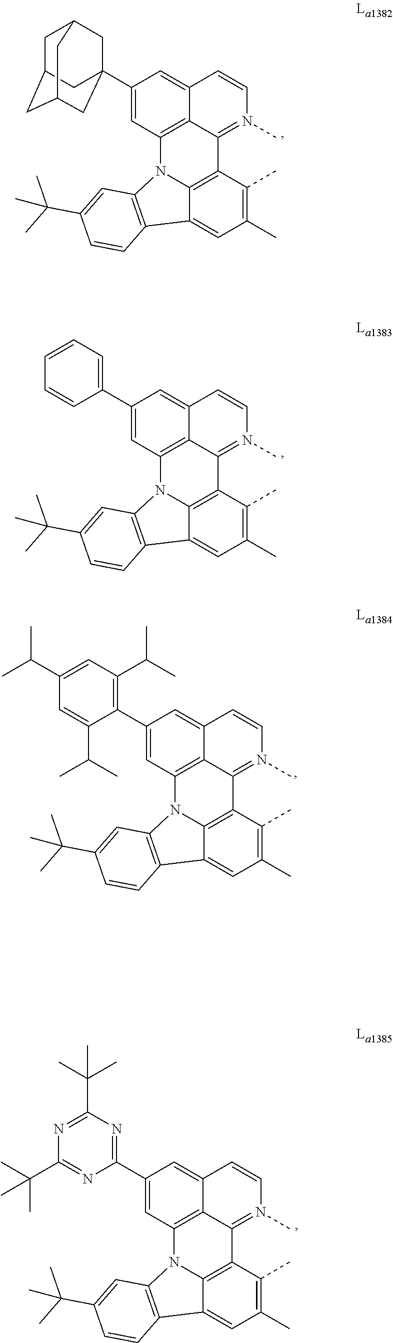 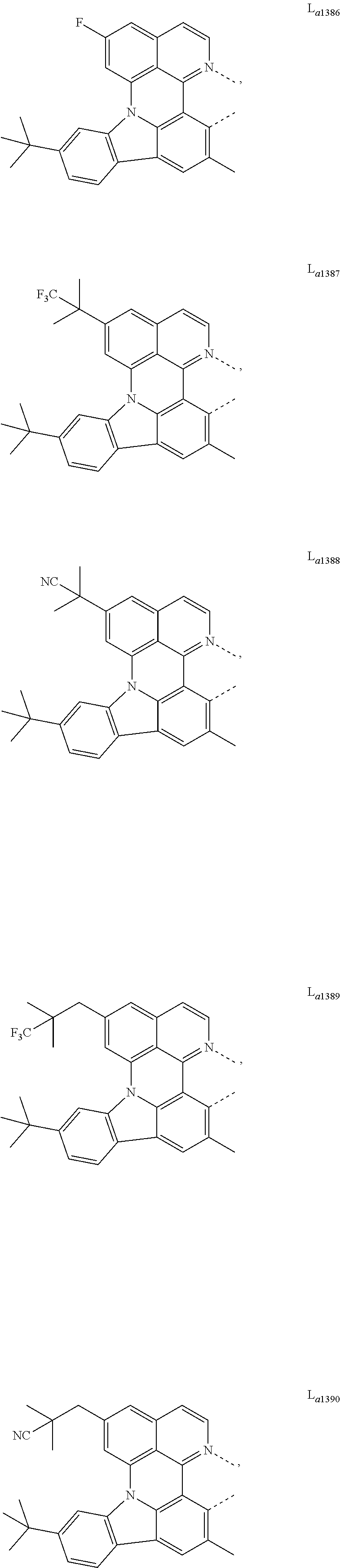 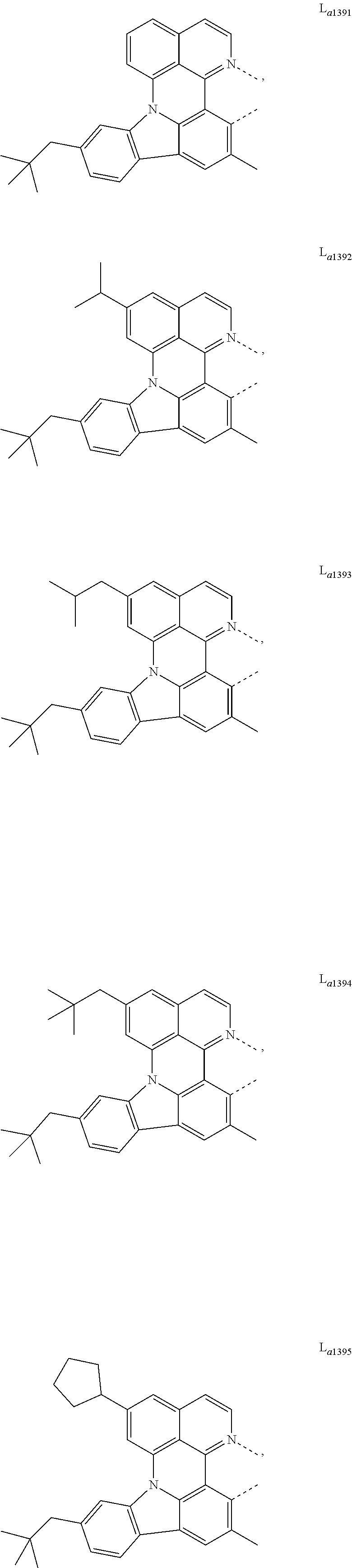 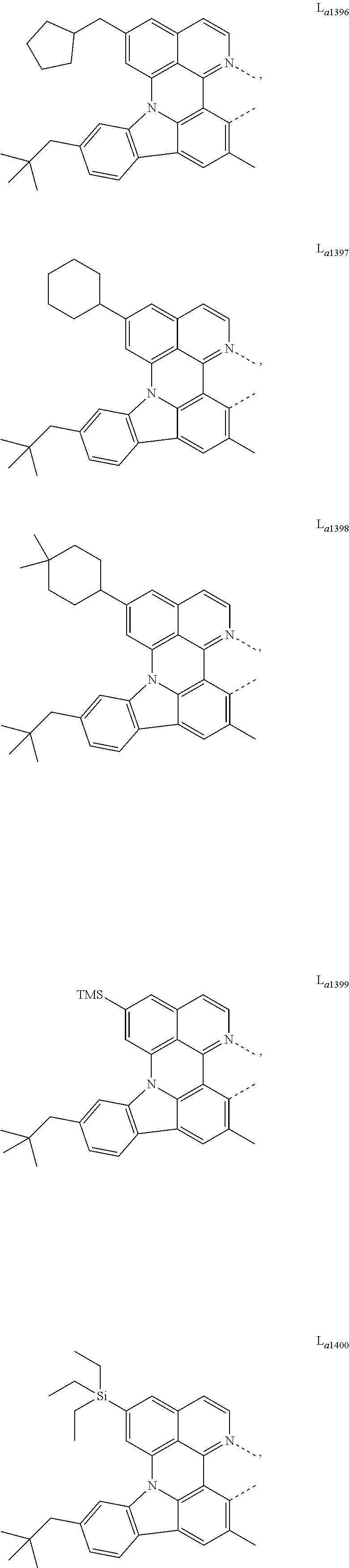 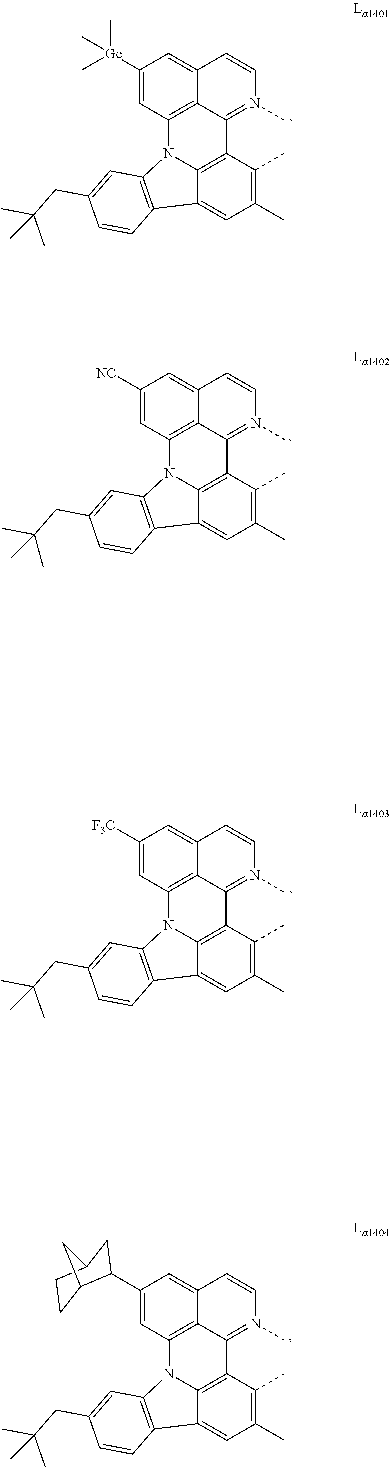 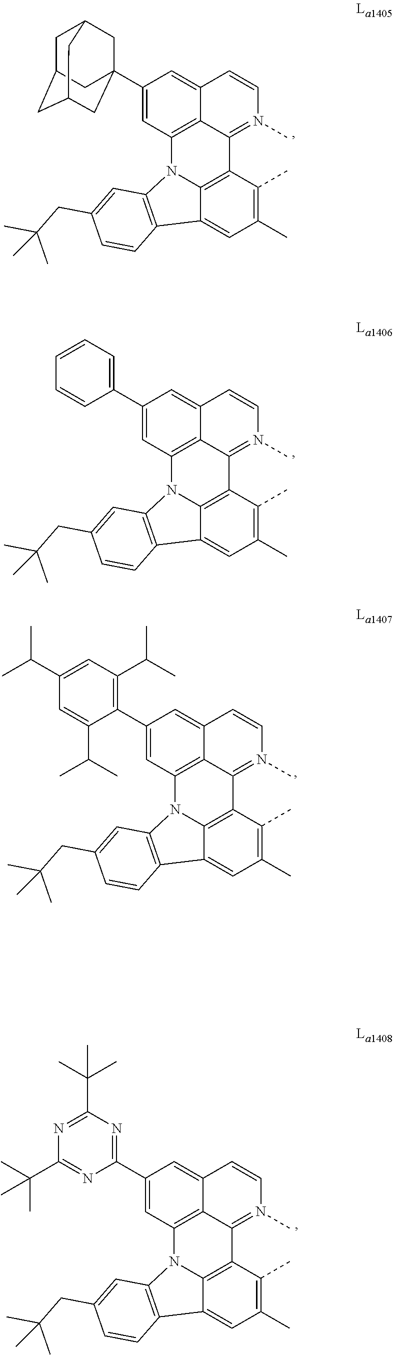 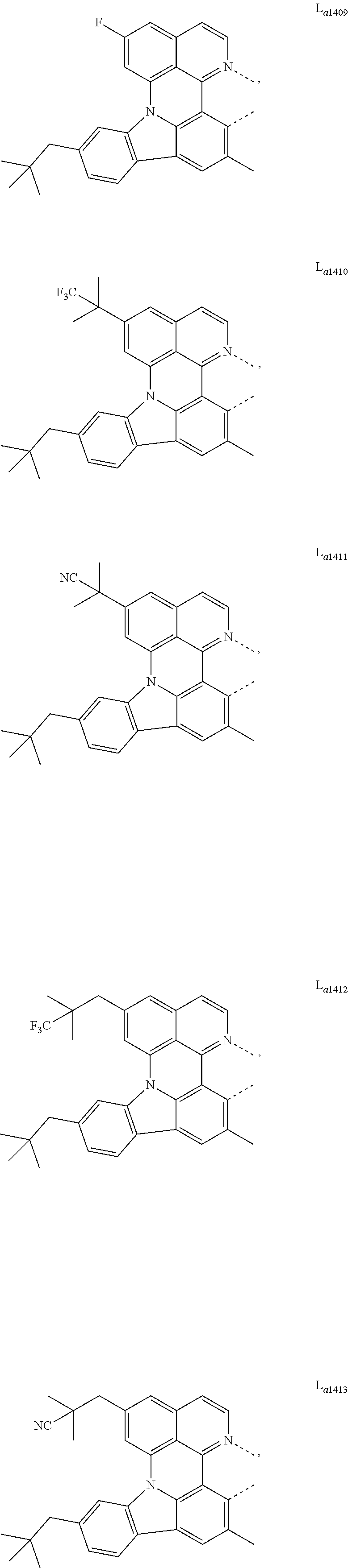 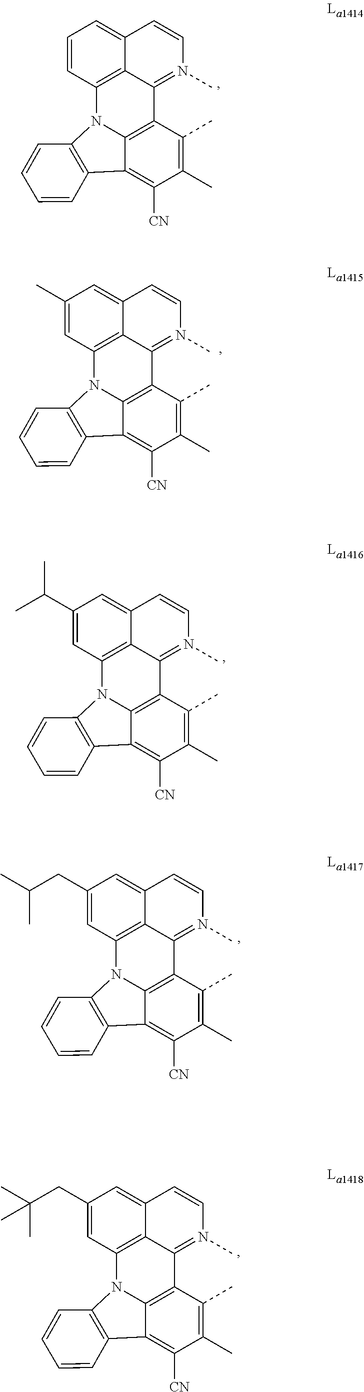 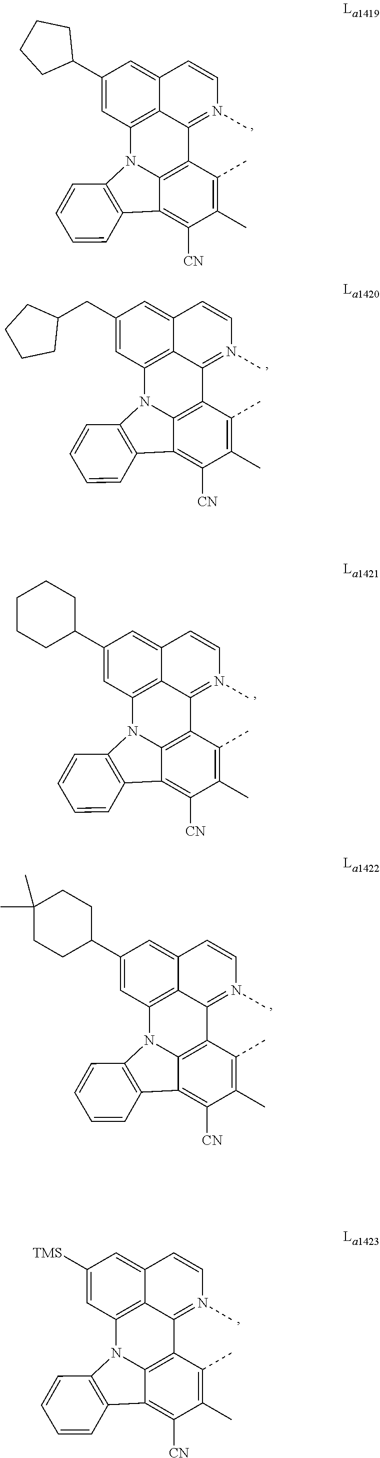 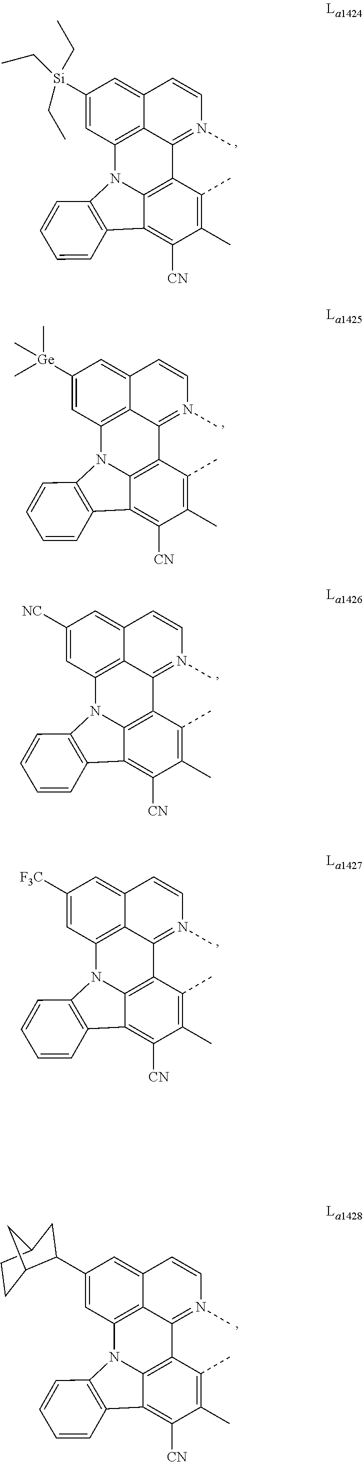 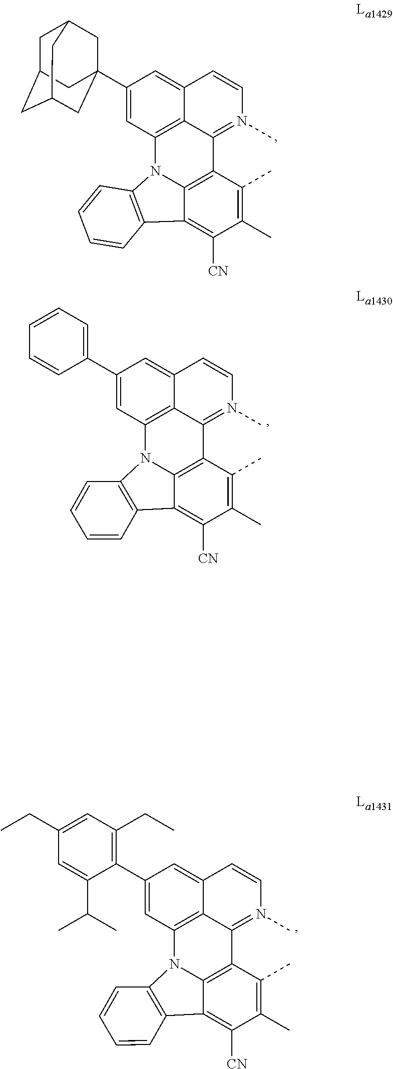 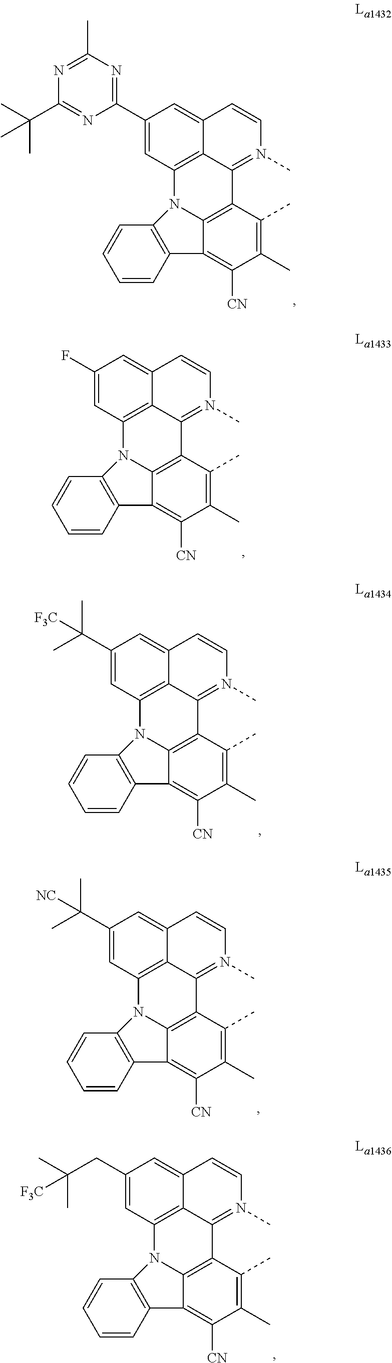 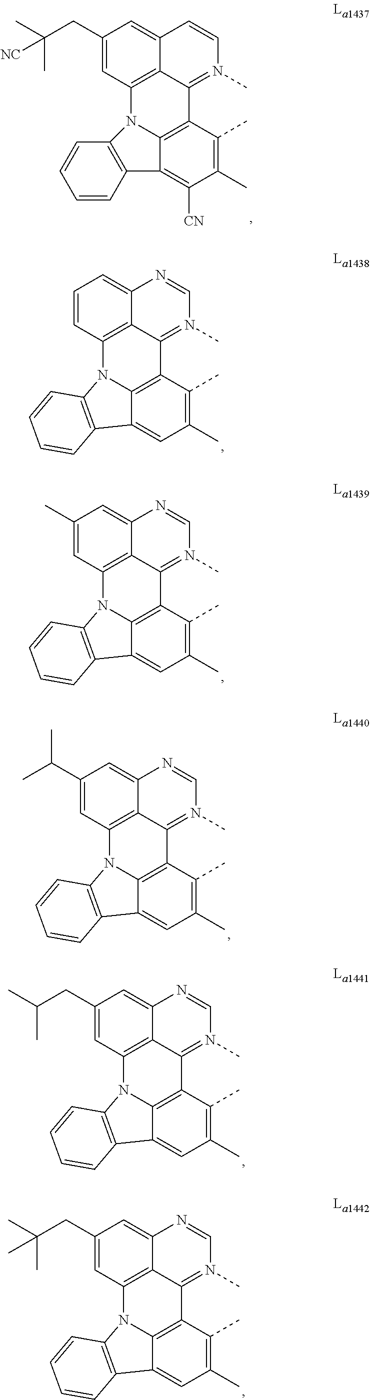 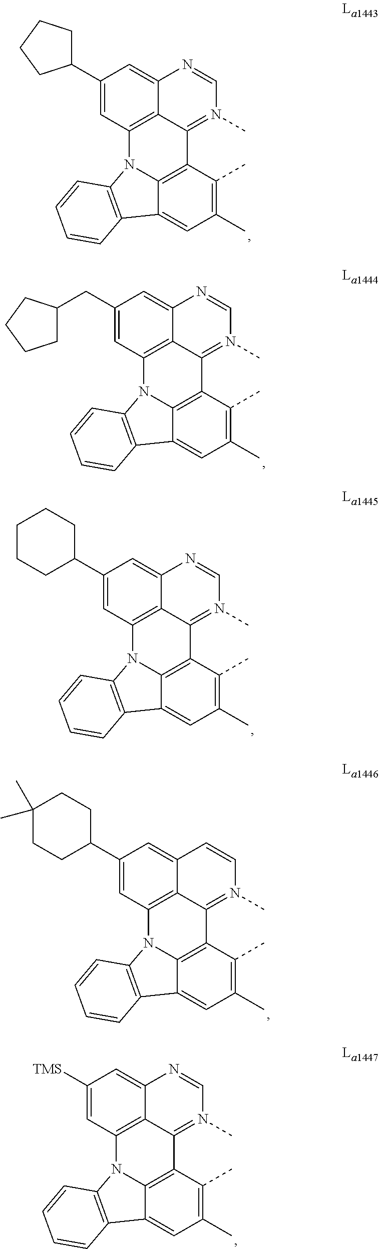 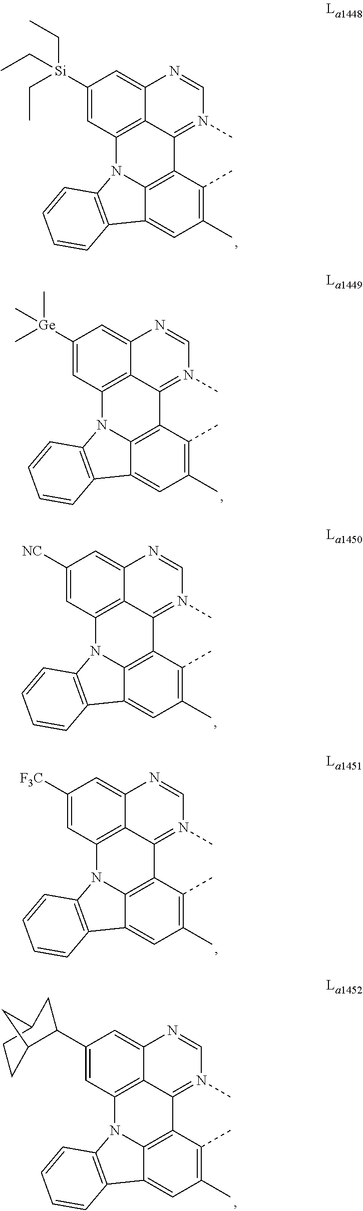 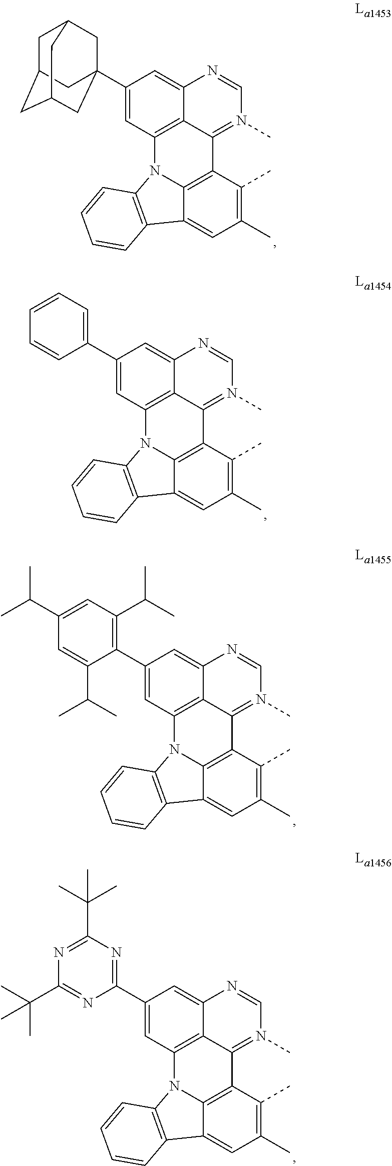 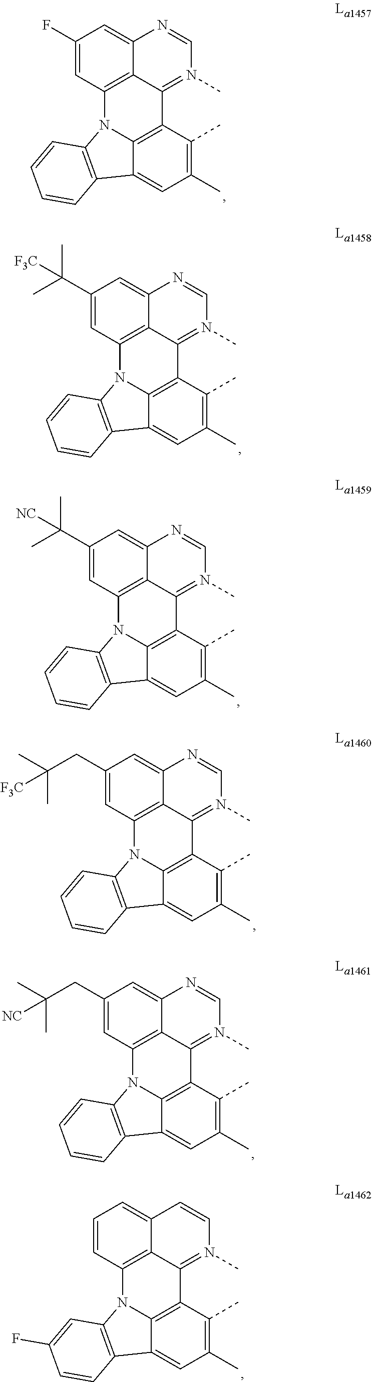 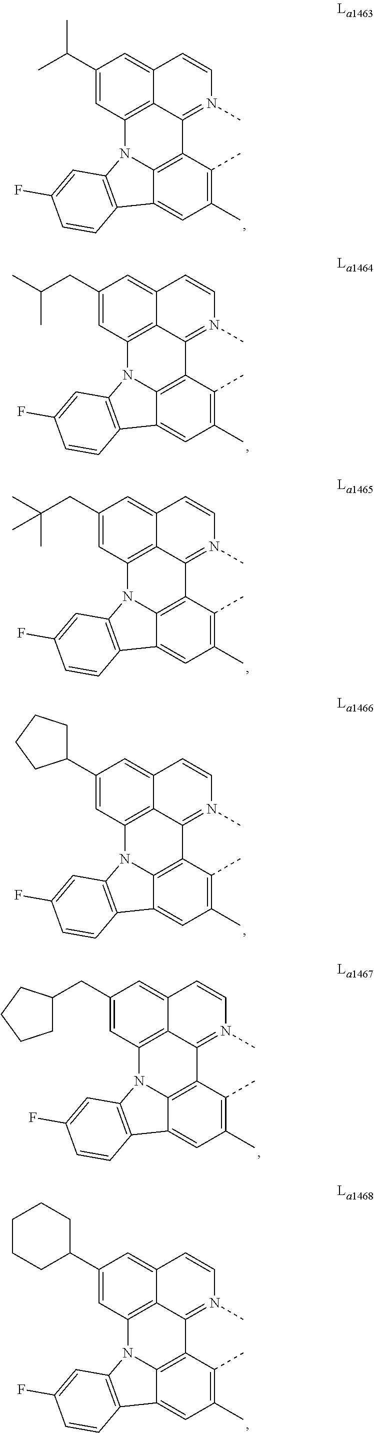 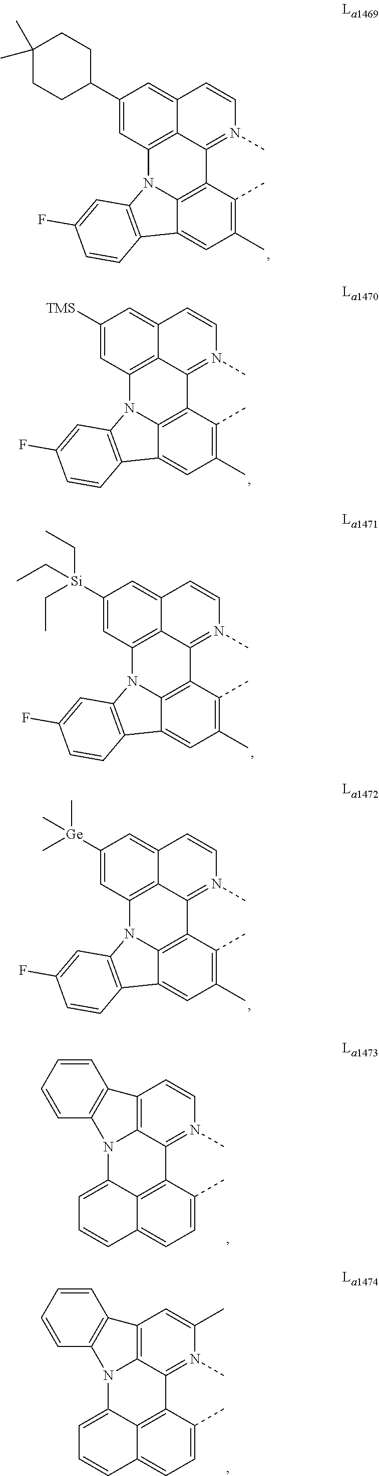 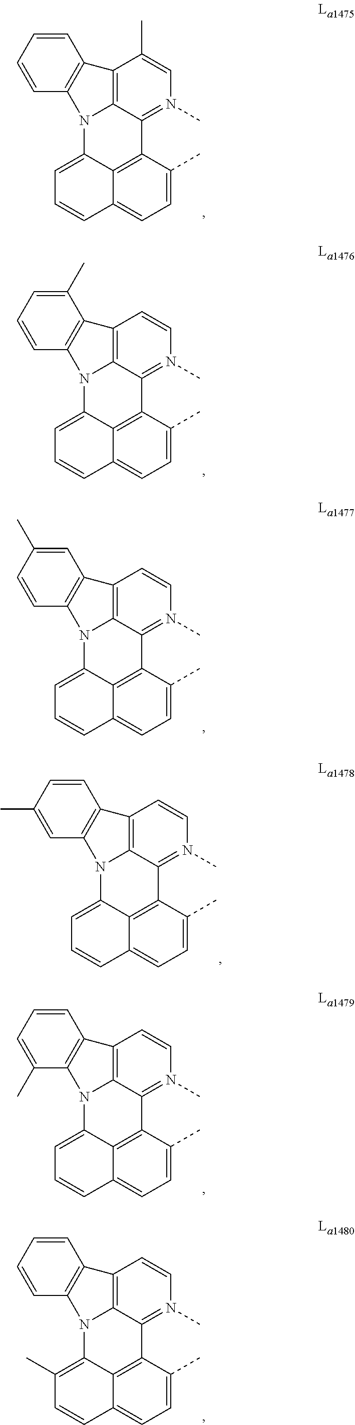 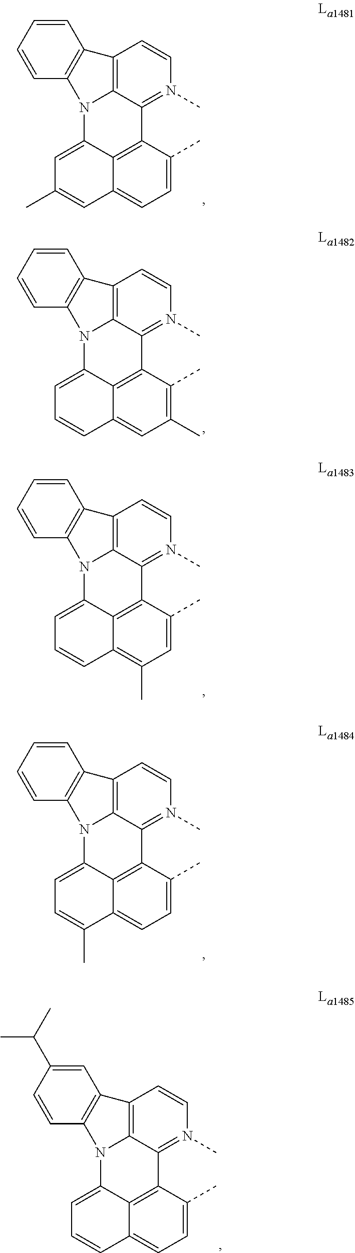 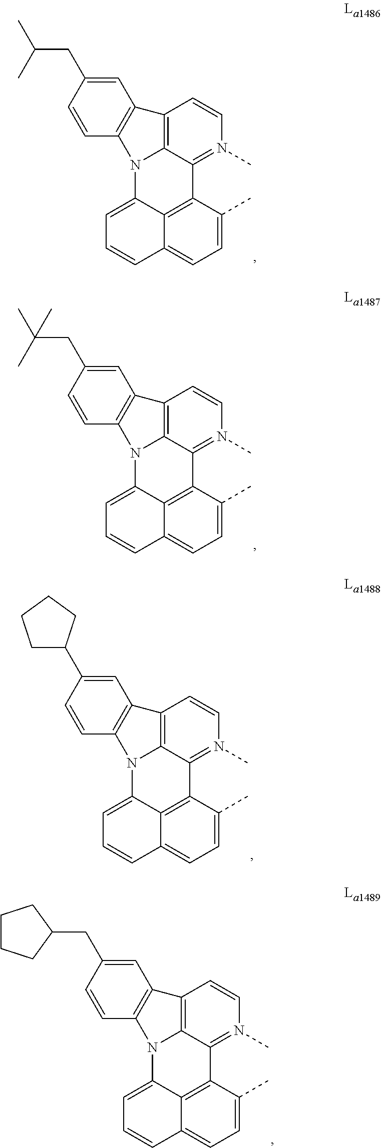 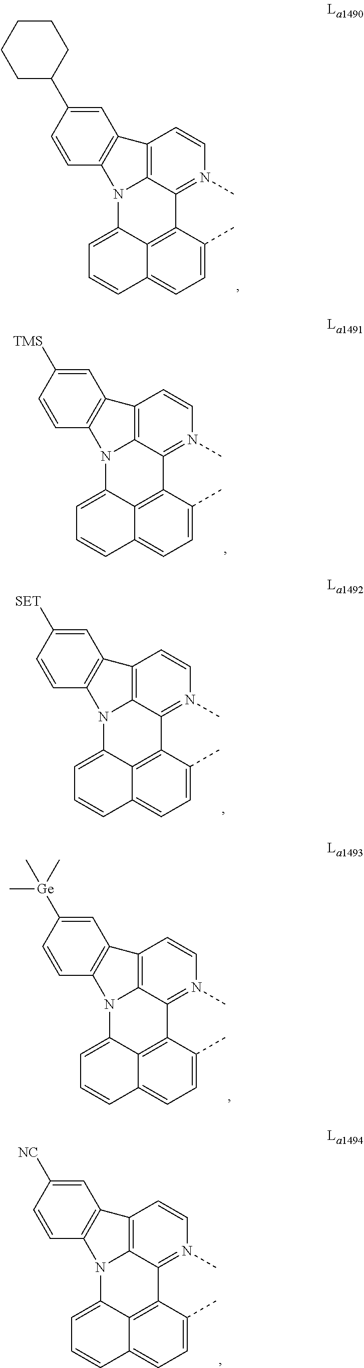 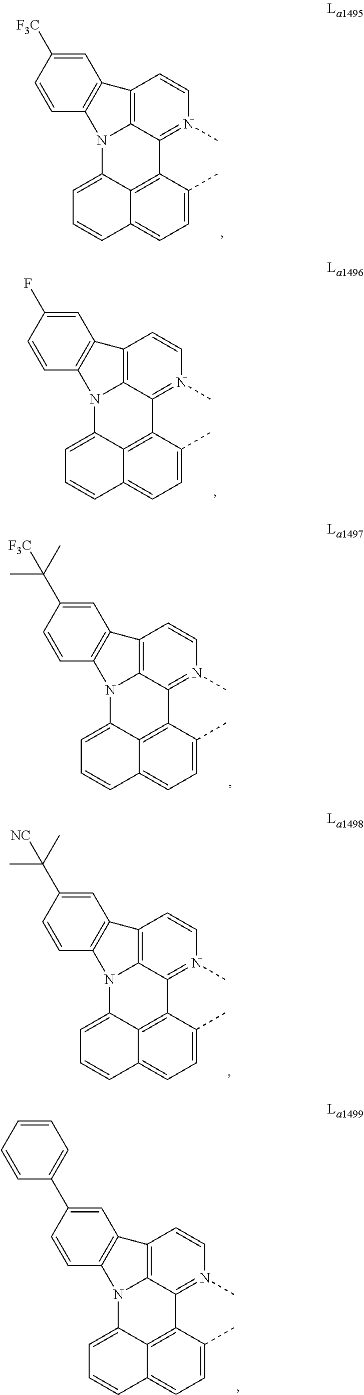 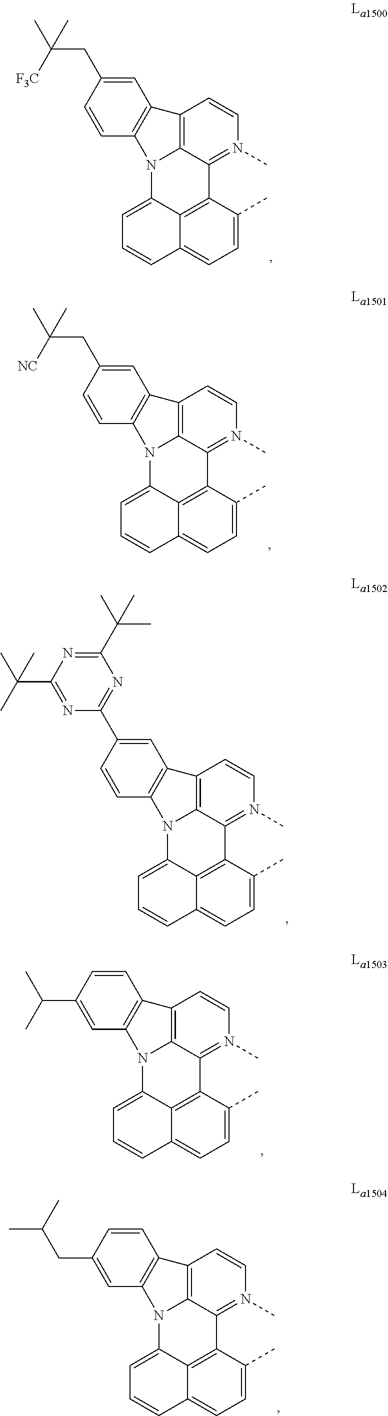 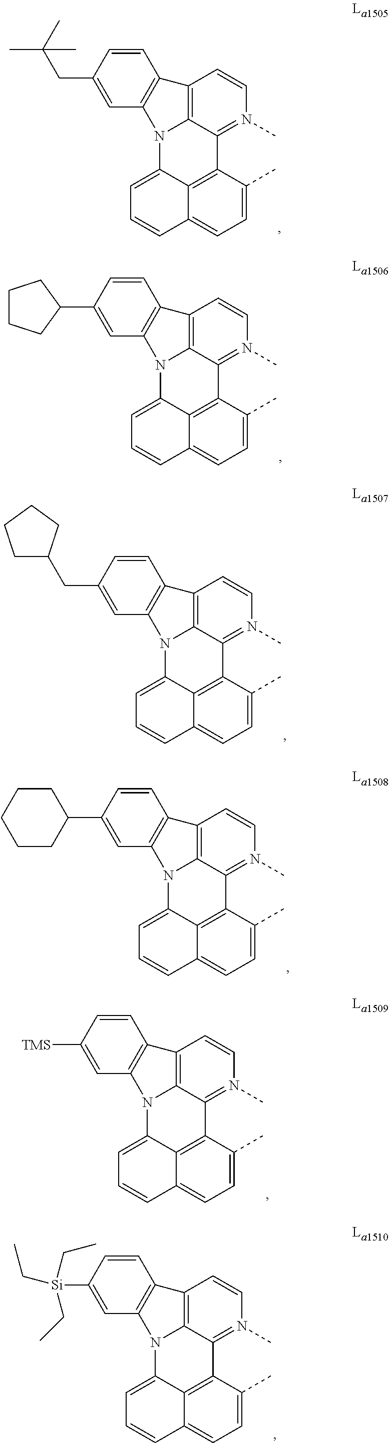 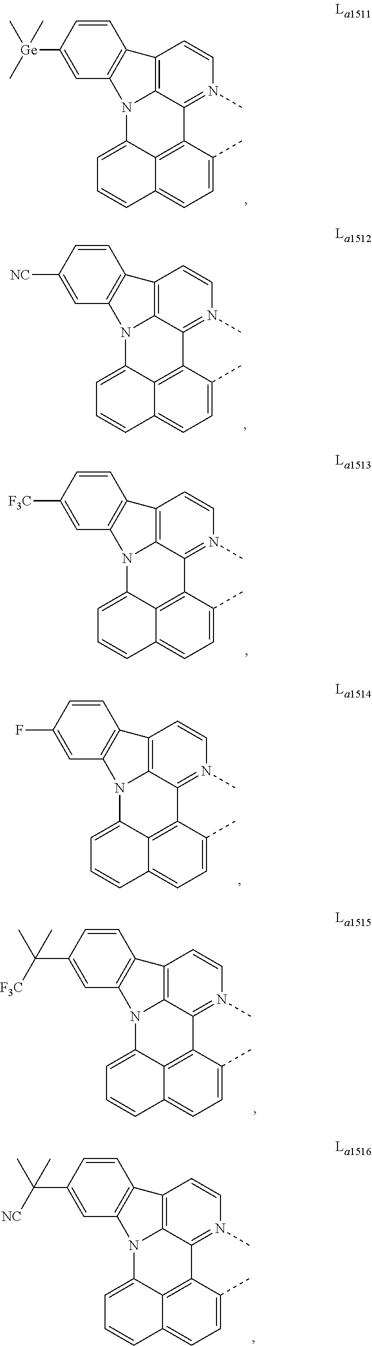 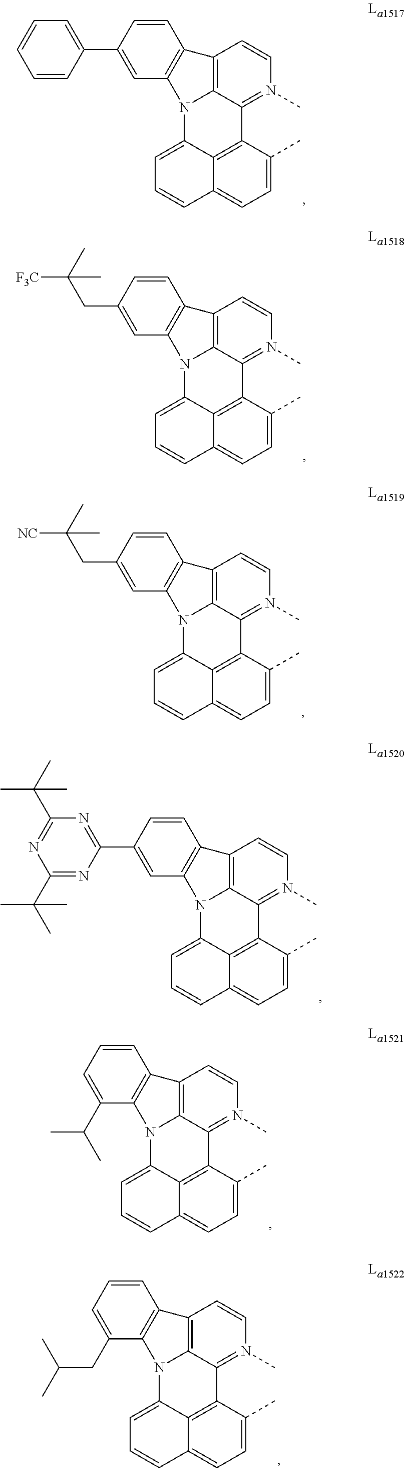 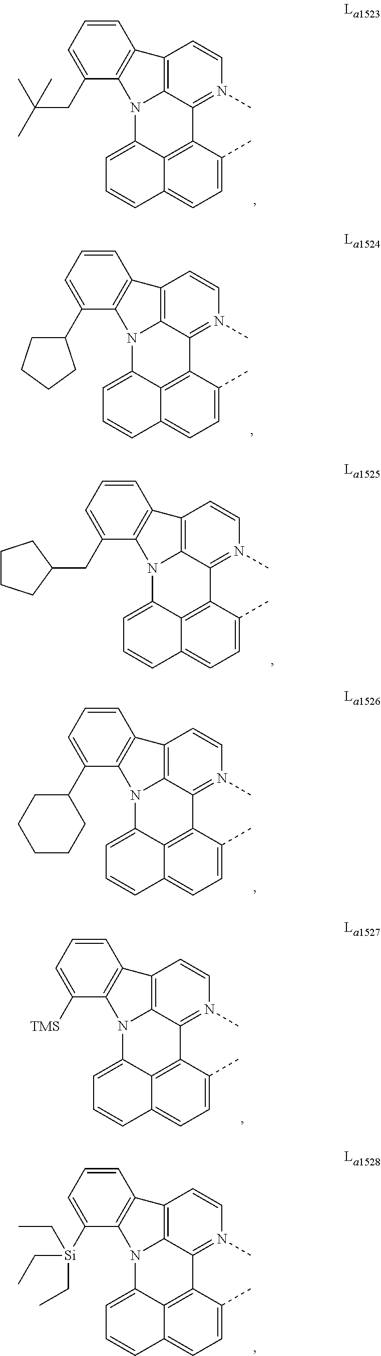 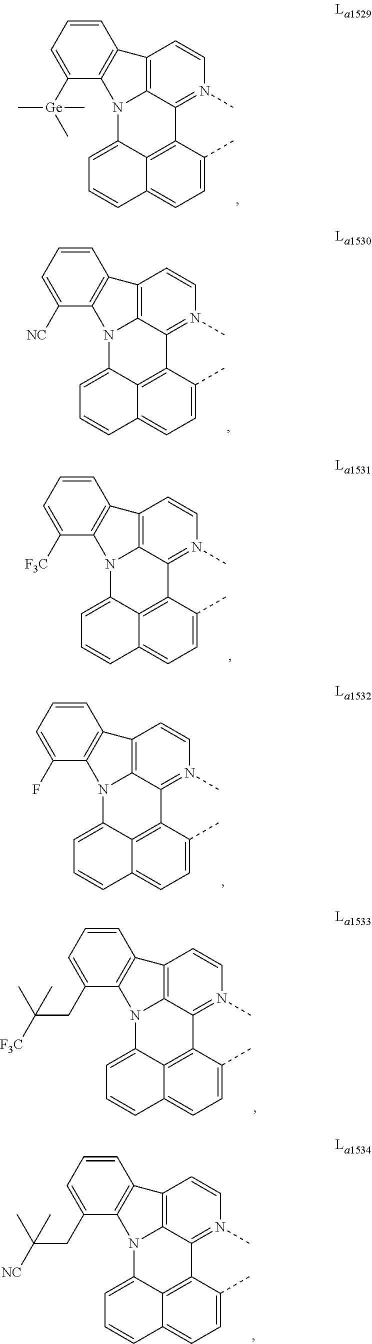 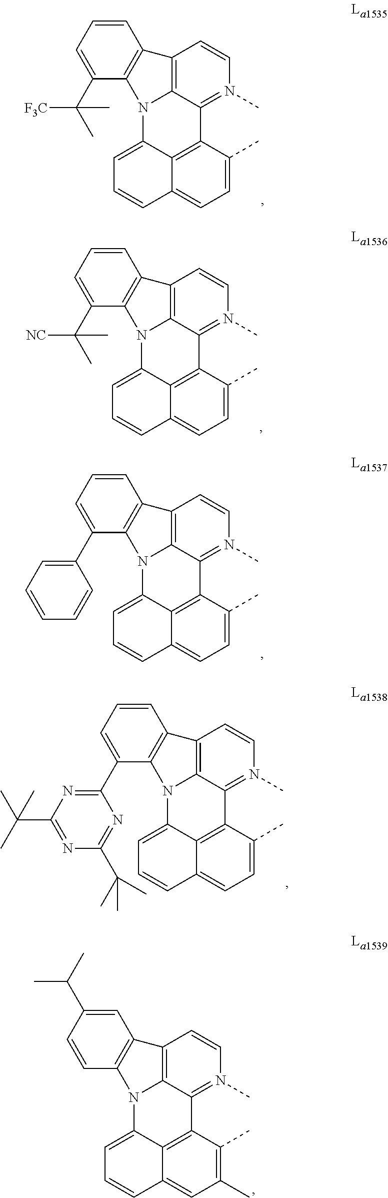 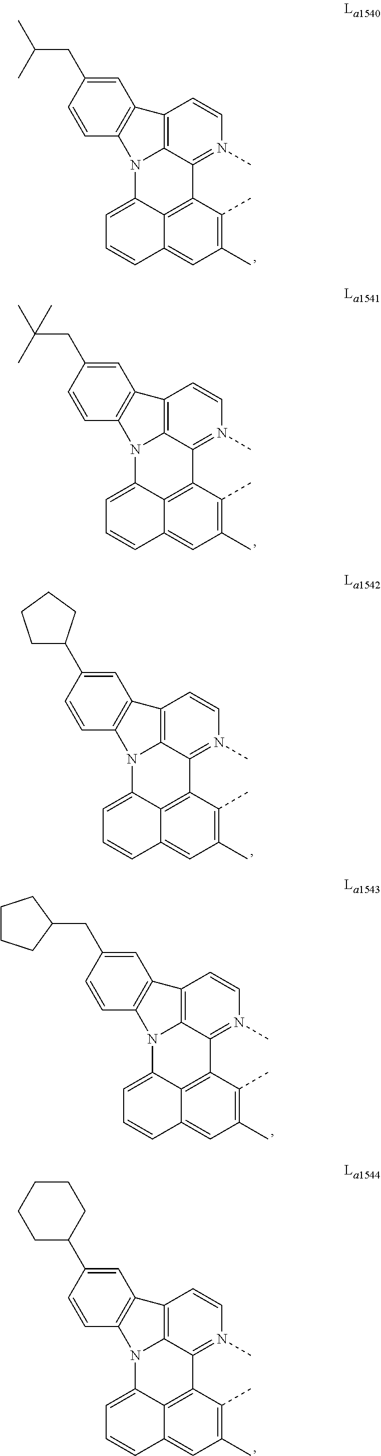 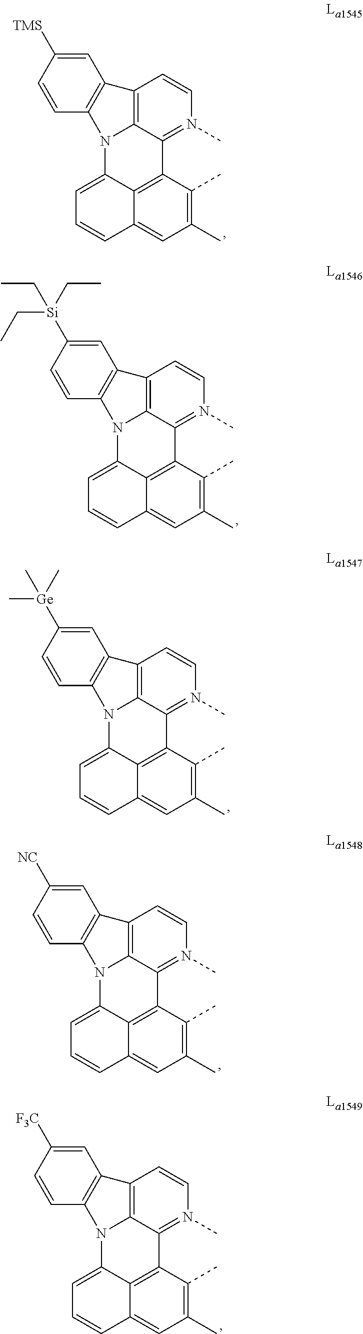 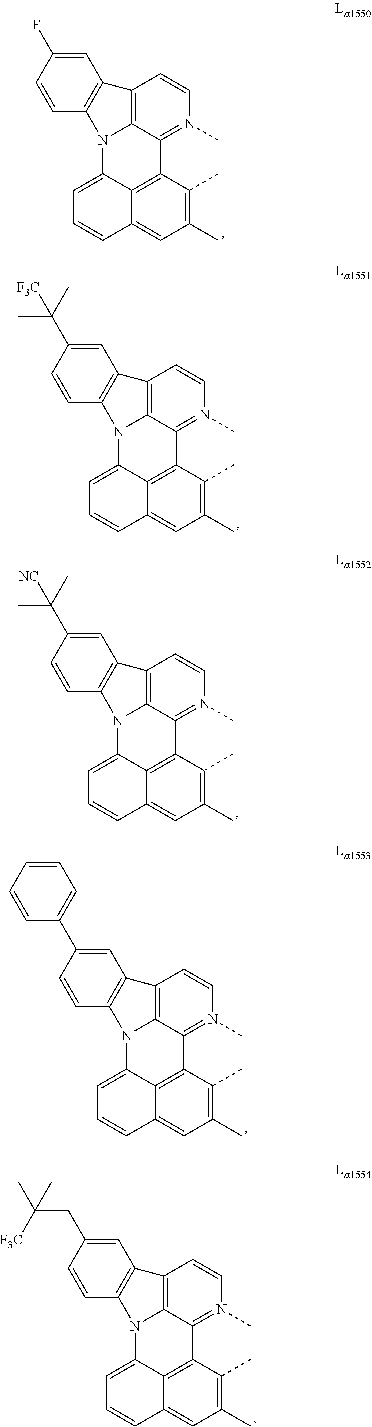 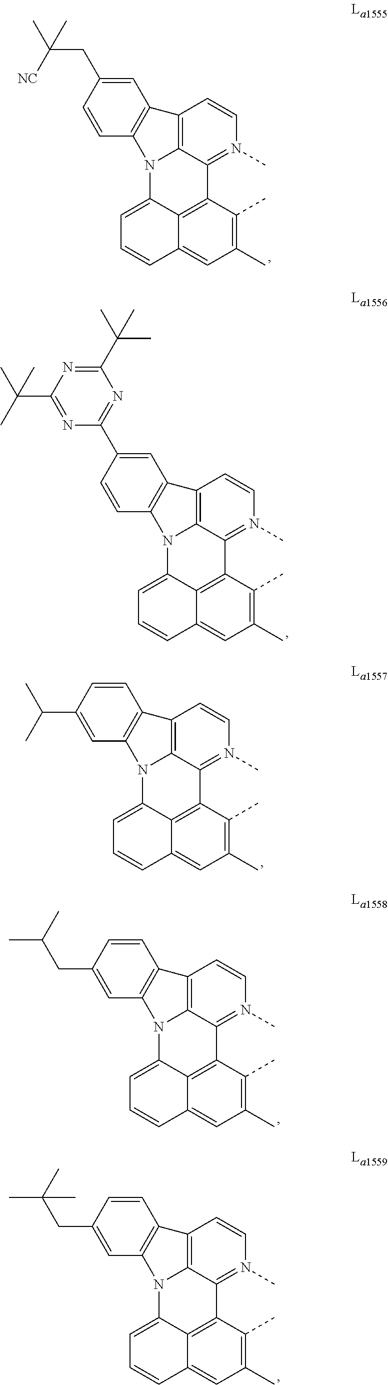 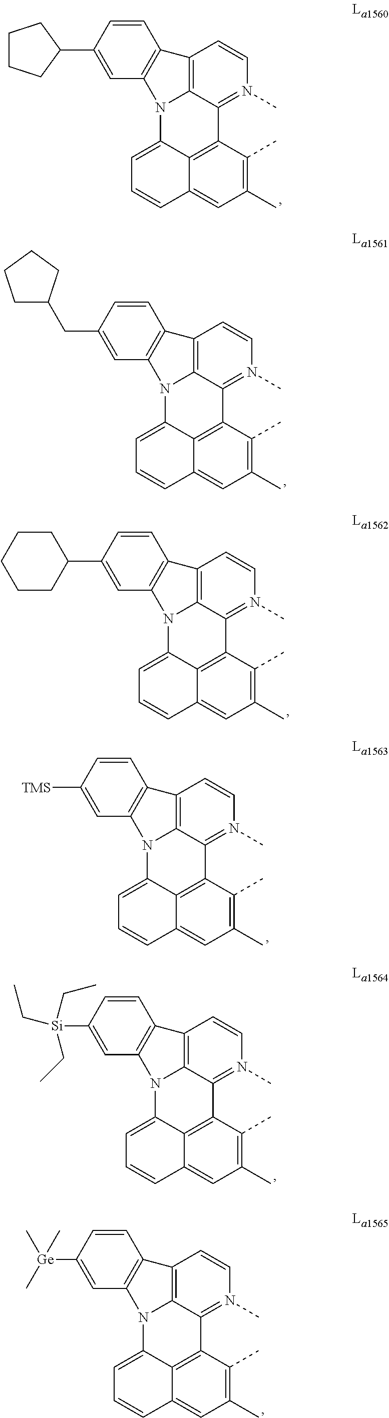 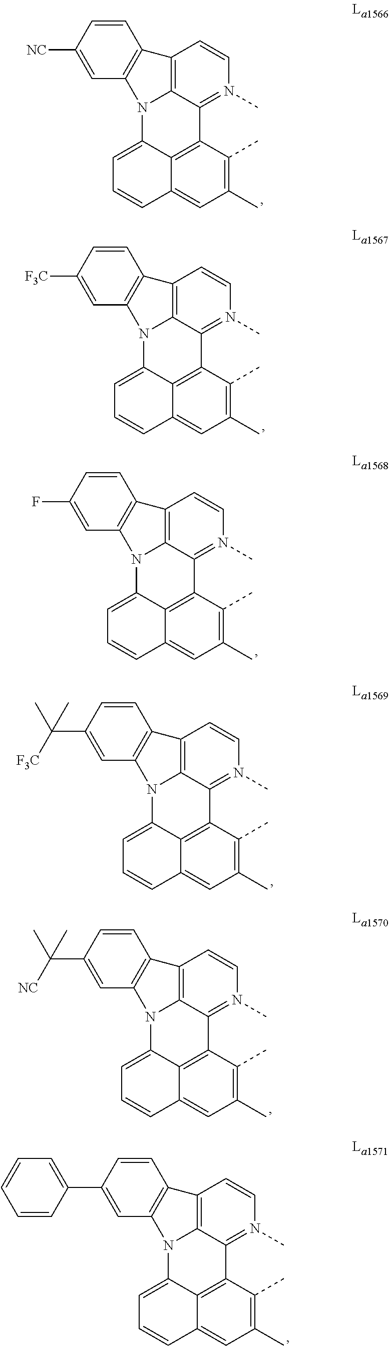 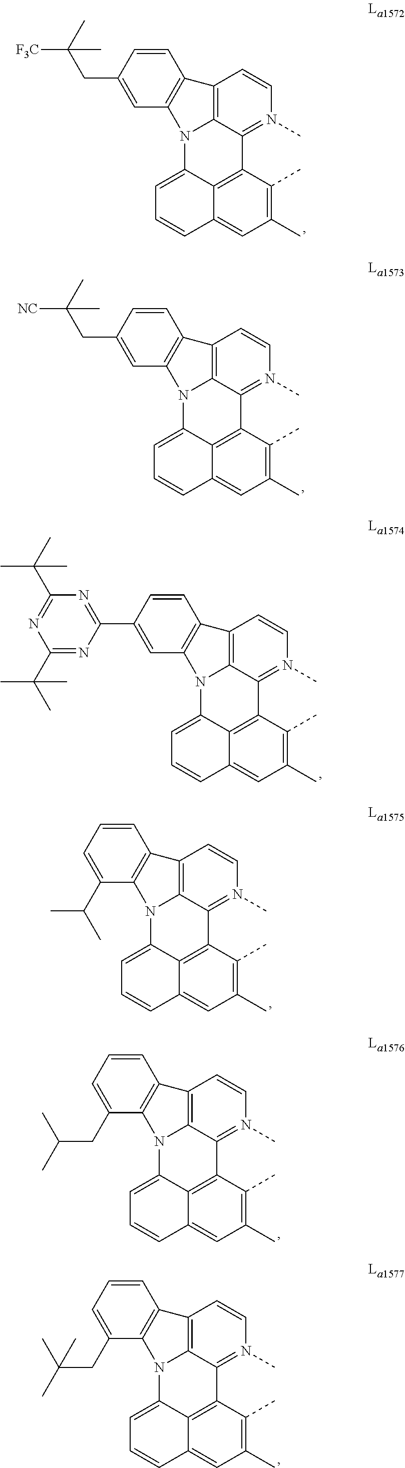 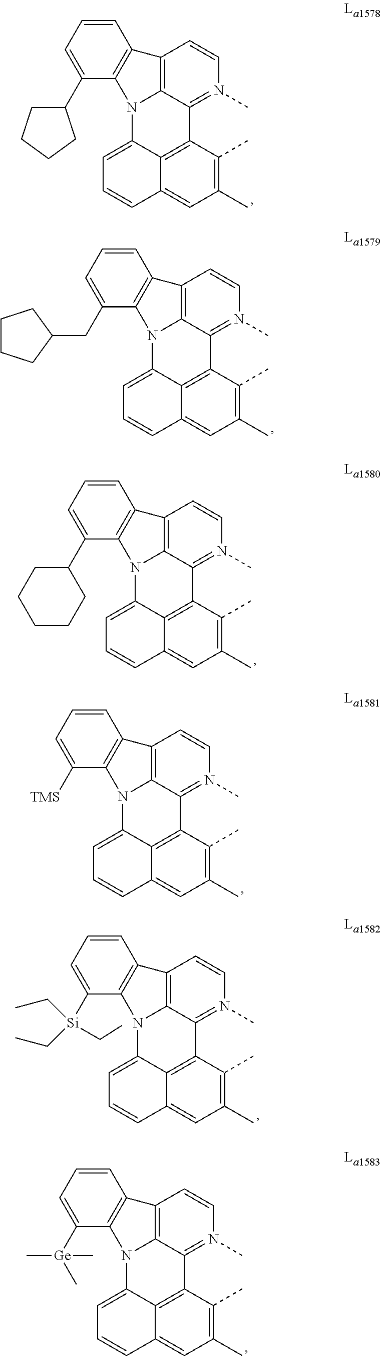 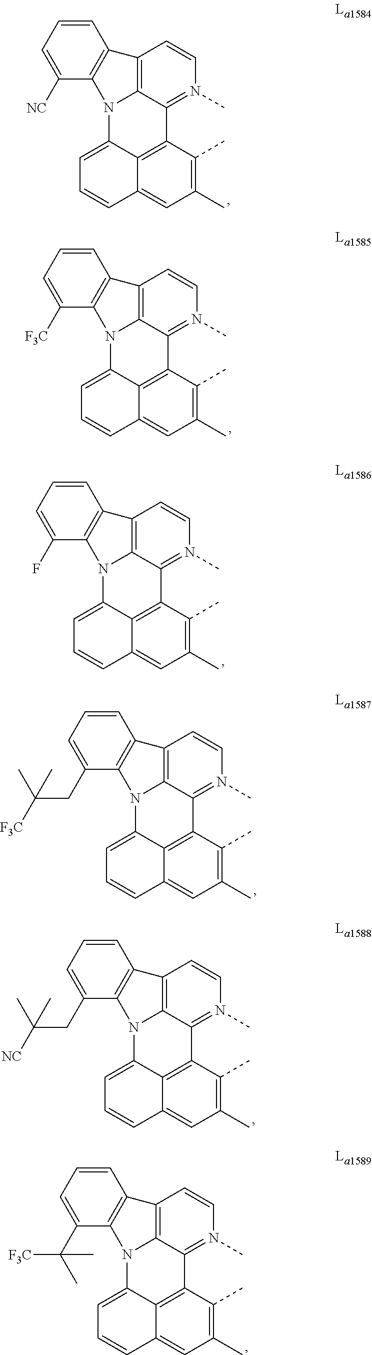 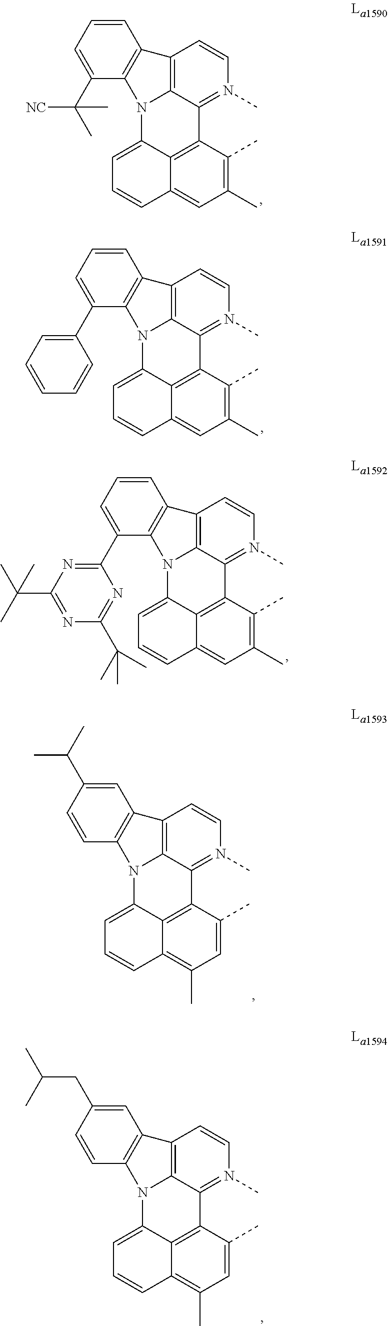 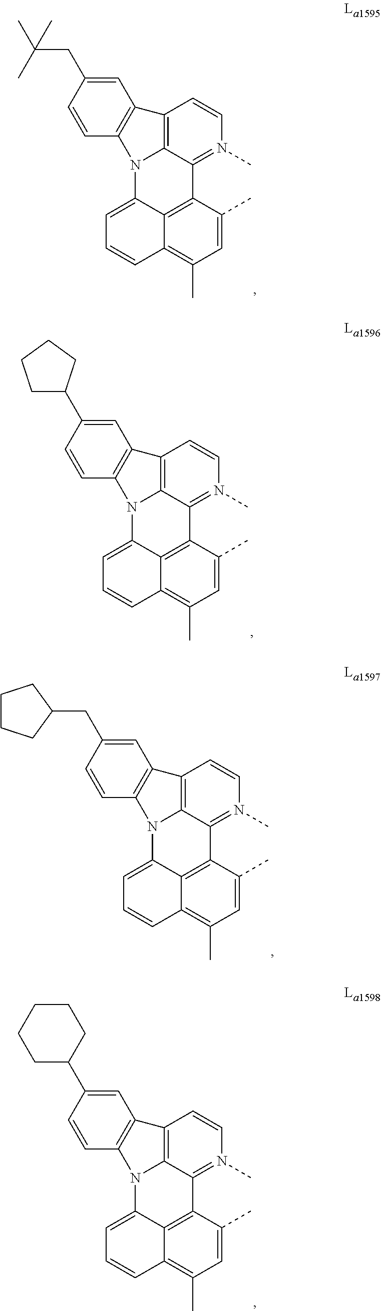 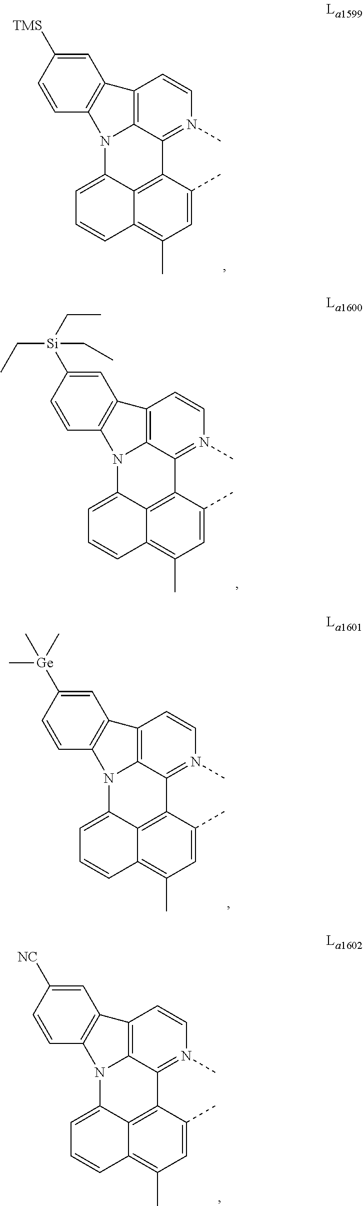 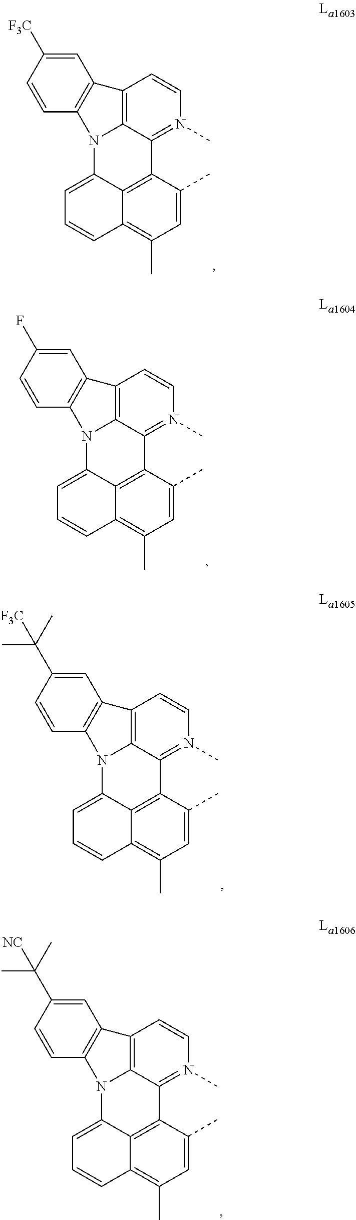 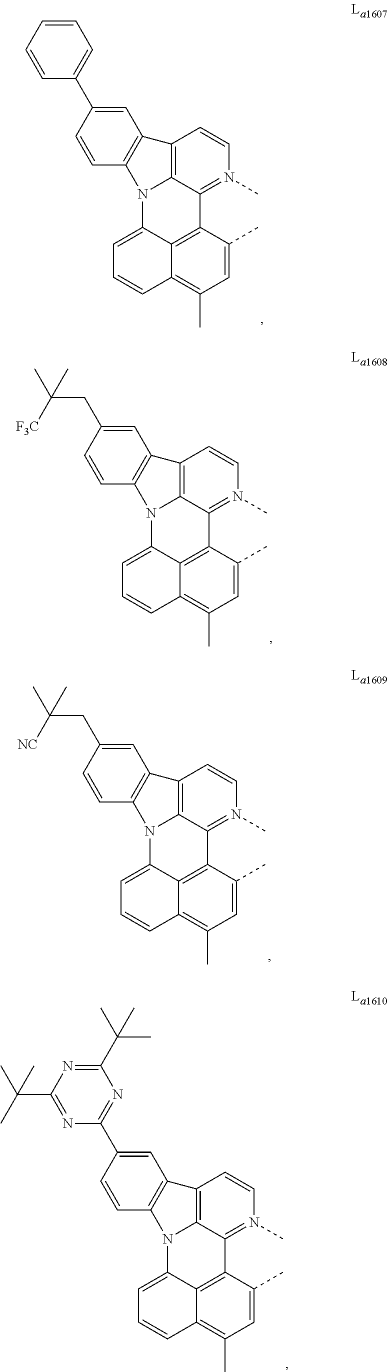 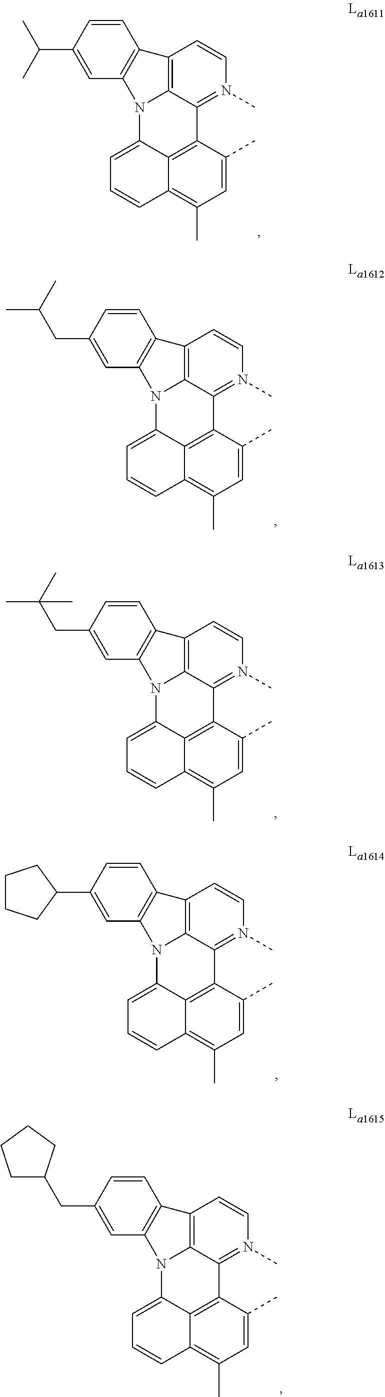 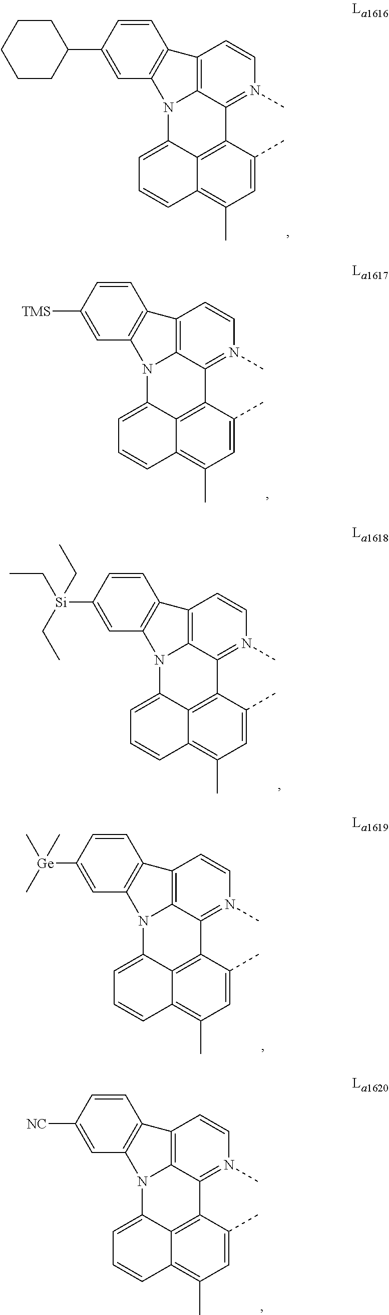 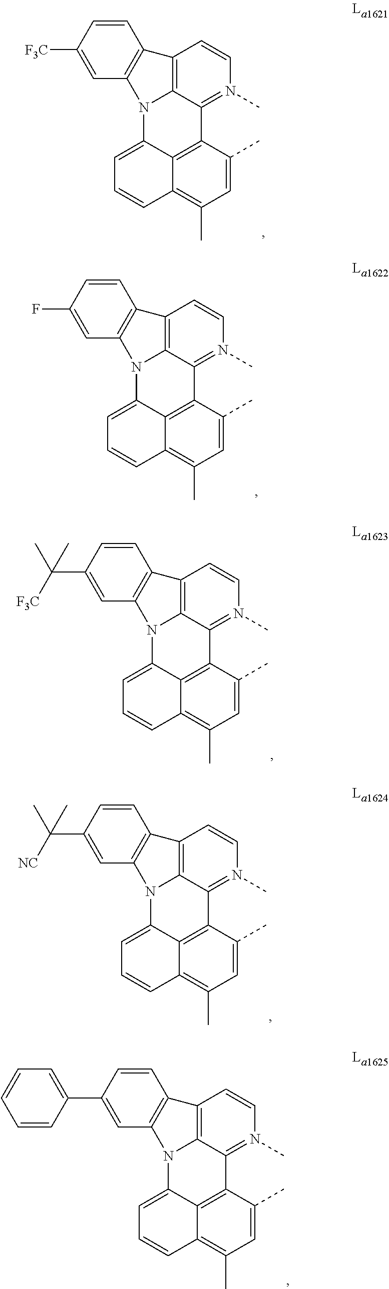 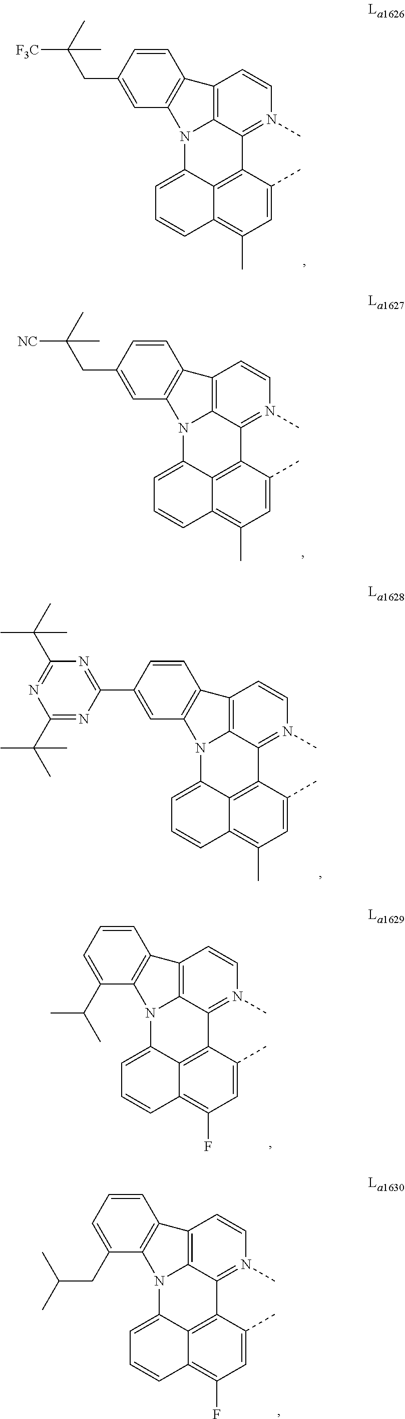 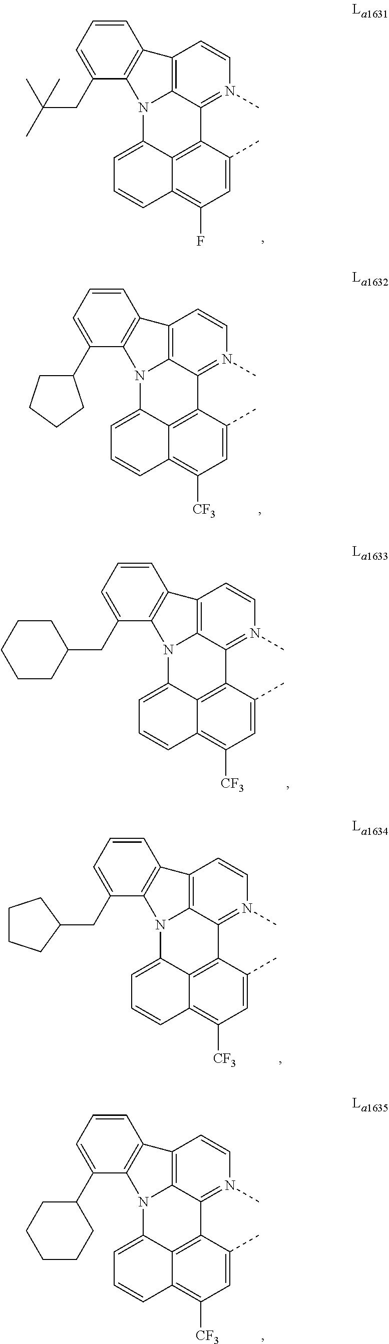 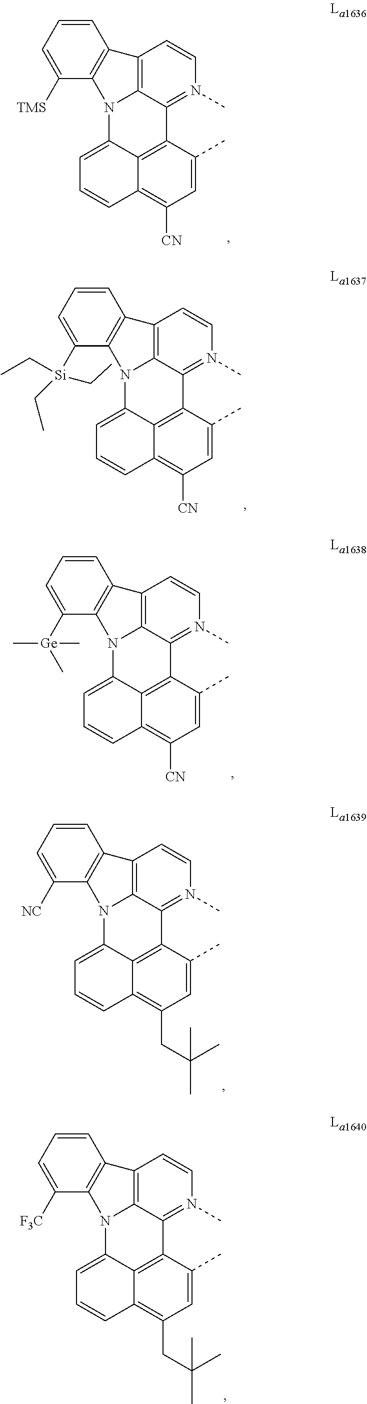 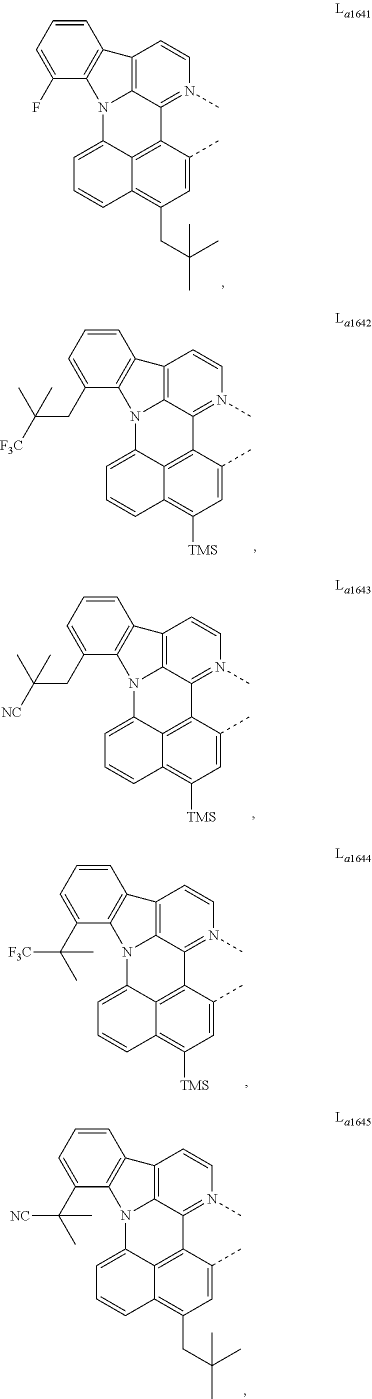 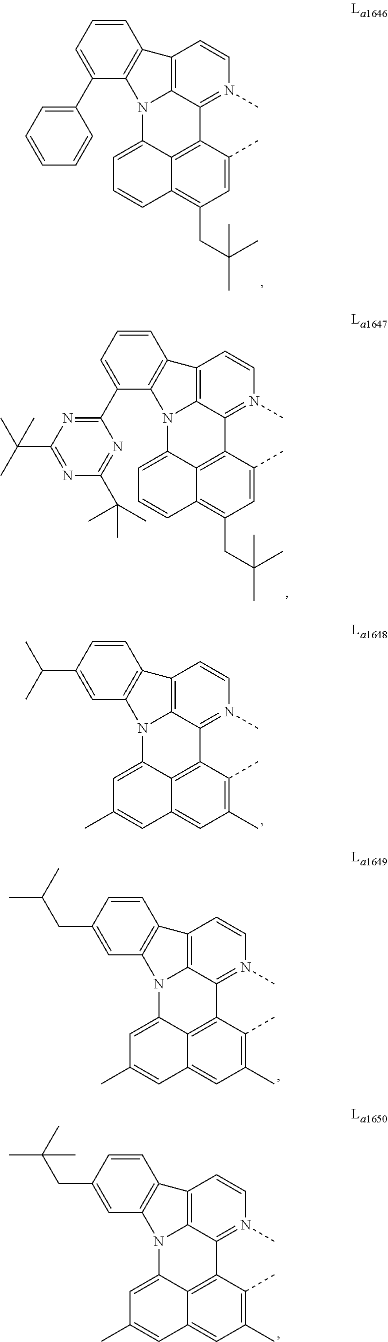 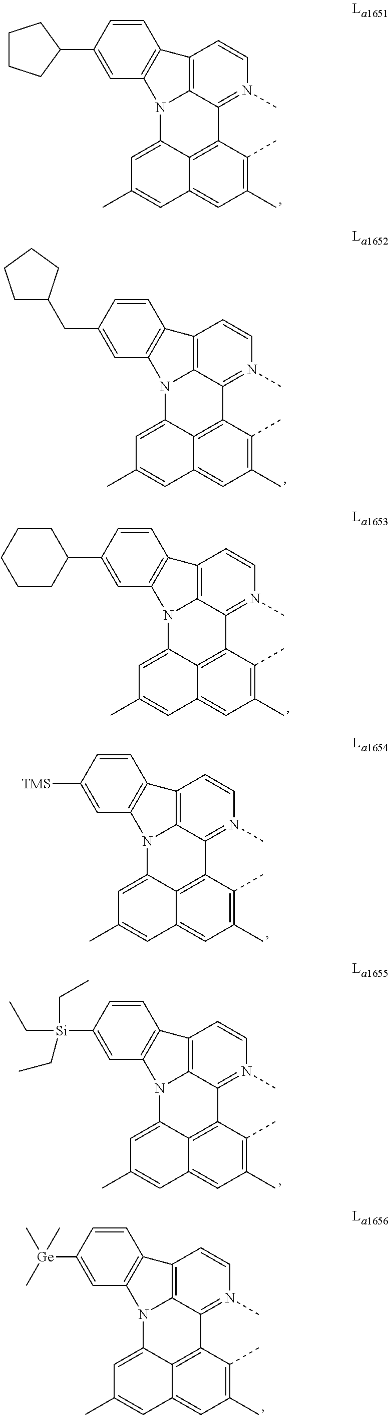 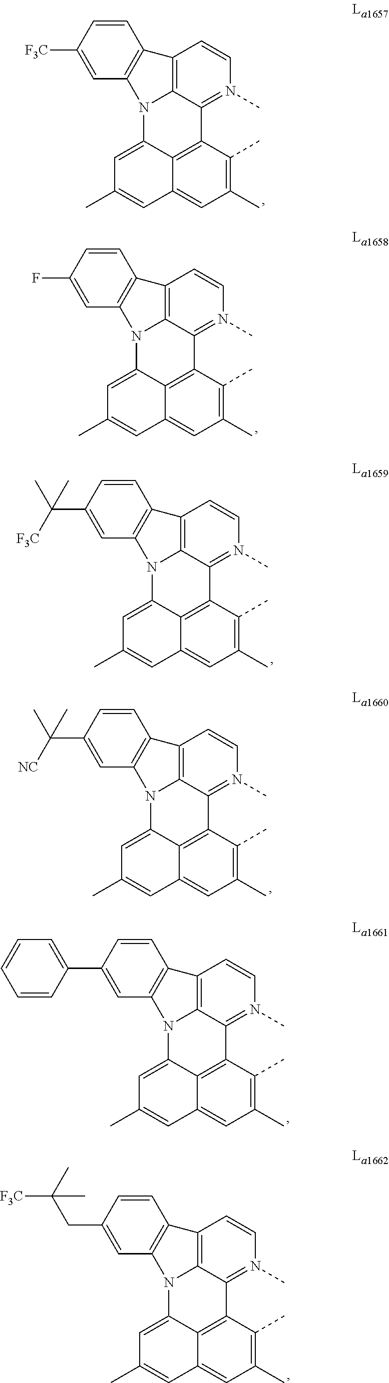 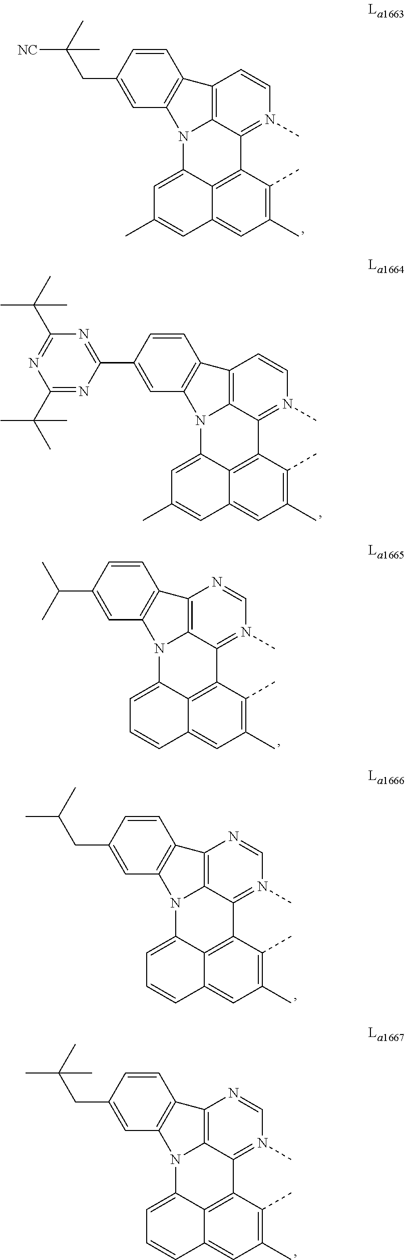 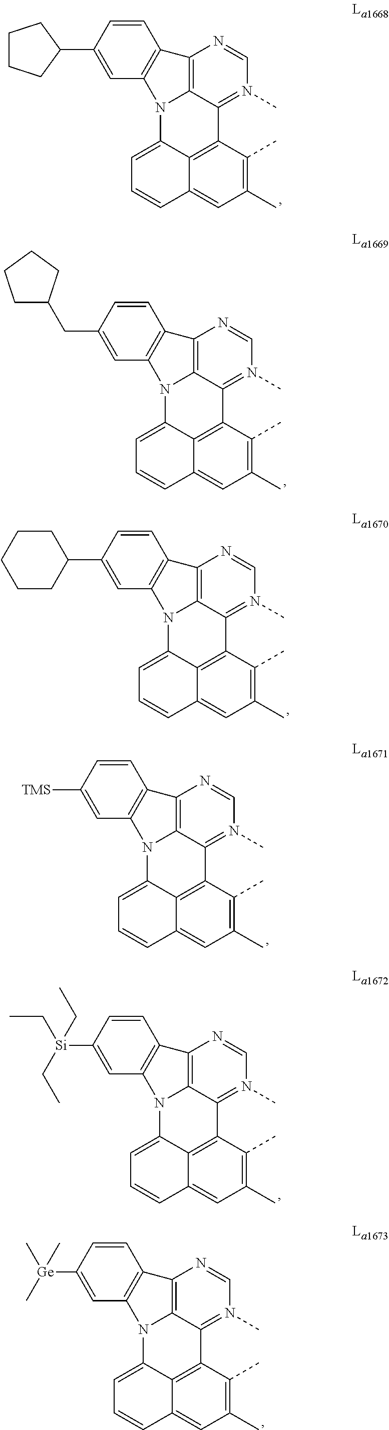 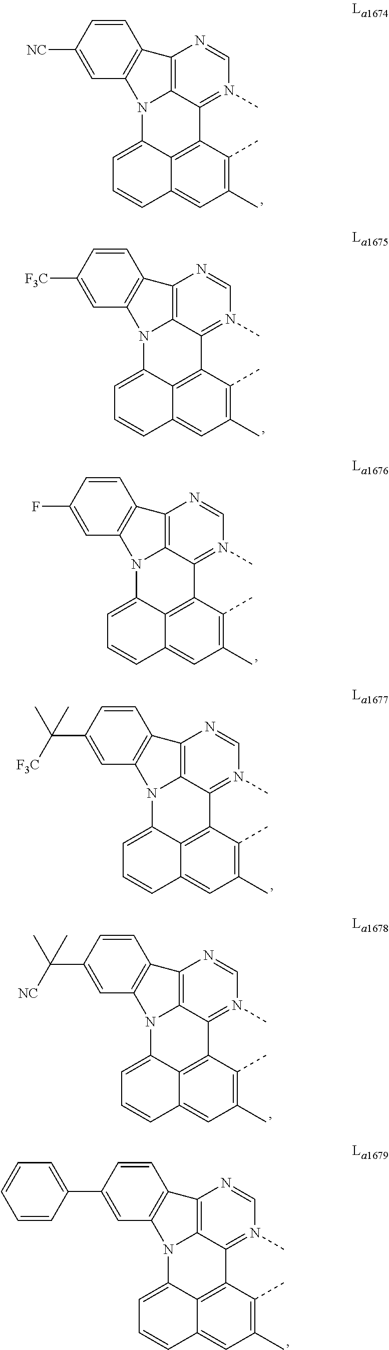 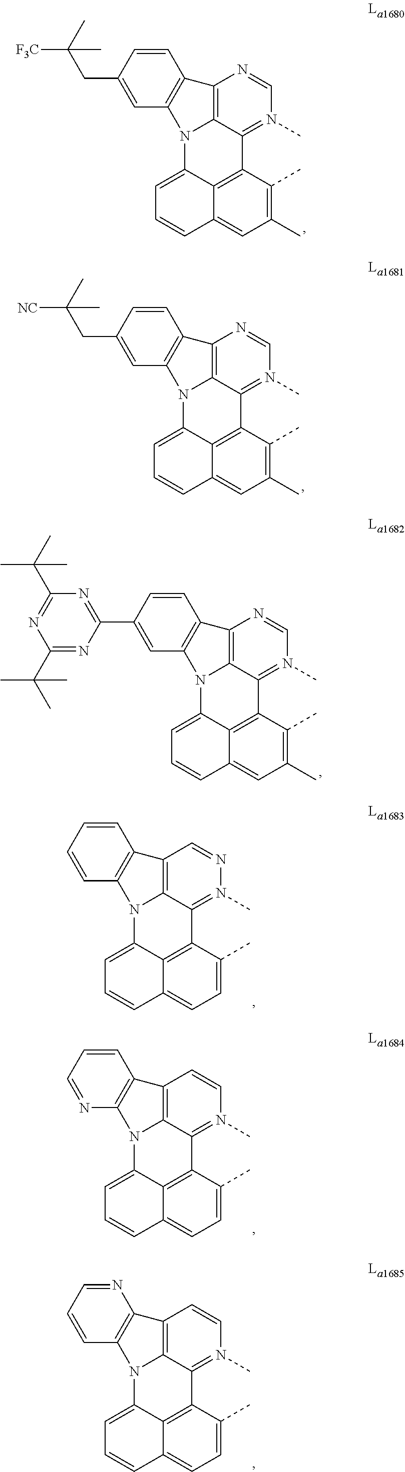 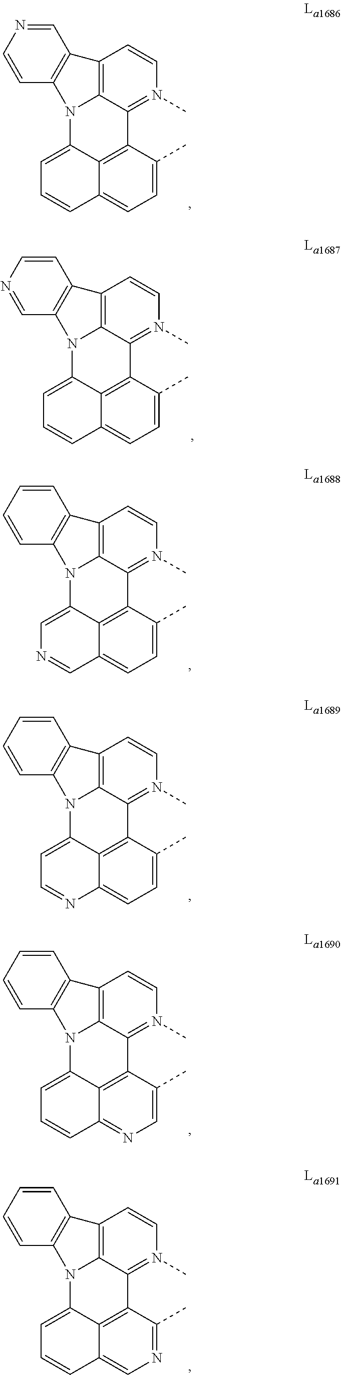 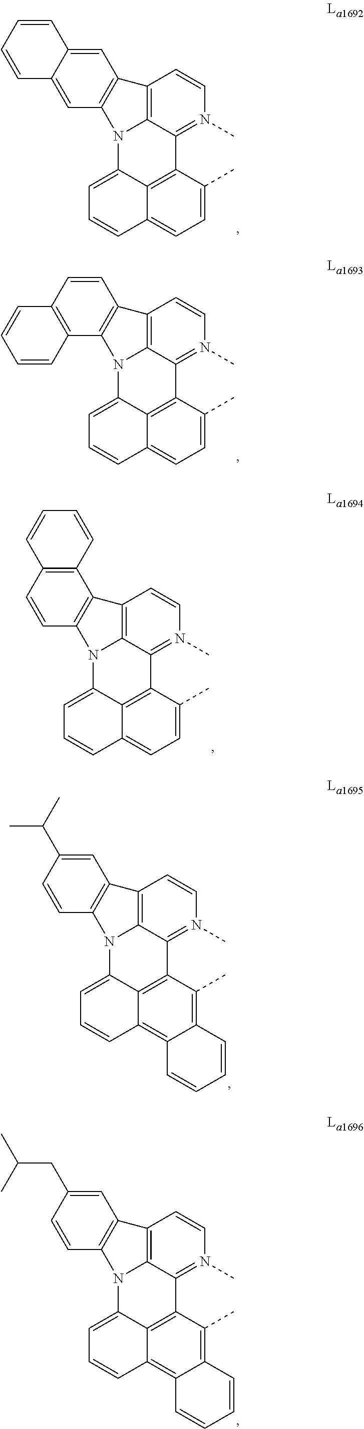 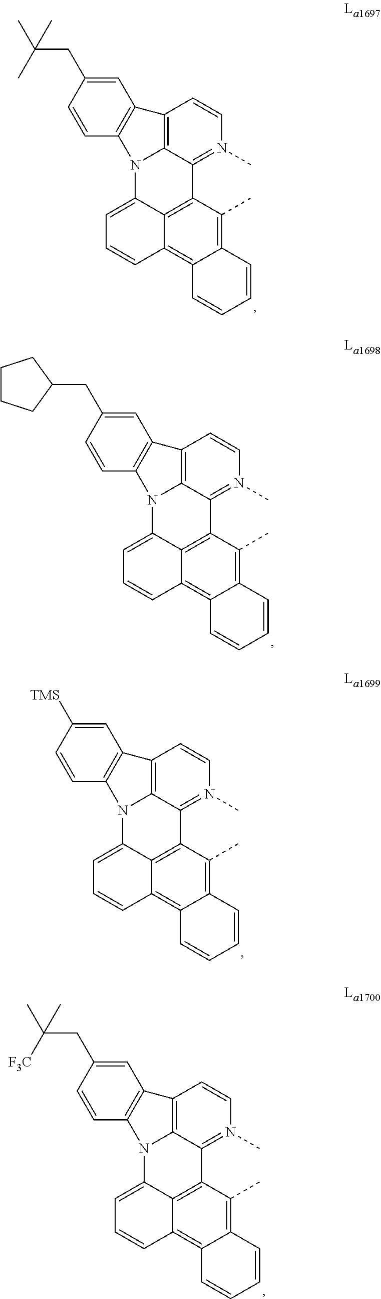 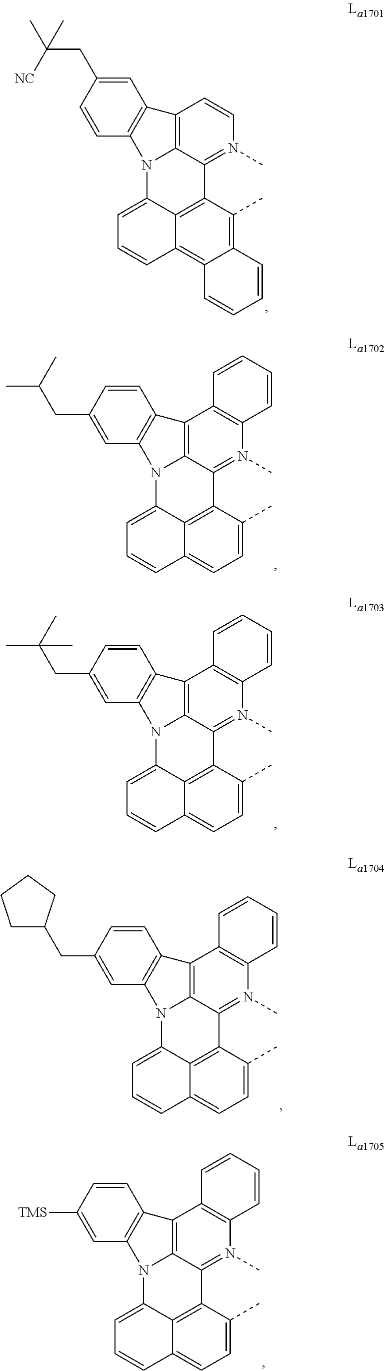 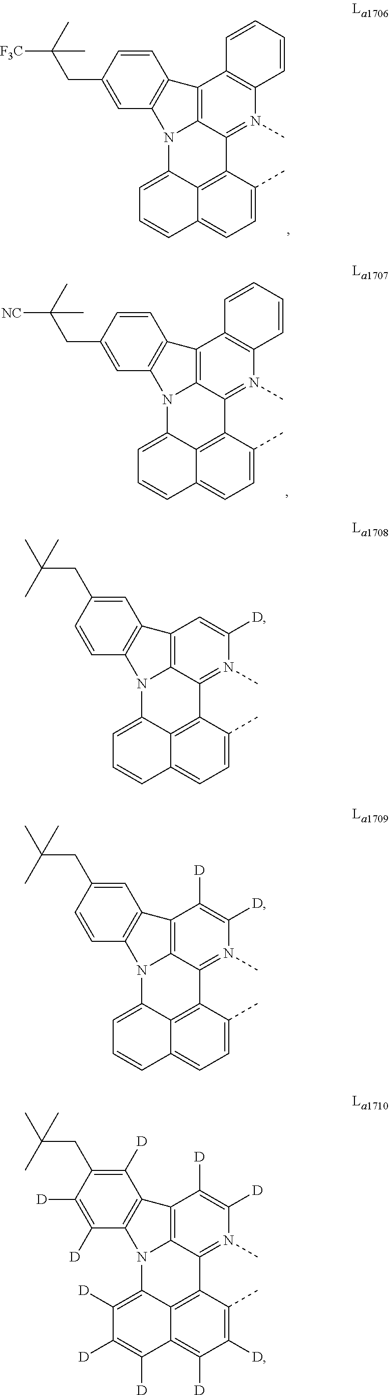 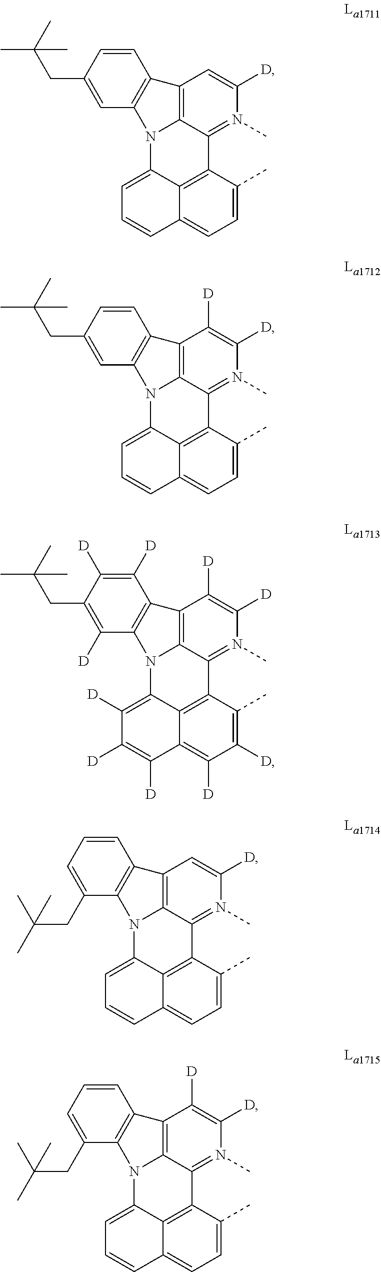 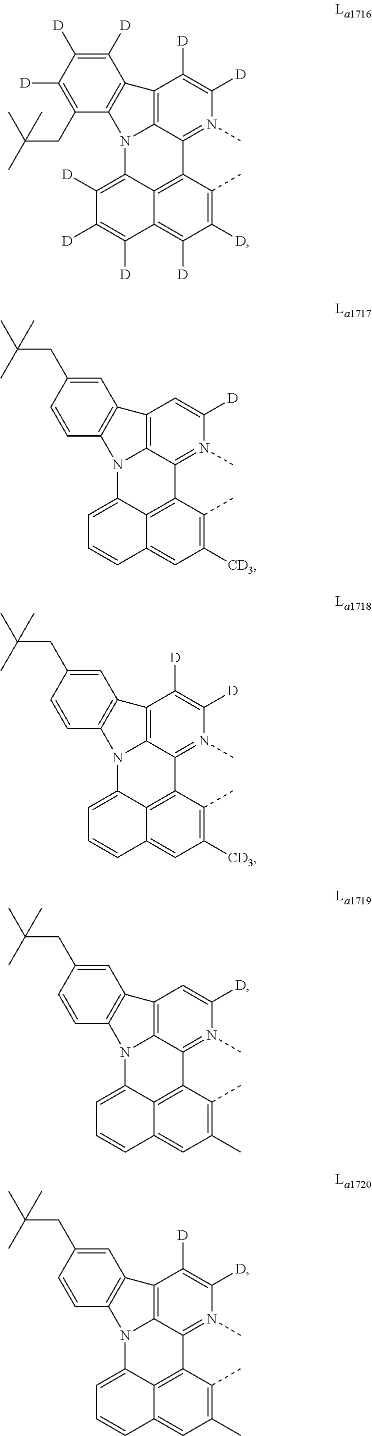 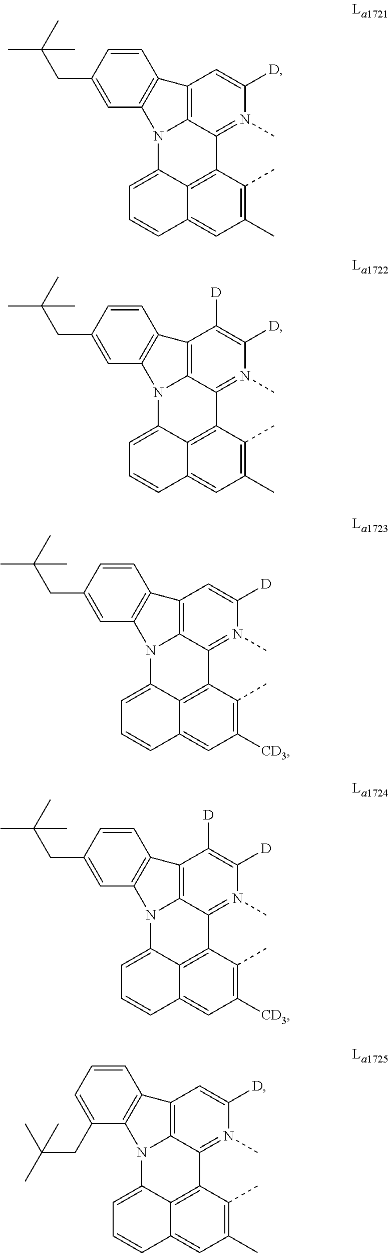 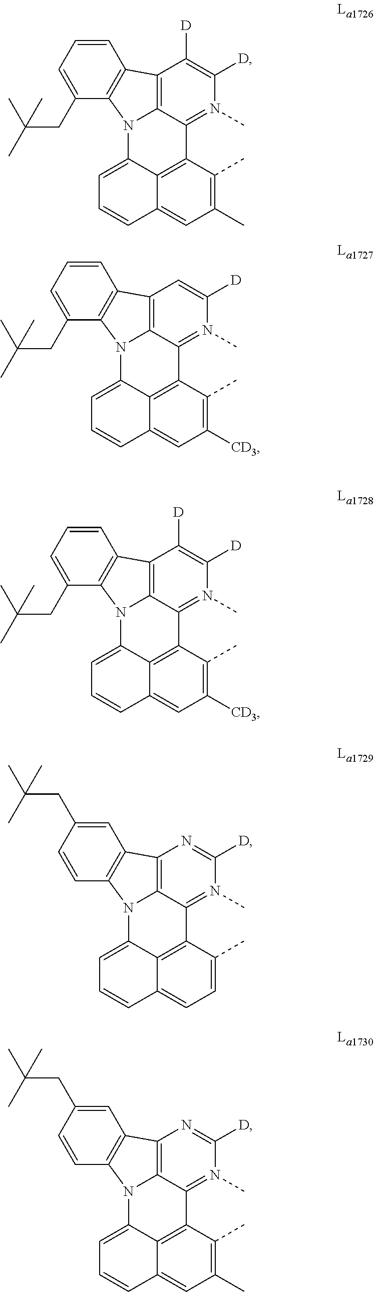 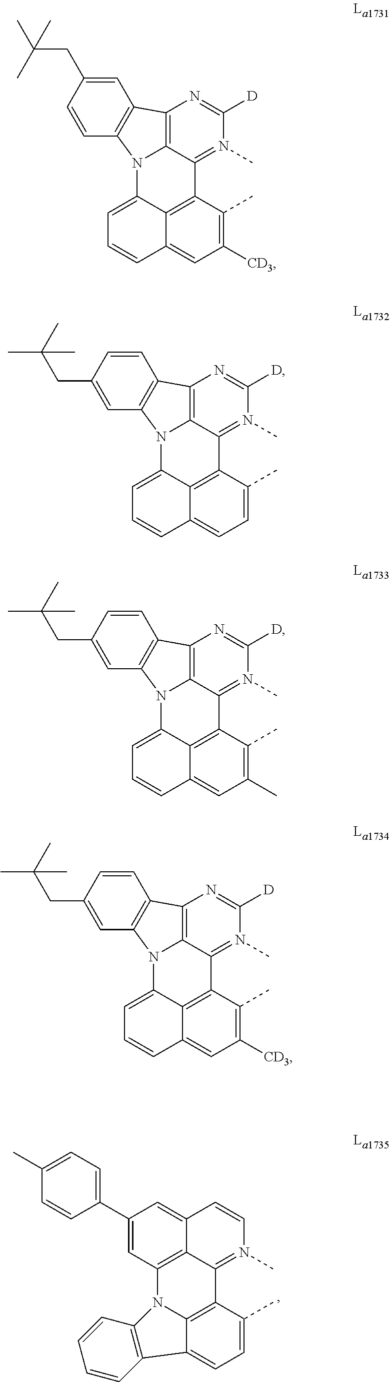 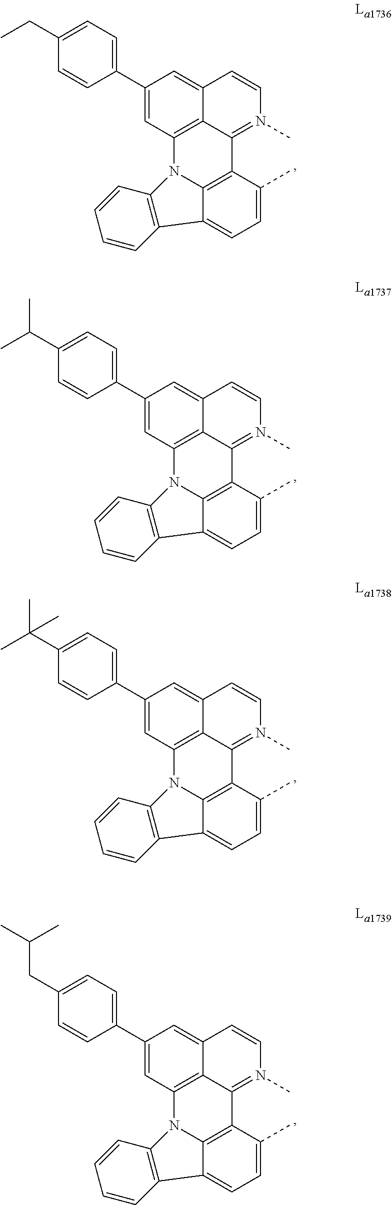 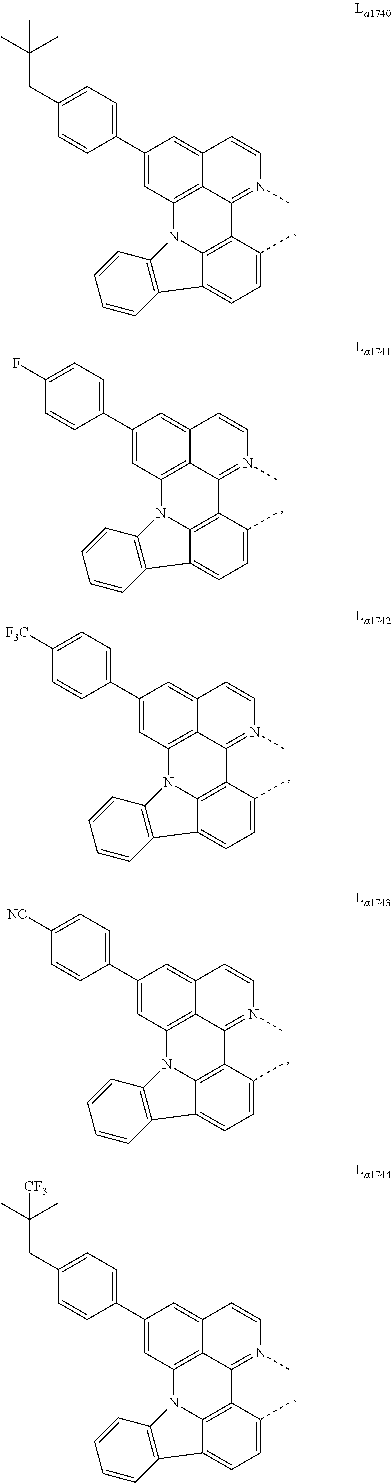 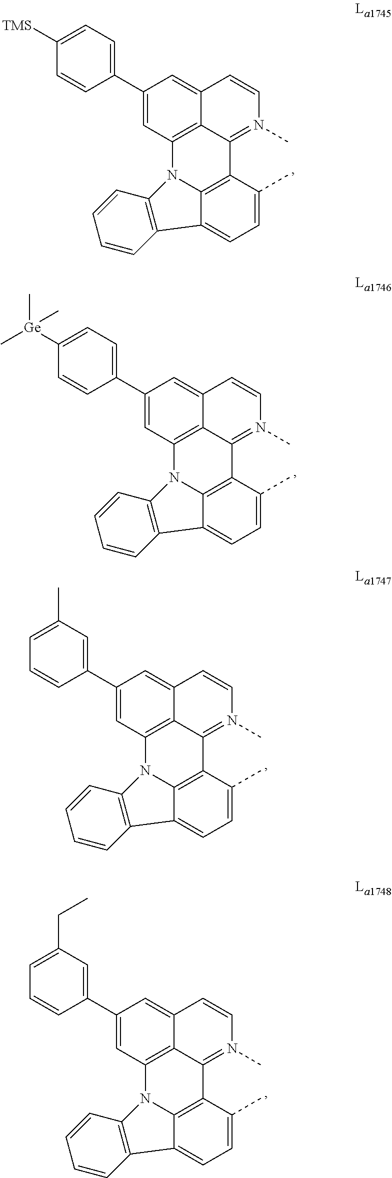 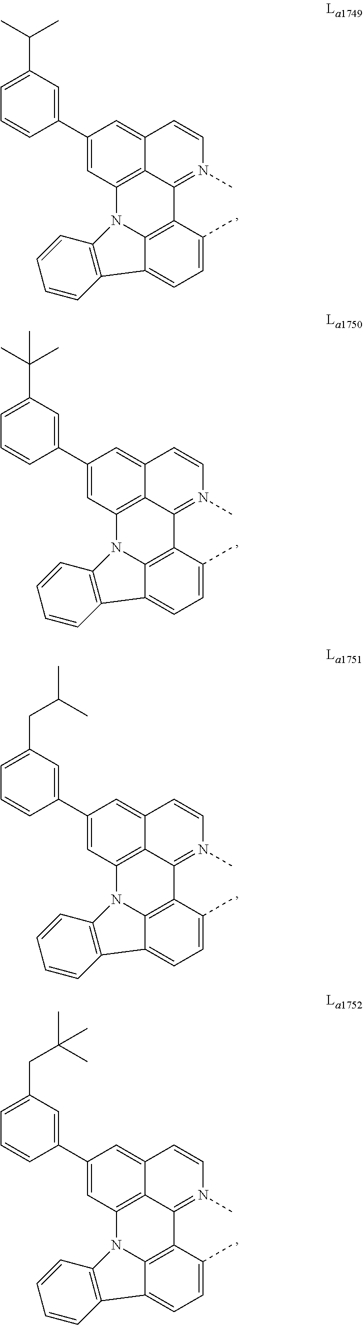 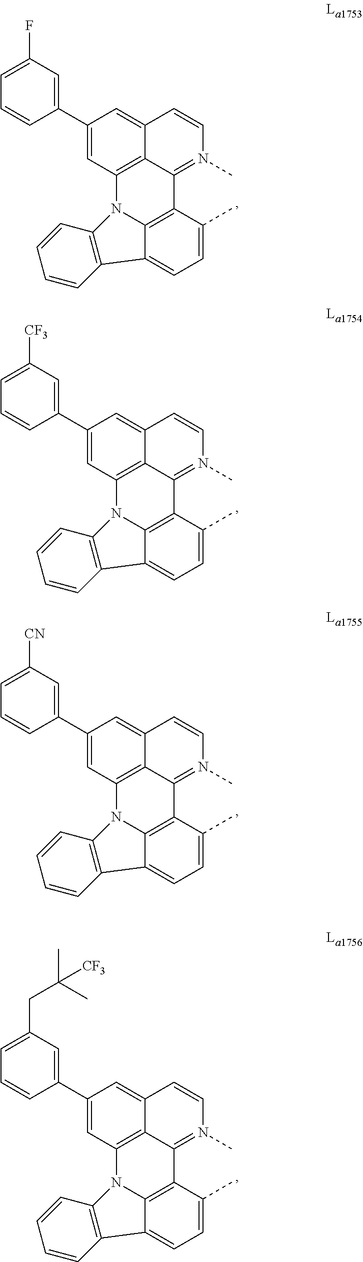 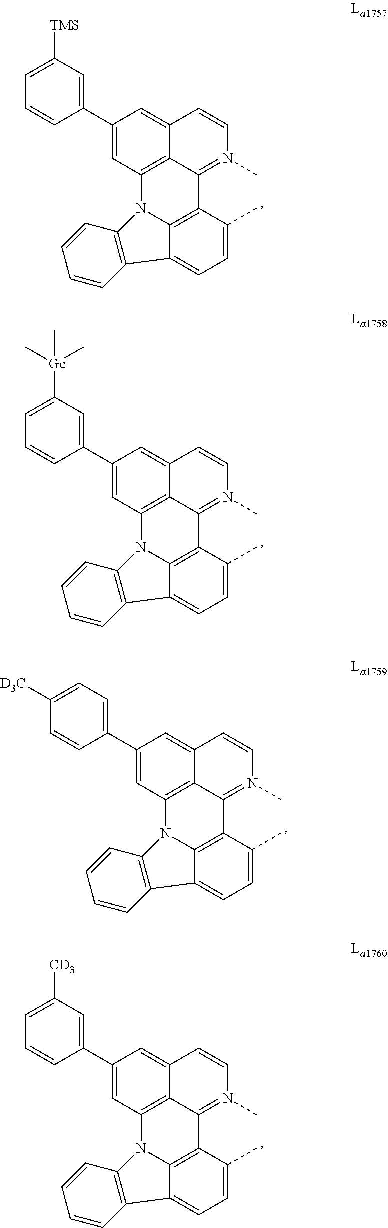 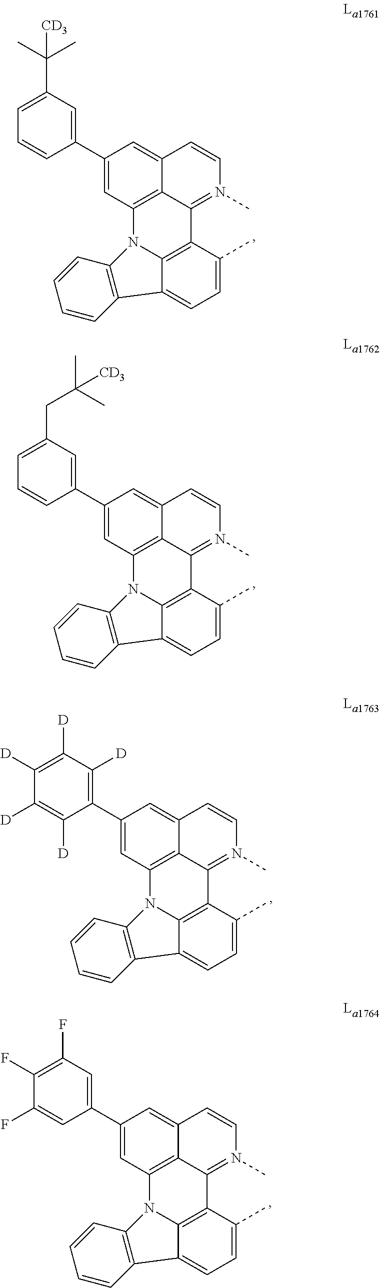 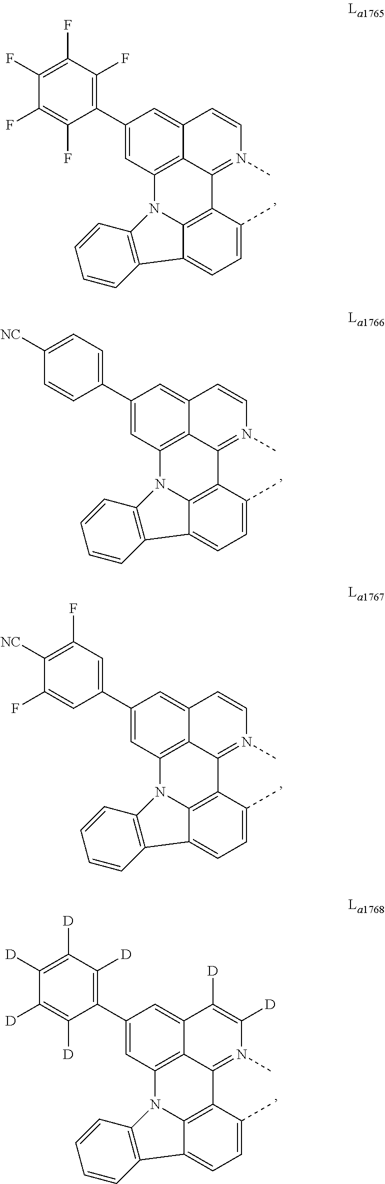 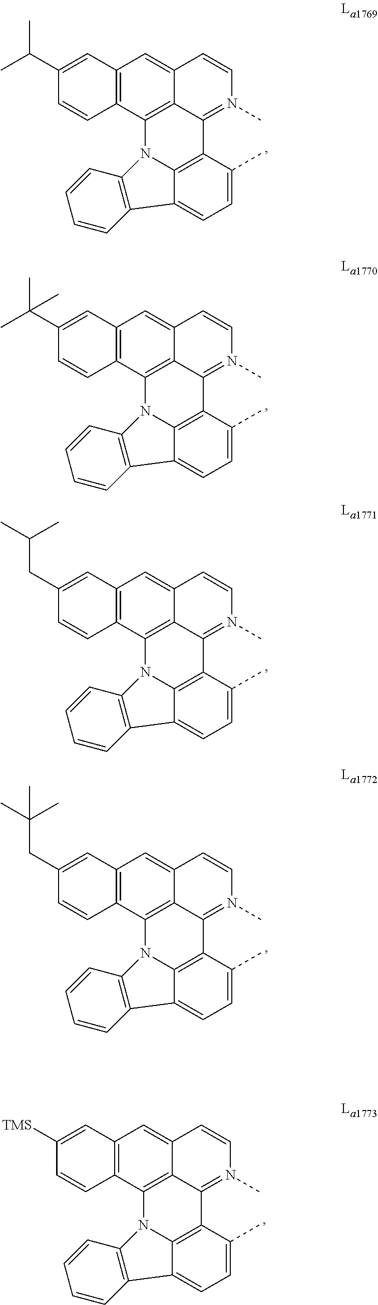 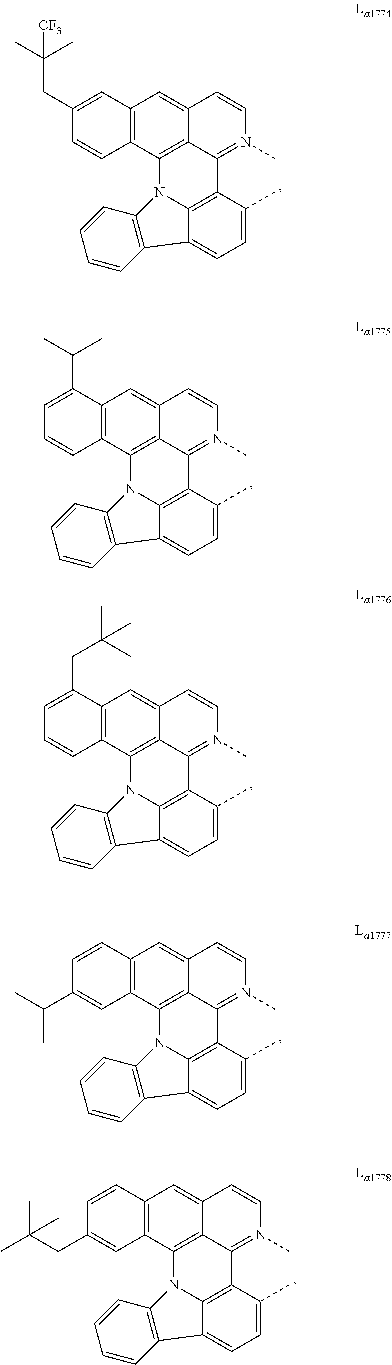 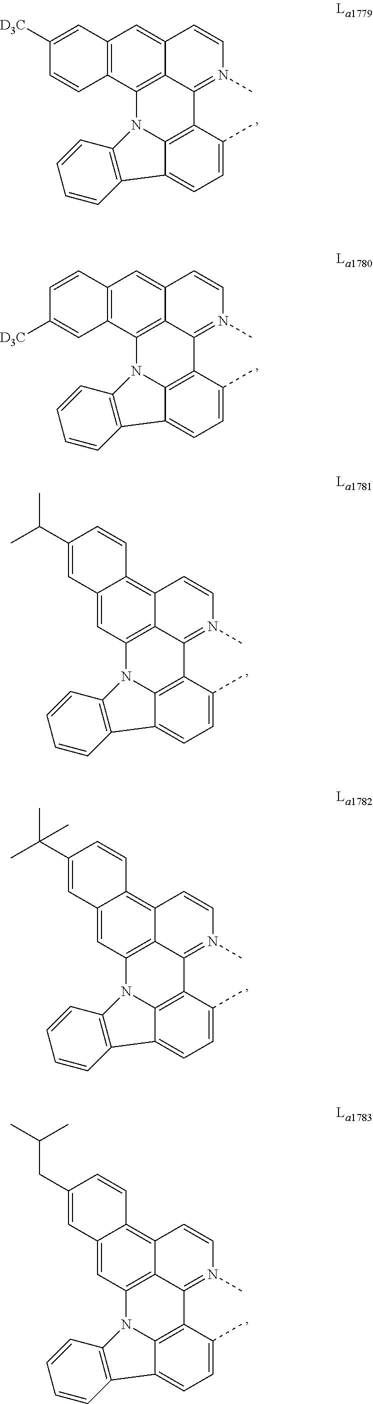 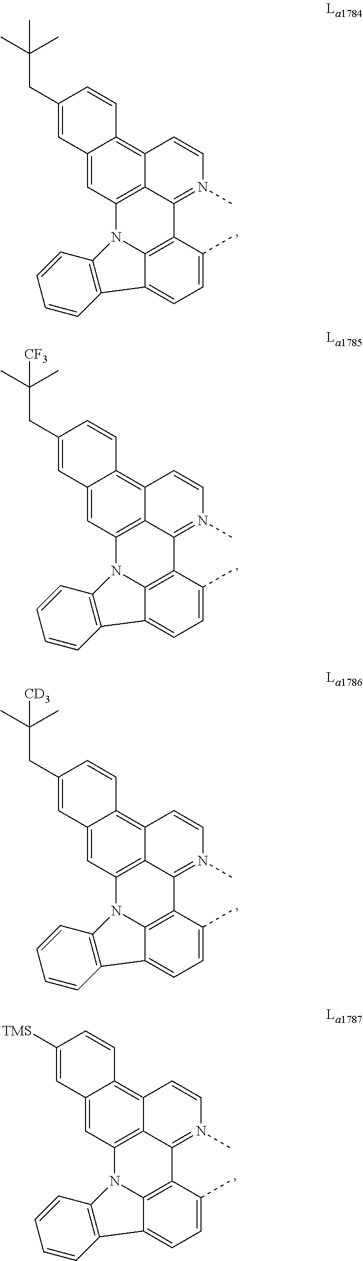 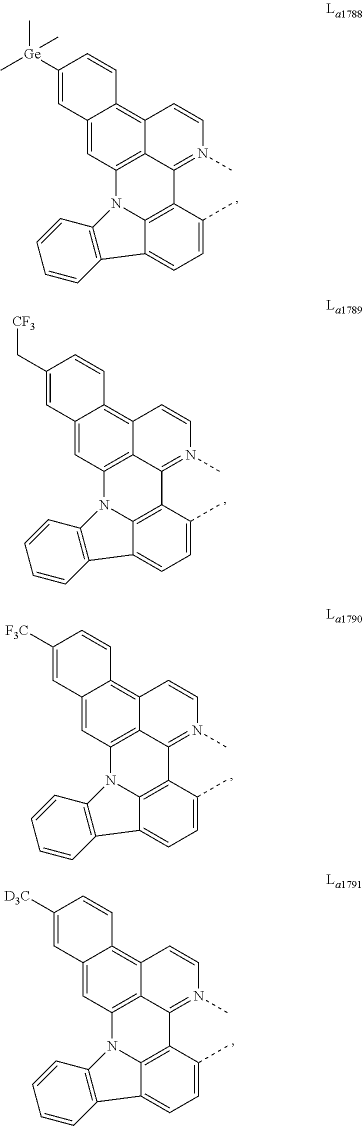 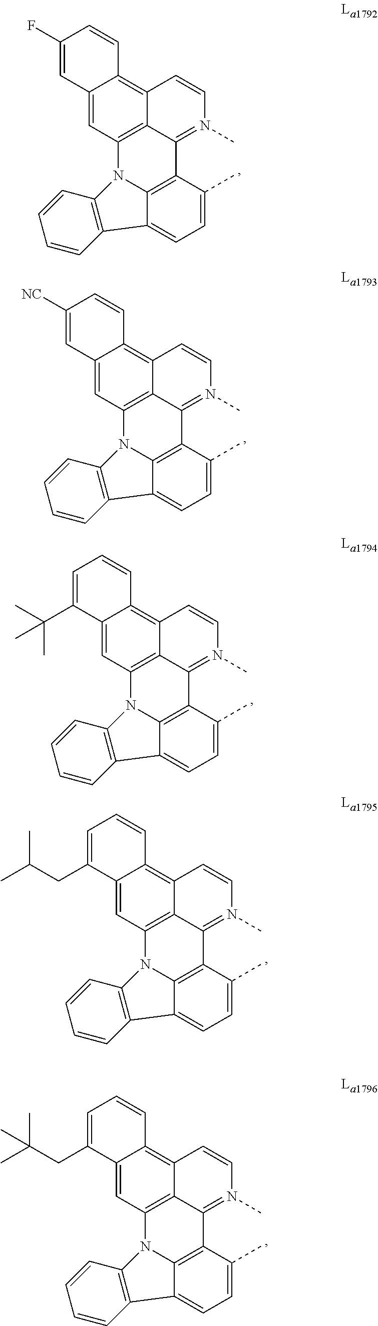 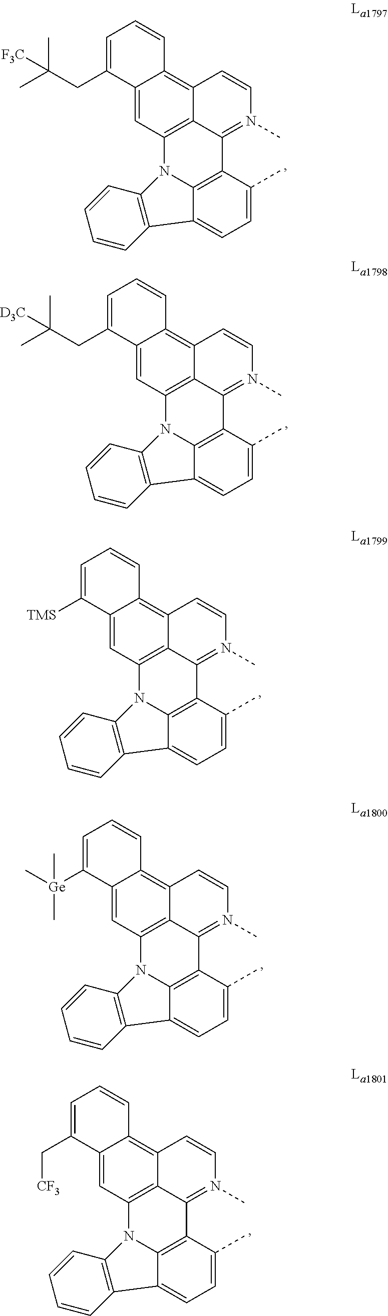 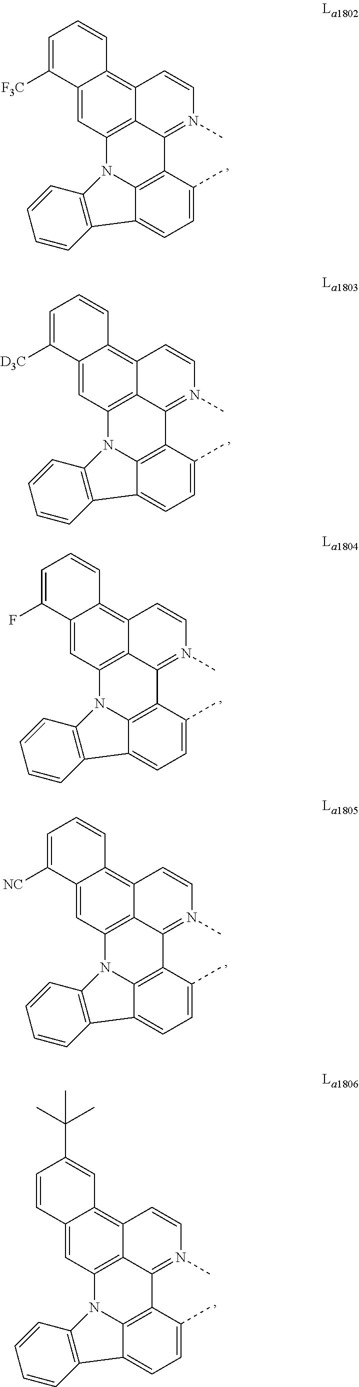 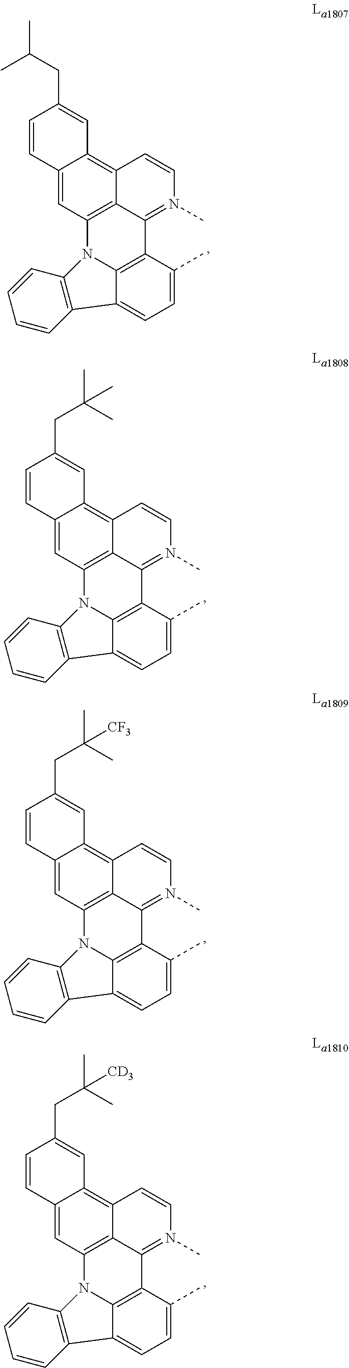 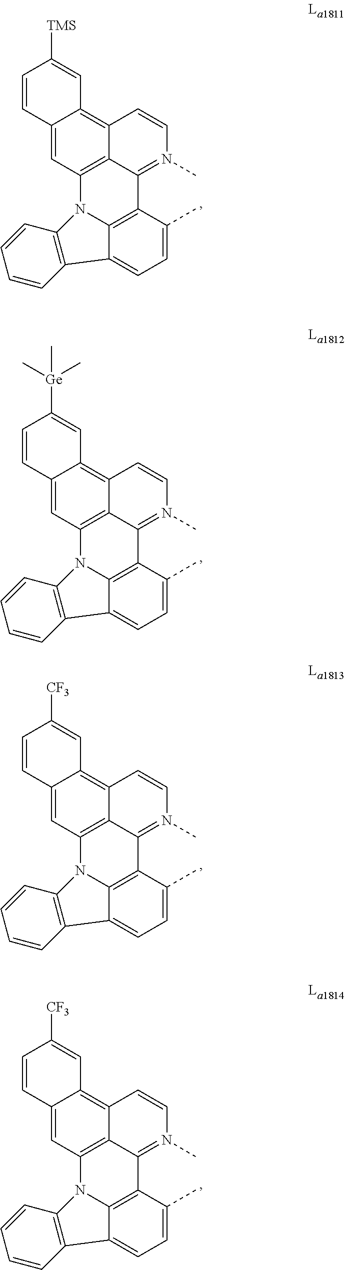 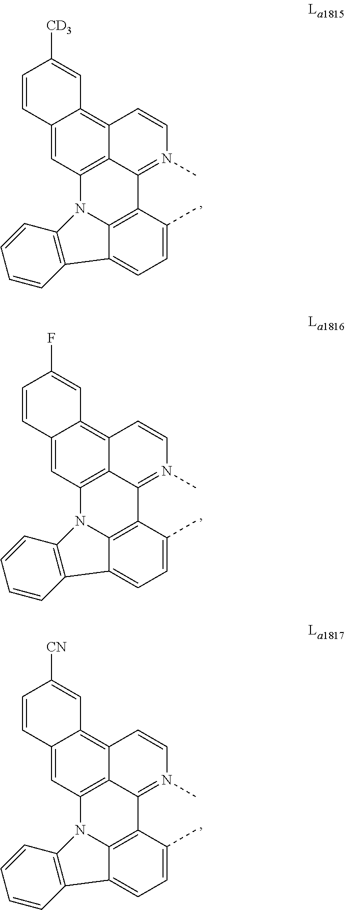
wherein in the above structures, TMS represents trimethylsilyl, and Ph represents phenyl; and
optionally, hydrogens in the structures of Lₐ₁ to Lₐ₁₈₂₀ can be partially or fully substituted with deuterium.

11. The metal complex according to claim 1, wherein the second ligand L_{b} is represented by Formula 21: 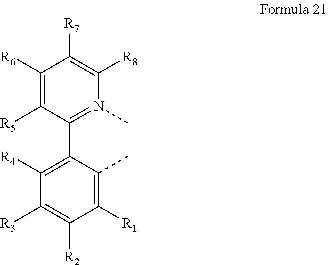
wherein R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R₁ to R₈ can be optionally joined to form a ring;
preferably, R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
more preferably, at least one or two of R₁ to R₈ are, at each occurrence identically or differently, selected from deuterium, substituted or unsubstituted alkyl having 1 to 20 carbon atoms, substituted or unsubstituted cycloalkyl having 3 to 20 ring carbon atoms, or a combination thereof.

12. The metal complex according to claim 11, wherein at least one, at least two, at least three, or all of R₂, R₃, R₆, and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, at least one, at least two, at least three, or all of R₂, R₃, R₆, and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, and combinations thereof,
more preferably, at least one, at least two, at least three, or all of R₂, R₃, R₆, and R₇ are, at each occurrence identically or differently, selected from the group consisting of: deuterium, methyl, ethyl, propyl, isopropyl, n-butyl, isobutyl, t-butyl, cyclopentyl, cyclohexyl, neopentyl, t-pentyl, and any preceding group that is partially or fully substituted with deuterium.

13. The metal complex according to claim 10, wherein L_{b} is, at each occurrence identically or differently, selected from the group consisting of the following: 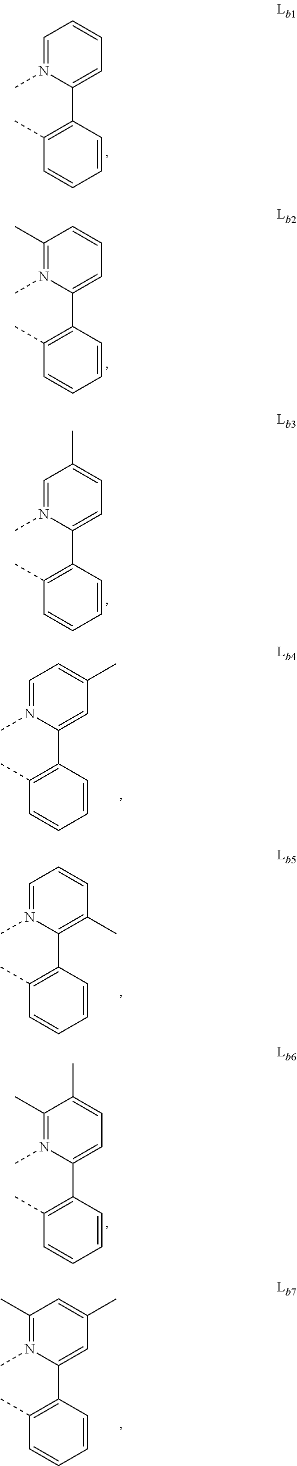 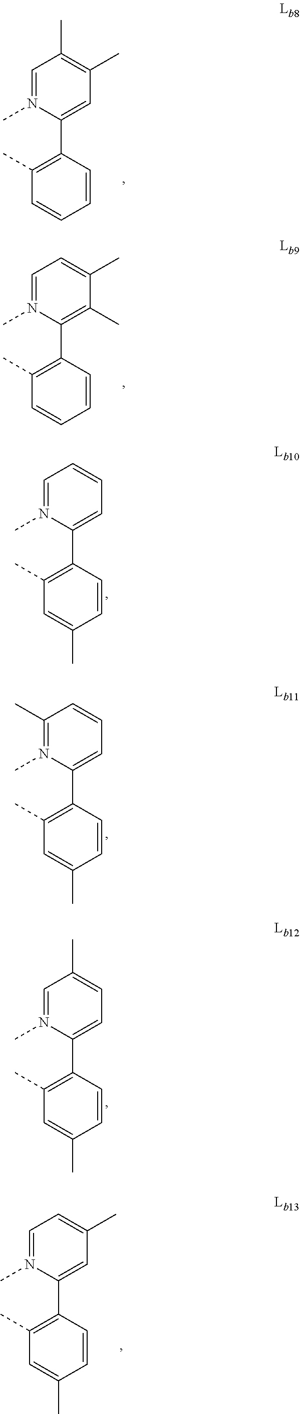 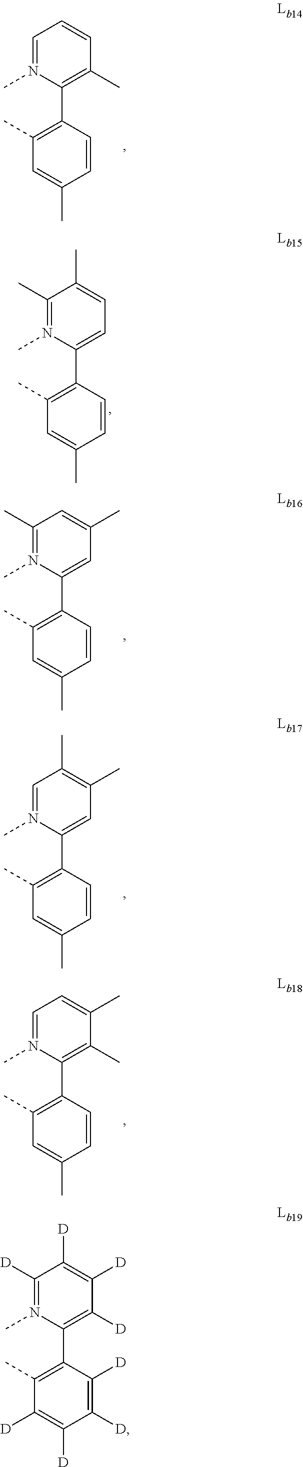 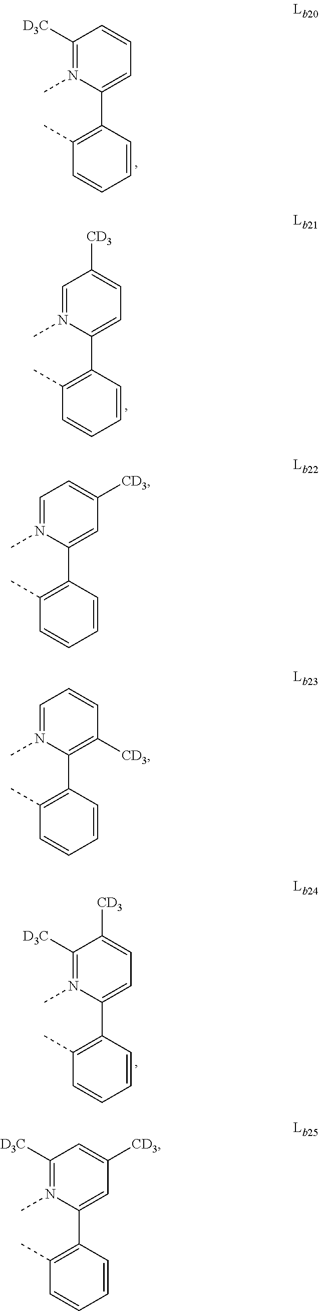 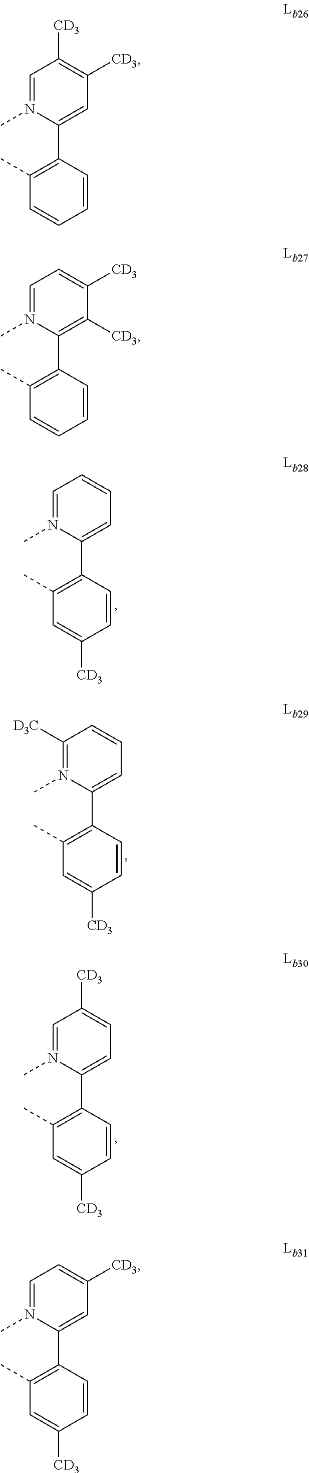 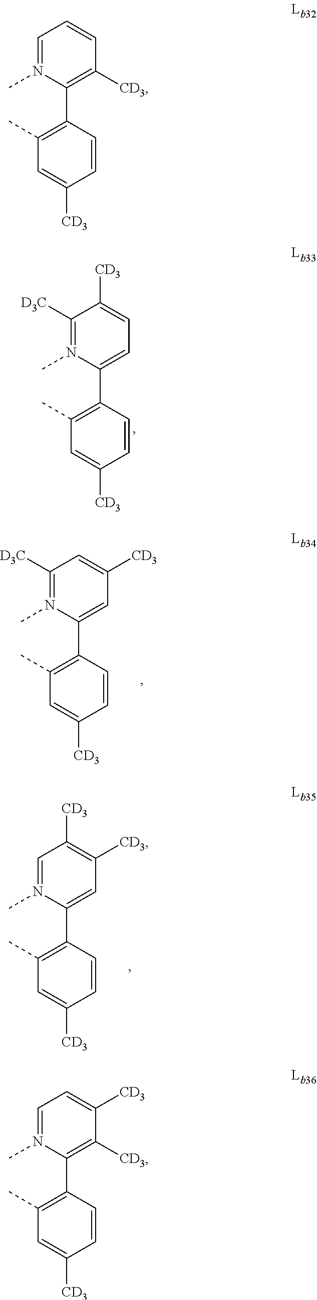 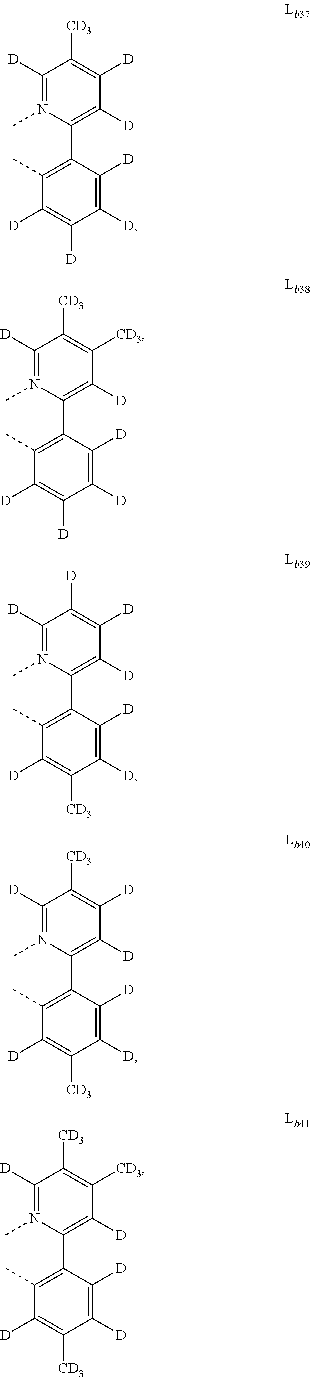 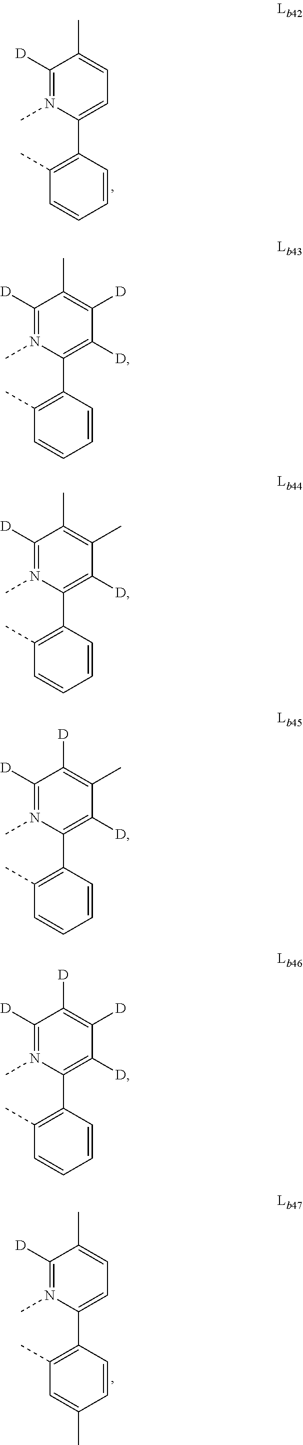 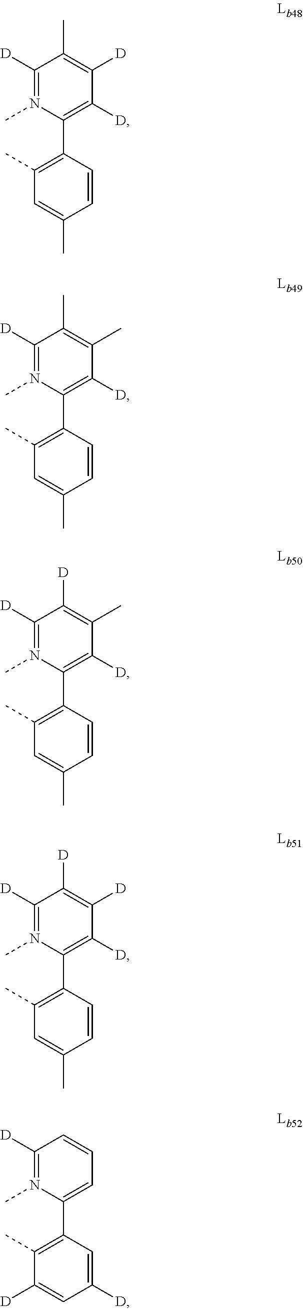 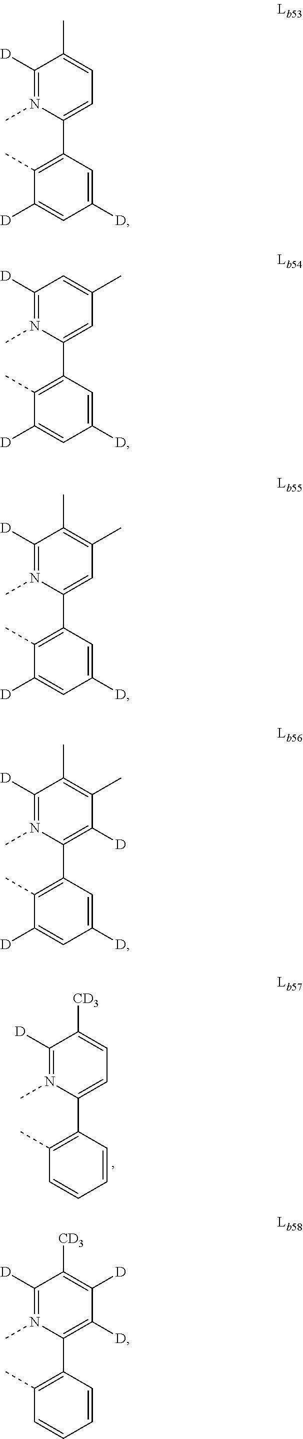 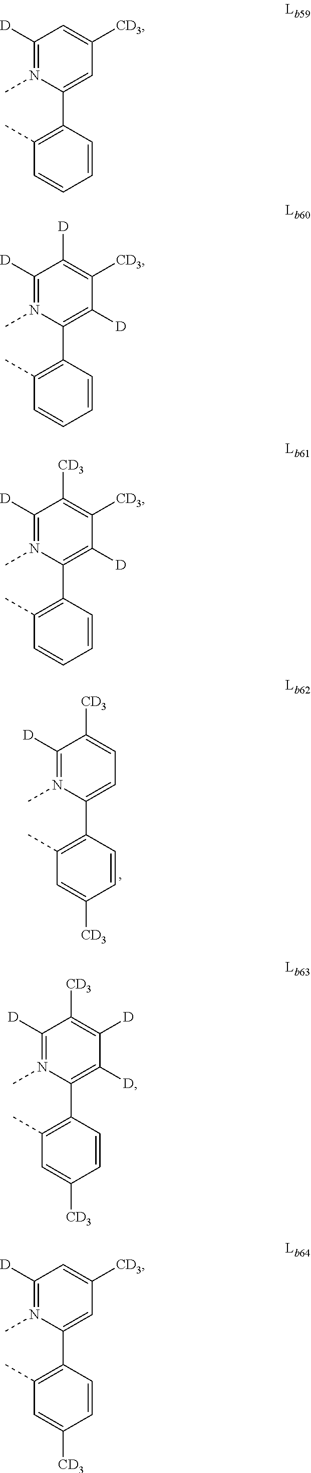 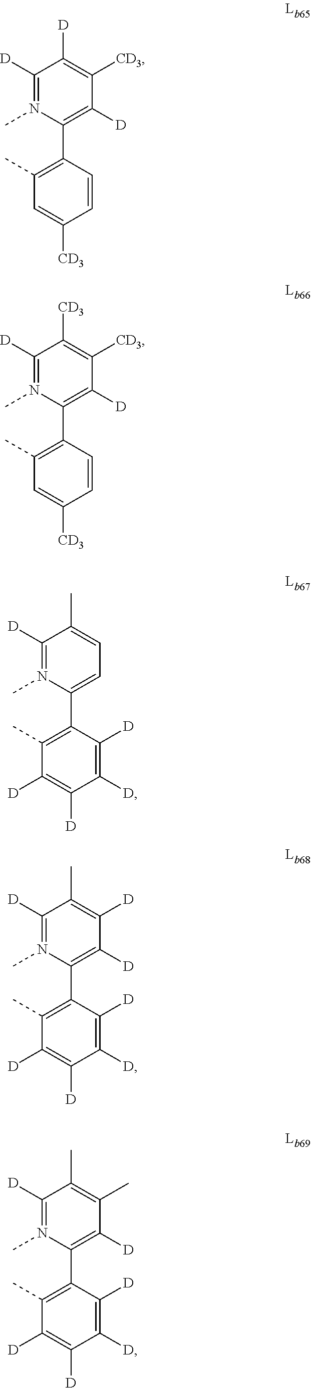 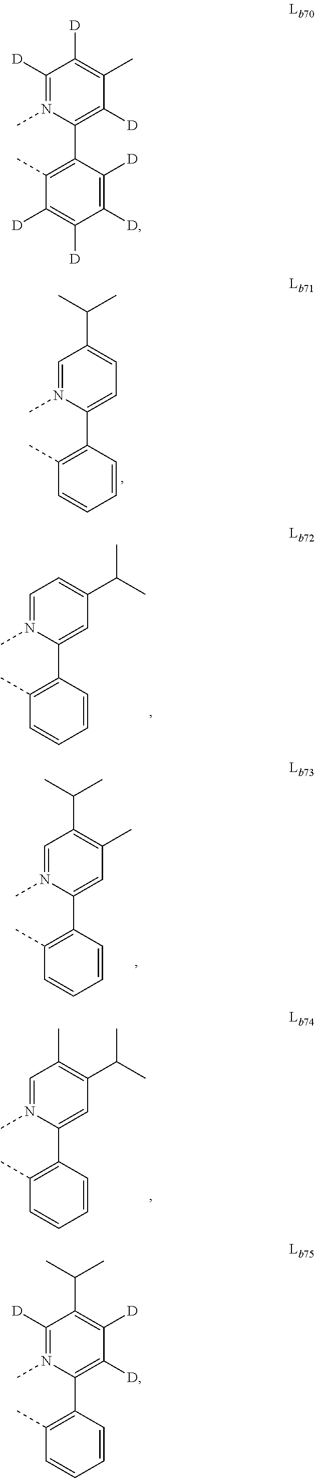 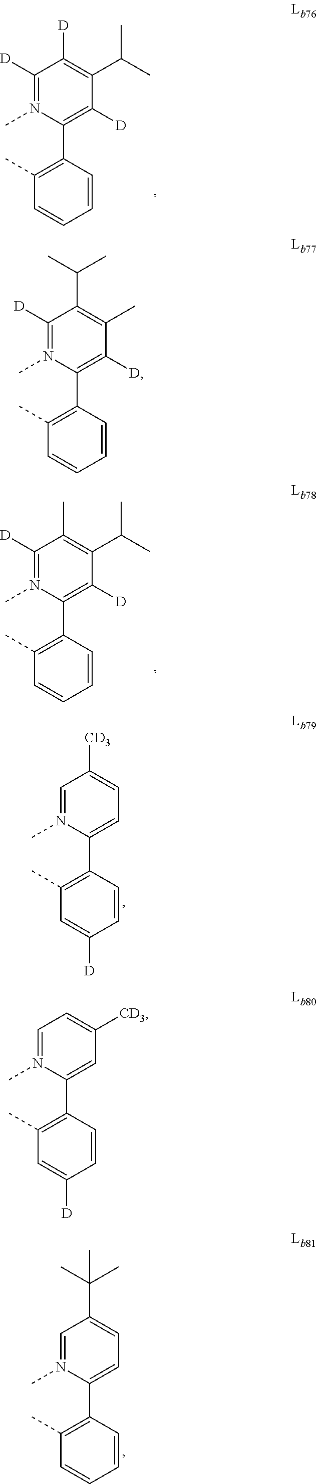 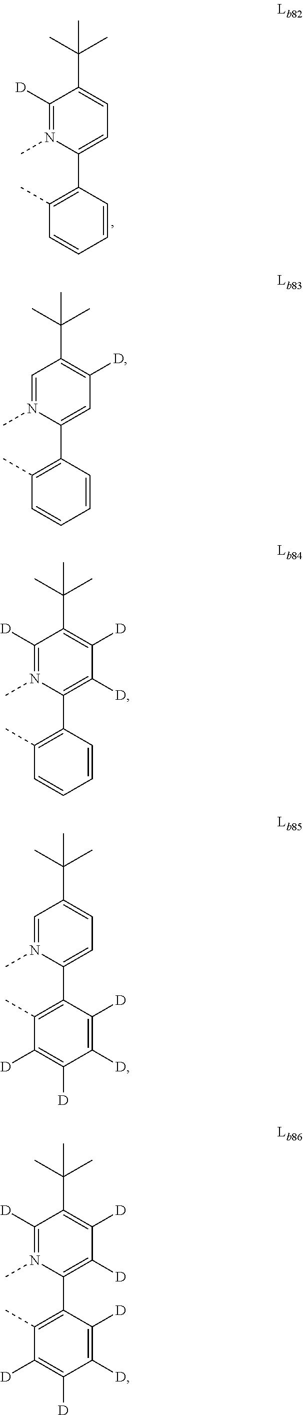 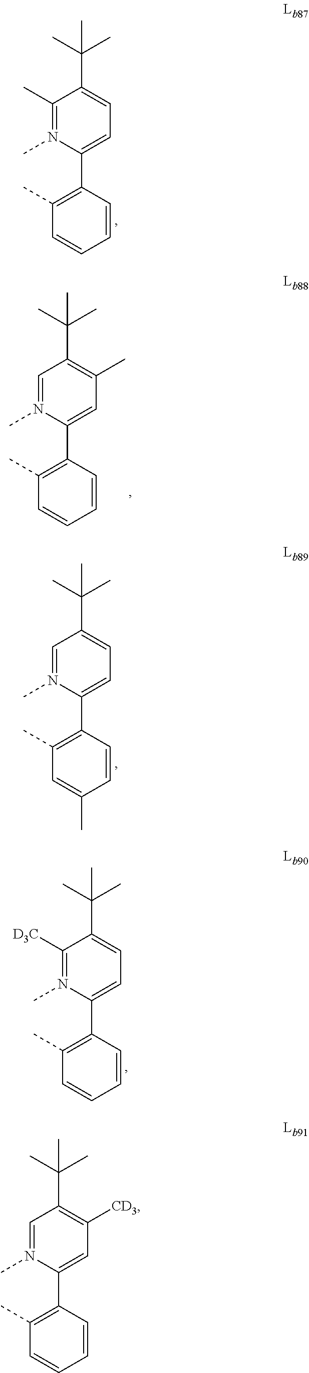 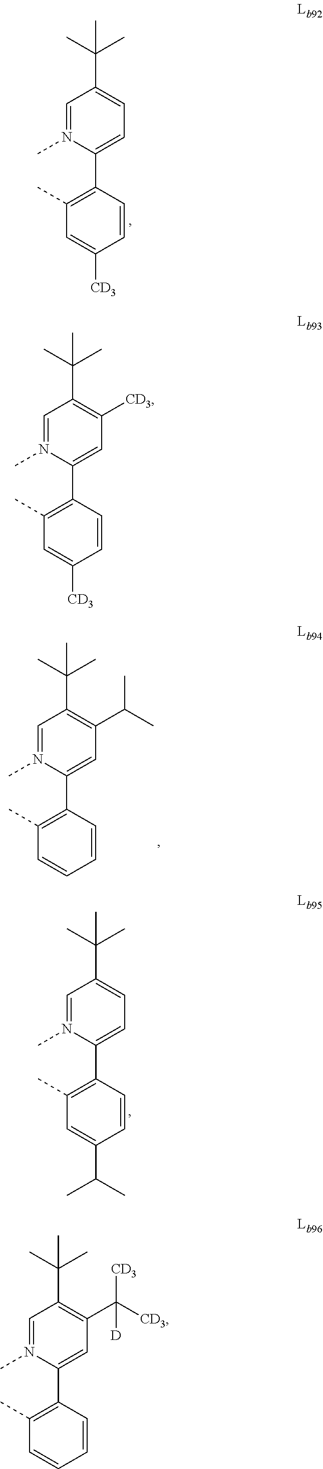 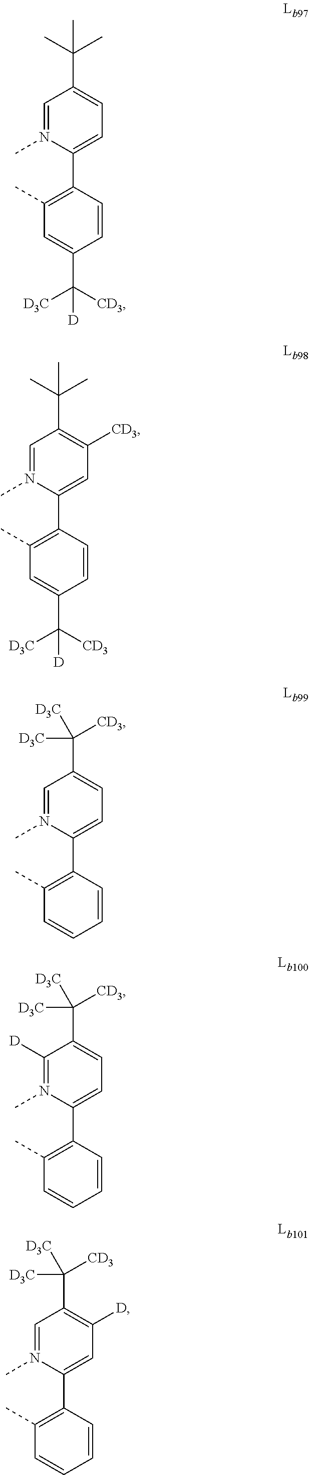 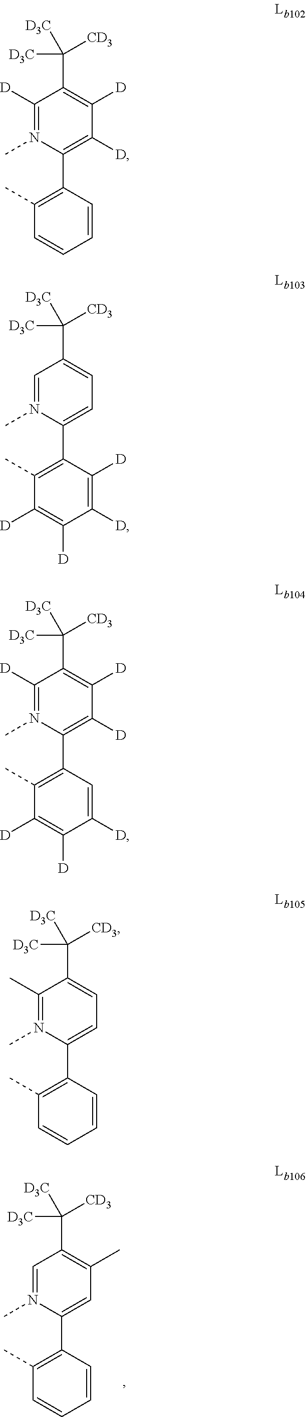 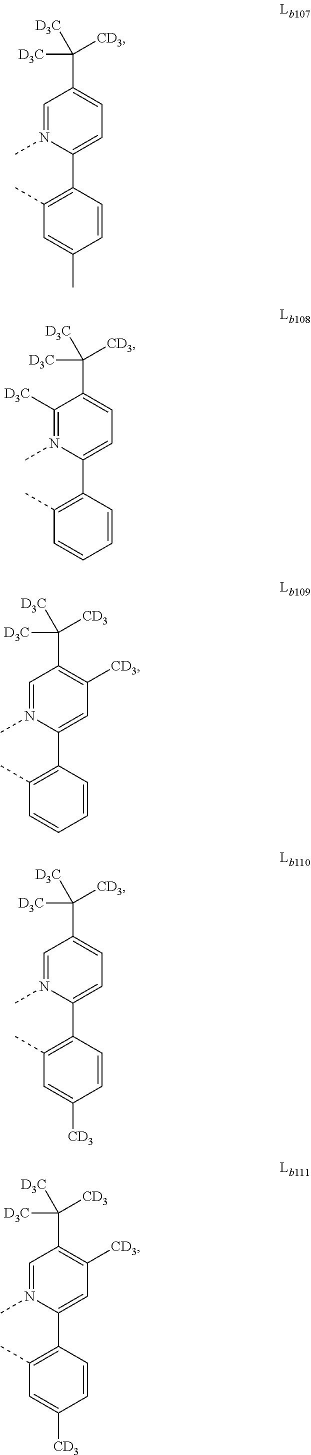 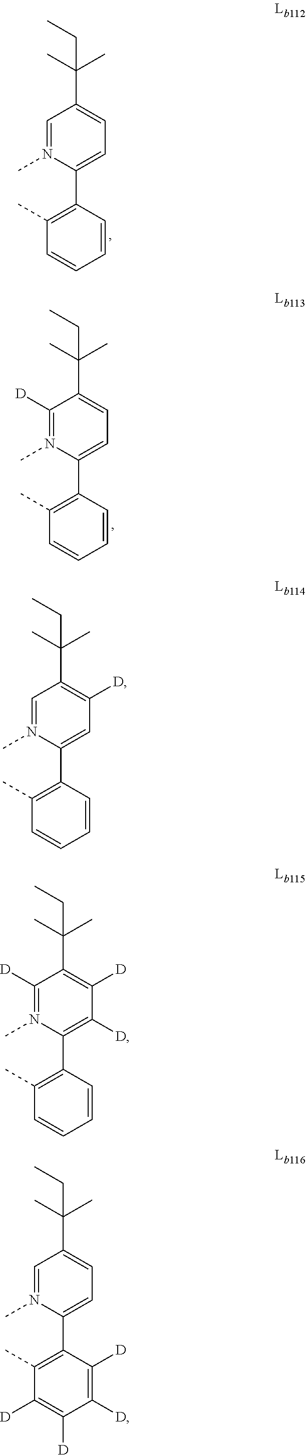 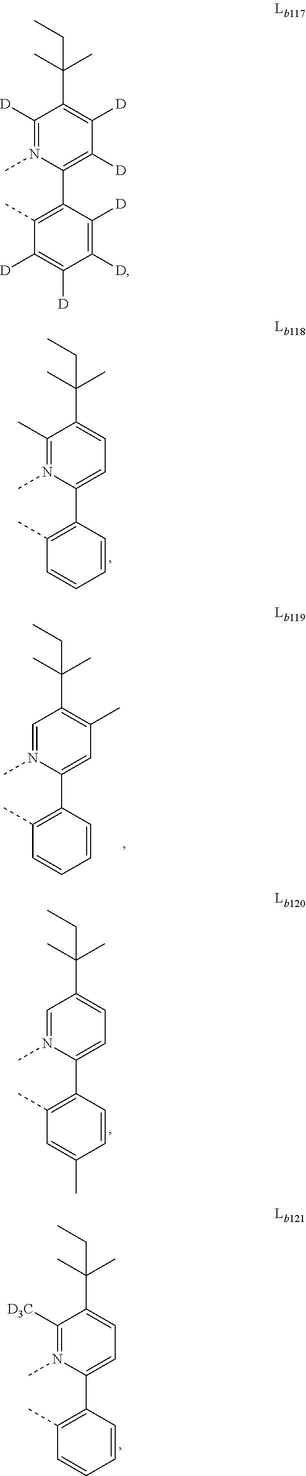 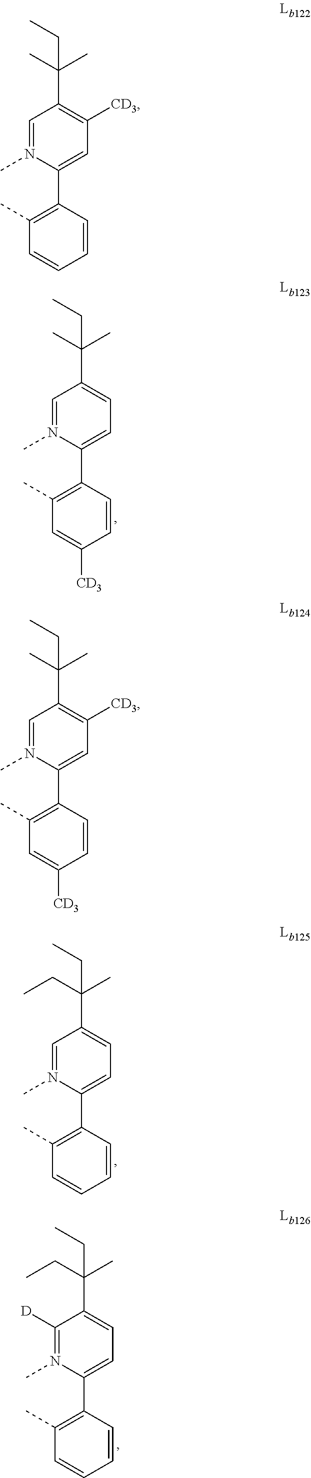 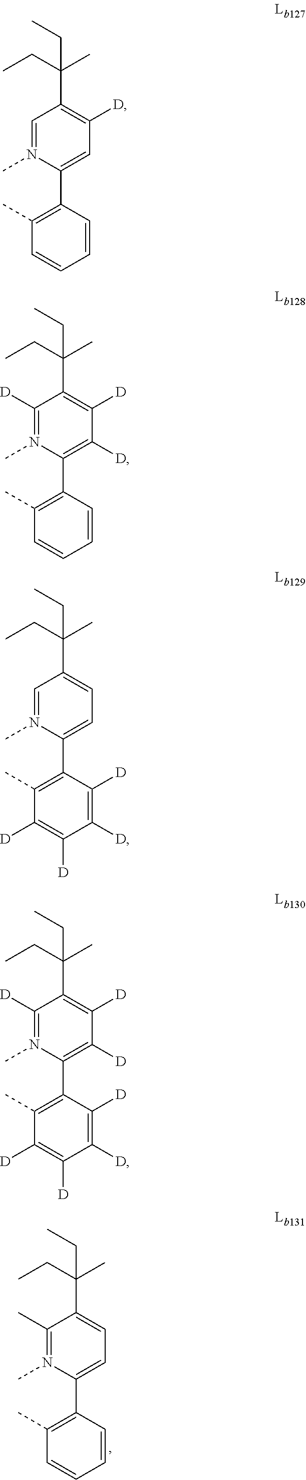 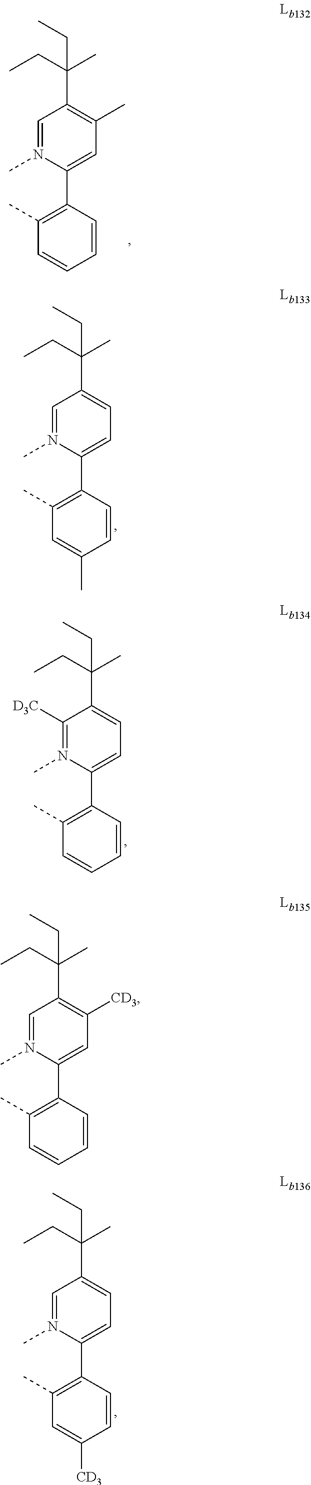 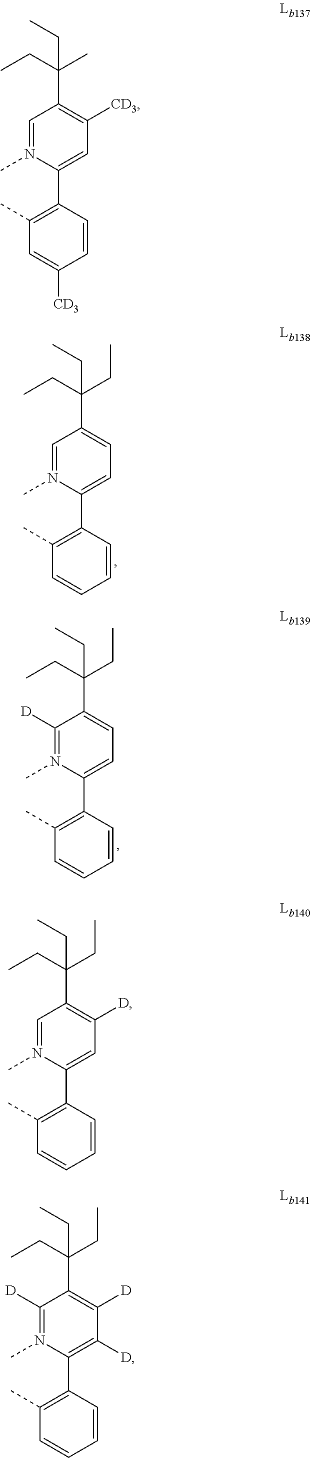 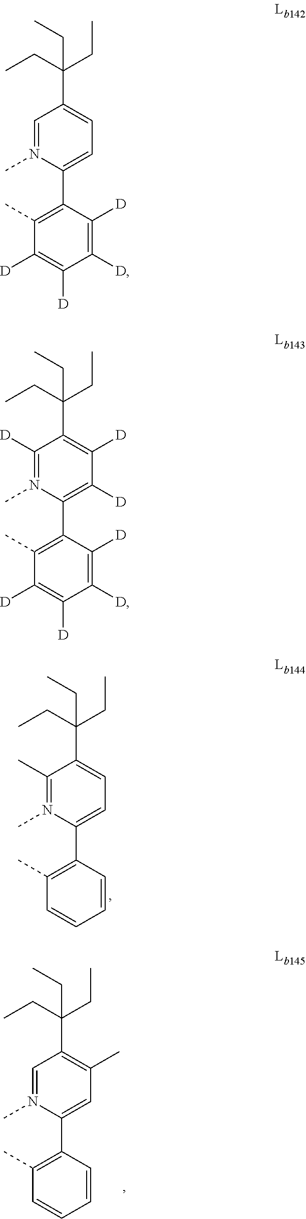 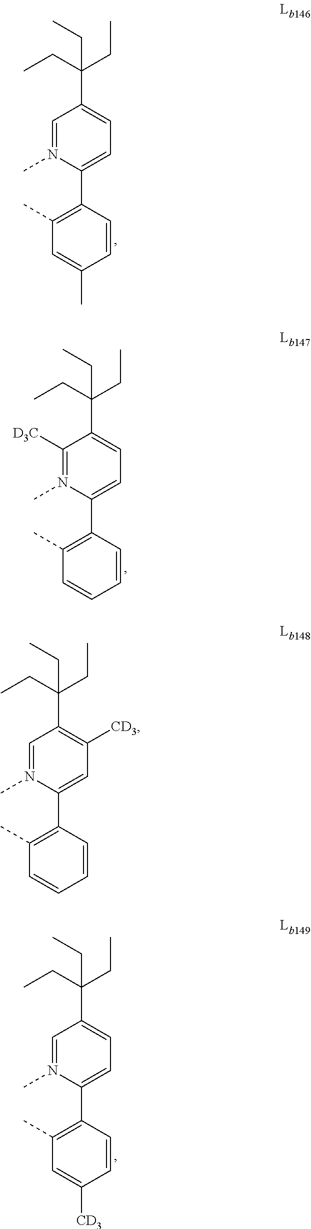 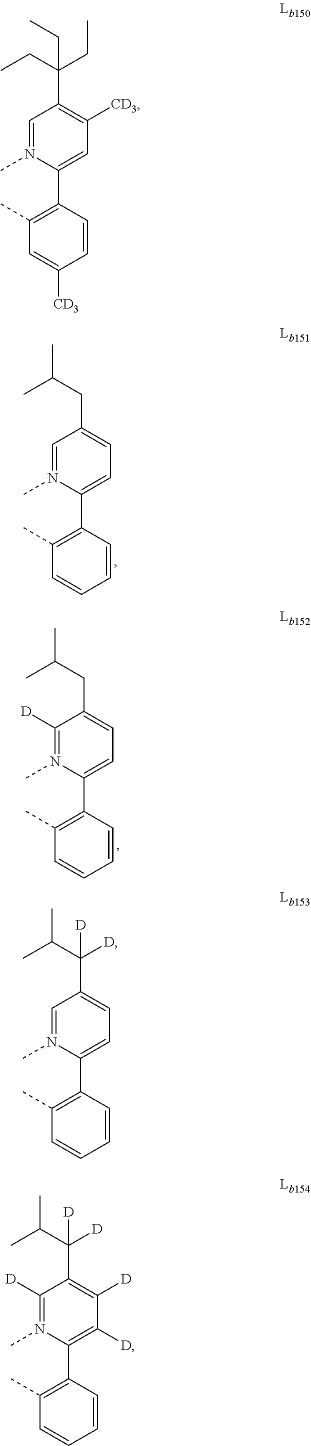 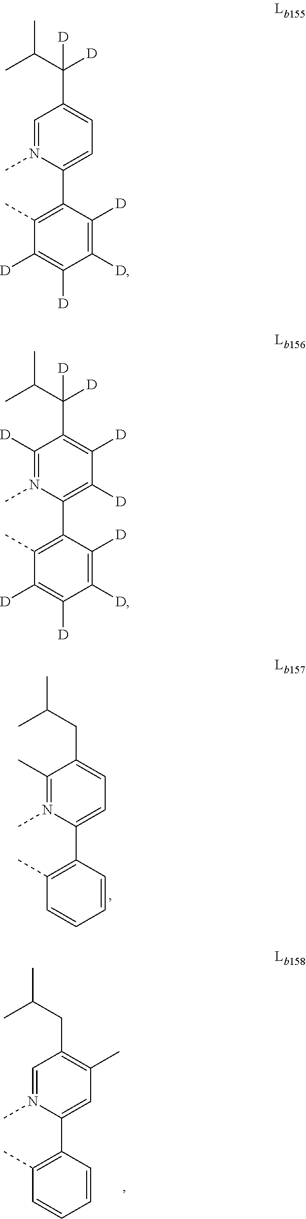 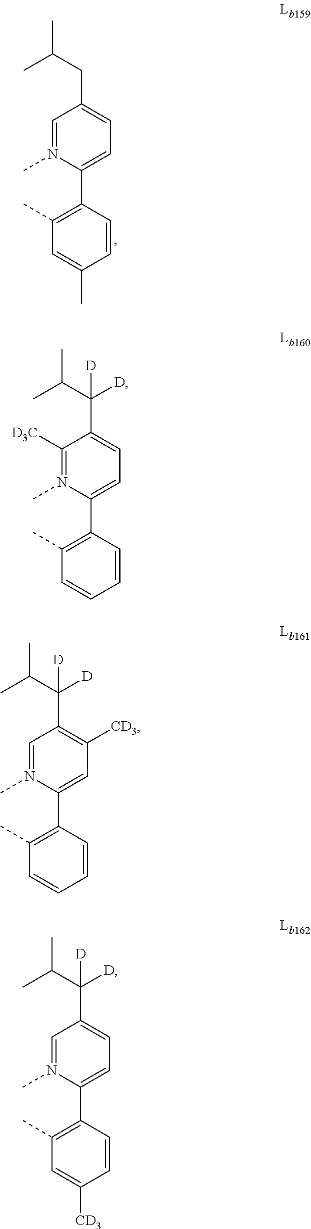 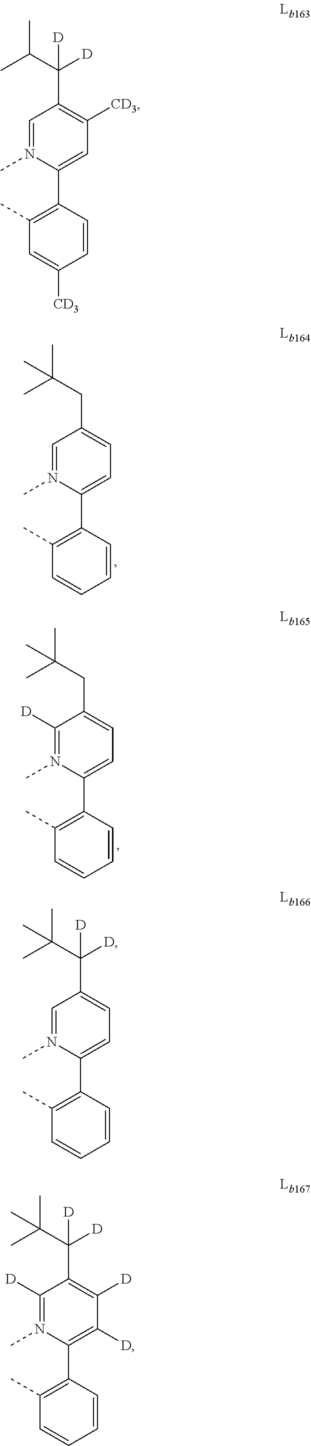 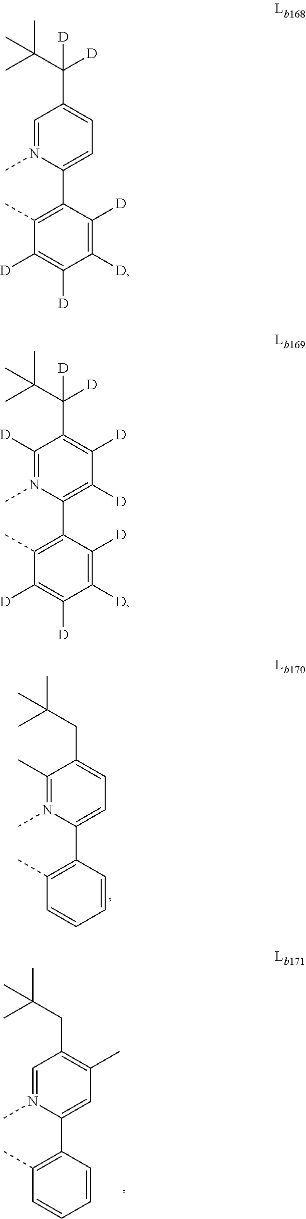 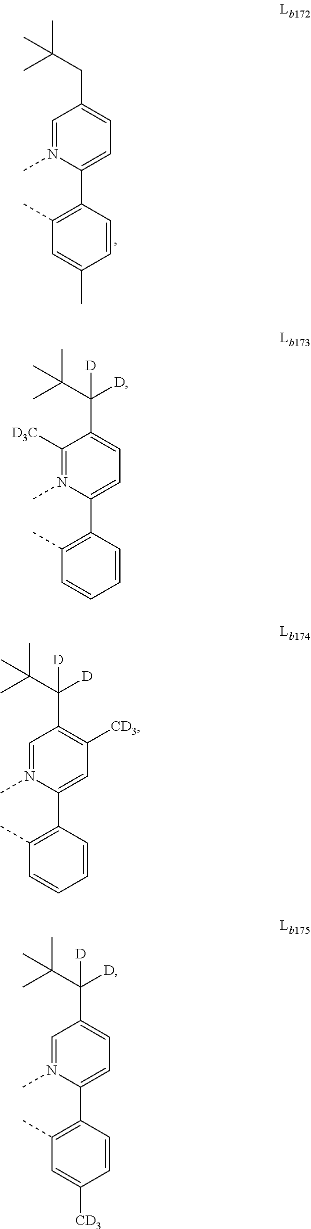 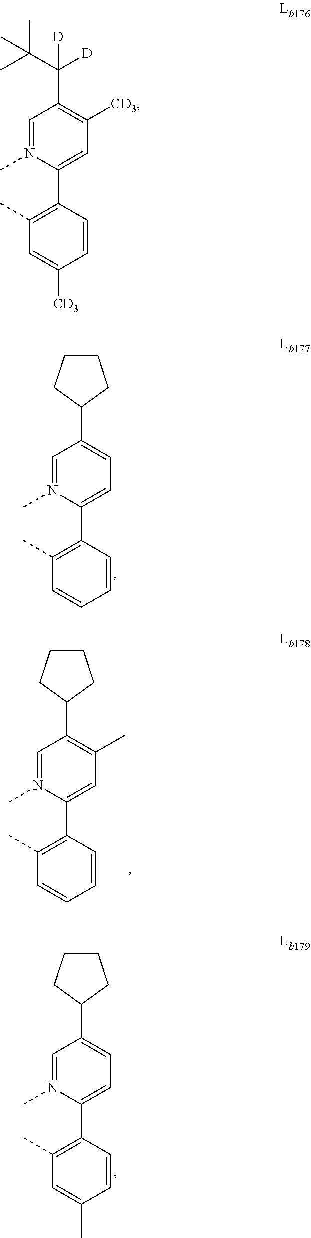 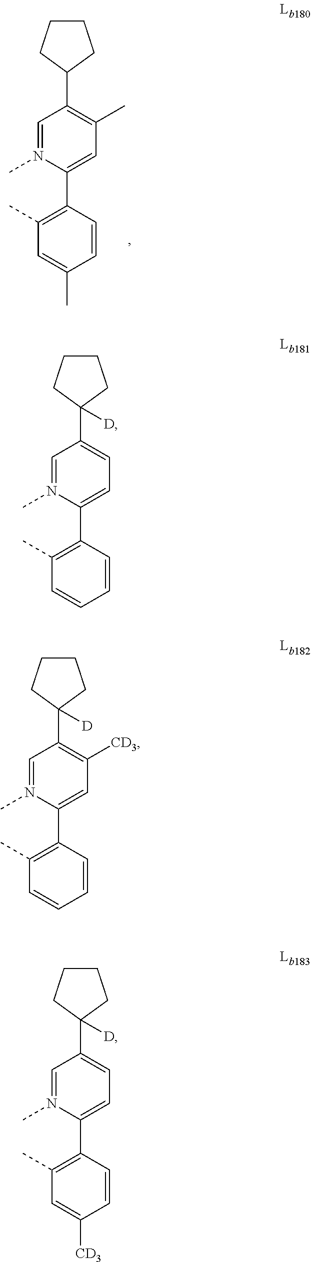 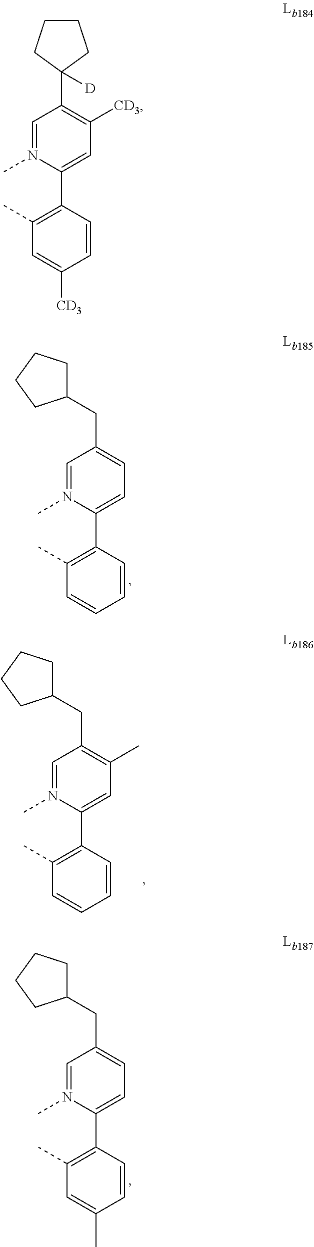 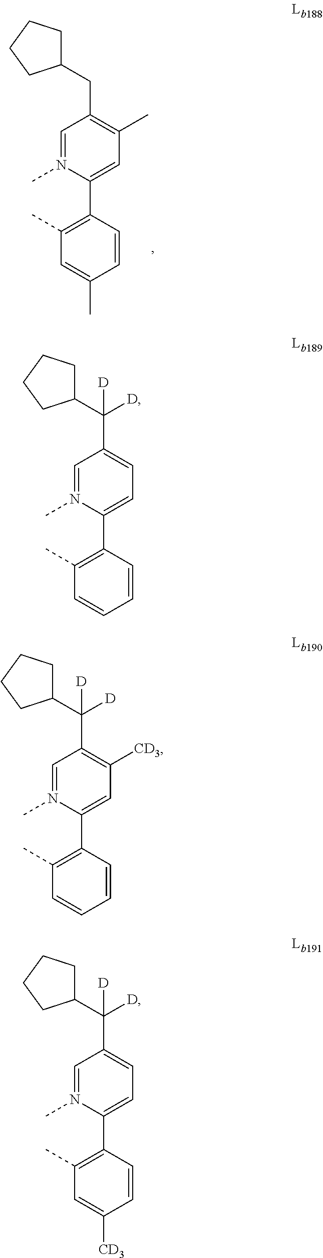 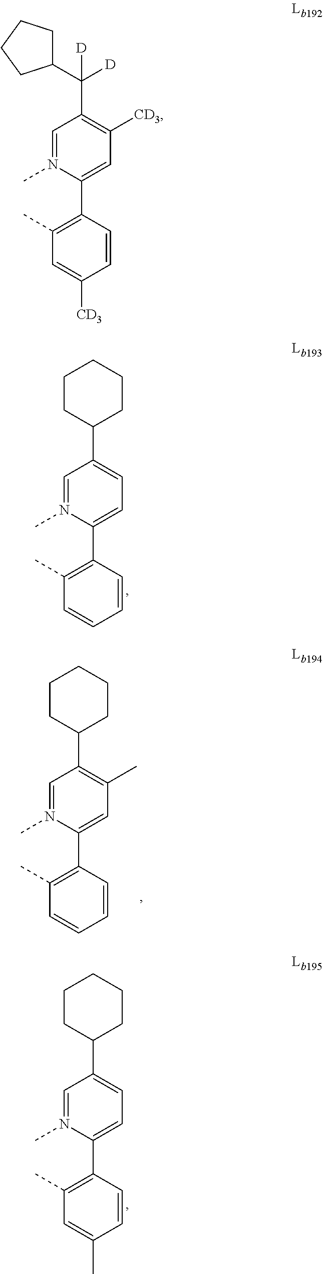 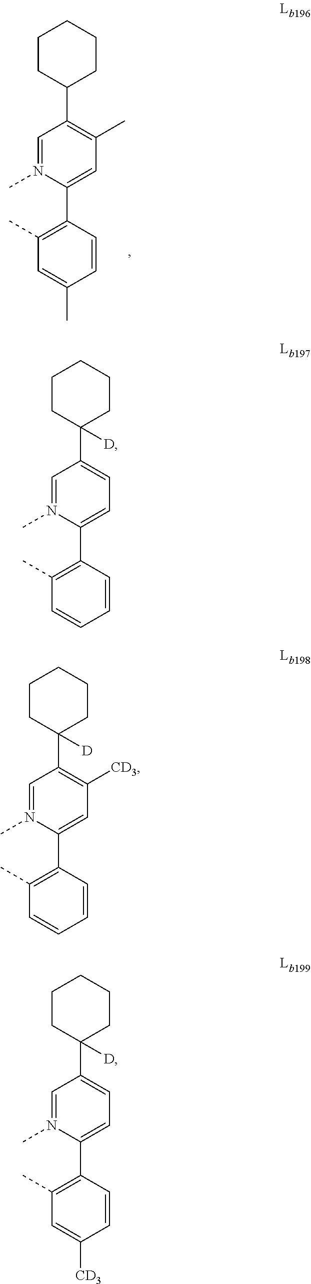 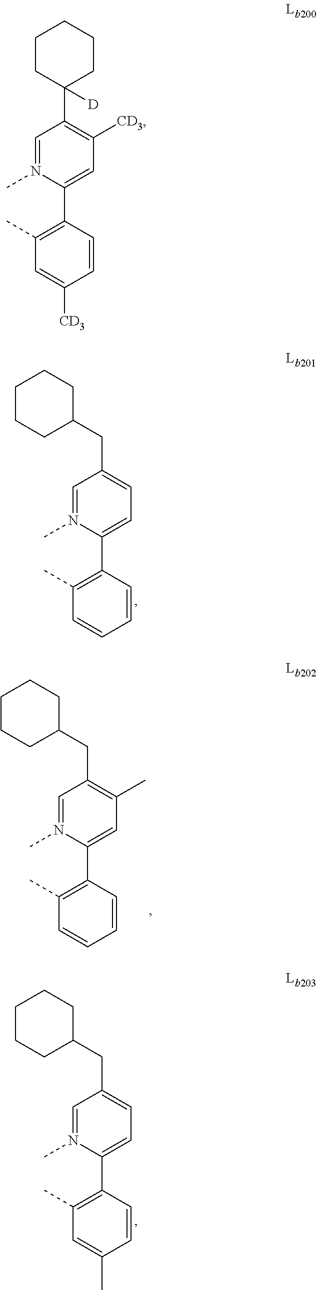 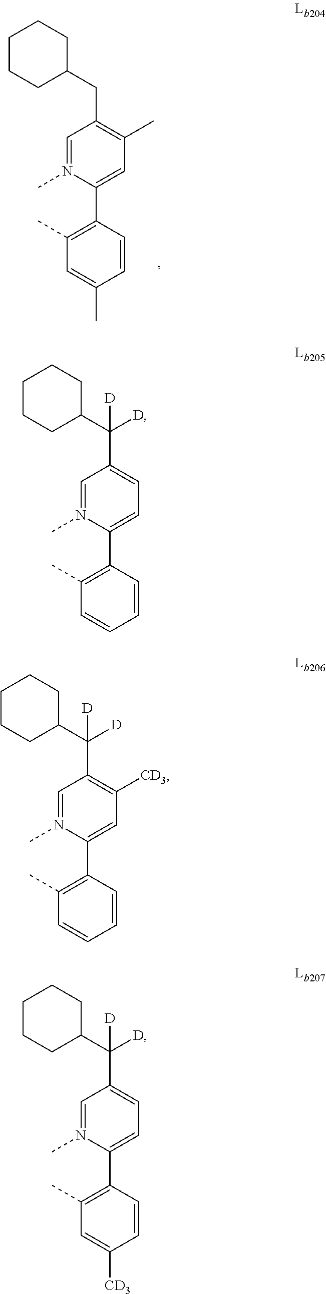 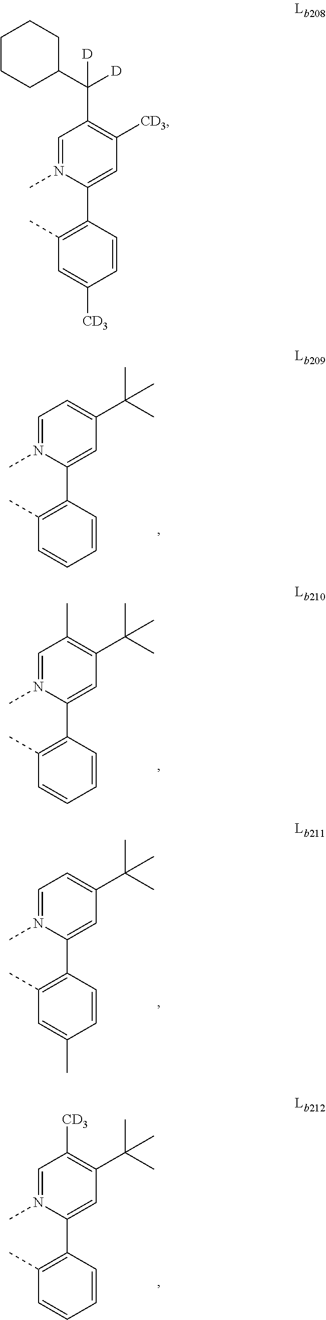 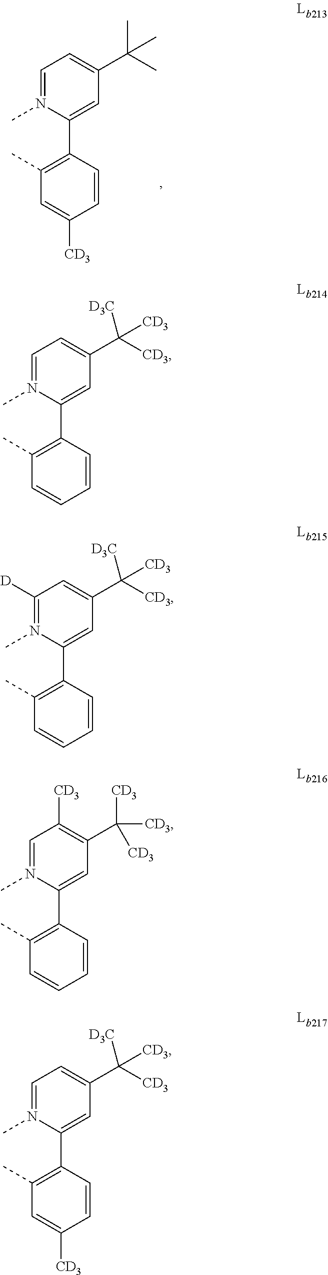 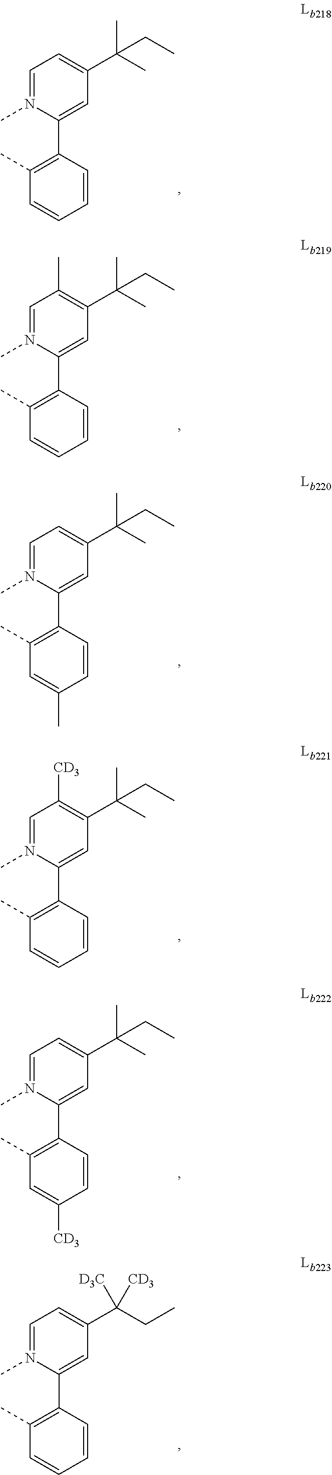 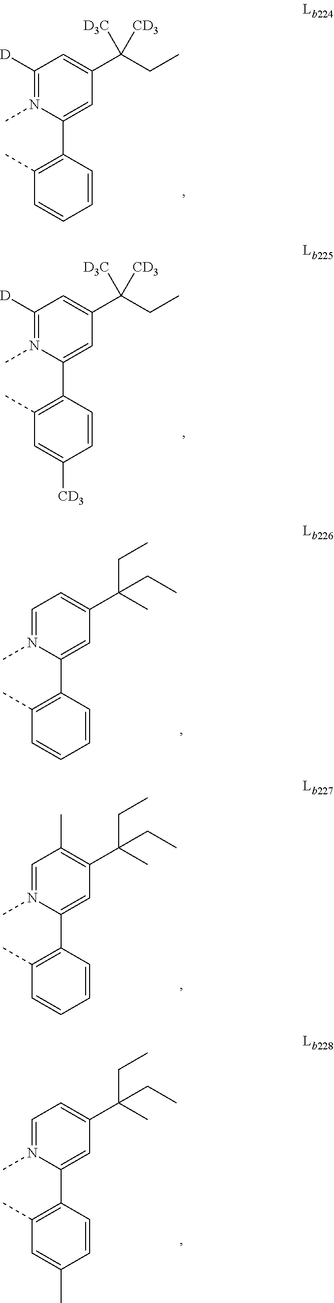 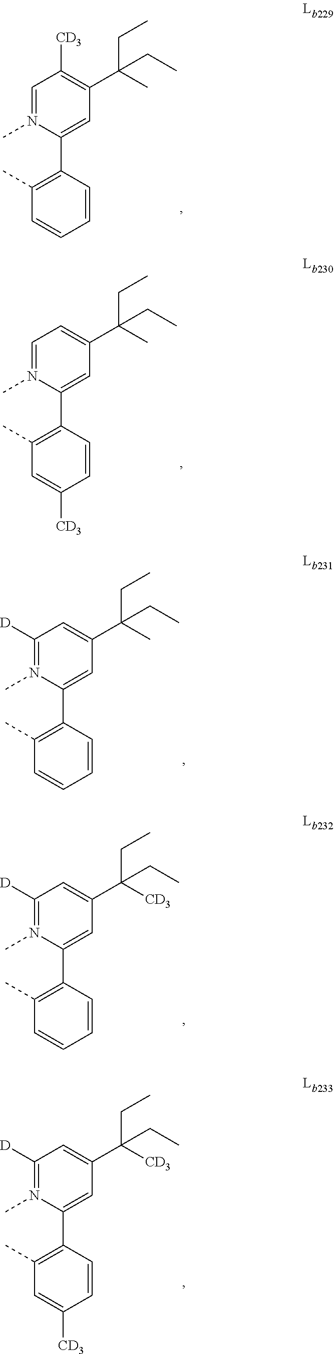 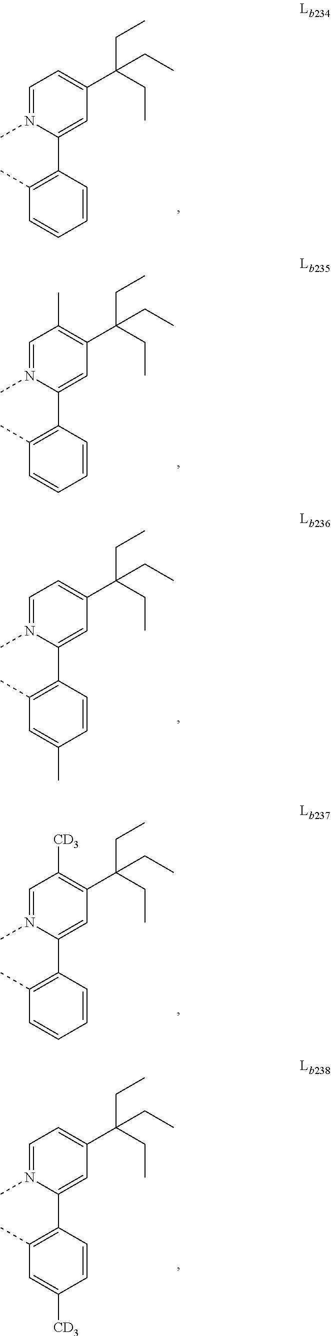 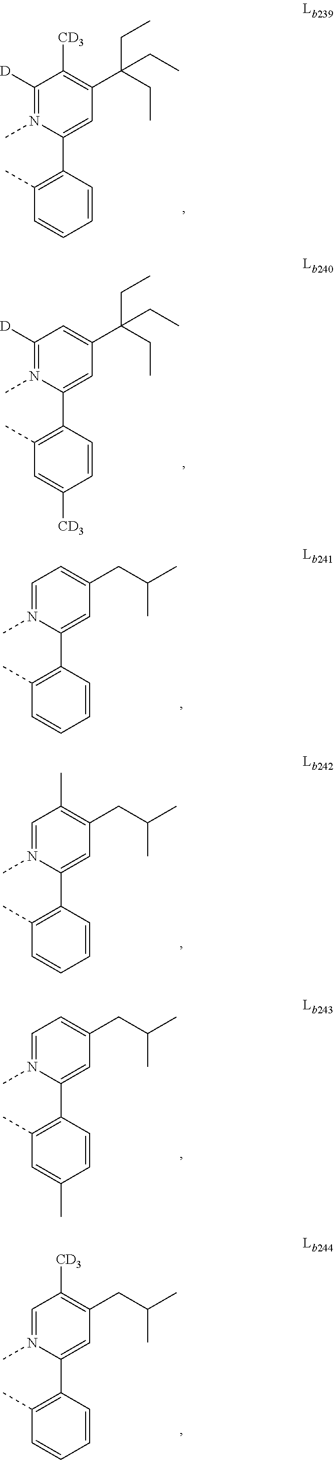 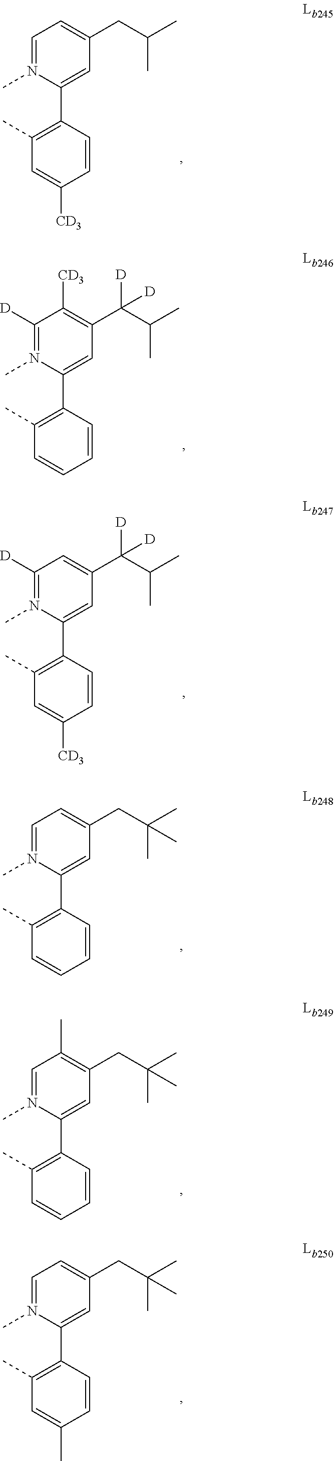 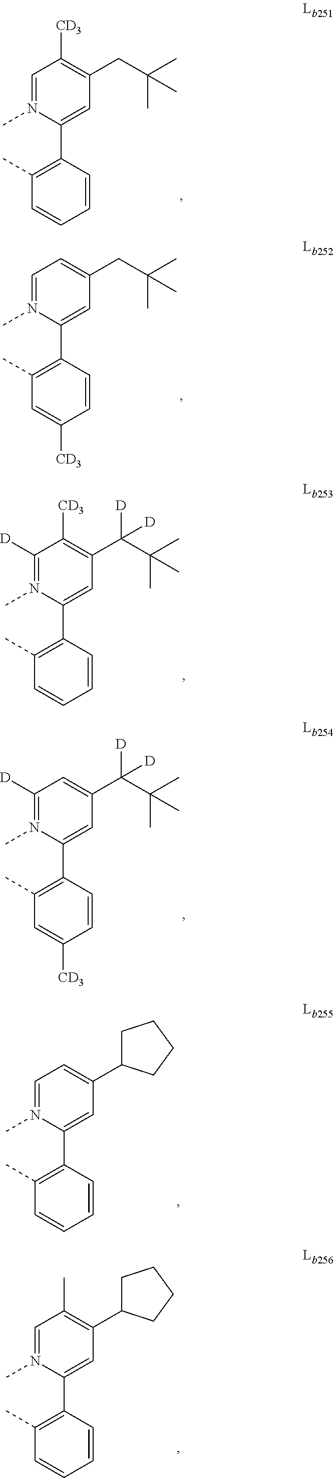 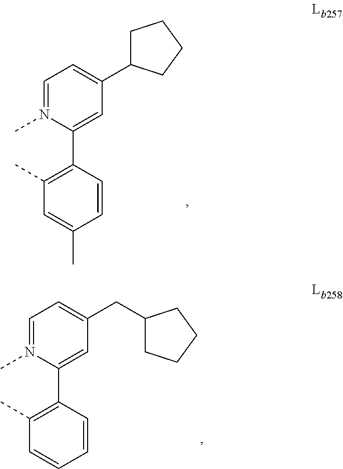 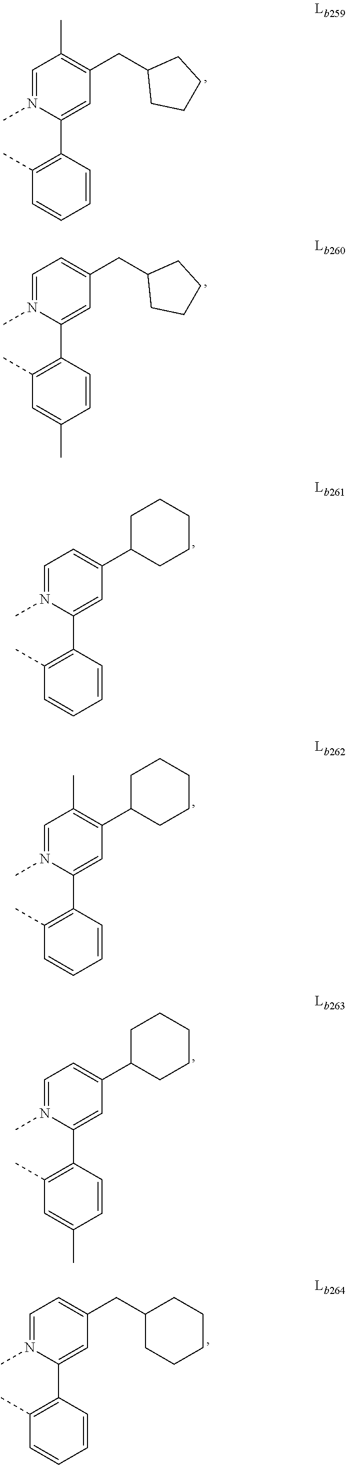 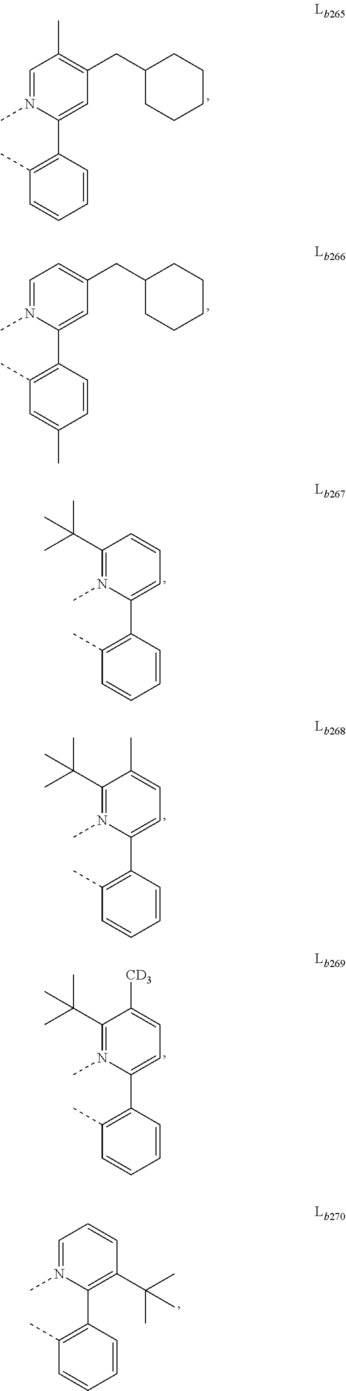 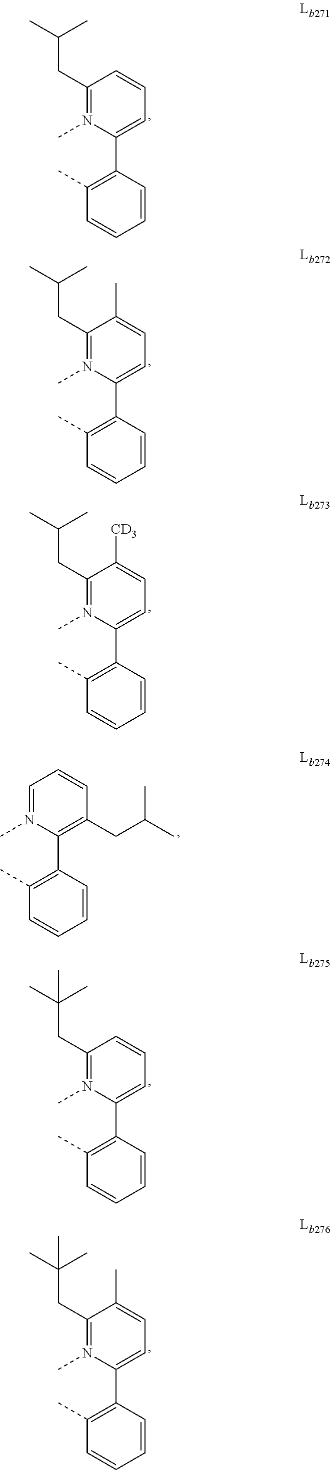 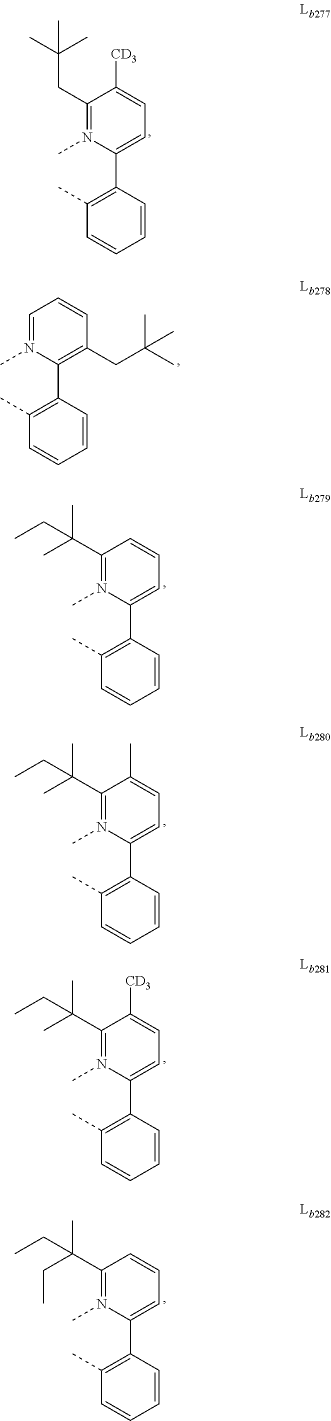 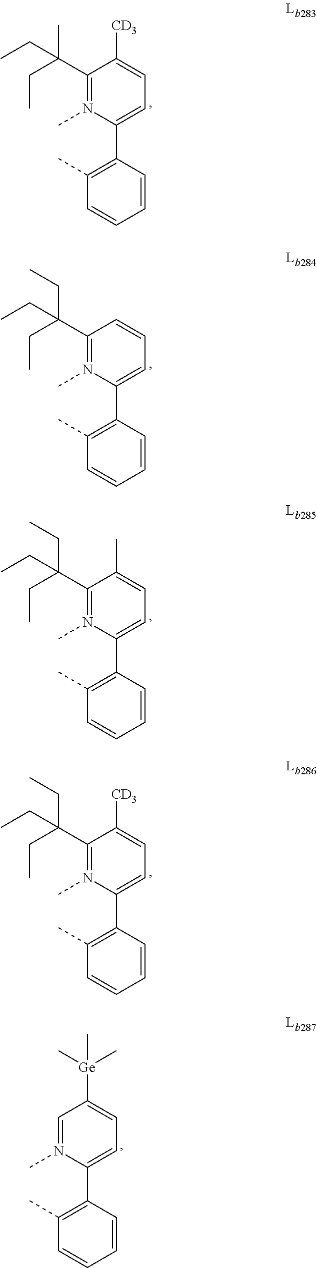 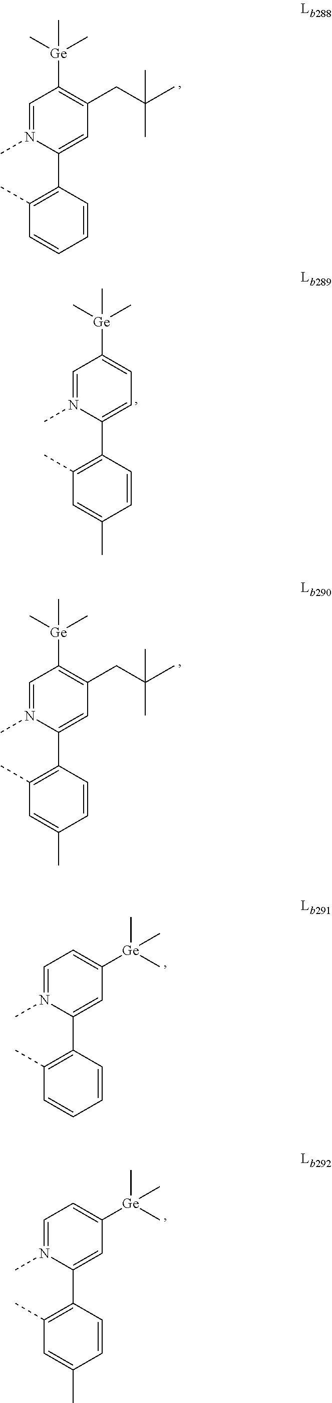 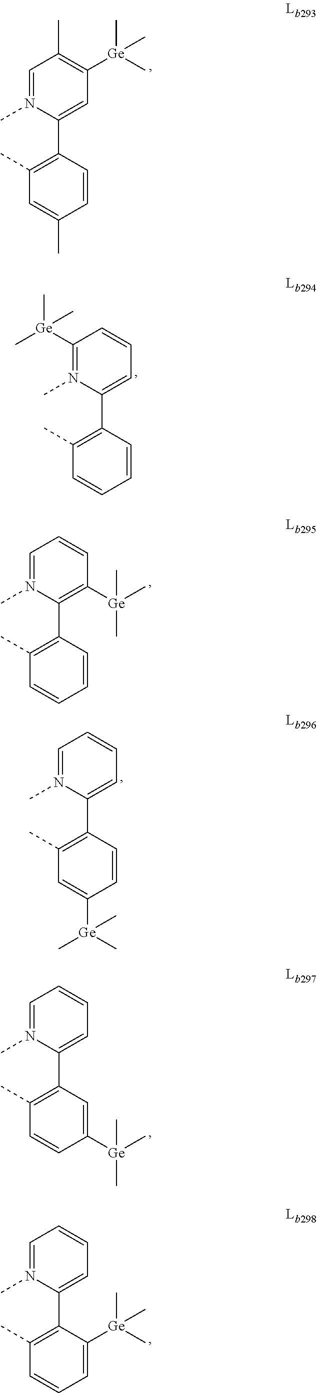 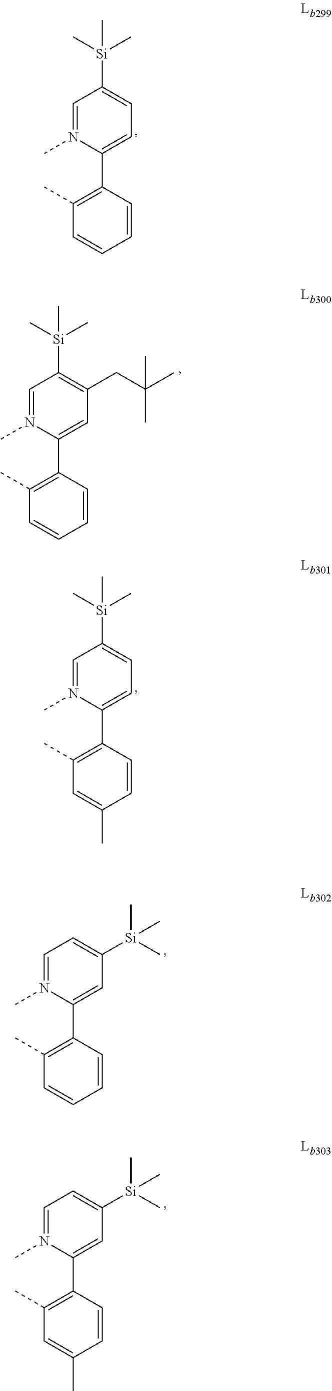 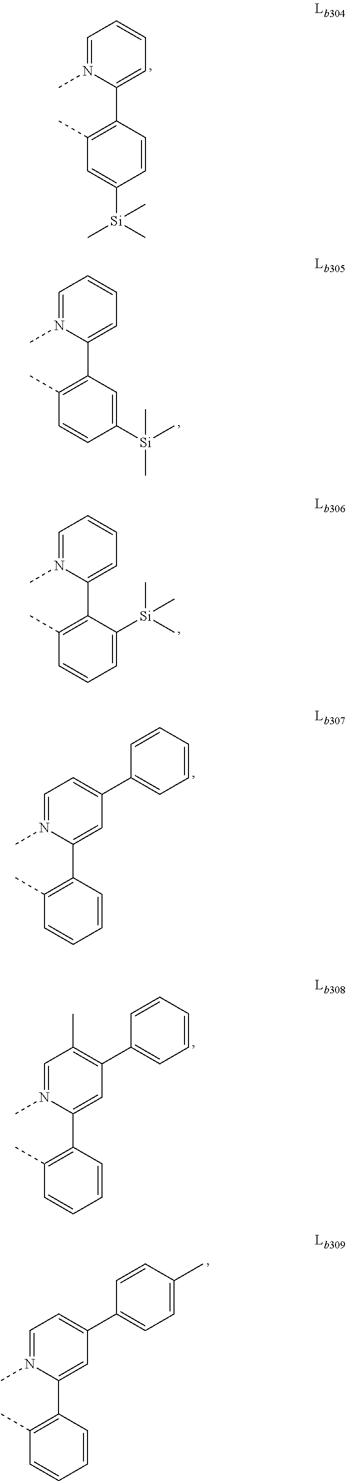 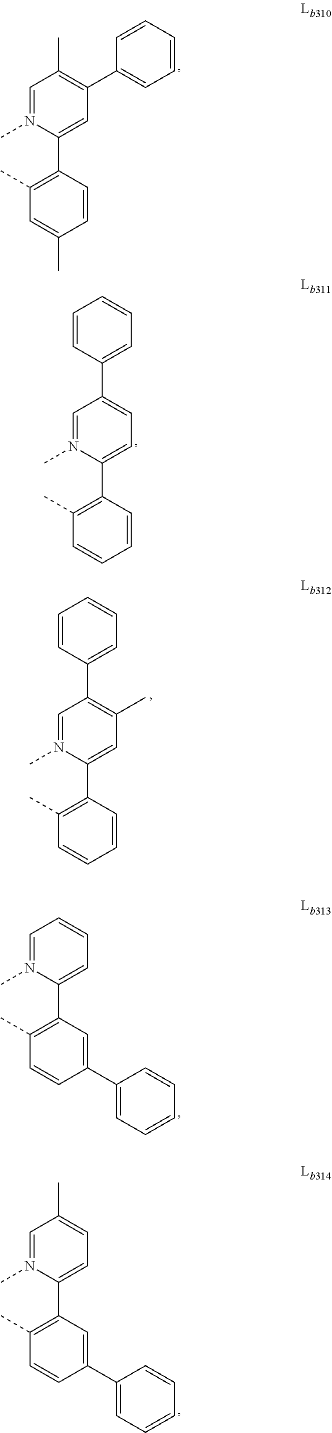 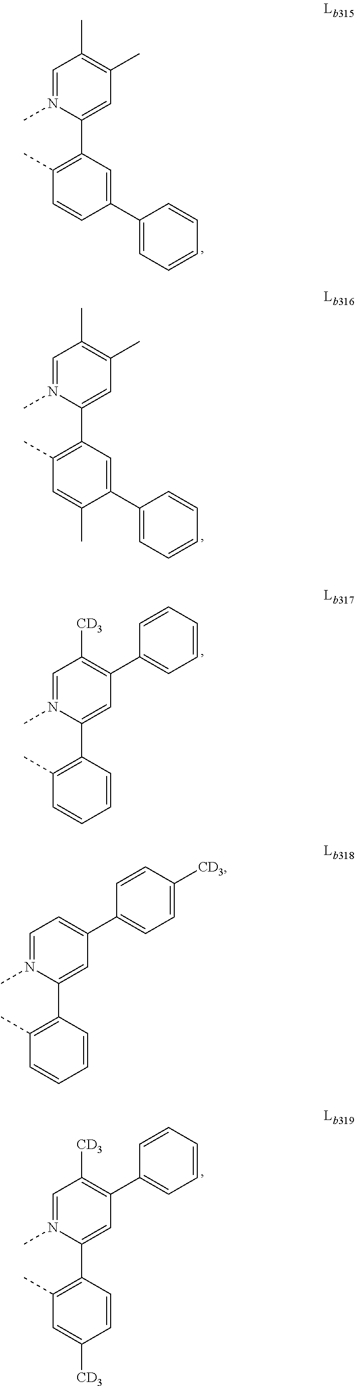 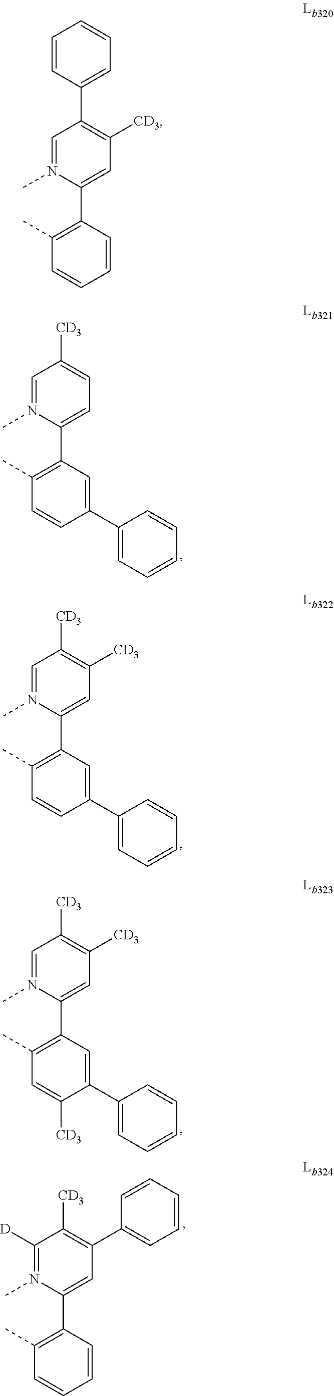 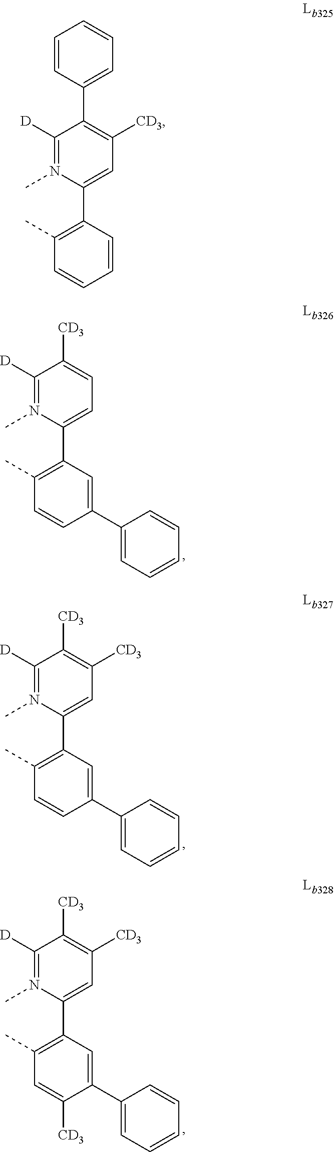 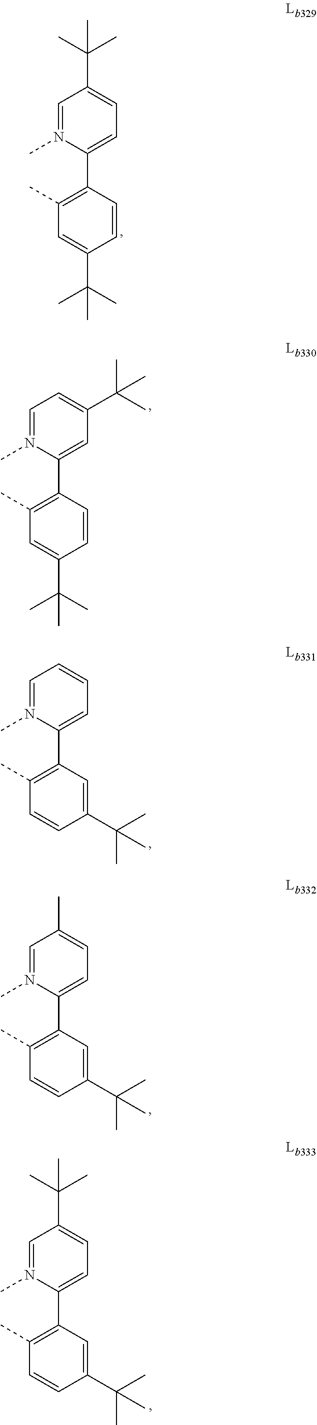 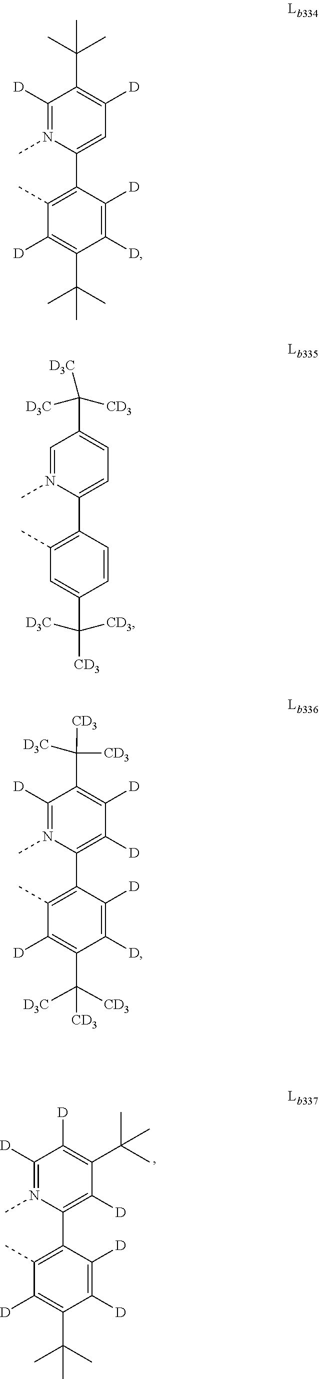 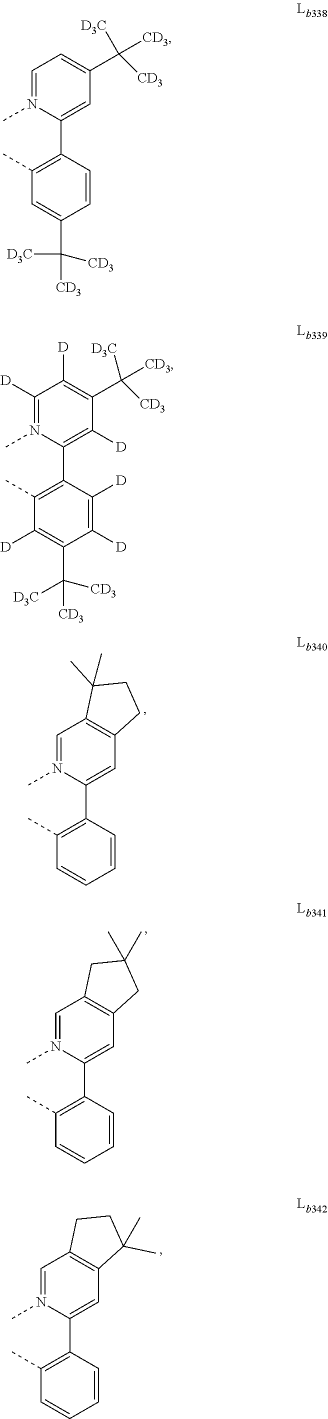 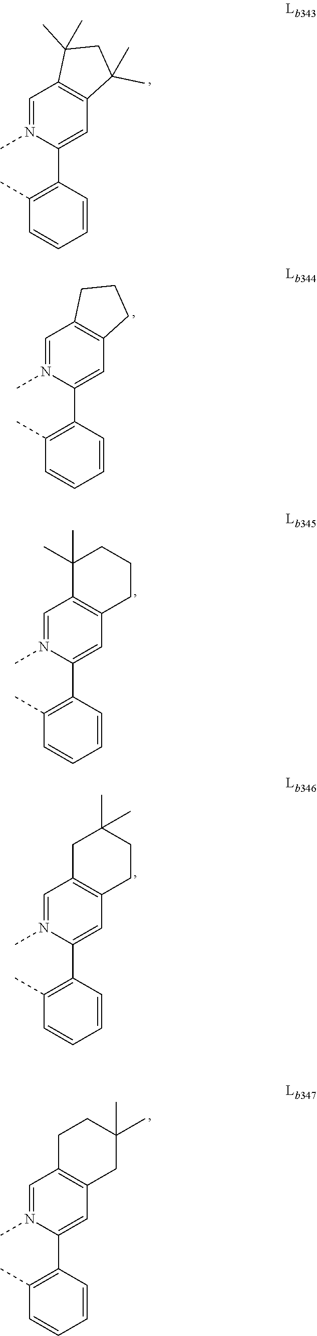 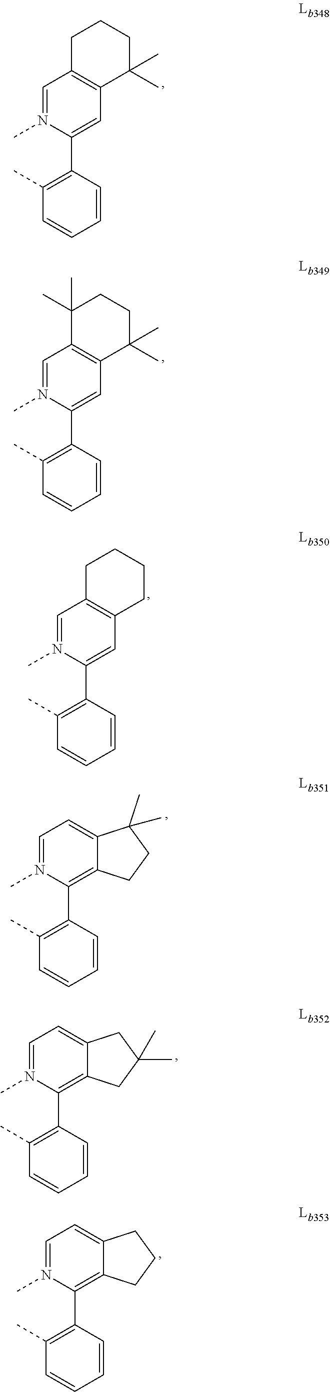 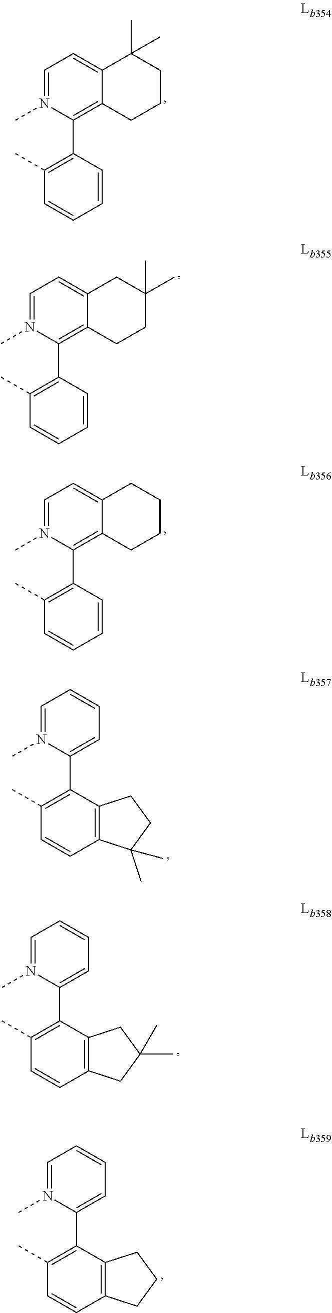 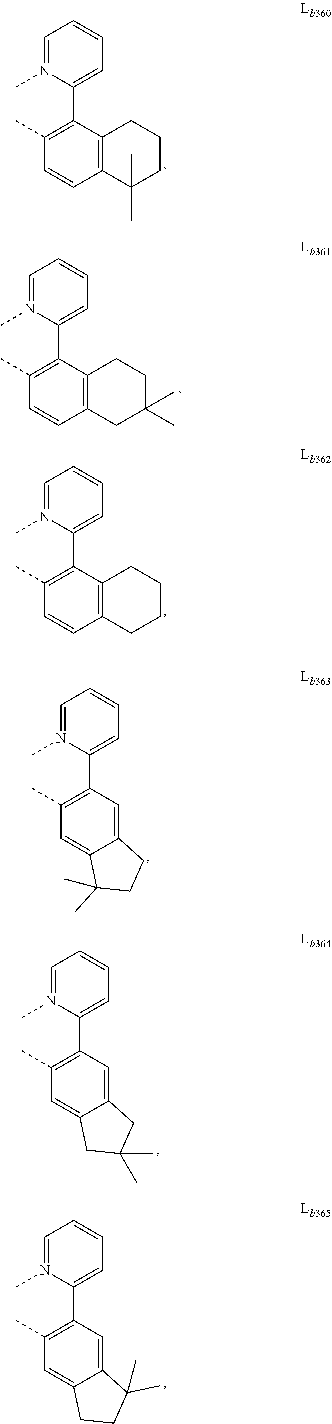 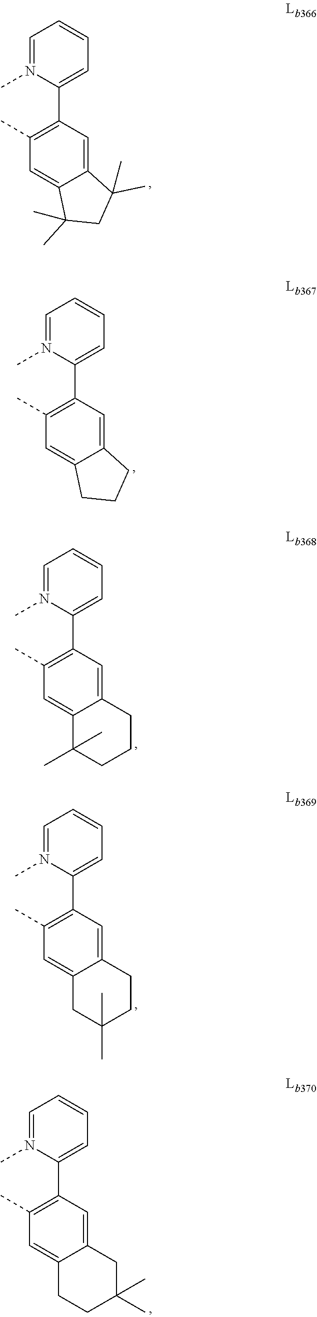 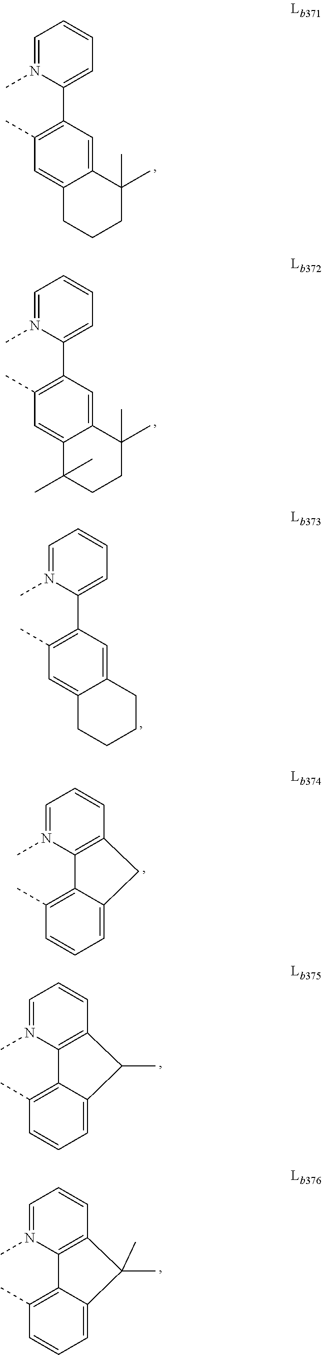 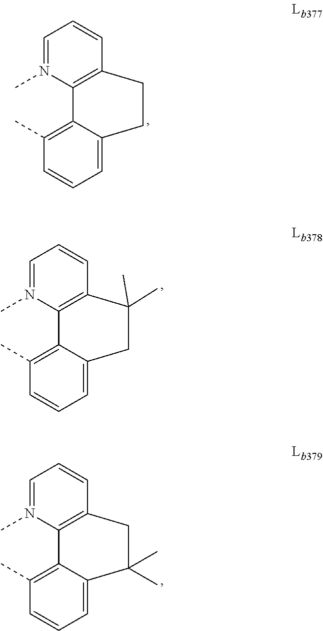
wherein optionally, hydrogen atoms in L_{b1} to L_{b379} can be partially or fully substituted with deuterium.

14. The metal complex according to claim 1, wherein L_{c} is, at each occurrence identically or differently, selected from the group consisting of the following structures: 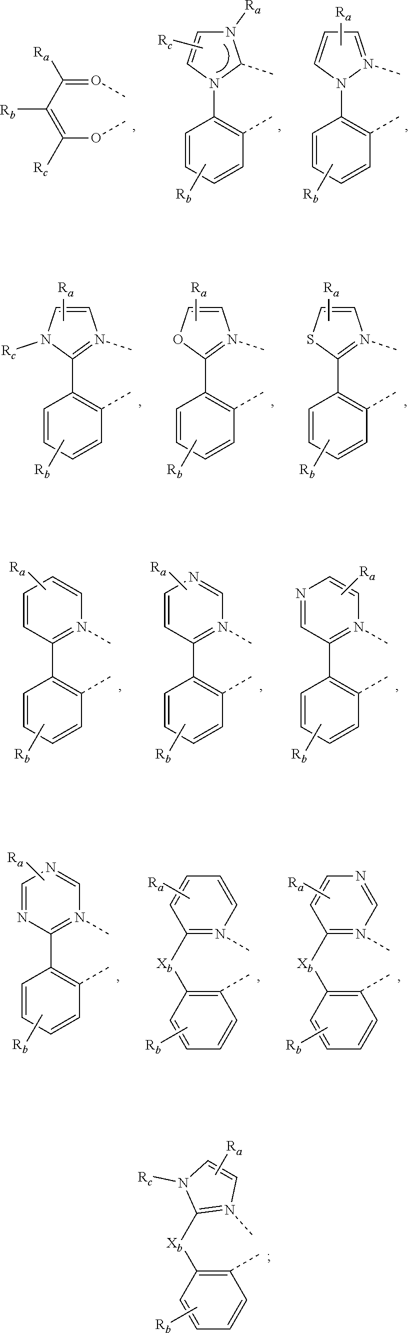
wherein Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ, R_{b}, R_{c}, R_{N1}, R_{C1}, and R_{C2} can be optionally joined to form a ring;
preferably, L_{c} is, at each occurrence identically or differently, selected from the group consisting of the following structures: 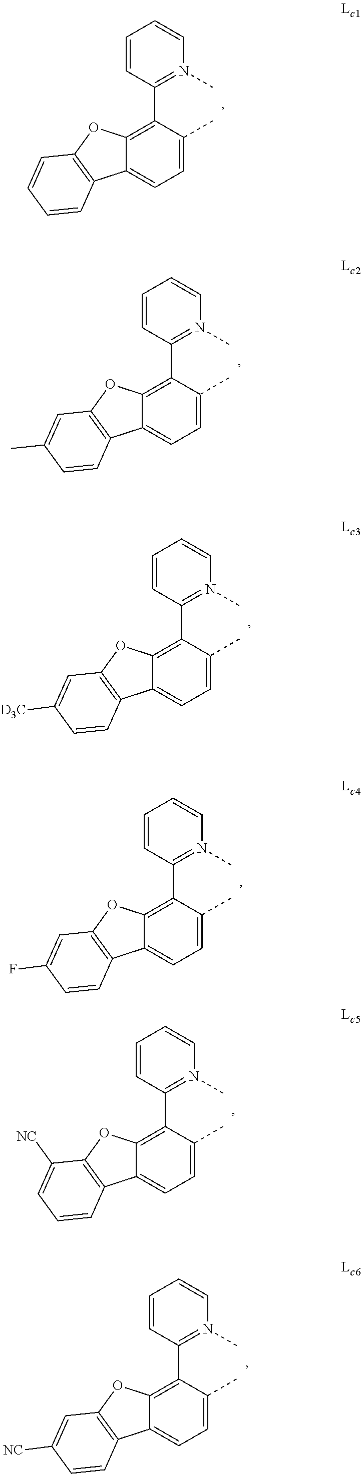 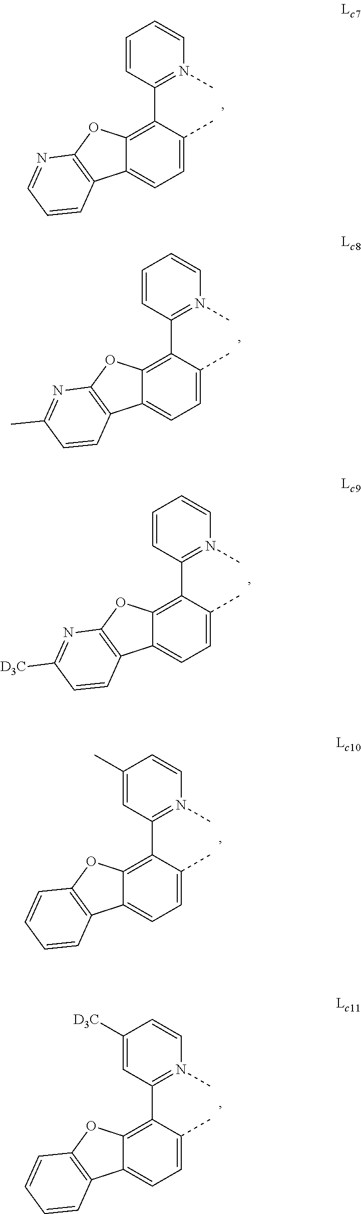 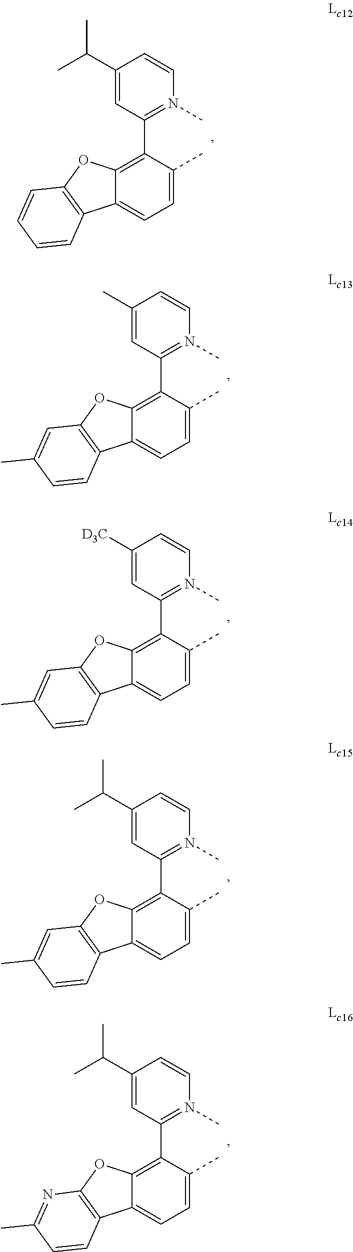 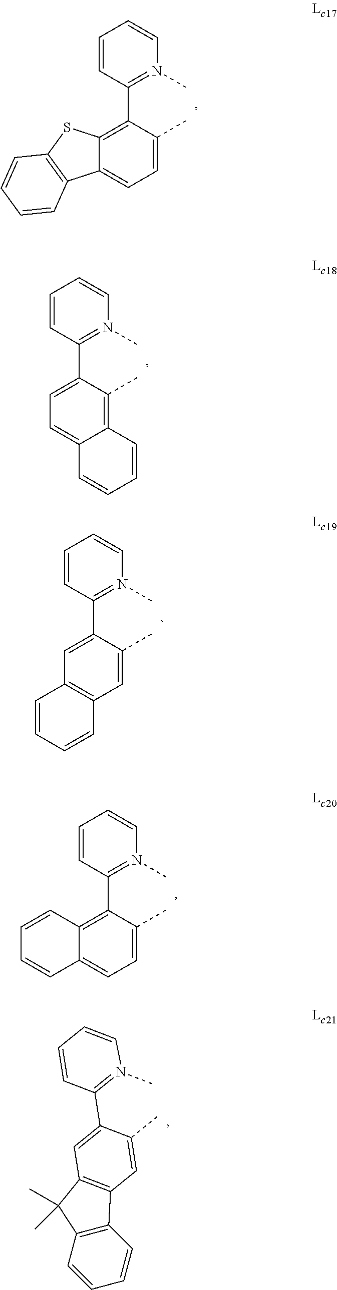 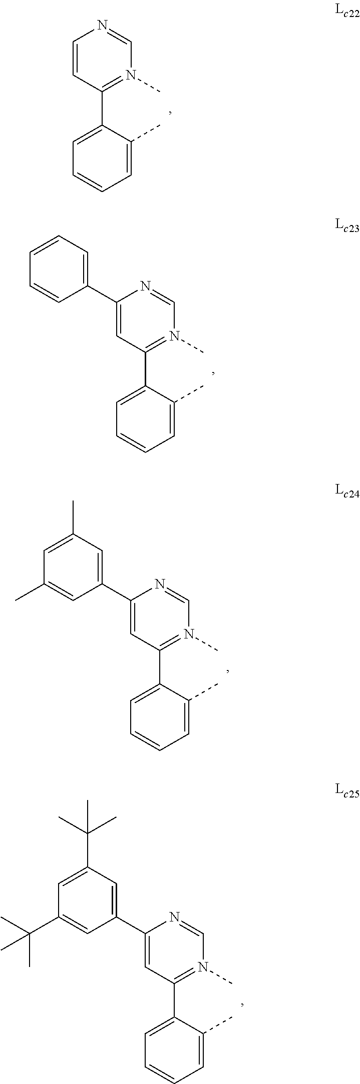 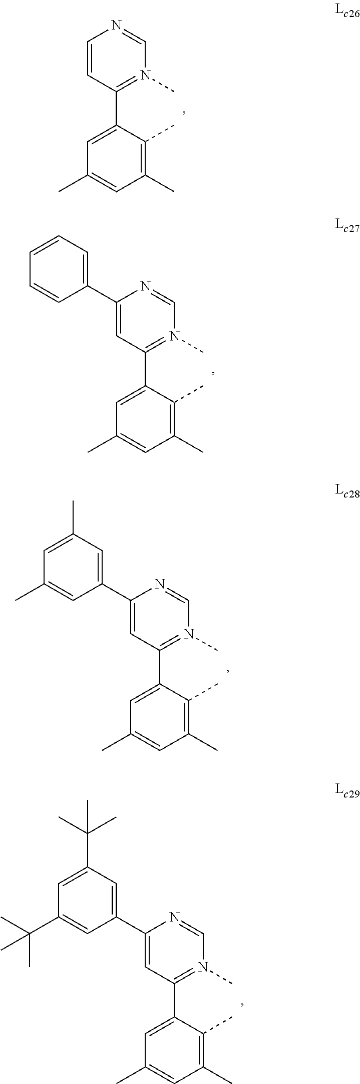 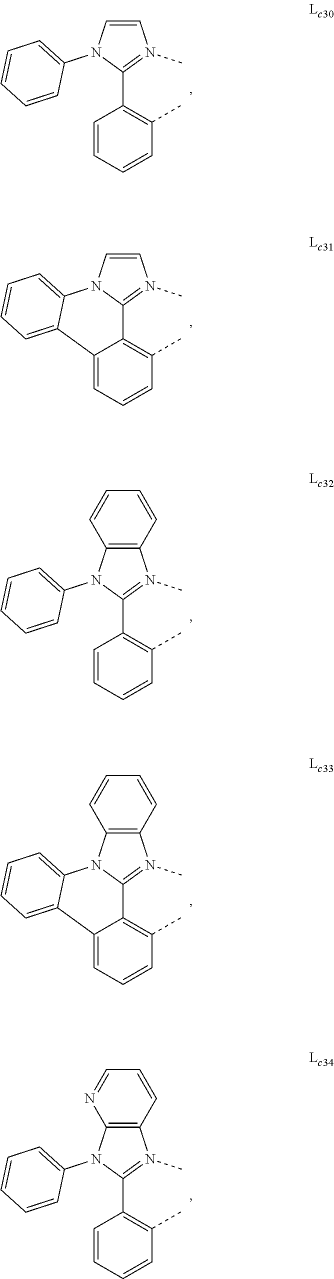 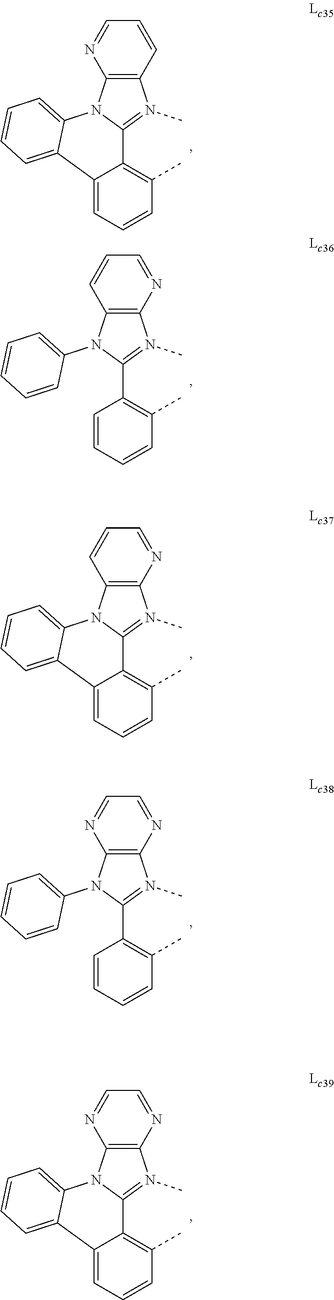 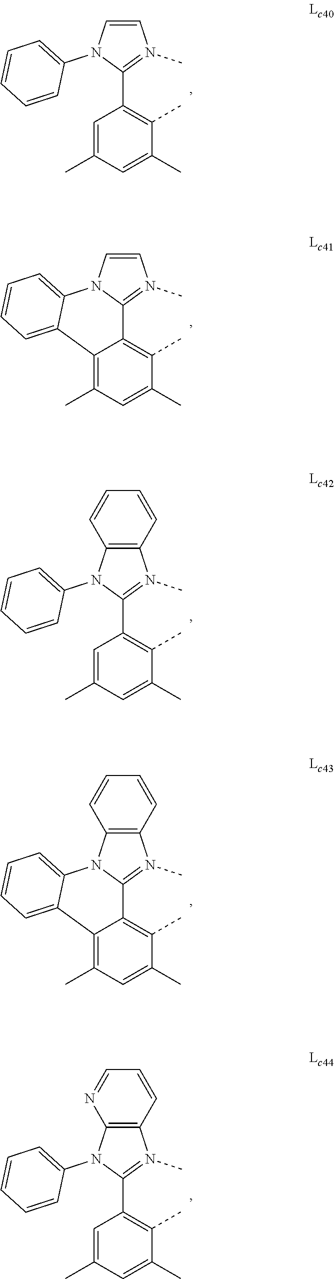 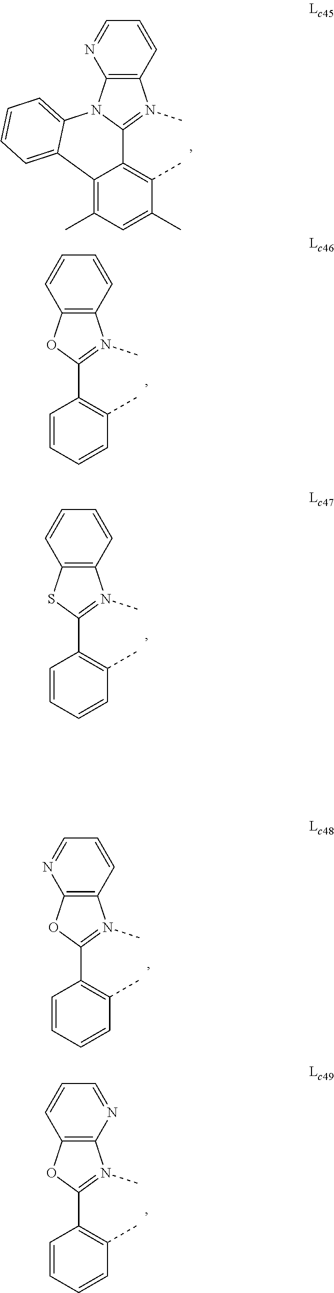 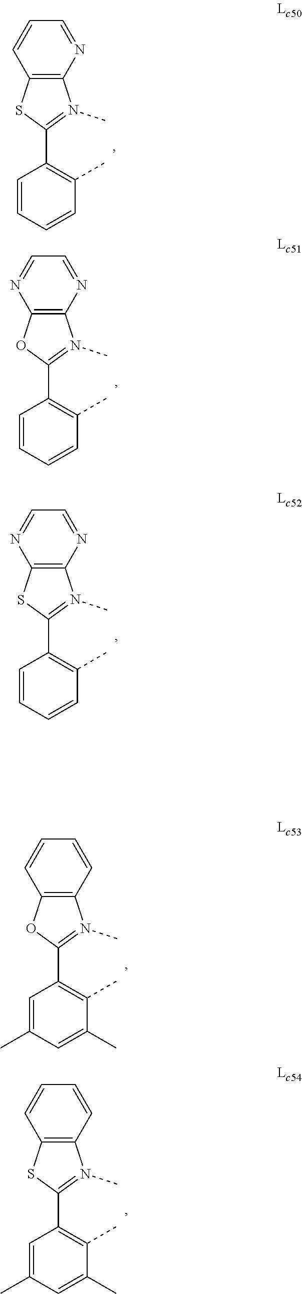 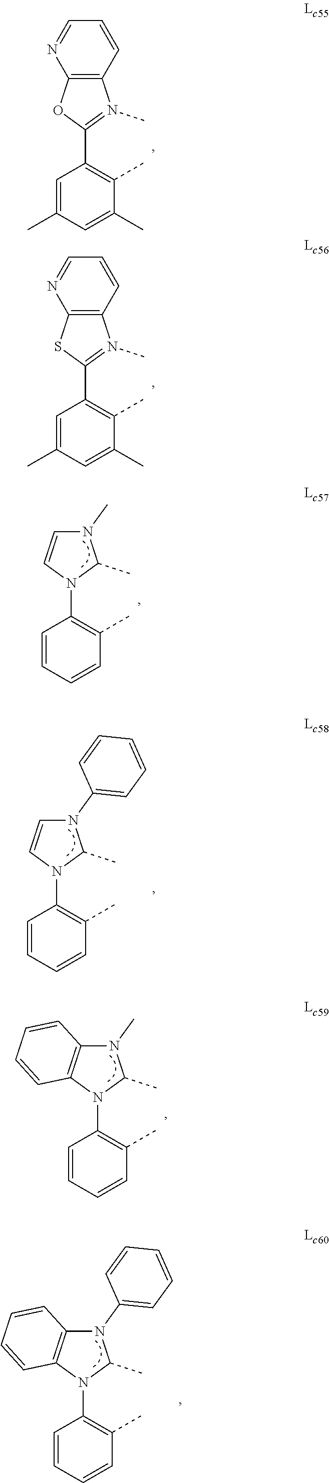 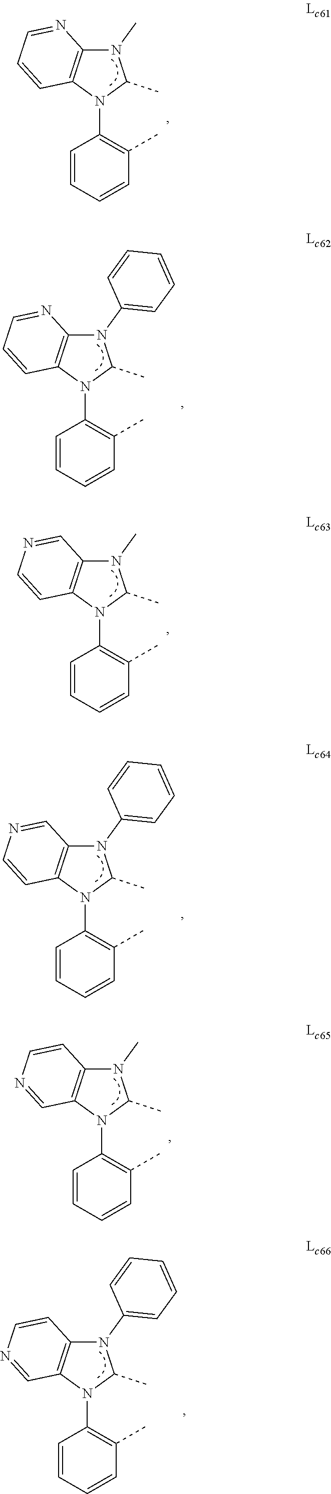 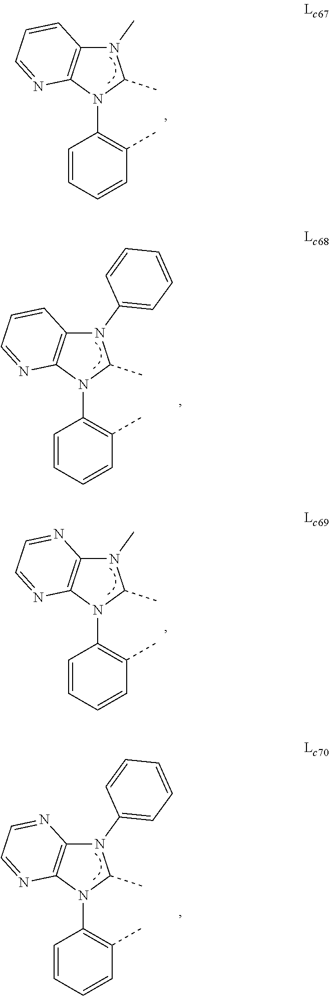 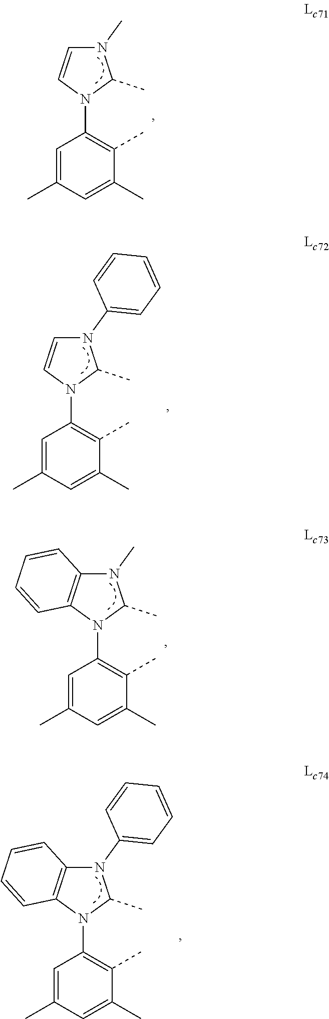 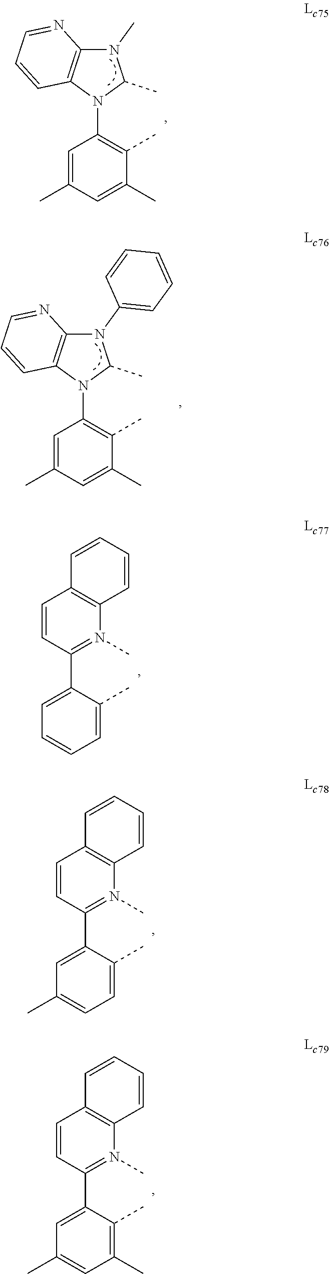 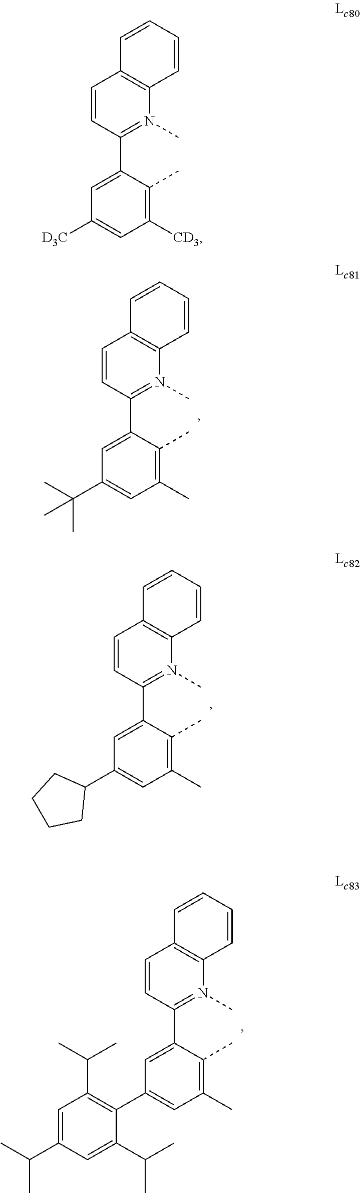 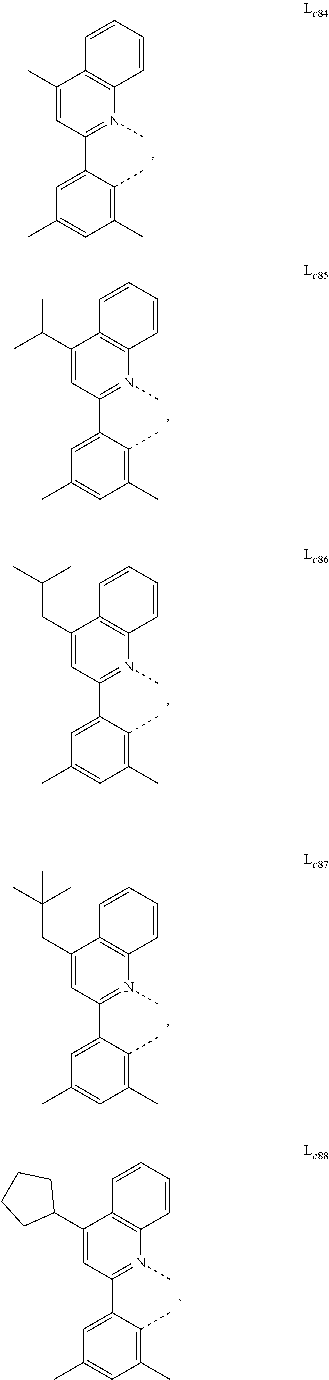 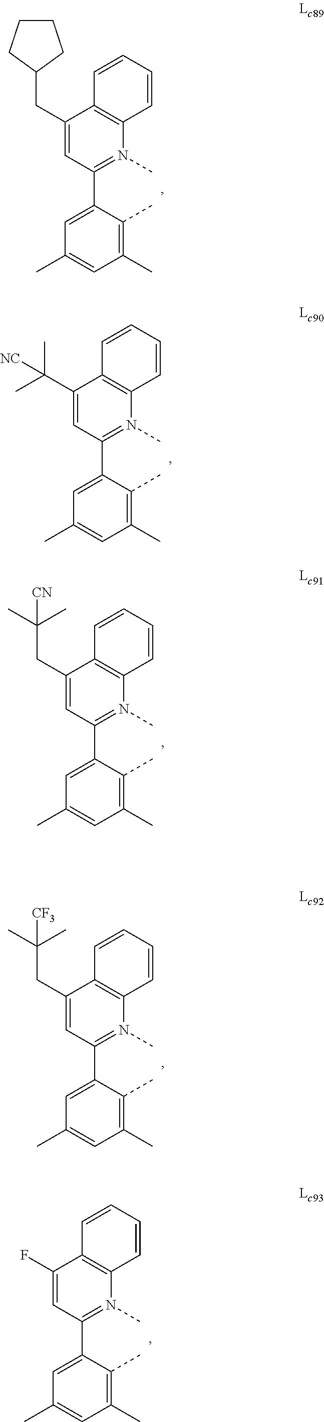 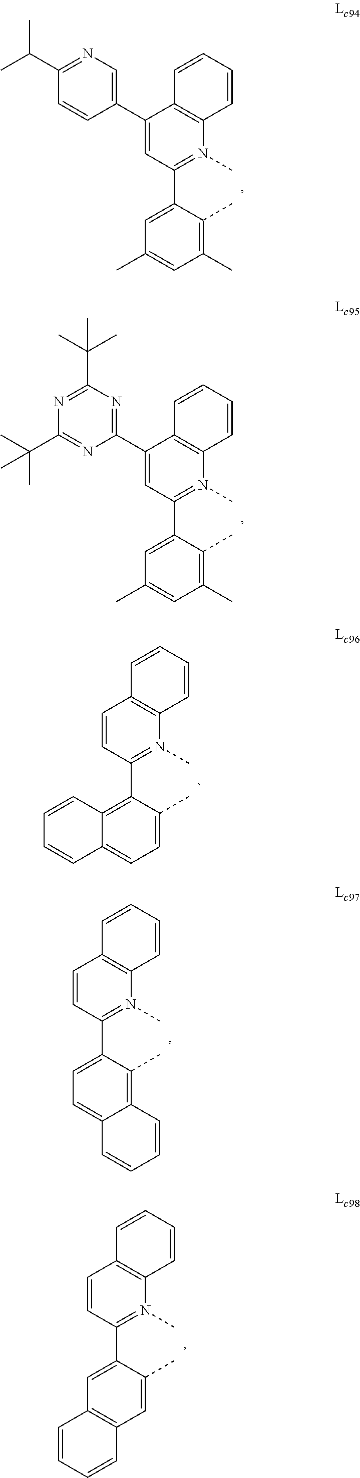 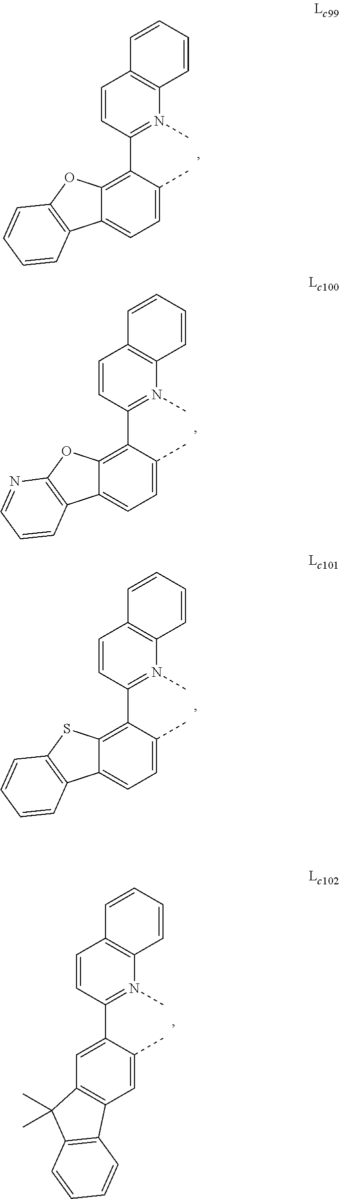 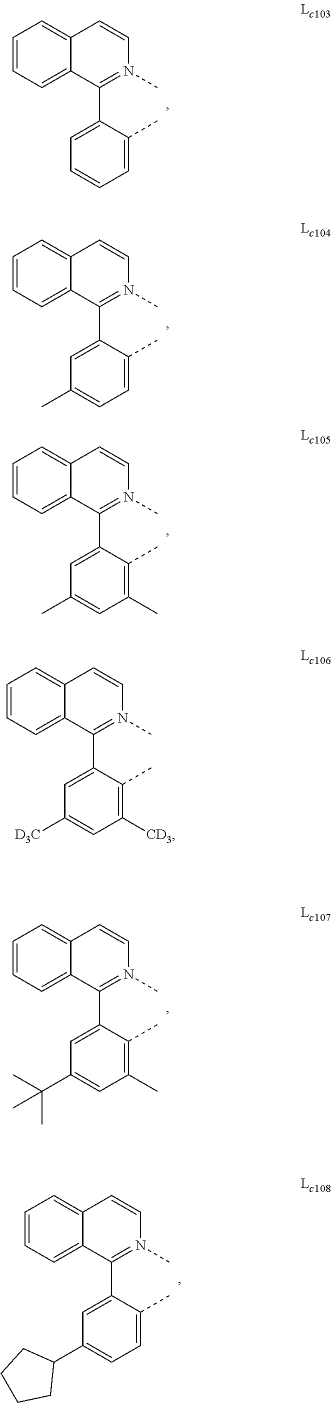 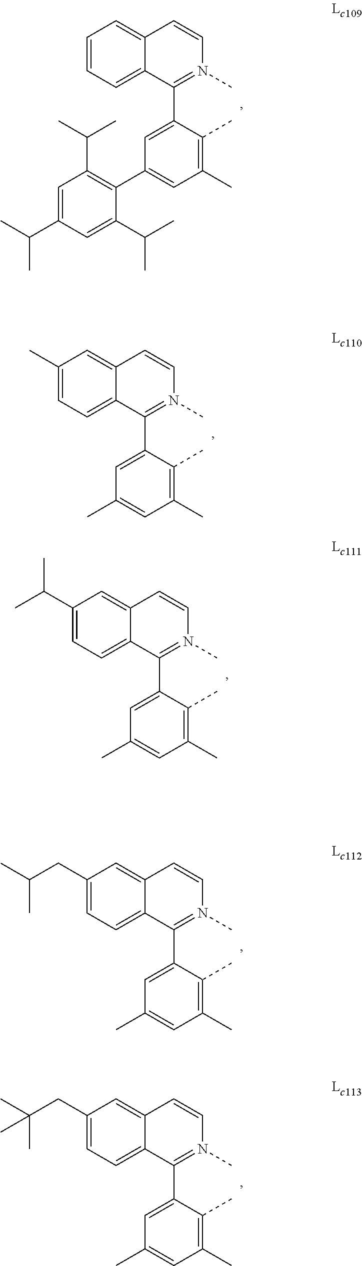 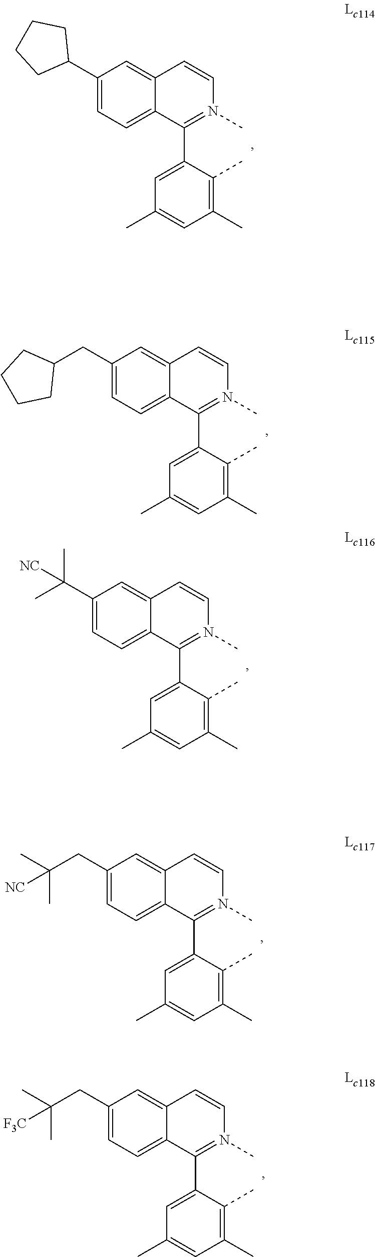 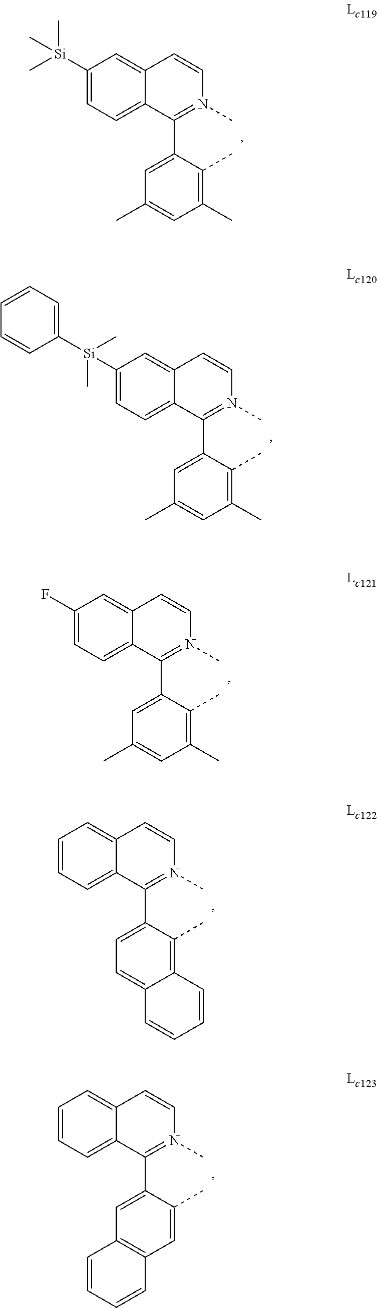 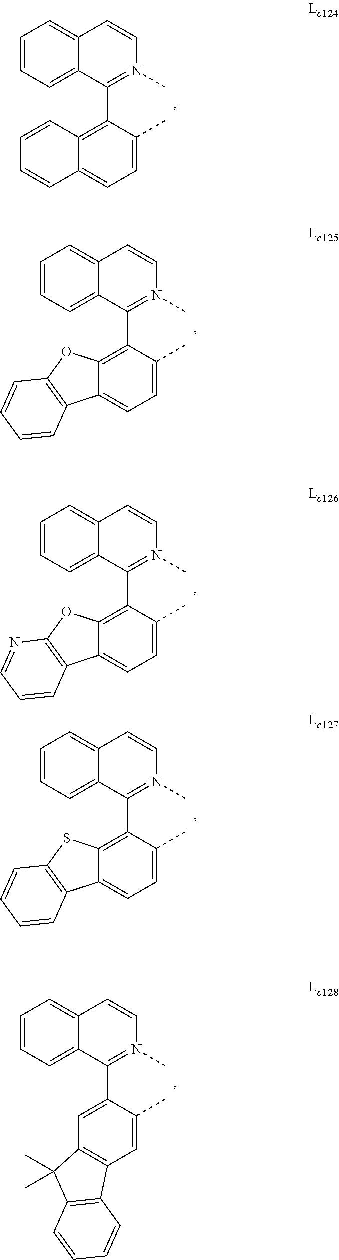 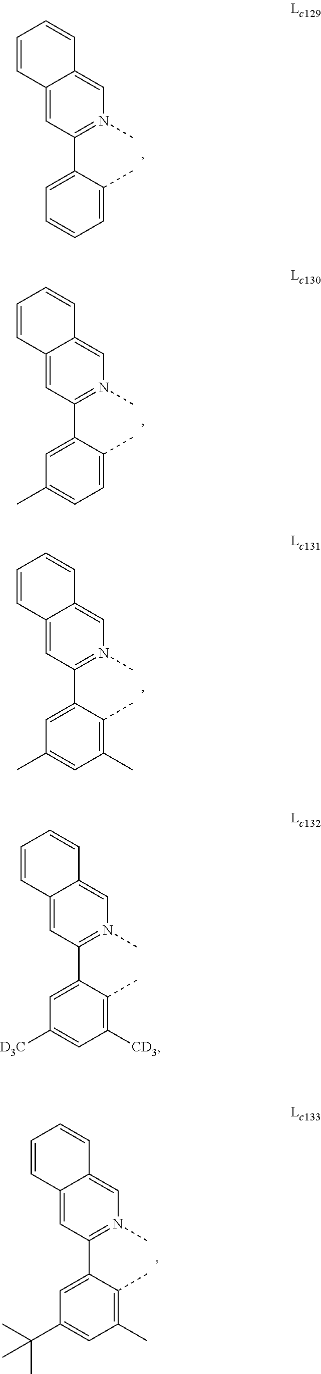 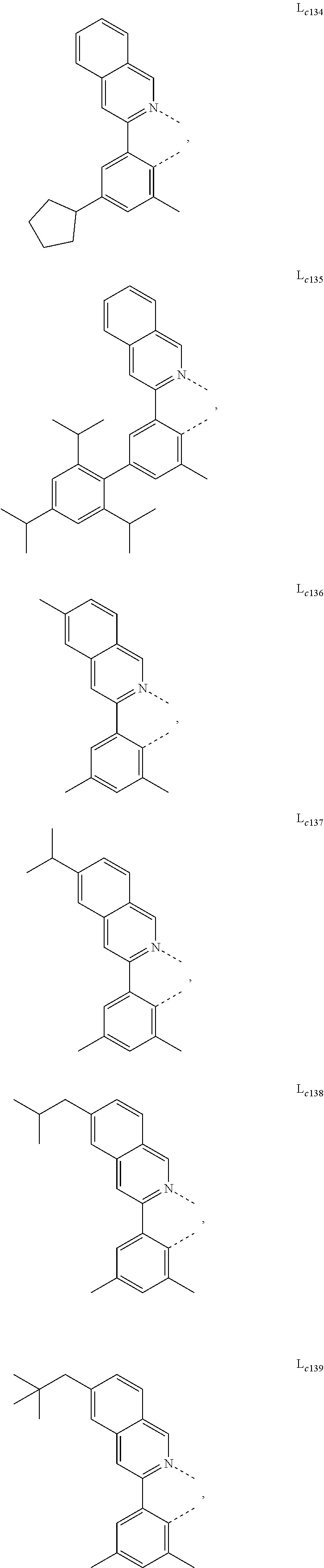 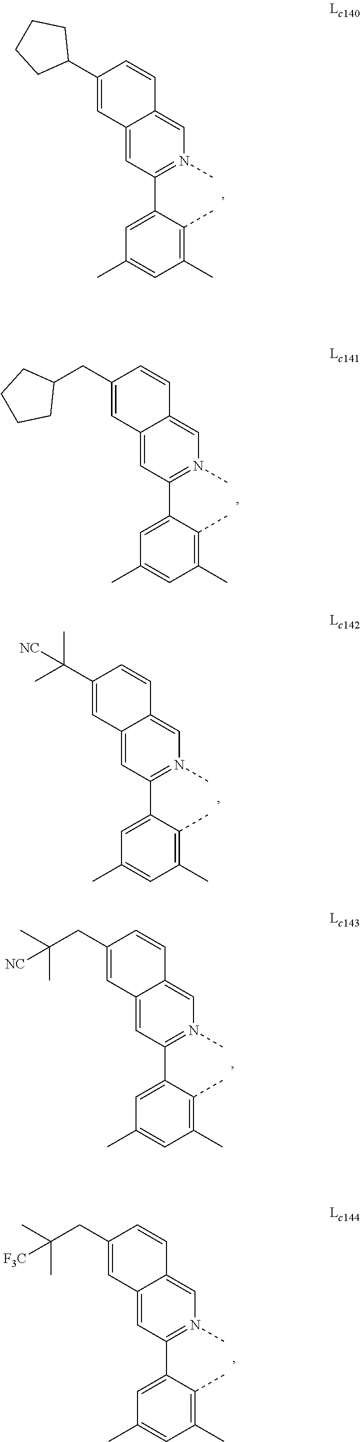 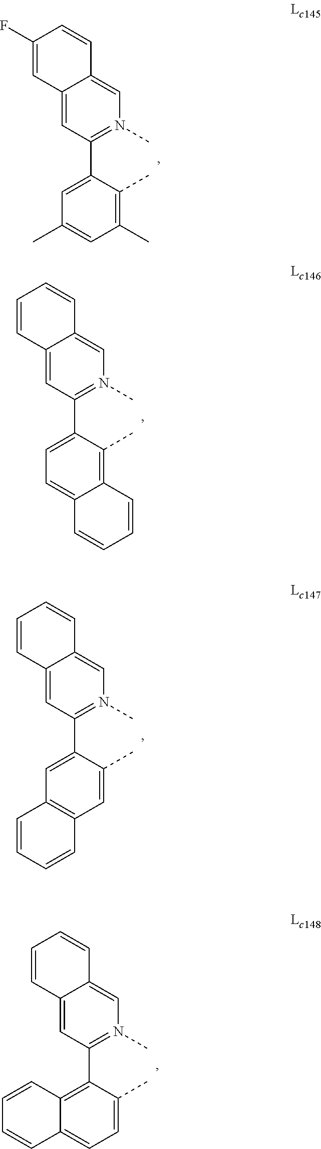 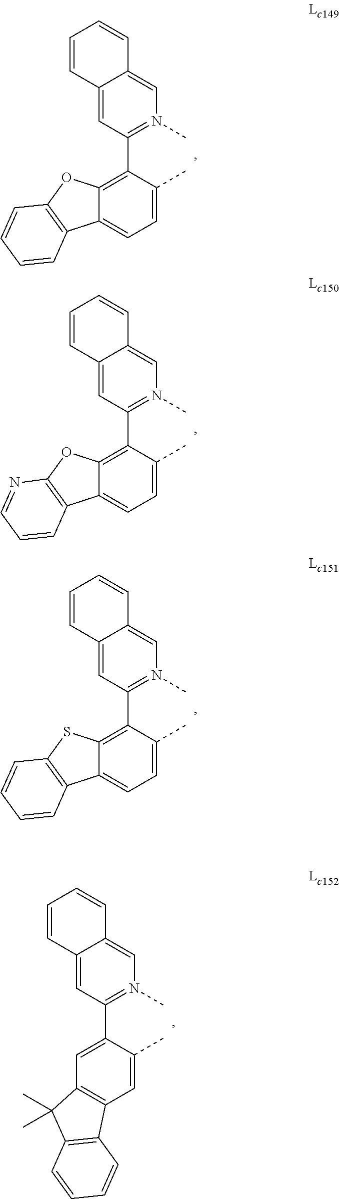 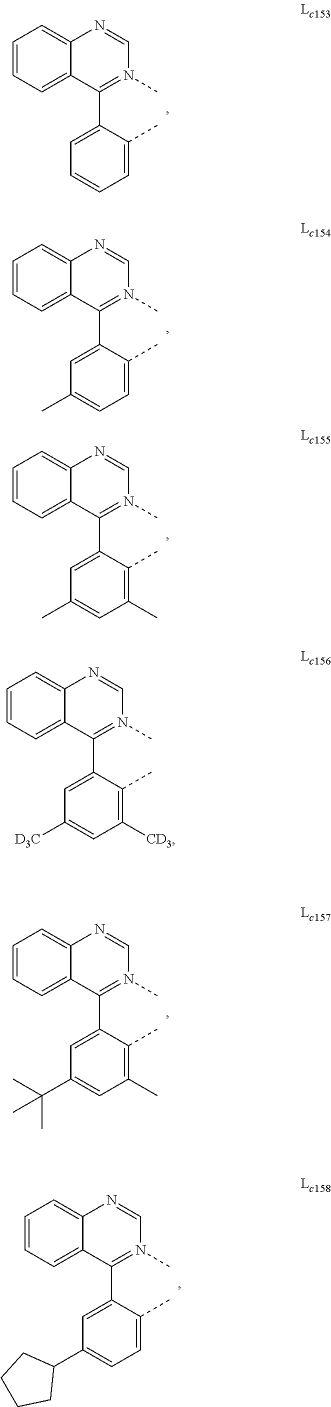 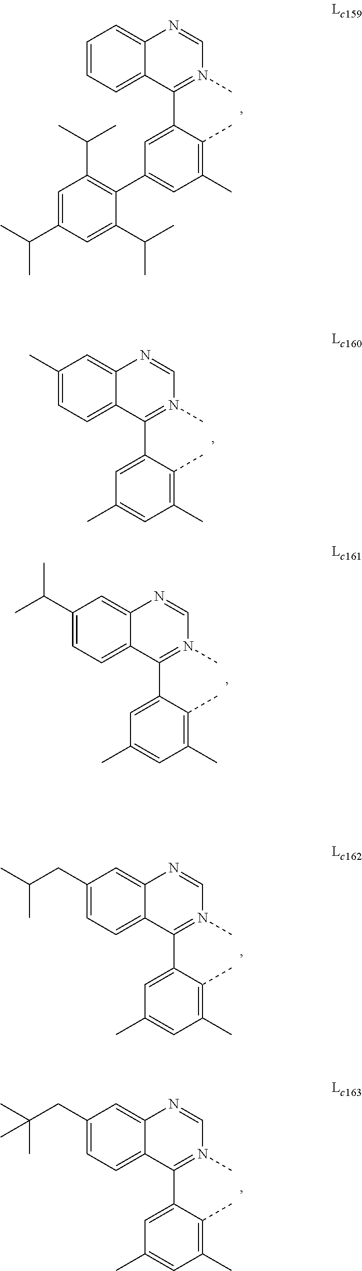 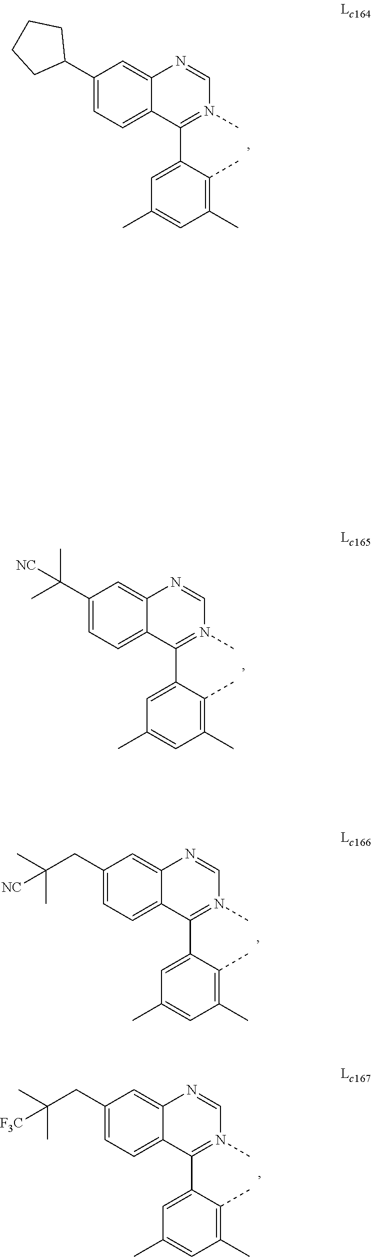 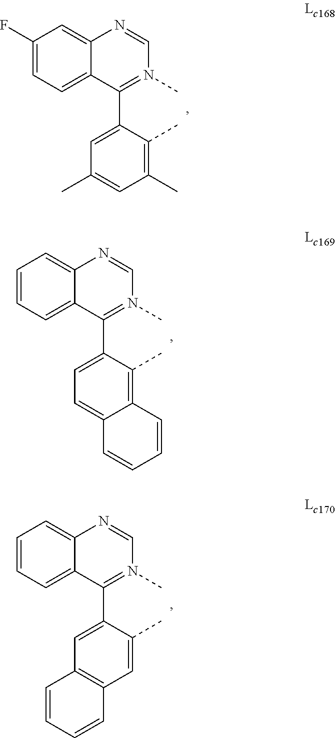 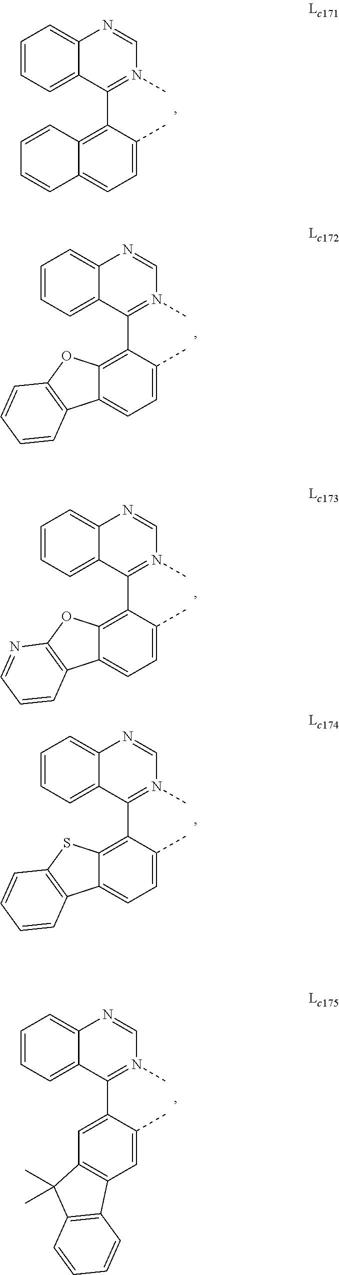 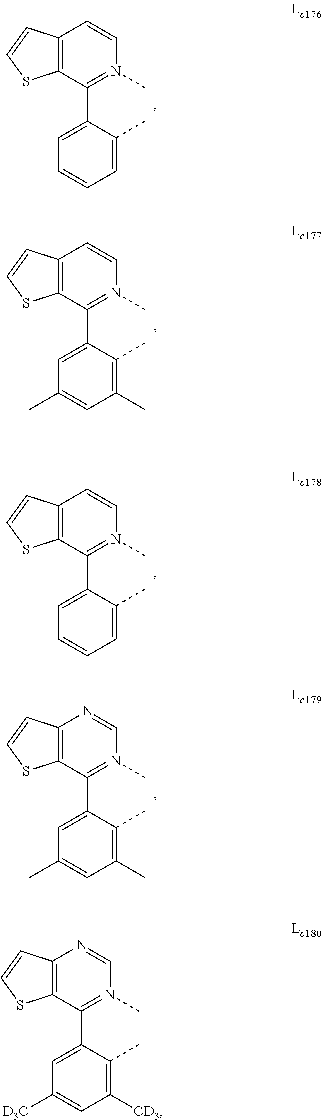 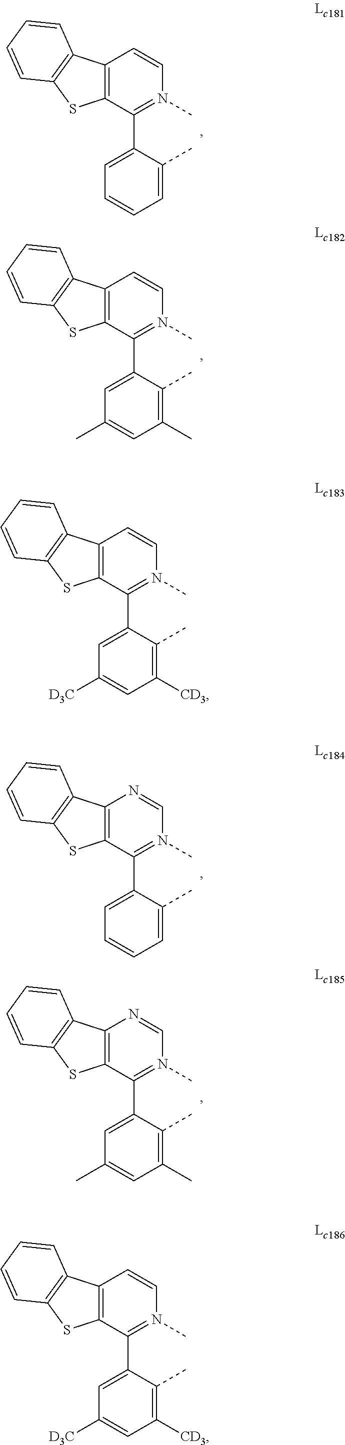 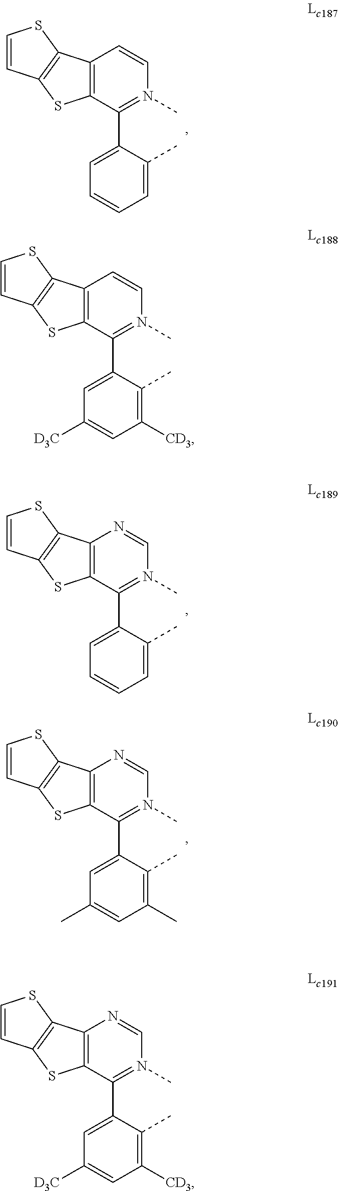 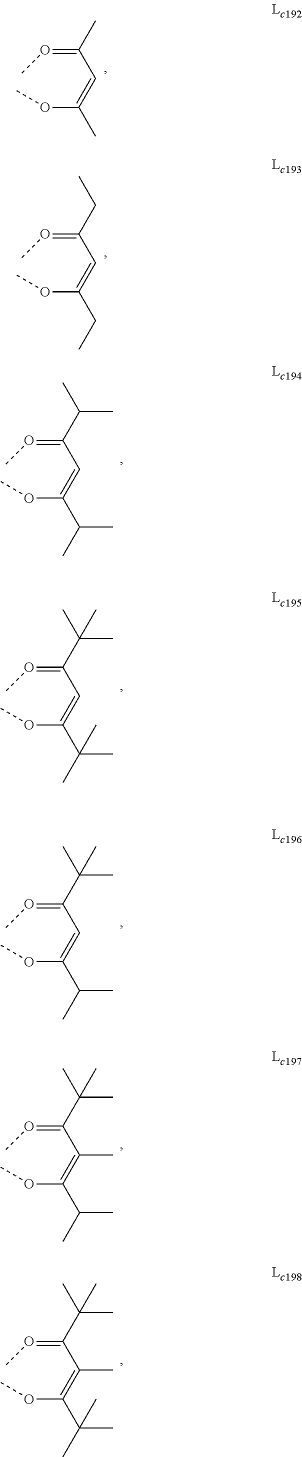 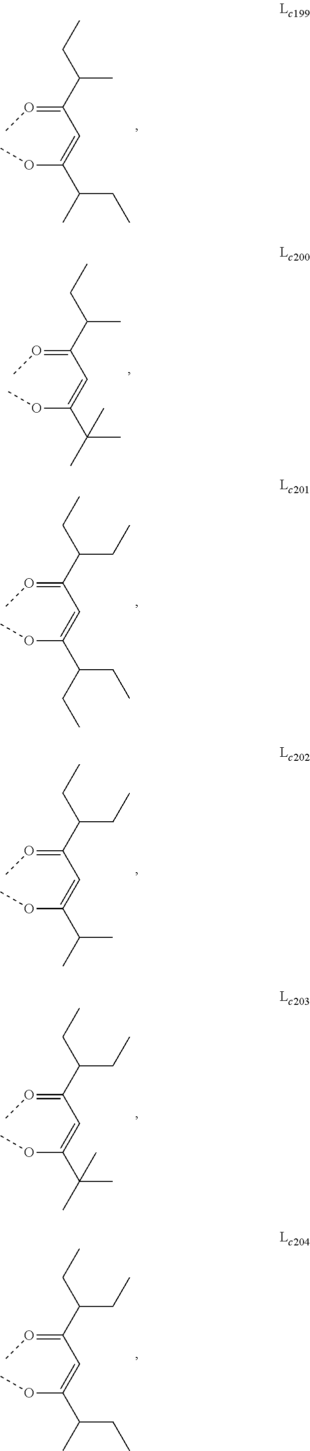 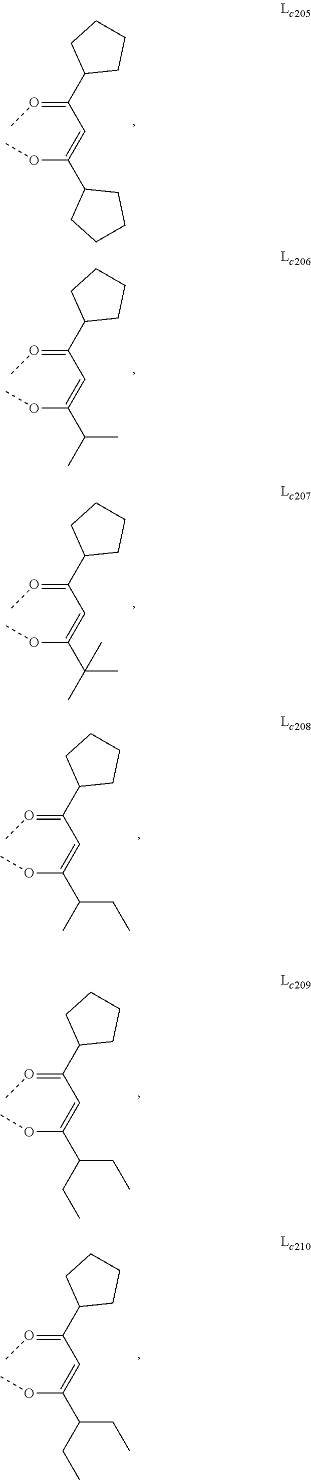 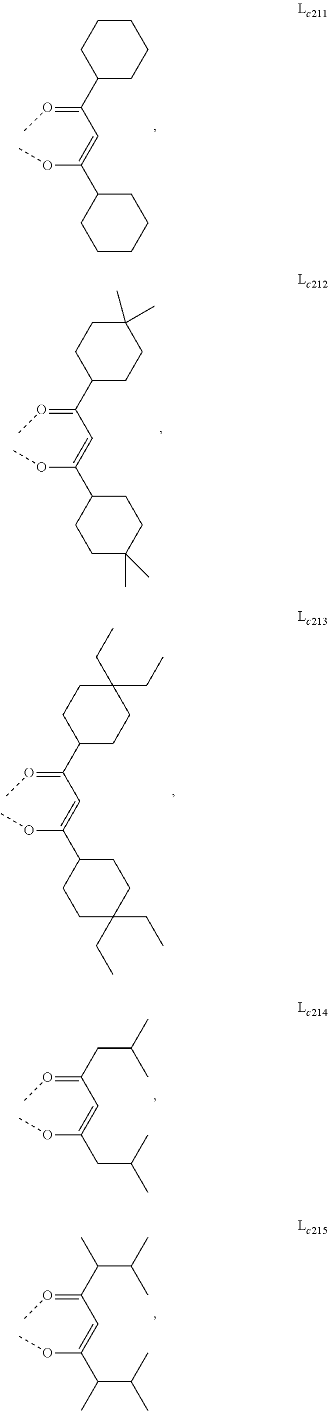 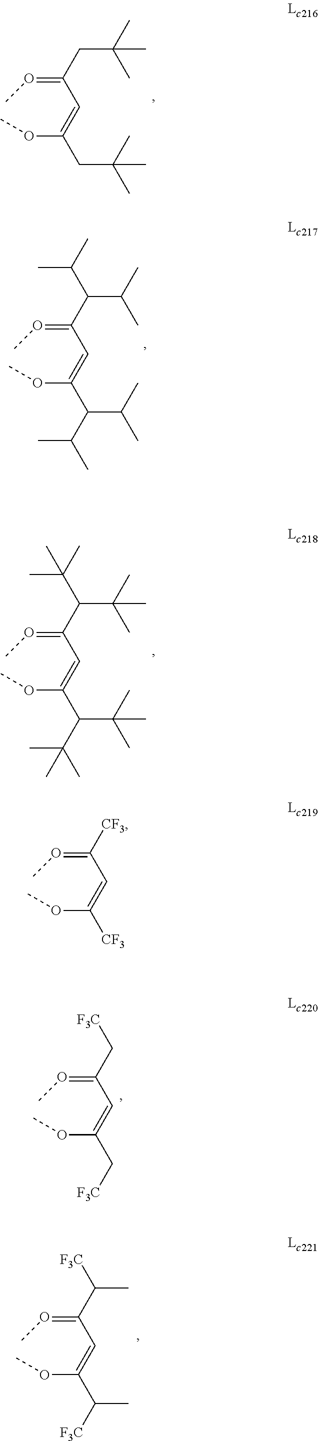 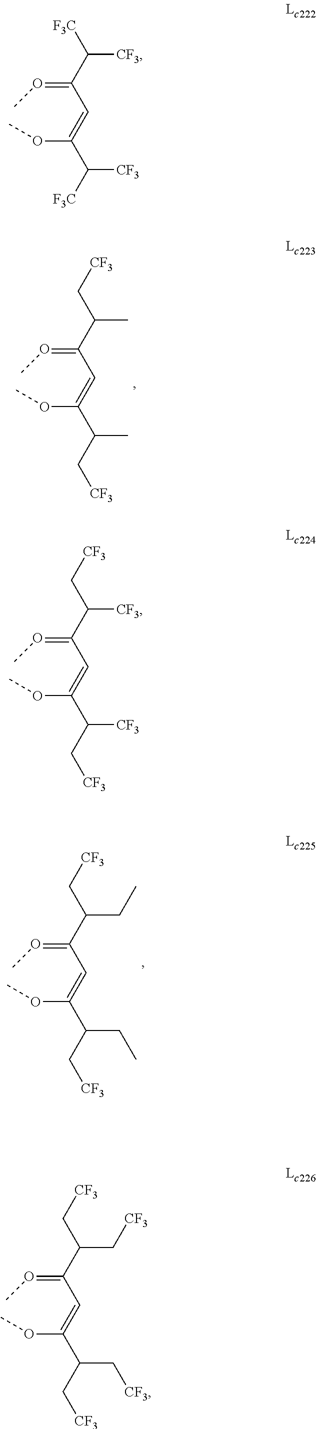 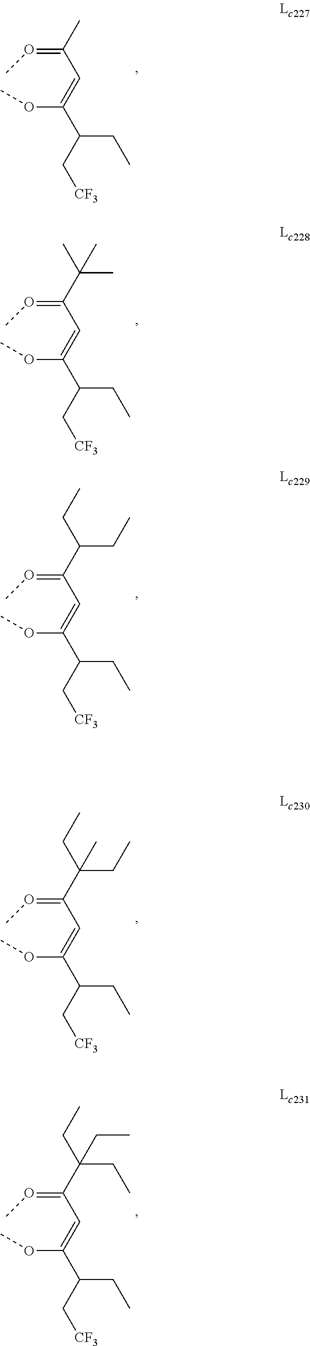 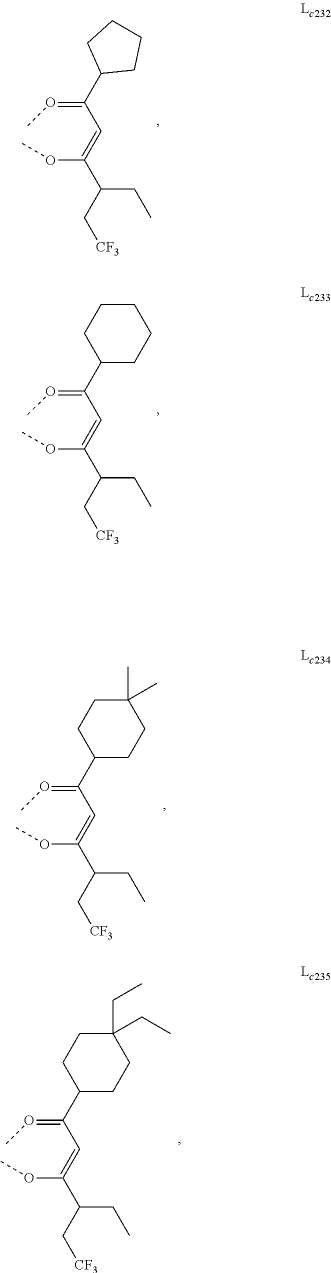 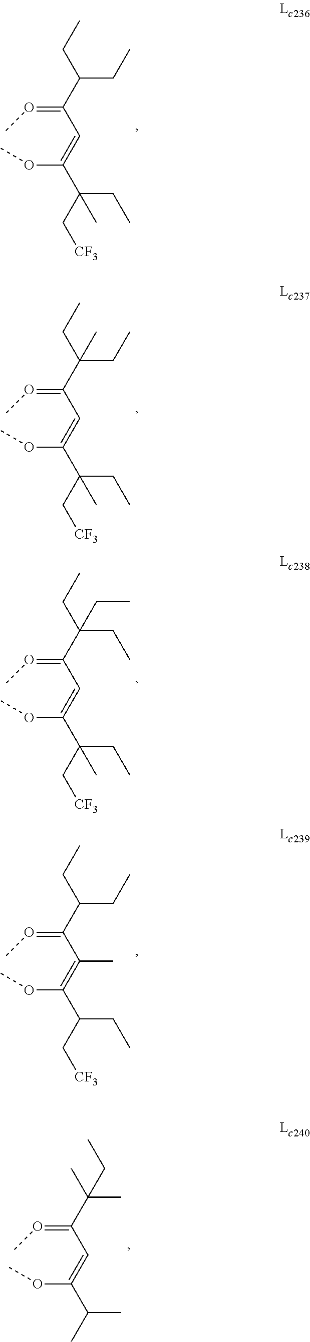 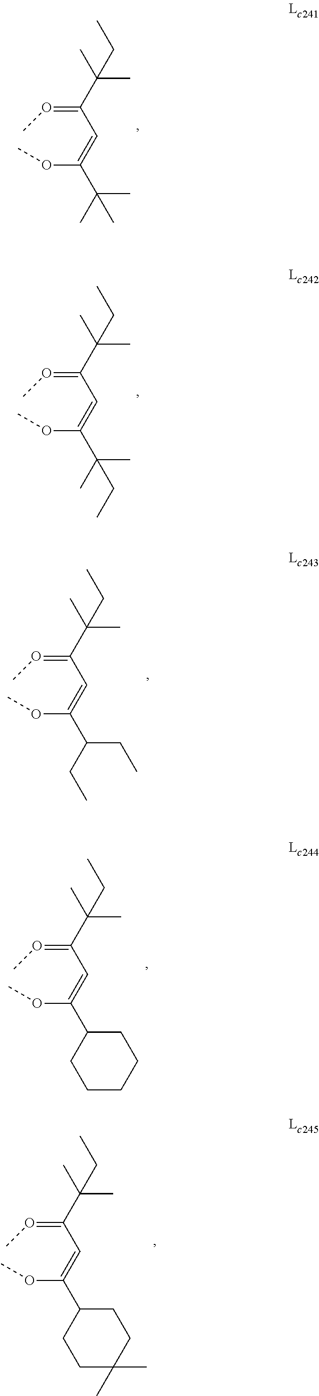 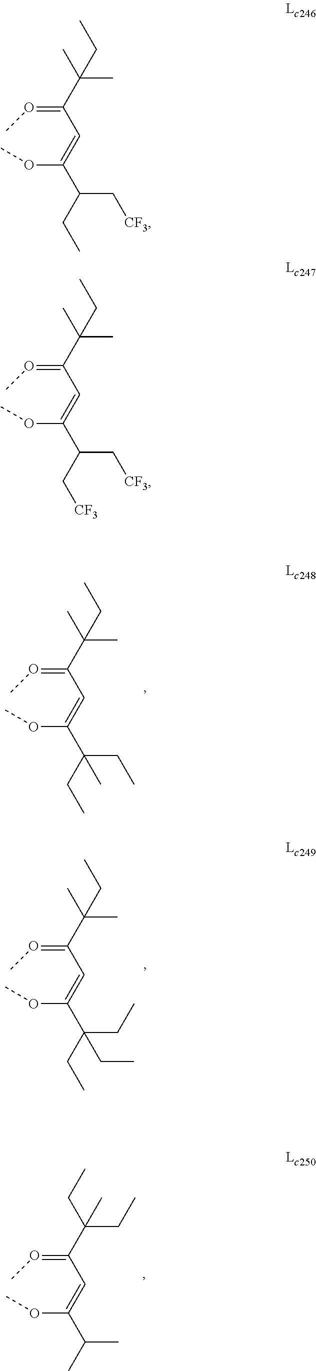 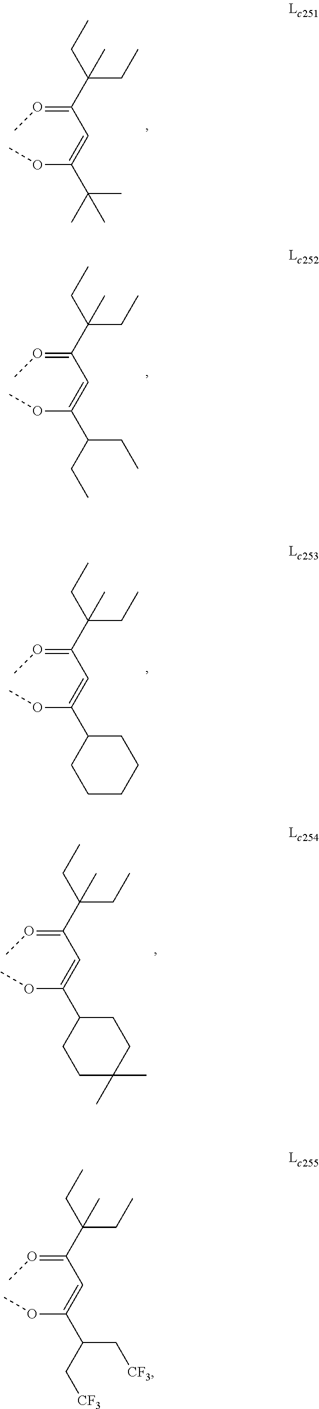 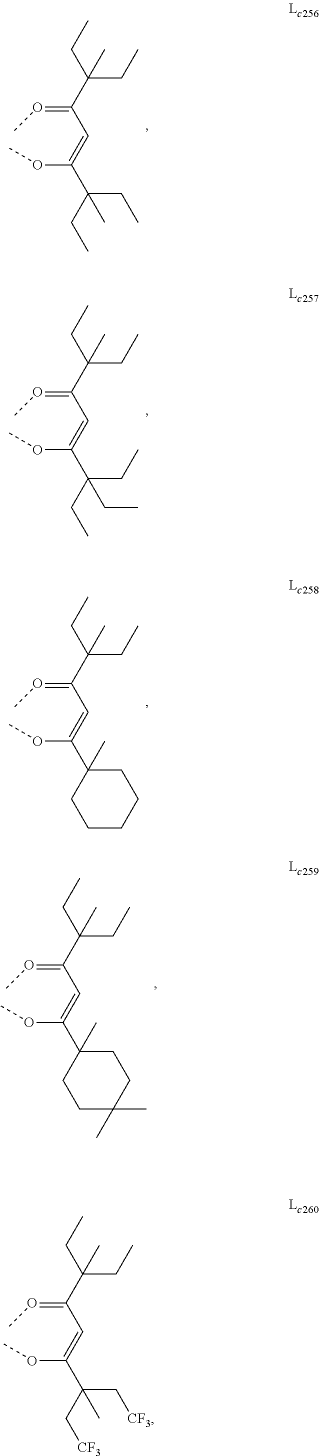 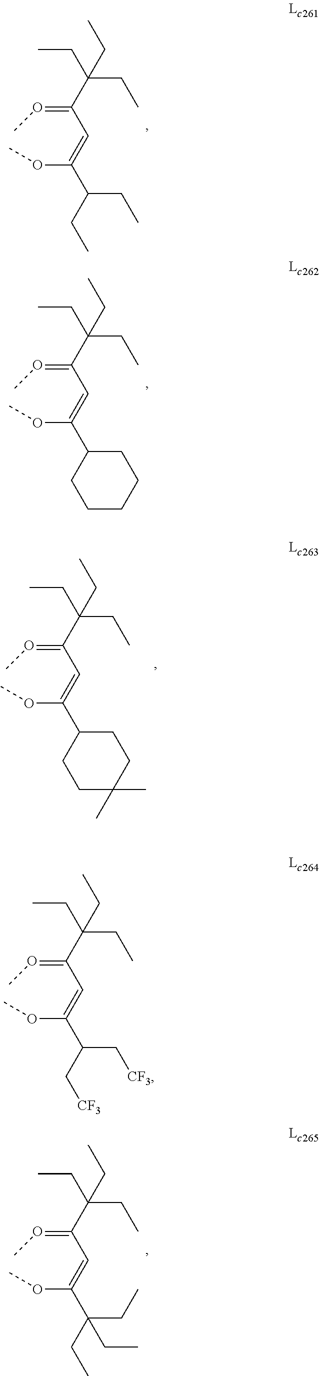 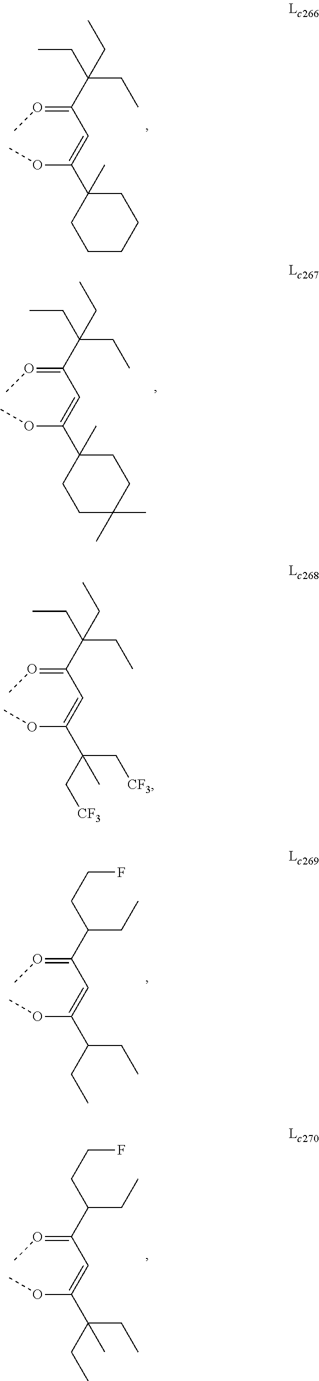 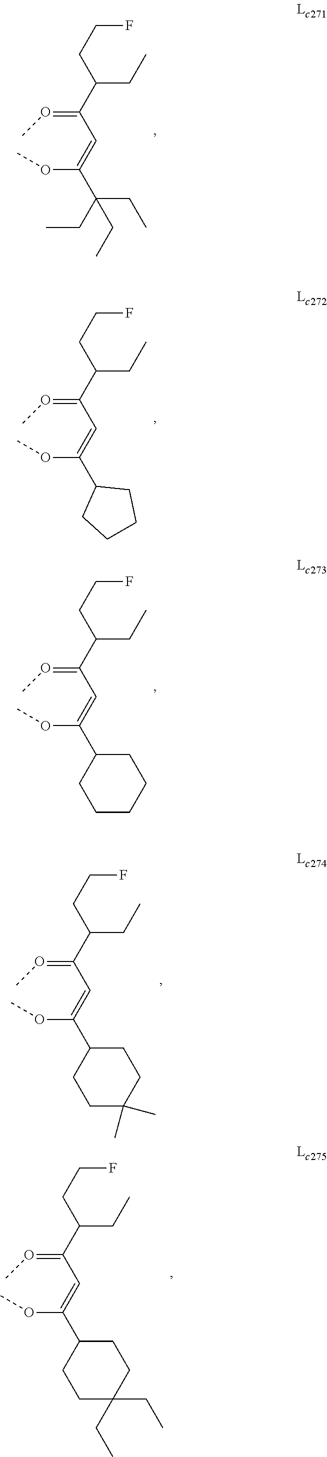 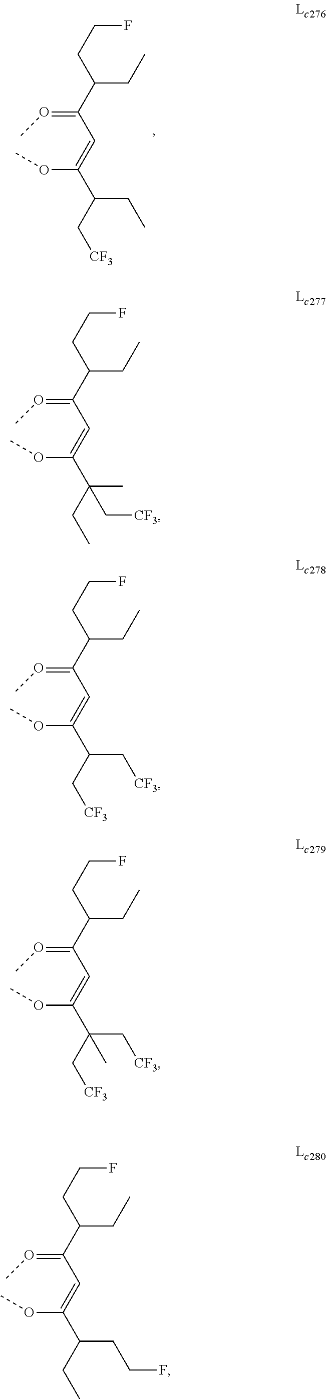 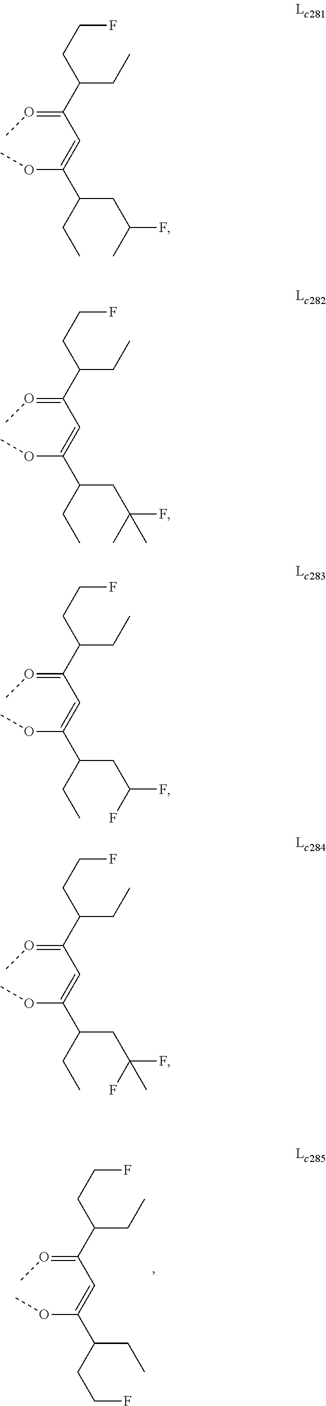 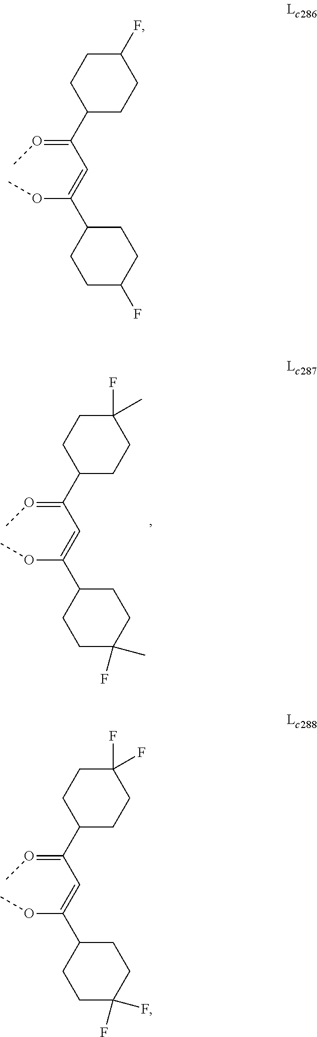 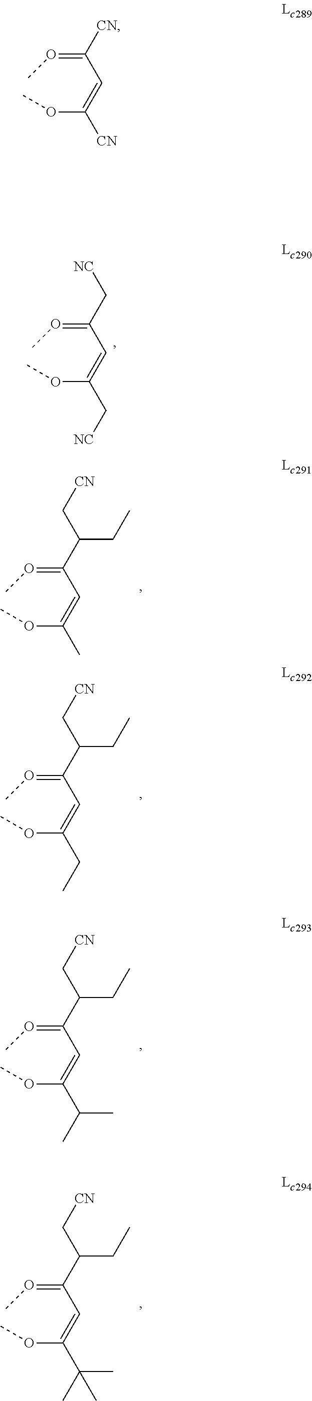 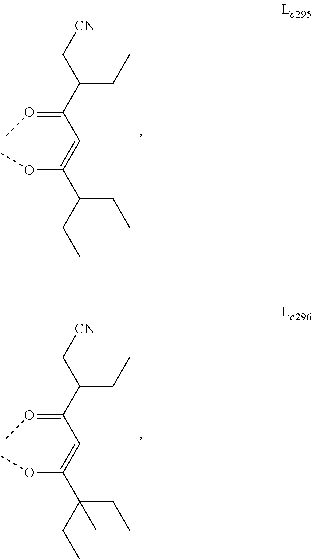 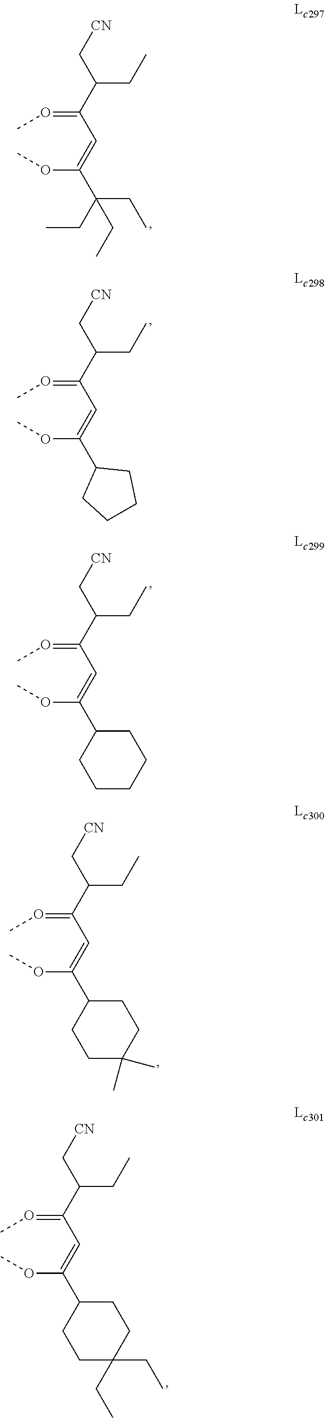 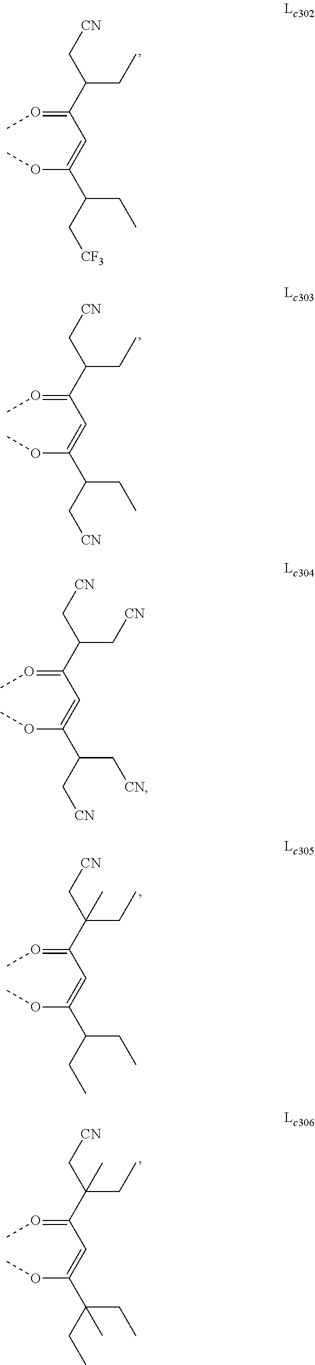 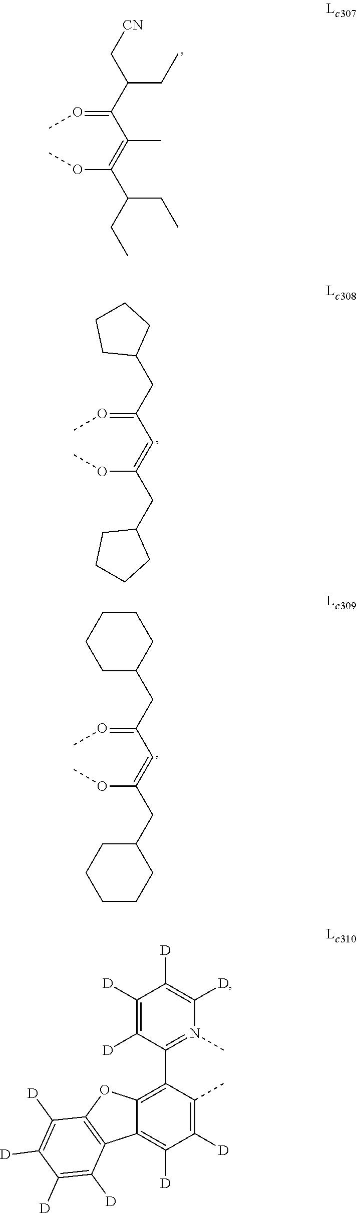 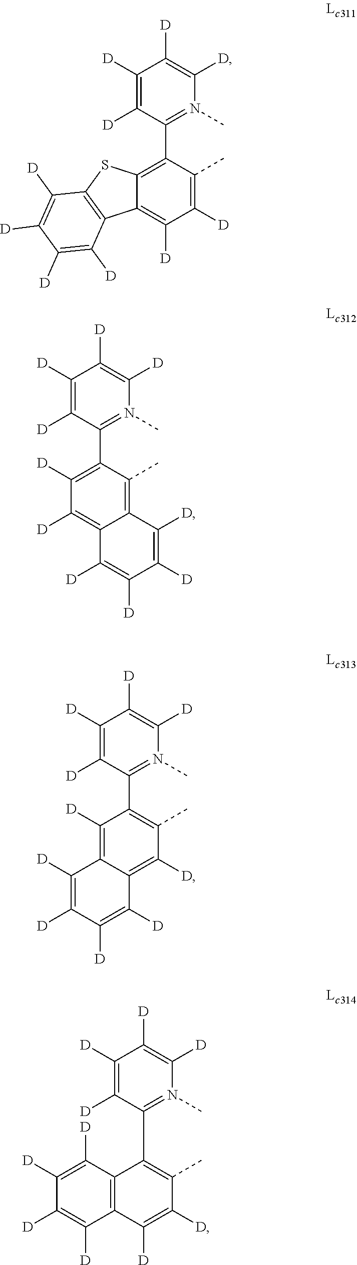 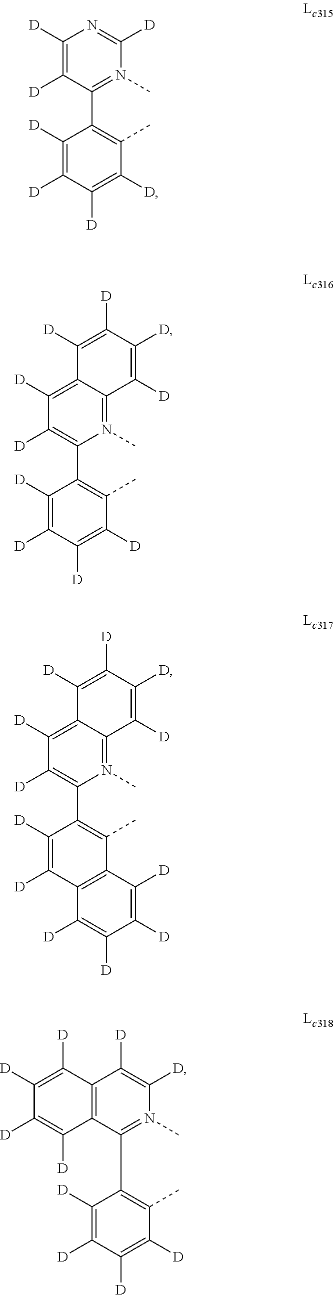 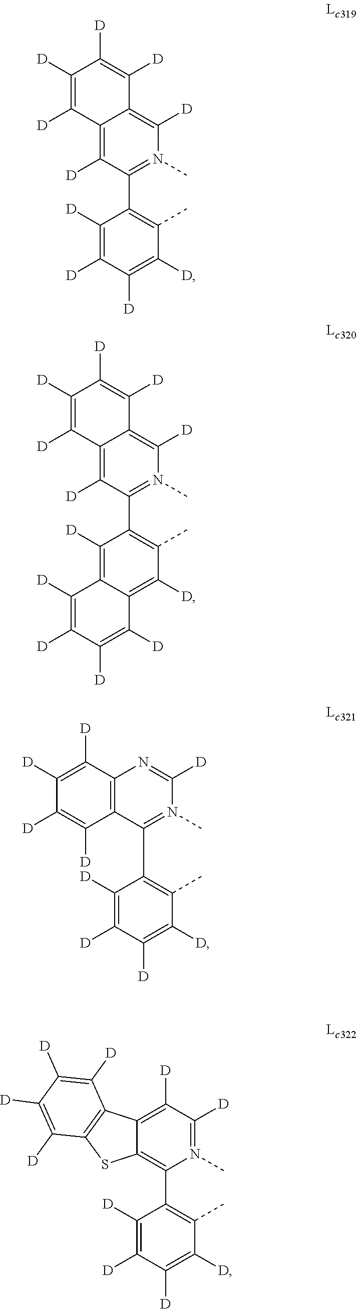 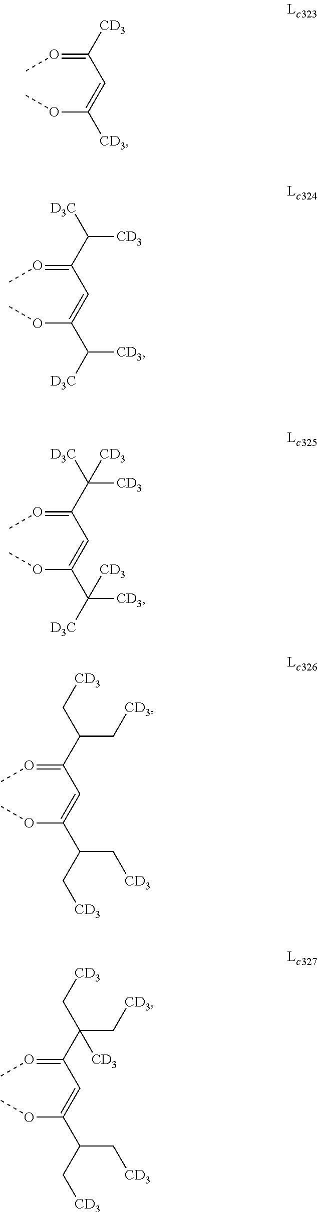 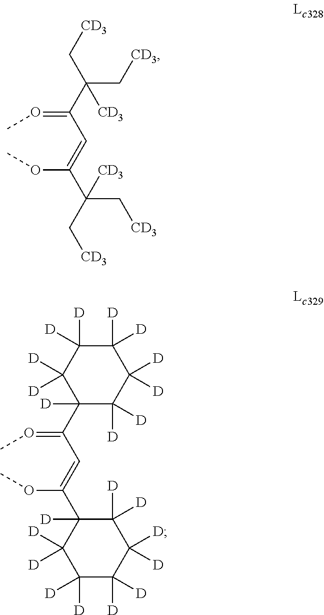
wherein optionally, hydrogen atoms in L_{c1} to L_{c329} can be partially or fully substituted with deuterium.

15. The metal complex according to claim 1, wherein the metal M is selected from Ir, Rh, Re, Os, Pt, Au, or Cu; preferably, the metal M is selected from Ir, Pt, or Os; more preferably, the metal M is Ir.

16. The metal complex according to claim 1, wherein the metal complex has a general formula of Ir(Lₐ)ₘ(L_{b})₃₋ₘ and has a structure represented by Formula 22: 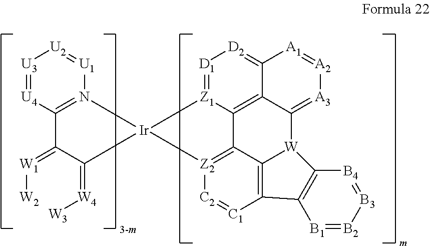
wherein m is 1 or 2;
Z₁ and Z₂ are each independently selected from C or N, and Z₁ is different from Z₂;
W is, at each occurrence identically or differently, selected from B, N, or P;
A₁ to A₃ are, at each occurrence identically or differently, selected from N or CR_{A};
B₁ to B₄ are, at each occurrence identically or differently, selected from N or CR_{B};
C₁ and C₂ are, at each occurrence identically or differently, selected from N or CR_{C};
D₁ and D₂ are, at each occurrence identically or differently, selected from N or CR_{D};
U₁ to U₄ are, at each occurrence identically or differently, selected from N or CR_{U};
W₁ to W₄ are, at each occurrence identically or differently, selected from N or CR_{W};
R_{A}, R_{B}, R_{C}, R_{D}, R_{U}, and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{A}, R_{B}, R_{C}, R_{D} can be optionally joined to form a ring; and
adjacent substituents R_{U}, R_{W} can be optionally joined to form a ring;
preferably, at least one of A₁ to A₃ is selected from CR_{A} and/or at least one of B₁ to B₄ is selected from CR_{B}, and the R_{A} and R_{B} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, hydroxyl, sulfanyl, and combinations thereof,
more preferably, A₂ is selected from CR_{A} and/or one of B₂ and B₃ is selected from CR_{B};
most preferably, the R_{A} and R_{B} are, at each occurrence identically or differently, selected from the group consisting of: deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, sec-butyl, t-butyl, neopentyl, cyclopentyl, cyclopentylmethyl, cyclohexyl, norbornyl, adamantyl, trimethylsilyl, triethylsilyl, phenyldimethylsilyl, trimethylgermanyl, triethylgermanyl, phenyl, 2,6-dimethylphenyl, 2,6-diisopropylphenyl, pyridyl, pyrimidinyl, triazinyl, and combinations thereof.

17. The metal complex according to claim 1, wherein the metal complex has a structure of Ir(Lₐ)(L_{b})₂ or Ir(Lₐ)₂(L_{b}) or Ir(Lₐ)(L_{b})(L_{c});
wherein when the metal complex has a structure of Ir(Lₐ)(L_{b})₂, Lₐ is selected from any one of the group consisting of Lₐ₁ to Lₐ₁₈₂₀ and L_{b} is, at each occurrence identically or differently, selected from any one or two of the group consisting of L_{b}, to L_{b379}; when the metal complex has a structure of Ir(Lₐ)₂(L_{b}), Lₐ is, at each occurrence identically or differently, selected from any one or two of the group consisting of Lₐ₁ to Lₐ₁₈₂₀ and L_{b} is selected from any one of the group consisting of L_{b1} to L_{b379}; when the metal complex has a structure of Ir(Lₐ)(L_{b})(L_{c}), Lₐ is selected from any one of the group consisting of Lₐ₁ to Lₐ₈₂₀, L_{b} is selected from any one of the group consisting of L_{b1} to L_{b379}, and L_{c} is selected from any one of the group consisting of L_{c1} to L_{c329}; optionally, hydrogen atoms in the structure of the metal complex can be partially or fully substituted with deuterium;
preferably, the metal complex is selected from the group consisting of Compound 1 to Compound 1826;
wherein Compound 1 to Compound 1638 each have a structure of Ir(Lₐ)(L_{b})₂, wherein the two L_{b} are the same, and Lₐ and L_{b} are selected from the structures listed in the following table, respectively

| Compound | | | Compound | | |
|---|---|---|---|---|---|
| No. | Lₐ | L_{b} | No. | Lₐ | L_{b} |
| 1 | Lₐ₅ | L_{b2} | 2 | Lₐ₅ | L_{b3} |
| 3 | Lₐ₂₇ | L_{b2} | 4 | Lₐ₂₇ | L_{b3} |
| 5 | Lₐ₂₈ | L_{b2} | 6 | Lₐ₂₈ | L_{b3} |
| 7 | Lₐ₂₉ | L_{b2} | 8 | Lₐ₂₉ | L_{b3} |
| 9 | Lₐ₃₀ | L_{b2} | 10 | Lₐ₃₀ | L_{b3} |
| 11 | Lₐ₃₃ | L_{b2} | 12 | Lₐ₃₃ | L_{b3} |
| 13 | Lₐ₃₅ | L_{b2} | 14 | Lₐ₃₅ | L_{b3} |
| 15 | Lₐ₃₇ | L_{b2} | 16 | Lₐ₃₇ | L_{b3} |
| 17 | Lₐ₄₁ | L_{b2} | 18 | Lₐ₄₁ | L_{b3} |
| 19 | Lₐ₄₃ | L_{b2} | 20 | Lₐ₄₃ | L_{b3} |
| 21 | Lₐ₅₁ | L_{b2} | 22 | Lₐ₅₁ | L_{b3} |
| 23 | Lₐ₅₆ | L_{b2} | 24 | Lₐ₅₆ | L_{b3} |
| 25 | Lₐ₅₈ | L_{b2} | 26 | Lₐ₅₈ | L_{b3} |
| 27 | Lₐ₇₄ | L_{b2} | 28 | Lₐ₇₄ | L_{b3} |
| 29 | Lₐ₇₉ | L_{b2} | 30 | Lₐ₇₉ | L_{b3} |
| 31 | Lₐ₈₁ | L_{b2} | 32 | Lₐ₈₁ | L_{b3} |
| 33 | Lₐ₉₇ | L_{b2} | 34 | Lₐ₉₇ | L_{b3} |
| 35 | Lₐ₁₀₂ | L_{b2} | 36 | Lₐ₁₀₂ | L_{b3} |
| 37 | Lₐ₁₀₄ | L_{b2} | 38 | Lₐ₁₀₄ | L_{b3} |
| 39 | Lₐ₁₂₀ | L_{b2} | 40 | Lₐ₁₂₀ | L_{b3} |
| 41 | Lₐ₁₂₅ | L_{b2} | 42 | Lₐ₁₂₅ | L_{b3} |
| 43 | Lₐ₂₁₂ | L_{b2} | 44 | Lₐ₂₁₂ | L_{b3} |
| 45 | Lₐ₂₁₄ | L_{b2} | 46 | Lₐ₂₁₄ | L_{b3} |
| 47 | Lₐ₂₁₇ | L_{b2} | 48 | Lₐ₂₁₇ | L_{b3} |
| 49 | Lₐ₂₁₉ | L_{b2} | 50 | Lₐ₂₁₉ | L_{b3} |
| 51 | Lₐ₂₂₆ | L_{b2} | 52 | Lₐ₂₂₆ | L_{b3} |
| 53 | Lₐ₃₀₄ | L_{b2} | 54 | Lₐ₃₀₄ | L_{b3} |
| 55 | Lₐ₃₀₆ | L_{b2} | 56 | Lₐ₃₀₆ | L_{b3} |
| 57 | Lₐ₃₀₉ | L_{b2} | 58 | Lₐ₃₀₉ | L_{b3} |
| 59 | Lₐ₃₁₁ | L_{b2} | 60 | Lₐ₃₁₁ | L_{b3} |
| 61 | Lₐ₃₂₁ | L_{b2} | 62 | Lₐ₃₂₁ | L_{b3} |
| 63 | Lₐ₃₂₃ | L_{b2} | 64 | Lₐ₃₂₃ | L_{b3} |
| 65 | Lₐ₃₃₂ | L_{b2} | 66 | Lₐ₃₃₂ | L_{b3} |
| 67 | Lₐ₃₅₁ | L_{b2} | 68 | Lₐ₃₅₁ | L_{b3} |
| 69 | Lₐ₃₅₆ | L_{b2} | 70 | Lₐ₃₅₆ | L_{b3} |
| 71 | Lₐ₃₇₅ | L_{b2} | 72 | Lₐ₃₇₅ | L_{b3} |
| 73 | Lₐ₄₂₂ | L_{b2} | 74 | Lₐ₄₂₂ | L_{b3} |
| 75 | Lₐ₄₂₇ | L_{b2} | 76 | Lₐ₄₂₇ | L_{b3} |
| 77 | Lₐ₄₅₀ | L_{b2} | 78 | Lₐ₄₅₀ | L_{b3} |
| 79 | Lₐ₄₇₃ | L_{b2} | 80 | Lₐ₄₇₃ | L_{b3} |
| 81 | Lₐ₄₉₆ | L_{b2} | 82 | Lₐ₄₉₆ | L_{b3} |
| 83 | Lₐ₆₀₆ | L_{b2} | 84 | Lₐ₆₀₆ | L_{b3} |
| 85 | Lₐ₆₁₁ | L_{b2} | 86 | Lₐ₆₁₁ | L_{b3} |
| 87 | Lₐ₆₃₄ | L_{b2} | 88 | Lₐ₆₃₄ | L_{b3} |
| 89 | Lₐ₈₉₉ | L_{b2} | 90 | Lₐ₈₉₉ | L_{b3} |
| 91 | Lₐ₉₂₃ | L_{b2} | 92 | Lₐ₉₂₃ | L_{b3} |
| 93 | Lₐ₉₉₇ | L_{b2} | 94 | Lₐ₉₉₇ | L_{b3} |
| 95 | Lₐ₁₁₀₆ | L_{b2} | 96 | Lₐ₁₁₀₆ | L_{b3} |
| 97 | Lₐ₁₁₀₈ | L_{b2} | 98 | Lₐ₁₁₀₈ | L_{b3} |
| 99 | Lₐ₁₁₁₂ | L_{b2} | 100 | Lₐ₁₁₁₂ | L_{b3} |
| 101 | Lₐ₁₁₁₄ | L_{b2} | 102 | Lₐ₁₁₁₄ | L_{b3} |
| 103 | Lₐ₁₁₁₈ | L_{b2} | 104 | Lₐ₁₁₁₈ | L_{b3} |
| 105 | Lₐₗ₁₂₀ | L_{b2} | 106 | Lₐ₁₁₂₀ | L_{b3} |
| 107 | Lₐ₁₂₁₈ | L_{b2} | 108 | Lₐ₁₂₁₈ | L_{b3} |
| 109 | Lₐ₁₂₁₉ | L_{b2} | 110 | Lₐ₁₂₁₉ | L_{b3} |
| 111 | Lₐ₁₃₀₂ | L_{b2} | 112 | Lₐ₁₃₀₂ | L_{b3} |
| 113 | Lₐ₁₃₀₇ | L_{b2} | 114 | Lₐ₁₃₀₇ | L_{b3} |
| 115 | Lₐ₁₄₇₃ | L_{b2} | 116 | Lₐ₁₄₇₃ | L_{b3} |
| 117 | Lₐ₁₄₈₇ | L_{b2} | 118 | Lₐ₁₄₈₇ | L_{b3} |
| 119 | Lₐ₁₄₉₁ | L_{b2} | 120 | Lₐ₁₄₉₁ | L_{b3} |
| 121 | Lₐ₁₇₁₀ | L_{b2} | 122 | Lₐ₁₇₁₀ | L_{b3} |
| 123 | Lₐ₁₇₄₀ | L_{b2} | 124 | Lₐ₁₇₄₀ | L_{b3} |
| 125 | Lₐ₁₇₄₅ | L_{b2} | 126 | Lₐ₁₇₄₅ | L_{b3} |
| 127 | Lₐ₅ | L_{b5} | 128 | Lₐ₅ | L_{b21} |
| 129 | Lₐ₂₇ | L_{b5} | 130 | Lₐ₂₇ | L_{b21} |
| 131 | Lₐ₂₈ | L_{b5} | 132 | Lₐ₂₈ | L_{b21} |
| 133 | Lₐ₂₉ | L_{b5} | 134 | Lₐ₂₉ | L_{b21} |
| 135 | Lₐ₃₀ | L_{b5} | 136 | Lₐ₃₀ | L_{b21} |
| 137 | Lₐ₃₃ | L_{b5} | 138 | Lₐ₃₃ | L_{b21} |
| 139 | Lₐ₃₅ | L_{b5} | 140 | Lₐ₃₅ | L_{b21} |
| 141 | Lₐ₃₇ | L_{b5} | 142 | Lₐ₃₇ | L_{b21} |
| 143 | Lₐ₄₁ | L_{b5} | 144 | Lₐ₄₁ | L_{b21} |
| 145 | Lₐ₄₃ | L_{b5} | 146 | Lₐ₄₃ | L_{b21} |
| 147 | Lₐ₅₁ | L_{b5} | 148 | Lₐ₅₁ | L_{b21} |
| 149 | Lₐ₅₆ | L_{b5} | 150 | Lₐ₅₆ | L_{b21} |
| 151 | Lₐ₅₈ | L_{b5} | 152 | Lₐ₅₈ | L_{b21} |
| 153 | Lₐ₇₄ | L_{b5} | 154 | Lₐ₇₄ | L_{b21} |
| 155 | Lₐ₇₉ | L_{b5} | 156 | Lₐ₇₉ | L_{b21} |
| 157 | Lₐ₈₁ | L_{b5} | 158 | Lₐ₈₁ | L_{b21} |
| 159 | Lₐ₉₇ | L_{b5} | 160 | Lₐ₉₇ | L_{b21} |
| 161 | Lₐ₁₀₂ | L_{b5} | 162 | Lₐ₁₀₂ | L_{b21} |
| 163 | Lₐ₁₀₄ | L_{b5} | 164 | Lₐ₁₀₄ | L_{b21} |
| 165 | Lₐ₁₂₀ | L_{b5} | 166 | Lₐ₁₂₀ | L_{b21} |
| 167 | Lₐ₁₂₅ | L_{b5} | 168 | Lₐ₁₂₅ | L_{b21} |
| 169 | Lₐ₂₁₂ | L_{b5} | 170 | Lₐ₂₁₂ | L_{b21} |
| 171 | Lₐ₂₁₄ | L_{b5} | 172 | Lₐ₂₁₄ | L_{b21} |
| 173 | Lₐ₂₁₇ | L_{b5} | 174 | Lₐ₂₁₇ | L_{b21} |
| 175 | Lₐ₂₁₉ | L_{b5} | 176 | Lₐ₂₁₉ | L_{b21} |
| 177 | Lₐ₂₂₆ | L_{b5} | 178 | Lₐ₂₂₆ | L_{b21} |
| 179 | Lₐ₃₀₄ | L_{b5} | 180 | Lₐ₃₀₄ | L_{b21} |
| 181 | Lₐ₃₀₆ | L_{b5} | 182 | Lₐ₃₀₆ | L_{b21} |
| 183 | Lₐ₃₀₉ | L_{b5} | 184 | Lₐ₃₀₉ | L_{b21} |
| 185 | Lₐ₃₁₁ | L_{b5} | 186 | Lₐ₃₁₁ | L_{b21} |
| 187 | Lₐ₃₂₁ | L_{b5} | 188 | Lₐ₃₂₁ | L_{b21} |
| 189 | Lₐ₃₂₃ | L_{b5} | 190 | Lₐ₃₂₃ | L_{b21} |
| 191 | Lₐ₃₃₂ | L_{b5} | 192 | Lₐ₃₃₂ | L_{b21} |
| 193 | Lₐ₃₅₁ | L_{b5} | 194 | Lₐ₃₅₁ | L_{b21} |
| 195 | Lₐ₃₅₆ | L_{b5} | 196 | Lₐ₃₅₆ | L_{b21} |
| 197 | Lₐ₃₇₅ | L_{b5} | 198 | Lₐ₃₇₅ | L_{b21} |
| 199 | Lₐ₄₂₂ | L_{b5} | 200 | Lₐ₄₂₂ | L_{b21} |
| 201 | Lₐ₄₂₇ | L_{b5} | 202 | Lₐ₄₂₇ | L_{b21} |
| 203 | Lₐ₄₅₀ | L_{b5} | 204 | Lₐ₄₅₀ | L_{b21} |
| 205 | Lₐ₄₇₃ | L_{b5} | 206 | Lₐ₄₇₃ | L_{b21} |
| 207 | Lₐ₄₉₆ | L_{b5} | 208 | Lₐ₄₉₆ | L_{b21} |
| 209 | Lₐ₆₀₆ | L_{b5} | 210 | Lₐ₆₀₆ | L_{b21} |
| 211 | Lₐ₆₁₁ | L_{b5} | 212 | Lₐ₆₁₁ | L_{b21} |
| 213 | Lₐ₆₃₄ | L_{b5} | 214 | Lₐ₆₃₄ | L_{b21} |
| 215 | Lₐ₈₉₉ | L_{b5} | 216 | Lₐ₈₉₉ | L_{b21} |
| 217 | Lₐ₉₂₃ | L_{b5} | 218 | Lₐ₉₂₃ | L_{b21} |
| 219 | Lₐ₉₉₇ | L_{b5} | 220 | Lₐ₉₉₇ | L_{b21} |
| 221 | Lₐ₁₁₀₆ | L_{b5} | 222 | Lₐ₁₁₀₆ | L_{b21} |
| 223 | Lₐ₁₁₀₈ | L_{b5} | 224 | Lₐ₁₁₀₈ | L_{b21} |
| 225 | Lₐ₁₁₁₂ | L_{b5} | 226 | Lₐ₁₁₁₂ | L_{b21} |
| 227 | Lₐ₁₁₁₄ | L_{b5} | 228 | Lₐ₁₁₁₄ | L_{b21} |
| 229 | Lₐ₁₁₁₈ | L_{b5} | 230 | Lₐ₁₁₁₈ | L_{b21} |
| 231 | Lₐ₁₁₂₀ | L_{b5} | 232 | Lₐ₁₁₂₀ | L_{b21} |
| 233 | Lₐ₁₂₁₈ | L_{b5} | 234 | Lₐ₁₂₁₈ | L_{b21} |
| 235 | Lₐ₁₂₁₉ | L_{b5} | 236 | Lₐ₁₂₁₉ | L_{b21} |
| 237 | Lₐ₁₃₀₂ | L_{b5} | 238 | Lₐ₁₃₀₂ | L_{b21} |
| 239 | Lₐ₁₃₀₇ | L_{b5} | 240 | Lₐ₁₃₀₇ | L_{b21} |
| 241 | Lₐ₁₄₇₃ | L_{b5} | 242 | Lₐ₁₄₇₃ | L_{b21} |
| 243 | Lₐ₁₄₈₇ | L_{b5} | 244 | Lₐ₁₄₈₇ | L_{b21} |
| 245 | Lₐ₁₄₉₁ | L_{b5} | 246 | Lₐ₁₄₉₁ | L_{b21} |
| 247 | Lₐ₁₇₁₀ | L_{b5} | 248 | Lₐ₁₇₁₀ | L_{b21} |
| 249 | Lₐ₁₇₄₀ | L_{b5} | 250 | Lₐ₁₇₄₀ | L_{b21} |
| 251 | Lₐ₁₇₄₅ | L_{b5} | 252 | Lₐ₁₇₄₅ | L_{b21} |
| 253 | Lₐ₅ | L_{b81} | 254 | Lₐ₅ | L_{b84} |
| 255 | Lₐ₂₇ | L_{b81} | 256 | Lₐ₂₇ | L_{b84} |
| 257 | Lₐ₂₈ | L_{b81} | 258 | Lₐ₂₈ | L_{b84} |
| 259 | Lₐ₂₉ | L_{b81} | 260 | Lₐ₂₉ | L_{b84} |
| 261 | Lₐ₃₀ | L_{b81} | 262 | Lₐ₃₀ | L_{b84} |
| 263 | Lₐ₃₃ | L_{b81} | 264 | Lₐ₃₃ | L_{b84} |
| 265 | Lₐ₃₅ | L_{b81} | 266 | Lₐ₃₅ | L_{b84} |
| 267 | Lₐ₃₇ | L_{b81} | 268 | Lₐ₃₇ | L_{b84} |
| 269 | Lₐ₄₁ | L_{b81} | 270 | Lₐ₄₁ | L_{b84} |
| 271 | Lₐ₄₃ | L_{b81} | 272 | Lₐ₄₃ | L_{b84} |
| 273 | Lₐ₅₁ | L_{b81} | 274 | Lₐ₅₁ | L_{b84} |
| 275 | Lₐ₅₆ | L_{b81} | 276 | Lₐ₅₆ | L_{b84} |
| 277 | Lₐ₅₈ | L_{b81} | 278 | Lₐ₅₈ | L_{b84} |
| 279 | Lₐ₇₄ | L_{b81} | 280 | Lₐ₇₄ | L_{b84} |
| 281 | Lₐ₇₉ | L_{b81} | 282 | Lₐ₇₉ | L_{b84} |
| 283 | Lₐ₈₁ | L_{b81} | 284 | Lₐ₈₁ | L_{b84} |
| 285 | Lₐ₉₇ | L_{b81} | 286 | Lₐ₉₇ | L_{b84} |
| 287 | Lₐ₁₀₂ | L_{b81} | 288 | Lₐ₁₀₂ | L_{b84} |
| 289 | Lₐ₁₀₄ | L_{b81} | 290 | Lₐ₁₀₄ | L_{b84} |
| 291 | Lₐ₁₂₀ | L_{b81} | 292 | Lₐ₁₂₀ | L_{b84} |
| 293 | Lₐ₁₂₅ | L_{b81} | 294 | Lₐ₁₂₅ | L_{b84} |
| 295 | Lₐ₂₁₂ | L_{b81} | 296 | Lₐ₂₁₂ | L_{b84} |
| 297 | Lₐ₂₁₄ | L_{b81} | 298 | Lₐ₂₁₄ | L_{b84} |
| 299 | Lₐ₂₁₇ | L_{b81} | 300 | Lₐ₂₁₇ | L_{b84} |
| 301 | Lₐ₂₁₉ | L_{b81} | 302 | Lₐ₂₁₉ | L_{b84} |
| 303 | Lₐ₂₂₆ | L_{b81} | 304 | Lₐ₂₂₆ | L_{b84} |
| 305 | Lₐ₃₀₄ | L_{b81} | 306 | Lₐ₃₀₄ | L_{b84} |
| 307 | Lₐ₃₀₆ | L_{b81} | 308 | Lₐ₃₀₆ | L_{b84} |
| 309 | Lₐ₃₀₉ | L_{b81} | 310 | Lₐ₃₀₉ | L_{b84} |
| 311 | Lₐ₃₁₁ | L_{b81} | 312 | Lₐ₃₁₁ | L_{b84} |
| 313 | Lₐ₃₂₁ | L_{b81} | 314 | Lₐ₃₂₁ | L_{b84} |
| 315 | Lₐ₃₂₃ | L_{b81} | 316 | Lₐ₃₂₃ | L_{b84} |
| 317 | Lₐ₃₃₂ | L_{b81} | 318 | Lₐ₃₃₂ | L_{b84} |
| 319 | Lₐ₃₅₁ | L_{b81} | 320 | Lₐ₃₅₁ | L_{b84} |
| 321 | Lₐ₃₅₆ | L_{b81} | 322 | Lₐ₃₅₆ | L_{b84} |
| 323 | Lₐ₃₇₅ | L_{b81} | 324 | Lₐ₃₇₅ | L_{b84} |
| 325 | Lₐ₄₂₂ | L_{b81} | 326 | Lₐ₄₂₂ | L_{b84} |
| 327 | Lₐ₄₂₇ | L_{b81} | 328 | Lₐ₄₂₇ | L_{b84} |
| 329 | Lₐ₄₅₀ | L_{b81} | 330 | Lₐ₄₅₀ | L_{b84} |
| 331 | Lₐ₄₇₃ | L_{b81} | 332 | Lₐ₄₇₃ | L_{b84} |
| 333 | Lₐ₄₉₆ | L_{b81} | 334 | Lₐ₄₉₆ | L_{b84} |
| 335 | Lₐ₆₀₆ | L_{b81} | 336 | Lₐ₆₀₆ | L_{b84} |
| 337 | Lₐ₆₁₁ | L_{b81} | 338 | Lₐ₆₁₁ | L_{b84} |
| 339 | Lₐ₆₃₄ | L_{b81} | 340 | Lₐ₆₃₄ | L_{b84} |
| 341 | Lₐ₈₉₉ | L_{b81} | 342 | Lₐ₈₉₉ | L_{b84} |
| 343 | Lₐ₉₂₃ | L_{b81} | 344 | Lₐ₉₂₃ | L_{b84} |
| 345 | Lₐ₉₉₇ | L_{b81} | 346 | Lₐ₉₉₇ | L_{b84} |
| 347 | Lₐ₁₁₀₆ | L_{b81} | 348 | Lₐ₁₁₀₆ | L_{b84} |
| 349 | Lₐ₁₁₀₈ | L_{b81} | 350 | Lₐ₁₁₀₈ | L_{b84} |
| 351 | Lₐ₁₁₁₂ | L_{b81} | 352 | Lₐ₁₁₁₂ | L_{b84} |
| 353 | Lₐ₁₁₁₄ | L_{b81} | 354 | Lₐ₁₁₁₄ | L_{b84} |
| 355 | Lₐ₁₁₁₈ | L_{b81} | 356 | Lₐ₁₁₁₈ | L_{b84} |
| 357 | Lₐ₁₁₂₀ | L_{b81} | 358 | Lₐ₁₁₂₀ | L_{b84} |
| 359 | Lₐ₁₂₁₈ | L_{b81} | 360 | Lₐ₁₂₁₈ | L_{b84} |
| 361 | Lₐ₁₂₁₉ | L_{b81} | 362 | Lₐ₁₂₁₉ | L_{b84} |
| 363 | Lₐ₁₃₀₂ | L_{b81} | 364 | Lₐ₁₃₀₂ | L_{b84} |
| 365 | Lₐ₁₃₀₇ | L_{b81} | 366 | Lₐ₁₃₀₇ | L_{b84} |
| 367 | Lₐ₁₄₇₃ | L_{b81} | 368 | Lₐ₁₄₇₃ | L_{b84} |
| 369 | Lₐ₁₄₈₇ | L_{b81} | 370 | Lₐ₁₄₈₇ | L_{b84} |
| 371 | Lₐ₁₄₉₁ | L_{b81} | 372 | Lₐ₁₄₉₁ | L_{b84} |
| 373 | Lₐ₁₇₁₀ | L_{b81} | 374 | Lₐ₁₇₁₀ | L_{b84} |
| 375 | Lₐ₁₇₄₀ | L_{b81} | 376 | Lₐ₁₇₄₀ | L_{b84} |
| 377 | Lₐ₁₇₄₅ | L_{b81} | 378 | Lₐ₁₇₄₅ | L_{b84} |
| 379 | Lₐ₅ | L_{b85} | 380 | Lₐ₅ | L_{b99} |
| 381 | Lₐ₂₇ | L_{b85} | 382 | Lₐ₂₇ | L_{b99} |
| 383 | Lₐ₂₈ | L_{b85} | 384 | Lₐ₂₈ | L_{b99} |
| 385 | Lₐ₂₉ | L_{b85} | 386 | Lₐ₂₉ | L_{b99} |
| 387 | Lₐ₃₀ | L_{b85} | 388 | Lₐ₃₀ | L_{b99} |
| 389 | Lₐ₃₃ | L_{b85} | 390 | Lₐ₃₃ | L_{b99} |
| 391 | Lₐ₃₅ | L_{b85} | 392 | Lₐ₃₅ | L_{b99} |
| 393 | Lₐ₃₇ | L_{b85} | 394 | Lₐ₃₇ | L_{b99} |
| 395 | Lₐ₄₁ | L_{b85} | 396 | Lₐ₄₁ | L_{b99} |
| 397 | Lₐ₄₃ | L_{b85} | 398 | Lₐ₄₃ | L_{b99} |
| 399 | Lₐ₅₁ | L_{b85} | 400 | Lₐ₅₁ | L_{b99} |
| 401 | Lₐ₅₆ | L_{b85} | 402 | Lₐ₅₆ | L_{b99} |
| 403 | Lₐ₅₈ | L_{b85} | 404 | Lₐ₅₈ | L_{b99} |
| 405 | Lₐ₇₄ | L_{b85} | 406 | Lₐ₇₄ | L_{b99} |
| 407 | Lₐ₇₉ | L_{b85} | 408 | Lₐ₇₉ | L_{b99} |
| 409 | Lₐ₈₁ | L_{b85} | 410 | Lₐ₈₁ | L_{b99} |
| 411 | Lₐ₉₇ | L_{b85} | 412 | Lₐ₉₇ | L_{b99} |
| 413 | Lₐ₁₀₂ | L_{b85} | 414 | Lₐ₁₀₂ | L_{b99} |
| 415 | Lₐ₁₀₄ | L_{b85} | 416 | Lₐ₁₀₄ | L_{b99} |
| 417 | Lₐ₁₂₀ | L_{b85} | 418 | Lₐ₁₂₀ | L_{b99} |
| 419 | Lₐ₁₂₅ | L_{b85} | 420 | Lₐ₁₂₅ | L_{b99} |
| 421 | Lₐ₂₁₂ | L_{b85} | 422 | Lₐ₂₁₂ | L_{b99} |
| 423 | Lₐ₂₁₄ | L_{b85} | 424 | Lₐ₂₁₄ | L_{b99} |
| 425 | Lₐ₂₁₇ | L_{b85} | 426 | Lₐ₂₁₇ | L_{b99} |
| 427 | Lₐ₂₁₉ | L_{b85} | 428 | Lₐ₂₁₉ | L_{b99} |
| 429 | Lₐ₂₂₆ | L_{b85} | 430 | Lₐ₂₂₆ | L_{b99} |
| 431 | Lₐ₃₀₄ | L_{b85} | 432 | Lₐ₃₀₄ | L_{b99} |
| 433 | Lₐ₃₀₆ | L_{b85} | 434 | Lₐ₃₀₆ | L_{b99} |
| 435 | Lₐ₃₀₉ | L_{b85} | 436 | Lₐ₃₀₉ | L_{b99} |
| 437 | Lₐ₃₁₁ | L_{b85} | 438 | Lₐ₃₁₁ | L_{b99} |
| 439 | Lₐ₃₂₁ | L_{b85} | 440 | Lₐ₃₂₁ | L_{b99} |
| 441 | Lₐ₃₂₃ | L_{b85} | 442 | Lₐ₃₂₃ | L_{b99} |
| 443 | Lₐ₃₃₂ | L_{b85} | 444 | Lₐ₃₃₂ | L_{b99} |
| 445 | Lₐ₃₅₁ | L_{b85} | 446 | Lₐ₃₅₁ | L_{b99} |
| 447 | Lₐ₃₅₆ | L_{b85} | 448 | Lₐ₃₅₆ | L_{b99} |
| 449 | Lₐ₃₇₅ | L_{b85} | 450 | Lₐ₃₇₅ | L_{b99} |
| 451 | Lₐ₄₂₂ | L_{b85} | 452 | Lₐ₄₂₂ | L_{b99} |
| 453 | Lₐ₄₂₇ | L_{b85} | 454 | Lₐ₄₂₇ | L_{b99} |
| 455 | Lₐ₄₅₀ | L_{b85} | 456 | Lₐ₄₅₀ | L_{b99} |
| 457 | Lₐ₄₇₃ | L_{b85} | 458 | Lₐ₄₇₃ | L_{b99} |
| 459 | Lₐ₄₉₆ | L_{b85} | 460 | Lₐ₄₉₆ | L_{b99} |
| 461 | Lₐ₆₀₆ | L_{b85} | 462 | Lₐ₆₀₆ | L_{b99} |
| 463 | Lₐ₆₁₁ | L_{b85} | 464 | Lₐ₆₁₁ | L_{b99} |
| 465 | Lₐ₆₃₄ | L_{b85} | 466 | Lₐ₆₃₄ | L_{b99} |
| 467 | Lₐ₈₉₉ | L_{b85} | 468 | Lₐ₈₉₉ | L_{b99} |
| 469 | Lₐ₉₂₃ | L_{b85} | 470 | Lₐ₉₂₃ | L_{b99} |
| 471 | Lₐ₉₉₇ | L_{b85} | 472 | Lₐ₉₉₇ | L_{b99} |
| 473 | Lₐ₁₁₀₆ | L_{b85} | 474 | Lₐ₁₁₀₆ | L_{b99} |
| 475 | Lₐ₁₁₀₈ | L_{b85} | 476 | Lₐ₁₁₀₈ | L_{b99} |
| 477 | Lₐ₁₁₁₂ | L_{b85} | 478 | Lₐ₁₁₁₂ | L_{b99} |
| 479 | Lₐ₁₁₁₄ | L_{b85} | 480 | Lₐ₁₁₁₄ | L_{b99} |
| 481 | Lₐ₁₁₁₈ | L_{b85} | 482 | Lₐ₁₁₁₈ | L_{b99} |
| 483 | Lₐ₁₁₂₀ | L_{b85} | 484 | Lₐ₁₁₂₀ | L_{b99} |
| 485 | Lₐ₁₂₁₈ | L_{b85} | 486 | Lₐ₁₂₁₈ | L_{b99} |
| 487 | Lₐ₁₂₁₉ | L_{b85} | 488 | Lₐ₁₂₁₉ | L_{b99} |
| 489 | Lₐ₁₃₀₂ | L_{b85} | 490 | Lₐ₁₃₀₂ | L_{b99} |
| 491 | Lₐ₁₃₀₇ | L_{b85} | 492 | Lₐ₁₃₀₇ | L_{b99} |
| 493 | Lₐ₁₄₇₃ | L_{b85} | 494 | Lₐ₁₄₇₃ | L_{b99} |
| 495 | Lₐ₁₄₈₇ | L_{b85} | 496 | Lₐ₁₄₈₇ | L_{b99} |
| 497 | Lₐ₁₄₉₁ | L_{b85} | 498 | Lₐ₁₄₉₁ | L_{b99} |
| 499 | Lₐ₁₇₁₀ | L_{b85} | 500 | Lₐ₁₇₁₀ | L_{b99} |
| 501 | Lₐ₁₇₄₀ | L_{b85} | 502 | Lₐ₁₇₄₀ | L_{b99} |
| 503 | Lₐ₁₇₄₅ | L_{b85} | 504 | Lₐ₁₇₄₅ | L_{b99} |
| 505 | Lₐ₅ | L_{b102} | 506 | Lₐ₅ | L_{b112} |
| 507 | Lₐ₂₇ | L_{b102} | 508 | Lₐ₂₇ | L_{b112} |
| 509 | Lₐ₂₈ | L_{b102} | 510 | Lₐ₂₈ | L_{b112} |
| 511 | Lₐ₂₉ | L_{b102} | 512 | Lₐ₂₉ | L_{b112} |
| 513 | Lₐ₃₀ | L_{b102} | 514 | Lₐ₃₀ | L_{b112} |
| 515 | Lₐ₃₃ | L_{b102} | 516 | Lₐ₃₃ | L_{b112} |
| 517 | Lₐ₃₅ | L_{b102} | 518 | Lₐ₃₅ | L_{b112} |
| 519 | Lₐ₃₇ | L_{b102} | 520 | Lₐ₃₇ | L_{b112} |
| 521 | Lₐ₄₁ | L_{b102} | 522 | Lₐ₄₁ | L_{b112} |
| 523 | Lₐ₄₃ | L_{b102} | 524 | Lₐ₄₃ | L_{b112} |
| 525 | Lₐ₅₁ | L_{b102} | 526 | Lₐ₅₁ | L_{b112} |
| 527 | Lₐ₅₆ | L_{b102} | 528 | Lₐ₅₆ | L_{b112} |
| 529 | Lₐ₅₈ | L_{b102} | 530 | Lₐ₅₈ | L_{b112} |
| 531 | Lₐ₇₄ | L_{b102} | 532 | Lₐ₇₄ | L_{b112} |
| 533 | Lₐ₇₉ | L_{b102} | 534 | Lₐ₇₉ | L_{b112} |
| 535 | Lₐ₈₁ | L_{b102} | 536 | Lₐ₈₁ | L_{b112} |
| 537 | Lₐ₉₇ | L_{b102} | 538 | Lₐ₉₇ | L_{b112} |
| 539 | Lₐ₁₀₂ | L_{b102} | 540 | Lₐ₁₀₂ | L_{b112} |
| 541 | Lₐ₁₀₄ | L_{b102} | 542 | Lₐ₁₀₄ | L_{b112} |
| 543 | Lₐ₁₂₀ | L_{b102} | 544 | Lₐ₁₂₀ | L_{b112} |
| 545 | Lₐ₁₂₅ | L_{b102} | 546 | Lₐ₁₂₅ | L_{b112} |
| 547 | Lₐ₂₁₂ | L_{b102} | 548 | Lₐ₂₁₂ | L_{b112} |
| 549 | Lₐ₂₁₄ | L_{b102} | 550 | Lₐ₂₁₄ | L_{b112} |
| 551 | Lₐ₂₁₇ | L_{b102} | 552 | Lₐ₂₁₇ | L_{b112} |
| 553 | Lₐ₂₁₉ | L_{b102} | 554 | Lₐ₂₁₉ | L_{b112} |
| 555 | Lₐ₂₂₆ | L_{b102} | 556 | Lₐ₂₂₆ | L_{b112} |
| 557 | Lₐ₃₀₄ | L_{b102} | 558 | Lₐ₃₀₄ | L_{b112} |
| 559 | Lₐ₃₀₆ | L_{b102} | 560 | Lₐ₃₀₆ | L_{b112} |
| 561 | Lₐ₃₀₉ | L_{b102} | 562 | Lₐ₃₀₉ | L_{b112} |
| 563 | Lₐ₃₁₁ | L_{b102} | 564 | Lₐ₃₁₁ | L_{b112} |
| 565 | Lₐ₃₂₁ | L_{b102} | 566 | Lₐ₃₂₁ | L_{b112} |
| 567 | Lₐ₃₂₃ | L_{b102} | 568 | Lₐ₃₂₃ | L_{b112} |
| 569 | Lₐ₃₃₂ | L_{b102} | 570 | Lₐ₃₃₂ | L_{b112} |
| 571 | Lₐ₃₅₁ | L_{b102} | 572 | Lₐ₃₅₁ | L_{b112} |
| 573 | Lₐ₃₅₆ | L_{b102} | 574 | Lₐ₃₅₆ | L_{b112} |
| 575 | Lₐ₃₇₅ | L_{b102} | 576 | Lₐ₃₇₅ | L_{b112} |
| 577 | Lₐ₄₂₂ | L_{b102} | 578 | Lₐ₄₂₂ | L_{b112} |
| 579 | Lₐ₄₂₇ | L_{b102} | 580 | Lₐ₄₂₇ | L_{b112} |
| 581 | Lₐ₄₅₀ | L_{b102} | 582 | Lₐ₄₅₀ | L_{b112} |
| 583 | Lₐ₄₇₃ | L_{b102} | 584 | Lₐ₄₇₃ | L_{b112} |
| 585 | Lₐ₄₉₆ | L_{b102} | 586 | Lₐ₄₉₆ | L_{b112} |
| 587 | Lₐ₆₀₆ | L_{b102} | 588 | Lₐ₆₀₆ | L_{b112} |
| 589 | Lₐ₆₁₁ | L_{b102} | 590 | Lₐ₆₁₁ | L_{b112} |
| 591 | Lₐ₆₃₄ | L_{b102} | 592 | Lₐ₆₃₄ | L_{b112} |
| 593 | Lₐ₈₉₉ | L_{b102} | 594 | Lₐ₈₉₉ | L_{b112} |
| 595 | Lₐ₉₂₃ | L_{b102} | 596 | Lₐ₉₂₃ | L_{b112} |
| 597 | Lₐ₉₉₇ | L_{b102} | 598 | Lₐ₉₉₇ | L_{b112} |
| 599 | Lₐ₁₁₀₆ | L_{b102} | 600 | Lₐ₁₁₀₆ | L_{b112} |
| 601 | Lₐ₁₁₀₈ | L_{b102} | 602 | Lₐ₁₁₀₈ | L_{b112} |
| 603 | Lₐ₁₁₁₂ | L_{b102} | 604 | Lₐ₁₁₁₂ | L_{b112} |
| 605 | Lₐ₁₁₁₄ | L_{b102} | 606 | Lₐ₁₁₁₄ | L_{b112} |
| 607 | Lₐ₁₁₁₈ | L_{b102} | 608 | Lₐ₁₁₁₈ | L_{b112} |
| 609 | Lₐ₁₁₂₀ | L_{b102} | 610 | Lₐ₁₁₂₀ | L_{b112} |
| 611 | Lₐ₁₂₁₈ | L_{b102} | 612 | Lₐ₁₂₁₈ | L_{b112} |
| 613 | Lₐ₁₂₁₉ | L_{b102} | 614 | Lₐ₁₂₁₉ | L_{b112} |
| 615 | Lₐ₁₃₀₂ | L_{b102} | 616 | Lₐ₁₃₀₂ | L_{b112} |
| 617 | Lₐ₁₃₀₇ | L_{b102} | 618 | Lₐ₁₃₀₇ | L_{b112} |
| 619 | Lₐ₁₄₇₃ | L_{b102} | 620 | Lₐ₁₄₇₃ | L_{b112} |
| 621 | Lₐ₁₄₈₇ | L_{b102} | 622 | Lₐ₁₄₈₇ | L_{b112} |
| 623 | Lₐ₁₄₉₁ | L_{b102} | 624 | Lₐ₁₄₉₁ | L_{b112} |
| 625 | Lₐ₁₇₁₀ | L_{b102} | 626 | Lₐ₁₇₁₀ | L_{b112} |
| 627 | Lₐ₁₇₄₀ | L_{b102} | 628 | Lₐ₁₇₄₀ | L_{b112} |
| 629 | Lₐ₁₇₄₅ | L_{b102} | 630 | Lₐ₁₇₄₅ | L_{b112} |
| 631 | Lₐ₅ | L_{b151} | 632 | Lₐ₅ | L_{b164} |
| 633 | Lₐ₂₇ | L_{b151} | 634 | Lₐ₂₇ | L_{b164} |
| 635 | Lₐ₂₈ | L_{b151} | 636 | Lₐ₂₈ | L_{b164} |
| 637 | Lₐ₂₉ | L_{b151} | 638 | Lₐ₂₉ | L_{b164} |
| 639 | Lₐ₃₀ | L_{b151} | 640 | Lₐ₃₀ | L_{b164} |
| 641 | Lₐ₃₃ | L_{b151} | 642 | Lₐ₃₃ | L_{b164} |
| 643 | Lₐ₃₅ | L_{b151} | 644 | Lₐ₃₅ | L_{b164} |
| 645 | Lₐ₃₇ | L_{b151} | 646 | Lₐ₃₇ | L_{b164} |
| 647 | Lₐ₄₁ | L_{b151} | 648 | Lₐ₄₁ | L_{b164} |
| 649 | Lₐ₄₃ | L_{b151} | 650 | Lₐ₄₃ | L_{b164} |
| 651 | Lₐ₅₁ | L_{b151} | 652 | Lₐ₅₁ | L_{b164} |
| 653 | Lₐ₅₆ | L_{b151} | 654 | Lₐ₅₆ | L_{b164} |
| 655 | Lₐ₅₈ | L_{b151} | 656 | Lₐ₅₈ | L_{b164} |
| 657 | Lₐ₇₄ | L_{b151} | 658 | Lₐ₇₄ | L_{b164} |
| 659 | Lₐ₇₉ | L_{b151} | 660 | Lₐ₇₉ | L_{b164} |
| 661 | Lₐ₈₁ | L_{b151} | 662 | Lₐ₈₁ | L_{b164} |
| 663 | Lₐ₉₇ | L_{b151} | 664 | Lₐ₉₇ | L_{b164} |
| 665 | Lₐ₁₀₂ | L_{b151} | 666 | Lₐ₁₀₂ | L_{b164} |
| 667 | Lₐ₁₀₄ | L_{b151} | 668 | Lₐ₁₀₄ | L_{b164} |
| 669 | Lₐ₁₂₀ | L_{b151} | 670 | Lₐ₁₂₀ | L_{b164} |
| 671 | Lₐ₁₂₅ | L_{b151} | 672 | Lₐ₁₂₅ | L_{b164} |
| 673 | Lₐ₂₁₂ | L_{b151} | 674 | Lₐ₂₁₂ | L_{b164} |
| 675 | Lₐ₂₁₄ | L_{b151} | 676 | Lₐ₂₁₄ | L_{b164} |
| 677 | Lₐ₂₁₇ | L_{b151} | 678 | Lₐ₂₁₇ | L_{b164} |
| 679 | Lₐ₂₁₉ | L_{b151} | 680 | Lₐ₂₁₉ | L_{b164} |
| 681 | Lₐ₂₂₆ | L_{b151} | 682 | Lₐ₂₂₆ | L_{b164} |
| 683 | Lₐ₃₀₄ | L_{b151} | 684 | Lₐ₃₀₄ | L_{b164} |
| 685 | Lₐ₃₀₆ | L_{b151} | 686 | Lₐ₃₀₆ | L_{b164} |
| 687 | Lₐ₃₀₉ | L_{b151} | 688 | Lₐ₃₀₉ | L_{b164} |
| 689 | Lₐ₃₁₁ | L_{b151} | 690 | Lₐ₃₁₁ | L_{b164} |
| 691 | Lₐ₃₂₁ | L_{b151} | 692 | Lₐ₃₂₁ | L_{b164} |
| 693 | Lₐ₃₂₃ | L_{b151} | 694 | Lₐ₃₂₃ | L_{b164} |
| 695 | Lₐ₃₃₂ | L_{b151} | 696 | Lₐ₃₃₂ | L_{b164} |
| 697 | Lₐ₃₅₁ | L_{b151} | 698 | Lₐ₃₅₁ | L_{b164} |
| 699 | Lₐ₃₅₆ | L_{b151} | 700 | Lₐ₃₅₆ | L_{b164} |
| 701 | Lₐ₃₇₅ | L_{b151} | 702 | Lₐ₃₇₅ | L_{b164} |
| 703 | Lₐ₄₂₂ | L_{b151} | 704 | Lₐ₄₂₂ | L_{b164} |
| 705 | Lₐ₄₂₇ | L_{b151} | 706 | Lₐ₄₂₇ | L_{b164} |
| 707 | Lₐ₄₅₀ | L_{b151} | 708 | Lₐ₄₅₀ | L_{b164} |
| 709 | Lₐ₄₇₃ | L_{b151} | 710 | Lₐ₄₇₃ | L_{b164} |
| 711 | Lₐ₄₉₆ | L_{b151} | 712 | Lₐ₄₉₆ | L_{b164} |
| 713 | Lₐ₆₀₆ | L_{b151} | 714 | Lₐ₆₀₆ | L_{b164} |
| 715 | Lₐ₆₁₁ | L_{b151} | 716 | Lₐ₆₁₁ | L_{b164} |
| 717 | Lₐ₆₃₄ | L_{b151} | 718 | Lₐ₆₃₄ | L_{b164} |
| 719 | Lₐ₈₉₉ | L_{b151} | 720 | Lₐ₈₉₉ | L_{b164} |
| 721 | Lₐ₉₂₃ | L_{b151} | 722 | Lₐ₉₂₃ | L_{b164} |
| 723 | Lₐ₉₉₇ | L_{b151} | 724 | Lₐ₉₉₇ | L_{b164} |
| 725 | Lₐ₁₁₀₆ | L_{b151} | 726 | Lₐ₁₁₀₆ | L_{b164} |
| 727 | Lₐ₁₁₀₈ | L_{b151} | 728 | Lₐ₁₁₀₈ | L_{b164} |
| 729 | Lₐ₁₁₁₂ | L_{b151} | 730 | Lₐ₁₁₁₂ | L_{b164} |
| 731 | Lₐ₁₁₁₄ | L_{b151} | 732 | Lₐ₁₁₁₄ | L_{b164} |
| 733 | Lₐ₁₁₁₈ | L_{b151} | 734 | Lₐ₁₁₁₈ | L_{b164} |
| 735 | Lₐ₁₁₂₀ | L_{b151} | 736 | Lₐ₁₁₂₀ | L_{b164} |
| 737 | Lₐ₁₂₁₈ | L_{b151} | 738 | Lₐ₁₂₁₈ | L_{b164} |
| 739 | Lₐ₁₂₁₉ | L_{b151} | 740 | Lₐ₁₂₁₉ | L_{b164} |
| 741 | Lₐ₁₃₀₂ | L_{b151} | 742 | Lₐ₁₃₀₂ | L_{b164} |
| 743 | Lₐ₁₃₀₇ | L_{b151} | 744 | Lₐ₁₃₀₇ | L_{b164} |
| 745 | Lₐ₁₄₇₃ | L_{b151} | 746 | Lₐ₁₄₇₃ | L_{b164} |
| 747 | Lₐ₁₄₈₇ | L_{b151} | 748 | Lₐ₁₄₈₇ | L_{b164} |
| 749 | Lₐ₁₄₉₁ | L_{b151} | 750 | Lₐ₁₄₉₁ | L_{b164} |
| 751 | Lₐ₁₇₁₀ | L_{b151} | 752 | Lₐ₁₇₁₀ | L_{b164} |
| 753 | Lₐ₁₇₄₀ | L_{b151} | 754 | Lₐ₁₇₄₀ | L_{b164} |
| 755 | Lₐ₁₇₄₅ | L_{b151} | 756 | Lₐ₁₇₄₅ | L_{b164} |
| 757 | Lₐ₅ | L_{b187} | 758 | Lₐ₅ | L_{b209} |
| 759 | Lₐ₂₇ | L_{b187} | 760 | Lₐ₂₇ | L_{b209} |
| 761 | Lₐ₂₈ | L_{b187} | 762 | Lₐ₂₈ | L_{b209} |
| 763 | Lₐ₂₉ | L_{b187} | 764 | Lₐ₂₉ | L_{b209} |
| 765 | Lₐ₃₀ | L_{b187} | 766 | Lₐ₃₀ | L_{b209} |
| 767 | Lₐ₃₃ | L_{b187} | 768 | Lₐ₃₃ | L_{b209} |
| 769 | Lₐ₃₅ | L_{b187} | 770 | Lₐ₃₅ | L_{b209} |
| 771 | Lₐ₃₇ | L_{b187} | 772 | Lₐ₃₇ | L_{b209} |
| 773 | Lₐ₄₁ | L_{b187} | 774 | Lₐ₄₁ | L_{b209} |
| 775 | Lₐ₄₃ | L_{b187} | 776 | Lₐ₄₃ | L_{b209} |
| 777 | Lₐ₅₁ | L_{b187} | 778 | Lₐ₅₁ | L_{b209} |
| 779 | Lₐ₅₆ | L_{b187} | 780 | Lₐ₅₆ | L_{b209} |
| 781 | Lₐ₅₈ | L_{b187} | 782 | Lₐ₅₈ | L_{b209} |
| 783 | Lₐ₇₄ | L_{b187} | 784 | Lₐ₇₄ | L_{b209} |
| 785 | Lₐ₇₉ | L_{b187} | 786 | Lₐ₇₉ | L_{b209} |
| 787 | Lₐ₈₁ | L_{b187} | 788 | Lₐ₈₁ | L_{b209} |
| 789 | Lₐ₉₇ | L_{b187} | 790 | Lₐ₉₇ | L_{b209} |
| 791 | Lₐ₁₀₂ | L_{b187} | 792 | Lₐ₁₀₂ | L_{b209} |
| 793 | Lₐ₁₀₄ | L_{b187} | 794 | Lₐ₁₀₄ | L_{b209} |
| 795 | Lₐ₁₂₀ | L_{b187} | 796 | Lₐ₁₂₀ | L_{b209} |
| 797 | Lₐ₁₂₅ | L_{b187} | 798 | Lₐ₁₂₅ | L_{b209} |
| 799 | Lₐ₂₁₂ | L_{b187} | 800 | Lₐ₂₁₂ | L_{b209} |
| 801 | Lₐ₂₁₄ | L_{b187} | 802 | Lₐ₂₁₄ | L_{b209} |
| 803 | Lₐ₂₁₇ | L_{b187} | 804 | Lₐ₂₁₇ | L_{b209} |
| 805 | Lₐ₂₁₉ | L_{b187} | 806 | Lₐ₂₁₉ | L_{b209} |
| 807 | Lₐ₂₂₆ | L_{b187} | 808 | Lₐ₂₂₆ | L_{b209} |
| 809 | Lₐ₃₀₄ | L_{b187} | 810 | Lₐ₃₀₄ | L_{b209} |
| 811 | Lₐ₃₀₆ | L_{b187} | 812 | Lₐ₃₀₆ | L_{b209} |
| 813 | Lₐ₃₀₉ | L_{b187} | 814 | Lₐ₃₀₉ | L_{b209} |
| 815 | Lₐ₃₁₁ | L_{b187} | 816 | Lₐ₃₁₁ | L_{b209} |
| 817 | Lₐ₃₂₁ | L_{b187} | 818 | Lₐ₃₂₁ | L_{b209} |
| 819 | Lₐ₃₂₃ | L_{b187} | 820 | Lₐ₃₂₃ | L_{b209} |
| 821 | Lₐ₃₃₂ | L_{b187} | 822 | Lₐ₃₃₂ | L_{b209} |
| 823 | Lₐ₃₅₁ | L_{b187} | 824 | Lₐ₃₅₁ | L_{b209} |
| 825 | Lₐ₃₅₆ | L_{b187} | 826 | Lₐ₃₅₆ | L_{b209} |
| 827 | Lₐ₃₇₅ | L_{b187} | 828 | Lₐ₃₇₅ | L_{b209} |
| 829 | Lₐ₄₂₂ | L_{b187} | 830 | Lₐ₄₂₂ | L_{b209} |
| 831 | Lₐ₄₂₇ | L_{b187} | 832 | Lₐ₄₂₇ | L_{b209} |
| 833 | Lₐ₄₅₀ | L_{b187} | 834 | Lₐ₄₅₀ | L_{b209} |
| 835 | Lₐ₄₇₃ | L_{b187} | 836 | Lₐ₄₇₃ | L_{b209} |
| 837 | Lₐ₄₉₆ | L_{b187} | 838 | Lₐ₄₉₆ | L_{b209} |
| 839 | Lₐ₆₀₆ | L_{b187} | 840 | Lₐ₆₀₆ | L_{b209} |
| 841 | Lₐ₆₁₁ | L_{b187} | 842 | Lₐ₆₁₁ | L_{b209} |
| 843 | Lₐ₆₃₄ | L_{b187} | 844 | Lₐ₆₃₄ | L_{b209} |
| 845 | Lₐ₈₉₉ | L_{b187} | 846 | Lₐ₈₉₉ | L_{b209} |
| 847 | Lₐ₉₂₃ | L_{b187} | 848 | Lₐ₉₂₃ | L_{b209} |
| 849 | Lₐ₉₉₇ | L_{b187} | 850 | Lₐ₉₉₇ | L_{b209} |
| 851 | Lₐ₁₁₀₆ | L_{b187} | 852 | Lₐ₁₁₀₆ | L_{b209} |
| 853 | Lₐ₁₁₀₈ | L_{b187} | 854 | Lₐ₁₁₀₈ | L_{b209} |
| 855 | Lₐ₁₁₁₂ | L_{b187} | 856 | Lₐ₁₁₁₂ | L_{b209} |
| 857 | Lₐ₁₁₁₄ | L_{b187} | 858 | Lₐ₁₁₁₄ | L_{b209} |
| 859 | Lₐ₁₁₁₈ | L_{b187} | 860 | Lₐ₁₁₁₈ | L_{b209} |
| 861 | Lₐ₁₁₂₀ | L_{b187} | 862 | Lₐ₁₁₂₀ | L_{b209} |
| 863 | Lₐ₁₂₁₈ | L_{b187} | 864 | Lₐ₁₂₁₈ | L_{b209} |
| 865 | Lₐ₁₂₁₉ | L_{b187} | 866 | Lₐ₁₂₁₉ | L_{b209} |
| 867 | Lₐ₁₃₀₂ | L_{b187} | 868 | Lₐ₁₃₀₂ | L_{b209} |
| 869 | Lₐ₁₃₀₇ | L_{b187} | 870 | Lₐ₁₃₀₇ | L_{b209} |
| 871 | Lₐ₁₄₇₃ | L_{b187} | 872 | Lₐ₁₄₇₃ | L_{b209} |
| 873 | Lₐ₁₄₈₇ | L_{b187} | 874 | Lₐ₁₄₈₇ | L_{b209} |
| 875 | Lₐ₁₄₉₁ | L_{b187} | 876 | Lₐ₁₄₉₁ | L_{b209} |
| 877 | Lₐ₁₇₁₀ | L_{b187} | 878 | Lₐ₁₇₁₀ | L_{b209} |
| 879 | Lₐ₁₇₄₀ | L_{b187} | 880 | Lₐ₁₇₄₀ | L_{b209} |
| 881 | Lₐ₁₇₄₅ | L_{b187} | 882 | Lₐ₁₇₄₅ | L_{b209} |
| 883 | Lₐ₅ | L_{b214} | 884 | Lₐ₅ | L_{b215} |
| 885 | Lₐ₂₇ | L_{b214} | 886 | Lₐ₂₇ | L_{b215} |
| 887 | Lₐ₂₈ | L_{b214} | 888 | Lₐ₂₈ | L_{b215} |
| 889 | Lₐ₂₉ | L_{b214} | 890 | Lₐ₂₉ | L_{b215} |
| 891 | Lₐ₃₀ | L_{b214} | 892 | Lₐ₃₀ | L_{b215} |
| 893 | Lₐ₃₃ | L_{b214} | 894 | Lₐ₃₃ | L_{b215} |
| 895 | Lₐ₃₅ | L_{b214} | 896 | Lₐ₃₅ | L_{b215} |
| 897 | Lₐ₃₇ | L_{b214} | 898 | Lₐ₃₇ | L_{b215} |
| 899 | Lₐ₄₁ | L_{b214} | 900 | Lₐ₄₁ | L_{b215} |
| 901 | Lₐ₄₃ | L_{b214} | 902 | Lₐ₄₃ | L_{b215} |
| 903 | Lₐ₅₁ | L_{b214} | 904 | Lₐ₅₁ | L_{b215} |
| 905 | Lₐ₅₆ | L_{b214} | 906 | Lₐ₅₆ | L_{b215} |
| 907 | Lₐ₅₈ | L_{b214} | 908 | Lₐ₅₈ | L_{b215} |
| 909 | Lₐ₇₄ | L_{b214} | 910 | Lₐ₇₄ | L_{b215} |
| 911 | Lₐ₇₉ | L_{b214} | 912 | Lₐ₇₉ | L_{b215} |
| 913 | Lₐ₈₁ | L_{b214} | 914 | Lₐ₈₁ | L_{b215} |
| 915 | Lₐ₉₇ | L_{b214} | 916 | Lₐ₉₇ | L_{b215} |
| 917 | Lₐ₁₀₂ | L_{b214} | 918 | Lₐ₁₀₂ | L_{b215} |
| 919 | Lₐ₁₀₄ | L_{b214} | 920 | Lₐ₁₀₄ | L_{b215} |
| 921 | Lₐ₁₂₀ | L_{b214} | 922 | Lₐ₁₂₀ | L_{b215} |
| 923 | Lₐ₁₂₅ | L_{b214} | 924 | Lₐ₁₂₅ | L_{b215} |
| 925 | Lₐ₂₁₂ | L_{b214} | 926 | Lₐ₂₁₂ | L_{b215} |
| 927 | Lₐ₂₁₄ | L_{b214} | 928 | Lₐ₂₁₄ | L_{b215} |
| 929 | Lₐ₂₁₇ | L_{b214} | 930 | Lₐ₂₁₇ | L_{b215} |
| 931 | Lₐ₂₁₉ | L_{b214} | 932 | Lₐ₂₁₉ | L_{b215} |
| 933 | Lₐ₂₂₆ | L_{b214} | 934 | Lₐ₂₂₆ | L_{b215} |
| 935 | Lₐ₃₀₄ | L_{b214} | 936 | Lₐ₃₀₄ | L_{b215} |
| 937 | Lₐ₃₀₆ | L_{b214} | 938 | Lₐ₃₀₆ | L_{b215} |
| 939 | Lₐ₃₀₉ | L_{b214} | 940 | Lₐ₃₀₉ | L_{b215} |
| 941 | Lₐ₃₁₁ | L_{b214} | 942 | Lₐ₃₁₁ | L_{b215} |
| 943 | Lₐ₃₂₁ | L_{b214} | 944 | Lₐ₃₂₁ | L_{b215} |
| 945 | Lₐ₃₂₃ | L_{b214} | 946 | Lₐ₃₂₃ | L_{b215} |
| 947 | Lₐ₃₃₂ | L_{b214} | 948 | Lₐ₃₃₂ | L_{b215} |
| 949 | Lₐ₃₅₁ | L_{b214} | 950 | Lₐ₃₅₁ | L_{b215} |
| 951 | Lₐ₃₅₆ | L_{b214} | 952 | Lₐ₃₅₆ | L_{b215} |
| 953 | Lₐ₃₇₅ | L_{b214} | 954 | Lₐ₃₇₅ | L_{b215} |
| 955 | Lₐ₄₂₂ | L_{b214} | 956 | Lₐ₄₂₂ | L_{b215} |
| 957 | Lₐ₄₂₇ | L_{b214} | 958 | Lₐ₄₂₇ | L_{b215} |
| 959 | Lₐ₄₅₀ | L_{b214} | 960 | Lₐ₄₅₀ | L_{b215} |
| 961 | Lₐ₄₇₃ | L_{b214} | 962 | Lₐ₄₇₃ | L_{b215} |
| 963 | Lₐ₄₉₆ | L_{b214} | 964 | Lₐ₄₉₆ | L_{b215} |
| 965 | Lₐ₆₀₆ | L_{b214} | 966 | Lₐ₆₀₆ | L_{b215} |
| 967 | Lₐ₆₁₁ | L_{b214} | 968 | Lₐ₆₁₁ | L_{b215} |
| 969 | Lₐ₆₃₄ | L_{b214} | 970 | Lₐ₆₃₄ | L_{b215} |
| 971 | Lₐ₈₉₉ | L_{b214} | 972 | Lₐ₈₉₉ | L_{b215} |
| 973 | Lₐ₉₂₃ | L_{b214} | 974 | Lₐ₉₂₃ | L_{b215} |
| 975 | Lₐ₉₉₇ | L_{b214} | 976 | Lₐ₉₉₇ | L_{b215} |
| 977 | Lₐ₁₁₀₆ | L_{b214} | 978 | Lₐ₁₁₀₆ | L_{b215} |
| 979 | Lₐ₁₁₀₈ | L_{b214} | 980 | Lₐ₁₁₀₈ | L_{b215} |
| 981 | Lₐ₁₁₁₂ | L_{b214} | 982 | Lₐ₁₁₁₂ | L_{b215} |
| 983 | Lₐ₁₁₁₄ | L_{b214} | 984 | Lₐ₁₁₁₄ | L_{b215} |
| 985 | Lₐ₁₁₁₈ | L_{b214} | 986 | Lₐ₁₁₁₈ | L_{b215} |
| 987 | Lₐ₁₁₂₀ | L_{b214} | 988 | Lₐ₁₁₂₀ | L_{b215} |
| 989 | Lₐ₁₂₁₈ | L_{b214} | 990 | Lₐ₁₂₁₈ | L_{b215} |
| 991 | Lₐ₁₂₁₉ | L_{b214} | 992 | Lₐ₁₂₁₉ | L_{b215} |
| 993 | Lₐ₁₃₀₂ | L_{b214} | 994 | Lₐ₁₃₀₂ | L_{b215} |
| 995 | Lₐ₁₃₀₇ | L_{b214} | 996 | Lₐ₁₃₀₇ | L_{b215} |
| 997 | Lₐ₁₄₇₃ | L_{b214} | 998 | Lₐ₁₄₇₃ | L_{b215} |
| 999 | Lₐ₁₄₈₇ | L_{b214} | 1000 | Lₐ₁₄₈₇ | L_{b215} |
| 1001 | Lₐ₁₄₉₁ | L_{b214} | 1002 | Lₐ₁₄₉₁ | L_{b215} |
| 1003 | Lₐ₁₇₁₀ | L_{b214} | 1004 | Lₐ₁₇₁₀ | L_{b215} |
| 1005 | Lₐ₁₇₄₀ | L_{b214} | 1006 | Lₐ₁₇₄₀ | L_{b215} |
| 1007 | Lₐ₁₇₄₅ | L_{b214} | 1008 | Lₐ₁₇₄₅ | L_{b215} |
| 1009 | Lₐ₅ | L_{b218} | 1010 | Lₐ₅ | L_{b241} |
| 1011 | Lₐ₂₇ | L_{b218} | 1012 | Lₐ₂₇ | L_{b241} |
| 1013 | Lₐ₂₈ | L_{b218} | 1014 | Lₐ₂₈ | L_{b241} |
| 1015 | Lₐ₂₉ | L_{b218} | 1016 | Lₐ₂₉ | L_{b241} |
| 1017 | Lₐ₃₀ | L_{b218} | 1018 | Lₐ₃₀ | L_{b241} |
| 1019 | Lₐ₃₃ | L_{b218} | 1020 | Lₐ₃₃ | L_{b241} |
| 1021 | Lₐ₃₅ | L_{b218} | 1022 | Lₐ₃₅ | L_{b241} |
| 1023 | Lₐ₃₇ | L_{b218} | 1024 | Lₐ₃₇ | L_{b241} |
| 1025 | Lₐ₄₁ | L_{b218} | 1026 | Lₐ₄₁ | L_{b241} |
| 1027 | Lₐ₄₃ | L_{b218} | 1028 | Lₐ₄₃ | L_{b241} |
| 1029 | Lₐ₅₁ | L_{b218} | 1030 | Lₐ₅₁ | L_{b241} |
| 1031 | Lₐ₅₆ | L_{b218} | 1032 | Lₐ₅₆ | L_{b241} |
| 1033 | Lₐ₅₈ | L_{b218} | 1034 | Lₐ₅₈ | L_{b241} |
| 1035 | Lₐ₇₄ | L_{b218} | 1036 | Lₐ₇₄ | L_{b241} |
| 1037 | Lₐ₇₉ | L_{b218} | 1038 | Lₐ₇₉ | L_{b241} |
| 1039 | Lₐ₈₁ | L_{b218} | 1040 | Lₐ₈₁ | L_{b241} |
| 1041 | Lₐ₉₇ | L_{b218} | 1042 | Lₐ₉₇ | L_{b241} |
| 1043 | Lₐ₁₀₂ | L_{b218} | 1044 | Lₐ₁₀₂ | L_{b241} |
| 1045 | Lₐ₁₀₄ | L_{b218} | 1046 | Lₐ₁₀₄ | L_{b241} |
| 1047 | Lₐ₁₂₀ | L_{b218} | 1048 | Lₐ₁₂₀ | L_{b241} |
| 1049 | Lₐ₁₂₅ | L_{b218} | 1050 | Lₐ₁₂₅ | L_{b241} |
| 1051 | Lₐ₂₁₂ | L_{b218} | 1052 | Lₐ₂₁₂ | L_{b241} |
| 1053 | Lₐ₂₁₄ | L_{b218} | 1054 | Lₐ₂₁₄ | L_{b241} |
| 1055 | Lₐ₂₁₇ | L_{b218} | 1056 | Lₐ₂₁₇ | L_{b241} |
| 1057 | Lₐ₂₁₉ | L_{b218} | 1058 | Lₐ₂₁₉ | L_{b241} |
| 1059 | Lₐ₂₂₆ | L_{b218} | 1060 | Lₐ₂₂₆ | L_{b241} |
| 1061 | Lₐ₃₀₄ | L_{b218} | 1062 | Lₐ₃₀₄ | L_{b241} |
| 1063 | Lₐ₃₀₆ | L_{b218} | 1064 | Lₐ₃₀₆ | L_{b241} |
| 1065 | Lₐ₃₀₉ | L_{b218} | 1066 | Lₐ₃₀₉ | L_{b241} |
| 1067 | Lₐ₃₁₁ | L_{b218} | 1068 | Lₐ₃₁₁ | L_{b241} |
| 1069 | Lₐ₃₂₁ | L_{b218} | 1070 | Lₐ₃₂₁ | L_{b241} |
| 1071 | Lₐ₃₂₃ | L_{b218} | 1072 | Lₐ₃₂₃ | L_{b241} |
| 1073 | Lₐ₃₃₂ | L_{b218} | 1074 | Lₐ₃₃₂ | L_{b241} |
| 1075 | Lₐ₃₅₁ | L_{b218} | 1076 | Lₐ₃₅₁ | L_{b241} |
| 1077 | Lₐ₃₅₆ | L_{b218} | 1078 | Lₐ₃₅₆ | L_{b241} |
| 1079 | Lₐ₃₇₅ | L_{b218} | 1080 | Lₐ₃₇₅ | L_{b241} |
| 1081 | Lₐ₄₂₂ | L_{b218} | 1082 | Lₐ₄₂₂ | L_{b241} |
| 1083 | Lₐ₄₂₇ | L_{b218} | 1084 | Lₐ₄₂₇ | L_{b241} |
| 1085 | Lₐ₄₅₀ | L_{b218} | 1086 | Lₐ₄₅₀ | L_{b241} |
| 1087 | Lₐ₄₇₃ | L_{b218} | 1088 | Lₐ₄₇₃ | L_{b241} |
| 1089 | Lₐ₄₉₆ | L_{b218} | 1090 | Lₐ₄₉₆ | L_{b241} |
| 1091 | Lₐ₆₀₆ | L_{b218} | 1092 | Lₐ₆₀₆ | L_{b241} |
| 1093 | Lₐ₆₁₁ | L_{b218} | 1094 | Lₐ₆₁₁ | L_{b241} |
| 1095 | Lₐ₆₃₄ | L_{b218} | 1096 | Lₐ₆₃₄ | L_{b241} |
| 1097 | Lₐ₈₉₉ | L_{b218} | 1098 | Lₐ₈₉₉ | L_{b241} |
| 1099 | Lₐ₉₂₃ | L_{b218} | 1100 | Lₐ₉₂₃ | L_{b241} |
| 1101 | Lₐ₉₉₇ | L_{b218} | 1102 | Lₐ₉₉₇ | L_{b241} |
| 1103 | Lₐ₁₁₀₆ | L_{b218} | 1104 | Lₐ₁₁₀₆ | L_{b241} |
| 1105 | Lₐ₁₁₀₈ | L_{b218} | 1106 | Lₐ₁₁₀₈ | L_{b241} |
| 1107 | Lₐ₁₁₁₂ | L_{b218} | 1108 | Lₐ₁₁₁₂ | L_{b241} |
| 1109 | Lₐ₁₁₁₄ | L_{b218} | 1110 | Lₐ₁₁₁₄ | L_{b241} |
| 1111 | Lₐ₁₁₁₈ | L_{b218} | 1112 | Lₐ₁₁₁₈ | L_{b241} |
| 1113 | Lₐ₁₁₂₀ | L_{b218} | 1114 | Lₐ₁₁₂₀ | L_{b241} |
| 1115 | Lₐ₁₂₁₈ | L_{b218} | 1116 | Lₐ₁₂₁₈ | L_{b241} |
| 1117 | Lₐ₁₂₁₉ | L_{b218} | 1118 | Lₐ₁₂₁₉ | L_{b241} |
| 1119 | Lₐ₁₃₀₂ | L_{b218} | 1120 | Lₐ₁₃₀₂ | L_{b241} |
| 1121 | Lₐ₁₃₀₇ | L_{b218} | 1122 | Lₐ₁₃₀₇ | L_{b241} |
| 1123 | Lₐ₁₄₇₃ | L_{b218} | 1124 | Lₐ₁₄₇₃ | L_{b241} |
| 1125 | Lₐ₁₄₈₇ | L_{b218} | 1126 | Lₐ₁₄₈₇ | L_{b241} |
| 1127 | Lₐ₁₄₉₁ | L_{b218} | 1128 | Lₐ₁₄₉₁ | L_{b241} |
| 1129 | Lₐ₁₇₁₀ | L_{b218} | 1130 | Lₐ₁₇₁₀ | L_{b241} |
| 1131 | Lₐ₁₇₄₀ | L_{b218} | 1132 | Lₐ₁₇₄₀ | L_{b241} |
| 1133 | Lₐ₁₇₄₅ | L_{b218} | 1134 | Lₐ₁₇₄₅ | L_{b241} |
| 1135 | Lₐ₅ | L_{b248} | 1136 | Lₐ₅ | L_{b267} |
| 1137 | Lₐ₂₇ | L_{b248} | 1138 | Lₐ₂₇ | L_{b267} |
| 1139 | Lₐ₂₈ | L_{b248} | 1140 | Lₐ₂₈ | L_{b267} |
| 1141 | Lₐ₂₉ | L_{b248} | 1142 | Lₐ₂₉ | L_{b267} |
| 1143 | Lₐ₃₀ | L_{b248} | 1144 | Lₐ₃₀ | L_{b267} |
| 1145 | Lₐ₃₃ | L_{b248} | 1146 | Lₐ₃₃ | L_{b267} |
| 1147 | Lₐ₃₅ | L_{b248} | 1148 | Lₐ₃₅ | L_{b267} |
| 1149 | Lₐ₃₇ | L_{b248} | 1150 | Lₐ₃₇ | L_{b267} |
| 1151 | Lₐ₄₁ | L_{b248} | 1152 | Lₐ₄₁ | L_{b267} |
| 1153 | Lₐ₄₃ | L_{b248} | 1154 | Lₐ₄₃ | L_{b267} |
| 1155 | Lₐ₅₁ | L_{b248} | 1156 | Lₐ₅₁ | L_{b267} |
| 1157 | Lₐ₅₆ | L_{b248} | 1158 | Lₐ₅₆ | L_{b267} |
| 1159 | Lₐ₅₈ | L_{b248} | 1160 | Lₐ₅₈ | L_{b267} |
| 1161 | Lₐ₇₄ | L_{b248} | 1162 | Lₐ₇₄ | L_{b267} |
| 1163 | Lₐ₇₉ | L_{b248} | 1164 | Lₐ₇₉ | L_{b267} |
| 1165 | Lₐ₈₁ | L_{b248} | 1166 | Lₐ₈₁ | L_{b267} |
| 1167 | Lₐ₉₇ | L_{b248} | 1168 | Lₐ₉₇ | L_{b267} |
| 1169 | Lₐ₁₀₂ | L_{b248} | 1170 | Lₐ₁₀₂ | L_{b267} |
| 1171 | Lₐ₁₀₄ | L_{b248} | 1172 | Lₐ₁₀₄ | L_{b267} |
| 1173 | Lₐ₁₂₀ | L_{b248} | 1174 | Lₐ₁₂₀ | L_{b267} |
| 1175 | Lₐ₁₂₅ | L_{b248} | 1176 | Lₐ₁₂₅ | L_{b267} |
| 1177 | Lₐ₂₁₂ | L_{b248} | 1178 | Lₐ₂₁₂ | L_{b267} |
| 1179 | Lₐ₂₁₄ | L_{b248} | 1180 | Lₐ₂₁₄ | L_{b267} |
| 1181 | Lₐ₂₁₇ | L_{b248} | 1182 | Lₐ₂₁₇ | L_{b267} |
| 1183 | Lₐ₂₁₉ | L_{b248} | 1184 | Lₐ₂₁₉ | L_{b267} |
| 1185 | Lₐ₂₂₆ | L_{b248} | 1186 | Lₐ₂₂₆ | L_{b267} |
| 1187 | Lₐ₃₀₄ | L_{b248} | 1188 | Lₐ₃₀₄ | L_{b267} |
| 1189 | Lₐ₃₀₆ | L_{b248} | 1190 | Lₐ₃₀₆ | L_{b267} |
| 1191 | Lₐ₃₀₉ | L_{b248} | 1192 | Lₐ₃₀₉ | L_{b267} |
| 1193 | Lₐ₃₁₁ | L_{b248} | 1194 | Lₐ₃₁₁ | L_{b267} |
| 1195 | Lₐ₃₂₁ | L_{b248} | 1196 | Lₐ₃₂₁ | L_{b267} |
| 1197 | Lₐ₃₂₃ | L_{b248} | 1198 | Lₐ₃₂₃ | L_{b267} |
| 1199 | Lₐ₃₃₂ | L_{b248} | 1200 | Lₐ₃₃₂ | L_{b267} |
| 1201 | Lₐ₃₅₁ | L_{b248} | 1202 | Lₐ₃₅₁ | L_{b267} |
| 1203 | Lₐ₃₅₆ | L_{b248} | 1204 | Lₐ₃₅₆ | L_{b267} |
| 1205 | Lₐ₃₇₅ | L_{b248} | 1206 | Lₐ₃₇₅ | L_{b267} |
| 1207 | Lₐ₄₂₂ | L_{b248} | 1208 | Lₐ₄₂₂ | L_{b267} |
| 1209 | Lₐ₄₂₇ | L_{b248} | 1210 | Lₐ₄₂₇ | L_{b267} |
| 1211 | Lₐ₄₅₀ | L_{b248} | 1212 | Lₐ₄₅₀ | L_{b267} |
| 1213 | Lₐ₄₇₃ | L_{b248} | 1214 | Lₐ₄₇₃ | L_{b267} |
| 1215 | Lₐ₄₉₆ | L_{b248} | 1216 | Lₐ₄₉₆ | L_{b267} |
| 1217 | Lₐ₆₀₆ | L_{b248} | 1218 | Lₐ₆₀₆ | L_{b267} |
| 1219 | Lₐ₆₁₁ | L_{b248} | 1220 | Lₐ₆₁₁ | L_{b267} |
| 1221 | Lₐ₆₃₄ | L_{b248} | 1222 | Lₐ₆₃₄ | L_{b267} |
| 1223 | Lₐ₈₉₉ | L_{b248} | 1224 | Lₐ₈₉₉ | L_{b267} |
| 1225 | Lₐ₉₂₃ | L_{b248} | 1226 | Lₐ₉₂₃ | L_{b267} |
| 1227 | Lₐ₉₉₇ | L_{b248} | 1228 | Lₐ₉₉₇ | L_{b267} |
| 1229 | Lₐ₁₁₀₆ | L_{b248} | 1230 | Lₐ₁₁₀₆ | L_{b267} |
| 1231 | Lₐ₁₁₀₈ | L_{b248} | 1232 | Lₐ₁₁₀₈ | L_{b267} |
| 1233 | Lₐ₁₁₁₂ | L_{b248} | 1234 | Lₐ₁₁₁₂ | L_{b267} |
| 1235 | Lₐ₁₁₁₄ | L_{b248} | 1236 | Lₐ₁₁₁₄ | L_{b267} |
| 1237 | Lₐ₁₁₁₈ | L_{b248} | 1238 | Lₐ₁₁₁₈ | L_{b267} |
| 1239 | Lₐ₁₁₂₀ | L_{b248} | 1240 | Lₐ₁₁₂₀ | L_{b267} |
| 1241 | Lₐ₁₂₁₈ | L_{b248} | 1242 | Lₐ₁₂₁₈ | L_{b267} |
| 1243 | Lₐ₁₂₁₉ | L_{b248} | 1244 | Lₐ₁₂₁₉ | L_{b267} |
| 1245 | Lₐ₁₃₀₂ | L_{b248} | 1246 | Lₐ₁₃₀₂ | L_{b267} |
| 1247 | Lₐ₁₃₀₇ | L_{b248} | 1248 | Lₐ₁₃₀₇ | L_{b267} |
| 1249 | Lₐ₁₄₇₃ | L_{b248} | 1250 | Lₐ₁₄₇₃ | L_{b267} |
| 1251 | Lₐ₁₄₈₇ | L_{b248} | 1252 | Lₐ₁₄₈₇ | L_{b267} |
| 1253 | Lₐ₁₄₉₁ | L_{b248} | 1254 | Lₐ₁₄₉₁ | L_{b267} |
| 1255 | Lₐ₁₇₁₀ | L_{b248} | 1256 | Lₐ₁₇₁₀ | L_{b267} |
| 1257 | Lₐ₁₇₄₀ | L_{b248} | 1258 | Lₐ₁₇₄₀ | L_{b267} |
| 1259 | Lₐ₁₇₄₅ | L_{b248} | 1260 | Lₐ₁₇₄₅ | L_{b267} |
| 1261 | Lₐ₅ | L_{b279} | 1262 | Lₐ₅ | L_{b329} |
| 1263 | Lₐ₂₇ | L_{b279} | 1264 | Lₐ₂₇ | L_{b329} |
| 1265 | Lₐ₂₈ | L_{b279} | 1266 | Lₐ₂₈ | L_{b329} |
| 1267 | Lₐ₂₉ | L_{b279} | 1268 | Lₐ₂₉ | L_{b329} |
| 1269 | Lₐ₃₀ | L_{b279} | 1270 | Lₐ₃₀ | L_{b329} |
| 1271 | Lₐ₃₃ | L_{b279} | 1272 | Lₐ₃₃ | L_{b329} |
| 1273 | Lₐ₃₅ | L_{b279} | 1274 | Lₐ₃₅ | L_{b329} |
| 1275 | Lₐ₃₇ | L_{b279} | 1276 | Lₐ₃₇ | L_{b329} |
| 1277 | Lₐ₄₁ | L_{b279} | 1278 | Lₐ₄₁ | L_{b329} |
| 1279 | Lₐ₄₃ | L_{b279} | 1280 | Lₐ₄₃ | L_{b329} |
| 1281 | Lₐ₅₁ | L_{b279} | 1282 | Lₐ₅₁ | L_{b329} |
| 1283 | Lₐ₅₆ | L_{b279} | 1284 | Lₐ₅₆ | L_{b329} |
| 1285 | Lₐ₅₈ | L_{b279} | 1286 | Lₐ₅₈ | L_{b329} |
| 1287 | Lₐ₇₄ | L_{b279} | 1288 | Lₐ₇₄ | L_{b329} |
| 1289 | Lₐ₇₉ | L_{b279} | 1290 | Lₐ₇₉ | L_{b329} |
| 1291 | Lₐ₈₁ | L_{b279} | 1292 | Lₐ₈₁ | L_{b329} |
| 1293 | Lₐ₉₇ | L_{b279} | 1294 | Lₐ₉₇ | L_{b329} |
| 1295 | Lₐ₁₀₂ | L_{b279} | 1296 | Lₐ₁₀₂ | L_{b329} |
| 1297 | Lₐ₁₀₄ | L_{b279} | 1298 | Lₐ₁₀₄ | L_{b329} |
| 1299 | Lₐ₁₂₀ | L_{b279} | 1300 | Lₐ₁₂₀ | L_{b329} |
| 1301 | Lₐ₁₂₅ | L_{b279} | 1302 | Lₐ₁₂₅ | L_{b329} |
| 1303 | Lₐ₂₁₂ | L_{b279} | 1304 | Lₐ₂₁₂ | L_{b329} |
| 1305 | Lₐ₂₁₄ | L_{b279} | 1306 | Lₐ₂₁₄ | L_{b329} |
| 1307 | Lₐ₂₁₇ | L_{b279} | 1308 | Lₐ₂₁₇ | L_{b329} |
| 1309 | Lₐ₂₁₉ | L_{b279} | 1310 | Lₐ₂₁₉ | L_{b329} |
| 1311 | Lₐ₂₂₆ | L_{b279} | 1312 | Lₐ₂₂₆ | L_{b329} |
| 1313 | Lₐ₃₀₄ | L_{b279} | 1314 | Lₐ₃₀₄ | L_{b329} |
| 1315 | Lₐ₃₀₆ | L_{b279} | 1316 | Lₐ₃₀₆ | L_{b329} |
| 1317 | Lₐ₃₀₉ | L_{b279} | 1318 | Lₐ₃₀₉ | L_{b329} |
| 1319 | Lₐ₃₁₁ | L_{b279} | 1320 | Lₐ₃₁₁ | L_{b329} |
| 1321 | Lₐ₃₂₁ | L_{b279} | 1322 | Lₐ₃₂₁ | L_{b329} |
| 1323 | Lₐ₃₂₃ | L_{b279} | 1324 | Lₐ₃₂₃ | L_{b329} |
| 1325 | Lₐ₃₃₂ | L_{b279} | 1326 | Lₐ₃₃₂ | L_{b329} |
| 1327 | Lₐ₃₅₁ | L_{b279} | 1328 | Lₐ₃₅₁ | L_{b329} |
| 1329 | Lₐ₃₅₆ | L_{b279} | 1330 | Lₐ₃₅₆ | L_{b329} |
| 1331 | Lₐ₃₇₅ | L_{b279} | 1332 | Lₐ₃₇₅ | L_{b329} |
| 1333 | Lₐ₄₂₂ | L_{b279} | 1334 | Lₐ₄₂₂ | L_{b329} |
| 1335 | Lₐ₄₂₇ | L_{b279} | 1336 | Lₐ₄₂₇ | L_{b329} |
| 1337 | Lₐ₄₅₀ | L_{b279} | 1338 | Lₐ₄₅₀ | L_{b329} |
| 1339 | Lₐ₄₇₃ | L_{b279} | 1340 | Lₐ₄₇₃ | L_{b329} |
| 1341 | Lₐ₄₉₆ | L_{b279} | 1342 | Lₐ₄₉₆ | L_{b329} |
| 1343 | Lₐ₆₀₆ | L_{b279} | 1344 | Lₐ₆₀₆ | L_{b329} |
| 1345 | Lₐ₆₁₁ | L_{b279} | 1346 | Lₐ₆₁₁ | L_{b329} |
| 1347 | Lₐ₆₃₄ | L_{b279} | 1348 | Lₐ₆₃₄ | L_{b329} |
| 1349 | Lₐ₈₉₉ | L_{b279} | 1350 | Lₐ₈₉₉ | L_{b329} |
| 1351 | Lₐ₉₂₃ | L_{b279} | 1352 | Lₐ₉₂₃ | L_{b329} |
| 1353 | Lₐ₉₉₇ | L_{b279} | 1354 | Lₐ₉₉₇ | L_{b329} |
| 1355 | Lₐ₁₁₀₆ | L_{b279} | 1356 | Lₐ₁₁₀₆ | L_{b329} |
| 1357 | Lₐ₁₁₀₈ | L_{b279} | 1358 | Lₐ₁₁₀₈ | L_{b329} |
| 1359 | Lₐ₁₁₁₂ | L_{b279} | 1360 | Lₐ₁₁₁₂ | L_{b329} |
| 1361 | Lₐ₁₁₁₄ | L_{b279} | 1362 | Lₐ₁₁₁₄ | L_{b329} |
| 1363 | Lₐ₁₁₁₈ | L_{b279} | 1364 | Lₐ₁₁₁₈ | L_{b329} |
| 1365 | Lₐ₁₁₂₀ | L_{b279} | 1366 | Lₐ₁₁₂₀ | L_{b329} |
| 1367 | Lₐ₁₂₁₈ | L_{b279} | 1368 | Lₐ₁₂₁₈ | L_{b329} |
| 1369 | Lₐ₁₂₁₉ | L_{b279} | 1370 | Lₐ₁₂₁₉ | L_{b329} |
| 1371 | Lₐ₁₃₀₂ | L_{b279} | 1372 | Lₐ₁₃₀₂ | L_{b329} |
| 1373 | Lₐ₁₃₀₇ | L_{b279} | 1374 | Lₐ₁₃₀₇ | L_{b329} |
| 1375 | Lₐ₁₄₇₃ | L_{b279} | 1376 | Lₐ₁₄₇₃ | L_{b329} |
| 1377 | Lₐ₁₄₈₇ | L_{b279} | 1378 | Lₐ₁₄₈₇ | L_{b329} |
| 1379 | Lₐ₁₄₉₁ | L_{b279} | 1380 | Lₐ₁₄₉₁ | L_{b329} |
| 1381 | Lₐ₁₇₁₀ | L_{b279} | 1382 | Lₐ₁₇₁₀ | L_{b329} |
| 1383 | Lₐ₁₇₄₀ | L_{b279} | 1384 | Lₐ₁₇₄₀ | L_{b329} |
| 1385 | Lₐ₁₇₄₅ | L_{b279} | 1386 | Lₐ₁₇₄₅ | L_{b329} |
| 1387 | Lₐ₅ | L_{b330} | 1388 | Lₐ₅ | L_{b331} |
| 1389 | Lₐ₂₇ | L_{b330} | 1390 | Lₐ₂₇ | L_{b331} |
| 1391 | Lₐ₂₈ | L_{b330} | 1392 | Lₐ₂₈ | L_{b331} |
| 1393 | Lₐ₂₉ | L_{b330} | 1394 | Lₐ₂₉ | L_{b331} |
| 1395 | Lₐ₃₀ | L_{b330} | 1396 | Lₐ₃₀ | L_{b331} |
| 1397 | Lₐ₃₃ | L_{b330} | 1398 | Lₐ₃₃ | L_{b331} |
| 1399 | Lₐ₃₅ | L_{b330} | 1400 | Lₐ₃₅ | L_{b331} |
| 1401 | Lₐ₃₇ | L_{b330} | 1402 | Lₐ₃₇ | L_{b331} |
| 1403 | Lₐ₄₁ | L_{b330} | 1404 | Lₐ₄₁ | L_{b331} |
| 1405 | Lₐ₄₃ | L_{b330} | 1406 | Lₐ₄₃ | L_{b331} |
| 1407 | Lₐ₅₁ | L_{b330} | 1408 | Lₐ₅₁ | L_{b331} |
| 1409 | Lₐ₅₆ | L_{b330} | 1410 | Lₐ₅₆ | L_{b331} |
| 1411 | Lₐ₅₈ | L_{b330} | 1412 | Lₐ₅₈ | L_{b331} |
| 1413 | Lₐ₇₄ | L_{b330} | 1414 | Lₐ₇₄ | L_{b331} |
| 1415 | Lₐ₇₉ | L_{b330} | 1416 | Lₐ₇₉ | L_{b331} |
| 1417 | Lₐ₈₁ | L_{b330} | 1418 | Lₐ₈₁ | L_{b331} |
| 1419 | Lₐ₉₇ | L_{b330} | 1420 | Lₐ₉₇ | L_{b331} |
| 1421 | Lₐ₁₀₂ | L_{b330} | 1422 | Lₐ₁₀₂ | L_{b331} |
| 1423 | Lₐ₁₀₄ | L_{b330} | 1424 | Lₐ₁₀₄ | L_{b331} |
| 1425 | Lₐ₁₂₀ | L_{b330} | 1426 | Lₐ₁₂₀ | L_{b331} |
| 1427 | Lₐ₁₂₅ | L_{b330} | 1428 | Lₐ₁₂₅ | L_{b331} |
| 1429 | Lₐ₂₁₂ | L_{b330} | 1430 | Lₐ₂₁₂ | L_{b331} |
| 1431 | Lₐ₂₁₄ | L_{b330} | 1432 | Lₐ₂₁₄ | L_{b331} |
| 1433 | Lₐ₂₁₇ | L_{b330} | 1434 | Lₐ₂₁₇ | L_{b331} |
| 1435 | Lₐ₂₁₉ | L_{b330} | 1436 | Lₐ₂₁₉ | L_{b331} |
| 1437 | Lₐ₂₂₆ | L_{b330} | 1438 | Lₐ₂₂₆ | L_{b331} |
| 1439 | Lₐ₃₀₄ | L_{b330} | 1440 | Lₐ₃₀₄ | L_{b331} |
| 1441 | Lₐ₃₀₆ | L_{b330} | 1442 | Lₐ₃₀₆ | L_{b331} |
| 1443 | Lₐ₃₀₉ | L_{b330} | 1444 | Lₐ₃₀₉ | L_{b331} |
| 1445 | Lₐ₃₁₁ | L_{b330} | 1446 | Lₐ₃₁₁ | L_{b331} |
| 1447 | Lₐ₃₂₁ | L_{b330} | 1448 | Lₐ₃₂₁ | L_{b331} |
| 1449 | Lₐ₃₂₃ | L_{b330} | 1450 | Lₐ₃₂₃ | L_{b331} |
| 1451 | Lₐ₃₃₂ | L_{b330} | 1452 | Lₐ₃₃₂ | L_{b331} |
| 1453 | Lₐ₃₅₁ | L_{b330} | 1454 | Lₐ₃₅₁ | L_{b331} |
| 1455 | Lₐ₃₅₆ | L_{b330} | 1456 | Lₐ₃₅₆ | L_{b331} |
| 1457 | Lₐ₃₇₅ | L_{b330} | 1458 | Lₐ₃₇₅ | L_{b331} |
| 1459 | Lₐ₄₂₂ | L_{b330} | 1460 | Lₐ₄₂₂ | L_{b331} |
| 1461 | Lₐ₄₂₇ | L_{b330} | 1462 | Lₐ₄₂₇ | L_{b331} |
| 1463 | Lₐ₄₅₀ | L_{b330} | 1464 | Lₐ₄₅₀ | L_{b331} |
| 1465 | Lₐ₄₇₃ | L_{b330} | 1466 | Lₐ₄₇₃ | L_{b331} |
| 1467 | Lₐ₄₉₆ | L_{b330} | 1468 | Lₐ₄₉₆ | L_{b331} |
| 1469 | Lₐ₆₀₆ | L_{b330} | 1470 | Lₐ₆₀₆ | L_{b331} |
| 1471 | Lₐ₆₁₁ | L_{b330} | 1472 | Lₐ₆₁₁ | L_{b331} |
| 1473 | Lₐ₆₃₄ | L_{b330} | 1474 | Lₐ₆₃₄ | L_{b331} |
| 1475 | Lₐ₈₉₉ | L_{b330} | 1476 | Lₐ₈₉₉ | L_{b331} |
| 1477 | Lₐ₉₂₃ | L_{b330} | 1478 | Lₐ₉₂₃ | L_{b331} |
| 1479 | Lₐ₉₉₇ | L_{b330} | 1480 | Lₐ₉₉₇ | L_{b331} |
| 1481 | Lₐ₁₁₀₆ | L_{b330} | 1482 | Lₐ₁₁₀₆ | L_{b331} |
| 1483 | Lₐ₁₁₀₈ | L_{b330} | 1484 | Lₐ₁₁₀₈ | L_{b331} |
| 1485 | Lₐ₁₁₁₂ | L_{b330} | 1486 | Lₐ₁₁₁₂ | L_{b331} |
| 1487 | Lₐ₁₁₁₄ | L_{b330} | 1488 | Lₐ₁₁₁₄ | L_{b331} |
| 1489 | Lₐ₁₁₁₈ | L_{b330} | 1490 | Lₐ₁₁₁₈ | L_{b331} |
| 1491 | Lₐ₁₁₂₀ | L_{b330} | 1492 | Lₐ₁₁₂₀ | L_{b331} |
| 1493 | Lₐ₁₂₁₈ | L_{b330} | 1494 | Lₐ₁₂₁₈ | L_{b331} |
| 1495 | Lₐ₁₂₁₉ | L_{b330} | 1496 | Lₐ₁₂₁₉ | L_{b331} |
| 1497 | Lₐ₁₃₀₂ | L_{b330} | 1498 | Lₐ₁₃₀₂ | L_{b331} |
| 1499 | Lₐ₁₃₀₇ | L_{b330} | 1500 | Lₐ₁₃₀₇ | L_{b331} |
| 1501 | Lₐ₁₄₇₃ | L_{b330} | 1502 | Lₐ₁₄₇₃ | L_{b331} |
| 1503 | Lₐ₁₄₈₇ | L_{b330} | 1504 | Lₐ₁₄₈₇ | L_{b331} |
| 1505 | Lₐ₁₄₉₁ | L_{b330} | 1506 | Lₐ₁₄₉₁ | L_{b331} |
| 1507 | Lₐ₁₇₁₀ | L_{b330} | 1508 | Lₐ₁₇₁₀ | L_{b331} |
| 1509 | Lₐ₁₇₄₀ | L_{b330} | 1510 | Lₐ₁₇₄₀ | L_{b331} |
| 1511 | Lₐ₁₇₄₅ | L_{b330} | 1512 | Lₐ₁₇₄₅ | L_{b331} |
| 1513 | Lₐ₅ | L_{b332} | 1514 | Lₐ₅ | L_{b333} |
| 1515 | Lₐ₂₇ | L_{b332} | 1516 | Lₐ₂₇ | L_{b333} |
| 1517 | Lₐ₂₈ | L_{b332} | 1518 | Lₐ₂₈ | L_{b333} |
| 1519 | Lₐ₂₉ | L_{b332} | 1520 | Lₐ₂₉ | L_{b333} |
| 1521 | Lₐ₃₀ | L_{b332} | 1522 | Lₐ₃₀ | L_{b333} |
| 1523 | Lₐ₃ | L_{b332} | 1524 | Lₐ₃₃ | L_{b333} |
| 1525 | Lₐ₃₅ | L_{b332} | 1526 | Lₐ₃₅ | L_{b333} |
| 1527 | Lₐ₃₇ | L_{b332} | 1528 | Lₐ₃₇ | L_{b333} |
| 1529 | Lₐ₄₁ | L_{b332} | 1530 | Lₐ₄₁ | L_{b333} |
| 1531 | Lₐ₄₃ | L_{b332} | 1532 | Lₐ₄₃ | L_{b333} |
| 1533 | Lₐ₅₁ | L_{b332} | 1534 | Lₐ₅₁ | L_{b333} |
| 1535 | Lₐ₅₆ | L_{b332} | 1536 | Lₐ₅₆ | L_{b333} |
| 1537 | Lₐ₅₈ | L_{b332} | 1538 | Lₐ₅₈ | L_{b333} |
| 1539 | Lₐ₇₄ | L_{b332} | 1540 | Lₐ₇₄ | L_{b333} |
| 1541 | Lₐ₇₉ | L_{b332} | 1542 | Lₐ₇₉ | L_{b333} |
| 1543 | Lₐ₈₁ | L_{b332} | 1544 | Lₐ₈₁ | L_{b333} |
| 1545 | Lₐ₉₇ | L_{b332} | 1546 | Lₐ₉₇ | L_{b333} |
| 1547 | Lₐ₁₀₂ | L_{b332} | 1548 | Lₐ₁₀₂ | L_{b333} |
| 1549 | Lₐ₁₀₄ | L_{b332} | 1550 | Lₐ₁₀₄ | L_{b333} |
| 1551 | Lₐ₁₂₀ | L_{b332} | 1552 | Lₐ₁₂₀ | L_{b333} |
| 1553 | Lₐ₁₂₅ | L_{b332} | 1554 | Lₐ₁₂₅ | L_{b333} |
| 1555 | Lₐ₂₁₂ | L_{b332} | 1556 | Lₐ₂₁₂ | L_{b333} |
| 1557 | Lₐ₂₁₄ | L_{b332} | 1558 | Lₐ₂₁₄ | L_{b333} |
| 1559 | Lₐ₂₁₇ | L_{b332} | 1560 | Lₐ₂₁₇ | L_{b333} |
| 1561 | Lₐ₂₁₉ | L_{b332} | 1562 | Lₐ₂₁₉ | L_{b333} |
| 1563 | Lₐ₂₂₆ | L_{b332} | 1564 | Lₐ₂₂₆ | L_{b333} |
| 1565 | Lₐ₃₀₄ | L_{b332} | 1566 | Lₐ₃₀₄ | L_{b333} |
| 1567 | Lₐ₃₀₆ | L_{b332} | 1568 | Lₐ₃₀₆ | L_{b333} |
| 1569 | Lₐ₃₀₉ | L_{b332} | 1570 | Lₐ₃₀₉ | L_{b333} |
| 1571 | Lₐ₃₁₁ | L_{b332} | 1572 | Lₐ₃₁₁ | L_{b333} |
| 1573 | Lₐ₃₂₁ | L_{b332} | 1574 | Lₐ₃₂₁ | L_{b333} |
| 1575 | Lₐ₃₂₃ | L_{b332} | 1576 | Lₐ₃₂₃ | L_{b333} |
| 1577 | Lₐ₃₃₂ | L_{b332} | 1578 | Lₐ₃₃₂ | L_{b333} |
| 1579 | Lₐ₃₅₁ | L_{b332} | 1580 | Lₐ₃₅₁ | L_{b333} |
| 1581 | Lₐ₃₅₆ | L_{b332} | 1582 | Lₐ₃₅₆ | L_{b333} |
| 1583 | Lₐ₃₇₅ | L_{b332} | 1584 | Lₐ₃₇₅ | L_{b333} |
| 1585 | Lₐ₄₂₂ | L_{b332} | 1586 | Lₐ₄₂₂ | L_{b333} |
| 1587 | Lₐ₄₂₇ | L_{b332} | 1588 | Lₐ₄₂₇ | L_{b333} |
| 1589 | Lₐ₄₅₀ | L_{b332} | 1590 | Lₐ₄₅₀ | L_{b333} |
| 1591 | Lₐ₄₇₃ | L_{b332} | 1592 | Lₐ₄₇₃ | L_{b333} |
| 1593 | Lₐ₄₉₆ | L_{b332} | 1594 | Lₐ₄₉₆ | L_{b333} |
| 1595 | Lₐ₆₀₆ | L_{b332} | 1596 | Lₐ₆₀₆ | L_{b333} |
| 1597 | Lₐ₆₁₁ | L_{b332} | 1598 | Lₐ₆₁₁ | L_{b333} |
| 1599 | Lₐ₆₃₄ | L_{b332} | 1600 | Lₐ₆₃₄ | L_{b333} |
| 1601 | Lₐ₈₉₉ | L_{b332} | 1602 | Lₐ₈₉₉ | L_{b333} |
| 1603 | Lₐ₉₂₃ | L_{b332} | 1604 | Lₐ₉₂₃ | L_{b333} |
| 1605 | Lₐ₉₉₇ | L_{b332} | 1606 | Lₐ₉₉₇ | L_{b333} |
| 1607 | Lₐ₁₁₀₆ | L_{b332} | 1608 | Lₐ₁₁₀₆ | L_{b333} |
| 1609 | Lₐ₁₁₀₈ | L_{b332} | 1610 | Lₐ₁₁₀₈ | L_{b333} |
| 1611 | Lₐ₁₁₁₂ | L_{b332} | 1612 | Lₐ₁₁₁₂ | L_{b333} |
| 1613 | Lₐ₁₁₁₄ | L_{b332} | 1614 | Lₐ₁₁₁₄ | L_{b333} |
| 1615 | Lₐ₁₁₁₈ | L_{b332} | 1616 | Lₐ₁₁₁₈ | L_{b333} |
| 1617 | Lₐ₁₁₂₀ | L_{b332} | 1618 | Lₐ₁₁₂₀ | L_{b333} |
| 1619 | Lₐ₁₂₁₈ | L_{b332} | 1620 | Lₐ₁₂₁₈ | L_{b333} |
| 1621 | Lₐ₁₂₁₉ | L_{b332} | 1622 | Lₐ₁₂₁₉ | L_{b333} |
| 1623 | Lₐ₁₃₀₂ | L_{b332} | 1624 | Lₐ₁₃₀₂ | L_{b333} |
| 1625 | Lₐ₁₃₀₇ | L_{b332} | 1626 | Lₐ₁₃₀₇ | L_{b333} |
| 1627 | Lₐ₁₄₇₃ | L_{b332} | 1628 | Lₐ₁₄₇₃ | L_{b333} |
| 1629 | Lₐ₁₄₈₇ | L_{b332} | 1630 | Lₐ₁₄₈₇ | L_{b333} |
| 1631 | Lₐ₁₄₉₁ | L_{b332} | 1632 | Lₐ₁₄₉₁ | L_{b333} |
| 1633 | Lₐ₁₇₁₀ | L_{b332} | 1634 | Lₐ₁₇₁₀ | L_{b333} |
| 1635 | Lₐ₁₇₄₀ | L_{b332} | 1636 | Lₐ₁₇₄₀ | L_{b333} |
| 1637 | Lₐ₁₇₄₅ | L_{b332} | 1638 | Lₐ₁₇₄₅ | L_{b333}; |

wherein Compound 1639 to Compound 1766 each have a structure of Ir(Lₐ)₂(L_{b}), wherein the two Lₐ are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 1639 | Lₐ₂₈ | L_{b2} | 1640 | Lₐ₂₈ | L_{b81} |
| 1641 | Lₐ₃₃ | L_{b2} | 1642 | Lₐ₃₃ | L_{b81} |
| 1643 | Lₐ₄₁ | L_{b2} | 1644 | Lₐ₄₁ | L_{b81} |
| 1645 | Lₐ₇₄ | L_{b2} | 1646 | Lₐ₇₄ | L_{b81} |
| 1647 | Lₐ₂₁₇ | L_{b2} | 1648 | Lₐ₂₁₇ | L_{b81} |
| 1649 | Lₐ₃₀₄ | L_{b2} | 1650 | Lₐ₃₀₄ | L_{b81} |
| 1651 | Lₐ₈₉₉ | L_{b2} | 1652 | Lₐ₈₉₉ | L_{b81} |
| 1653 | Lₐ₉₉₇ | L_{b2} | 1654 | Lₐ₉₉₇ | L_{b81} |
| 1655 | Lₐ₁₁₀₆ | L_{b2} | 1656 | Lₐ₁₁₀₆ | L_{b81} |
| 1657 | Lₐ₁₁₀₈ | L_{b2} | 1658 | Lₐ₁₁₀₈ | L_{b81} |
| 1659 | Lₐ₁₂₁₈ | L_{b2} | 1660 | Lₐ₁₂₁₈ | L_{b81} |
| 1661 | Lₐ₁₂₁₉ | L_{b2} | 1662 | Lₐ₁₂₁₉ | L_{b81} |
| 1663 | Lₐ₁₄₈₇ | L_{b2} | 1664 | Lₐ₁₄₈₇ | L_{b81} |
| 1665 | Lₐ₁₄₉₁ | L_{b2} | 1666 | Lₐ₁₄₉₁ | L_{b81} |
| 1667 | Lₐ₁₇₁₀ | L_{b2} | 1668 | Lₐ₁₇₁₀ | L_{b81} |
| 1669 | Lₐ₁₇₄₀ | L_{b2} | 1670 | Lₐ₁₇₄₀ | L_{b81} |
| 1671 | Lₐ₂₈ | L_{b112} | 1672 | Lₐ₂₈ | L_{b151} |
| 1673 | Lₐ₃₃ | L_{b112} | 1674 | Lₐ₃₃ | L_{b151} |
| 1675 | Lₐ₄₁ | L_{b112} | 1676 | Lₐ₄₁ | L_{b151} |
| 1677 | Lₐ₇₄ | L_{b112} | 1678 | Lₐ₇₄ | L_{b151} |
| 1679 | Lₐ₂₁₇ | L_{b112} | 1680 | Lₐ₂₁₇ | L_{b151} |
| 1681 | Lₐ₃₀₄ | L_{b112} | 1682 | Lₐ₃₀₄ | L_{b151} |
| 1683 | Lₐ₈₉₉ | L_{b112} | 1684 | Lₐ₈₉₉ | L_{b151} |
| 1685 | Lₐ₉₉₇ | L_{b112} | 1686 | Lₐ₉₉₇ | L_{b151} |
| 1687 | Lₐ₁₁₀₆ | L_{b112} | 1688 | Lₐ₁₁₀₆ | L_{b151} |
| 1689 | Lₐ₁₁₀₈ | L_{b112} | 1690 | Lₐ₁₁₀₈ | L_{b151} |
| 1691 | Lₐ₁₂₁₈ | L_{b112} | 1692 | Lₐ₁₂₁₈ | L_{b151} |
| 1693 | Lₐ₁₂₁₉ | L_{b112} | 1694 | Lₐ₁₂₁₉ | L_{b151} |
| 1695 | Lₐ₁₄₈₇ | L_{b112} | 1696 | Lₐ₁₄₈₇ | L_{b151} |
| 1697 | Lₐ₁₄₉₁ | L_{b112} | 1698 | Lₐ₁₄₉₁ | L_{b151} |
| 1699 | Lₐ₁₇₁₀ | L_{b112} | 1700 | Lₐ₁₇₁₀ | L_{b151} |
| 1701 | Lₐ₁₇₄₀ | L_{b112} | 1702 | Lₐ₁₇₄₀ | L_{b151} |
| 1703 | Lₐ₂₈ | L_{b209} | 1704 | Lₐ₂₈ | L_{b241} |
| 1705 | Lₐ₃₃ | L_{b209} | 1706 | Lₐ₃₃ | L_{b241} |
| 1707 | Lₐ₄₁ | L_{b209} | 1708 | Lₐ₄₁ | L_{b241} |
| 1709 | Lₐ₇₄ | L_{b209} | 1710 | Lₐ₇₄ | L_{b241} |
| 1711 | Lₐ₂₁₇ | L_{b209} | 1712 | Lₐ₂₁₇ | L_{b241} |
| 1713 | Lₐ₃₀₄ | L_{b209} | 1714 | Lₐ₃₀₄ | L_{b241} |
| 1715 | Lₐ₈₉₉ | L_{b209} | 1716 | Lₐ₈₉₉ | L_{b241} |
| 1717 | Lₐ₉₉₇ | L_{b209} | 1718 | Lₐ₉₉₇ | L_{b241} |
| 1719 | Lₐ₁₁₀₆ | L_{b209} | 1720 | Lₐ₁₁₀₆ | L_{b241} |
| 1721 | Lₐ₁₁₀₈ | L_{b209} | 1722 | Lₐ₁₁₀₈ | L_{b241} |
| 1723 | Lₐ₁₂₁₈ | L_{b209} | 1724 | Lₐ₁₂₁₈ | L_{b241} |
| 1725 | Lₐ₁₂₁₉ | L_{b209} | 1726 | Lₐ₁₂₁₉ | L_{b241} |
| 1727 | Lₐ₁₄₈₇ | L_{b209} | 1728 | Lₐ₁₄₈₇ | L_{b241} |
| 1729 | Lₐ₁₄₉₁ | L_{b209} | 1730 | Lₐ₁₄₉₁ | L_{b241} |
| 1731 | Lₐ₁₇₁₀ | L_{b209} | 1732 | Lₐ₁₇₁₀ | L_{b241} |
| 1733 | Lₐ₁₇₄₀ | L_{b209} | 1734 | Lₐ₁₇₄₀ | L_{b241} |
| 1735 | Lₐ₂₈ | L_{b330} | 1736 | Lₐ₂₈ | L_{b333} |
| 1737 | Lₐ₃₃ | L_{b330} | 1738 | Lₐ₃₃ | L_{b333} |
| 1739 | Lₐ₄₁ | L_{b330} | 1740 | Lₐ₄₁ | L_{b333} |
| 1741 | Lₐ₇₄ | L_{b330} | 1742 | Lₐ₇₄ | L_{b333} |
| 1743 | Lₐ₂₁₇ | L_{b330} | 1744 | Lₐ₂₁₇ | L_{b333} |
| 1745 | Lₐ₃₀₄ | L_{b330} | 1746 | Lₐ₃₀₄ | L_{b333} |
| 1747 | Lₐ₈₉₉ | L_{b330} | 1748 | Lₐ₈₉₉ | L_{b333} |
| 1749 | Lₐ₉₉₇ | L_{b330} | 1750 | Lₐ₉₉₇ | L_{b333} |
| 1751 | Lₐ₁₁₀₆ | L_{b330} | 1752 | Lₐ₁₁₀₆ | L_{b333} |
| 1753 | Lₐ₁₁₀₈ | L_{b330} | 1754 | Lₐ₁₁₀₈ | L_{b333} |
| 1755 | Lₐ₁₂₁₈ | L_{b330} | 1756 | Lₐ₁₂₁₈ | L_{b333} |
| 1757 | Lₐ₁₂₁₉ | L_{b330} | 1758 | Lₐ₁₂₁₉ | L_{b333} |
| 1759 | Lₐ₁₄₈₇ | L_{b330} | 1760 | Lₐ₁₄₈₇ | L_{b333} |
| 1761 | Lₐ₁₄₉₁ | L_{b330} | 1762 | Lₐ₁₄₉₁ | L_{b333} |
| 1763 | Lₐ₁₇₁₀ | L_{b330} | 1764 | Lₐ₁₇₁₀ | L_{b333} |
| 1765 | Lₐ₁₇₄₀ | L_{b330} | 1766 | Lₐ₁₇₄₀ | L_{b333}; |

wherein Compound 1767 to Compound 1826 each have a structure of Ir(Lₐ)(L_{b})(L_{c}), wherein Lₐ, L_{b}, and L_{c} are selected from the structures listed in the following table, respectively:

| Compound | | | | Compound | | | |
|---|---|---|---|---|---|---|---|
| No. | Lₐ | L_{b} | L_{c} | No. | Lₐ | L_{b} | L_{c} |
| 1767 | Lₐ₂₈ | L_{b81} | L_{c1} | 1768 | Lₐ₃₃ | L_{b81} | L_{c1} |
| 1769 | Lₐ₂₈ | L_{b81} | L_{c3} | 1770 | Lₐ₃₃ | L_{b81} | L_{c3} |
| 1771 | Lₐ₂₈ | L_{b81} | L_{c5} | 1772 | Lₐ₃₃ | L_{b81} | L_{c5} |
| 1773 | Lₐ₂₈ | L_{b81} | L_{c12} | 1774 | Lₐ₃₃ | L_{b81} | L_{c12} |
| 1775 | Lₐ₂₈ | L_{b81} | L_{c17} | 1776 | Lₐ₃₃ | L_{b81} | L_{c17} |
| 1777 | Lₐ₂₈ | L_{b81} | L_{c18} | 1778 | Lₐ₃₃ | L_{b81} | L_{c18} |
| 1779 | Lₐ₂₈ | L_{b81} | L_{c29} | 1780 | Lₐ₃₃ | L_{b81} | L_{c29} |
| 1781 | Lₐ₂₈ | L_{b81} | L_{c30} | 1782 | Lₐ₃₃ | L_{b81} | L_{c30} |
| 1783 | Lₐ₂₈ | L_{b81} | L_{c40} | 1784 | Lₐ₃₃ | L_{b81} | L_{c40} |
| 1785 | Lₐ₂₈ | L_{b81} | L_{c46} | 1786 | Lₐ₃₃ | L_{b81} | L_{c46} |
| 1787 | Lₐ₂₈ | L_{b81} | L_{c59} | 1788 | Lₐ₃₃ | L_{b81} | L_{c59} |
| 1789 | Lₐ₂₈ | L_{b81} | L_{c79} | 1790 | Lₐ₃₃ | L_{b81} | L_{c79} |
| 1791 | Lₐ₂₈ | L_{b81} | L_{c99} | 1792 | Lₐ₃₃ | L_{b81} | L_{c99} |
| 1793 | Lₐ₂₈ | L_{b81} | L_{c112} | 1794 | Lₐ₃₃ | L_{b81} | L_{c112} |
| 1795 | Lₐ₂₈ | L_{b81} | L_{c138} | 1796 | Lₐ₃₃ | L_{b81} | L_{c138} |
| 1797 | Lₐ₂₈ | L_{b81} | L_{c182} | 1798 | Lₐ₃₃ | L_{b81} | L_{c182} |
| 1799 | Lₐ₂₈ | L_{b81} | L_{c192} | 1800 | Lₐ₃₃ | L_{b81} | L_{c192} |
| 1801 | Lₐ₂₈ | L_{b81} | L_{c195} | 1802 | Lₐ₃₃ | L_{b81} | L_{c195} |
| 1803 | Lₐ₂₈ | L_{b81} | L_{c201} | 1804 | Lₐ₃₃ | L_{b81} | L_{c201} |
| 1805 | Lₐ₂₈ | L_{b81} | L_{c205} | 1806 | Lₐ₃₃ | L_{b81} | L_{c205} |
| 1807 | Lₐ₂₈ | L_{b81} | L_{c211} | 1808 | Lₐ₃₃ | L_{b81} | L_{c211} |
| 1809 | Lₐ₂₈ | L_{b81} | L_{c212} | 1810 | Lₐ₃₃ | L_{b81} | L_{c212} |
| 1811 | Lₐ₂₈ | L_{b81} | L_{c226} | 1812 | Lₐ₃₃ | L_{b81} | L_{c226} |
| 1813 | Lₐ₂₈ | L_{b81} | L_{c229} | 1814 | Lₐ₃₃ | L_{b81} | L_{c229} |
| 1815 | Lₐ₂₈ | L_{b81} | L_{c252} | 1816 | Lₐ₃₃ | L_{b81} | L_{c252} |
| 1817 | Lₐ₂₈ | L_{b81} | L_{c256} | 1818 | Lₐ₃₃ | L_{b81} | L_{c256} |
| 1819 | Lₐ₂₈ | L_{b81} | L_{c310} | 1820 | Lₐ₃₃ | L_{b81} | L_{c310} |
| 1821 | Lₐ₂₈ | L_{b81} | L_{c326} | 1822 | Lₐ₃₃ | L_{b81} | L_{c326} |
| 1823 | Lₐ₂₈ | L_{b81} | L_{c327} | 1824 | Lₐ₃₃ | L_{b81} | L_{c327} |
| 1825 | Lₐ₂₈ | L_{b81} | L_{c328} | 1826 | Lₐ₃₃ | L_{b81} | L_{c328}; |

wherein optionally, hydrogen atoms in the structures of Compound 1 to Compound 1826 can be partially or fully substituted with deuterium.

18. An electroluminescent device, comprising:
an anode,
a cathode, and
an organic layer disposed between the anode and the cathode, wherein the organic layer comprises the metal complex according to claim 1.

19. The electroluminescent device according to claim 18, wherein the organic layer is an emissive layer, and the metal complex is an emissive material.

20. The electroluminescent device according to claim 18, wherein the electroluminescent device emits red light or white light.

21. The electroluminescent device according to claim 19, wherein the emissive layer further comprises at least one host material;
preferably, the at least one host material comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

22. A compound composition, comprising the metal complex according to claim 1.
